(19) United States
(12) Patent Application Publication
(10) Pub. No.: US 2025/0169354 A1
(43) Pub. Date: May 22, 2025

(54) COMPOSITION, LIGHT-EMITTING DEVICE, ELECTRONIC EQUIPMENT INCLUDING THE LIGHT-EMITTING DEVICE, AND ORGANOMETALLIC COMPOUND

(71) Applicant: Samsung Display Co., Ltd., Yongin-si (KR)

(72) Inventors: Chanseok Oh, Yongin-si (KR); Iljoon Kang, Yongin-si (KR); Soobyung Ko, Yongin-si (KR); Sooinn Lee, Yongin-si (KR); Jinhee Ju, Yongin-si (KR); Junghoon Han, Yongin-si (KR)

(21) Appl. No.: 18/929,196

(22) Filed: Oct. 28, 2024

(30) Foreign Application Priority Data
Nov. 3, 2023 (KR) 10-2023-0151024

(51) Int. Cl. H10K 85/30; C09K 11/06; G02F 1/1335; H10K 85/40; H10K 85/60; H10K 101/20

(52) U.S. Cl. CPC H10K 85/346; C09K 11/06; G02F 1/133514; H10K 85/40; H10K 85/653; H10K 85/654; H10K 85/656; H10K 85/6572; H10K 85/658; H10K 2101/20

(57) ABSTRACT

A composition including an organometallic compound represented by Formula 1, a light-emitting device including the organometallic compound represented by Formula 1, and electronic equipment including the light-emitting device are provided. In addition, the organometallic compound represented by Formula 1 is also provided:

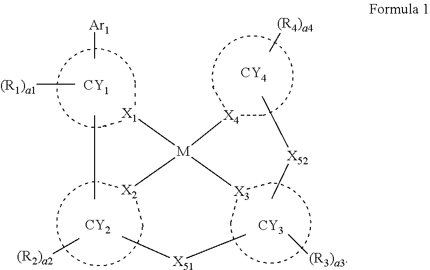

### CROSS-REFERENCE TO RELATED APPLICATION

The present application claims priority to and the benefit of Korean Patent Application No. 10-2023-0151024, filed on Nov. 3, 2023, in the Korean Intellectual Property Office, the entire content of which is incorporated herein by reference.

### BACKGROUND

### 1. Field

One or more embodiments of the present disclosure relate to a composition, a light-emitting device, an electronic equipment including the light-emitting device, and an organometallic compound.

### 2. Description of the Related Art

Self-emissive devices (for example, organic light-emitting devices, and/or the like) in light-emitting devices have relatively wide viewing angles, relatively high contrast ratios, relatively short response times, and excellent or suitable characteristics in terms of luminance, driving voltage, and/or response speed.

In a light-emitting device, a first electrode is arranged on a substrate, and a hole transport region, an emission layer, an electron transport region, and a second electrode are sequentially arranged on the first electrode in the stated order. Holes provided from the first electrode move toward the emission layer through the hole transport region, and electrons provided from the second electrode move toward the emission layer through the electron transport region. Carriers, such as the holes and the electrons, recombine in the emission layer to produce excitons. The excitons may transit and decay from an excited state to a ground state, thereby generating light.

### SUMMARY

One or more aspects of embodiments of the present disclosure are directed toward a composition capable of providing improved color purity, improved luminescence efficiency, and/or improved lifespan for a light-emitting device, an organometallic compound, a light-emitting device having improved color purity, improved luminescence efficiency, and/or improved lifespan, and/or an electronic equipment including the light-emitting device.

Additional aspects will be set forth in part in the description which follows and, in part, will be apparent from the description, or may be learned by practice of the presented embodiments of the disclosure.

According to one or more embodiments of the present disclosure, a composition includes:
an organometallic compound represented by Formula 1; and
a second compound including at least one π electron-deficient nitrogen-containing C₁-C₆₀ heterocyclic group, a third compound including a group represented by Formula 3, a fourth compound capable of emitting delayed fluorescence, or any combination thereof,
wherein the organometallic compound, the second compound, the third compound, and the fourth compound are different from each other:

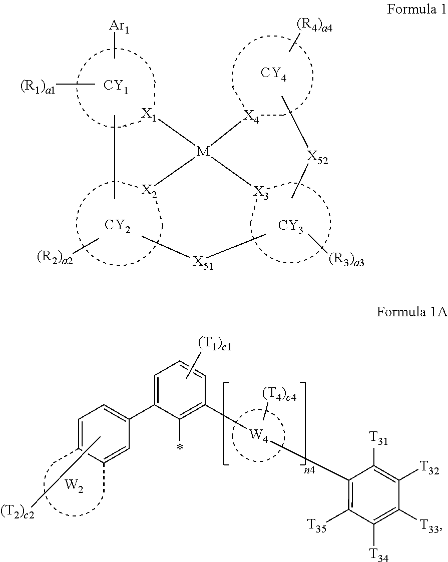

wherein, Ar₁ in Formula 1 may be a group represented by Formula 1A,
* in Formula 1A indicates a binding site to ring CY₁ in Formula 1,
wherein, in Formulae 1 and 1A,
M may be platinum (Pt), palladium (Pd), gold (Au), nickel (Ni), silver (Ag), or copper (Cu),
X₁ to X₄ may each independently be C or N,
i) a bond between X₁ and M may be a coordinate bond, and ii) one selected from among a bond between X₂ and M, a bond between X₃ and M, and a bond between X₄ and M is a coordinate bond, and the other two may each be a covalent bond,
ring CY₁ to ring CY₄ and ring W₄ may each independently be a C₃-C₆₀ carbocyclic group or a C₁-C₆₀ heterocyclic group,
ring W₂ may be a saturated C₃-C₈ carbocyclic group,
n4 may be 0, 1, or 2, wherein, when n4 is 0, a group represented by

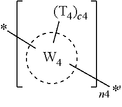

in Formula 1A may be a single bond,
X₅₁ may be a single bond, *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′, *—O—*′, *—C(═O)—*′, *—S(═O)—*′, *—S(═O)₂—*′, *—C(Z₅₁ₐ)=*′, *═C(Z₅₁ₐ)—*′, *—C(Z₅₁ₐ)═C(Z_{51b})—*′, *—C(═S)—*′, or *—C≡C—*′,
X₅₂ may be a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′, *—O—*′, *—C(═O)—*′, *—S(═O)—*′, *—S(═O)₂—*′, *—C(Z₅₂ₐ)=*′, *═C(Z₅₂ₐ)—*′, *—C(Z₅₂ₐ)═C(Z_{52b})—*′, *—C(═S)—*′, or *—C≡C—*′,
R₁ to R₄, Z₅₁ₐ, Z_{51b}, Z₅₂ₐ, and Z_{52b} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
T₁, T₂, T₃₁ to T₃₅, and T₄ may each independently be:
hydrogen, deuterium, —F, or a cyano group;
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof; or
a phenyl group, a naphthyl group, a dibenzofuranyl group, or a dibenzothiophenyl (dibenzothienyl) group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof,
a1 to a4 may each independently be an integer from 0 to 10,
c1 may be an integer from 1 to 3,
c2 may be an integer from 1 to 15,
c4 may be an integer from 1 to 10,
Formula 1A may satisfy at least one selected from among Conditions A and B:

### Condition A

T₃₁ and T₃₅ may be different from each other; and

### Condition B

T₃₂ and T₃₄ may be different from each other,
in Formula 1A, a group represented by

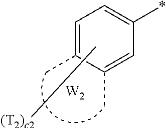

and a group represented by

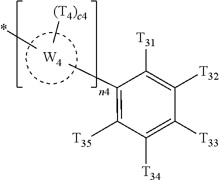

may be different from each other,
two or more selected from among ring CY₁, ring CY₂, ring CY₃, ring CY₄, R₁, R₂, R₃, R₄, Z₅₁ₐ, Z_{51b}, Z₅₂ₐ, Z_{52b}, T₁, T₂, T₃₁, T₃₂, T₃₃, T₃₄, T₃₅, and T₄ may optionally be bonded together to form (or provide) a C₃-C₆₀ carbocyclic group or unsubstituted or substituted with at least one R₁₀ₐ or a C₁-C₆₀ heterocyclic group unsubstituted or substituted with at least one R₁₀ₐ,
* indicates a binding site to a neighboring atom,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a (e.g., any suitable) combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a (e.g., any suitable) combination thereof;
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂); or
a (e.g., any suitable) combination thereof, and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or a (e.g., any suitable) combination thereof,

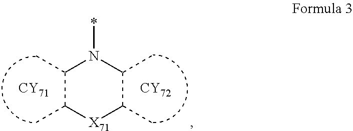

wherein, in Formula 3,
ring CY₇₁ and ring CY₇₂ may each independently be a π electron-rich C₃-C₆₀ cyclic group or a pyridine group,
X₇₁ may be a single bond, or a linking group including O, S, N, B, C, Si, or a (e.g., any suitable) combination thereof, and
* indicates a binding site to any atom included in the remaining part other than the group represented by Formula 3 in the third compound.

According to one or more embodiments of the present disclosure, a light-emitting device includes:
a first electrode;
a second electrode facing (e.g., opposite to and facing) the first electrode;
an interlayer between the first electrode and the second electrode and including an emission layer; and
the organometallic compound represented by Formula 1.

According to one or more embodiments of the present disclosure, electronic equipment includes the light-emitting device.

According to one or more embodiments of the present disclosure, an electronic apparatus includes the light-emitting device.

One or more aspects of embodiments of the present disclosure are directed toward the organometallic compound represented by Formula 1.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIG. 1 is a diagram schematically showing a structure of a light-emitting device according to one or more embodiments of the present disclosure;

FIGS. 2 and 3 are each a diagram schematically showing a structure of a light-emitting apparatus as an electronic apparatus, according to one or more embodiments of the present disclosure; and

FIGS. 4, 5, 6A, 6B, and 6C are each a diagram schematically showing a structure of an electronic equipment according to one or more embodiments of the present disclosure.

### DETAILED DESCRIPTION

Reference will now be made in more detail to embodiments, examples of which are illustrated in the accompanying drawings, wherein like reference numerals refer to like elements throughout the present disclosure, and duplicative descriptions thereof may not be provided for conciseness. In this regard, the embodiments of the present disclosure may have different forms and should not be construed as being limited to the descriptions set forth herein. Accordingly, the embodiments of the present disclosure are merely described, by referring to the drawings, to explain aspects of the present disclosure. As utilized herein, the term “and/or” or “or” may include any and all combinations of one or more of the associated listed items. Throughout the disclosure, the expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

According to one or more embodiments of the present disclosure, a composition includes:
an organometallic compound represented by Formula 1; and
a second compound including at least one π electron-deficient nitrogen-containing C₁-C₆₀ heterocyclic group, a third compound including a group represented by Formula 3, a fourth compound capable of emitting delayed fluorescence, or any combination thereof,
wherein the organometallic compound, the second compound, the third compound, and the fourth compound are different from each other:

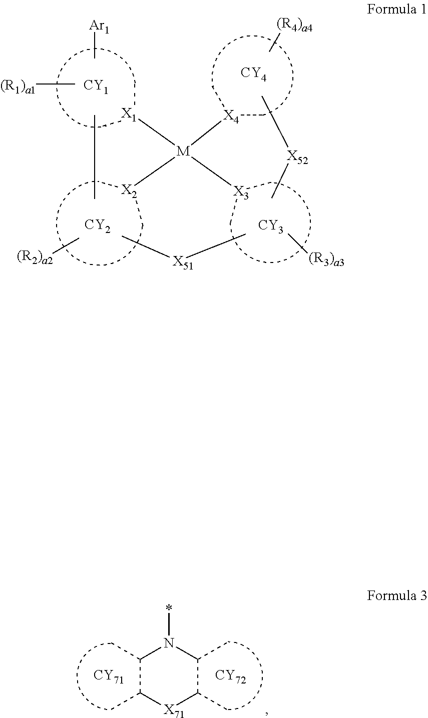

wherein, in Formula 3,
ring CY₇₁ and ring CY₇₂ may each independently be a π electron-rich C₃-C₆₀ cyclic group or a pyridine group,
X₇₁ may be a single bond, or a linking group including O, S, N, B, C, Si, or a (e.g., any suitable) combination thereof, and
* indicates a binding site to any atom included in the remaining part other than the group represented by Formula 3 in the third compound.

In the present disclosure, the organometallic compound represented by Formula 1 may be referred to as “first compound”.

For descriptions of each of Formulae 1 and 3, reference may be made to the present disclosure.

In one or more embodiments, the composition may be included in a layer, the layer including 1) the organometallic compound and 2) the second compound, the third compound, the fourth compound, or a combination thereof. The wording “layer including the composition” may refer that the layer includes a mixture including 1) the organometallic compound and 2) the second compound, the third compound, the fourth compound, or a combination thereof. Therefore, the wording “layer including the composition” may be, for example, clearly differentiated from a double layer including (e.g., consisting of) 1) a first layer including the organometallic compound and 2) a second layer including the second compound, the third compound, the fourth compound, or any combination thereof.

In one or more embodiments, the composition may be a composition prepared to form (or provide) a layer, the layer including 1) the organometallic compound and 2) the second compound, the third compound, the fourth compound, or any combination thereof, by utilizing one or more suitable methods such as a deposition process, a wet process, and/or the like. For example, the composition may be a pre-mixed mixture prepared for utilization in a deposition process (for example, a vacuum deposition process). The pre-mixed mixture may be, for example, charged into a deposition source within a vacuum chamber, and two or more compounds included in the pre-mixed mixture may be co-deposited.

In one or more embodiments, a weight ratio of the organometallic compound to the second compound in the composition may be in a range of about 10:90 to about 90:10 or about 20:80 to about 80:20.

According to one or more embodiments of the present disclosure, a light-emitting device may include:
a first electrode;
a second electrode facing (e.g., opposite to and facing) the first electrode;
an interlayer between the first electrode and the second electrode and including an emission layer; and
the organometallic compound represented by Formula 1.

For a description of Formula 1, reference may be made to the present disclosure.

The light-emitting device includes the organometallic compound represented by Formula 1, and may accordingly have improved color purity, improved luminescence efficiency, and/or improved lifespan characteristics.

In one or more embodiments, the interlayer in the light-emitting device may include the organometallic compound.

In one or more embodiments, the emission layer in the light-emitting device may include the organometallic compound.

In one or more embodiments, the light-emitting device may further include a second compound including at least one π electron-deficient nitrogen-containing C₁-C₆₀ heterocyclic group, a third compound including a group represented by Formula 3, a fourth compound capable of emitting delayed fluorescence, or any combination thereof,
wherein the organometallic compound, the second compound, the third compound, and the fourth compound in the light-emitting device may be different from each other:

For descriptions of each of the second compound to the fourth compound in the composition, reference may be made to the present disclosure.

In one or more embodiments, the organometallic compound may include at least one deuterium.

In one or more embodiments, the second compound to the fourth compound may each include at least one deuterium.

In one or more embodiments, the second compound may include at least one silicon.

In one or more embodiments, the third compound may include at least one silicon.

In one or more embodiments, each of the composition and the light-emitting device (e.g., the emission layer in the light-emitting device) may further include the second compound and the third compound, in addition to the organometallic compound represented by Formula 1, wherein at least one of the second compound or the third compound may include at least one deuterium, at least one silicon, or a combination thereof.

In one or more embodiments, each of the composition and the light-emitting device (e.g., the emission layer in the light-emitting device) may further include the second compound in addition to the organometallic compound. At least one of the organometallic compound or the second compound may include at least one deuterium. In one or more embodiments, each of the composition and the light-emitting device (e.g., the emission layer in the light-emitting device) may further include the third compound, the fourth compound, or a combination thereof, in addition to the organometallic compound and the second compound.

In one or more embodiments, each of the composition and the light-emitting device (e.g., the emission layer in the light-emitting device) may further include the third compound in addition to the organometallic compound. At least one of the organometallic compound or the third compound may include at least one deuterium. In one or more embodiments, each of the composition and the light-emitting device (e.g., the emission layer in the light-emitting device) may further include the second compound, the fourth compound, or a combination thereof, in addition to the organometallic compound and the third compound.

In one or more embodiments, each of the composition and the light-emitting device (e.g., the emission layer in the light-emitting device) may further include the fourth compound in addition to the organometallic compound. At least one of the organometallic compound or the fourth compound may include at least one deuterium. The fourth compound may have roles in improving color purity, luminescence efficiency, and lifespan characteristics of the light-emitting device. In one or more embodiments, each of the composition and the light-emitting device (e.g., the emission layer in the light-emitting device) may further include the second compound, the third compound, or a combination thereof, in addition to the organometallic compound and the fourth compound.

In one or more embodiments, each of the composition and the light-emitting device (e.g., the emission layer in the light-emitting device) may further include the second compound and the third compound, in addition to the organometallic compound. The second compound and the third compound may form (or provide) an exciplex. At least one of the organometallic compound, the second compound, or the third compound may include at least one deuterium.

In one or more embodiments, a highest occupied molecular orbital (HOMO) energy level of the organometallic compound may be in a range of about −5.35 eV to about −5.15 eV or about −5.30 eV to about −5.20 eV.

In one or more embodiments, a lowest unoccupied molecular orbital (LUMO) energy level of the organometallic compound may be in a range of about −2.20 eV to about −1.80 eV or about −2.15 eV to about −1.90 eV.

The HOMO and LUMO energy levels may be evaluated by cyclic voltammetry analysis (refer to Evaluation Example 1) for the organometallic compound.

In one or more embodiments, a maximum emission wavelength (or an emission peak wavelength) of an emission spectrum of a film of the organometallic compound may be in a range of about 430 nanometer (nm) to about 475 nm, about 440 nm to about 475 nm, about 450 nm to about 475 nm, about 430 nm to about 470 nm, about 440 nm to about 470 nm, about 450 nm to about 470 nm, about 430 nm to about 465 nm, about 440 nm to about 465 nm, about 450 nm to about 465 nm, about 430 nm to about 460 nm, about 440 nm to about 460 nm, or about 450 nm to about 460 nm.

In one or more embodiments, a full width at half maximum (FWHM) of an emission spectrum of a film of the organometallic compound may be 40 nm or less, for example, about 5 nm to about 40 nm, about 10 nm to about 40 nm, about 15 nm to about 40 nm, about 20 nm to about 40 nm, about 5 nm to about 38 nm, about 10 nm to about 38 nm, about 15 nm to about 38 nm, or about 20 nm to about 38 nm.

In one or more embodiments, a photoluminescence quantum yield (PLQY) of a film of the organometallic compound may be in a range of about 50% to about 99%, about 55% to about 95%, about 60% to about 95%, about 65% to about 95%, about 70% to about 95%, about 55% to about 90%, about 60% to about 90%, about 65% to about 90%, or about 70% to about 90%.

In one or more embodiments, a decay time of the organometallic compound may be in a range of about 1.80 μs to about 3.00 μs, about 1.90 μs to about 2.70 μs, about 1.90 μs to about 2.50 μs, or about 1.90 μs to about 2.30 μs.

The maximum emission wavelength, FWHM, PLQY, and decay time of the organometallic compound are evaluated for a film including the organometallic compound. For descriptions of evaluation methods therefor, reference may be made to, for example, Evaluation Examples 2 and 3.

In one or more embodiments, the emission layer in the light-emitting device may include: i) the organometallic compound; and ii) the second compound, the third compound, the fourth compound, or any combination thereof, wherein the emission layer may be to emit blue light.

In one or more embodiments, a maximum emission wavelength (e.g., emission peak wavelength) of the blue light may be in a range of about 390 nm to about 500 nm, about 410 nm to about 490 nm, about 430 nm to about 480 nm, about 440 nm to about 475 nm, about 455 nm to about 470 nm, 430 nm to about 475 nm, about 440 nm to about 475 nm, about 450 nm to about 475 nm, about 430 nm to about 470 nm, about 440 nm to about 470 nm, about 450 nm to about 470 nm, about 430 nm to about 465 nm, about 440 nm to about 465 nm, about 450 nm to about 465 nm, about 430 nm to about 460 nm, about 440 nm to about 460 nm, or about 450 nm to about 460 nm.

In one or more embodiments, the full width at half maximum of the blue light may be 40 nm or less, or may be in a range of about 5 nm to about 40 nm, about 10 nm to about 40 nm, about 15 nm to about 40 nm, about 20 nm to about 40 nm, about 5 nm to about 38 nm, about 10 nm to about 38 nm, about 15 nm to about 38 nm, or about 20 nm to about 38 nm.

In one or more embodiments, the blue light may be deep blue light.

In one or more embodiments, a CIEx coordinate (e.g., a CIEx coordinate for bottom emission) of the blue light may be in a range of about 0.125 to about 0.140 or about 0.130 to about 0.140.

In one or more embodiments, a CIEy coordinate (e.g., a CIEy coordinate for bottom emission) of the blue light may be in a range of about 0.100 to about 0.130.

For examples of the maximum emission wavelength and CIE y coordinate of the blue light, reference may be made to Tables 7 and 9 in the present disclosure.

In one or more embodiments, the second compound may include a pyridine group, a pyrimidine group, a pyrazine group, a pyridazine group, a triazine group, or a (e.g., any suitable) combination thereof.

In one or more embodiments, the third compound may not include (e.g., may exclude) the following compounds:

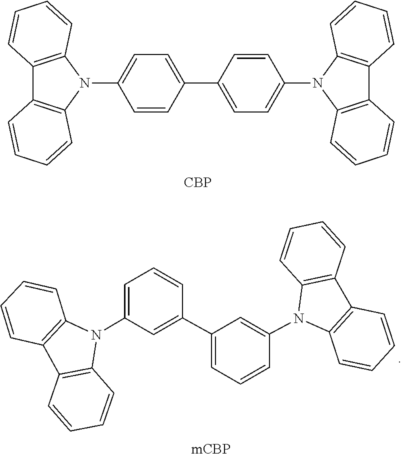 [SMILES: c1ccc2c(c1)c1ccccc1n2-c1ccc(-c2ccc(-n3c4ccccc4c4ccccc43)cc2)cc1 ; "CBP" ; c1cc(-c2cccc(-n3c4ccccc4c4ccccc43)c2)cc(-n2c3ccccc3c3ccccc32)c1 ; "mCBP"]

In one or more embodiments, the fourth compound may be a compound in which a difference between a triplet energy level (unit: eV) thereof and a singlet energy level (eV) thereof is in a range of about 0 eV or more to about 0.5 eV or less (or about 0 eV or more to about 0.3 eV or less).

In one or more embodiments, the fourth compound may be a compound including at least one cyclic group including both (e.g., simultaneously) boron (B) and nitrogen (N) as ring-forming atoms.

In one or more embodiments, the fourth compound may be a C₈-C₆₀ polycyclic group-containing compound including two or more cyclic groups that are condensed while sharing B (e.g., one being a third ring and the other being a fourth ring).

In one or more embodiments, the fourth compound may include a condensed ring in which at least one third ring is condensed with at least one fourth ring, for example, to form the condensed ring including four or more rings,
wherein the third ring of the fourth compound may be a cyclopentane group, a cyclohexane group, a cycloheptane group, a cyclooctane group, a cyclopentene group, a cyclohexene group, a cycloheptene group, a cyclooctene group, an adamantane group, a norbornene group, a norbornane group, a bicyclo[1.1.1]pentane group, a bicyclo[2.1.1]hexane group, a bicyclo[2.2.2]octane group, a benzene group, a pyridine group, a pyrimidine group, a pyridazine group, a pyrazine group, or a triazine group, and
the fourth ring of the fourth compound may be a 1,2-azaborinine group, a 1,3-azaborinine group, a 1,4-azaborinine group, a 1,2-dihydro-1,2-azaborinine group, a 1,4-oxaborinine group, a 1,4-thiaborinine group, or a 1,4-dihydroborinine group.

In one or more embodiments, the third compound may not include (e.g., may exclude) a (e.g., any suitable) compound represented by Formula 3-1 described herein.

In one or more embodiments, the second compound may include a compound represented by Formula 2:

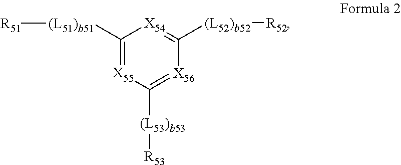

wherein, in Formula 2,
L₅₁ to L₅₃ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
b51 to b53 may each independently be an integer from 1 to 5,
X₅₄ may be N or C(R₅₄), X₅₅ may be N or C(R₅₅), X₅₆ may be N or C(R₅₅), and at least one selected from among X₅₄ to X₅₆ may be N, and
R₅₁ to R₅₆ and R₁₀ₐ may each be the same as described herein.

In one or more embodiments, the third compound may include a compound represented by Formula 3-1, a compound represented by Formula 3-2, a compound represented by Formula 3-3, a compound represented by Formula 3-4, a compound represented by Formula 3-5, or a (e.g., any suitable) combination thereof:

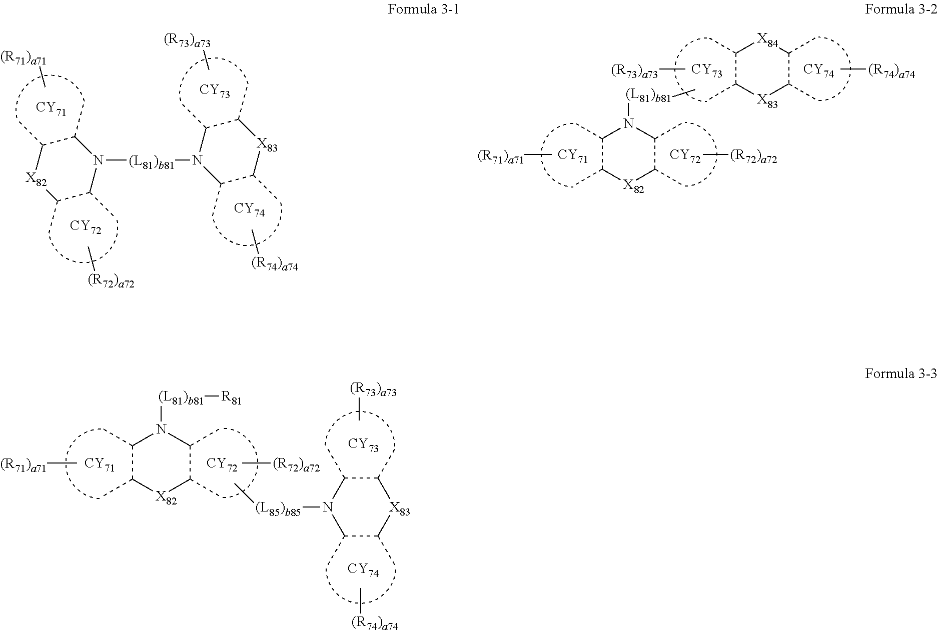

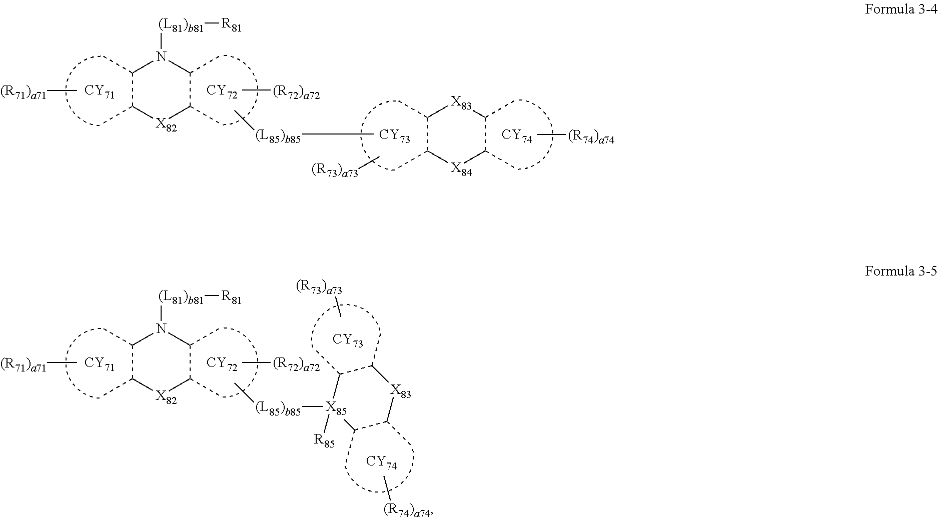

wherein, in Formulae 3-1 to 3-5,
ring CY₇₁ to ring CY₇₄ may each independently be a π electron-rich C₃-C₆₀ cyclic group or a pyridine group,
X₈₂ may be a single bond, O, S, N[(L₈₂)_{b82}-R₈₂], C(R₈₂ₐ)(R_{82b}), or Si(R₈₂ₐ) (R_{82b}),
X₈₃ may be a single bond, O, S, N[(L₈₃)_{b83}-R₈₃], C(R₈₃ₐ)(R_{83b}), or Si(R₈₃ₐ)(R_{83b}),
X₈₄ may be O, S, N[(L₈₄)_{b84}-R₈₄], C(R₈₄ₐ)(R_{84b}), or Si(R₈₄ₐ)(R_{84b}),
X₈₅ may be C or Si,
L₈₁ to L₈₅ may each independently be a single bond, *—C(Q₄)(Q₅)-*′, *—Si(Q₄)(Q₅)-*′, a π electron-rich C₃-C₆₀ cyclic group unsubstituted or substituted with at least one R₁₀ₐ, or a pyridine group unsubstituted or substituted with at least one R₁₀ₐ, wherein Q₄ and Q₅ may each independently be the same as described with respect to Q₁,
b81 to b85 may each independently be an integer from 1 to 5,
R₇₁ to R₇₄, R₈₁ to R₈₅, R₈₂ₐ, R_{82b}, R₈₃ₐ, R_{83b}, R₈₄ₐ, and R_{84b} may each independently be the same as described herein,
a71 to a74 may each independently be an integer from 0 to 20, and
R₁₀ₐ may be the same as described herein.

In one or more embodiments, the fourth compound may be a compound represented by Formula 502, a compound represented by Formula 503, or a (e.g., any suitable) combination thereof:

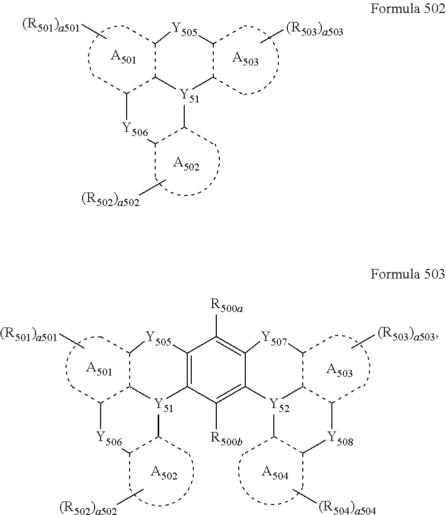

wherein, in Formulae 502 and 503,
ring A₅₀₁ to ring A₅₀₄ may each independently be a C₃-C₆₀ carbocyclic group or a C₁-C₆₀ heterocyclic group,
Y₅₀₅ may be O, S, N(R₅₀₅), B(R₅₀₅), C(R₅₀₅ₐ)(R_{505b}), or Si(R₅₀₅ₐ)(R_{505b}),
Y₅₀₆ may be O, S, N(R₅₀₆), B(R₅₀₆), C(R₅₀₆ₐ)(R_{506b}), or Si(R₅₀₆ₐ)(R_{506b}),
Y₅₀₇ may be O, S, N(R₅₀₇), B(R₅₀₇), C(R₅₀₇ₐ)(R_{507b}), or Si(R₅₀₇ₐ)(R_{507b}),
Y₅₀₈ may be O, S, N(R₅₀₈), B(R₅₀₈), C(R₅₀₈ₐ)(R_{508b}), or Si(R₅₀₈ₐ)(R_{508b}),
Y₅₁ and Y₅₂ may each independently be B or P(═O),
R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} may each be the same as described herein, and

a501 to a504 may each independently be an integer from 0 to 20.

In one or more embodiments, the light-emitting device may satisfy at least one selected from among Conditions 1 to 4:

### Condition 1

LUMO energy level (eV) of third compound>LUMO energy level (eV) of organometallic compound;

### Condition 2

LUMO energy level (eV) of organometallic compound>LUMO energy level (eV) of second compound;

### Condition 3

HOMO energy level (eV) of organometallic compound>HOMO energy level (eV) of third compound; and

### Condition 4

HOMO energy level (eV) of the third compound>HOMO energy level (eV) of the second compound.

Here, each of the HOMO energy level and the LUMO energy level of each of the organometallic compound, the second compound, and the third compound may be a negative value, and may be measured according to a suitable method, for example, a method described in Evaluation Example 1 in the present disclosure.

In one or more embodiments, an absolute value of a difference between the LUMO energy level of the organometallic compound and the LUMO energy level of the second compound may be in a range of about 0.1 eV or more to about 1.0 eV or less, an absolute value of a difference between the LUMO energy level of the organometallic compound and the LUMO energy level of the third compound may be in a range of about 0.1 eV or more to about 1.0 eV or less, an absolute value of a difference between the HOMO energy level of the organometallic compound and the HOMO energy level of the second compound may be 1.25 eV or less (e.g., about 0.2 eV or more to about 1.25 eV or less), and/or an absolute value of a difference between the HOMO energy level of the organometallic compound and the HOMO energy level of the third compound may be about 1.25 eV or less (e.g., about 0.2 eV or more to about 1.25 eV or less).

When the relationships between the LUMO energy level and HOMO energy level satisfy the aforementioned conditions, a balance between holes and electrons injected into the emission layer may be achieved.

The light-emitting device may have a structure of a first embodiment or a second embodiment.

### First Embodiment

According to the first embodiment, the emission layer of the interlayer in the light-emitting device may include the organometallic compound, and may further include a host, wherein the organometallic compound and the host may be different from each other, and the emission layer may be to emit phosphorescence or fluorescence emitted from the organometallic compound. For example, according to the first embodiment, the organometallic compound may be a dopant or an emitter. For example, in some embodiments, the organometallic compound may be a phosphorescent dopant or a phosphorescent emitter.

Phosphorescence or fluorescence emitted from the organometallic compound may be blue light.

In one or more embodiments, the emission layer may further include an auxiliary dopant. The auxiliary dopant may effectively transfer energy to the organometallic compound which serves as a dopant or an emitter, and in this regard, the auxiliary dopant may serve to improve luminescence efficiency of the organometallic compound.

The auxiliary dopant may be different from the organometallic compound and the host.

In one or more embodiments, the auxiliary dopant may be a compound capable of emitting delayed fluorescence.

In one or more embodiments, the auxiliary dopant may be a compound including at least one cyclic group including boron (B) and nitrogen (N) as ring-forming atoms.

### Second Embodiment

According to the second embodiment, the emission layer of the interlayer in the light-emitting device may include the organometallic compound, and may further include a host and a dopant, wherein the organometallic compound, the host, and the dopant may be different from each other, and the emission layer may be to emit phosphorescence or fluorescence (e.g., delayed fluorescence) emitted from the dopant.

In one or more embodiments, the organometallic compound in the second embodiment is not a dopant, and may rather serve as an auxiliary dopant that transfers energy to a dopant (or an emitter).

In one or more embodiments, the organometallic compound in the second embodiment may serve as an emitter, and may also serve as an auxiliary dopant that transfers energy to a dopant (or an emitter).

For example, in some embodiments, phosphorescence or fluorescence emitted from the dopant (or the emitter) in the second embodiment may be blue phosphorescence or blue fluorescence (e.g., blue delayed fluorescence).

The dopant (or the emitter) in the second embodiment may be a phosphorescent dopant material (e.g., the organometallic compound represented by Formula 1, an organometallic compound represented by Formula 401, or a (e.g., any suitable) combination thereof) or any fluorescent dopant material (e.g., a compound represented by Formula 501, a compound represented by Formula 502, a compound represented by Formula 503, or a (e.g., any suitable) combination thereof).

In the first embodiment and the second embodiment, the blue light may be blue light having a maximum emission wavelength (e.g., emission peak wavelength) in a range of about 390 nm to about 500 nm, about 410 nm to about 490 nm, about 430 nm to about 480 nm, about 440 nm to about 475 nm, about 455 nm to about 470 nm, about 430 nm to about 475 nm, about 440 nm to about 475 nm, about 450 nm to about 475 nm, about 430 nm to about 470 nm, about 440 nm to about 470 nm, about 450 nm to about 470 nm, about 430 nm to about 465 nm, about 440 nm to about 465 nm, about 450 nm to about 465 nm, about 430 nm to about 460 nm, about 440 nm to about 460 nm, or about 450 nm to about 460 nm.

The auxiliary dopant in the first embodiment may include, for example, the fourth compound represented by Formula 502 or Formula 503.

In one or more embodiments, the host in the first embodiment and the second embodiment may be any host material (e.g., a compound represented by Formula 301, a compound represented by Formula 301-1, a compound represented by Formula 301-2, or a (e.g., any suitable) combination thereof).

In one or more embodiments, the host in the first embodiment and the second embodiment may be the second compound, the third compound, or a (e.g., any suitable) combination thereof.

In one or more embodiments, the light-emitting device may further include a capping layer arranged outside (e.g., on) the first electrode and/or outside (e.g., on) the second electrode.

In one or more embodiments, the light-emitting device may further include at least one of a first capping layer arranged outside (e.g., on) the first electrode or a second capping layer arranged outside (e.g., on) the second electrode, wherein at least one of the first capping layer or the second capping layer may include the organometallic compound represented by Formula 1. More details on the first capping layer and/or the second capping layer may be referred to the descriptions provided herein.

In one or more embodiments, the light-emitting device may include:
A first capping layer arranged outside (e.g., on) the first electrode and including the organometallic compound represented by Formula 1;
a second capping layer arranged outside (e.g., on) the second electrode and including the organometallic compound represented by Formula 1; or
the first capping layer and the second capping layer.

The wording “(interlayer and/or capping layer) includes an organometallic compound represented by Formula 1” as utilized herein may be understood as “(interlayer and/or capping layer) may include one kind of organometallic compound represented by Formula 1 or two or more different kinds of organometallic compounds, each represented by Formula 1.”

In one or more embodiments, the interlayer and/or the capping layer may include Compound 1 only as the organometallic compound. In this regard, Compound 1 may be present in the emission layer of the light-emitting device. In one or more embodiments, the interlayer may include, as the organometallic compound, Compound 1 and Compound 2. In this regard, Compound 1 and Compound 2 may be present in substantially the same layer (for example, both (e.g., simultaneously) Compound 1 and Compound 2 may be present in the emission layer), or may be present in different layers (for example, Compound 1 may be present in the emission layer, and Compound 2 may be present in the electron transport region).

The term “interlayer” as utilized herein refers to a single layer and/or all of multiple layers between the first electrode and the second electrode of the light-emitting device.

According to one or more embodiments of the present disclosure, an electronic apparatus may include the light-emitting device. In one or more embodiments, the electronic apparatus may further include a thin-film transistor. For example, in some embodiments, the electronic apparatus may further include a thin-film transistor including a source electrode and a drain electrode, wherein the first electrode of the light-emitting device may be electrically connected to the source electrode or the drain electrode. In some embodiments, the electronic apparatus may further include a color filter, a color conversion layer, a touch screen layer, a polarizing layer, or a (e.g., any suitable) combination thereof. More details on the electronic apparatus may be referred to the descriptions provided herein.

According to one or more embodiments of the present disclosure, an electronic equipment may include the light-emitting device.

For example, the electronic equipment may be at least one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, or a signboard.

According to one or more embodiments of the present disclosure, the organometallic compound represented by Formula 1 is provided. Details on Formula 1 may be referred to the descriptions provided herein.

Synthesis methods of the organometallic compound may be recognizable by one of ordinary skill in the art by referring to Synthesis Examples and/or Examples provided herein.

### Description of Formula

In Formula 1, Ar₁ may be a group represented by Formula 1A:

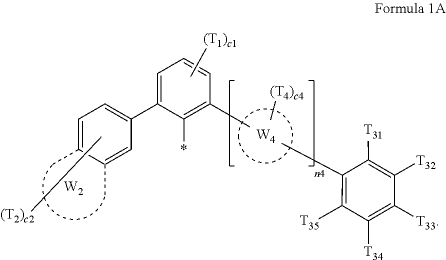

* in Formula 1A indicates a binding site to ring CY₁ in Formula 1. For example, in one or more embodiments, * in Formula 1A may indicate a binding site to a nitrogen atom in ring CY₁ in Formula 1.

For a description of Formula 1A (or a description of Ar₁ in Formula 1), reference may be made to the present disclosure.

In Formula 1, M may be platinum (Pt), palladium (Pd), gold (Au), nickel (Ni), silver (Ag), or copper (Cu).

In one or more embodiments, M may be Pt.

In Formula 1, X₁ to X₄ may each independently be C or N.

In one or more embodiments, X₁ may be C. In some embodiments, X₁ in Formula 1 may be C, and C may be carbon of a carbene moiety.

In one or more embodiments, X₁ in Formula 1 may be N.

In one or more embodiments, X₂ and X₃ may each be C, and X₄ may be N.

In Formula 1, i) a bond between X₁ and M may be a coordinate bond, and ii) any one selected from among a bond between X₂ and M, a bond between X₃ and M, and a bond between X₄ and M may be a coordinate bond, and the other two bonds may each be a covalent bond.

In one or more embodiments, a bond between X₂ and M and a bond between X₃ and M may each be a covalent bond, and a bond between X₄ and M may be a coordinate bond.

In one or more embodiments, X₄ may be N, and a bond between X₄ and M may be a coordinate bond.

In Formula 1 and Formula 1A, ring CY₁ to ring CY₄ and ring W₄ may each independently be a C₃-C₆₀ carbocyclic group or a C₁-C₆₀ heterocyclic group.

For example, in one or more embodiments, ring CY₁ may be a nitrogen-containing C₁-C₆₀ heterocyclic group.

In Formula 1, ring CY₁ may be i) an X₁-containing 5-membered ring, ii) an X₁-containing 5-membered ring condensed with at least one 6-membered ring, or iii) an X₁-containing 6-membered ring.

In one or more embodiments, ring CY₁ in Formula 1 may be i) an X₁-containing 5-membered ring or ii) an X₁-containing 5-membered ring condensed with at least one 6-membered ring. For example, in some embodiments, ring CY₁ may include a 5-membered ring bonded to M in Formula 1 via X₁. Here, the X₁-containing 5-membered ring may be a pyrrole group, a pyrazole group, an imidazole group, a triazole group, an oxazole group, an iso-oxazole group, a thiazole group, an isothiazole group, an oxadiazole group, or a thiadiazole group, and the X₁-containing 6-membered ring and the 6-membered ring which may be optionally condensed to the X₁-containing 5-membered ring may each independently be a benzene group, a pyridine group, or a pyrimidine group.

In one or more embodiments, ring CY₁ may be an X₁-containing 5-membered ring, and the X₁-containing 5-membered ring may be an imidazole group or a triazole group.

In one or more embodiments, ring CY₁ may be an X₁-containing 5-membered ring condensed with at least one 6-membered ring, and the X₁-containing 5-membered ring condensed with at least one 6-membered ring may be a benzimidazole group or an imidazopyridine group.

In one or more embodiments, ring CY₁ may be an imidazole group, a triazole group, a benzimidazole group, a naphthoimidazole group, or an imidazopyridine group.

In one or more embodiments, X₁ may be C, and ring CY₁ may be an imidazole group, a triazole group, a benzimidazole group, a naphthoimidazole group, or an imidazopyridine group.

In one or more embodiments, ring CY₂, ring CY₃, ring CY₄, and ring W₄ may each independently be a benzene group, a pyridine group, a pyrimidine group, a pyrazine group, a pyridazine group, a triazine group, a naphthalene group, a quinoline group, an isoquinoline group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinaphthofuran group, an azadinaphthothiophene group, an azadibenzocarbazole group, an azadibenzofluorene group, or an azadinaphthosilole group.

In one or more embodiments, ring CY₂ may be a benzene group, a pyridine group, a pyrimidine group, a naphthalene group, a dibenzofuran group, a dibenzothiophene group, a carbazole group, a fluorene group, or a dibenzosilole group.

In one or more embodiments, ring CY₃ may be a benzene group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinaphthofuran group, an azadinaphthothiophene group, an azadibenzocarbazole group, an azadibenzofluorene group, or an azadinaphthosilole group.

In one or more embodiments, ring CY₃ may be a carbazole group, a benzocarbazole group, a dibenzocarbazole group, an azacarbazole group, an azabenzocarbazole group, or an azadibenzocarbazole group.

In one or more embodiments, ring CY₄ may be a pyridine group, a pyrimidine group, a pyrazine group, a pyridazine group, a triazine group, a quinoline group, or an isoquinoline group.

In one or more embodiments, ring W₄ may be a benzene group.

In Formula 1A, ring W₂ may be a saturated C₃-C₈ carbocyclic group. For example, in one or more embodiments, ring W₂ may be a cyclopentane group, a cyclohexane group, a cycloheptane group, or a cyclooctane group.

In Formula 1A, n4 may be 0, 1, or 2. When n4 is 0, a group represented by

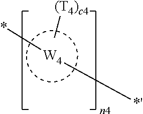

in Formula 1A may be a single bond.

In one or more embodiments, n4 in Formula 1A may be 0 or 1.

In Formula 1, X₅₁ may be a single bond, *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′, *—O—*′, *—C(═O)—*′, *—S(═O)—*′, *—S(═O)₂—*′, *—C(Z₅₁ₐ)=*′, *═C(Z₅₁ₐ)—*′, *—C(Z₅₁ₐ)═C(Z_{51b})—*′, *—C(═S)—*′, or *—C≡C—*′. Z₅₁ₐ and Z_{51b} may each be the same as described herein. Z₅₁ₐ and Z_{51b} may optionally be bonded to each other to form (or provide) a C₃-C₆₀ carbocyclic group unsubstituted or substituted with at least one R₁₀ₐ or a C₁-C₆₀ heterocyclic group unsubstituted or substituted with at least one R₁₀ₐ.

For example, in some embodiments, X₅₁ may be *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′, or *—O—*′.

In Formula 1, X₅₂ may be single bond, *N(Z₅₂ₐ)—*, *—B(Z₅₂ₐ)—*′, *—P(Z₅₂ₐ)—*′, * C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′, *—O—*′, *—C(═O)—*′, *—S(═O)—*′, *—S(═O)₂—*′, *—C(Z₅₂ₐ)=*′, *═C(Z₅₂ₐ)—*′, *—C(Z₅₂ₐ)═C(Z_{52b})—*′, *—C(═S)—*′, or *—C≡C—*′. Z₅₂ₐ and Z_{52b} may each be the same as described herein. Z₅₂ₐ and Z_{52b} may optionally be bonded to each other to form (or provide) a C₃-C₆₀ carbocyclic group unsubstituted or substituted with at least one R₁₀ₐ or a C₁-C₆₀ heterocyclic group unsubstituted or substituted with at least one R₁₀ₐ.

In some embodiments, in Formula 1, X₅₂ may be a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′, or *—O—*′.

In one or more embodiments, in Formula 1,
i) X₅₂ may be a single bond, and a group represented by

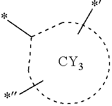

in Formula 1 may be a group represented by Formula CY3A or CY3B,
ii) X₅₂ may not be a single bond, and a group represented by

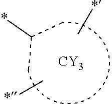

in Formula 1 may be a group represented by Formula CY3C, or
iii) X₅₂ may be *—N(R₅₂ₐ)—*′, and R₅₂ₐ and R₃ may be bonded to form (or provide) a C₃-C₆₀ carbocyclic group unsubstituted or substituted with at least one R₁₀ₐ or a C₁-C₆₀ heterocyclic group unsubstituted or substituted with at least one R₁₀ₐ:

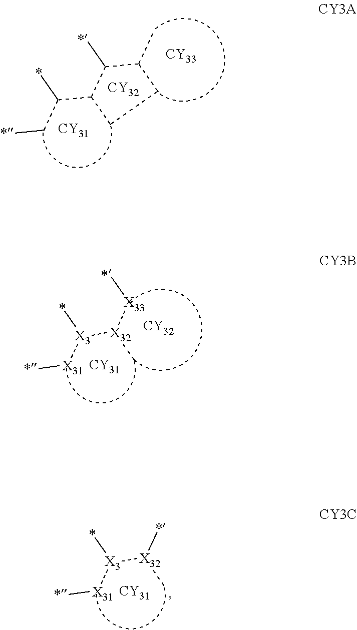

wherein, in Formulae CY3A to CY3C,
X₃ and X₃₁ to X₃₃ may each independently be C or N,
ring CY₃₁, ring CY₃₂, and ring CY₃₃ may each be a C₂-C₈ monocyclic group,
a bond between X₃₁ and X₃, a bond between X₃ and X₃₂, and a bond between X₃₂ and X₃₃ may each be a chemical bond,
*″ indicates a binding site to X₅₁,
* indicates a binding site to M in Formula 1, and
*′ indicates a binding site to X₅₂.

In one or more embodiments, in Formulae CY3A and CY3B, X₃₁, X₃, and X₃₂ may each be C, and X₃₃ may be N.

In one or more embodiments, X₃₁, X₃, and X₃₂ in Formula CY3C may each be C.

In Formula 1, R₁ to R₄, Z₅₁ₐ, Z_{51b}, Z₅₂ₐ, and Z_{52b} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂). Q₁ to Q₃ may each be the same as described herein.

In one or more embodiments, in Formula 1, R₁ to R₄, Z₅₁ₐ, Z_{51b}, Z₅₂ₐ, and Z_{52b} may each independently be:
hydrogen, deuterium, —F, or a cyano group;
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof; or
a C₃-C₁₀ cycloalkyl group, a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof.

In one or more embodiments, R₄ in Formula 1 may be:
hydrogen, deuterium, —F, or a cyano group; or
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof.

In one or more embodiments, R₄ in Formula 1 may be:
hydrogen, deuterium, —F, or a cyano group; or
a C₁-C₂₀ alkyl group unsubstituted or substituted with deuterium, —F, a cyano group, or a (e.g., any suitable) combination thereof.

In Formula 1A, T₁, T₂, T₃₁ to T₃₅, and T₄ may each independently be:
hydrogen, deuterium, —F, or a cyano group;
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof.

In one or more embodiments, in Formula 1A, T₁, T₂, T₃₁ to T₃₅, and T₄ may each independently be:
hydrogen, deuterium, —F, or a cyano group;
a C₁-C₂₀ alkyl group unsubstituted or substituted with deuterium, —F, a cyano group, or a (e.g., any suitable) combination thereof; or
a phenyl group unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof.

In one or more embodiments, Formula 1A may not include (e.g., may exclude) silicon (Si).

The terms “a C₁-C₆₀ alkyl group unsubstituted or substituted with at least one deuterium” and “a C₁-C₂₀ alkyl group unsubstituted or substituted with at least one deuterium” as utilized herein may each be, for example, a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with at least one deuterium.

In one or more embodiments, the terms “a C₁-C₆₀ alkyl group unsubstituted or substituted with at least one deuterium” and “a C₁-C₂₀ alkyl group unsubstituted or substituted with at least one deuterium” as utilized herein may each be —CH₃, —CDH₂, —CD₂H, —CD₃, —CH₂CH₃, —CDHCH₃, —CD₂CH₃, —CH₂CDH₂, —CDHCDH₂, —CD₂CDH₂, —CH₂CD₂H, —CDHCD₂H, —CD₂CD₂H, —CH₂CD₃, —CDHCD₃, —CD₂CD₃, or a group represented by one selected from among Formulae X-1 to X-30:

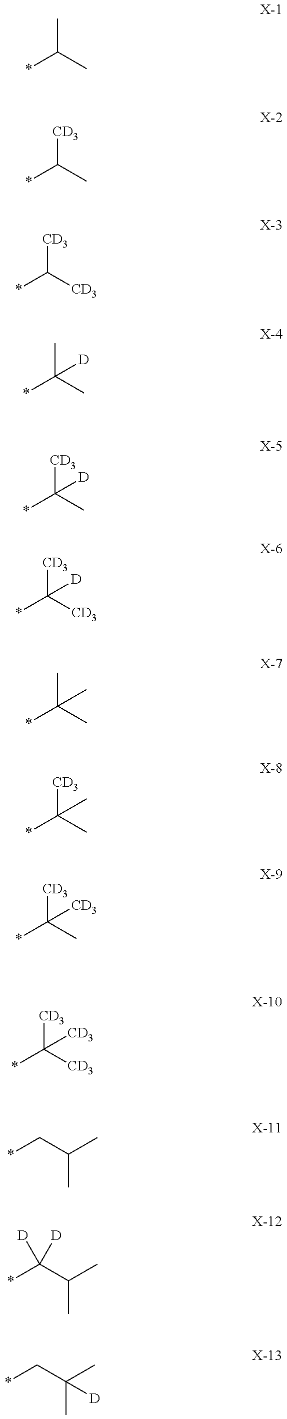

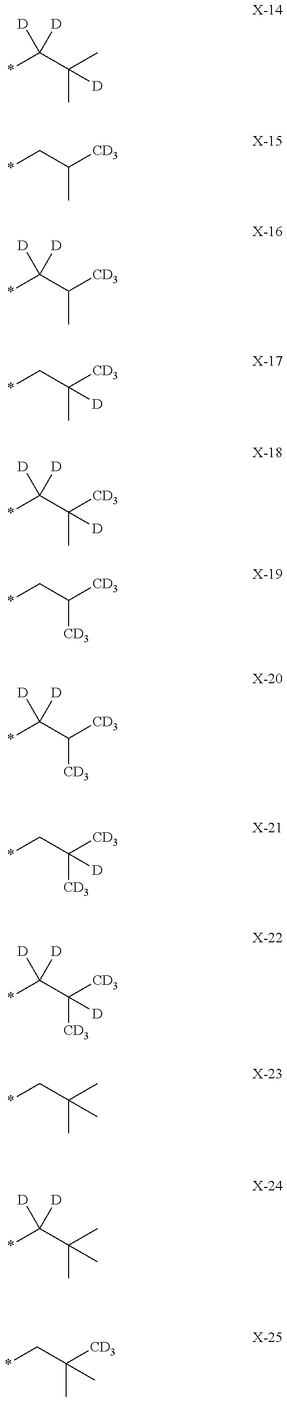

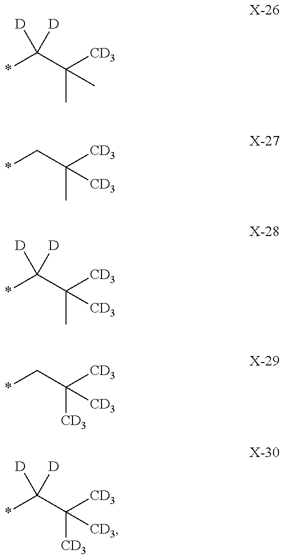

wherein, in Formulae X-1 to X-30, * indicates a binding site to a neighboring atom.

The term “a deuterated C₁-C₆₀ alkyl group”, “a C₁-C₆₀ alkyl group substituted with (at least one) deuterium”, “a deuterated C₁-C₂₀ alkyl group”, or “a C₁-C₂₀ alkyl group substituted with (at least one) deuterium” as utilized herein may refer to a group in which at least one hydrogen in a linear or branched C₁-C₆₀ alkyl group (or a linear or branched C₁-C₂₀ alkyl group) is substituted with deuterium, and non-limiting examples thereof may be a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each substituted with at least one deuterium (e.g., —CDH₂, —CD₂H, —CD₃, —CDHCH₃, —CD₂CH₃, —CH₂CDH₂, —CDHCDH₂, —CD₂CDH₂, —CH₂CD₂H, —CDHCD₂H, —CD₂CD₂H, —CH₂CD₃, —CDHCD₃, —CD₂CD₃, or a group represented by one selected from among Formulae X-2 to X-6, X-8 to X-10, X-12 to X-22, and X-24 to X-30).

In Formulae 1 and 1A, a1, a2, a3, a4, c1, c2, and c4 indicate the number of R₁(s), R₂(s), R₃(s), R₄(s), T₁(s), T₂(s), and T₄(s), respectively, wherein a1 to a4 may each independently be an integer from 0 to 10 (e.g., an integer from 0 to 6), c1 may be an integer from 1 to 3, c2 may be an integer from 1 to 15, and c4 may be an integer from 1 to 10. When a1 is 2 or more, two or more of R₁(s) may be identical to or different from each other, when a2 is 2 or more, two or more of R₂(s) may be identical to or different from each other, when a3 is 2 or more, two or more of R₃(s) may be identical to or different from each other, when a4 is 2 or more, two or more of R₄(s) may be identical to or different from each other, when c1 is 2 or more, two or more of T₁(s) may be identical to or different from each other, when c2 is 2 or more, two or more of T₂(s) may be identical to or different from each other, and when c4 is 2 or more, two or more of T₄(s) may be identical to or different from each other.

Formula 1A (or Formula 1) may satisfy at least one selected from among Conditions A and B:

### Condition A

T₃₁ and T₃₅ are different from each other; and

### Condition B

T₃₂ and T₃₄ are different from each other.

In one or more embodiments, Formula 1A (or Formula 1) may satisfy Condition A, and may further satisfy one selected from among Conditions A-1 to A-3:

### Condition A-1

T₃₁ is hydrogen, deuterium, or —F,
T₃₅ is:
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof;

### Condition A-2

T₃₁ and T₃₅ are different from each other, and
T₃₁ and T₃₅ may each independently be a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof; and

### Condition A-3

T₃₁ is a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof, and
T₃₅ is a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof.

In one or more embodiments, Formula 1A (or Formula 1) may satisfy Condition B, and may further satisfy one of Conditions B-1 to B-3:

### Condition B-1

T₃₂ is hydrogen, deuterium, or —F,
T₃₄ is:
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof;

### Condition B-2

T₃₂ and T₃₄ are different from each other, and
T₃₂ and T₃₄ may each independently be a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof, and

### Condition B-3

T₃₂ is a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof, and
T₃₄ is a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof.

In one or more embodiments, Formula 1A (or Formula 1) may satisfy Conditions A and/or B, and may further satisfy one selected from among Conditions A-1 to A-3 and one selected from among Conditions B-1 to B-3.

In one or more embodiments, the group represented by Formula 1A may be one selected from among groups represented by Formulae 1A(1) to 1A(4):

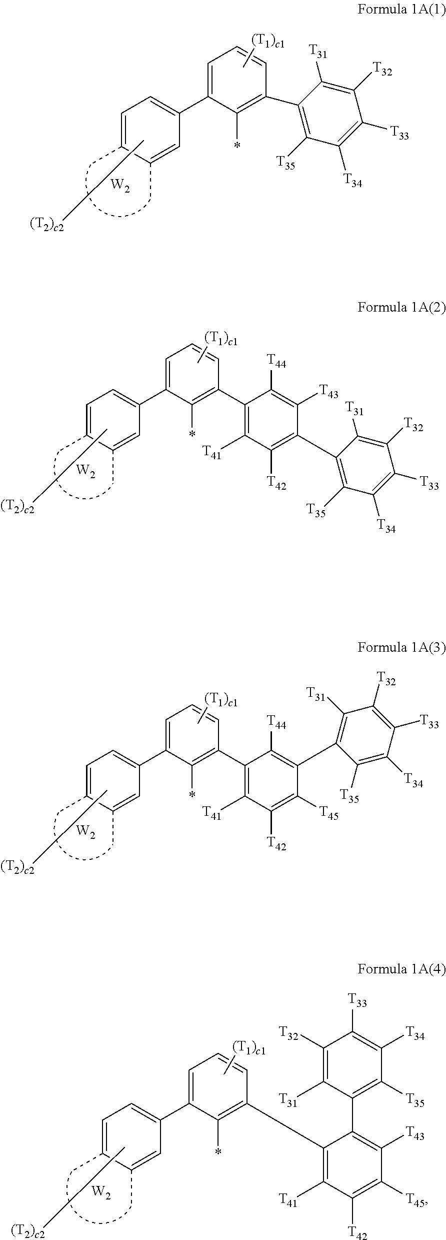

wherein, in Formulae 1A(1) to 1A(4),
* indicates a binding site to ring CY₁ in Formula 1,
ring W₂, T₁, T₂, T₃₁ to T₃₅, c1, and c2 may each be the same as described herein, and
T₄₁ to T₄₅ may each independently be the same as described with respect to T₄.

The description of Formula 1A may be applied to each of Formulae 1A(1) to 1A(4).

In one or more embodiments, the group represented by Formula 1A may be a group represented by one selected from among Formulae 5-1 to 5-100:

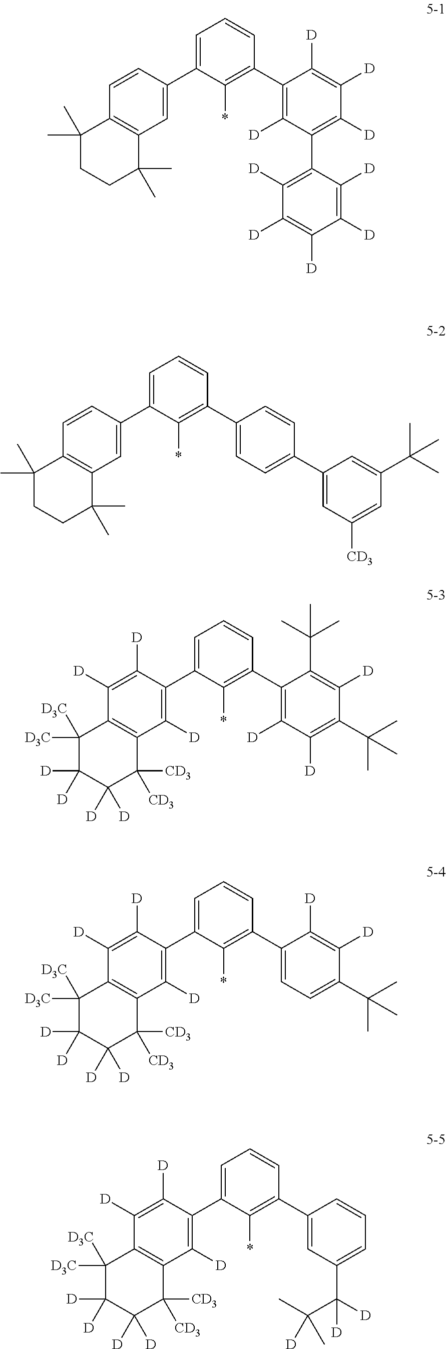

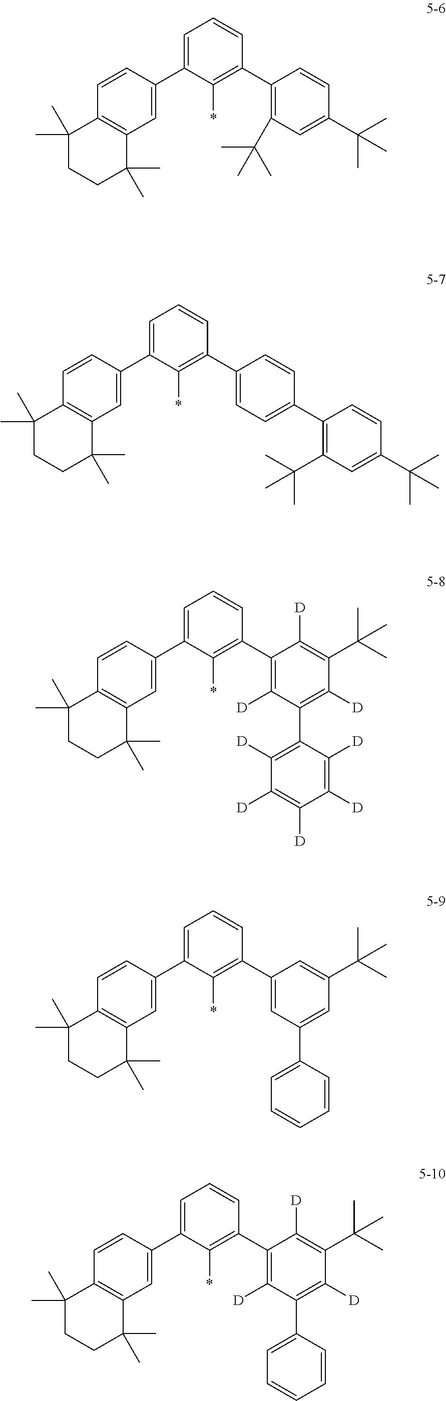

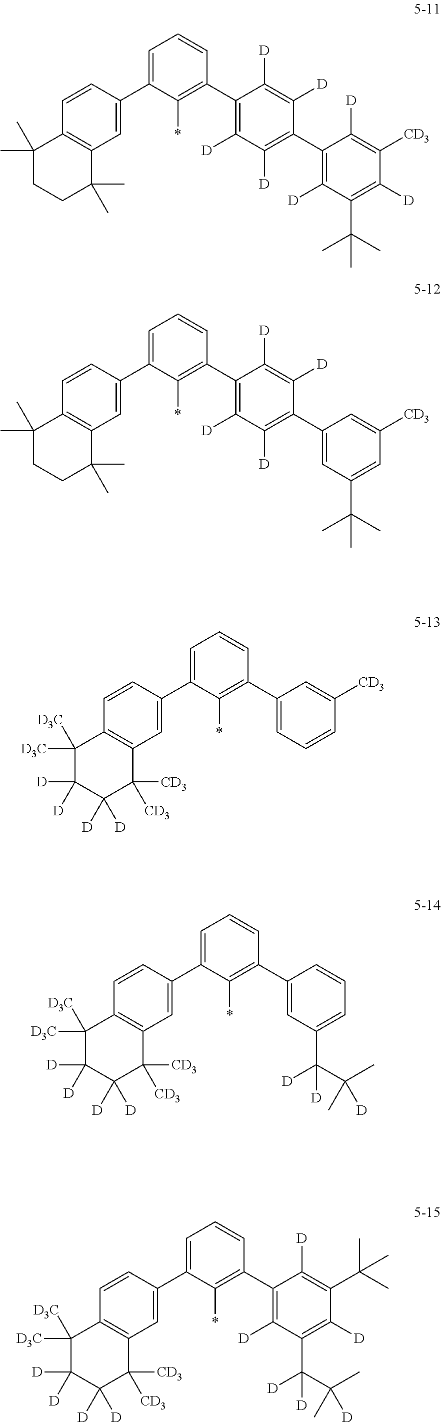

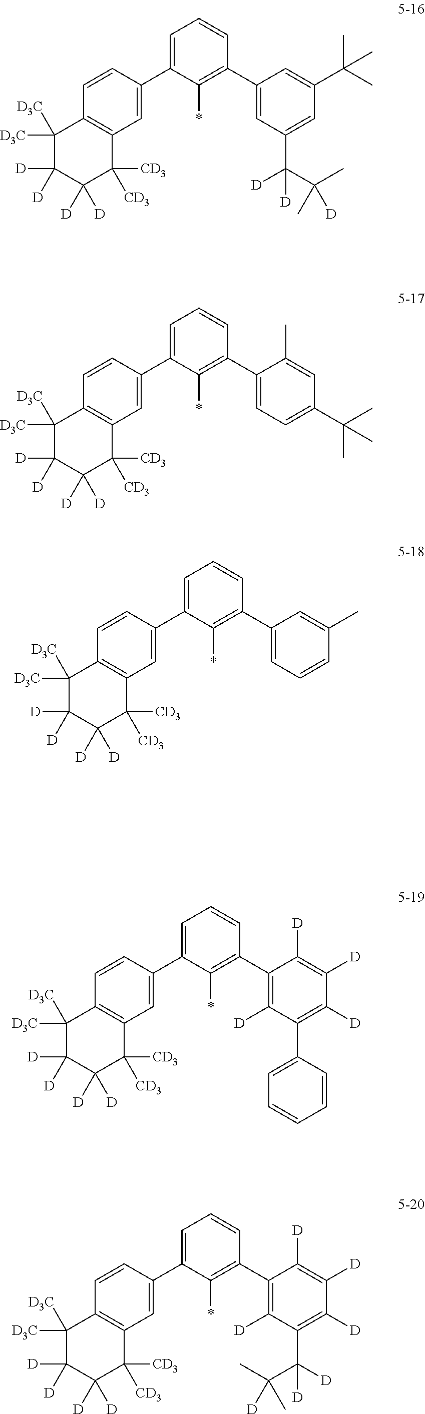

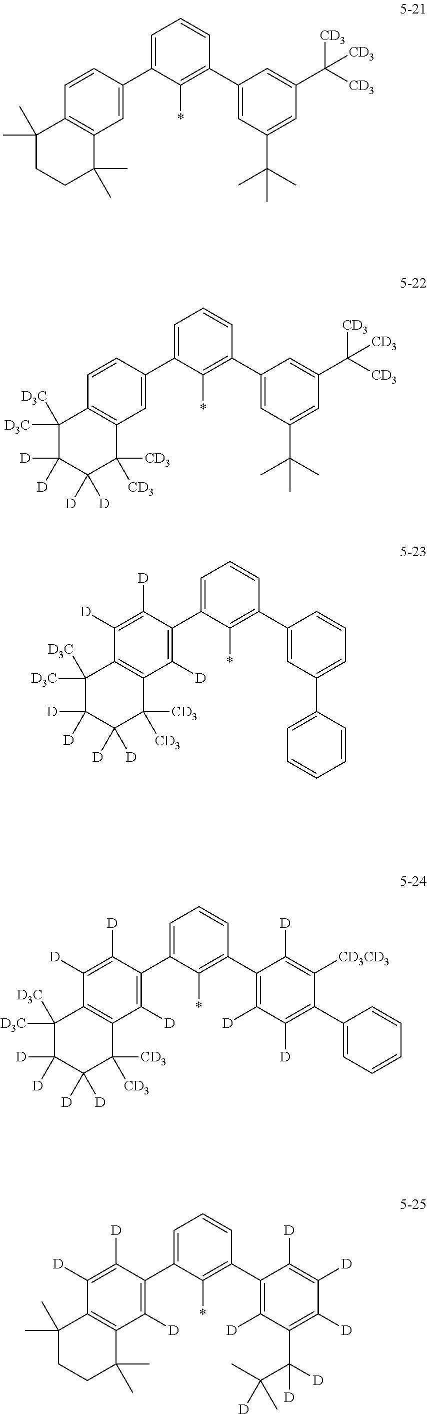

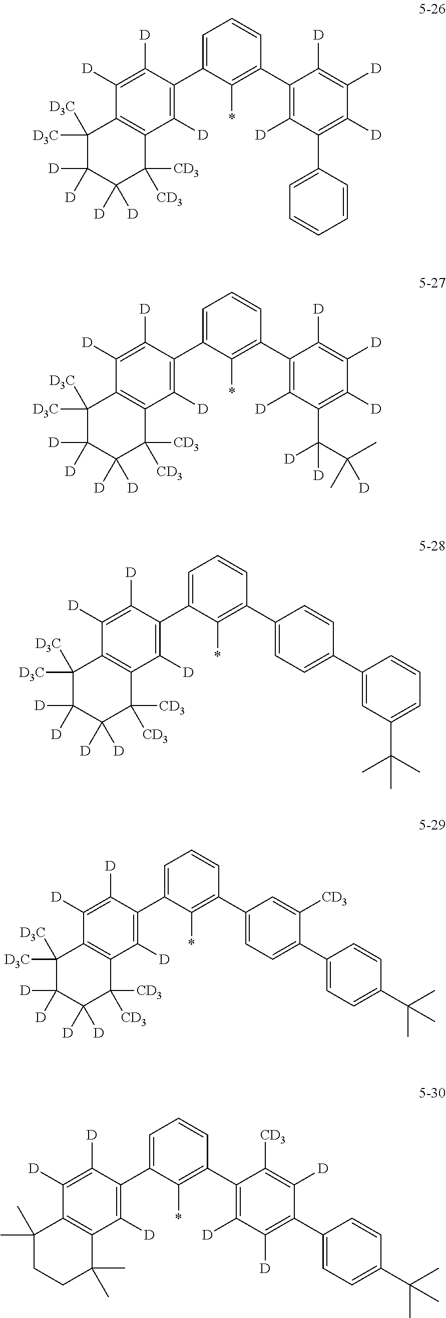

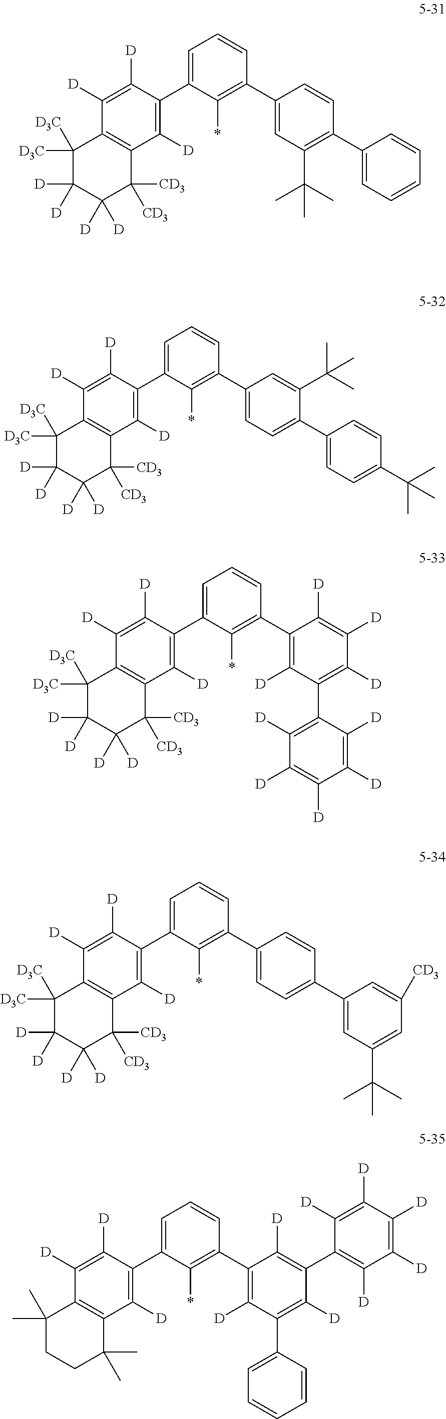

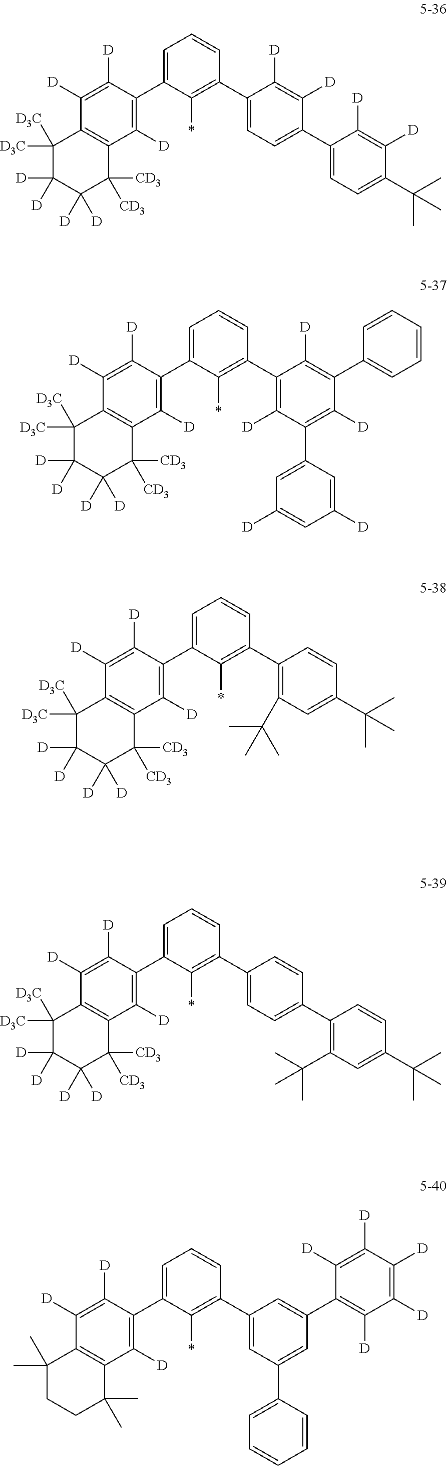

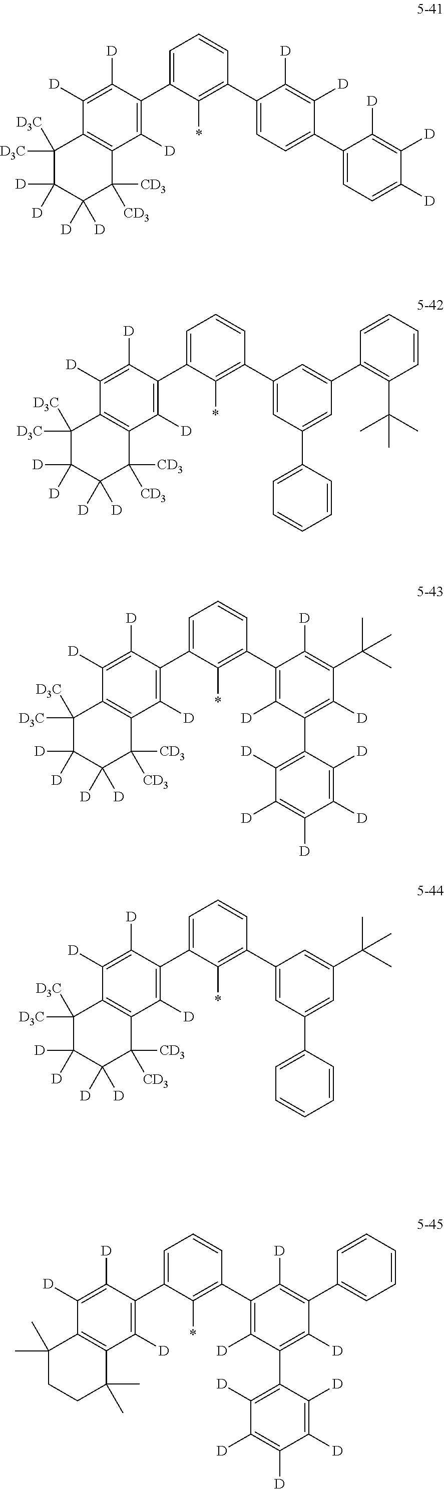

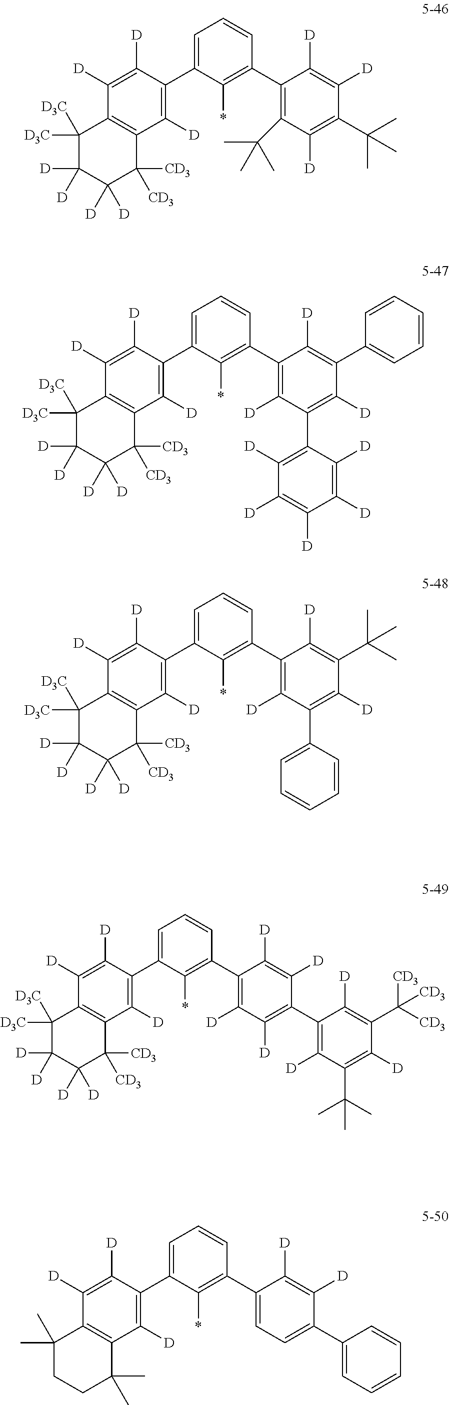

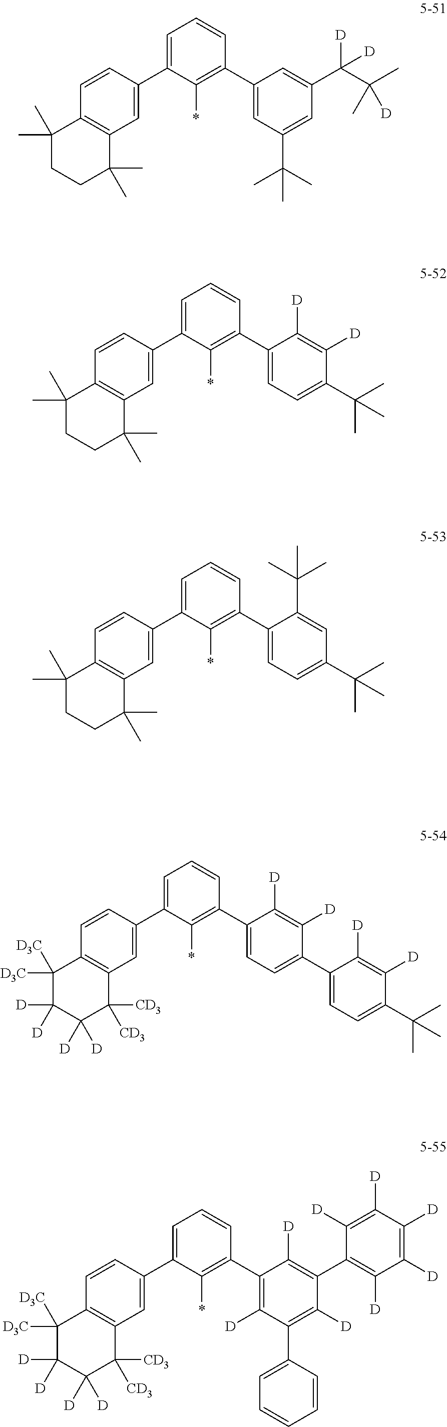

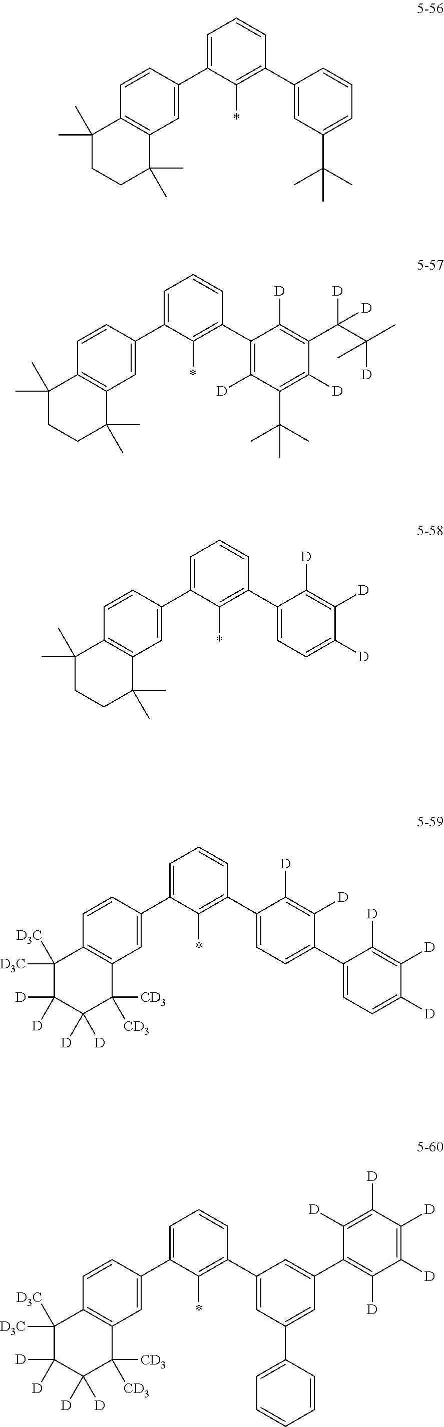

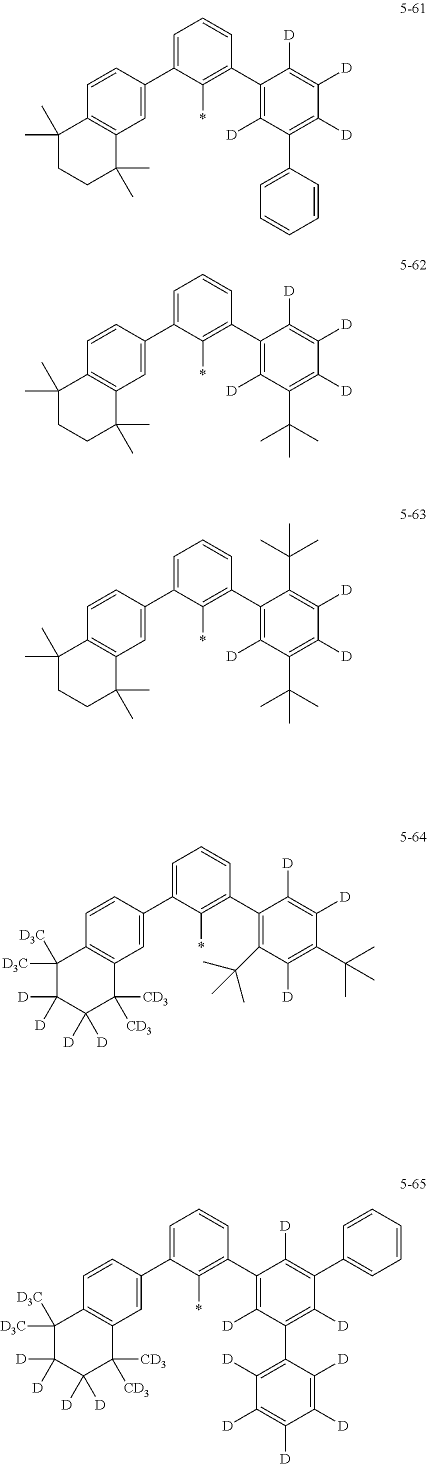

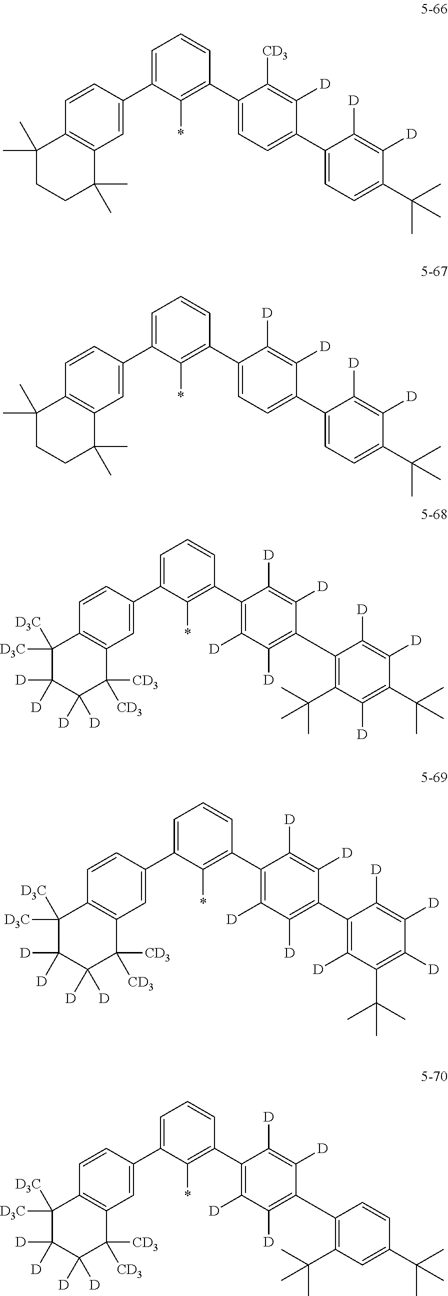

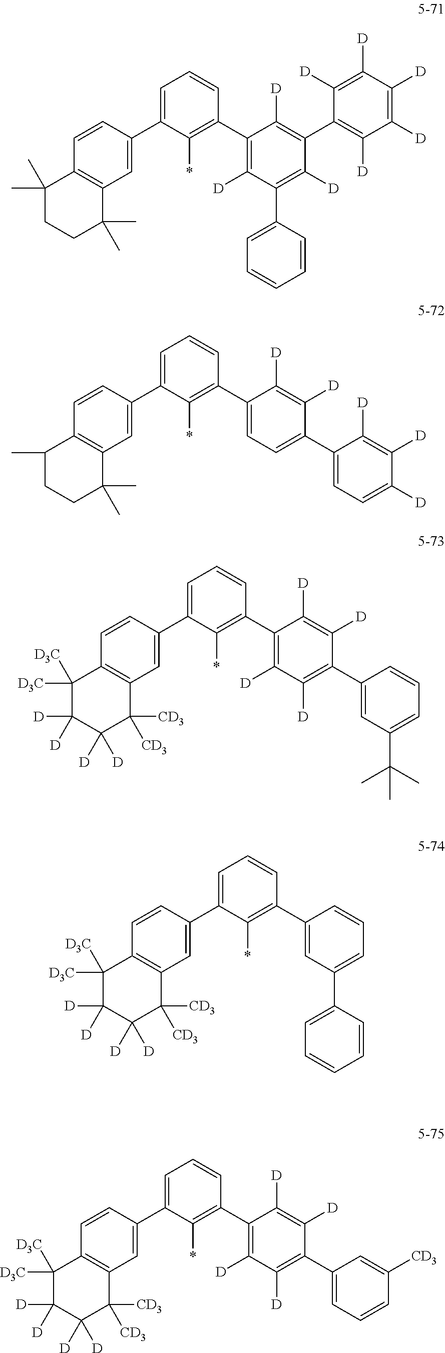

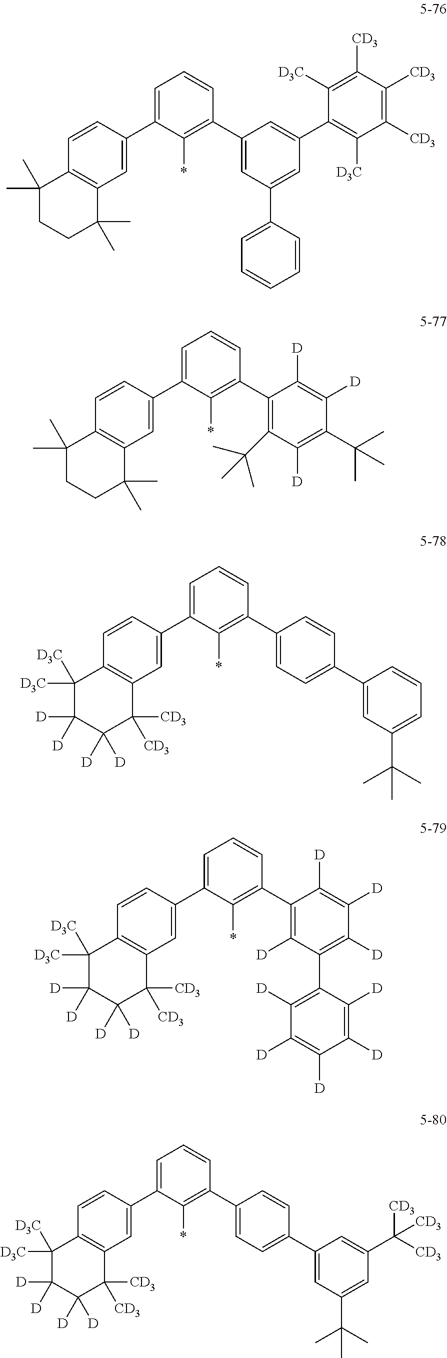

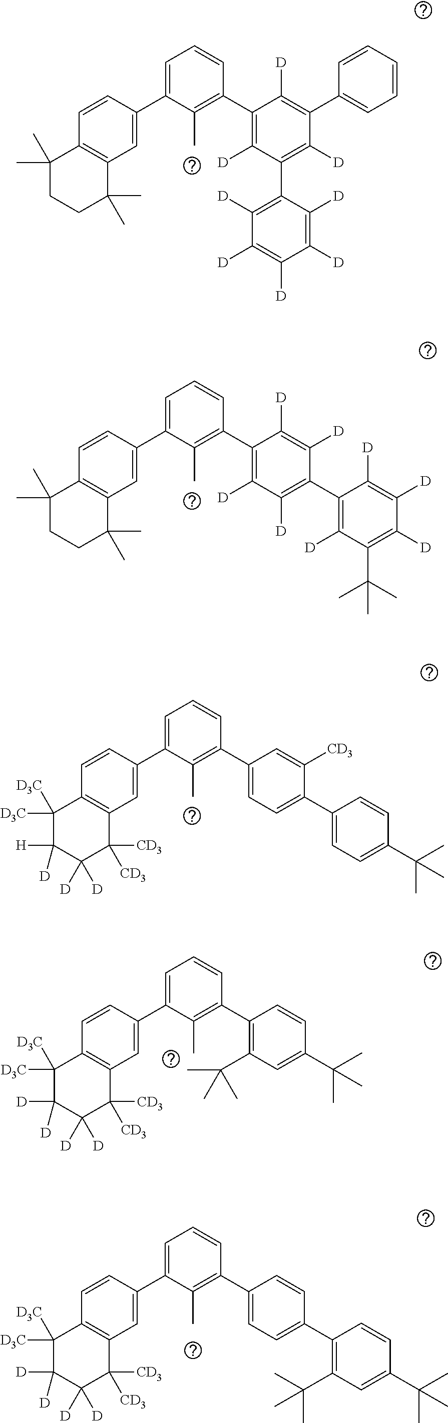

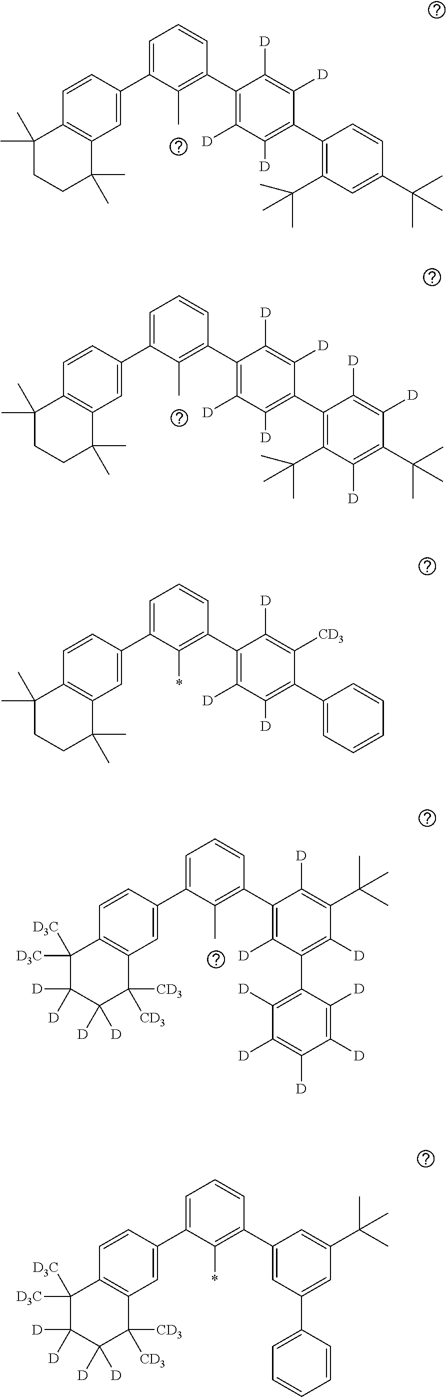

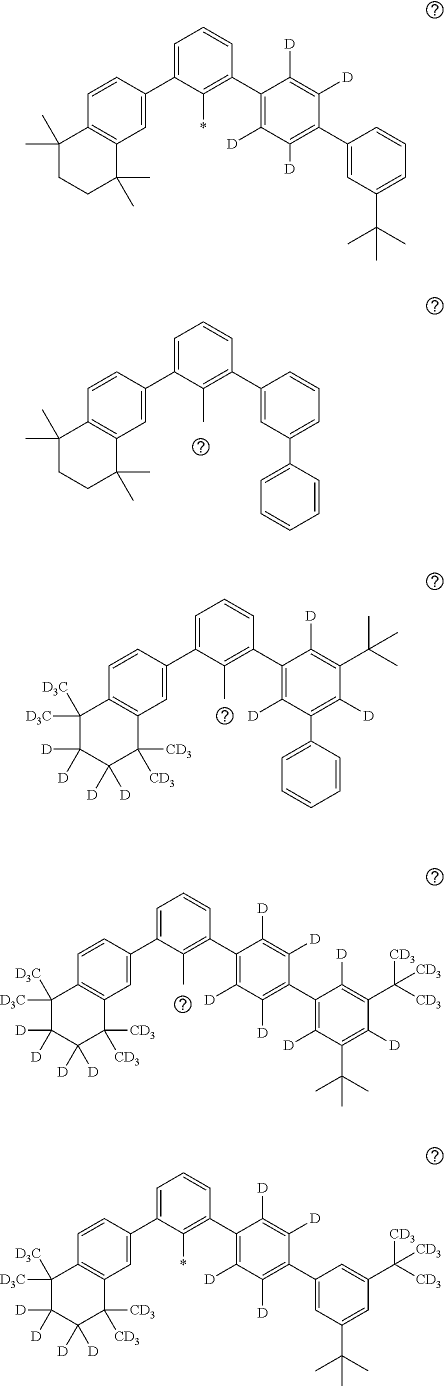

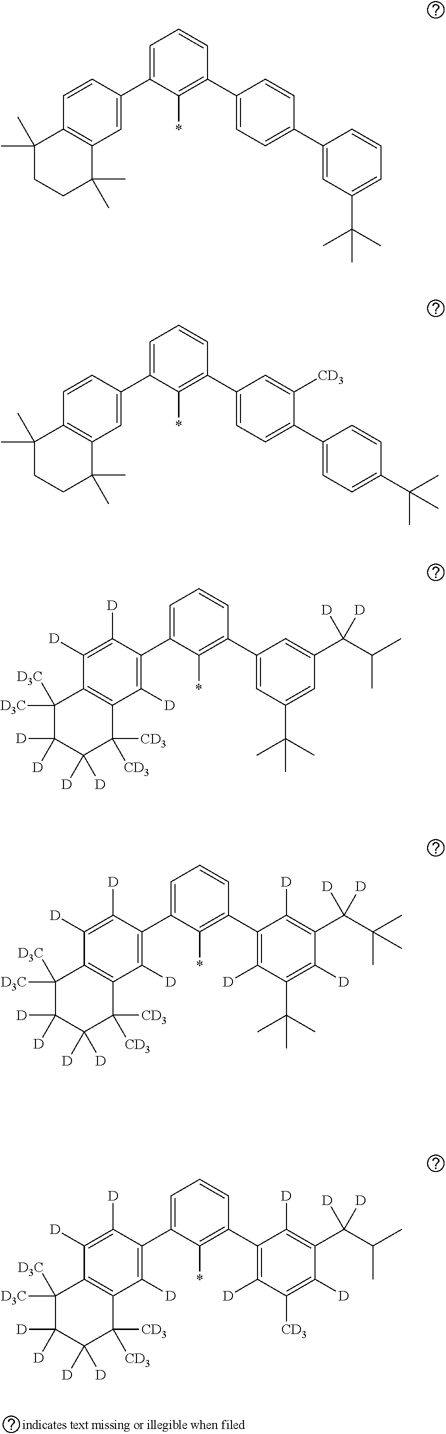

wherein, in Formulae 5-1 to 5-100, * indicates a binding site to ring CY₁ in Formula 1.

In one or more embodiments, the organometallic compound represented by Formula 1 may include at least one deuterium.

For example, in one or more embodiments, R₁ to R₄, Z₅₁ₐ, Z_{51b}, Z₅₂ₐ, and Z_{52b} in Formula 1 and T₁, T₂, T₃₁ to T₃₅, and T₄ in Formula 1A may each independently be deuterium or a deuterium-containing group.

The wording “a deuterium-containing group” as utilized herein refers to any group containing at least one deuterium, and may be additionally substituted with a substituent other than deuterium. For example, the deuterium-containing group may include a C₁-C₂₀ alkyl group, a fluorinated C₁-C₂₀ alkyl group, a phenyl group, a fluorinated phenyl group, a (C₁-C₂₀ alkyl)phenyl group, a biphenyl group, a fluorinated biphenyl group, a (C₁-C₂₀ alkyl)biphenyl group, a C₃-C₁₀ cycloalkyl group, a naphthyl group, a carbazolyl group, a dibenzofuranyl group, or a dibenzothiophenyl group, each substituted with at least one deuterium (e.g., —CH₂D, —CHD₂, —CD₃, —C₆D₅, and/or the like).

In Formula 1A, a group represented by

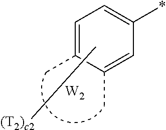

and a group represented by

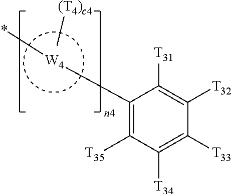

may be different from each other.

In one or more embodiments, Ar₁ (or a group represented by Formula 1A) may include a C₄-C₁₀ alkyl group unsubstituted or substituted with at least one deuterium (e.g., i) an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, and/or the like, each unsubstituted or substituted with at least one deuterium, or ii) groups represented by Formulae X-7 to X-30, and/or the like). Here, the number of the C₄-C₁₀ alkyl group unsubstituted or substituted with at least one deuterium included in Ar₁ may be 2 or more (e.g., 2 to 15).

In Formulae 1 and 1A, two or more selected from among ring CY₁, ring CY₂, ring CY₃, ring CY₄, R₁, R₂, R₃, R₄, Z₅₁ₐ, Z_{51b}, Z₅₂ₐ, Z_{52b}, T₁, T₂, T₃₁, T₃₂, T₃₃, T₃₄, T₃₅, and T₄ may optionally be bonded together to form (or provide) a C₃-C₆₀ carbocyclic group unsubstituted or substituted with at least one R₁₀ₐ or a C₁-C₆₀ heterocyclic group unsubstituted or substituted with at least one R₁₀ₐ.

Unless otherwise stated herein, “*” indicates a binding site to a neighboring atom.

In one or more embodiments, the organometallic compound represented by Formula 1 may be an organometallic compound represented by Formula 1-1 or an organometallic compound represented by Formula 1-2:

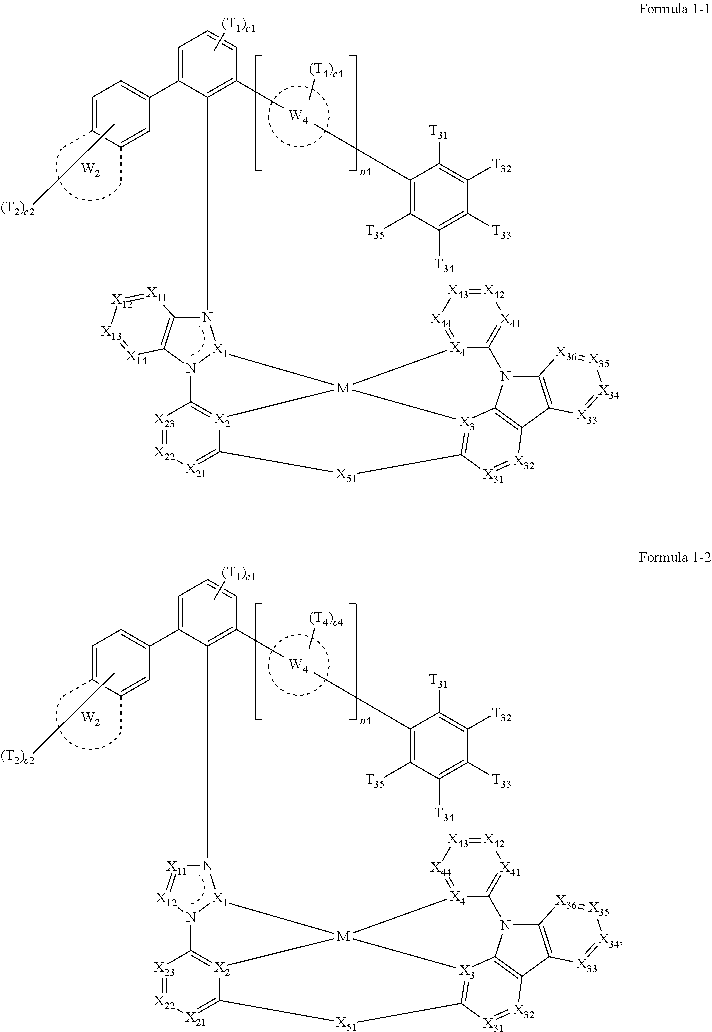

wherein, in Formulae 1-1 and 1-2,
M, X₁ to X₄, ring W₄, ring W₂, n4, X₅₁, T₁, T₂, T₃₁ to T₃₅, T₄, c1, c2, and c4 may each be the same as described herein,
X₁₁ may be C(R₁₁) or N, X₁₂ may be C(R₁₂) or N, X₁₃ may be C(R₁₃) or N, and X₁₄ may be C(R₁₄) or N,
R₁₁ to R₁₄ may each independently be the same as described with respect to R₁, and two or more selected from among R₁₁ to R₁₄ may optionally be bonded together to form (or provide) a C₃-C₆₀ carbocyclic group unsubstituted or substituted with at least one R₁₀ₐ or a C₁-C₆₀ heterocyclic group unsubstituted or substituted with at least one R₁₀ₐ,
X₂₁ may be C(R₂₁) or N, X₂₂ may be C(R₂₂) or N, and X₂₃ may be C(R₂₃) or N,
R₂₁ to R₂₃ may each independently be the same as described with respect to R₂, and two or more selected from among R₂₁ to R₂₃ may optionally be bonded together to form (or provide) a C₃-C₆₀ carbocyclic group unsubstituted or substituted with at least one R₁₀ₐ or a C₁-C₆₀ heterocyclic group unsubstituted or substituted with at least one R₁₀ₐ,
X₃₁ may be C(R₃₁) or N, X₃₂ may be C(R₃₂) or N, X₃₃ may be C(R₃₃) or N, X₃₄ may be C(R₃₄) or N, X₃₅ may be C(R₃₅) or N, and X₃₆ may be C(R₃₆) or N,
R₃₁ to R₃₆ may each independently be the same as described with respect to R₃, and two or more selected from among R₃₁ to R₃₆ may optionally be bonded together to form (or provide) a C₃-C₆₀ carbocyclic group unsubstituted or substituted with at least one R₁₀ₐ or a C₁-C₆₀ heterocyclic group unsubstituted or substituted with at least one R₁₀ₐ,
X₄₁ may be C(R₄₁) or N, X₄₂ may be C(R₄₂) or N, X₄₃ may be C(R₄₃) or N, and X₄₄ may be C(R₄₄) or N,
R₄₁ to R₄₄ may each be the same as described with respect to R₄, and two or more selected from among R₄₁ to R₄₄ may optionally be bonded together to form (or provide) a C₃-C₆₀ carbocyclic group unsubstituted or substituted with at least one R₁₀ₐ or a C₁-C₆₀ heterocyclic group unsubstituted or substituted with at least one R₁₀ₐ, and
Formulae 1-1 and 1-2 may satisfy at least one selected from among Conditions A and B:

### Condition A

T₃₁ and T₃₅ are different from each other; and

### Condition B

T₃₂ and T₃₄ are different from each other.

In Formulae 1-1 and 1-2, a group represented by

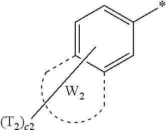

and a group represented by

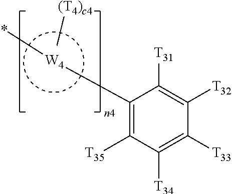

are different from each other, and
* indicates a binding site to a neighboring atom.

All descriptions of Formula 1 in the present disclosure may be applied to Formulae 1-1 and 1-2.

All descriptions of Ar₁ and Formula 1A in the present disclosure may be applied to a group represented by

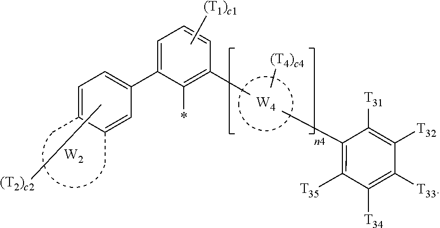

### in Formulae 1-1 and 1-2.

In one or more embodiments, in Formulae 1-1 and 1-2, X₄₃ may be C(R₄₃), and R₄₃ may be:
hydrogen, deuterium, —F, or a cyano group; or
a C₁-C₂₀ alkyl group unsubstituted or substituted with deuterium, —F, a cyano group, or a (e.g., any suitable) combination thereof.

In one or more embodiments, in Formulae 1-1 and 1-2, X₄₂ may be C(R₄₂), X₄₃ may be C(R₄₃), and at least one of R₄₂ or R₄₃ may not be hydrogen.

In one or more embodiments, in Formulae 1-1 and 1-2, X₁₁ may be C(R₁₁), X₁₂ may be C(R₁₂), X₁₃ may be C(R₁₃), X₁₄ may be C(R₁₄), X₂₁ may be C(R₂₁), X₂₂ may be C(R₂₂), X₂₃ may be C(R₂₃), X₃₁ may be C(R₃₁), X₃₂ may be C(R₃₂), X₃₃ may be C(R₃₃), X₃₄ may be C(R₃₄), X₃₅ may be C(R₃₅), X₃₆ may be C(R₃₆), X₄₁ may be C(R₄₁), X₄₂ may be C(R₄₂), X₄₃ may be C(R₄₃), and X₄₄ may be C(R₄₄).

Each of Formulae 1-1 and 1-2 may satisfy at least one selected from among Conditions H1 to H4:

### Condition H1

at least one selected from among R₁₁ to R₁₄ in Formula 1-1 is deuterium or a deuterium-containing group, and at least one selected from among R₁₁ and R₁₂ in Formula 1-2 is deuterium or a deuterium-containing group;

### Condition H2

at least one selected from among R₂₁ to R₂₃ is deuterium or a deuterium-containing group;

### Condition H3

at least one selected from among R₃₁ to R₃₆ is deuterium or a deuterium-containing group; and

### Condition H4

at least one selected from among R₄₁ to R₄₄ is deuterium or a deuterium-containing group.

In one or more embodiments, a group represented by

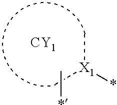

in Formula 1 may be a group represented by one selected from among Formulae CY1-1 to CY1-42:

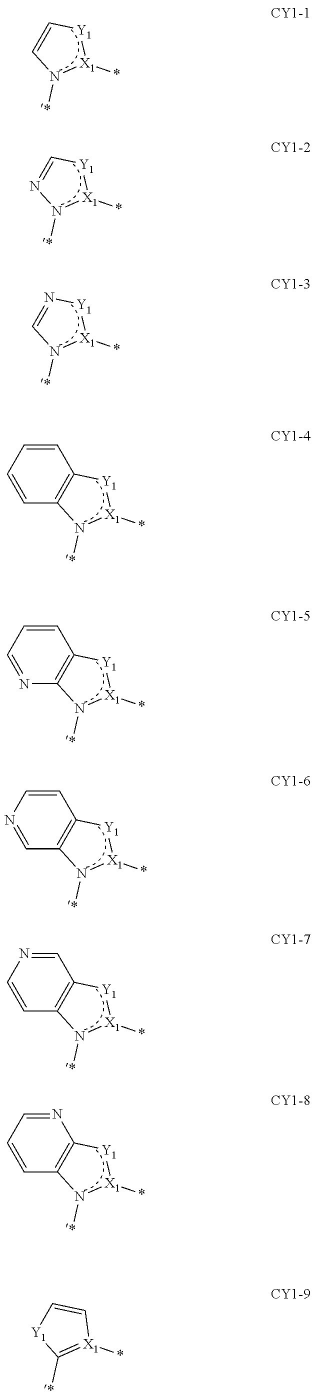

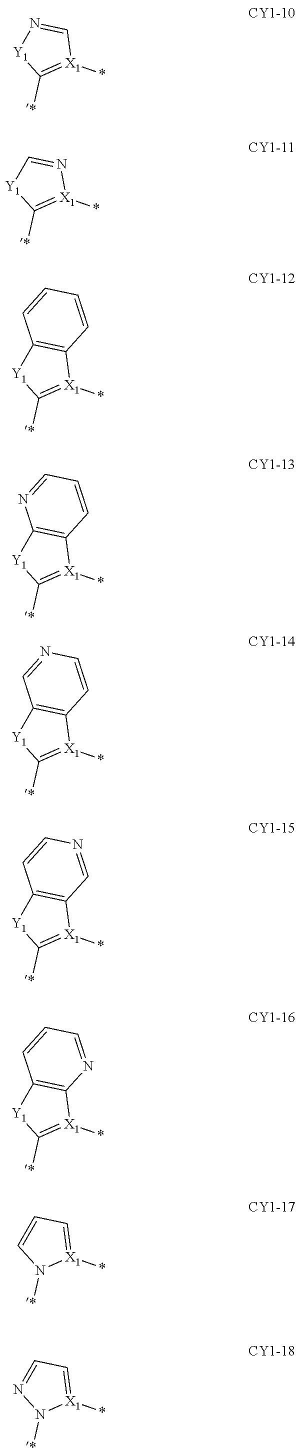

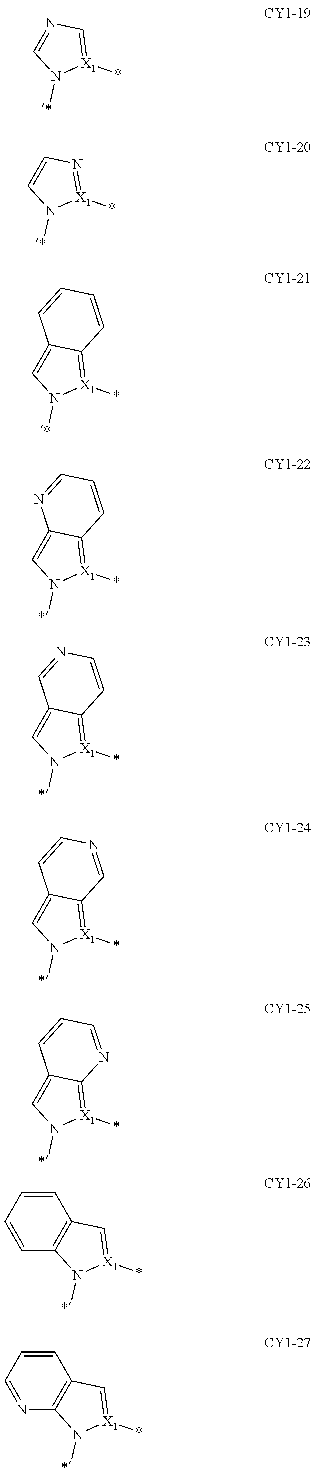

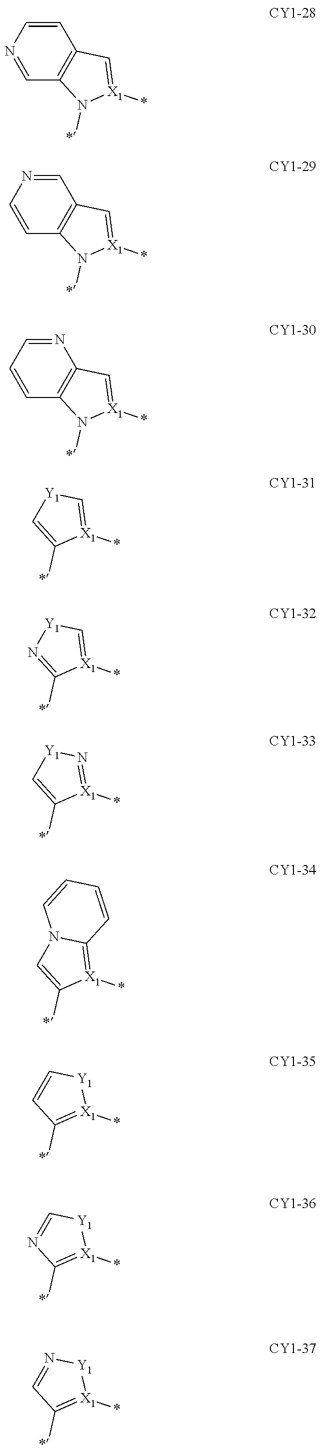

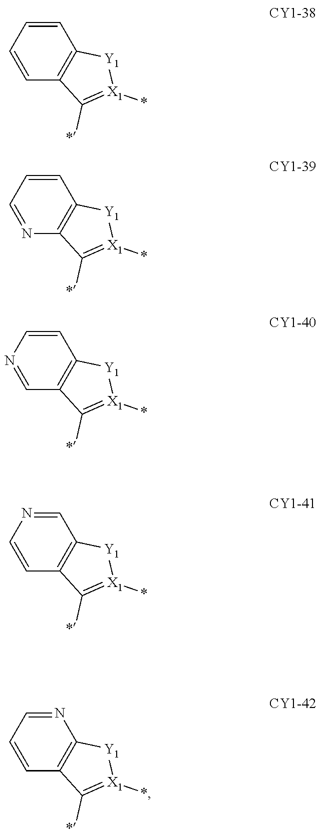

wherein, in Formulae CY1-1 to CY1-42,
X₁ may be the same as described herein,
Y₁ may include O, S, N, C, or Si,
* indicates a binding site to M in Formula 1, and
*′ indicates a binding site to ring CY₂ in Formula 1.

In one or more embodiments, X₁ in Formulae CY1-1 to CY1-8 may be C, and X₁ in Formulae CY1-9 to CY1-42 may be N.

In one or more embodiments, a group represented by

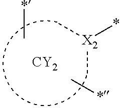

in Formula 1 may be a group represented by one selected from among Formulae CY2-1 to CY2-11:

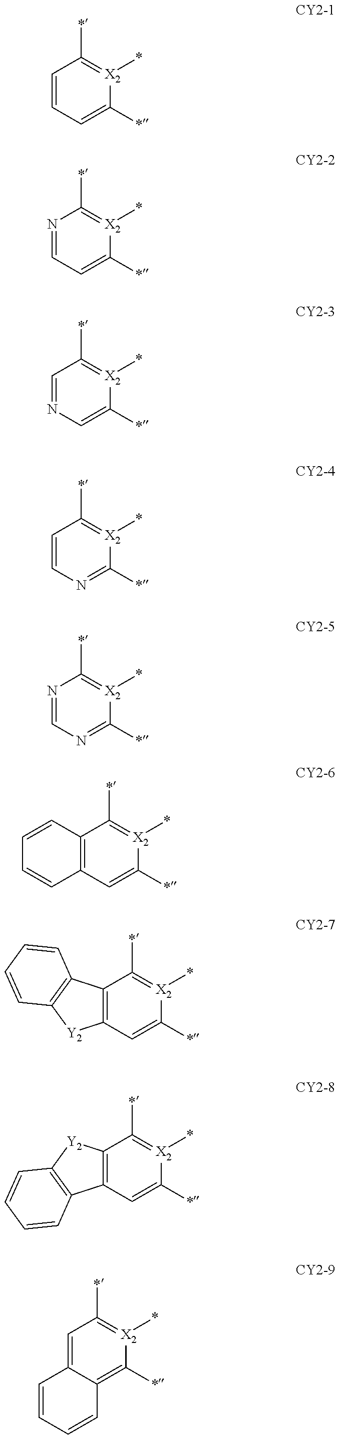

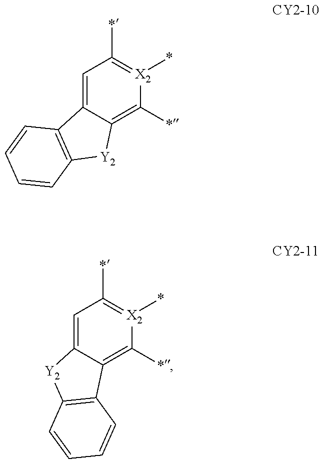

wherein, in Formulae CY2-1 to CY2-11,
X₂ may be the same as described herein,
Y₂ may include O, S, N, C, or Si,
* indicates a binding site to M in Formula 1,
*′ indicates a binding site to ring CY₁ in Formula 1, and
*″ indicates a binding site to X₅₁ in Formula 1.

In one or more embodiments, a group represented by

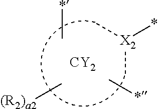

in Formula 1 and a group represented by

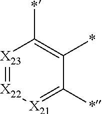

in Formulae 1-1 and 1-2 may each independently be a group represented by one selected from among Formulae CY2(1) to CY2(26):

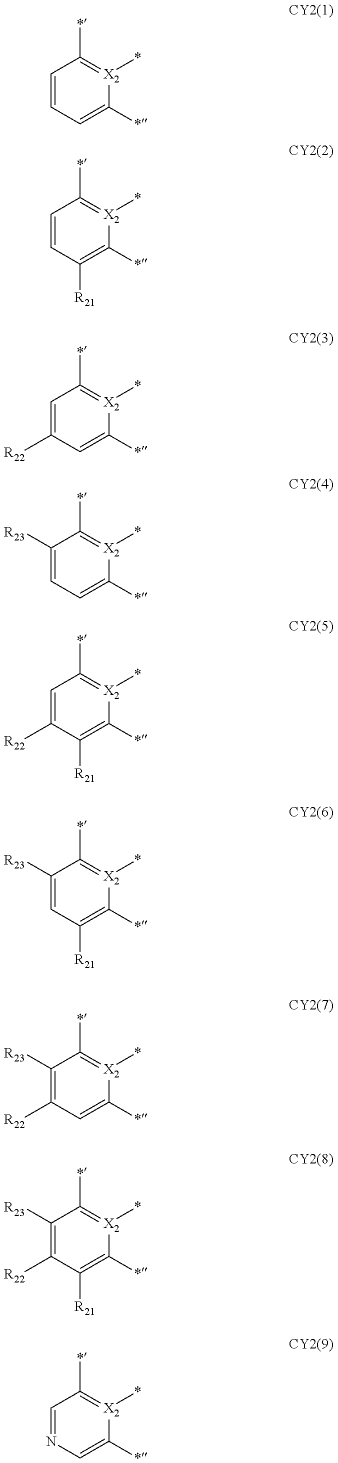

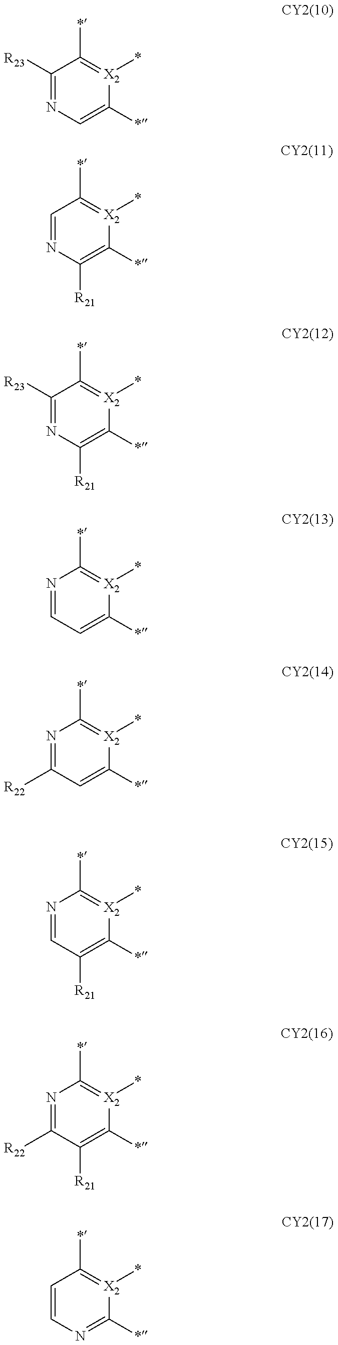

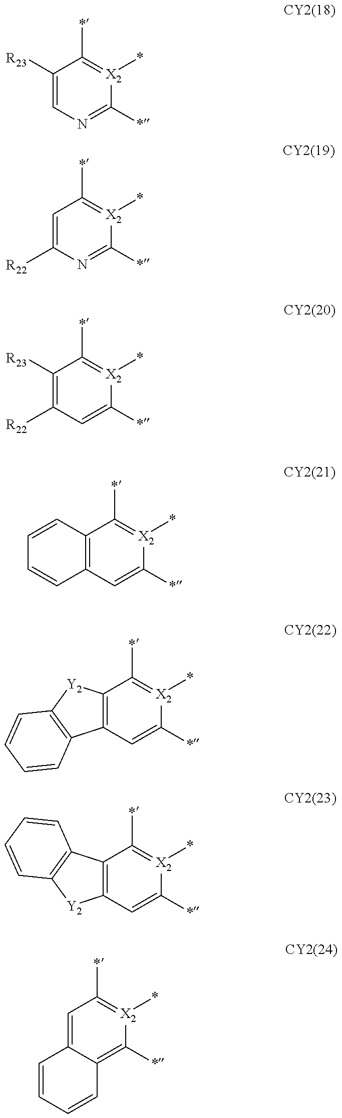

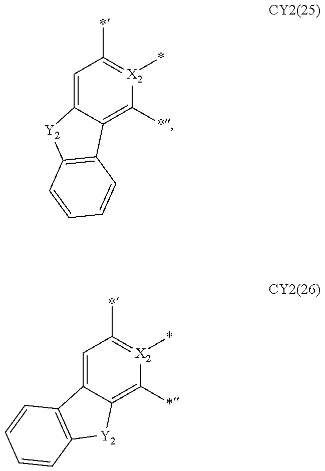

wherein, in Formulae CY2(1) to CY2(26),
X₂ may be the same as described herein,
Y₂ may be O, S, N(R₂₀), C(R₂₀ₐ)(R_{20b}), or Si(R₂₀ₐ)(R_{20b}),
R₂₀, R₂₀ₐ, R_{20b}, and R₂₁ to R₂₃ may each independently be the same as described with respect to R₂, wherein each of R₂₁ to R₂₃ may not be hydrogen,
* indicates a binding site to M in Formula 1,
*′ indicates a binding site to ring CY₁ in Formula 1, and
*″ indicates a binding site to X₅₁ in Formula 1.

In one or more embodiments, a group represented by

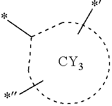

in Formula 1 may be a group represented by one selected from among Formulae CY3-1 to CY3-23:

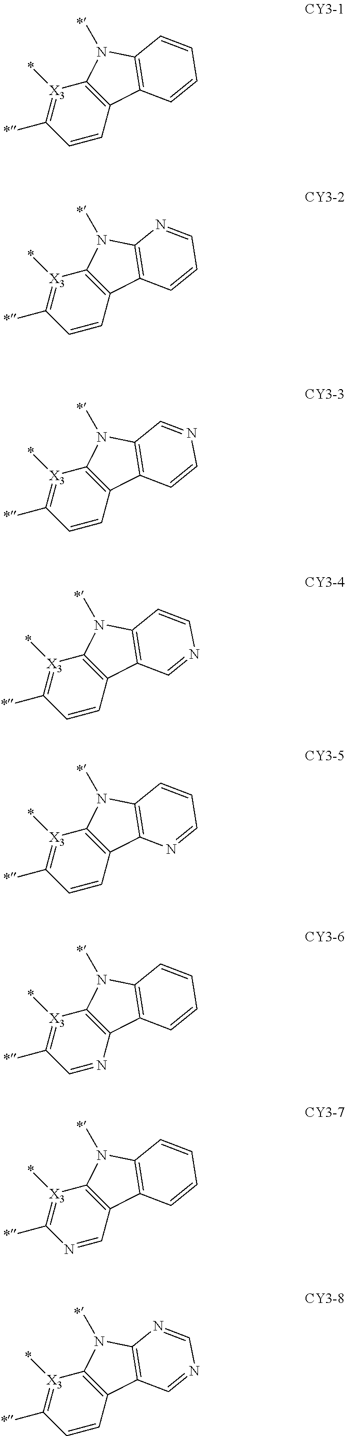

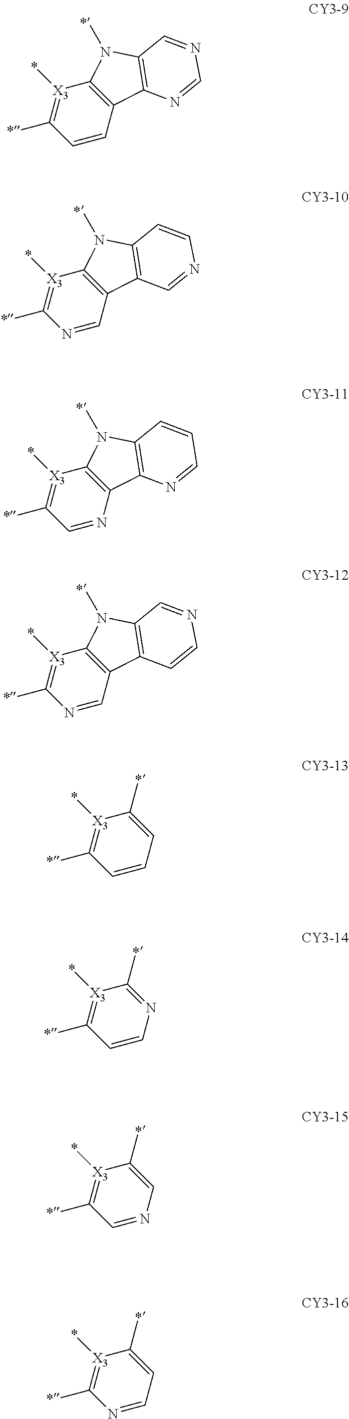

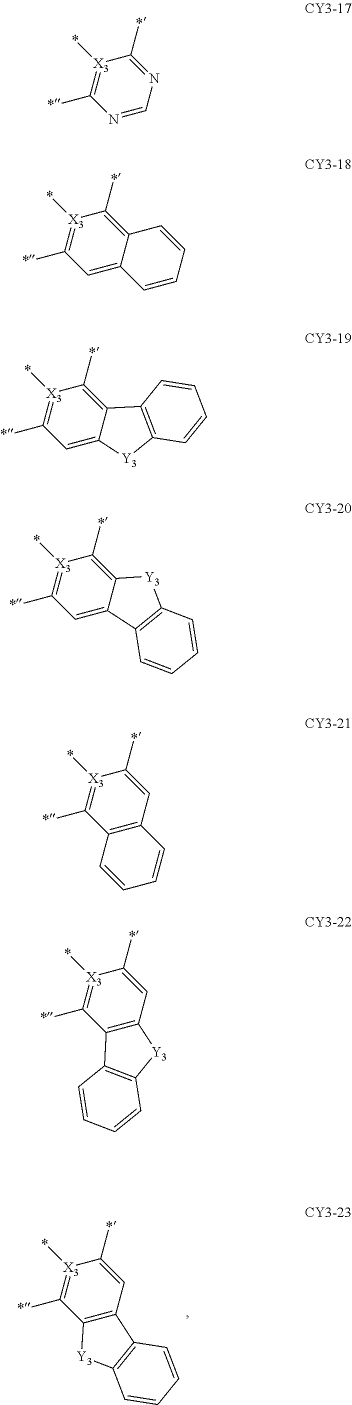

wherein, in Formulae CY3-1 to CY3-23,
X₃ may be the same as described herein,
Y₃ may include O, S, N, C, or Si,
* indicates a binding site to M in Formula 1,
*′ indicates a binding site to X₅₂ in Formula 1, and
*″ indicates a binding site to X₅₁ in Formula 1.

In one or more embodiments, a group represented by

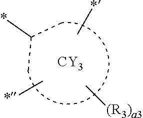

in Formula 1 may be a group represented by one selected from among Formulae CY3(1) to CY3(20), and a group represented by

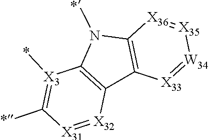

in Formulae 1-1 and 1-2 may be a group represented by one selected from among Formulae CY3(1) to CY3(12):

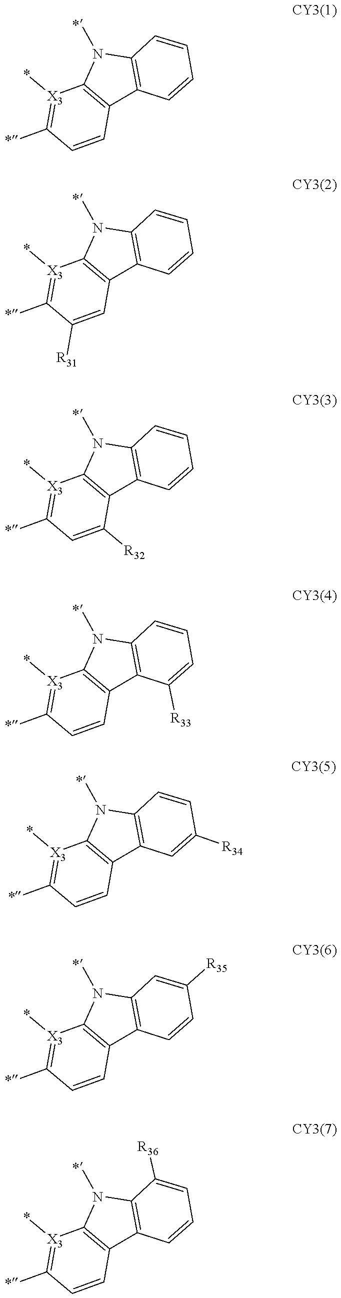

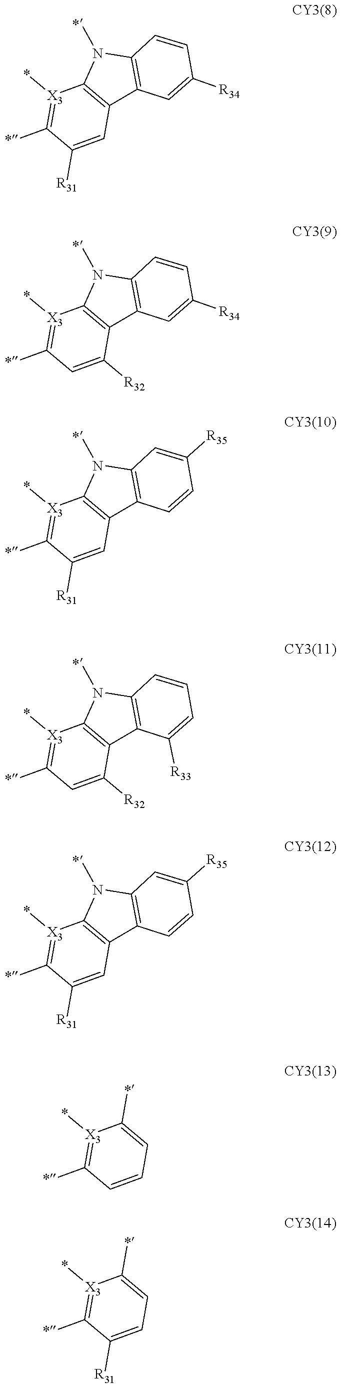

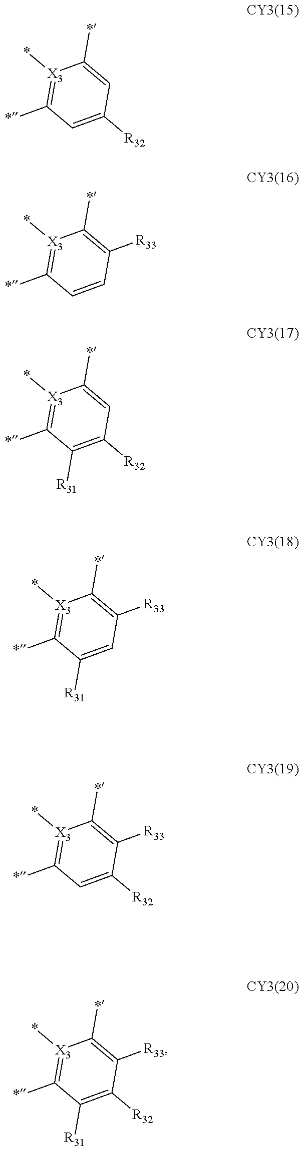

wherein, in Formulae CY3(1) to CY3(20),
X₃ may be the same as described herein,
R₃₁ to R₃₆ may each independently be the same as described with respect to R₃, wherein each of R₃₁ to R₃₆ may not be hydrogen,
* indicates a binding site to M in Formula 1,
*′ indicates a binding site to X₅₂ in Formula 1, and
*″ indicates a binding site to X₅₁ in Formula 1.

In one or more embodiments, a group represented by

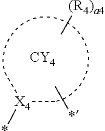

in Formula 1 may be a group represented by one selected from among Formulae CY4(1) to CY4(16):

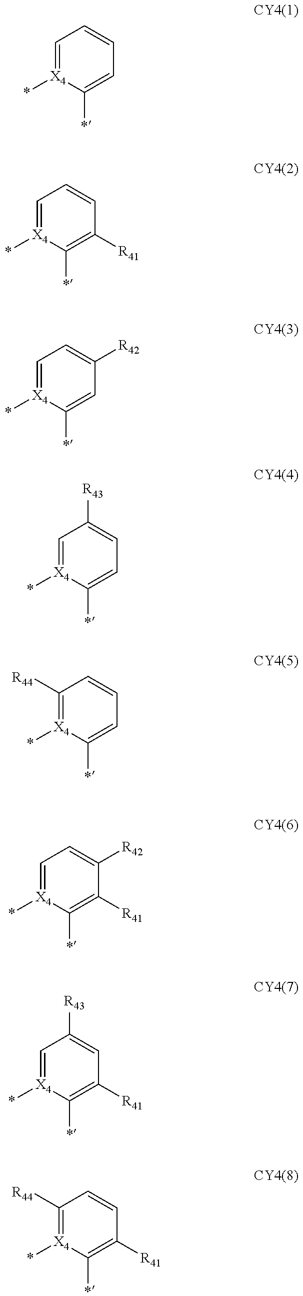

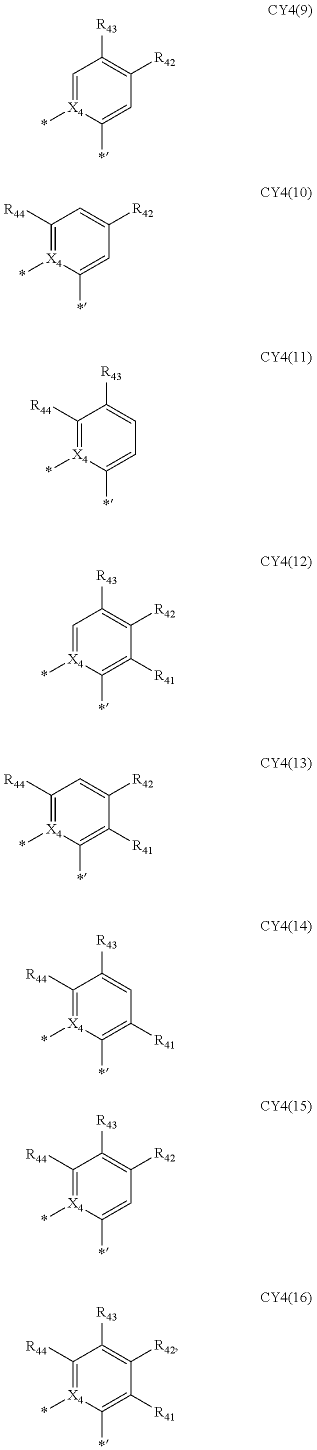

wherein, in Formulae CY4(1) to CY4(16),
X₄ may be the same as described herein,
R₄₁ to R₄₄ may each independently be the same as described with respect to R₄, wherein each of R₄₁ to R₄₄ may not be hydrogen,
* indicates a binding site to M in Formula 1, and
*′ indicates a binding site to X₅₂ in Formula 1.

In Formula 1, Ar₁ may be a group represented by Formula 1A:

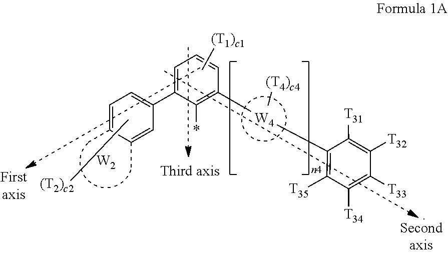

wherein, in Formula 1A, ring W₂ is a non-conjugated “saturated” C₃-C₈ carbocyclic group so that intermolecular interactions of the organometallic compound represented by Formula 1 may be effectively suppressed or reduced.

In one or more embodiments, T₁, T₂, T₃₁ to T₃₅, and T₄ in Formula 1A may each independently be:
hydrogen, deuterium, —F, or a cyano group;
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any suitable) combination thereof. For example, in one or more embodiments, Formula 1A may not include (e.g., may exclude) Si. In this regard, the organometallic compound represented by Formula may have excellent or suitable thermal stability.

Furthermore, in one or more embodiments, Formula 1A may have
i) an asymmetric structure with respect to a first axis due to the group represented by

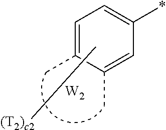

ii) an asymmetric structure with respect to a second axis by satisfying at least one selected from among Conditions A and B, and
iii) an asymmetric structure with respect to a third axis when a group represented by

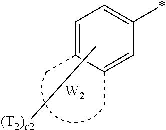

and a group represented by

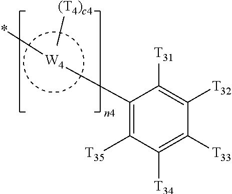

are different from each other.

By including the group represented by 1A that may form (or provide) three distinct asymmetric structures,
1) intermolecular interactions of the organometallic compound represented by Formula 1 may be further suppressed or reduced so that Dexter energy transfer may be effectively suppressed or reduced, and
2) packing effects between molecules of the organometallic compound represented by Formula 1 may be reduced so that sublimation temperatures and deposition temperatures may be lowered.

Accordingly, a light-emitting device including the organometallic compound represented by Formula 1 may have improved luminescence efficiency and improved lifespan.

In one or more embodiments, Formula 1A may further include a C₁-C₂₀ alkyl group unsubstituted or substituted with deuterium. In these embodiments, the asymmetry and bulkiness of Formula 1A may be increased so that a light-emitting device including the organometallic compound may have further improved luminescence efficiency and/or lifespan.

In Formula 2, b51 to b53 indicate the number of L₅₁ to L₅₃, respectively, and may each be an integer from 1 to 5. When b51 is 2 or more, two or more of L₅₁(s) may be identical to or different from each other, when b52 is 2 or more, two or more of L₅₂(s) may be identical to or different from each other, and when b53 is 2 or more, two or more of L₅₃(s) may be identical to or different from each other. In one or more embodiments, b51 to b53 may each independently be 1 or 2.

In one or more embodiments, in Formula 2, L₅₁ to L₅₃ may each independently be:
a single bond; or
a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzoxasiline group, a dibenzothiasiline group, a dibenzodihydroazasiline group, a dibenzodihydrodihydrodisiline group, a dibenzodihydrosiline group, a dibenzodioxin group, a dibenzoxathiin group, a dibenzoxazine group, a dibenzopyran group, a dibenzodithiin group, a dibenzothiazine group, a dibenzothiopyran group, a dibenzocyclohexadiene group, a dibenzodihydropyridine group, or a dibenzodihydropyrazine group, each unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or a (e.g., any suitable) combination thereof, and
Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In an embodiment, in Formula 2, a bond between L₅₁ and R₅₁, a bond between L₅₂ and R₅₂, a bond between L₅₃ and R₅₃, a bond between two L₅₁(s), a bond between two L₅₂(s), a bond between two L₅₃(s), a bond between L₅₁ and carbon between X₅₄ and X₅₅ in Formula 2, a bond between L₅₂ and carbon between X₅₄ and X₅₆ in Formula 2, and a bond between L₅₃ and carbon between X₅₅ and X₅₆ in Formula 2 may each be a “carbon-carbon single bond.”

In Formula 2, X₅₄ may be N or C(R₅₄), X₅₅ may be N or C(R₅₅), and X₅₆ may be N or C(R₅₆), wherein at least one selected from among X₅₄ to X₅₆ may be N. R₅₄ to R₅₆ may each be the same as described herein. In one or more embodiments, two or three selected from among X₅₄ to X₅₆ may each be N.

R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} in the present disclosure may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂). Q₁ to Q₃ may each be the same as described herein.

For example, in one or more embodiments, i) R₁ to R₄, Z₅₁ₐ, Z_{51b}, Z₅₂ₐ, Z_{52b}, and T₁ to T₄ in Formula 1, ii) R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} in Formulae 2, 3-1 to 3-5, 502, and 503, and iii) R₁₀ₐ may each independently be:
hydrogen, deuterium, —F, —Cl, —Br, —I, a hydroxyl group, a cyano group, a nitro group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or a (e.g., any suitable) combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or a (e.g., any suitable) combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or a (e.g., any suitable) combination thereof:

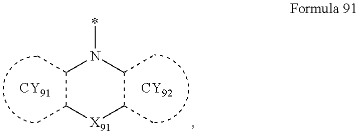

wherein, in Formula 91,
ring CY₉₁ and ring CY₉₂ may each independently be a C₅-C₃₀ carbocyclic group unsubstituted or substituted with at least one R₁₀ₐ or a C₁-C₃₀ heterocyclic group unsubstituted or substituted with at least one R₁₀ₐ,
X₉₁ may be a single bond, O, S, N(R₉₁), B(R₉₁), C(R₉₁ₐ)(R_{11b}), or Si(R₉₁ₐ)(R_{11b}),
R₉₁, R₉₁ₐ, and R_{91b} may be the same as described with respect to R₈₂, R₈₂ₐ, and R_{82b}, respectively,
R₁₀ₐ may be the same as described herein, and
* indicates a binding site to a neighboring atom.

For example, in one or more embodiments, in Formula 91,
ring CY₉₁ and ring CY₉₂ may each independently be a benzene group, a pyridine group, a pyrimidine group, a pyrazine group, a pyridazine group, or a triazine group, each unsubstituted or substituted with at least one R₁₀ₐ, and
R₉₁, R₉₁ₐ, and R_{91b} may each independently be:
hydrogen or a C₁-C₁₀ alkyl group; or
a phenyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or a (e.g., any suitable) combination thereof.

In one or more embodiments, i) R₁ to R₄, Z₅₁ₐ, Z_{51b}, Z₅₂ₐ, Z_{52b}, and T₁ to T₄ in Formula 1, ii) R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} in Formulae 2, 3-1 to 3-5, 502, and 503, and iii) R₁₀ₐ, may each independently be hydrogen, deuterium, —F, a cyano group, a nitro group, —CH₃, —CD₃, —CD₂H, —CDH₂, —CF₃, —CF₂H, —CFH₂, a group represented by one selected from among Formulae 9-1 to 9-19, a group represented by one selected from among Formulae 10-1 to 10-246, —C(Q₁)(Q₂)(Q₃), —Si(Q₁)(Q₂)(Q₃), or —P(═O)(Q₁)(Q₂) (wherein more details on Q₁ to Q₃ may be referred to the descriptions provided herein):

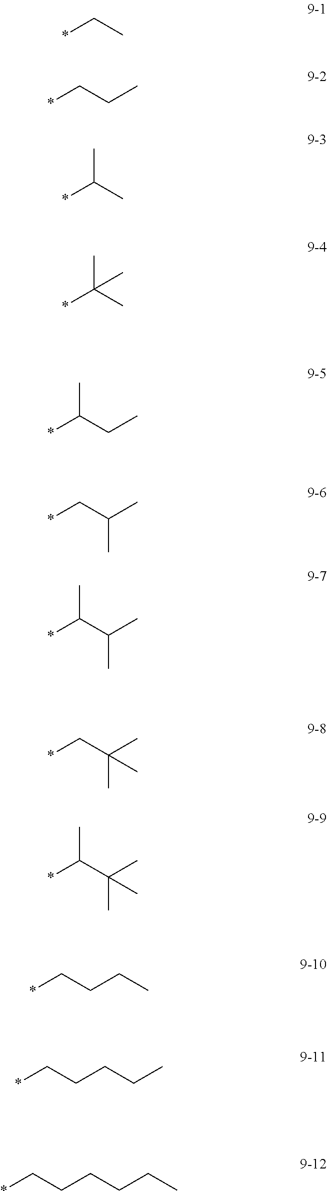

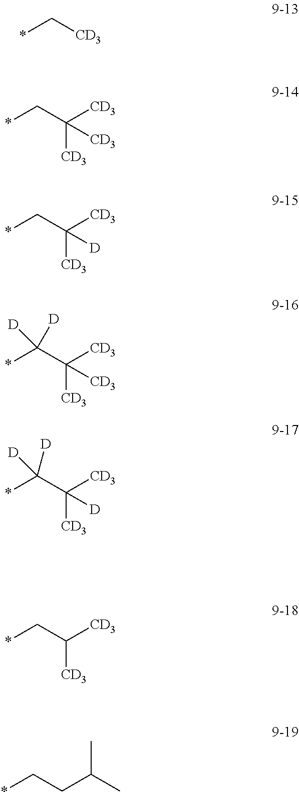

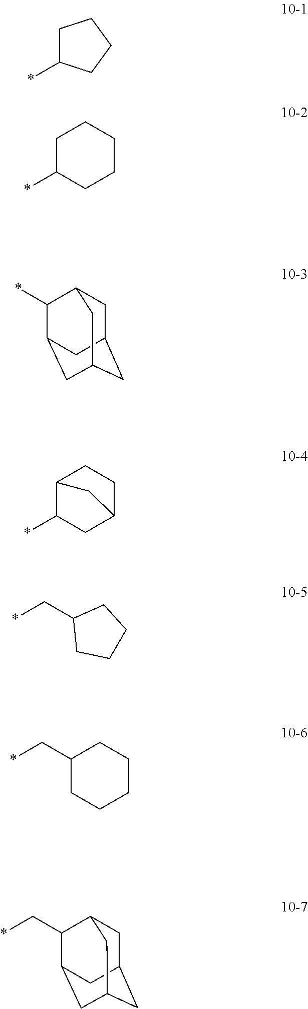

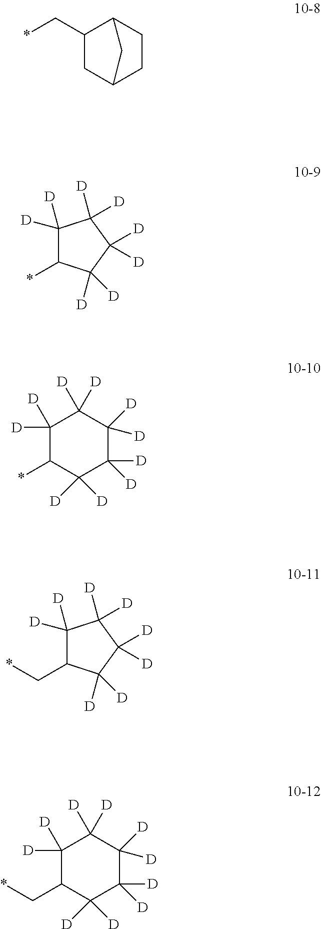

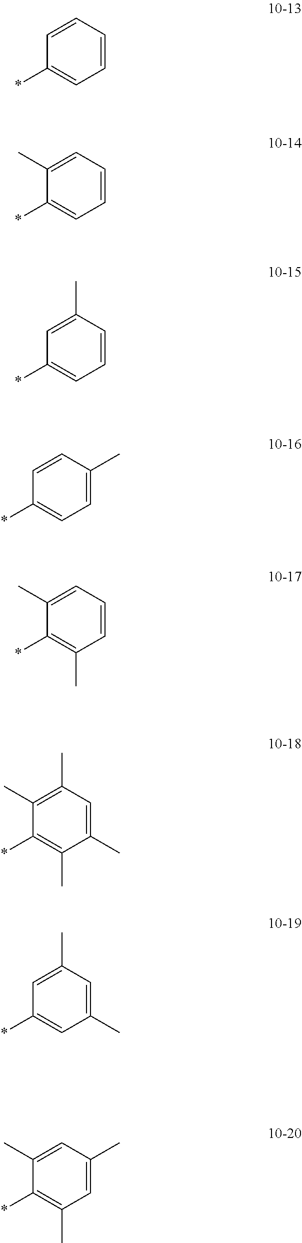

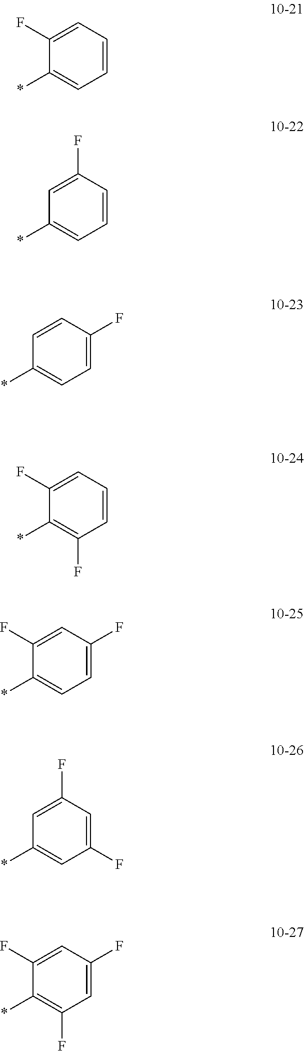

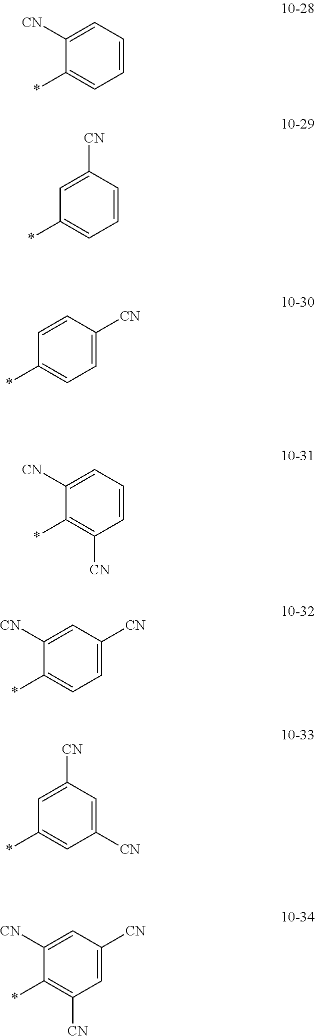

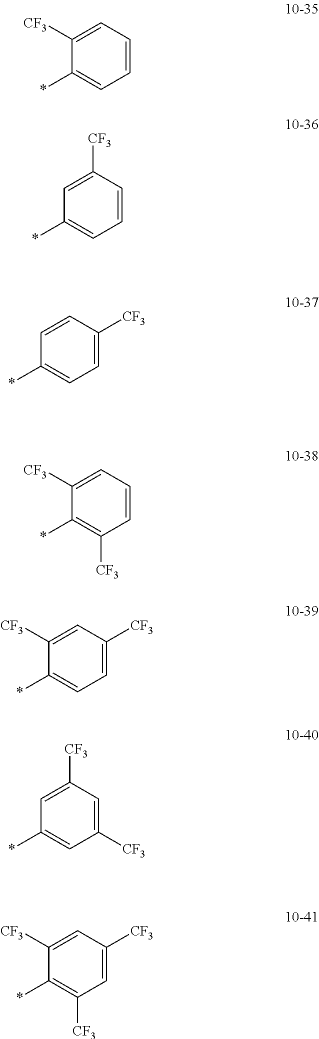

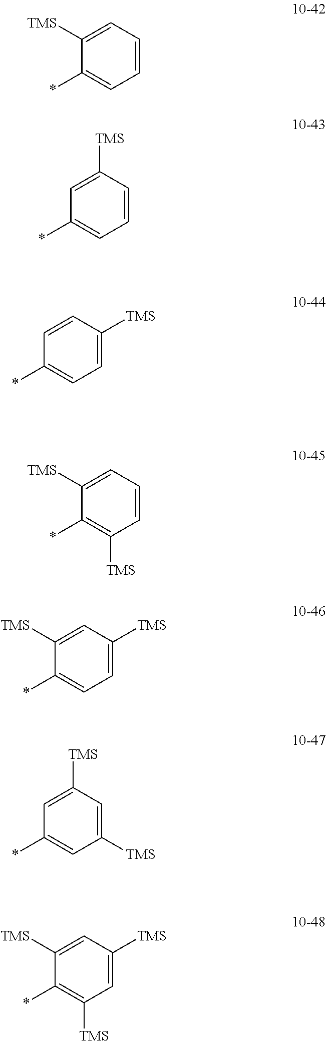

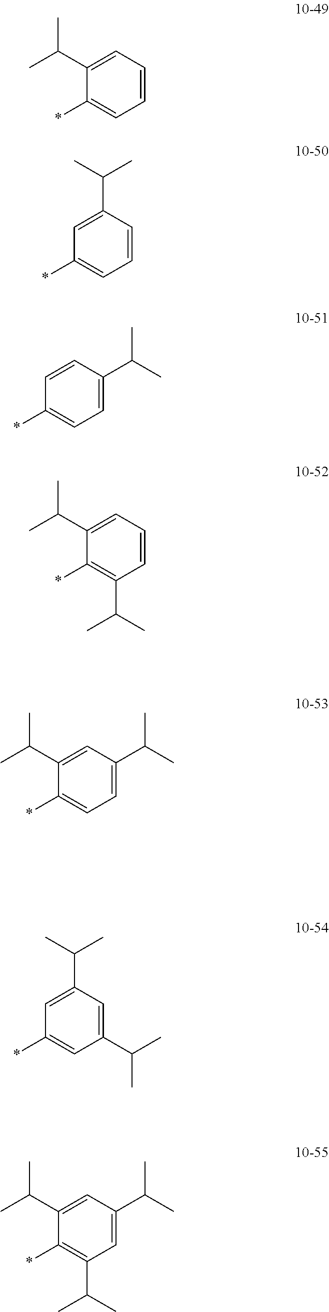

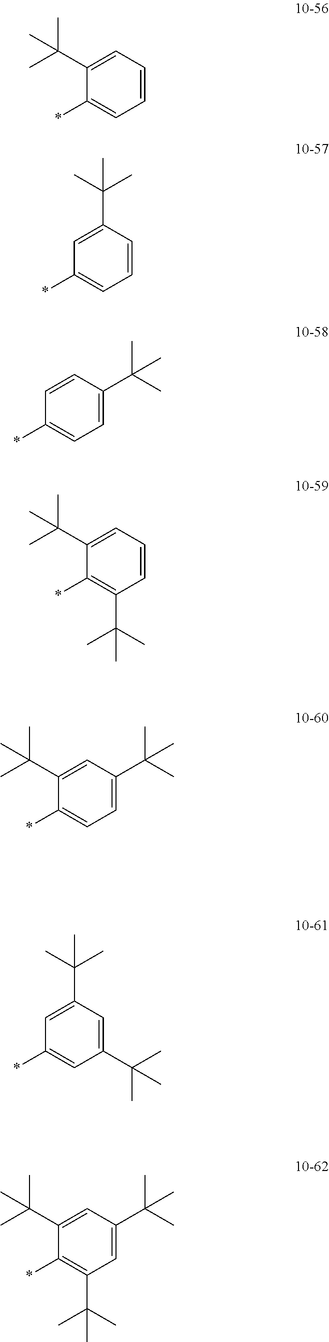

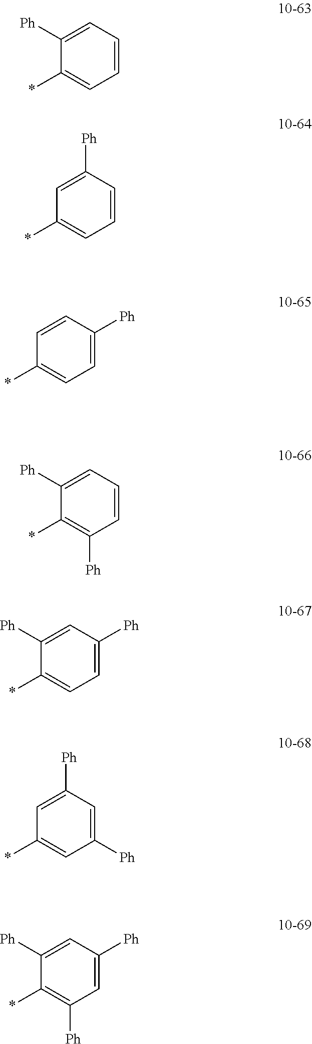

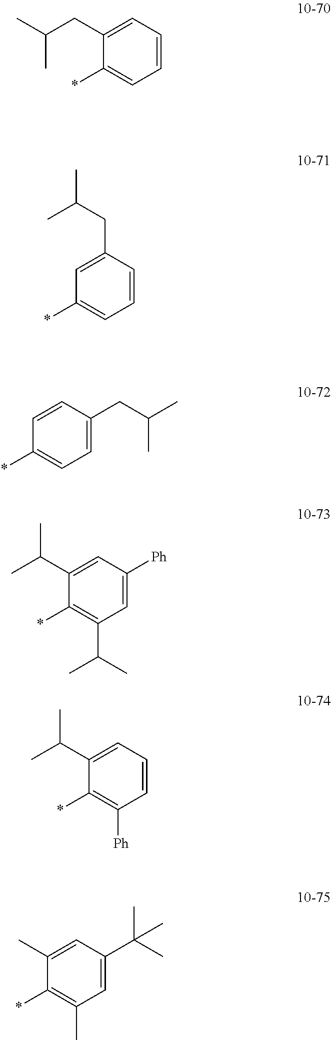

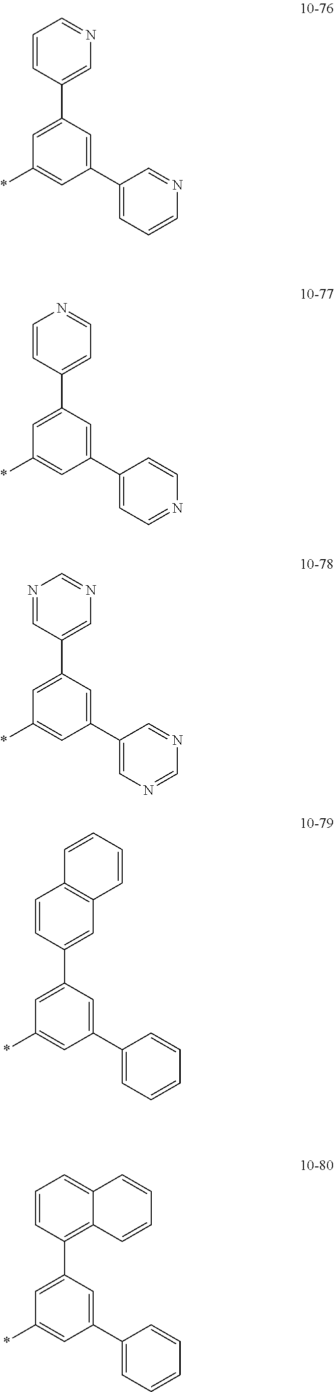

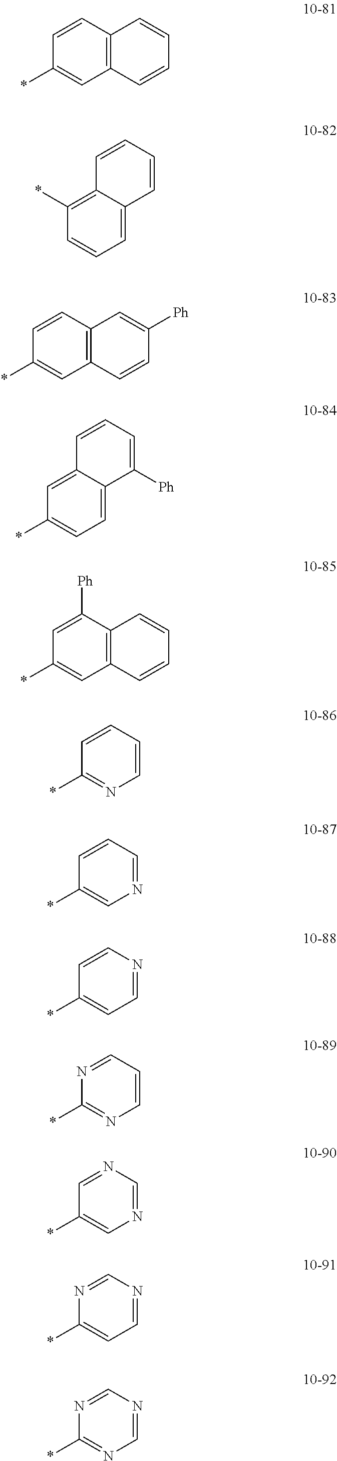

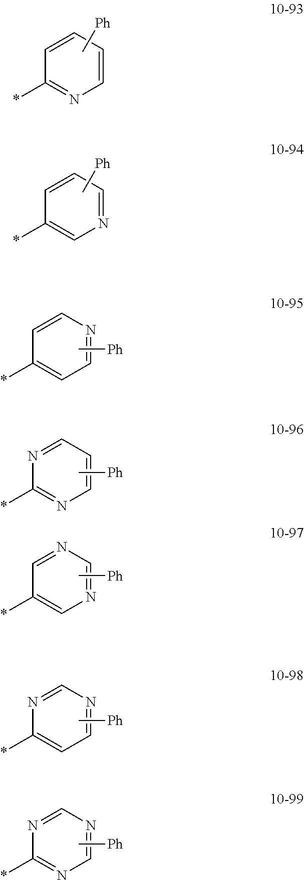

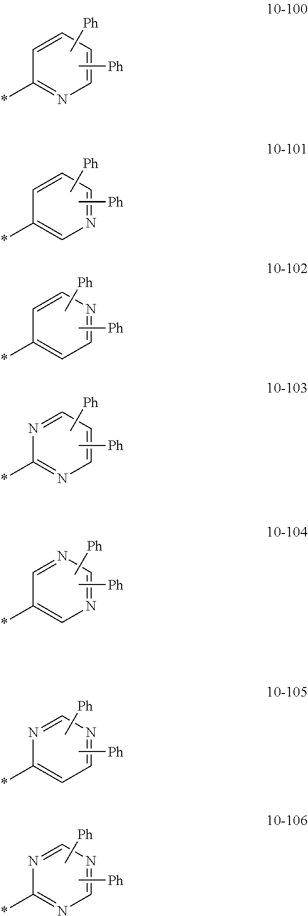

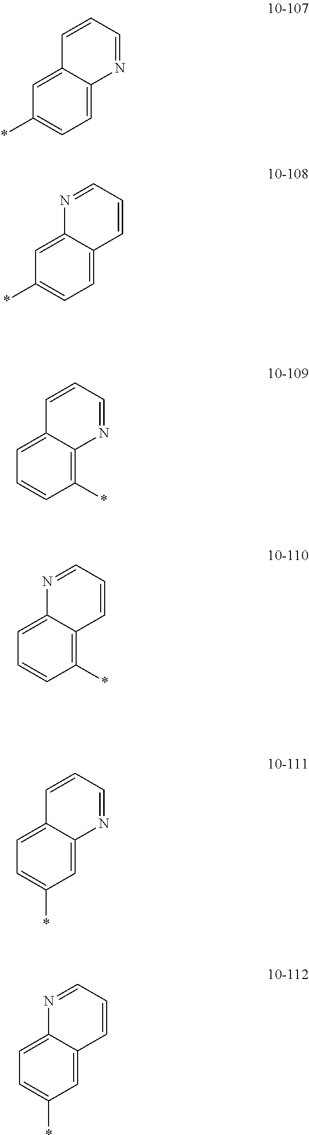

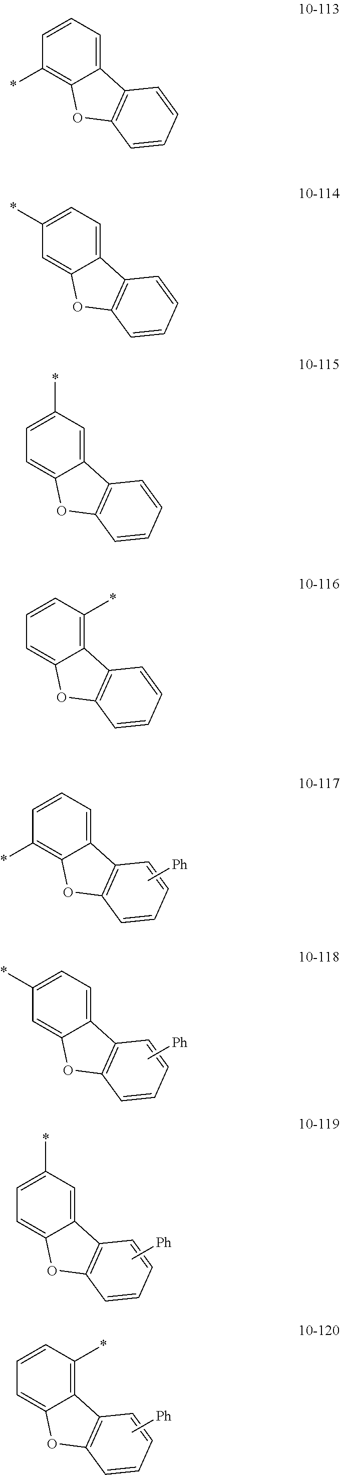

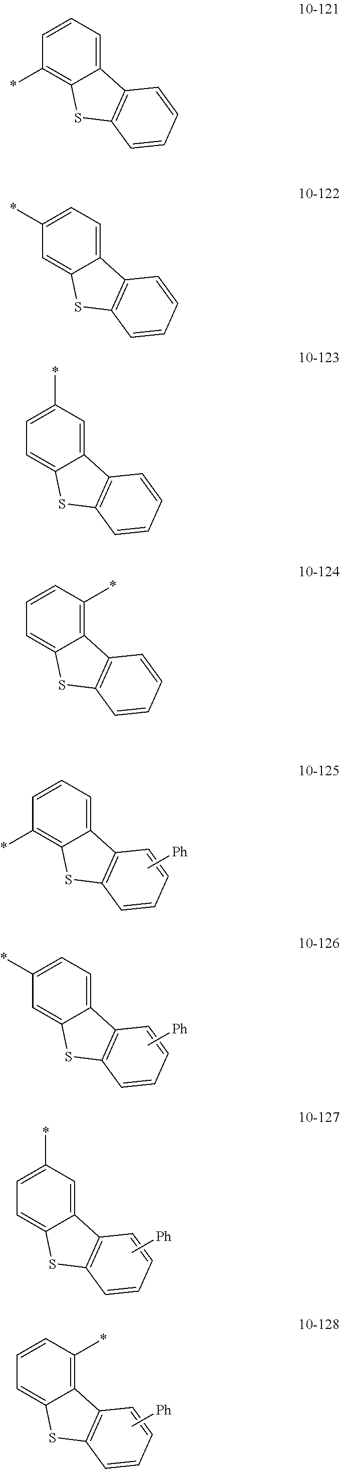

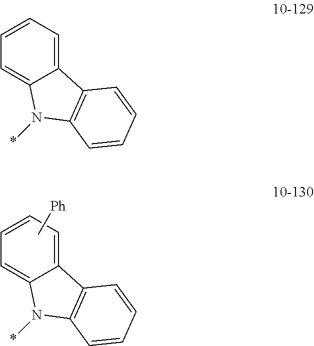

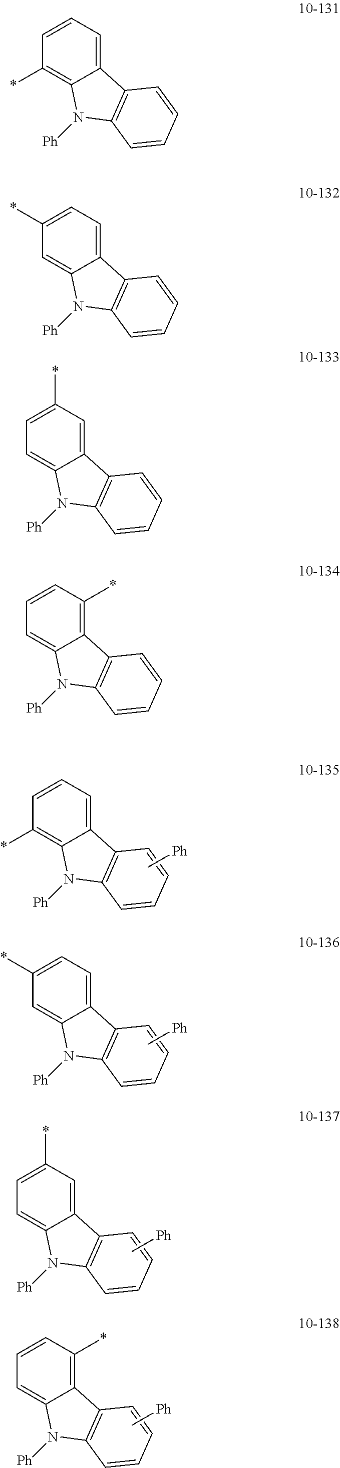

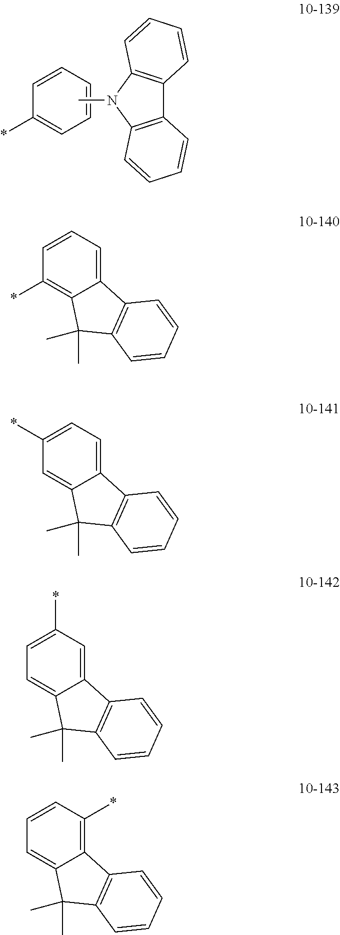

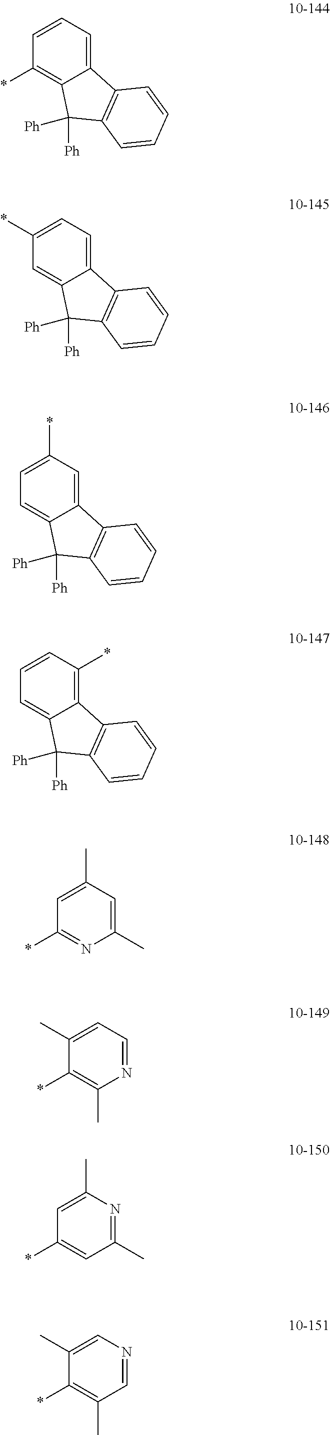

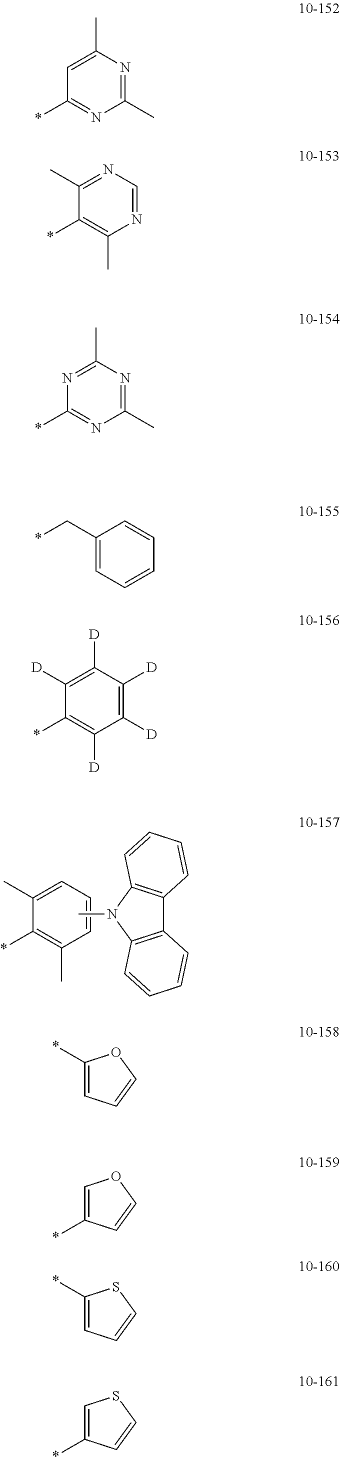

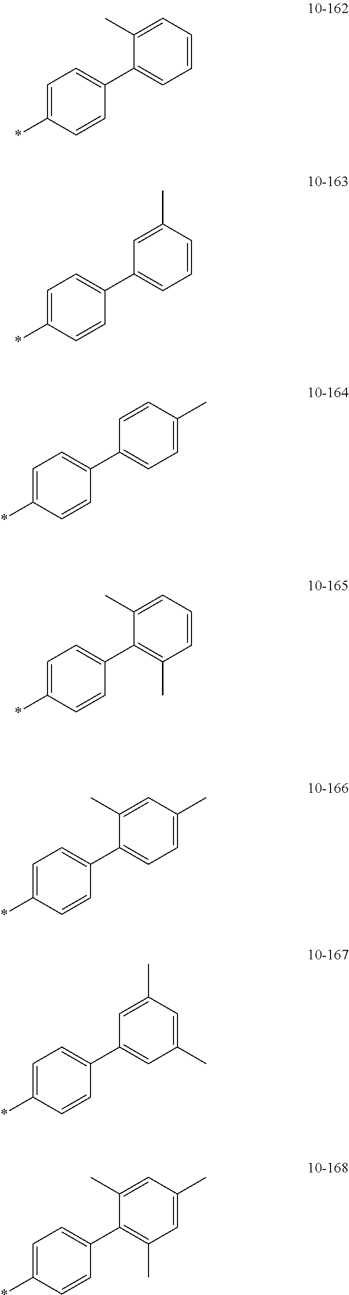

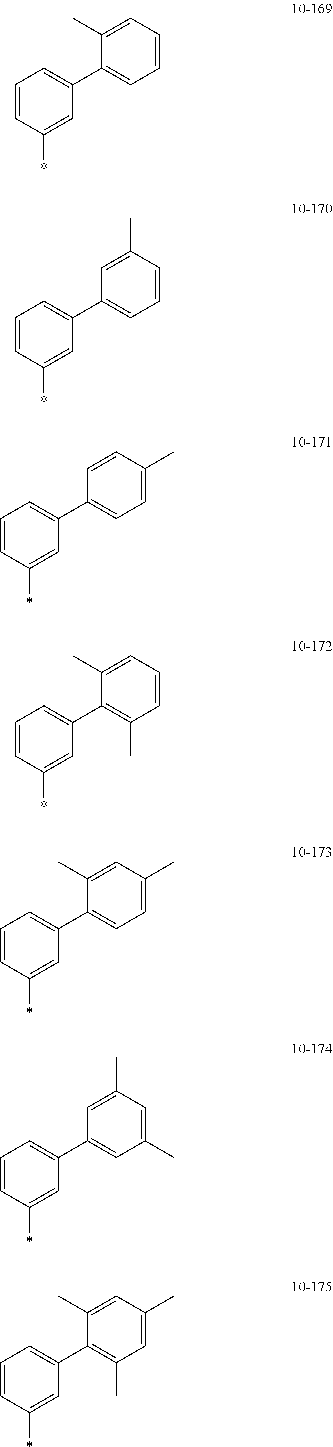

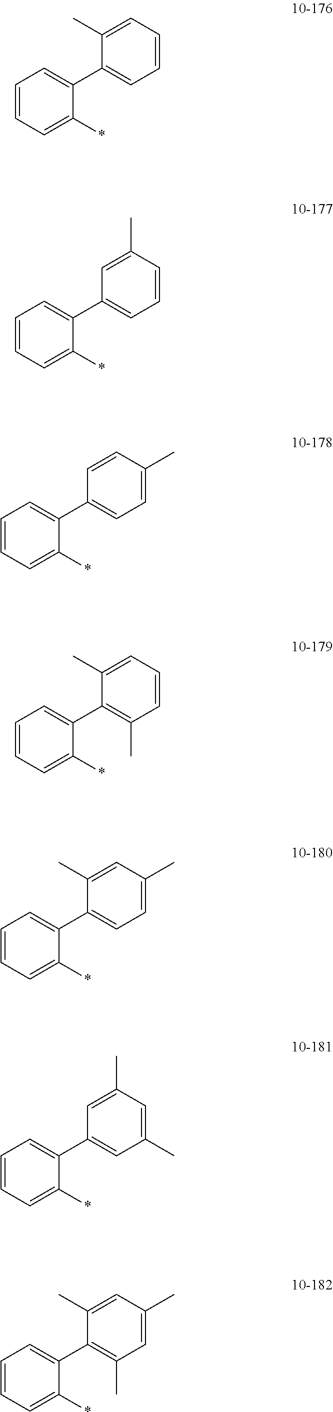

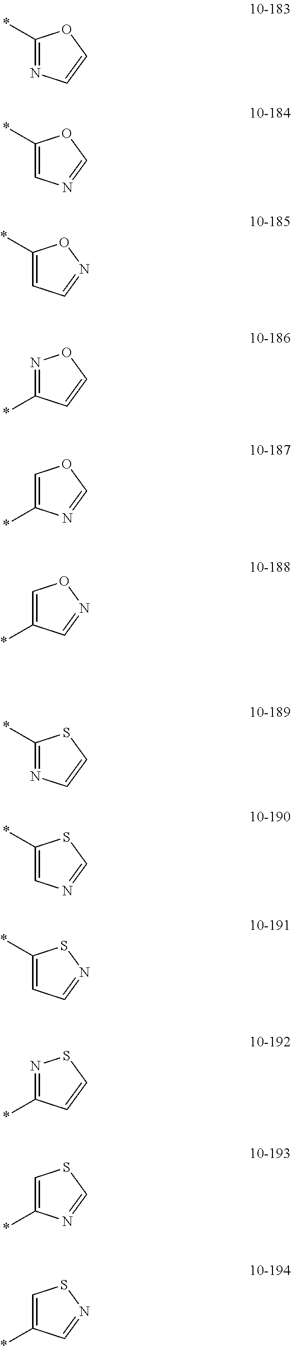

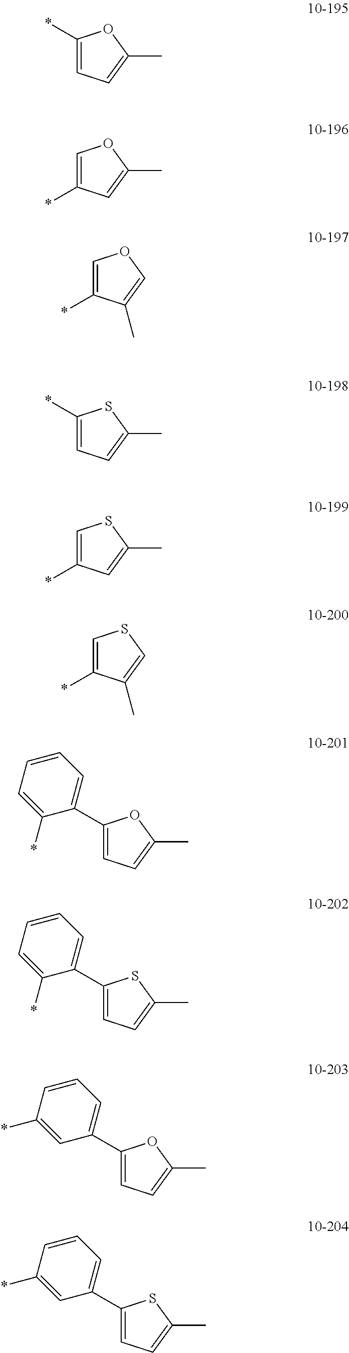

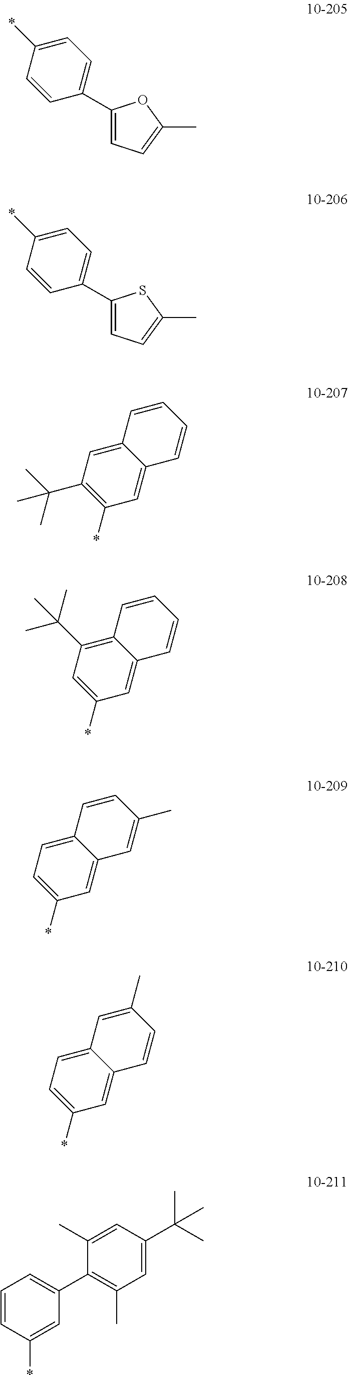

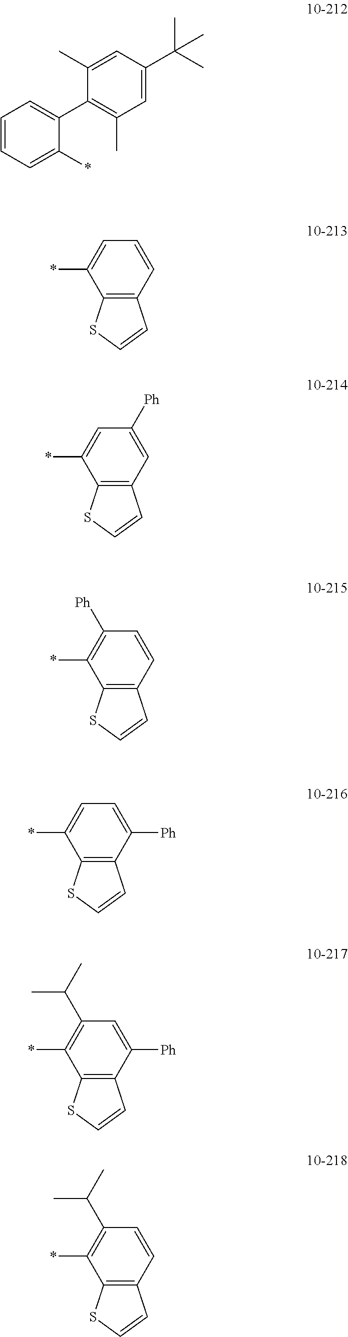

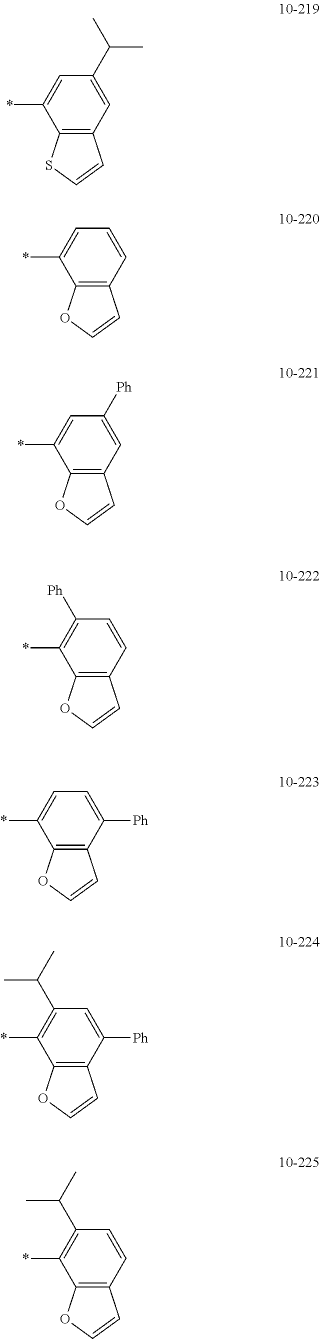

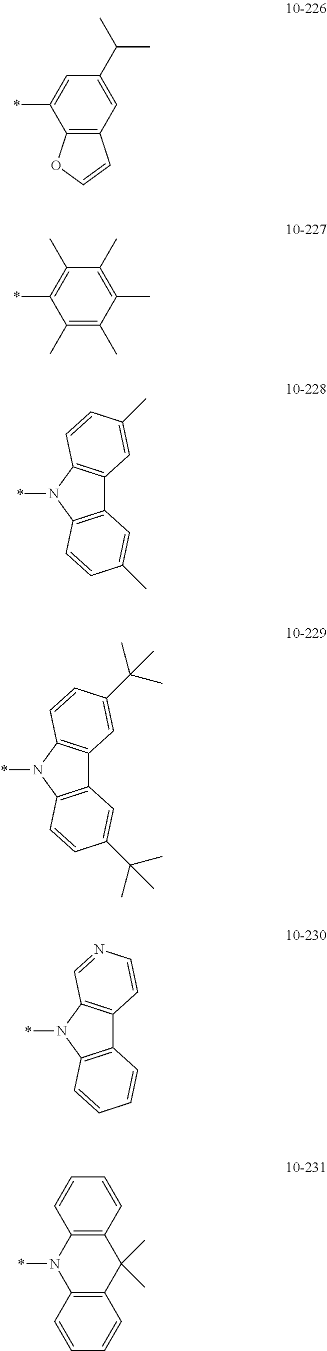

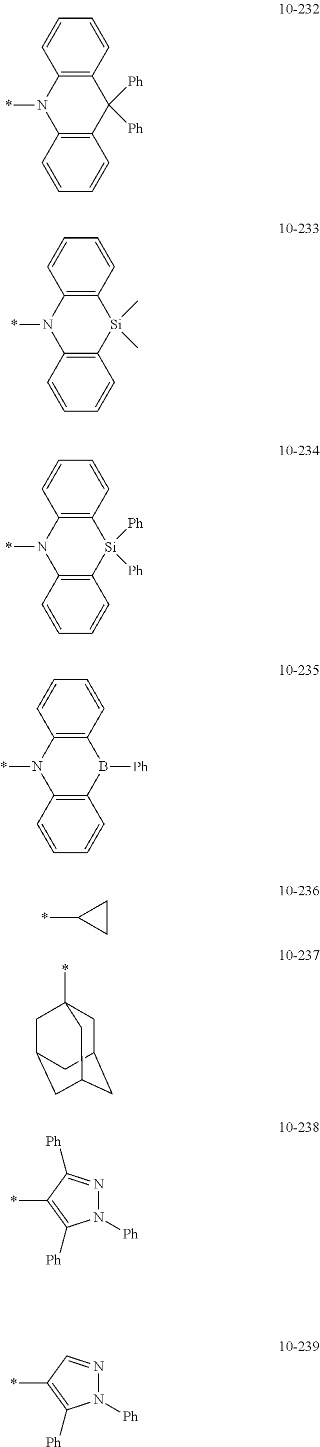

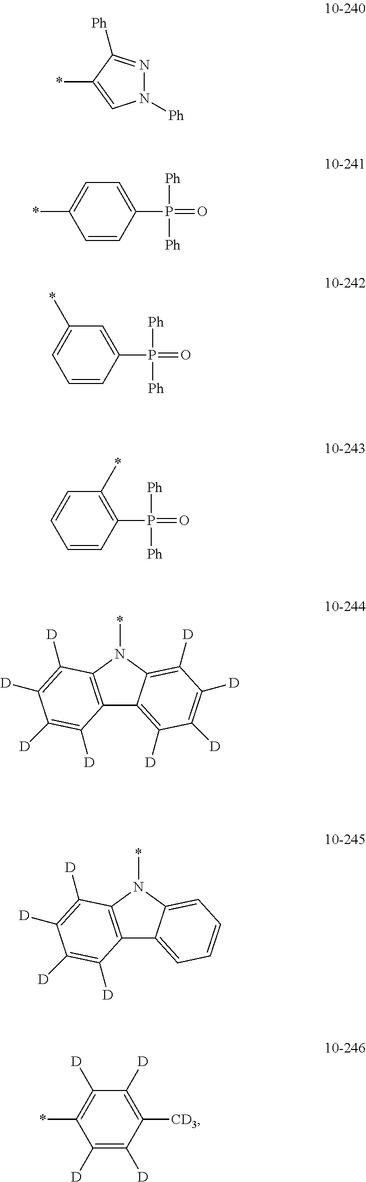

wherein, in Formulae 9-1 to 9-19 and 10-1 to 10-246, * indicates a binding site to a neighboring atom, “Ph” represents a phenyl group, “D” represents deuterium, and “TMS” represents a trimethylsilyl group.

In Formulae 3-1 to 3-5, 502, and 503, a71 to a74 and a501 to a504 each indicate the number of R₇₁ to R₇₄ and the number of R₅₀₁ to R₅₀₄, respectively, and may each independently be an integer from 0 to 20. When a71 is 2 or more, two or more of R₇₁(s) may be identical to or different from each other, when a72 is 2 or more, two or more of R₇₂(s) may be identical to or different from each other, when a73 is 2 or more, two or more of R₇₃(s) may be identical to or different from each other, when a74 is 2 or more, two or more of R₇₄(s) may be identical to or different from each other, when a501 is 2 or more, two or more of R₅₀₁(s) may be identical to or different from each other, when a502 is 2 or more, two or more of R₅₀₂(s) may be identical to or different from each other, when a503 is 2 or more, two or more of R₅₀₃(s) may be identical to or different from each other, and when a504 is 2 or more, two or more of R₅₀₄(s) may be identical to or different from each other. In some embodiments, a71 to a74 and a501 to a504 may each independently be an integer from 0 to 8.

In Formula 2, a group represented by *-(L₅₁)_{b51}-R₅₁ and a group represented by *-(L₅₂)_{b52}-R₅₂ may each not be a phenyl group.

In one or more embodiments, a group represented by *-(L₅₁)_{b51}-R₅₁ and a group represented by *-(L₅₂)_{b52}-R₅₂ in Formula 2 may be identical to each other.

In one or more embodiments, a group represented by *-(L₅₁)_{b51}-R₅₁ and a group represented by *-(L₅₂)_{b52}-R₅₂ in Formula 2 may be different from each other.

In one or more embodiments, in Formula 2, b51 and b52 may each be 1, 2, or 3, and L₅₁ and L₅₂ may each independently be a benzene group, a pyridine group, a pyrimidine group, a pyridazine group, a pyrazine group, or a triazine group, each unsubstituted or substituted with at least one R₁₀ₐ.

In one or more embodiments, R₅₁ and R₅₂ in Formula 2 may each independently be a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), or —Si(Q₁)(Q₂)(Q₃), and
Q₁ to Q₃ may each independently be a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or a (e.g., any suitable) combination thereof.

In one or more embodiments,
a group represented by *-(L₅₁)_{b51}-R₅₁ in Formula 2 may be a group represented by one selected from among Formulae CY51-1 to CY51-26, and/or
a group represented by *-(L₅₂)_{b52}-R₅₂ in Formula 2 may be a group represented by one selected from among Formulae CY52-1 to CY52-26, and/or
a group represented by *-(L₅₃)_{b53}-R₅₃ in Formula 2 may be a group represented by one selected from among Formulae CY53-1 to CY53-27, —C(Q₁)(Q₂)(Q₃), or —Si(Q₁)(Q₂)(Q₃):

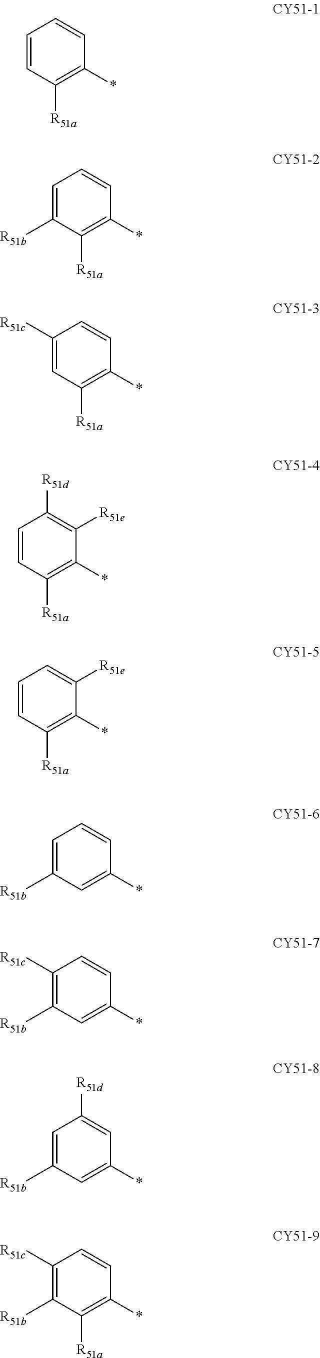

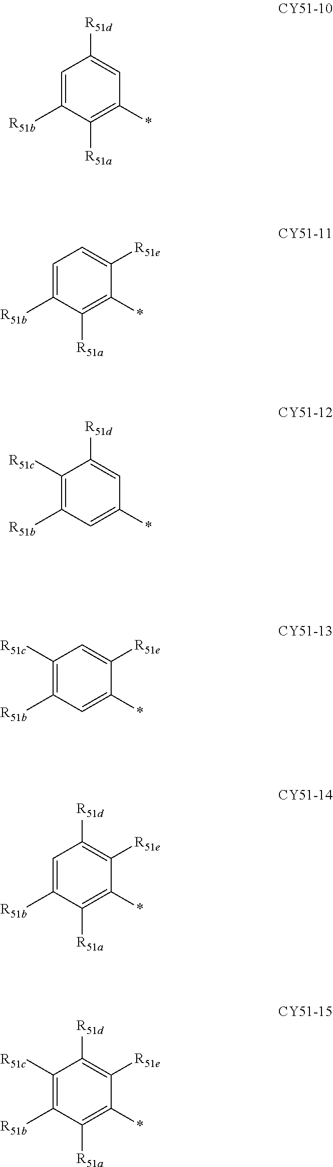

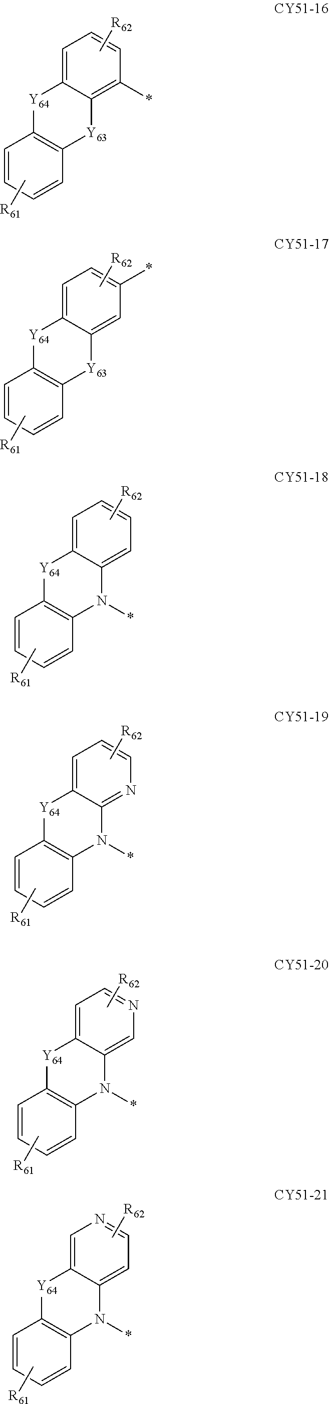

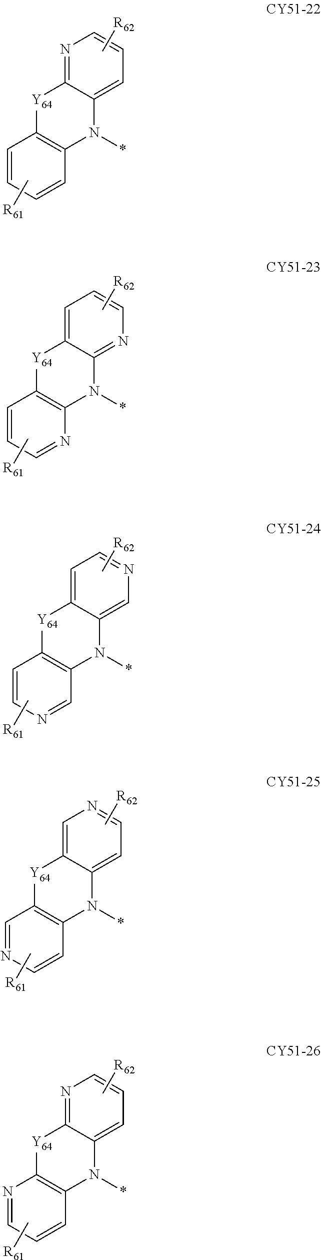

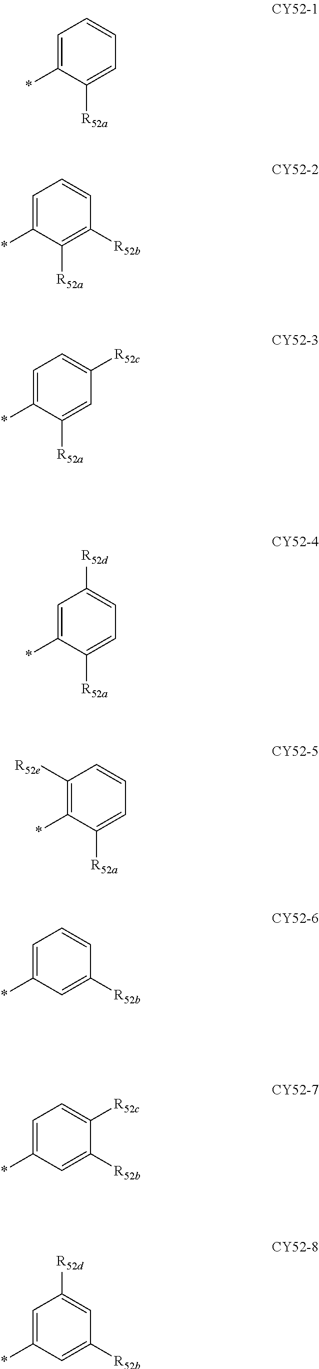

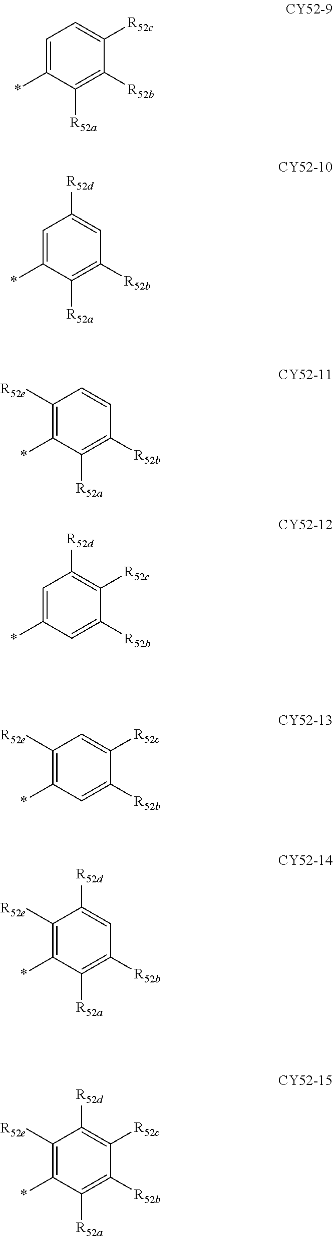

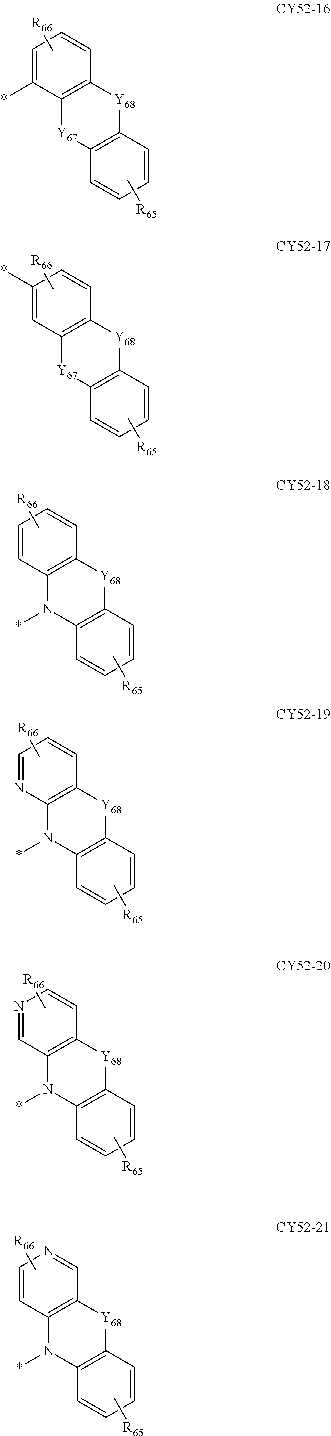

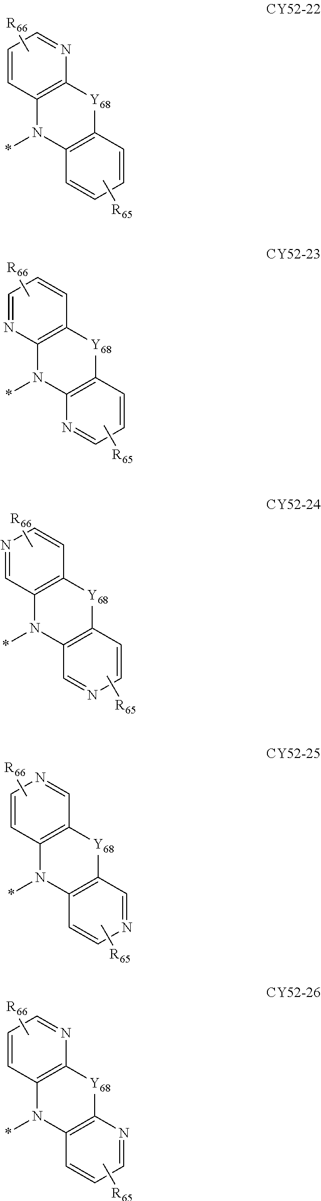

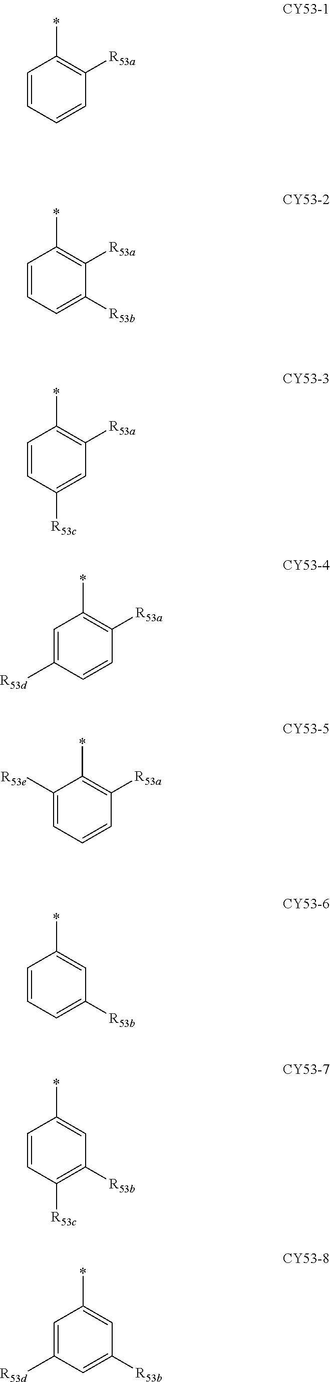

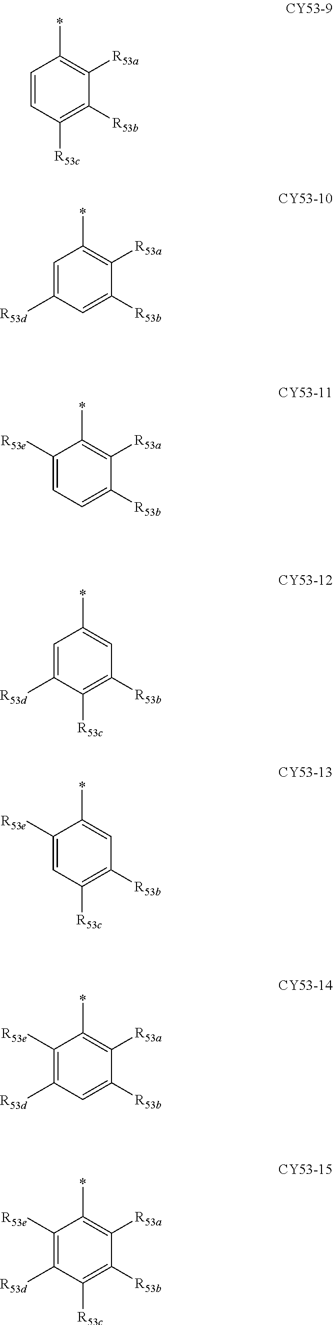

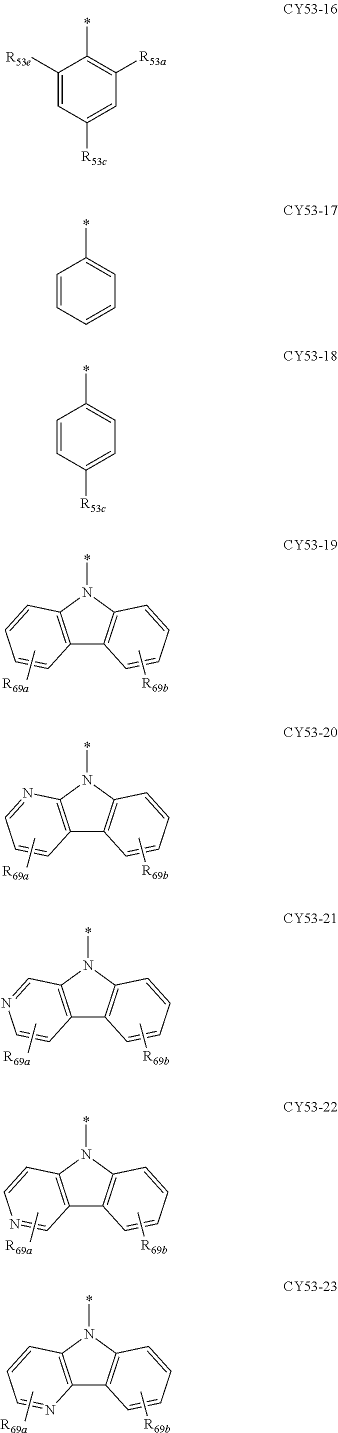

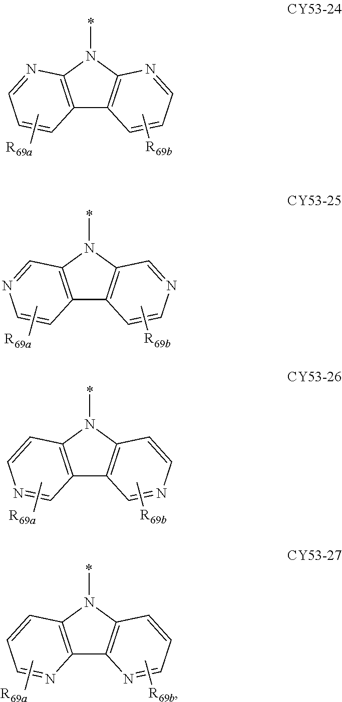

wherein, in Formulae CY51-1 to CY51-26, CY52-1 to CY52-26, and CY53-1 to CY53-27,
Y₆₃ may be a single bond, O, S, N(R₆₃), B(R₆₃), C(R₆₃ₐ)(R_{63b}), or Si(R₆₃ₐ)(R_{63b}),
Y₆₄ may be a single bond, O, S, N(R₆₄), B(R₆₄), C(R₆₄ₐ)(R_{64b}), or Si(R₆₄ₐ)(R_{64b}),
Y₆₇ may be a single bond, O, S, N(R₆₇), B(R₆₇), C(R₆₇ₐ)(R_{67b}), or Si(R₆₇ₐ)(R_{67b}),
Y₆₈ may be a single bond, O, S, N(R₆₈), B(R₆₈), C(R₆₈ₐ)(R_{68b}), or Si(R₆₈ₐ)(R_{68b}),
each of Y₆₃ and Y₆₄ in Formulae CY51-16 and CY51-17 may not be a single bond at the same time,
each of Y₆₇ and Y₆₈ in Formulae CY52-16 and CY52-17 may not be a single bond at the same time,
R₅₁ₐ to R₅₁ₑ, R₆₁ to R₆₄, R₆₃ₐ, R_{63b}, R₆₄ₐ, and R_{64b} may each independently be the same as described with respect to R₅₁, wherein R₅₁ₐ to R₅₁ₑ may each not be hydrogen,
R₅₂ₐ to R₅₂ₑ, R₆₅ to R₆₈, R₆₇ₐ, R_{67b}, R₆₈ₐ, and R_{68b} may each independently be the same as described with respect to R₅₂, wherein R₅₂ₐ to R₅₂ₑ may each not be hydrogen,
R₅₃ₐ to R₅₃ₑ, R₆₉ₐ, and R_{69b} may each independently be the same as described with respect to R₅₃, wherein R₅₃ₐ to R₅₃ₑ may each not be hydrogen, and
* indicates a binding site to a neighboring atom.

For example, in one or more embodiments,
in Formulae CY51-1 to CY51-26 and CY52-1 to CY52-26, R₅₁ₐ to R₅₁ₑ and R₅₂ₐ to R₅₂ₑ may each independently be:
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or a (e.g., any suitable) combination thereof; or
—C(Q₁)(Q₂)(Q₃) or —Si(Q₁)(Q₂)(Q₃), and
Q₁ to Q₃ may each independently be a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or a (e.g., any suitable) combination thereof,

In some embodiments, in Formulae CY51-16 and CY51-17, i) Y₆₃ may be O or S, and Y₆₄ may be Si(R₆₄ₐ)(R_{64b}), or ii) Y₆₃ may be Si(R₆₃ₐ)(R_{63b}), and Y₆₄ may be O or S, and

In some embodiments, in Formulae CY52-16 and CY52-17, i) Y₆₇ may be O or S, and Y₆₈ may be Si(R₆₈ₐ)(R_{68b}), or ii) Y₆₇ may be Si(R₆₇ₐ)(R_{67b}), and Y₆₈ may be O or S.

In one or more embodiments, in Formulae 3-1 to 3-5, L₈₁ to L₈₅ may each independently be:
a single bond; or
*—C(Q₄)(Q₅)-*′ or *—Si(Q₄)(Q₅)-*′; or
a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, a pyridine group, a pyrrole group, a benzoxadiazole group, or a benzothiadiazole group, each unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or a (e.g., any suitable) combination thereof, and
Q₄, Q₅, and Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In one or more embodiments, a group represented by

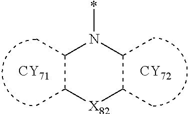

in Formulae 3-1 and 3-2 may be a group represented by one selected from among Formulae CY71-1(1) to CY71-1(8), and/or
a group represented by

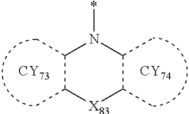

in Formulae 3-1 and 3-3 may be a group represented by one selected from among Formulae CY71-2(1) to CY71-2(8), and/or
a group represented by

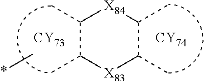

in Formulae 3-2 and 3-4 may be a group represented by one selected from among Formulae CY71-3(1) to CY71-3(32), and/or
a group represented by

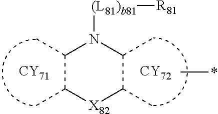

in Formulae 3-3 to 3-5 may be a group represented by one selected from among Formulae CY71-4(1) to CY71-4(32), and/or
a group represented by

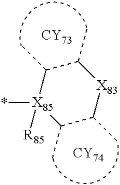

in Formula 3-5 may be a group represented by one selected from among Formulae CY71-5(1) to CY71-5(8):

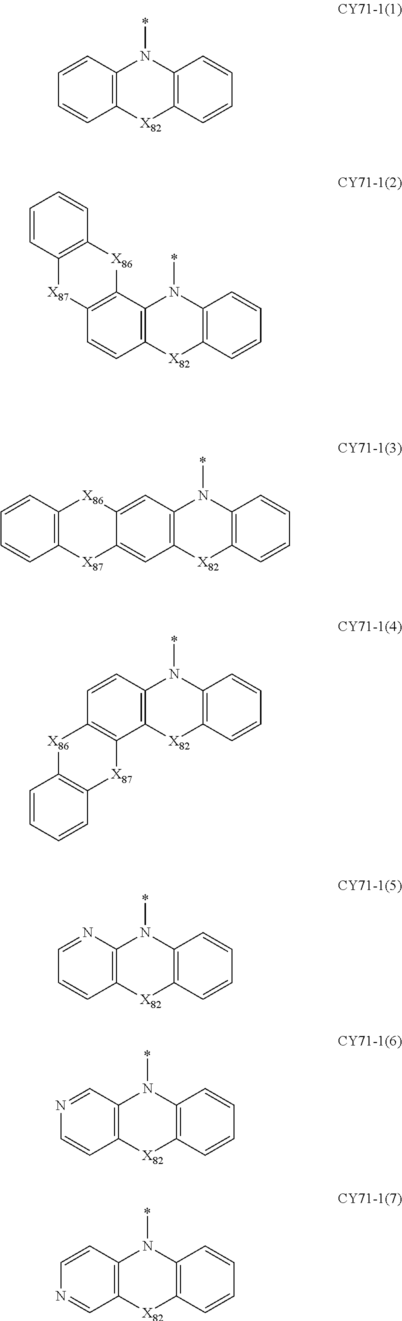

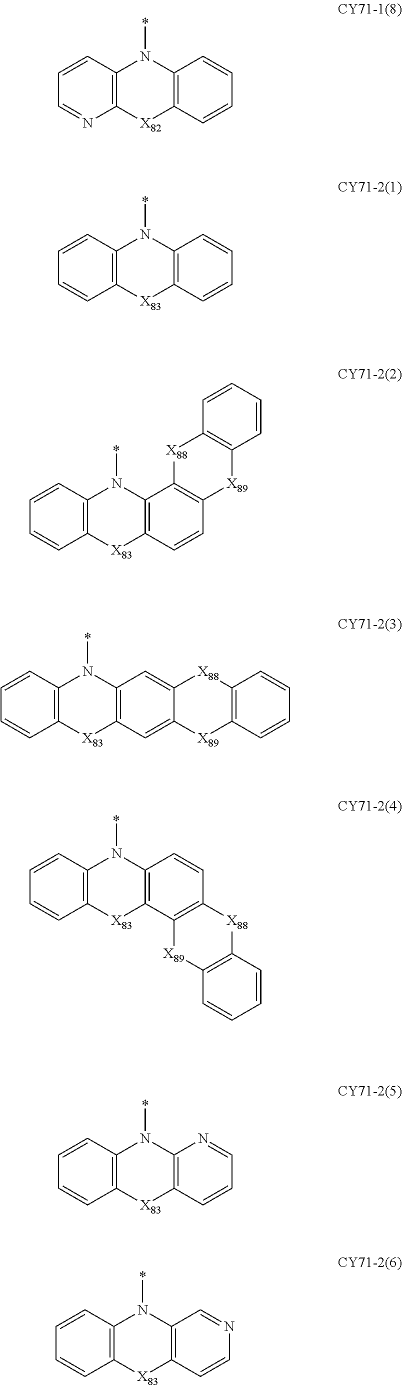

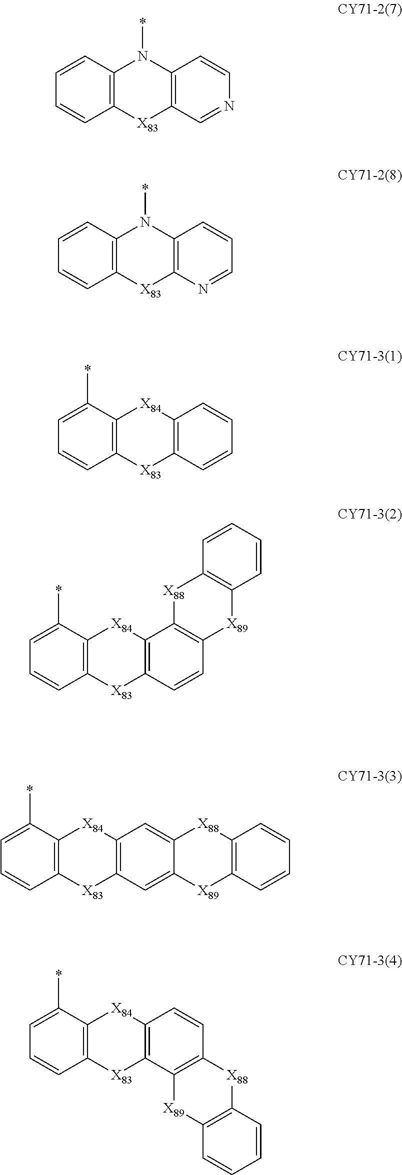

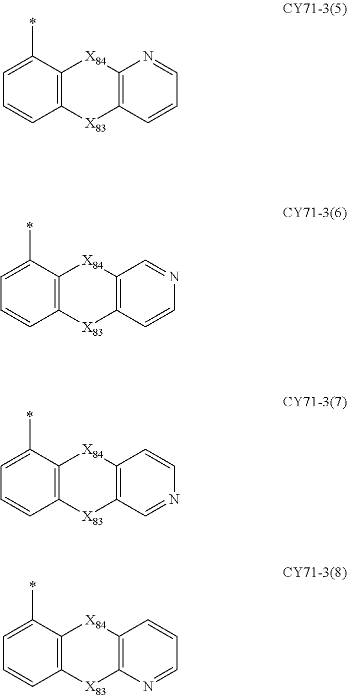

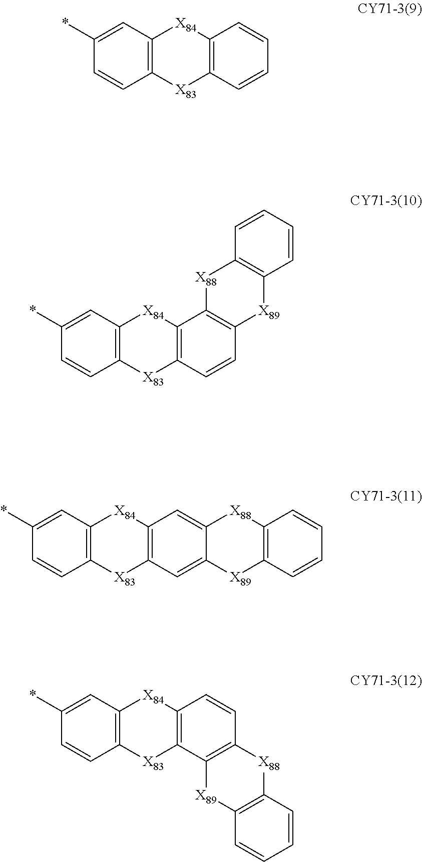

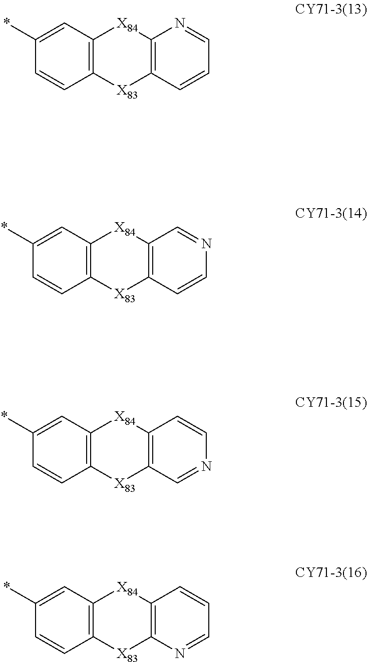

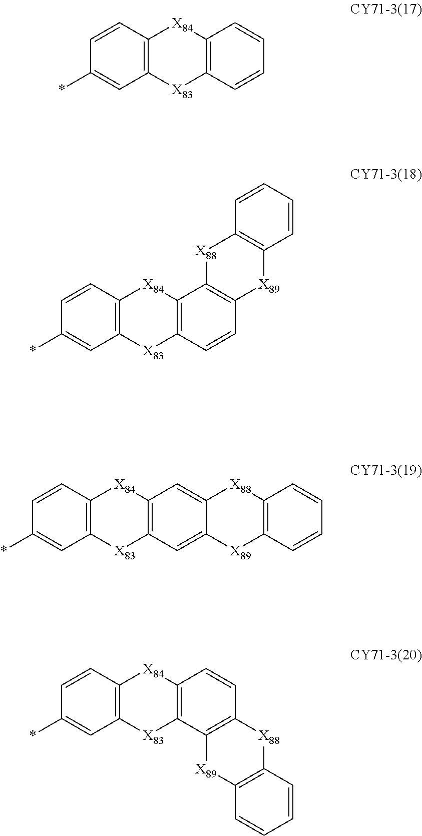

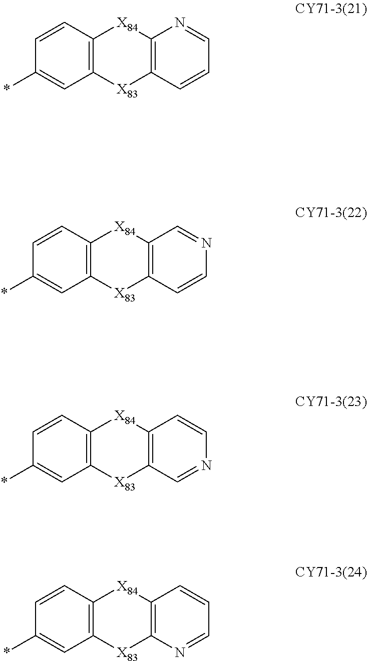

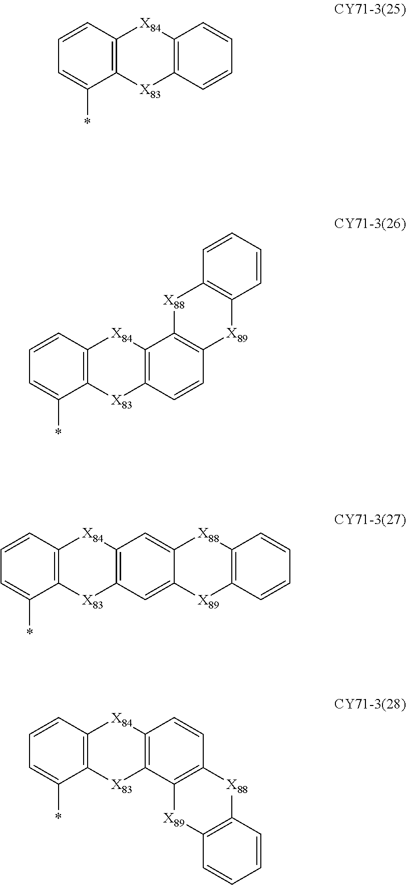

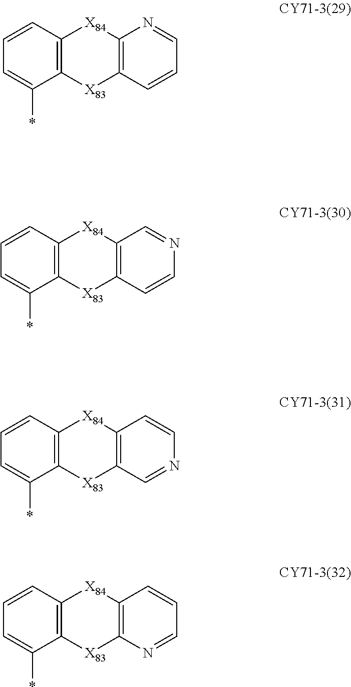

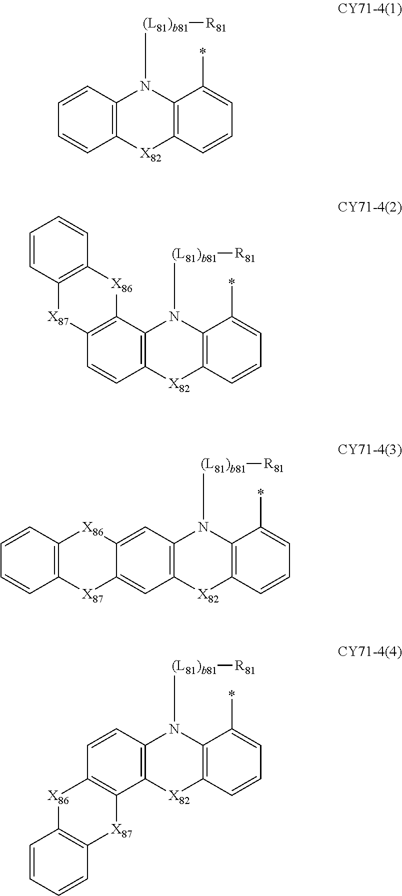

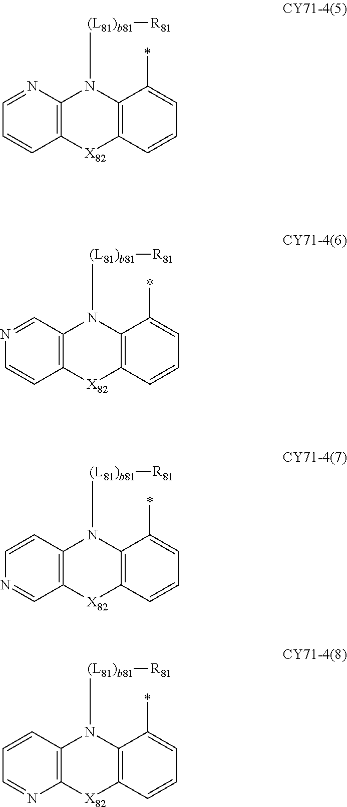

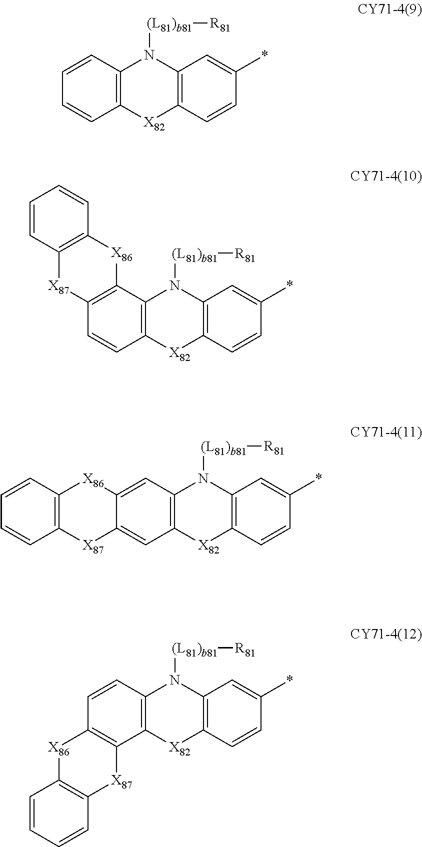

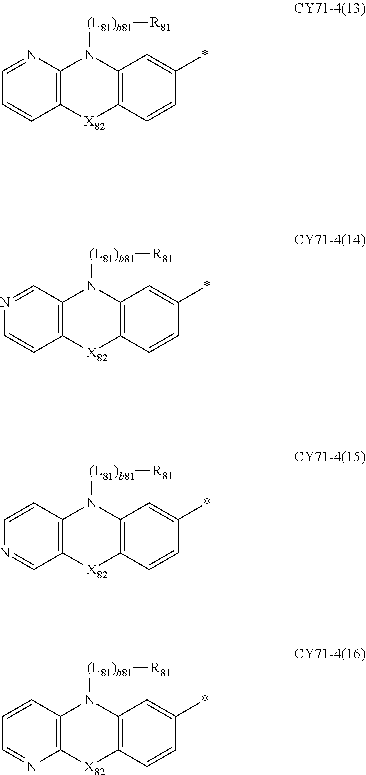

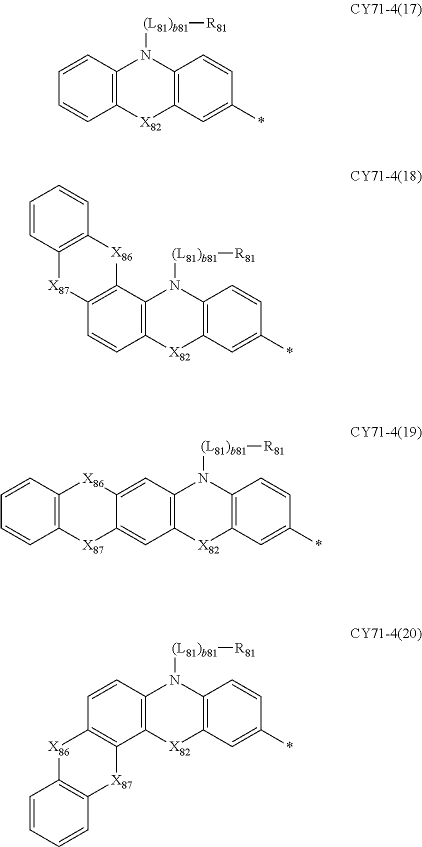

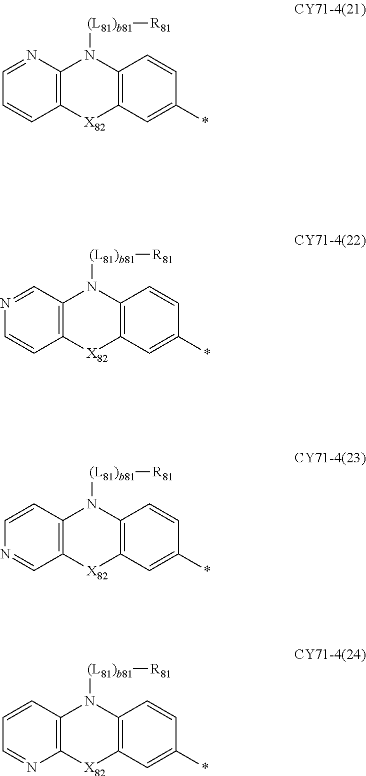

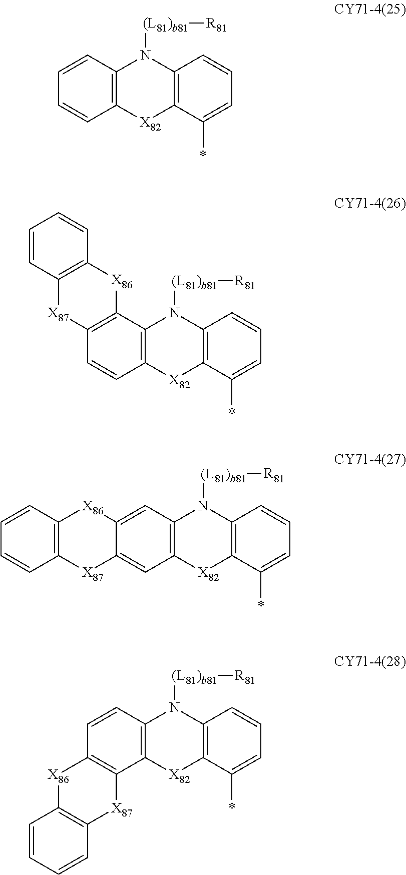

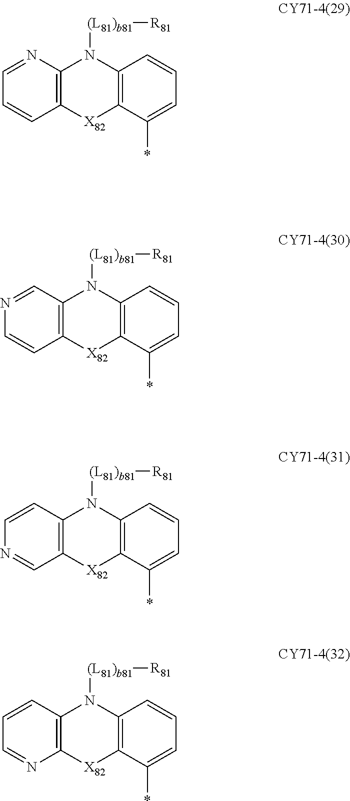

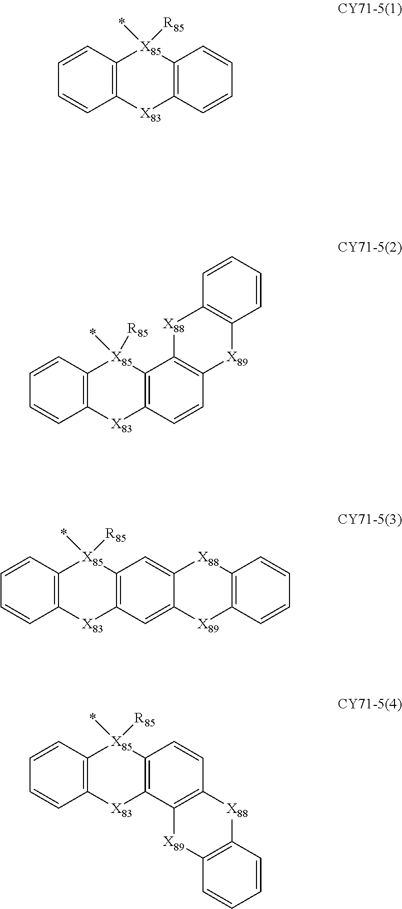

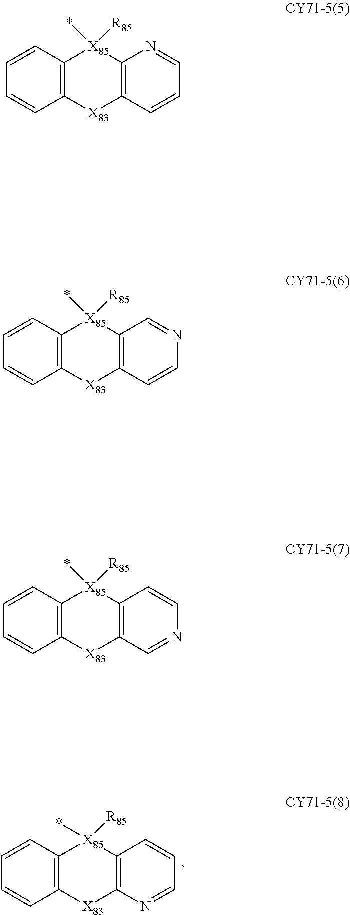

wherein, in Formulae CY71-1(1) to CY71-1(8), CY71-2(1) to CY71-2(8), CY71-3(1) to CY71-3(32), CY71-4(1) to CY71-4(32), and CY71-5(1) to CY71-5(8),
X₈₁ to X₈₅, L₈₁, b81, R₈₁, and R₈₅ may each be the same as described herein,
X₈₆ may be a single bond, O, S, N(R₈₆), B(R₈₆), C(R₈₆ₐ)(R_{86b}), or Si(R₈₆ₐ)(R_{86b}),
X₈₇ may be a single bond, O, S, N(R₈₇), B(R₈₇), C(R₈₇ₐ)(R_{87b}), or Si(R₈₇ₐ)(R_{87b}),
each of X₈₆ and X₈₇ in Formulae CY71-1(2) to CY71-1(4), CY71-4(2) to CY71-4(4), CY71-4(10) to CY71-4(12), CY71-4(18) to CY71-4(20), and CY71-4(26) to CY71-4(28) may not be a single bond at the same time,
X₈₈ may be a single bond, O, S, N(R₈₈), B(R₈₈), C(R₈₈ₐ)(R_{88b}), or Si(R₈₈ₐ)(R_{88b}),
X₈₉ may be a single bond, O, S, N(R₈₉), B(R₈₉), C(R₈₉ₐ)(R_{89b}), or Si(R₈₉ₐ)(R_{89b}),
each of X₈₈ and X₈₉ in Formulae CY71-2(2) to CY71-2(4), CY71-3(2) to CY71-3(4), CY71-3(10) to CY71-3(12), CY71-3(18) to CY71-3(20), CY71-3(26) to CY71-3(28), and CY71-5(2) to CY71-5(4) may not be a single bond at the same time, and
R₈₆ to R₈₉, R₈₆ₐ, R_{86b}, R₈₇ₐ, R_{87b}, R₈₈ₐ, R_{88b}, R₈₉ₐ, and R_{89b} may each independently be the same as described with respect to R₈₁.

### EXAMPLES OF COMPOUNDS

In one or more embodiments, the organometallic compound represented by Formula 1 may be one selected from among Compounds 1 to 267:

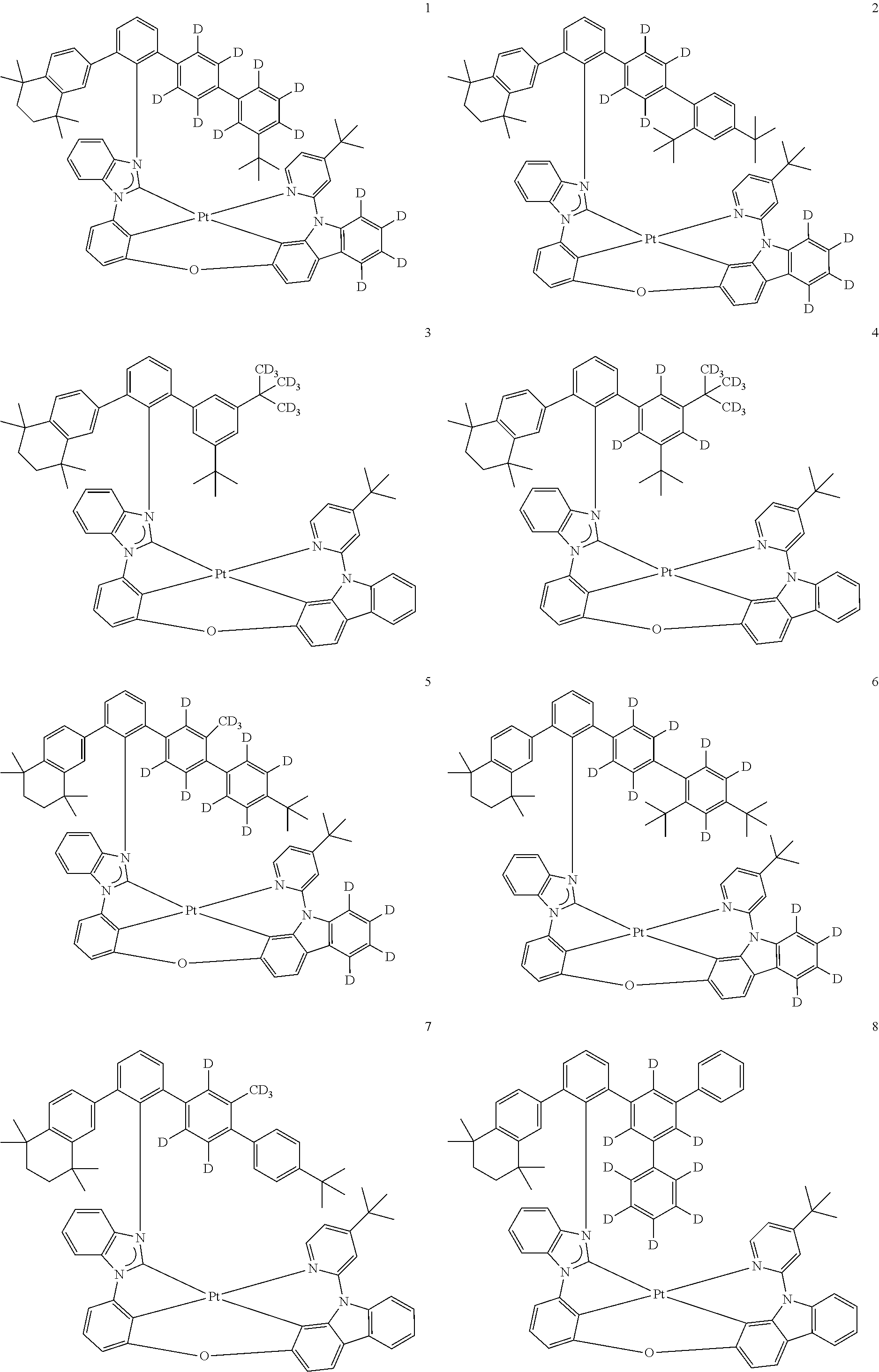

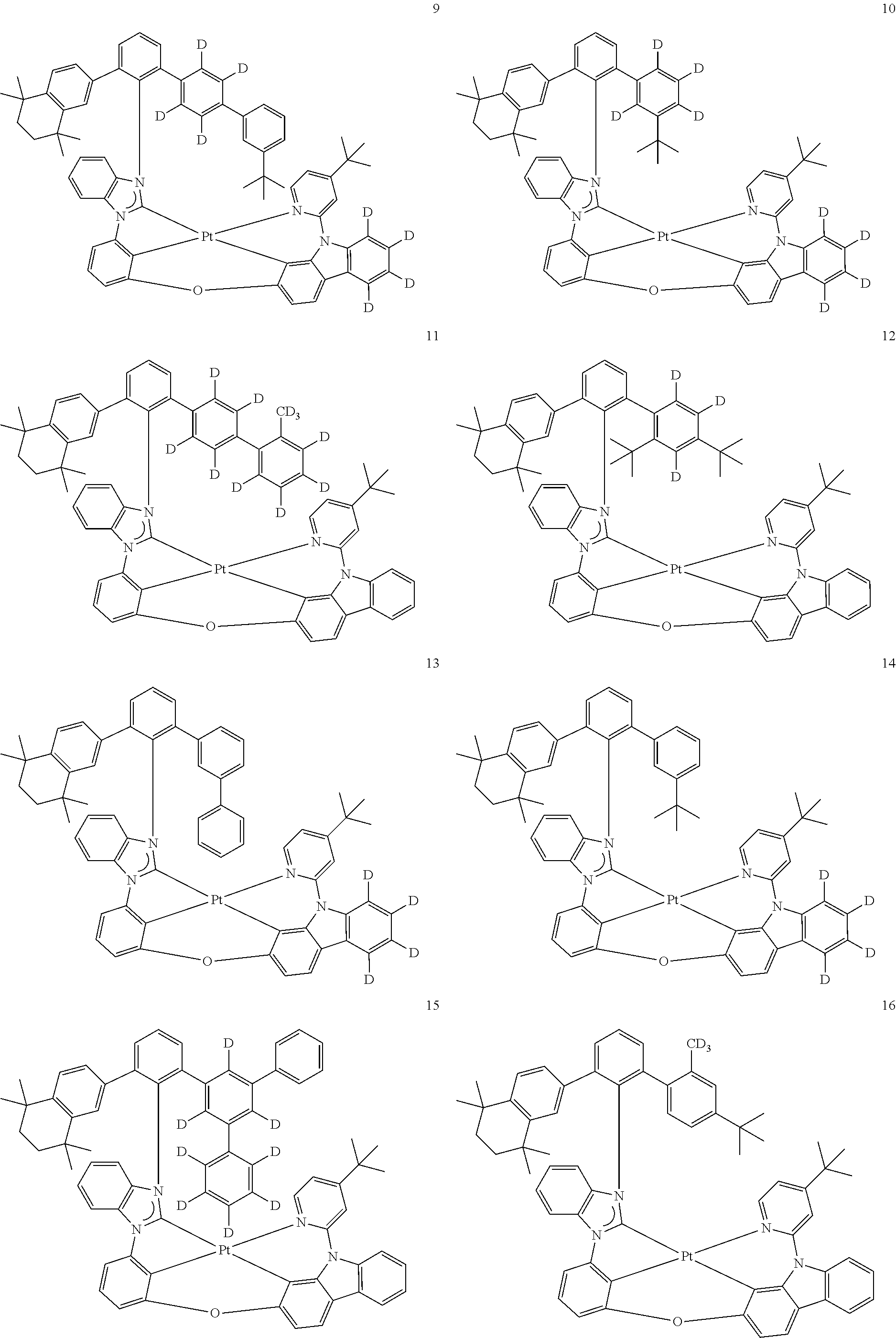

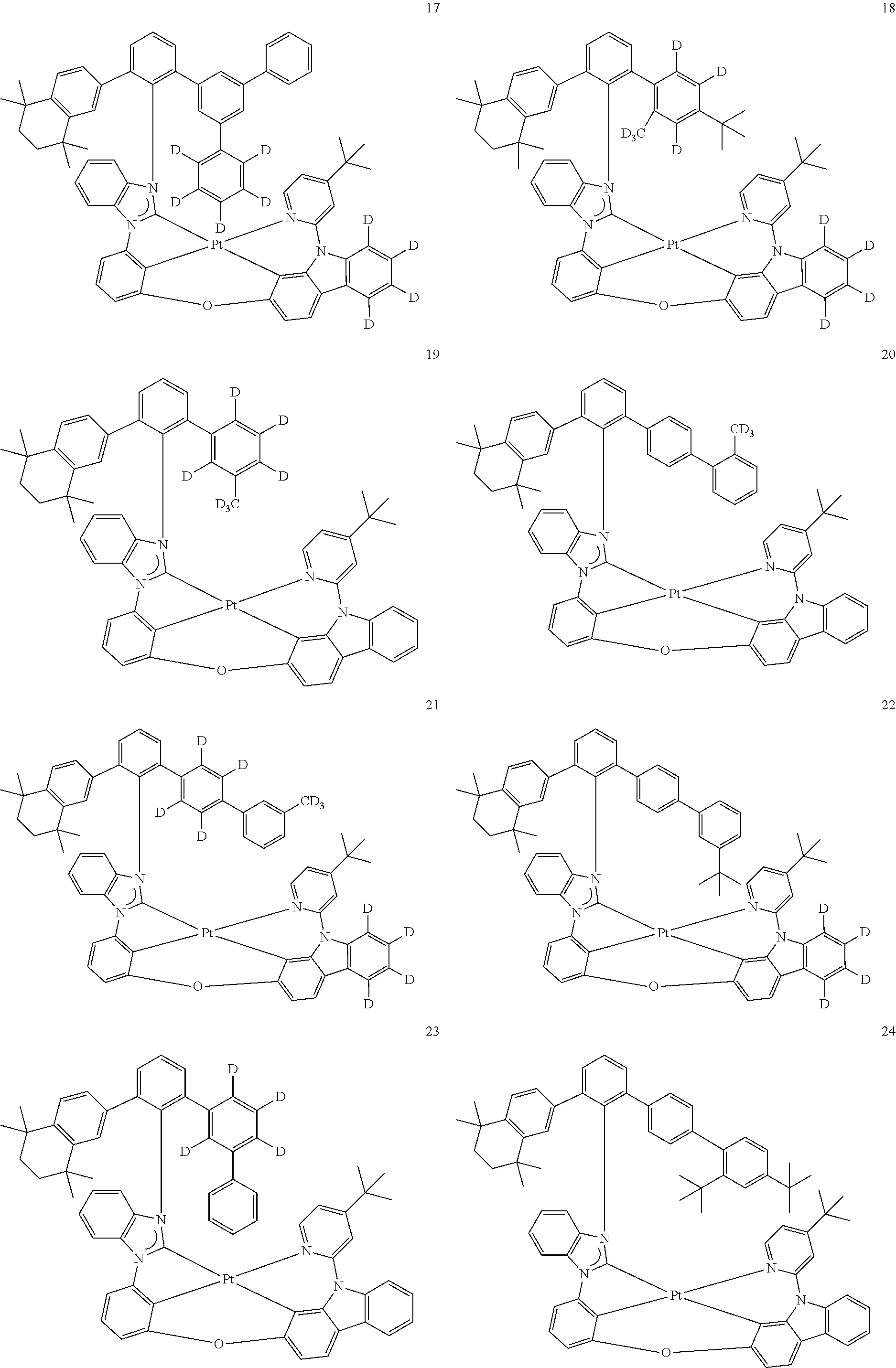

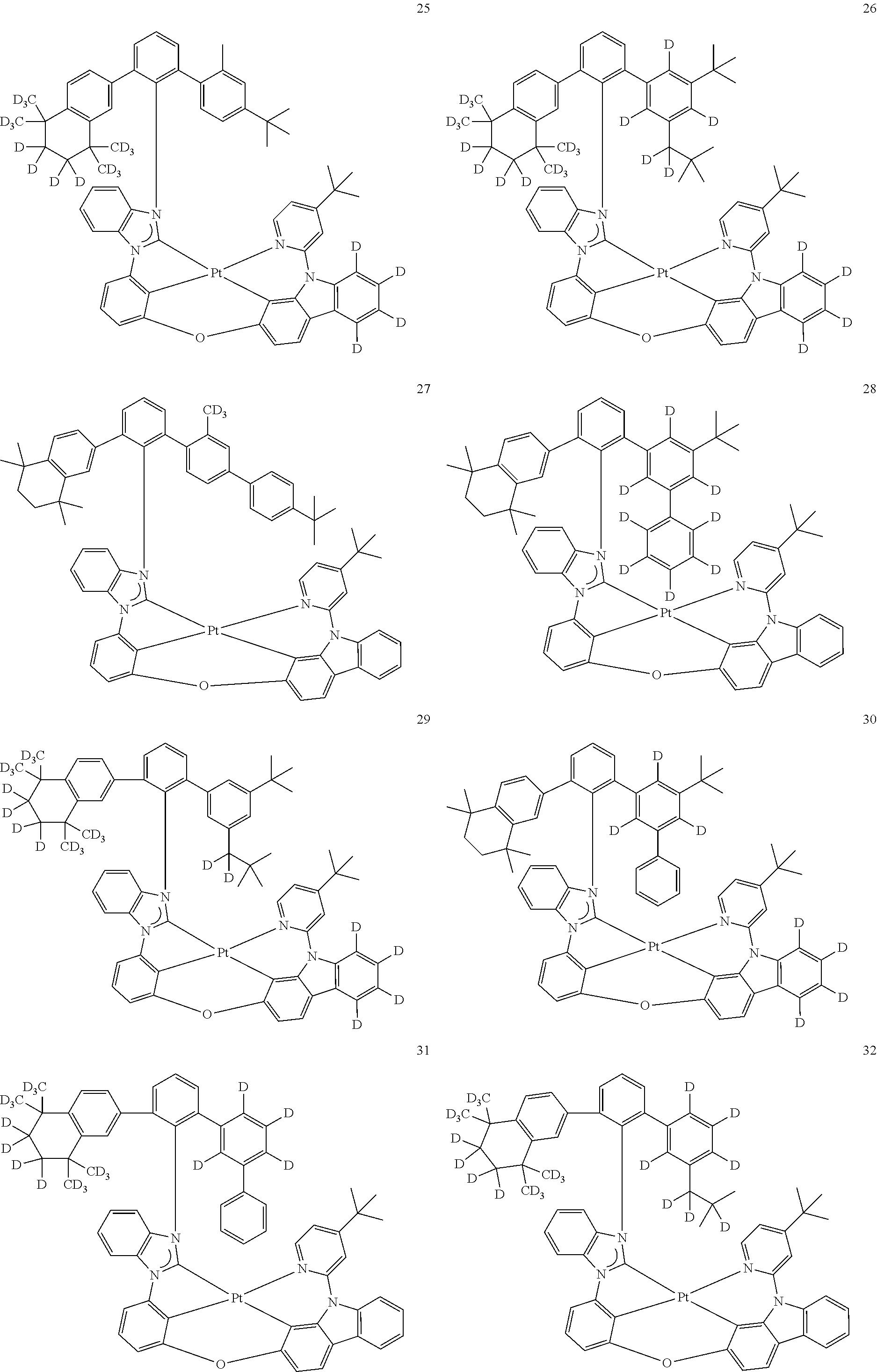

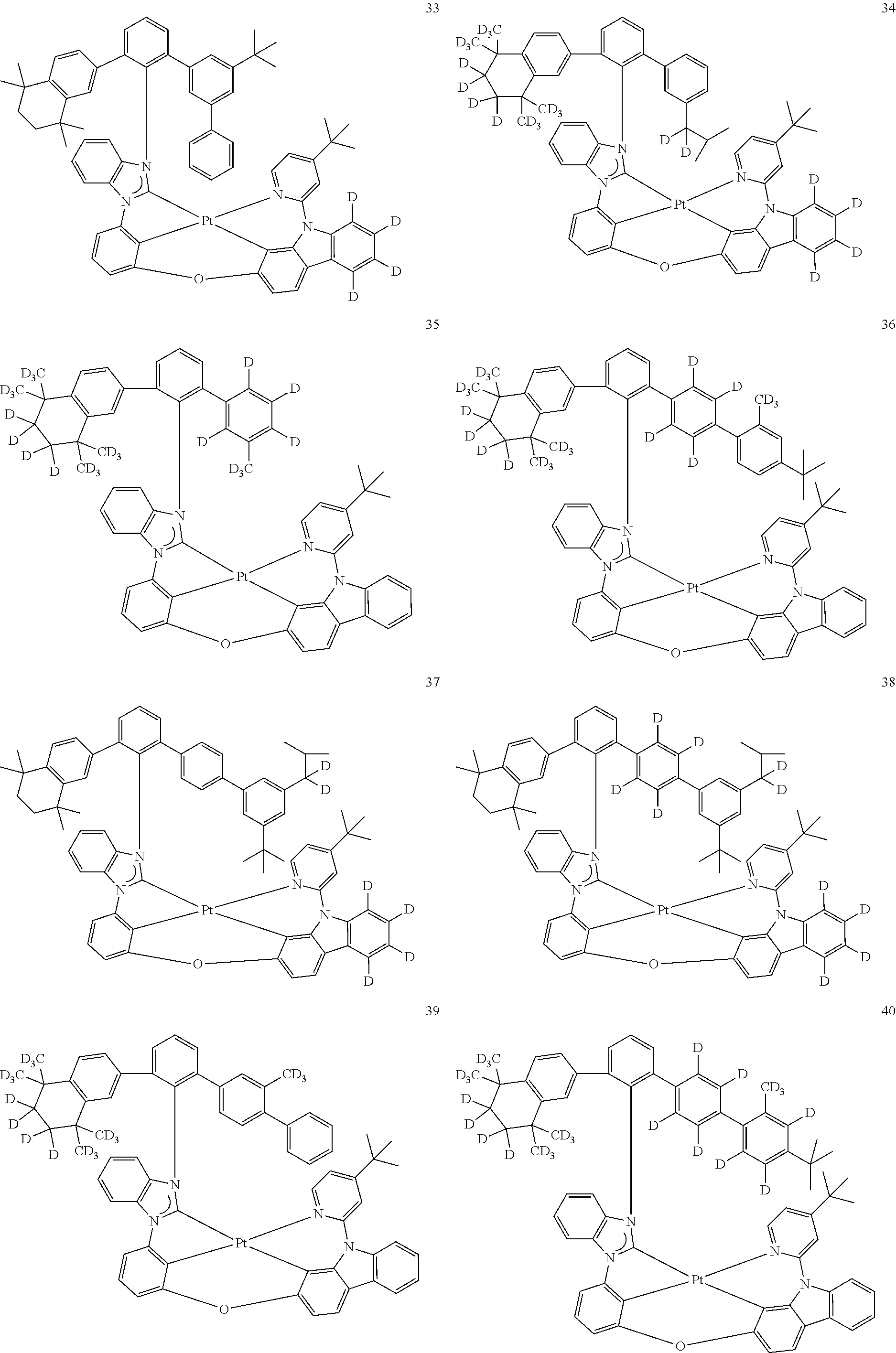

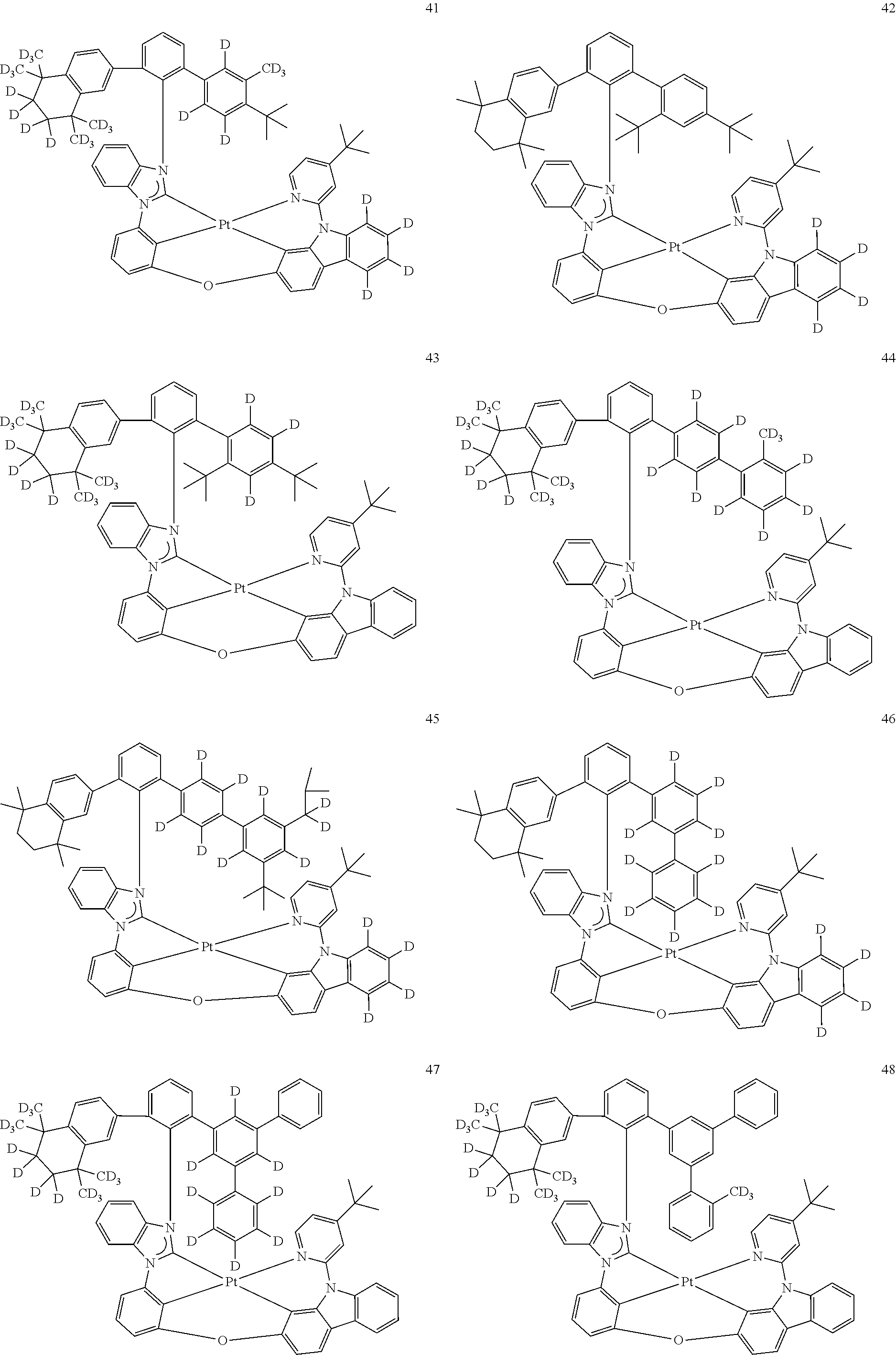

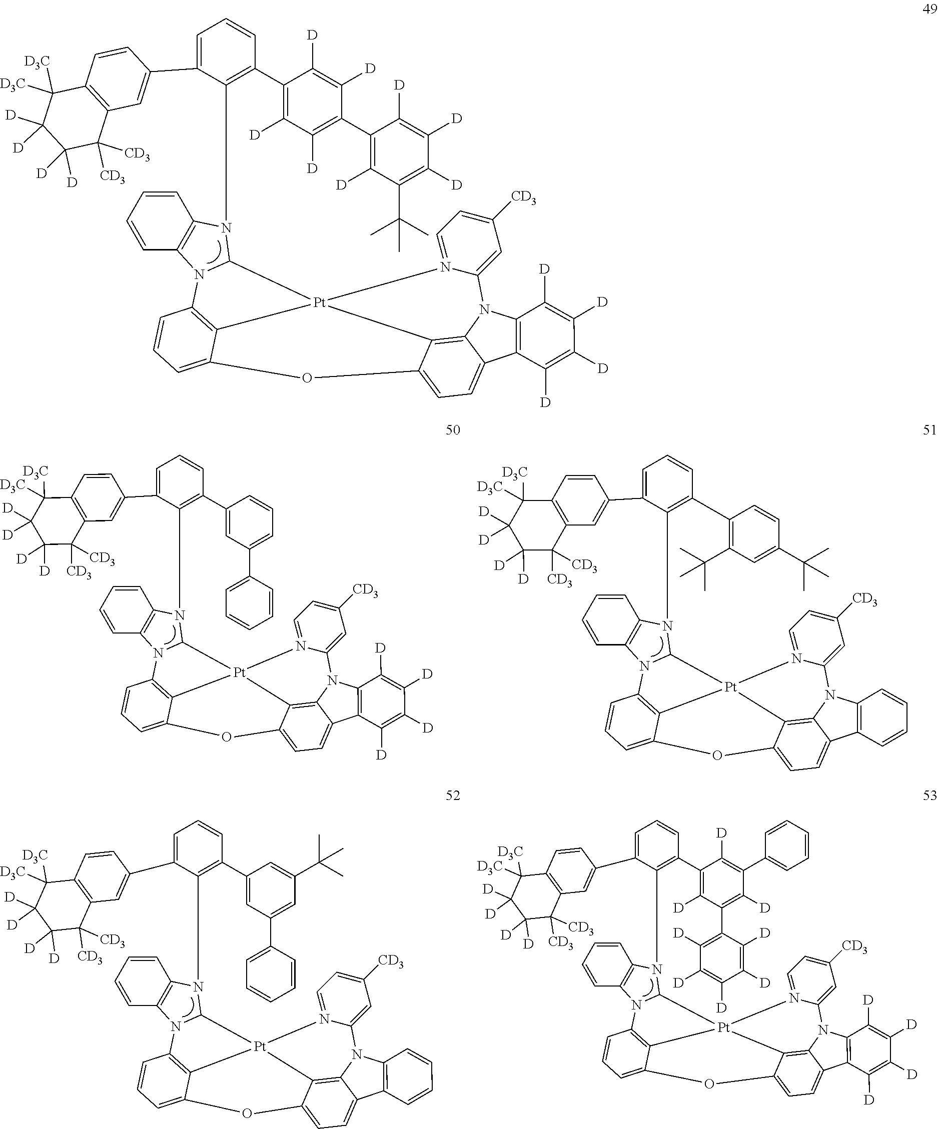

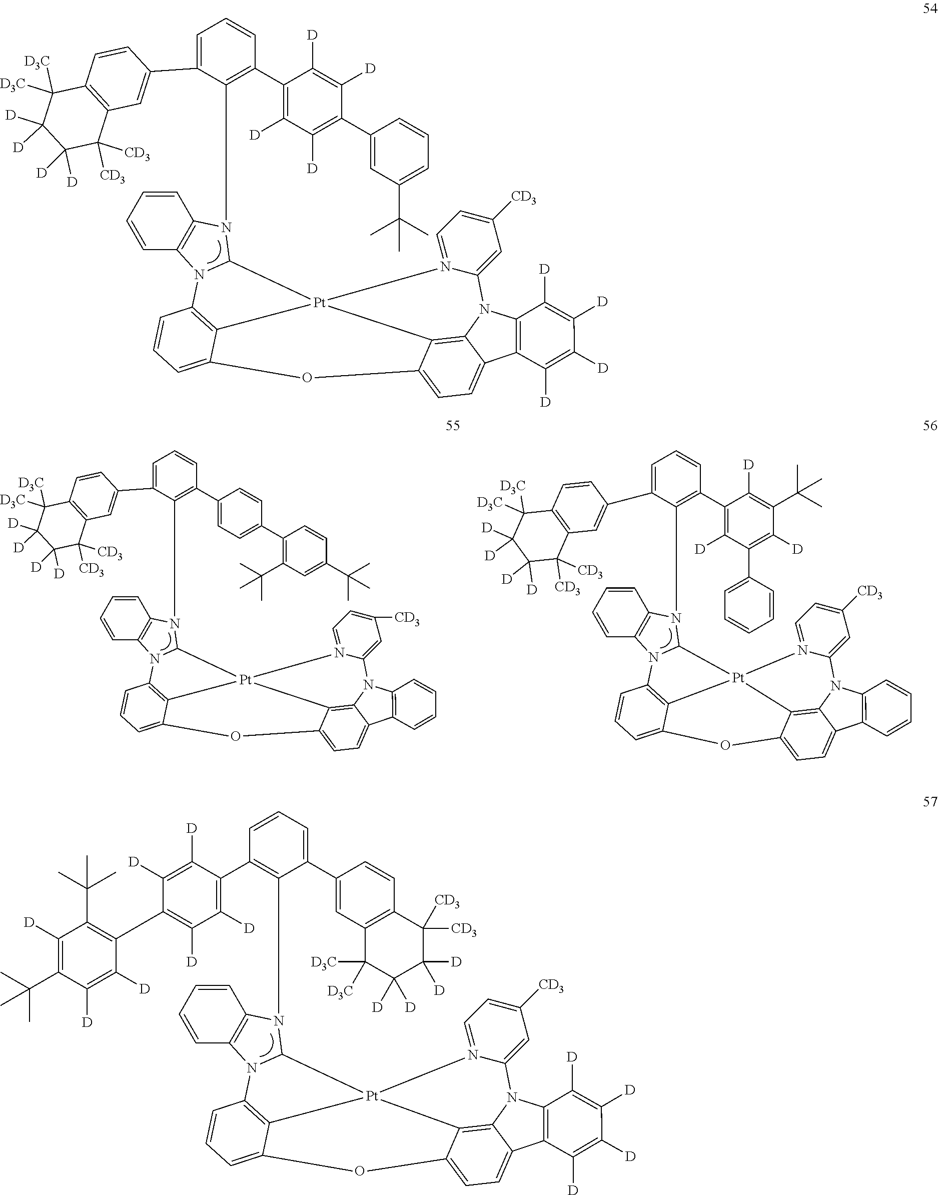

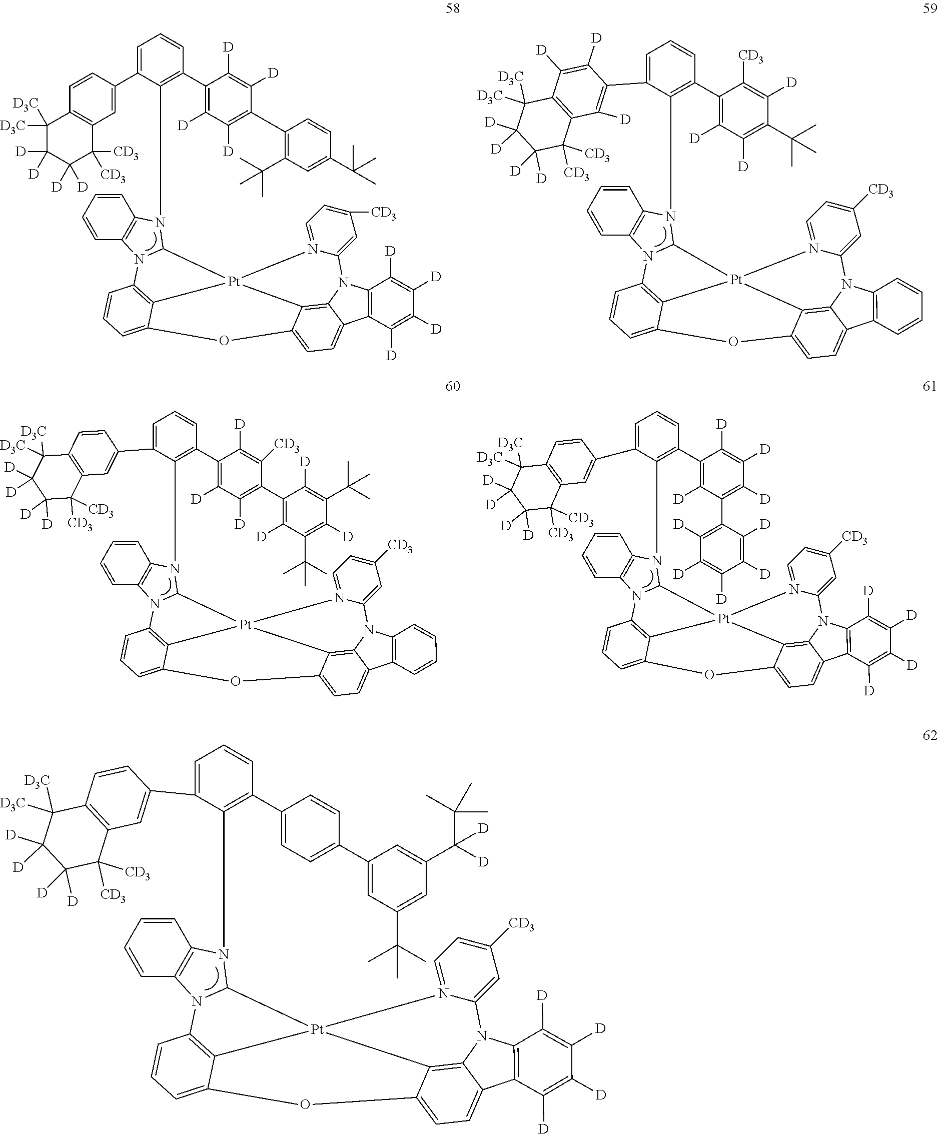

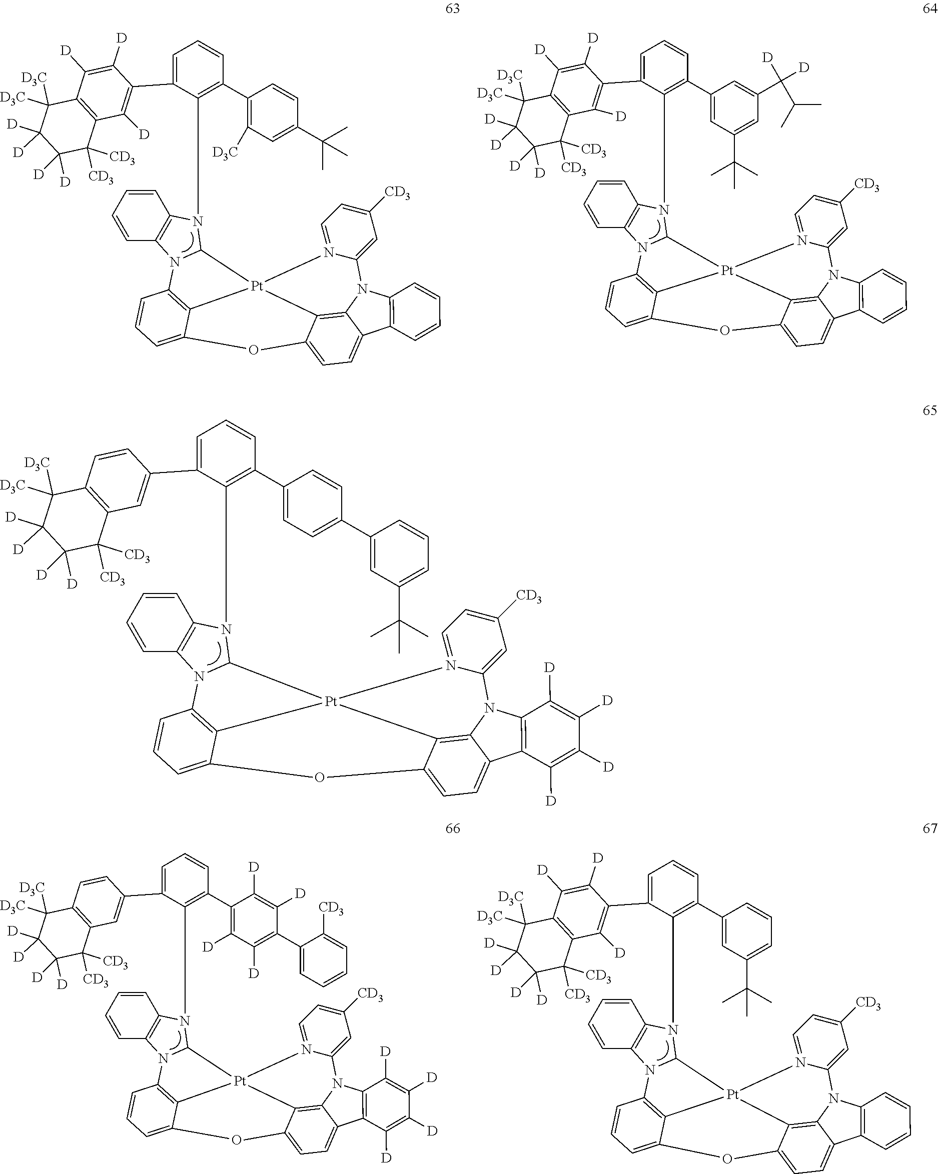

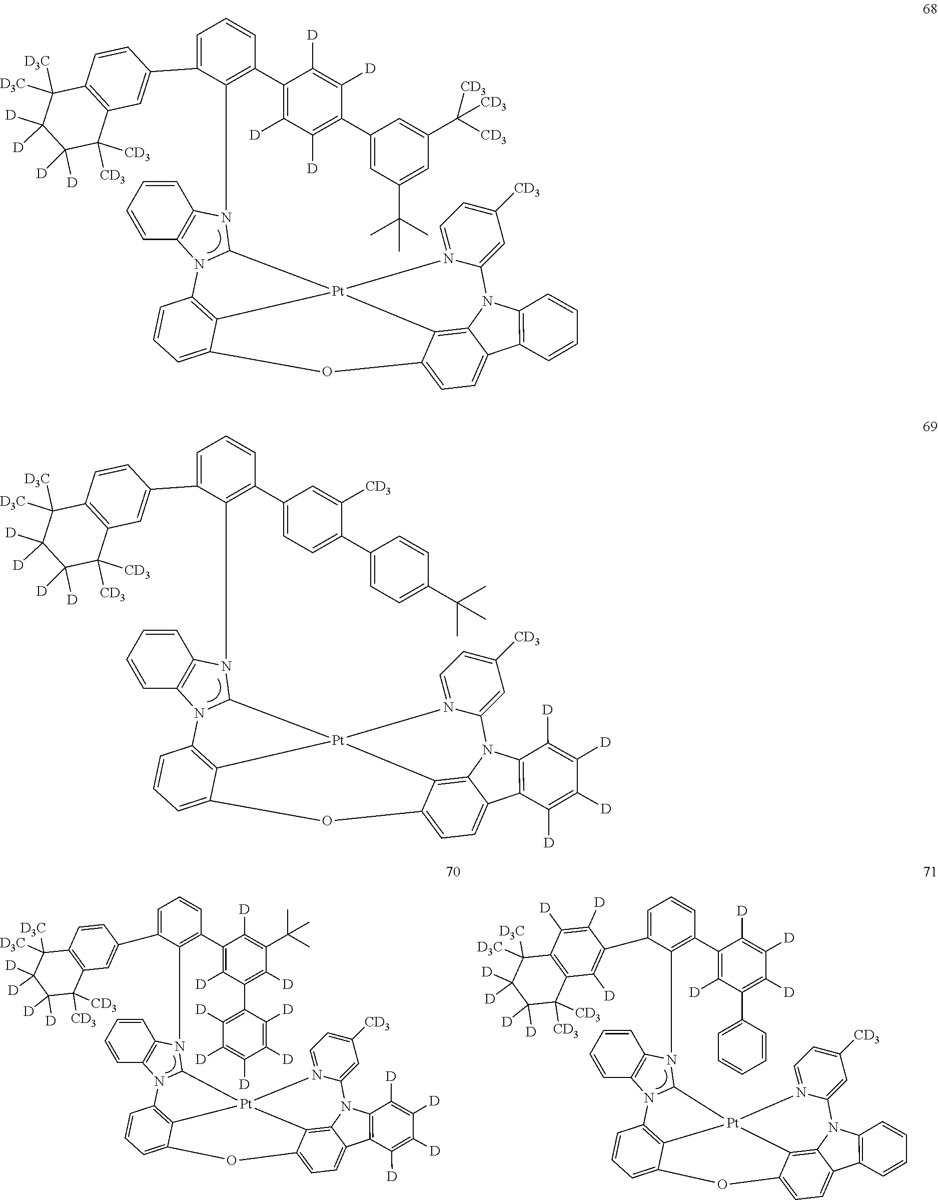

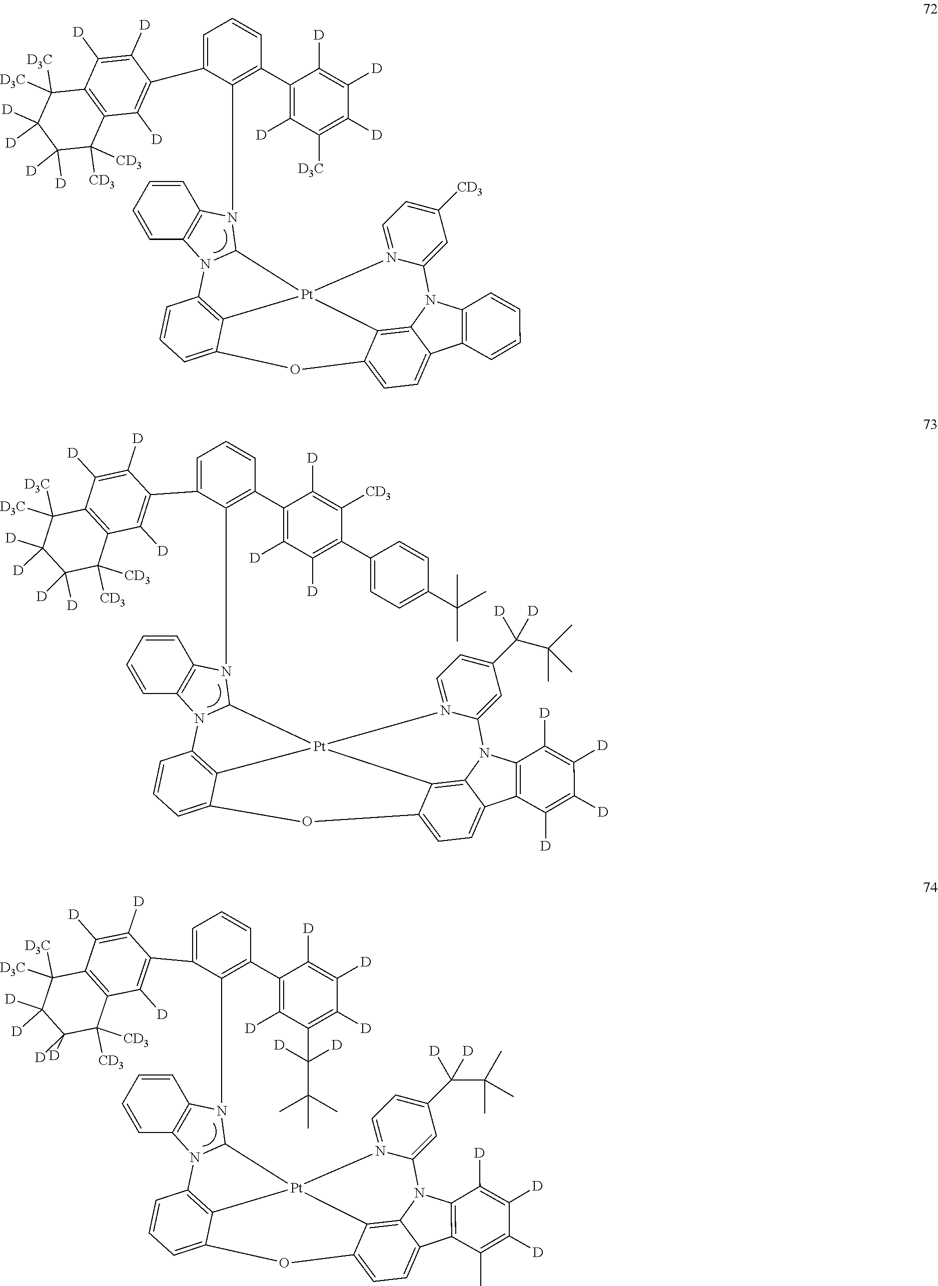

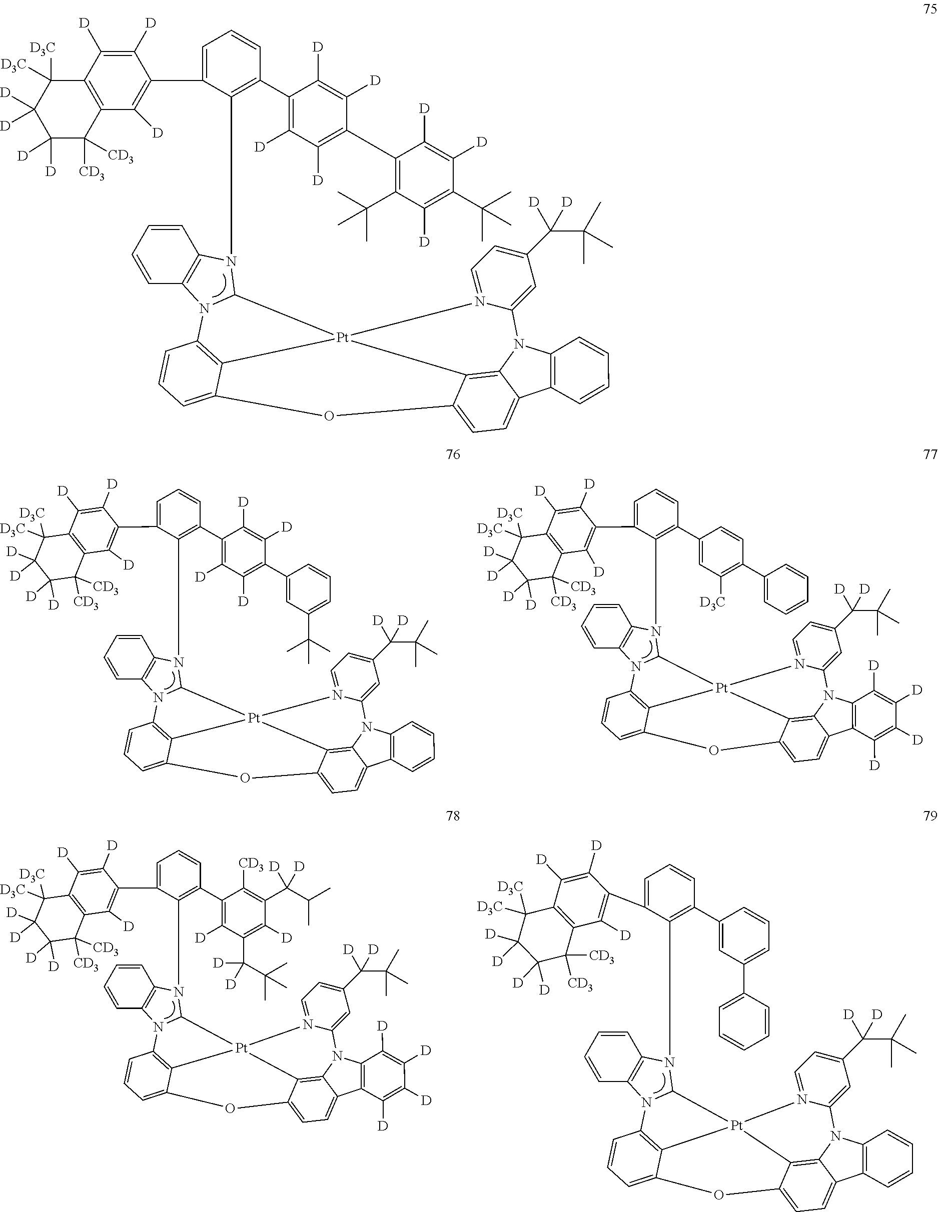

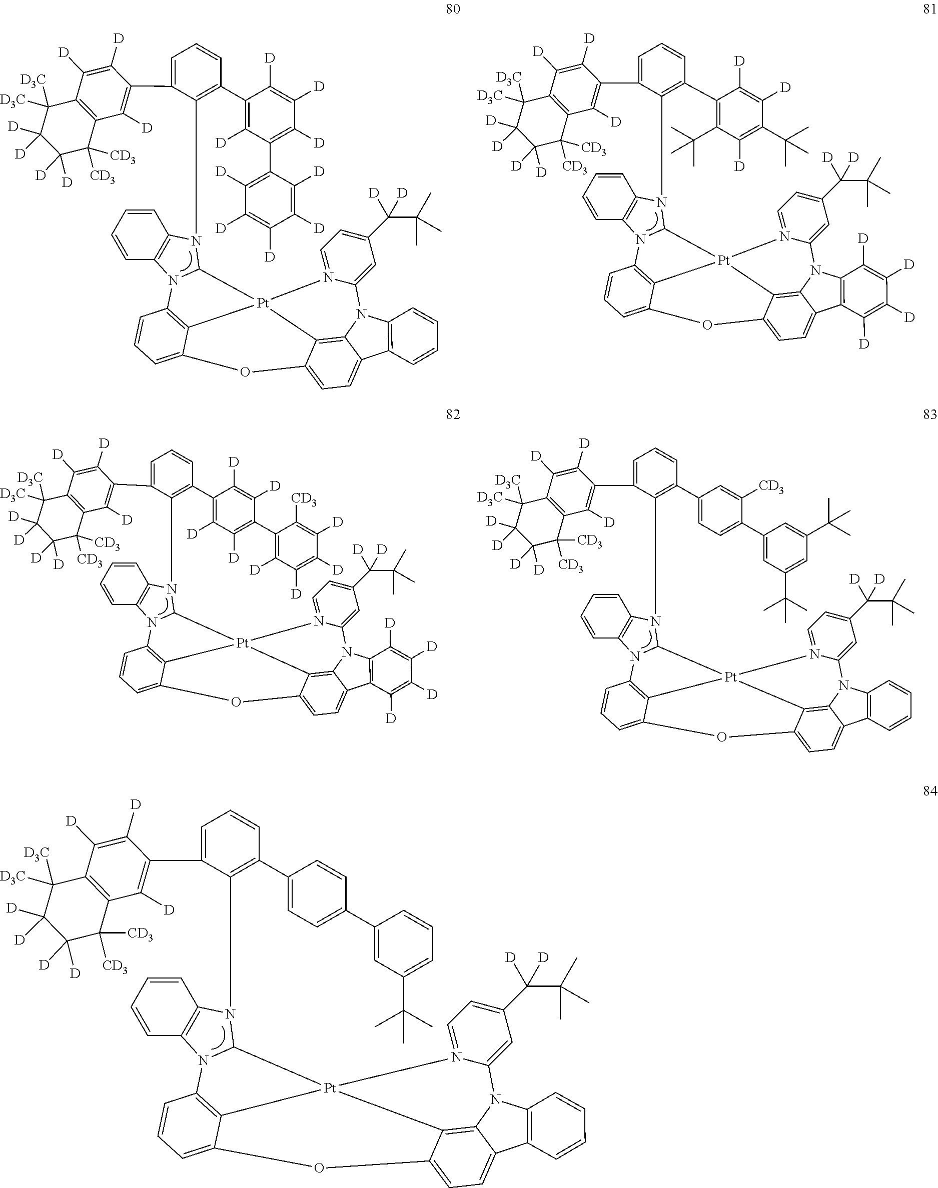

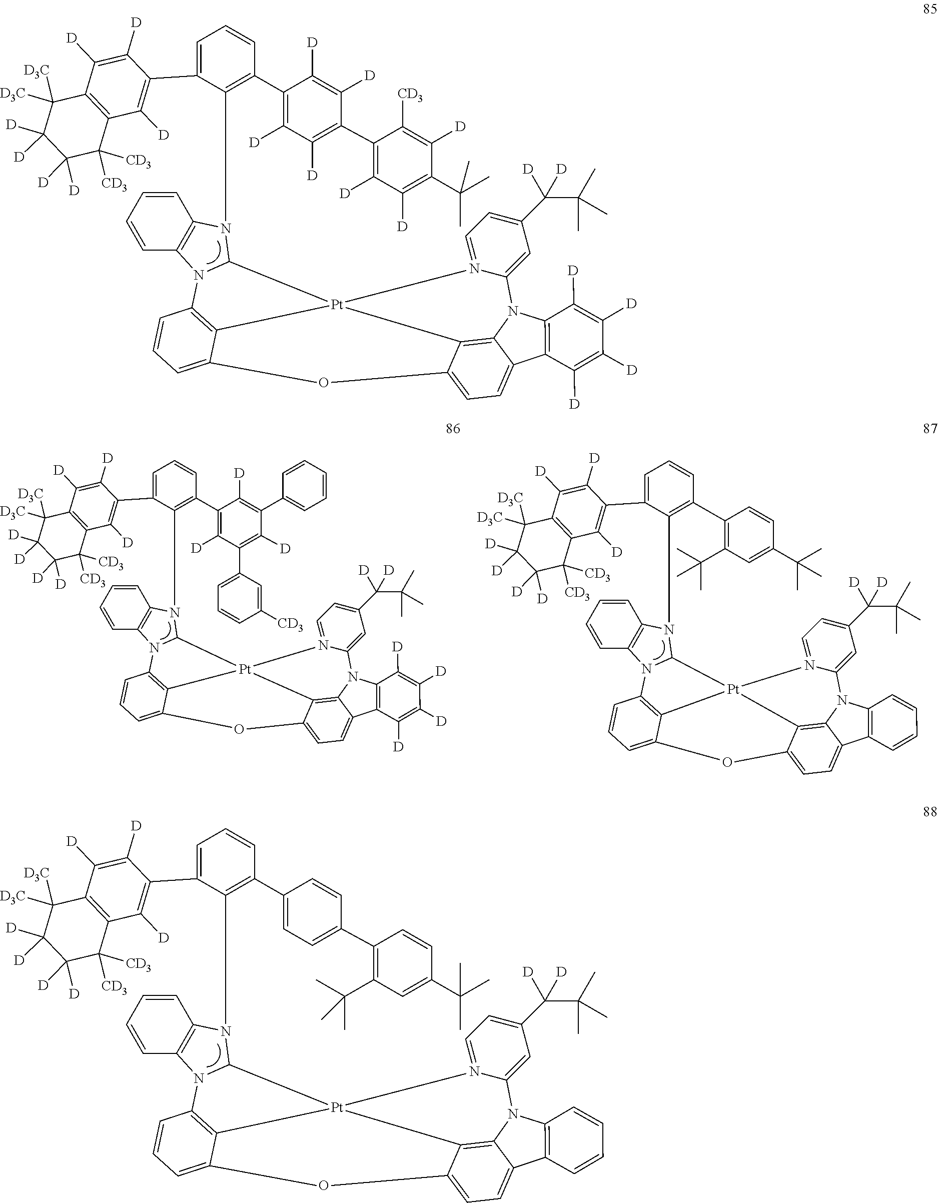

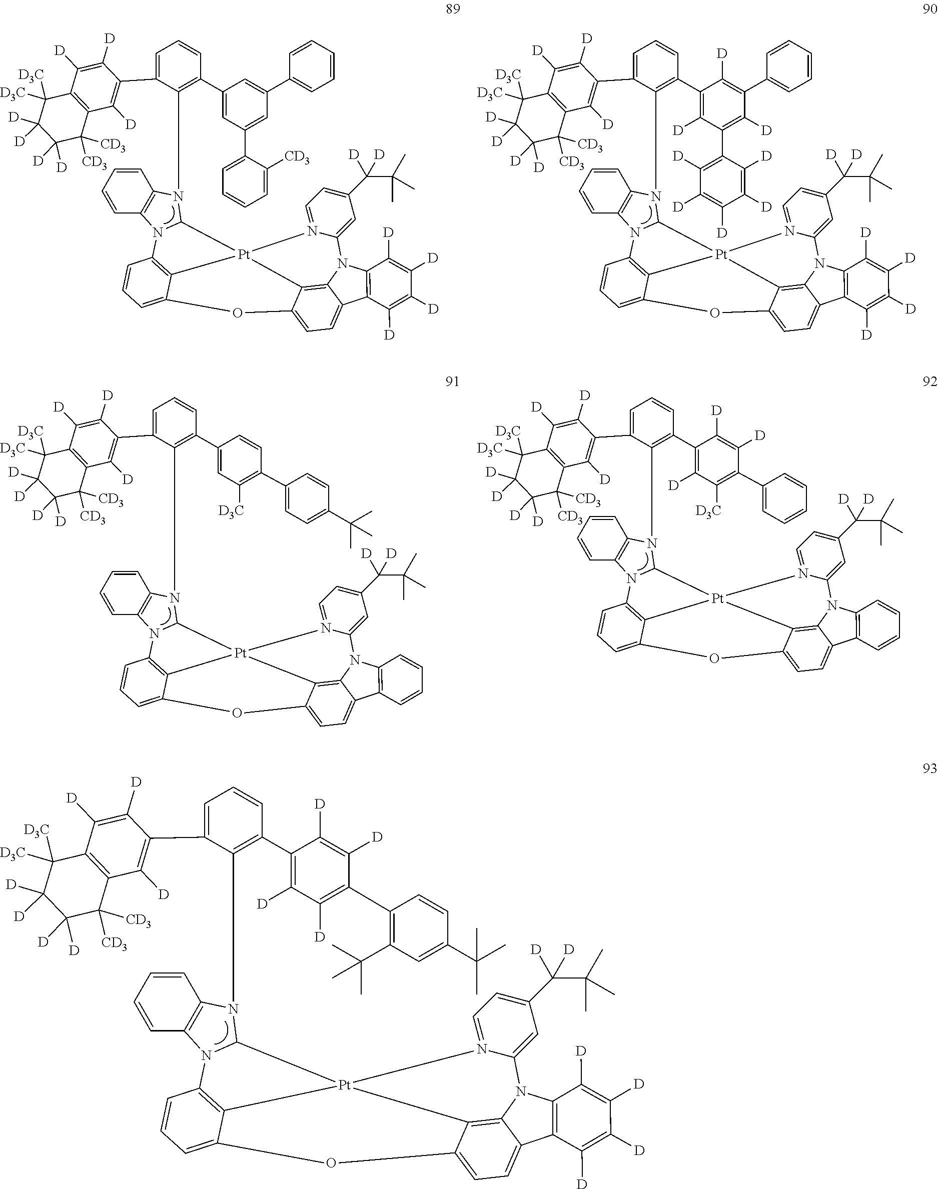

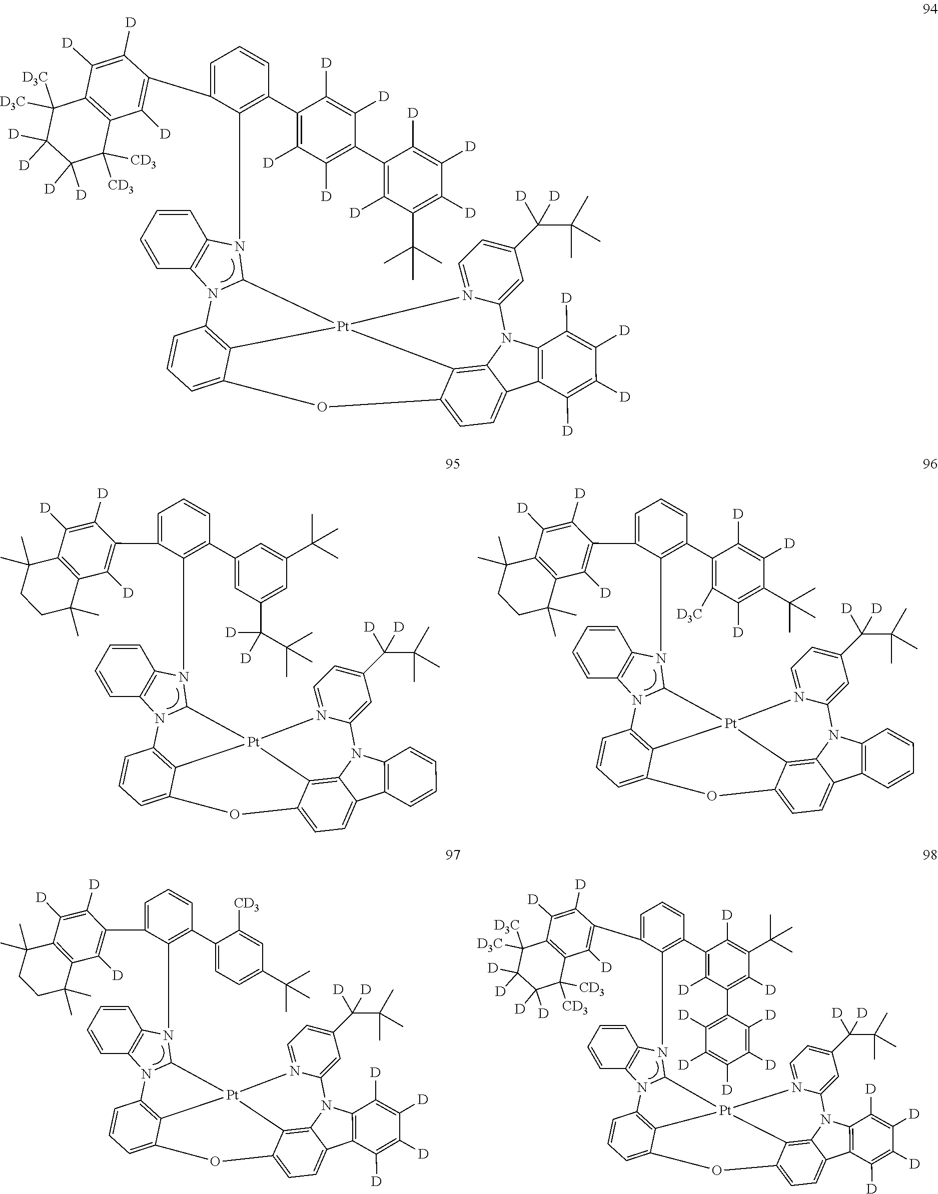

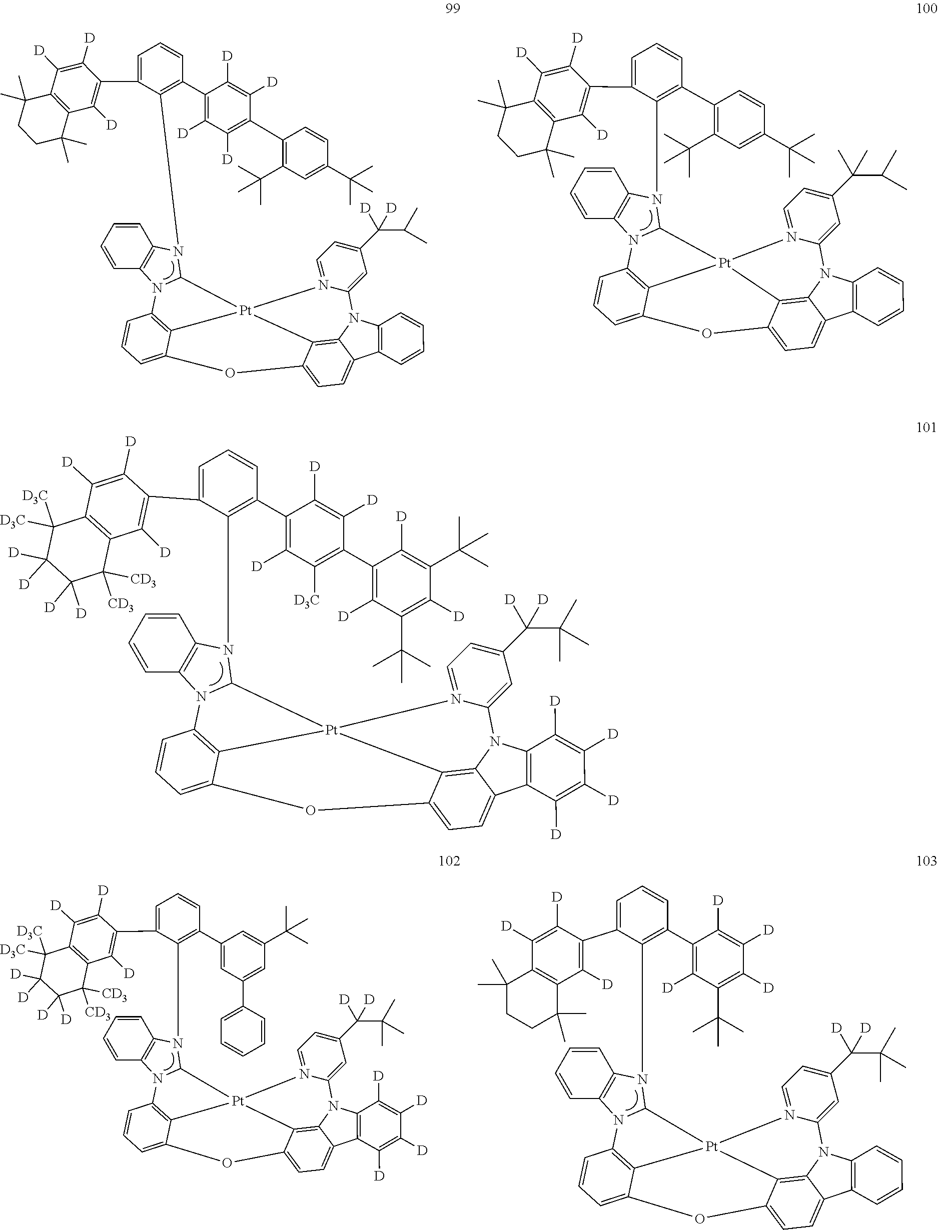

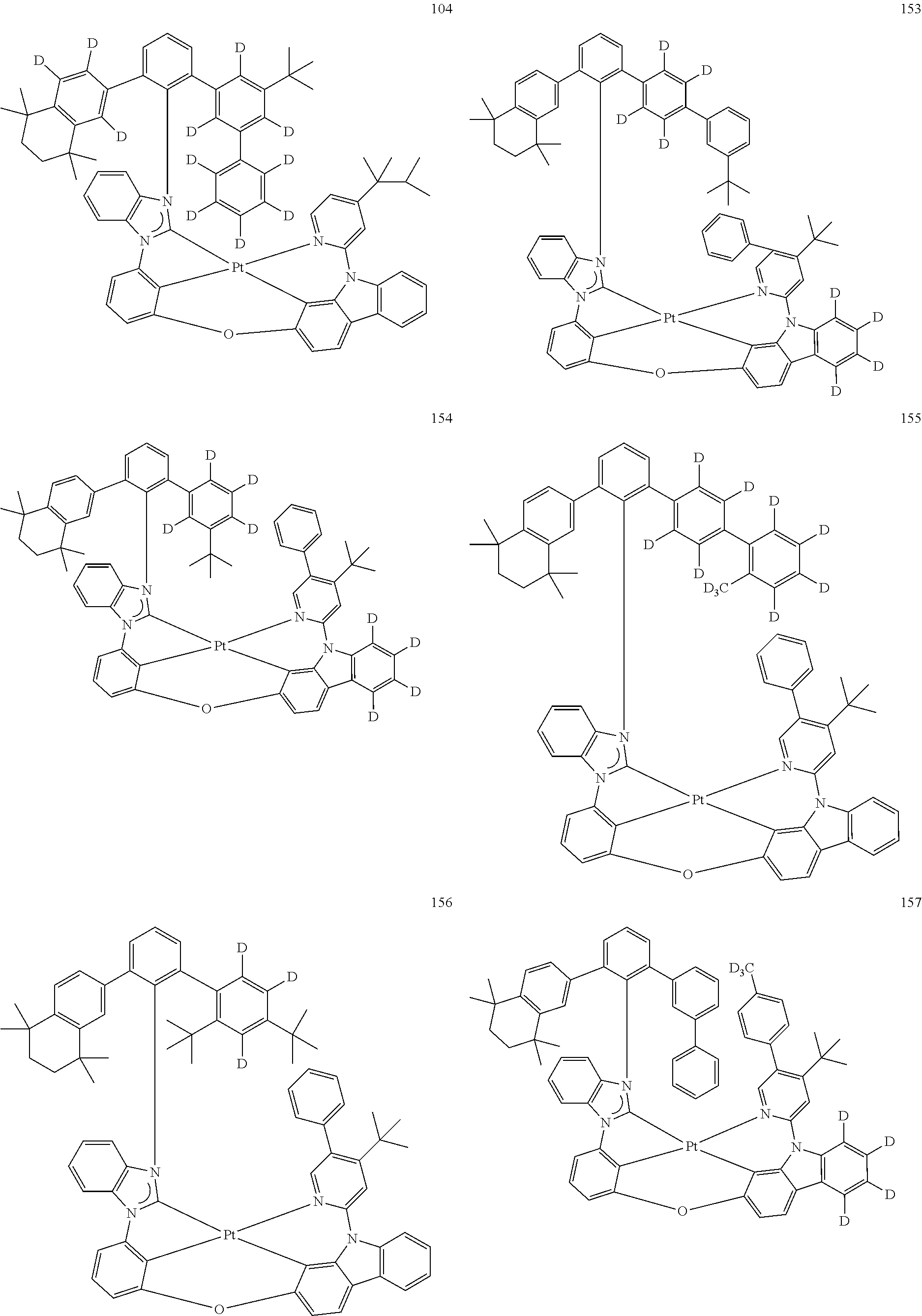

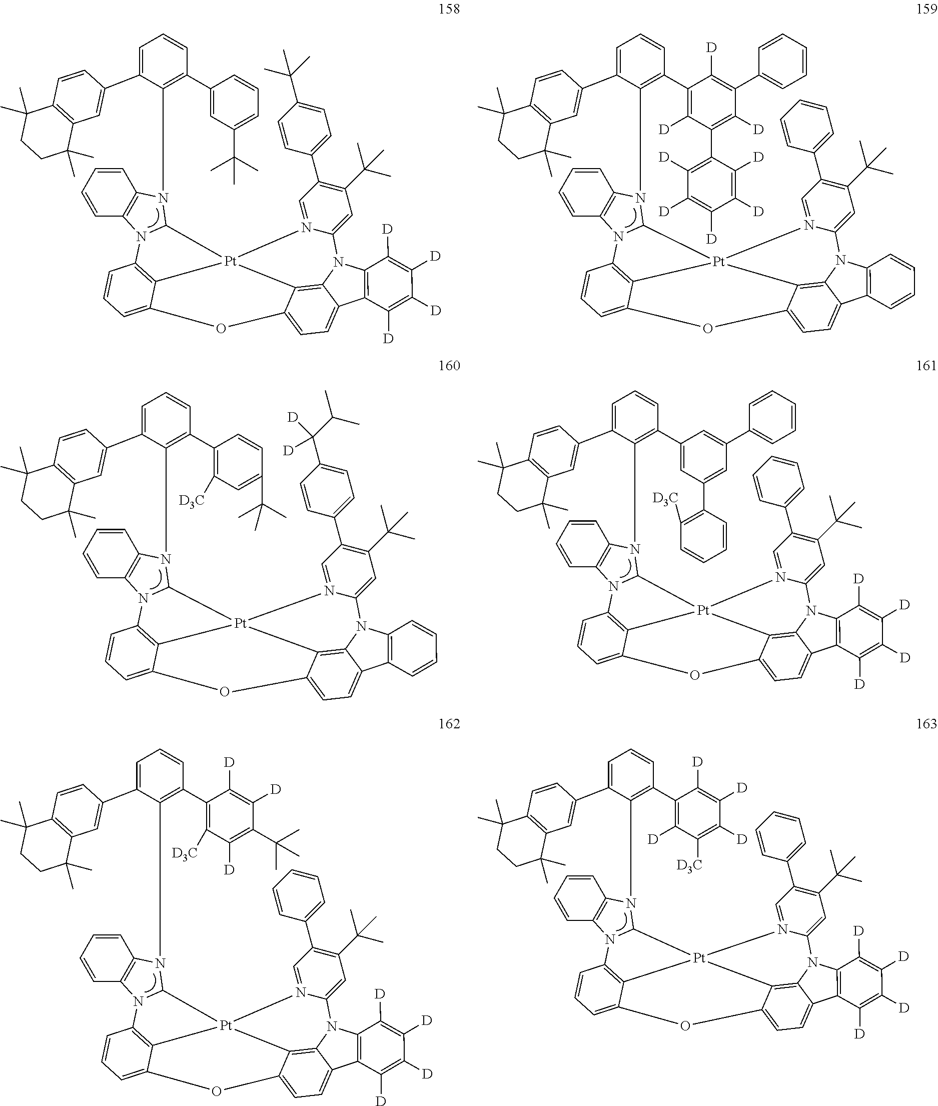

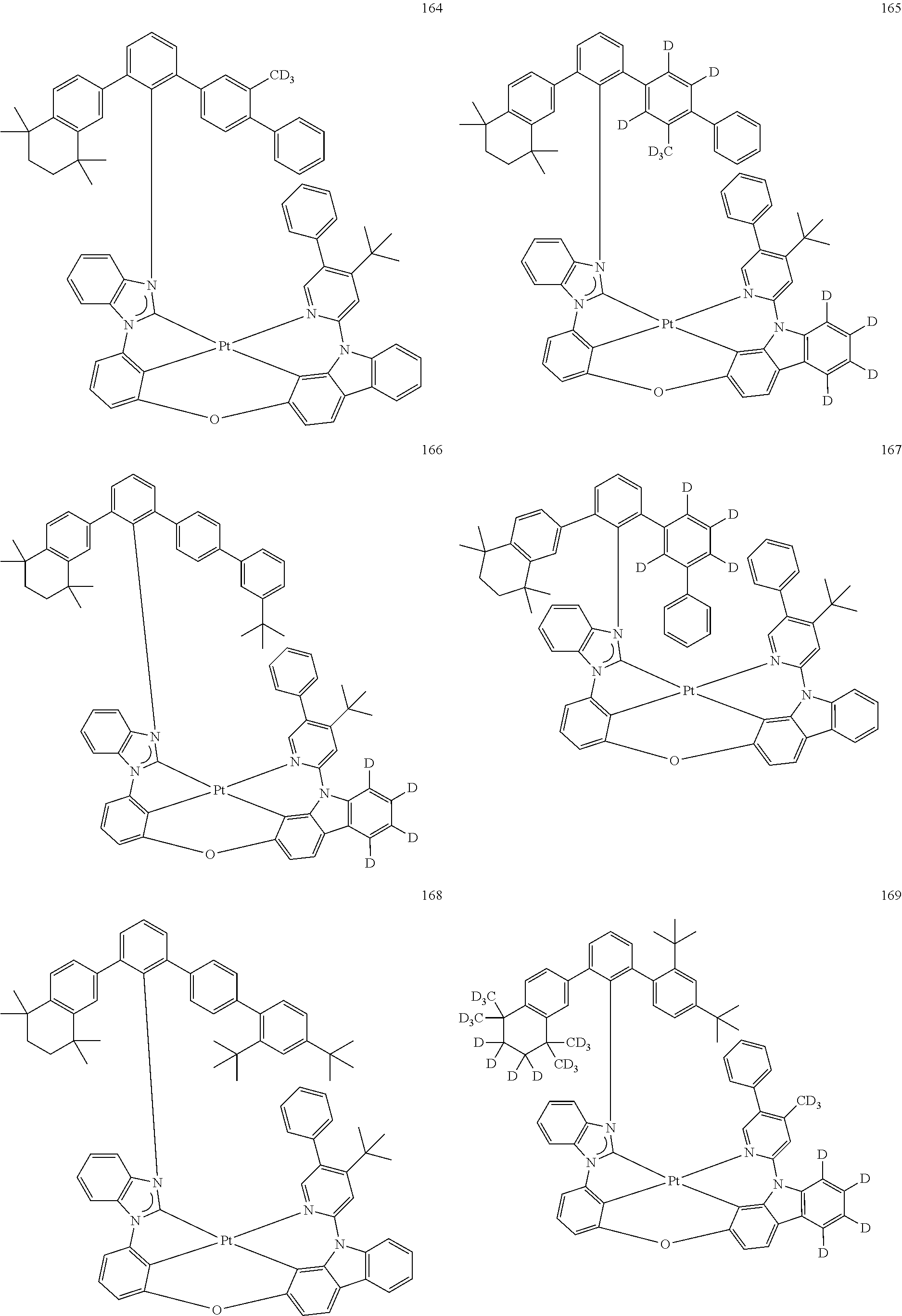

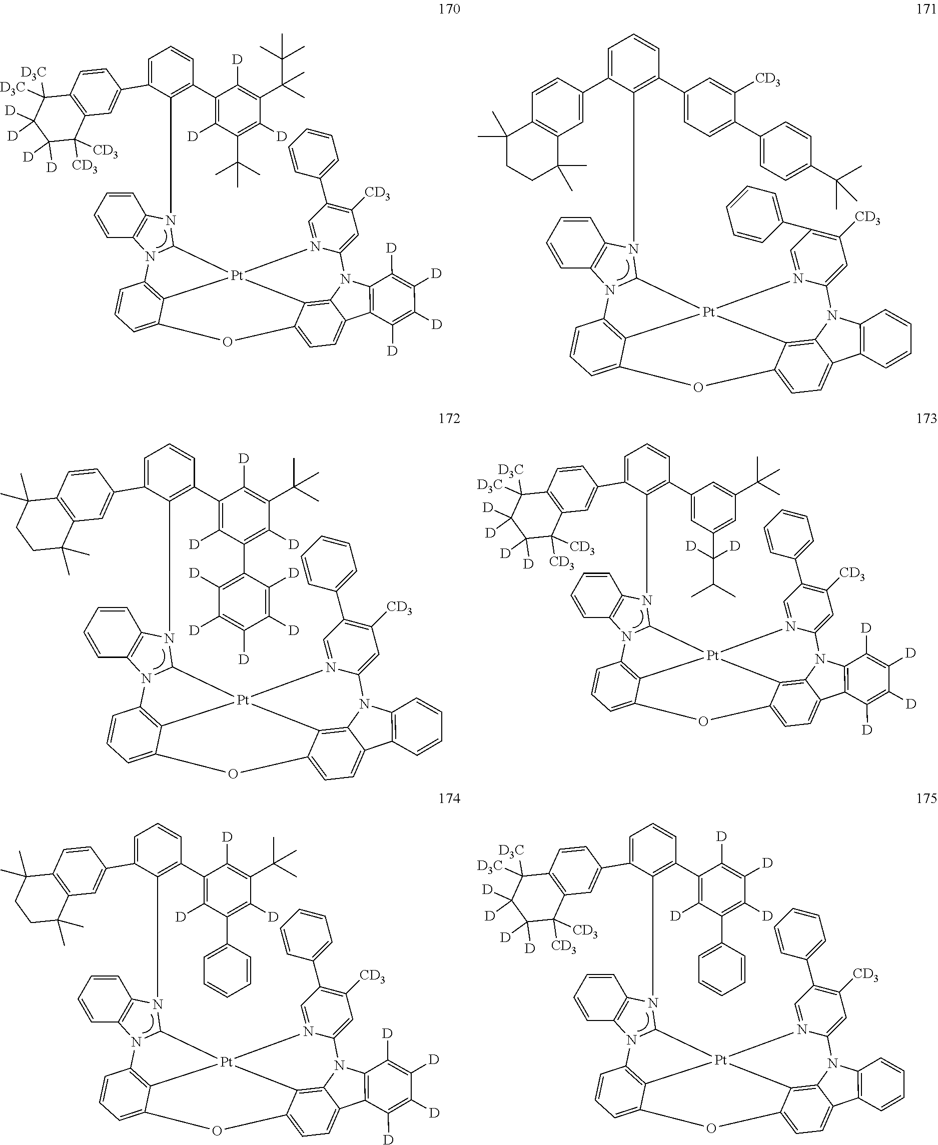

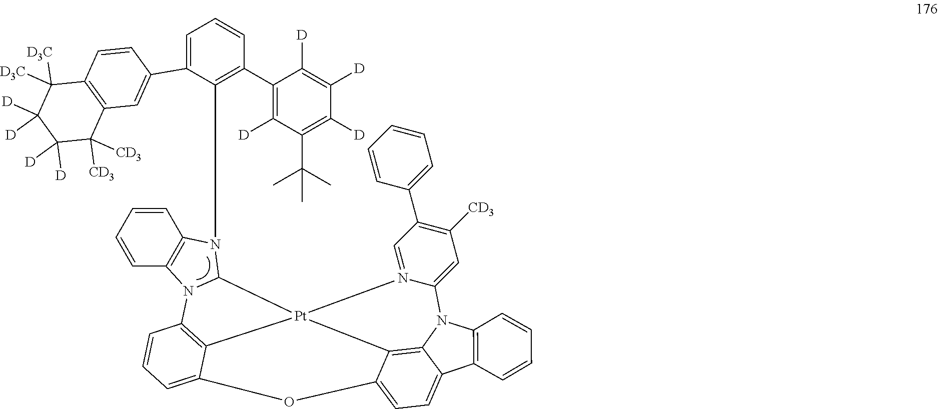

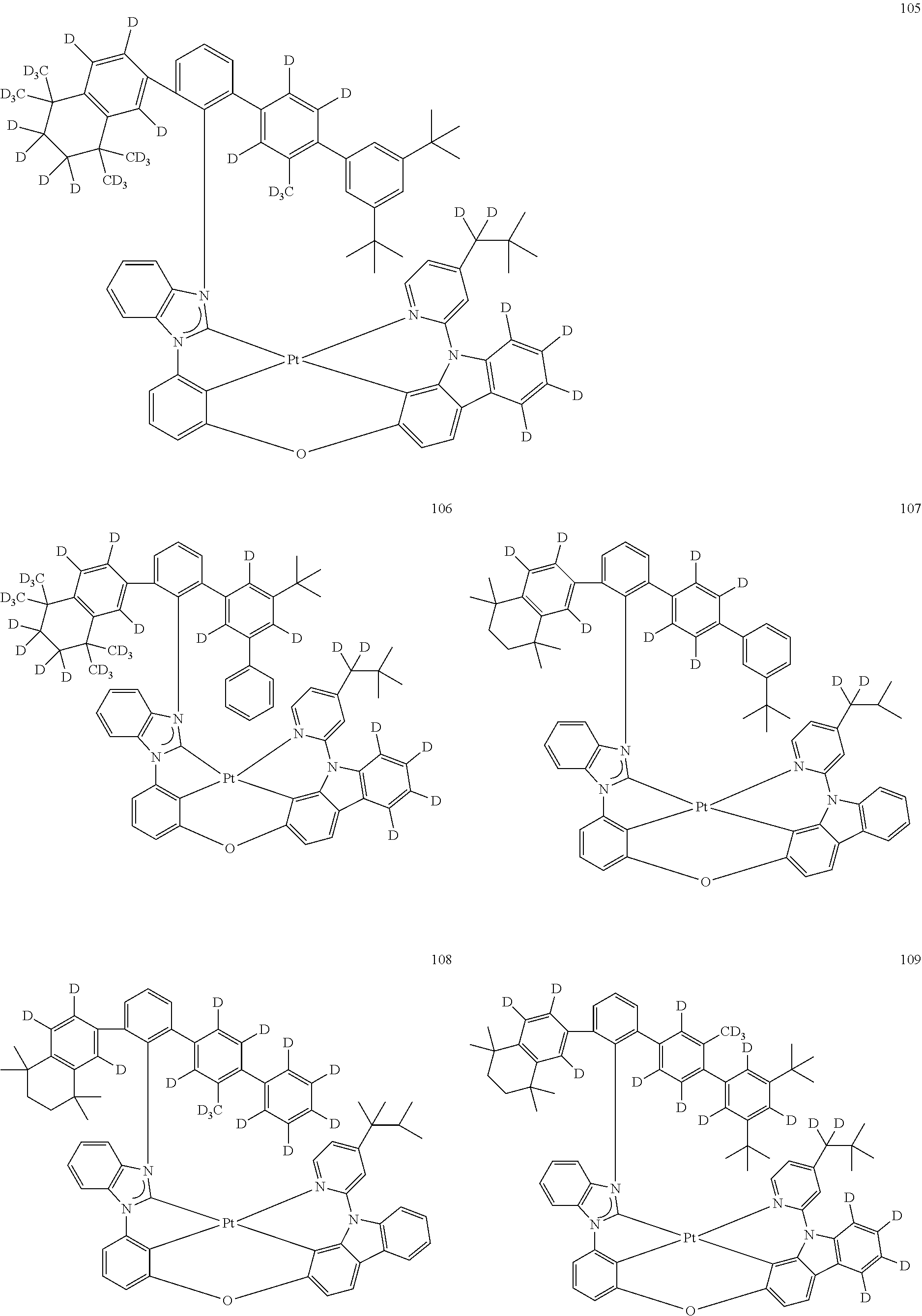

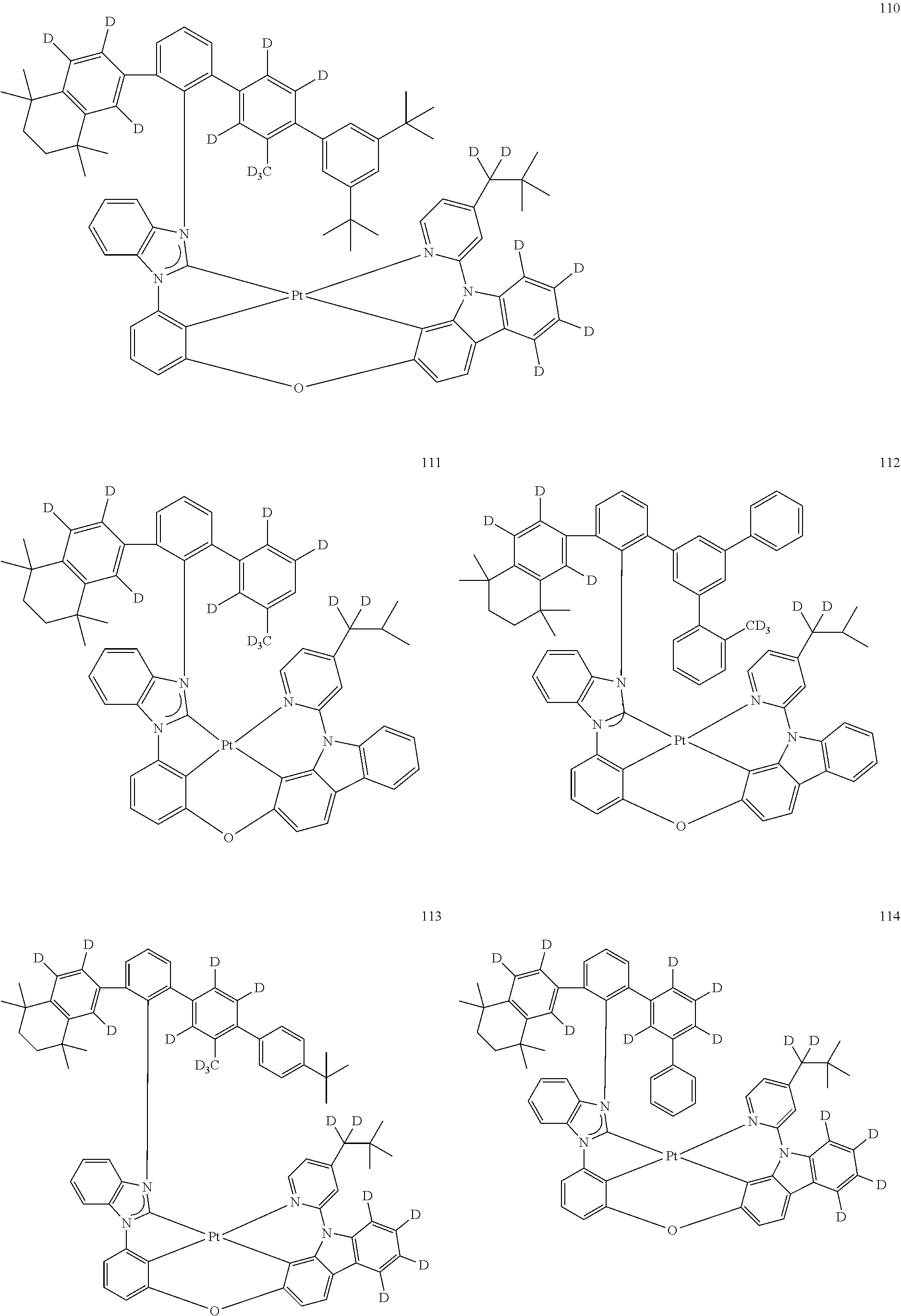

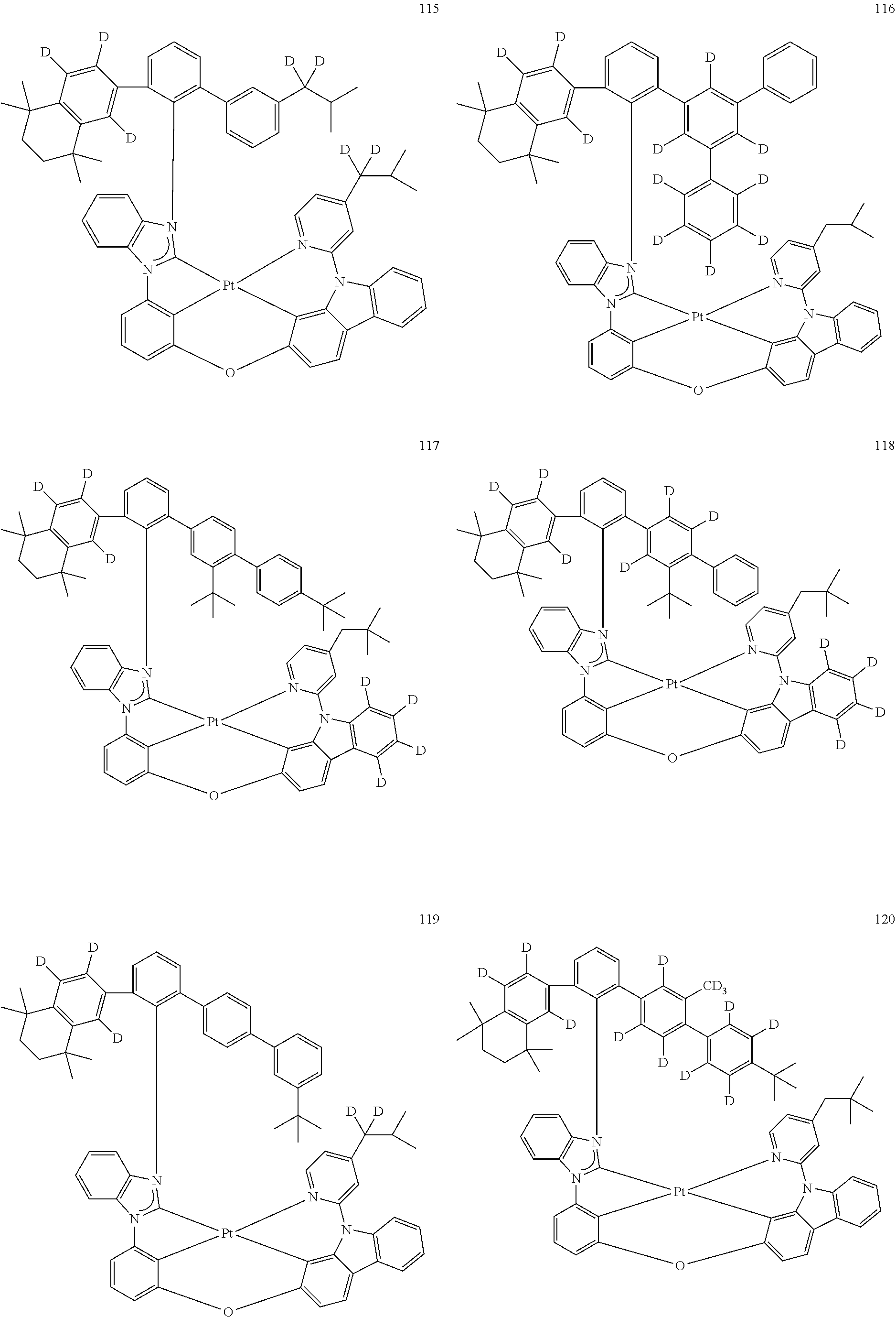

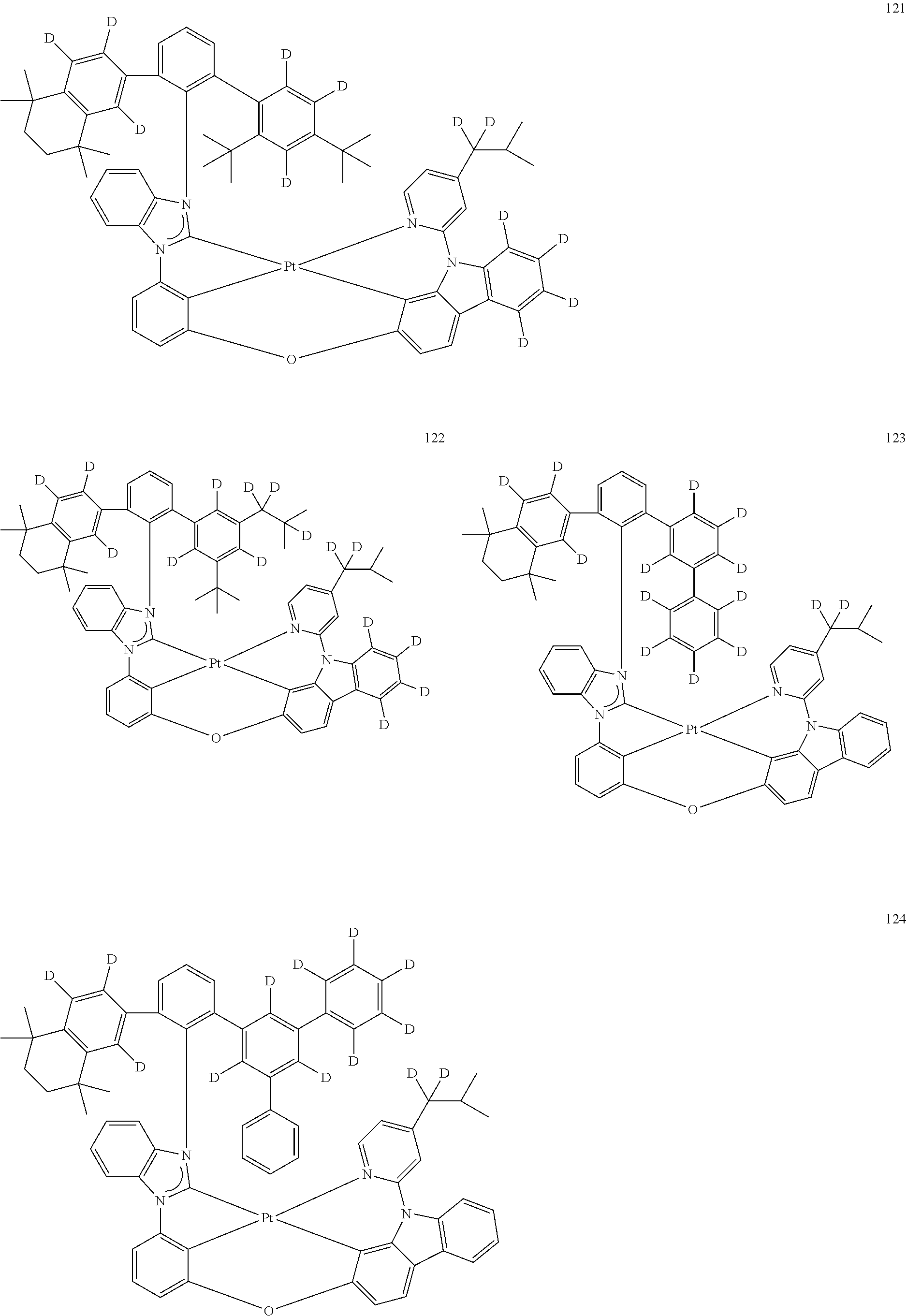

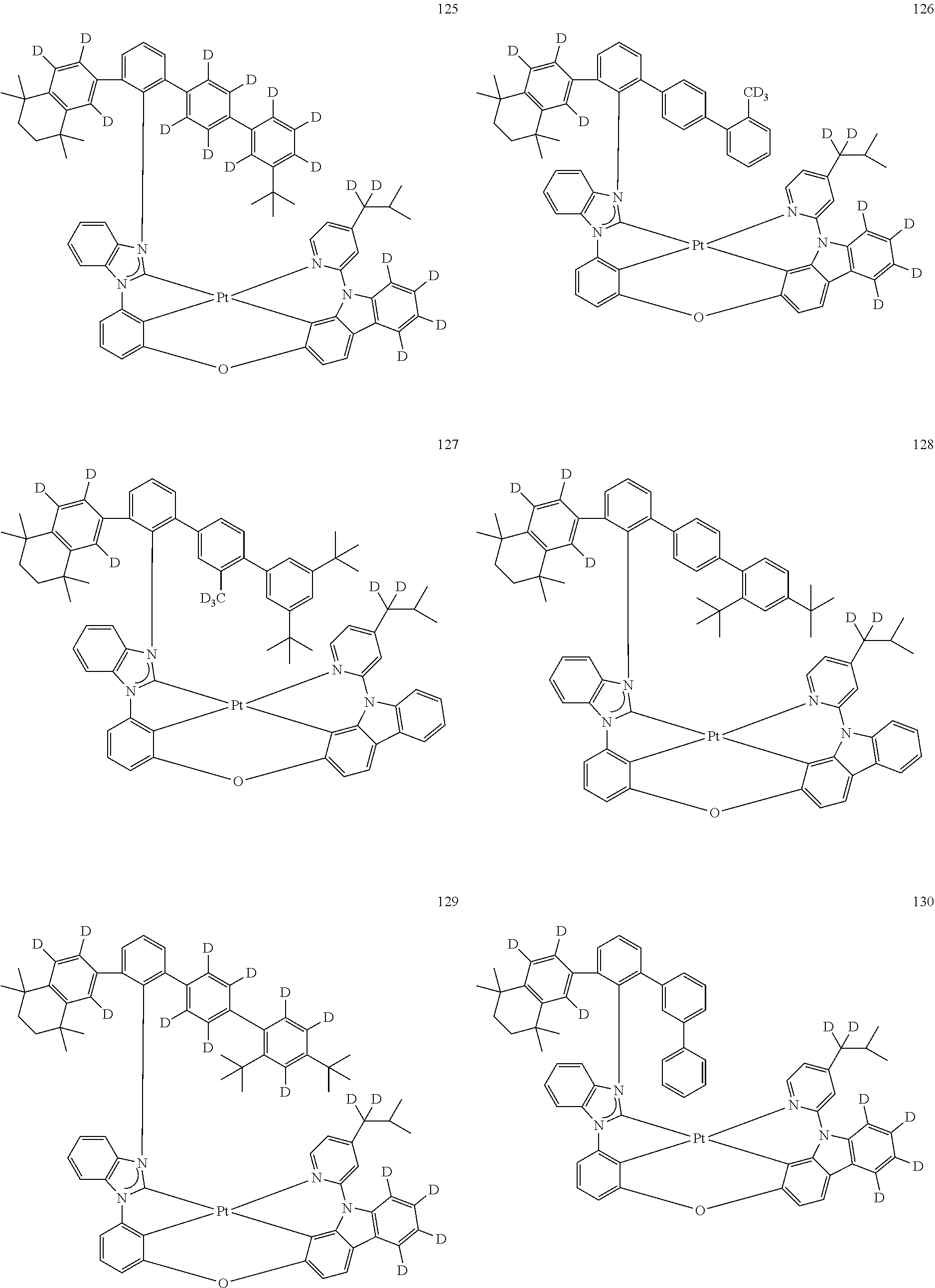

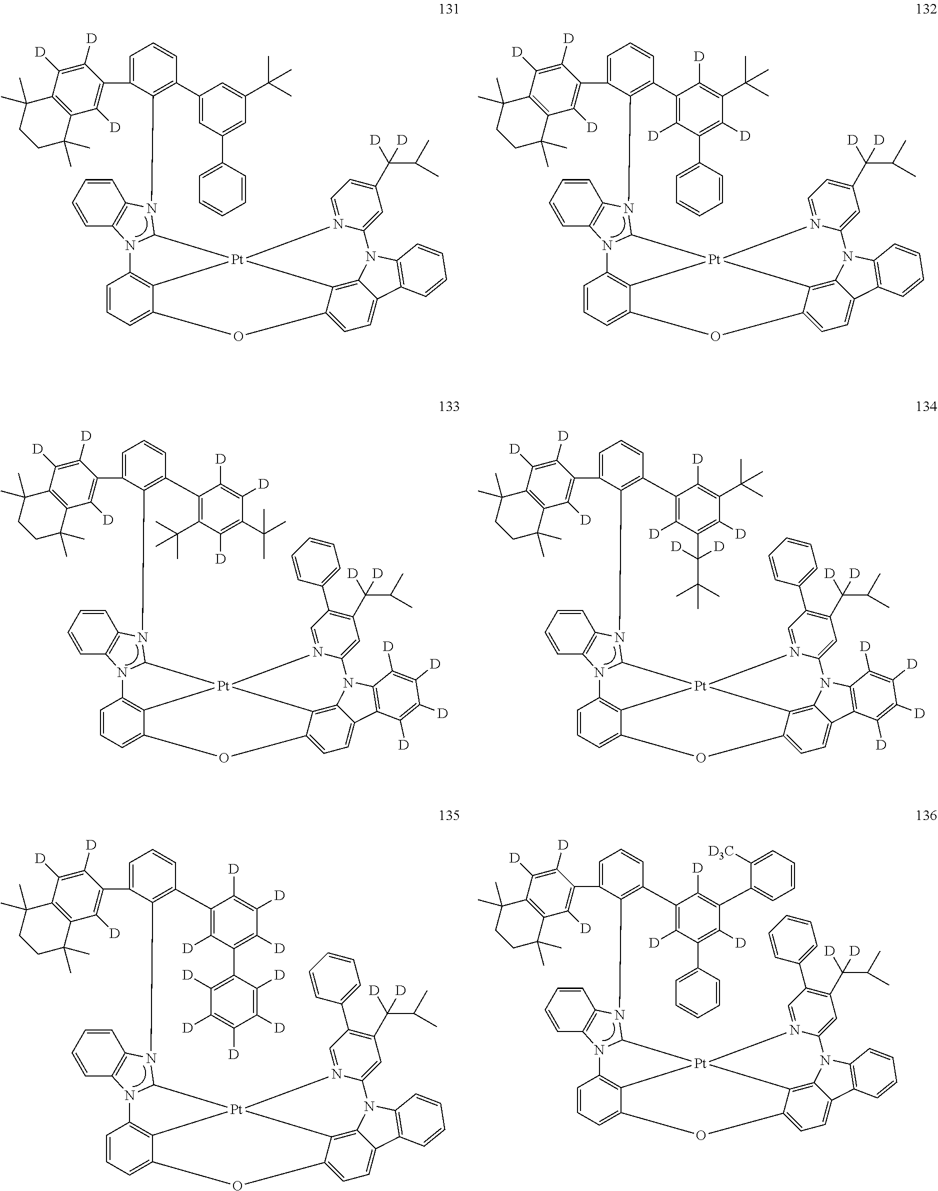

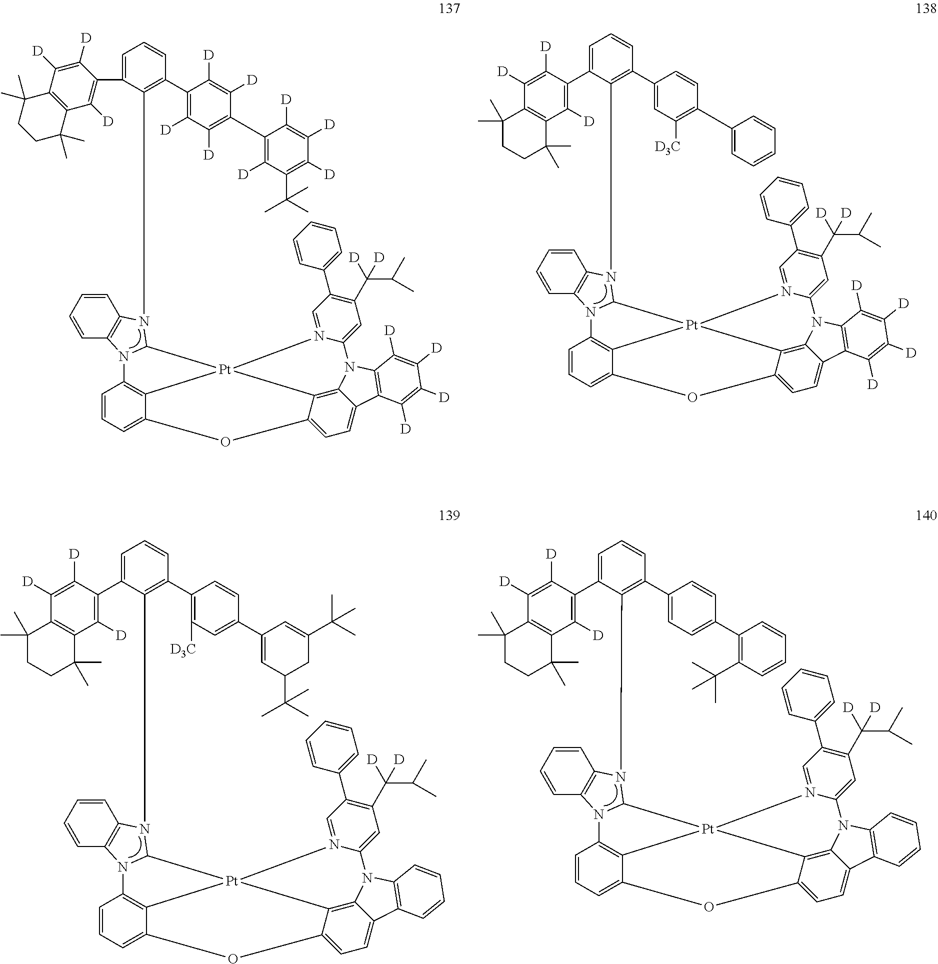

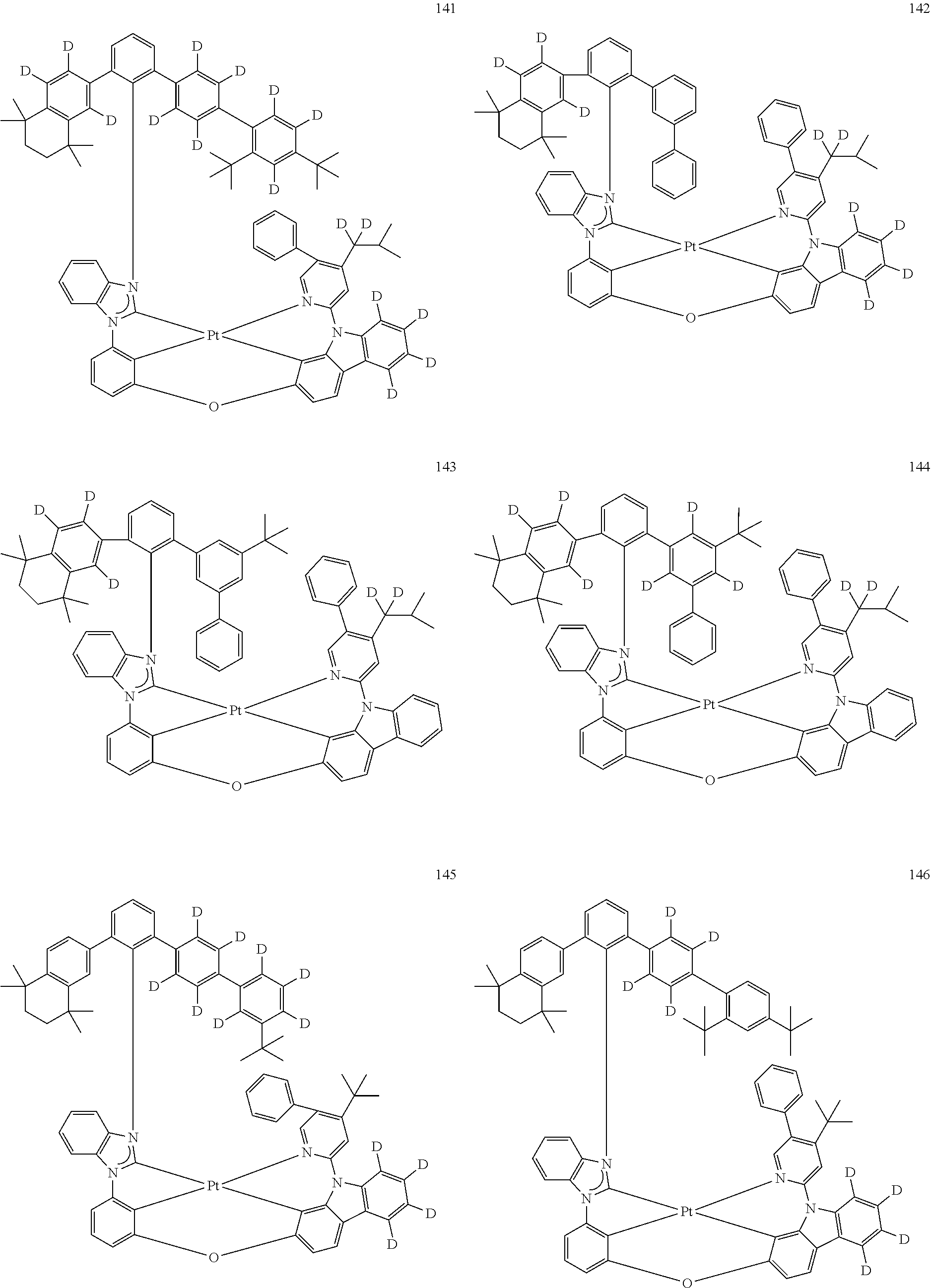

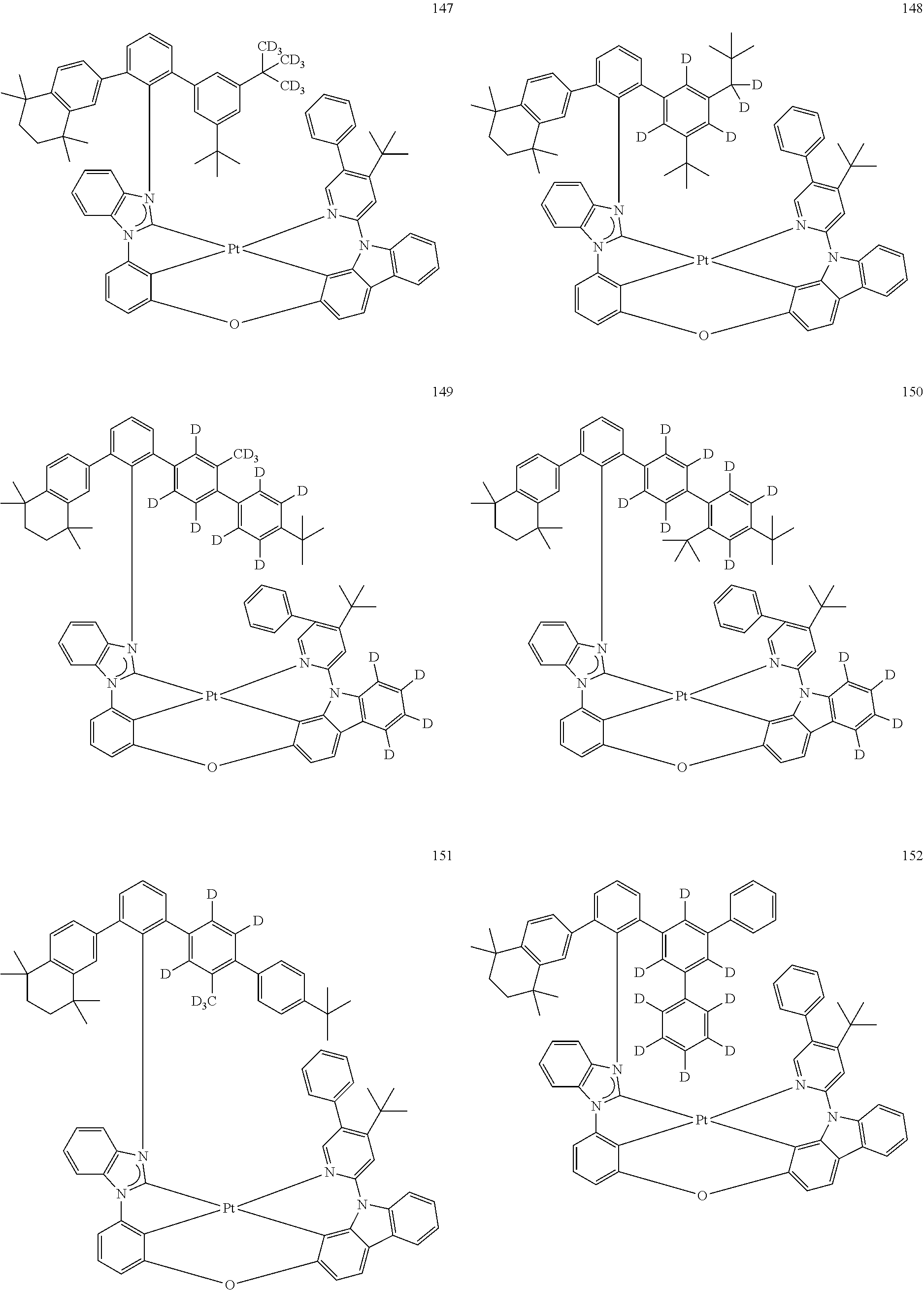

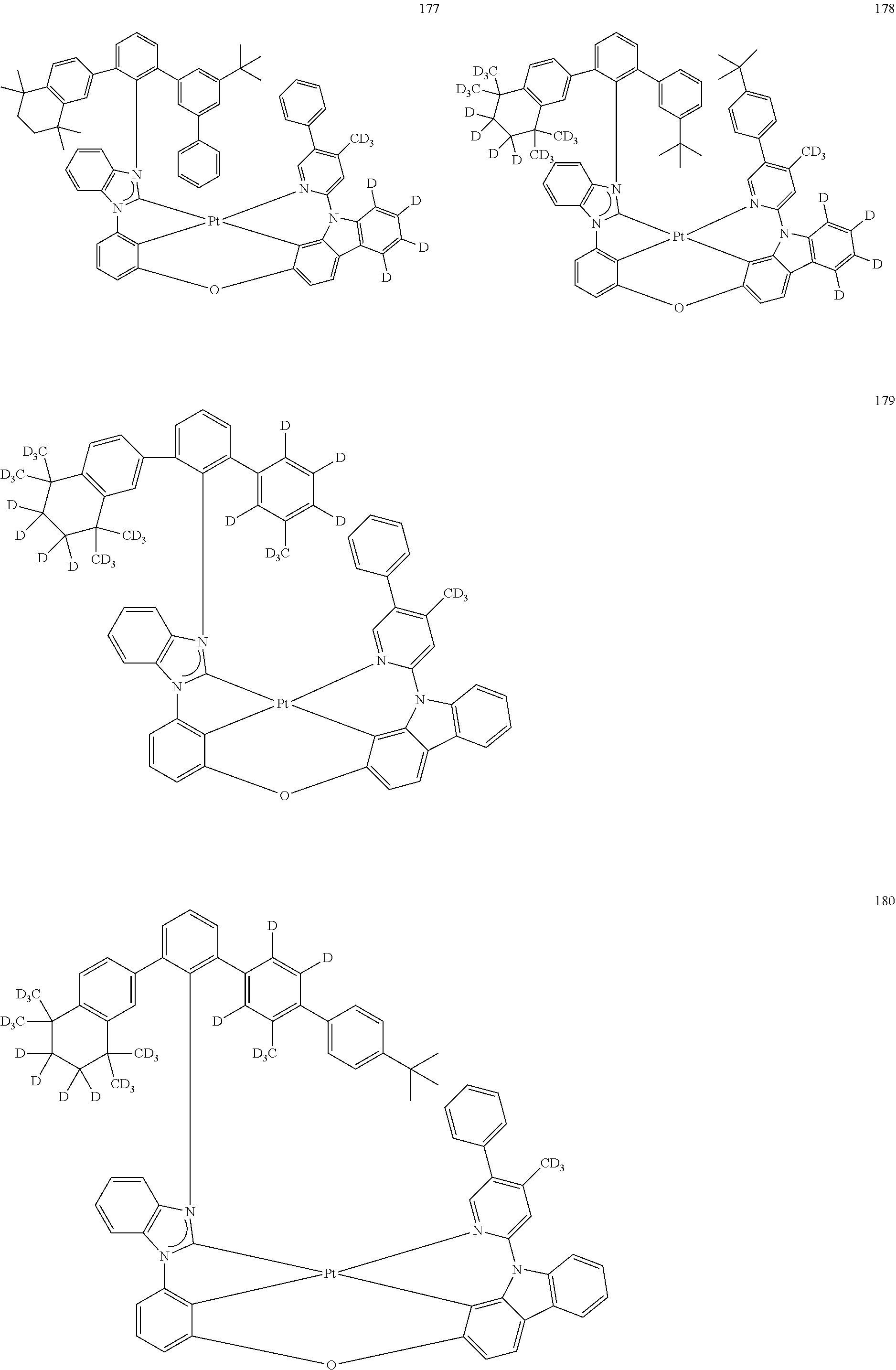

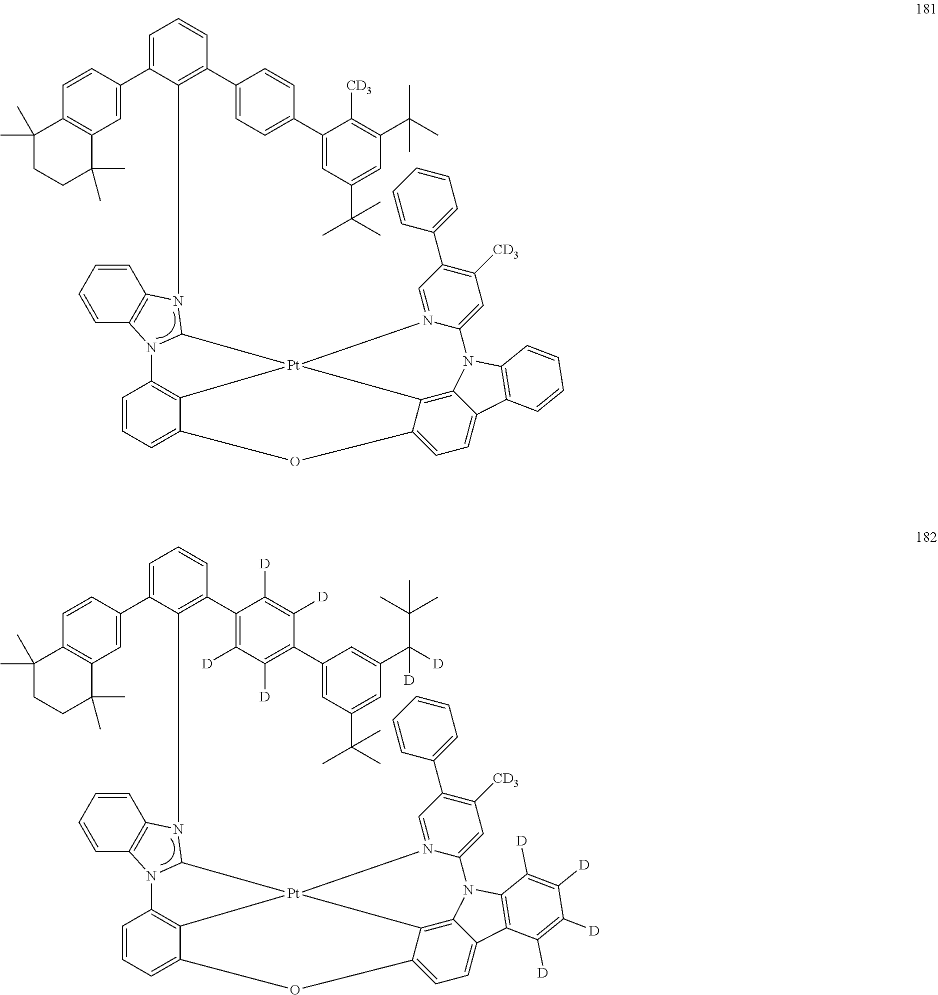

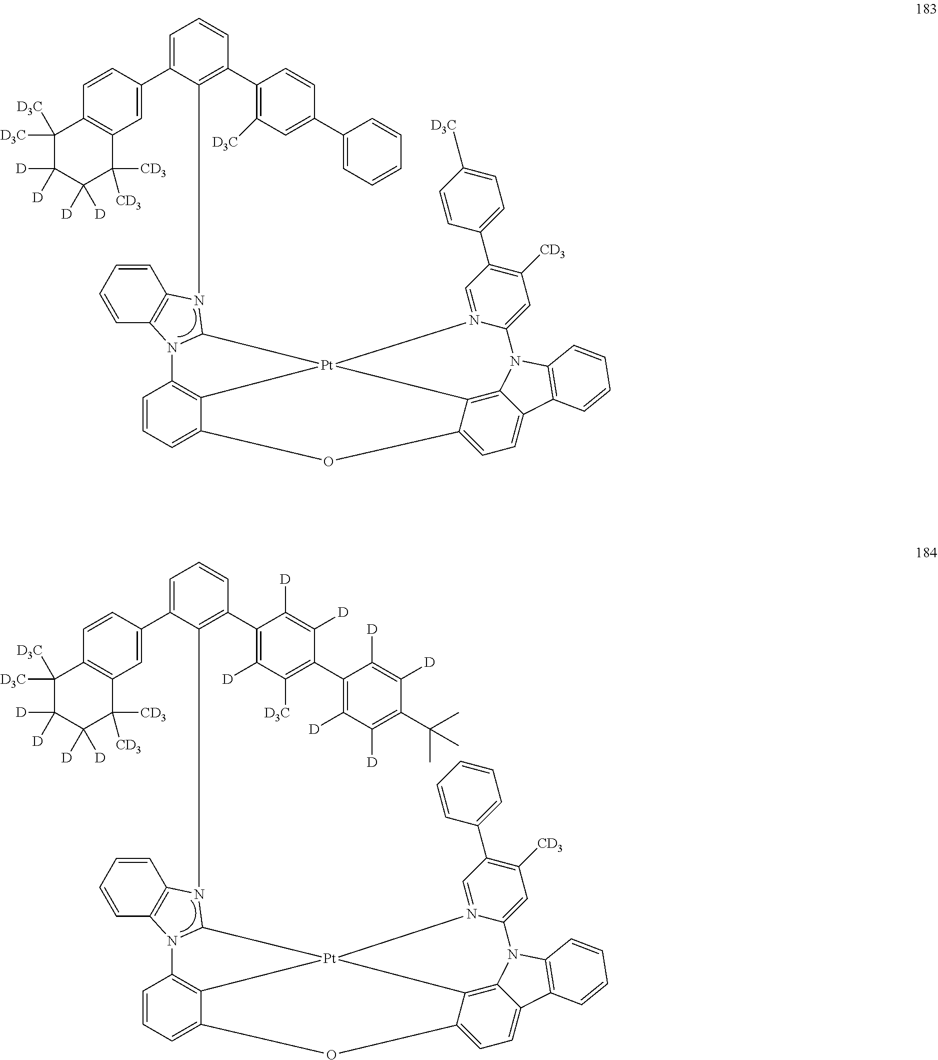

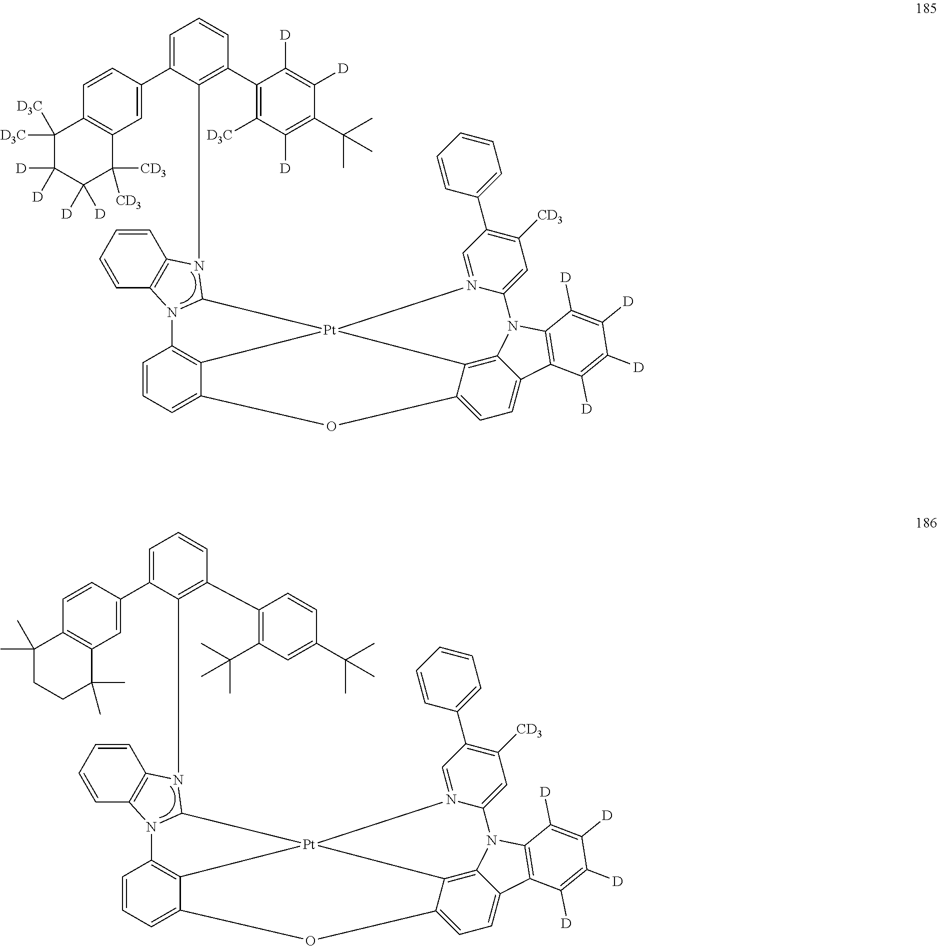

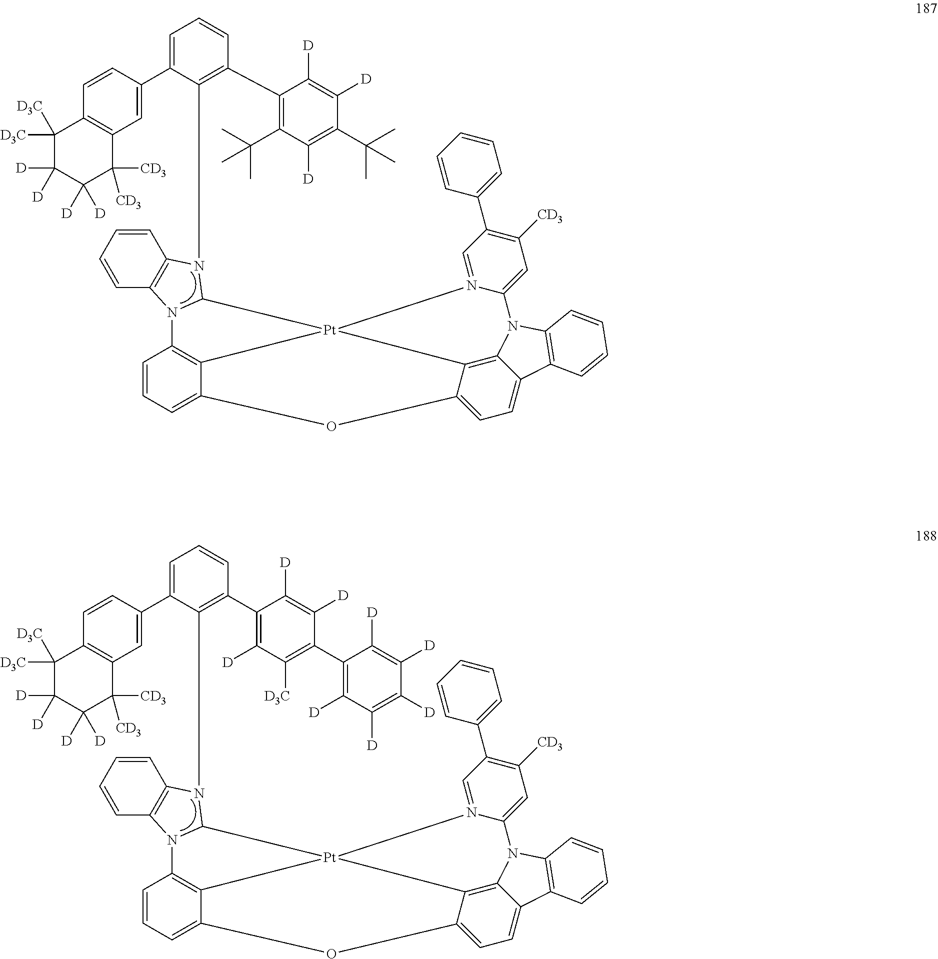

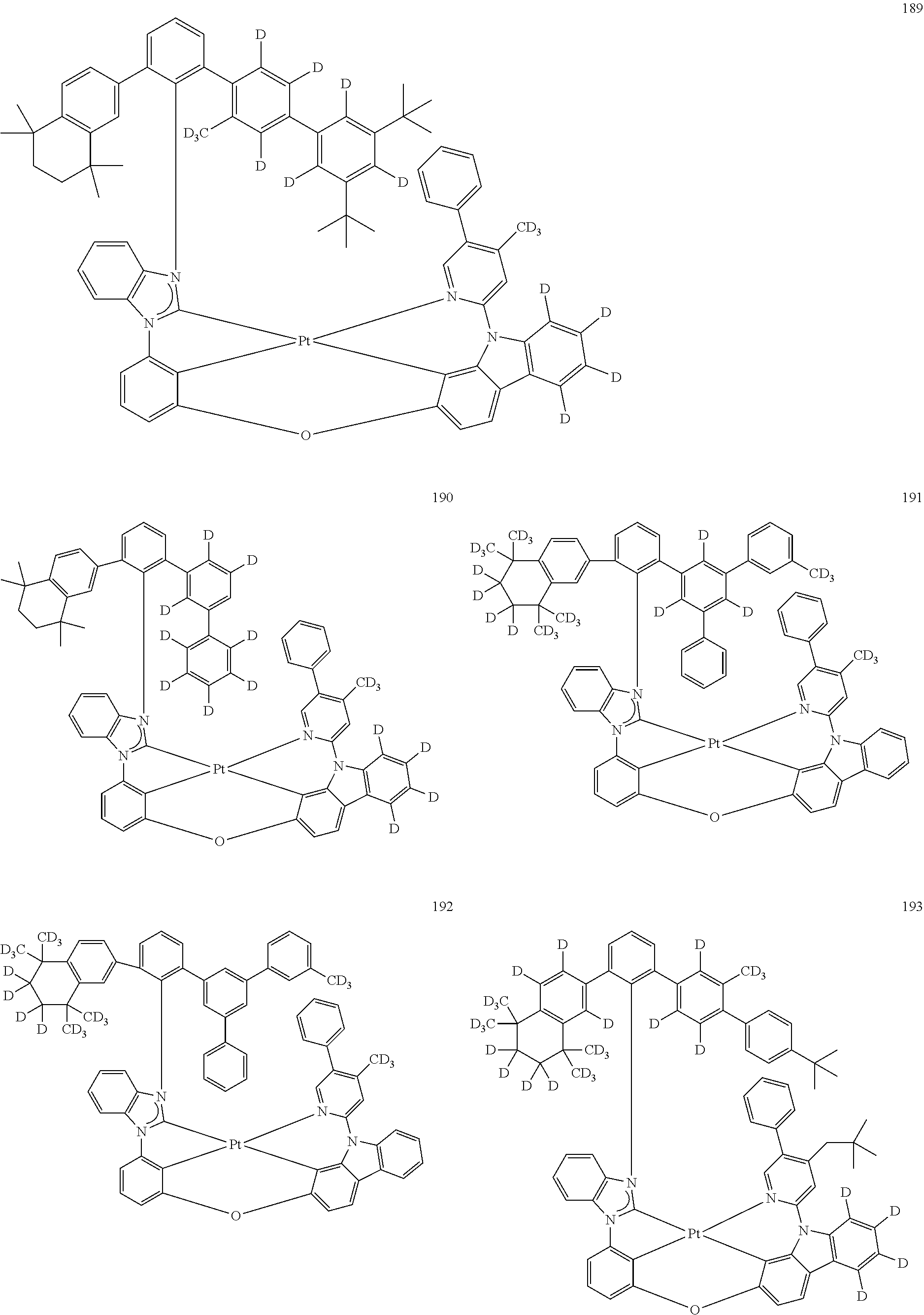

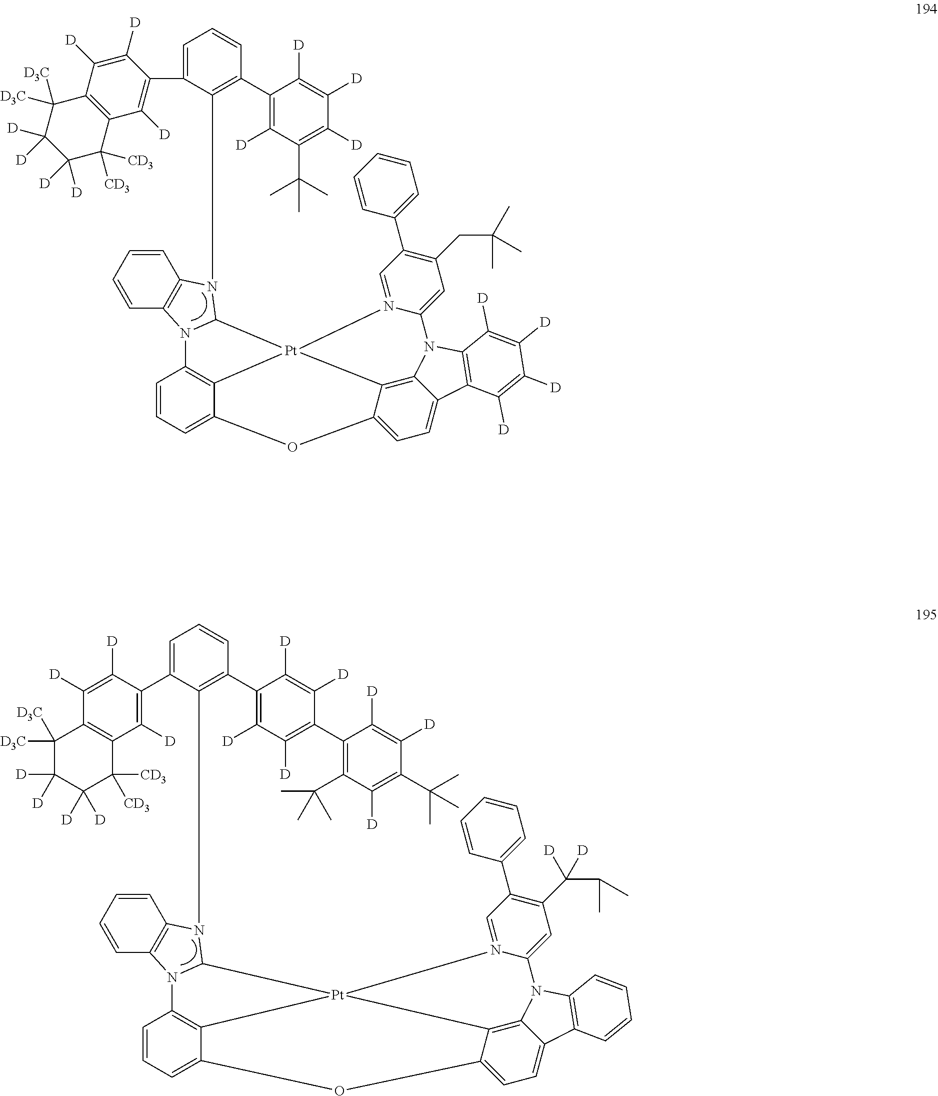

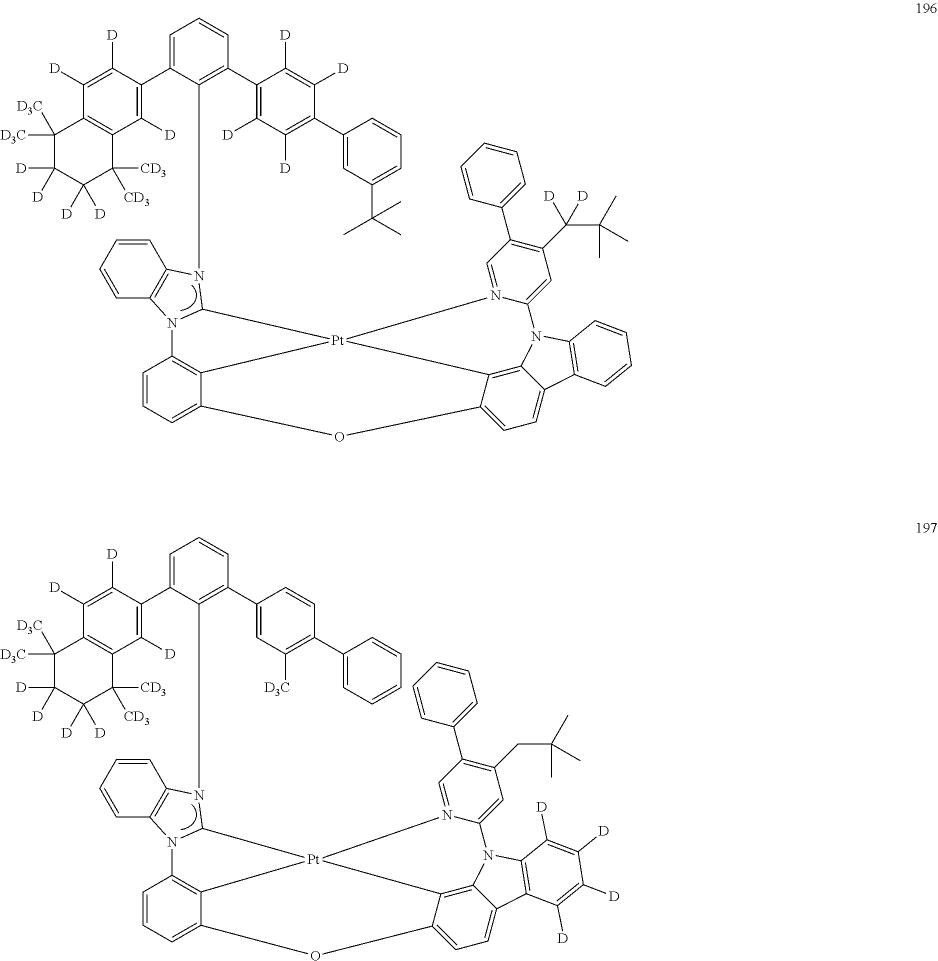

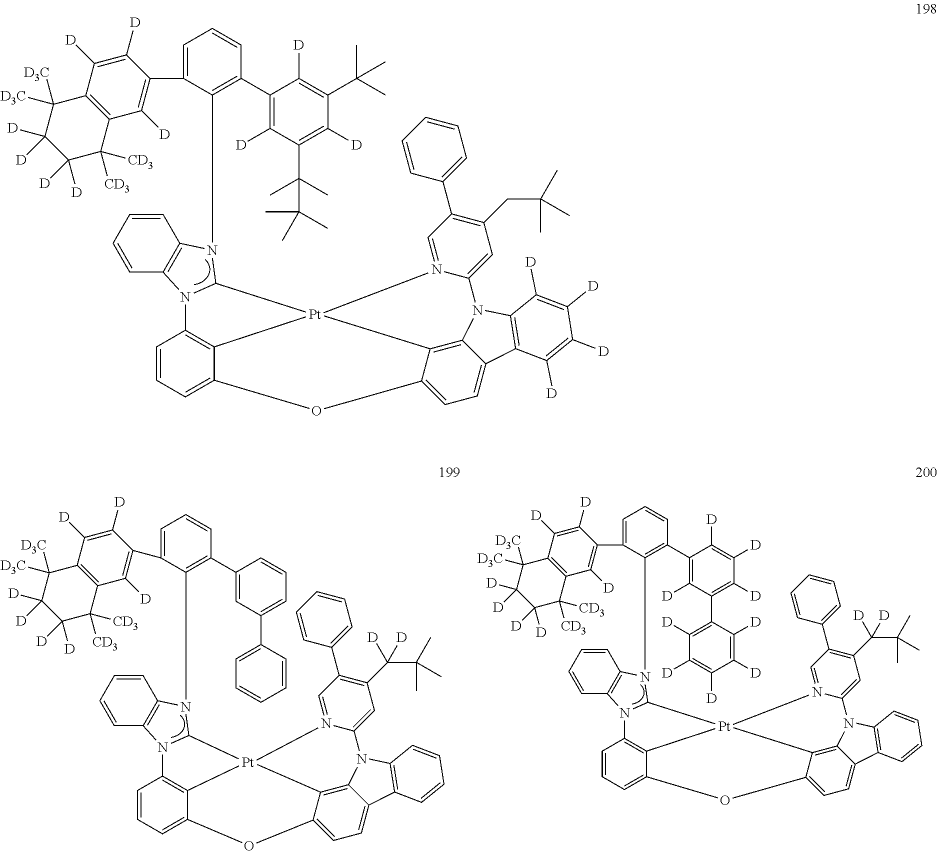

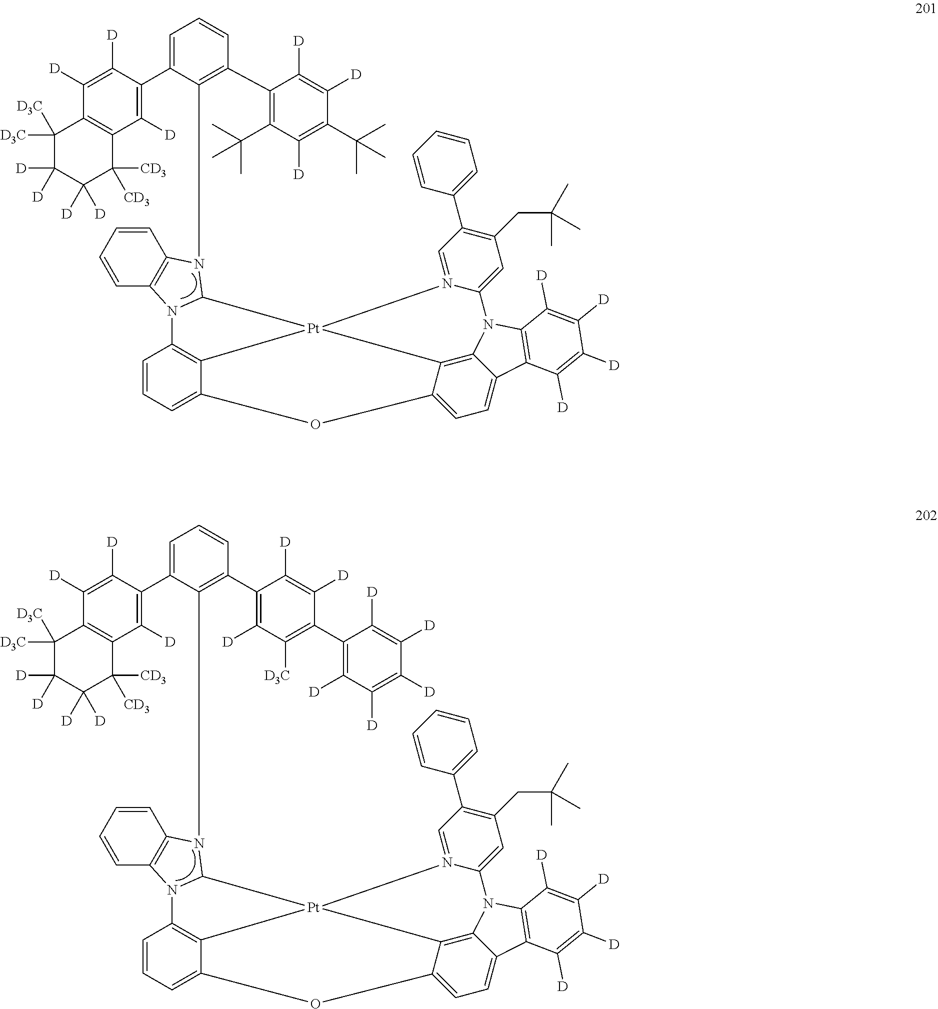

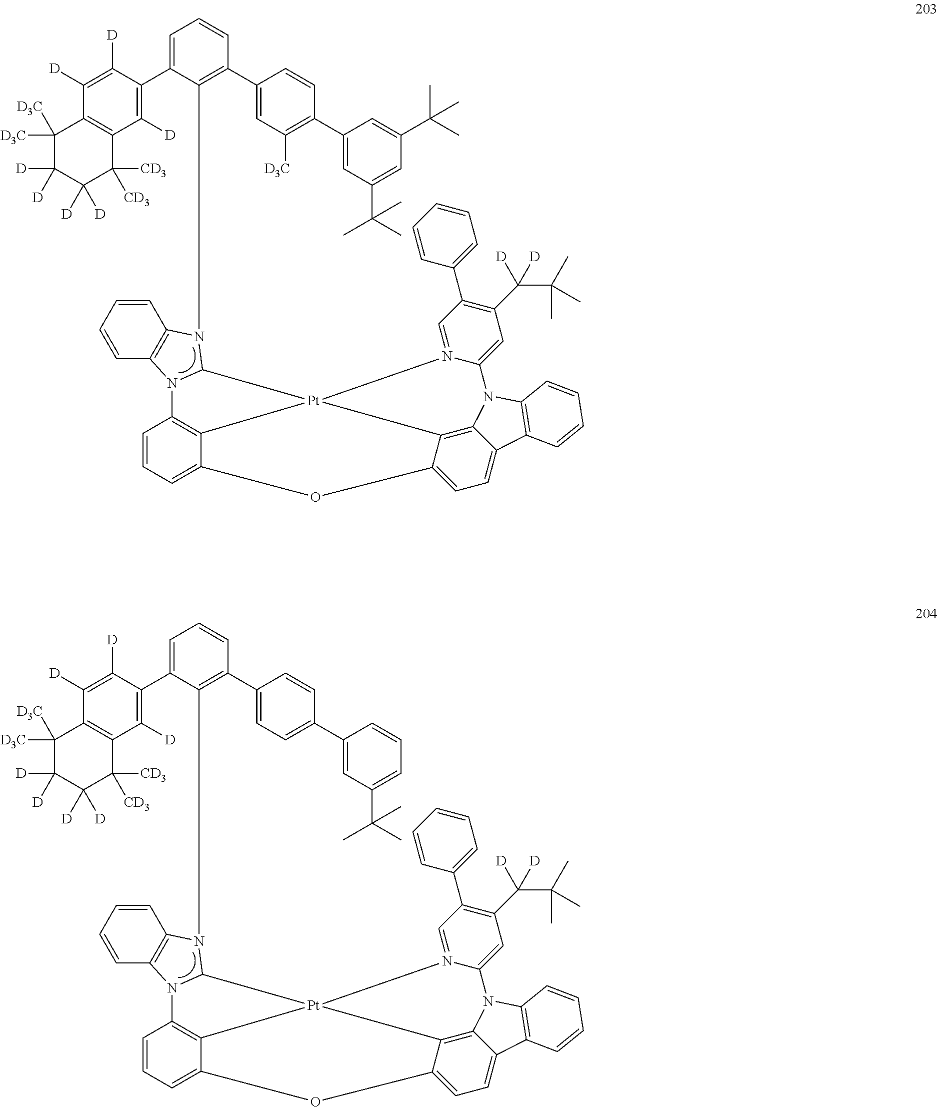

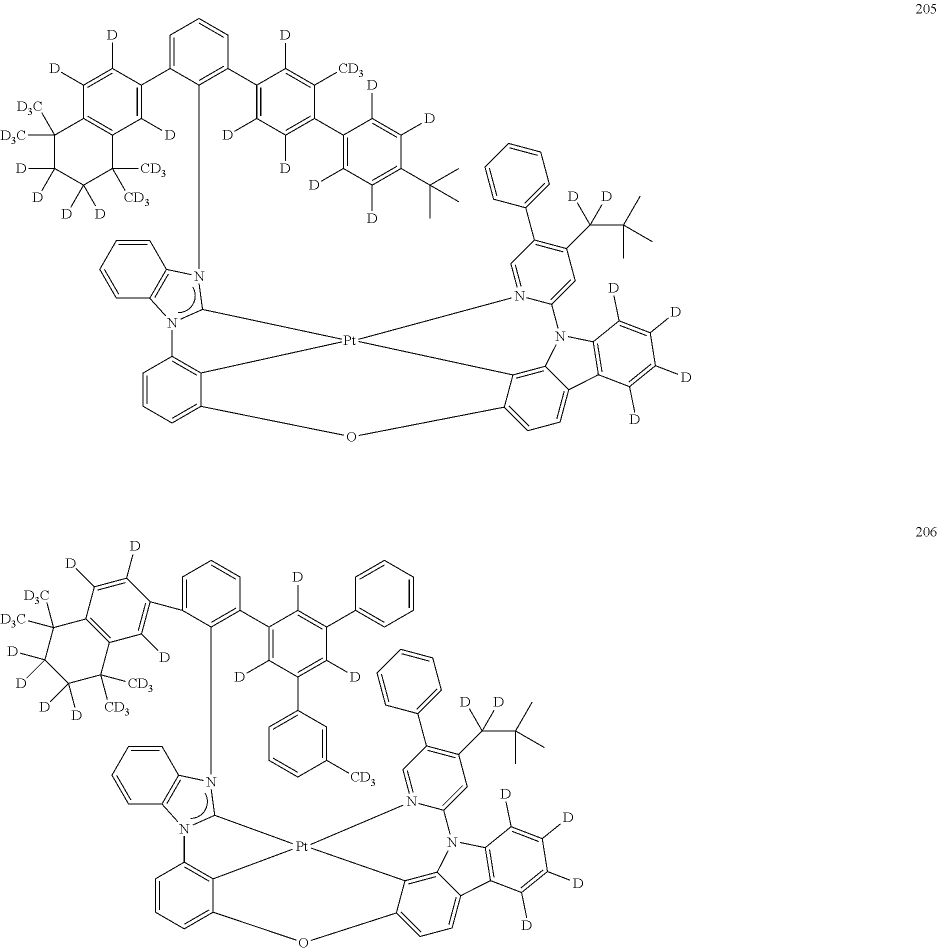

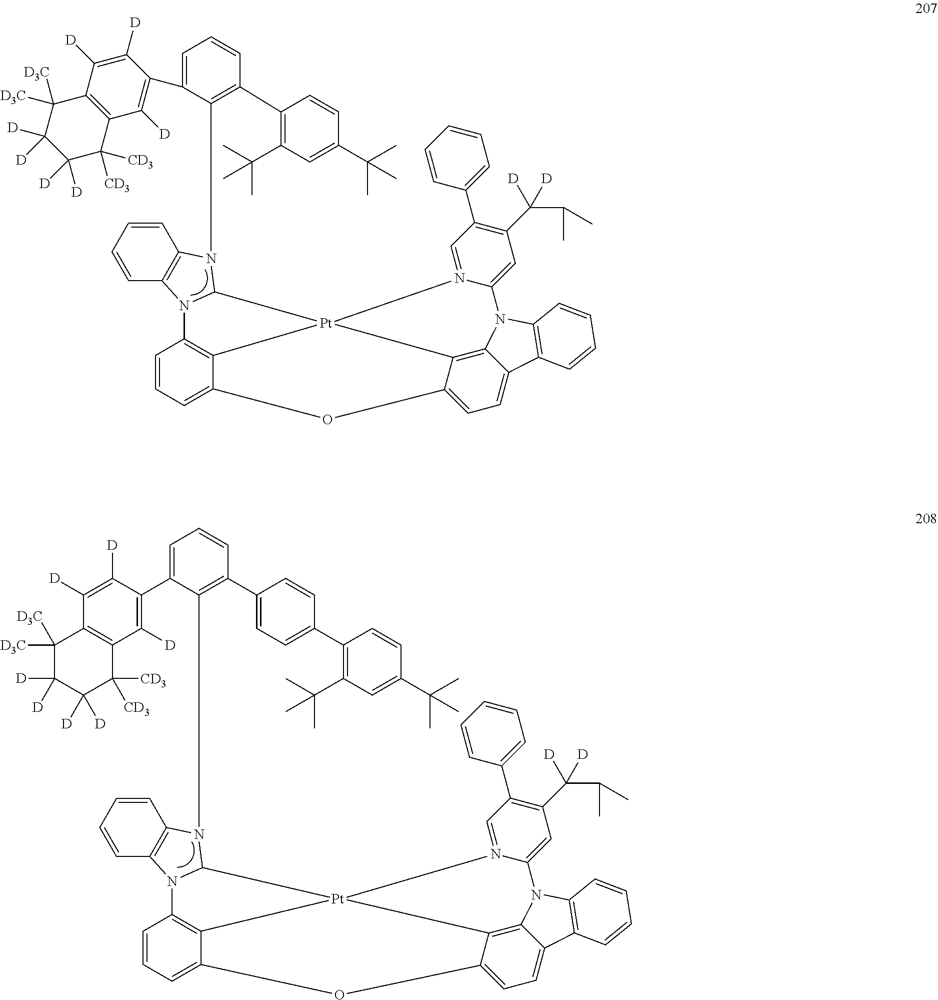

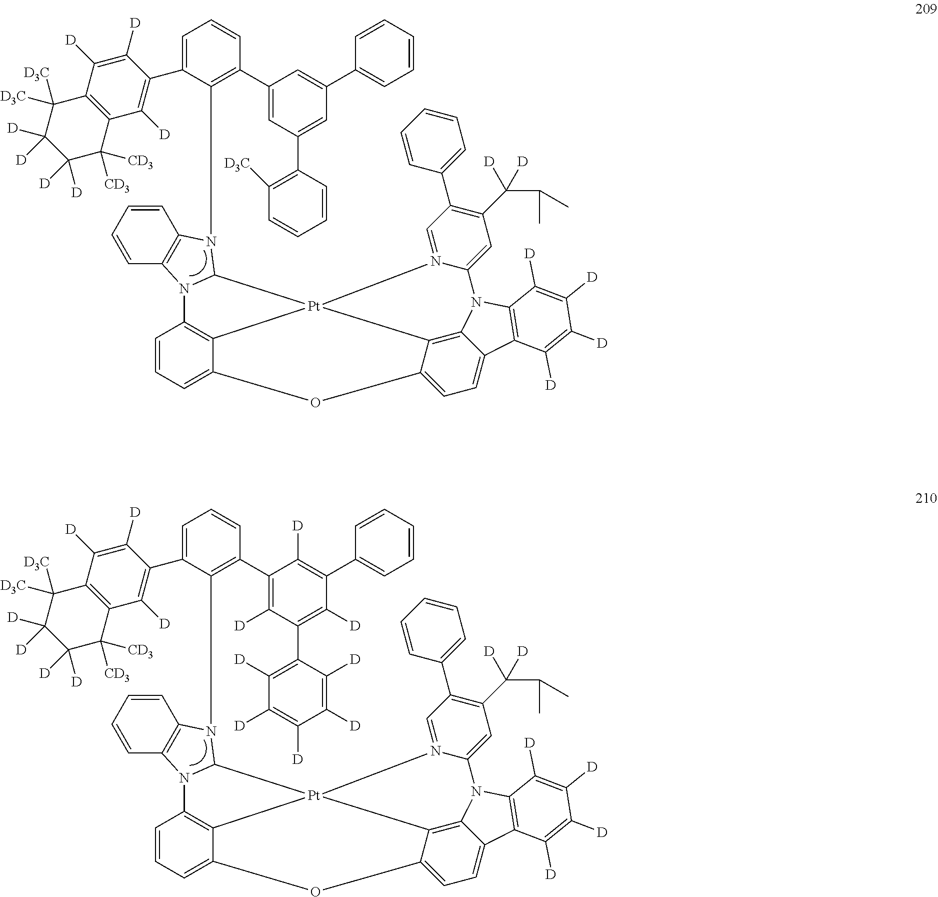

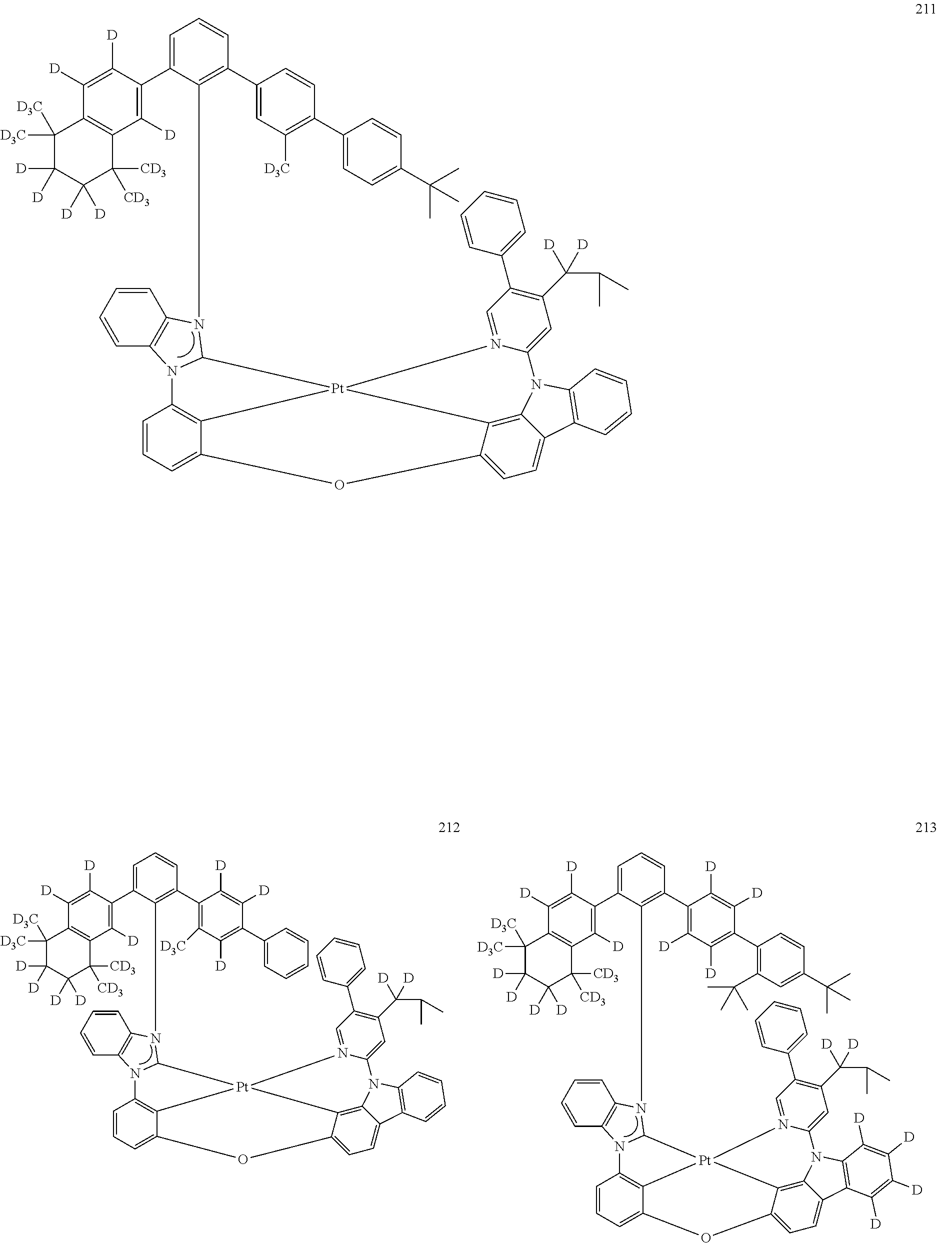

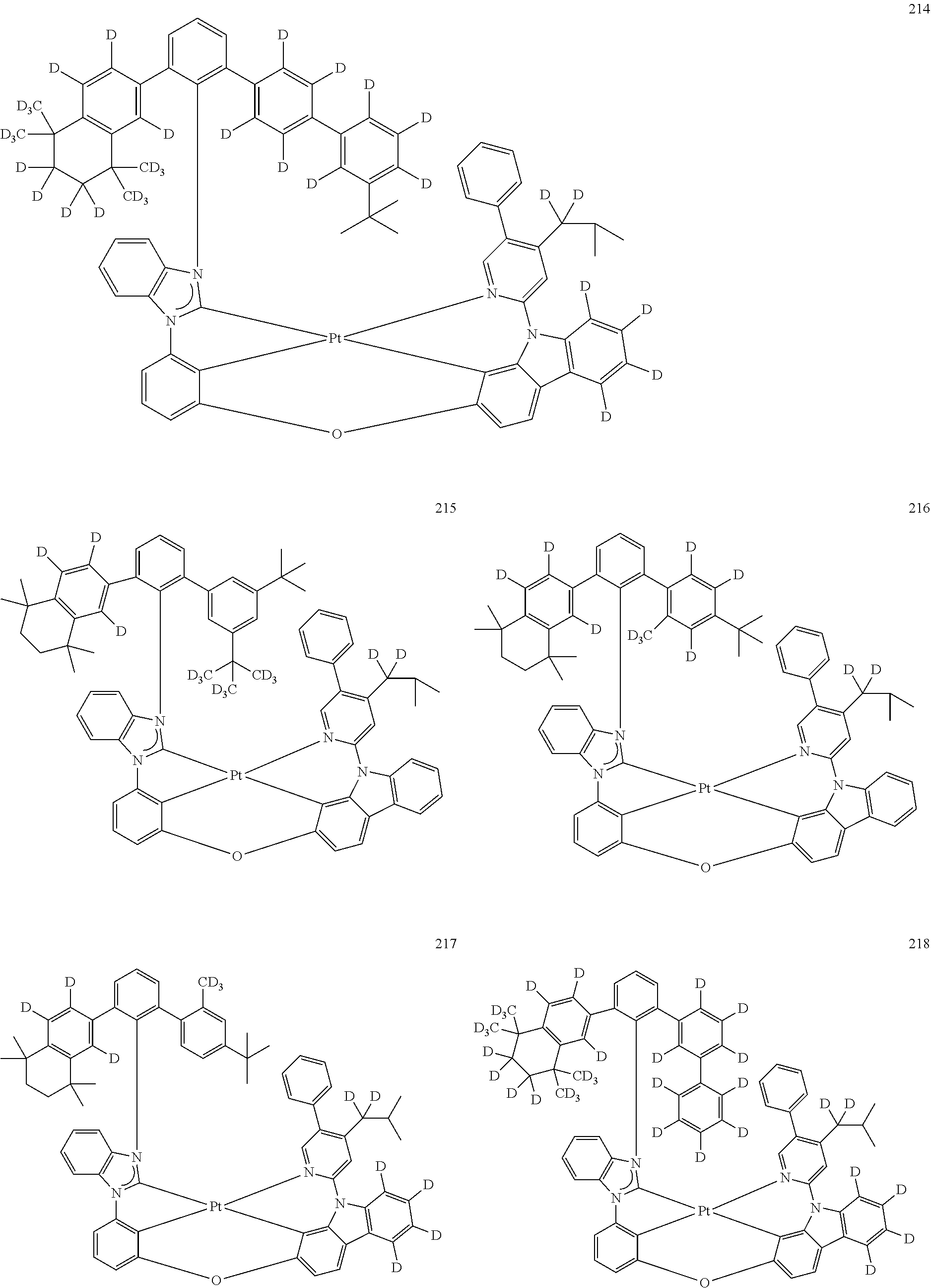

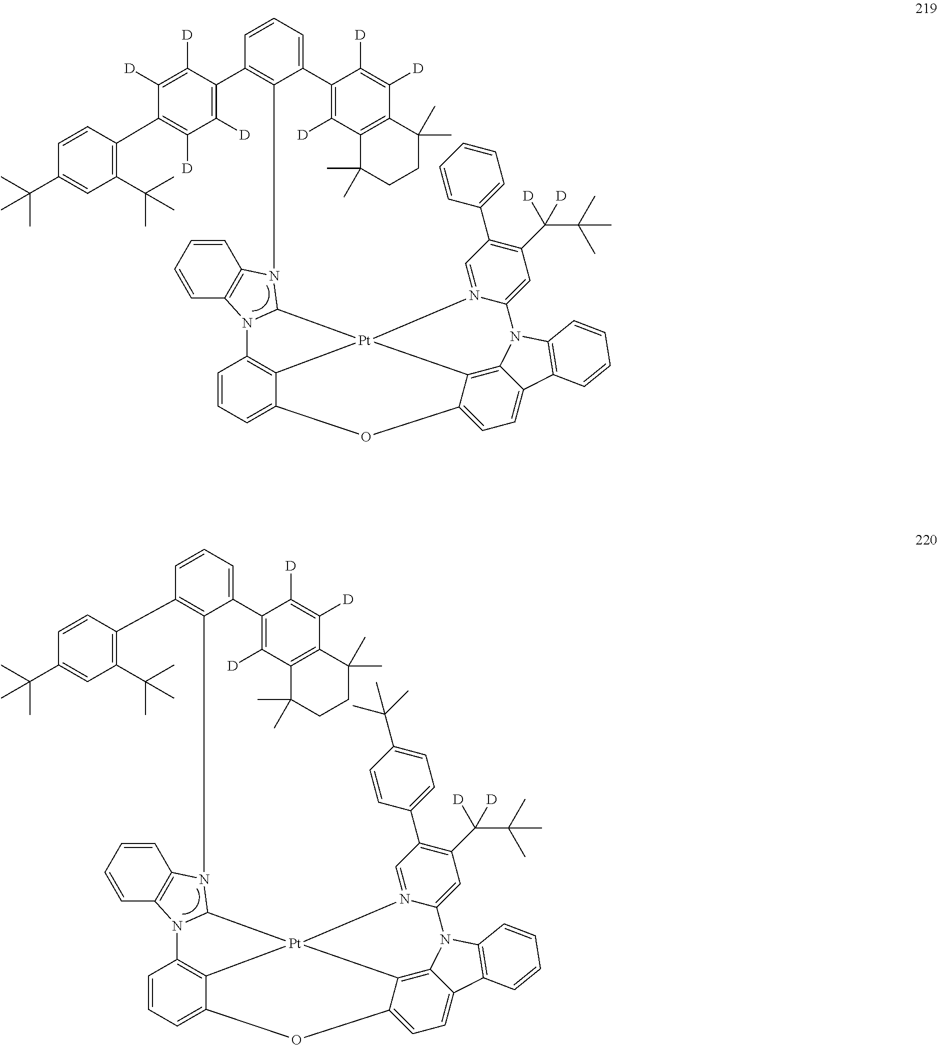

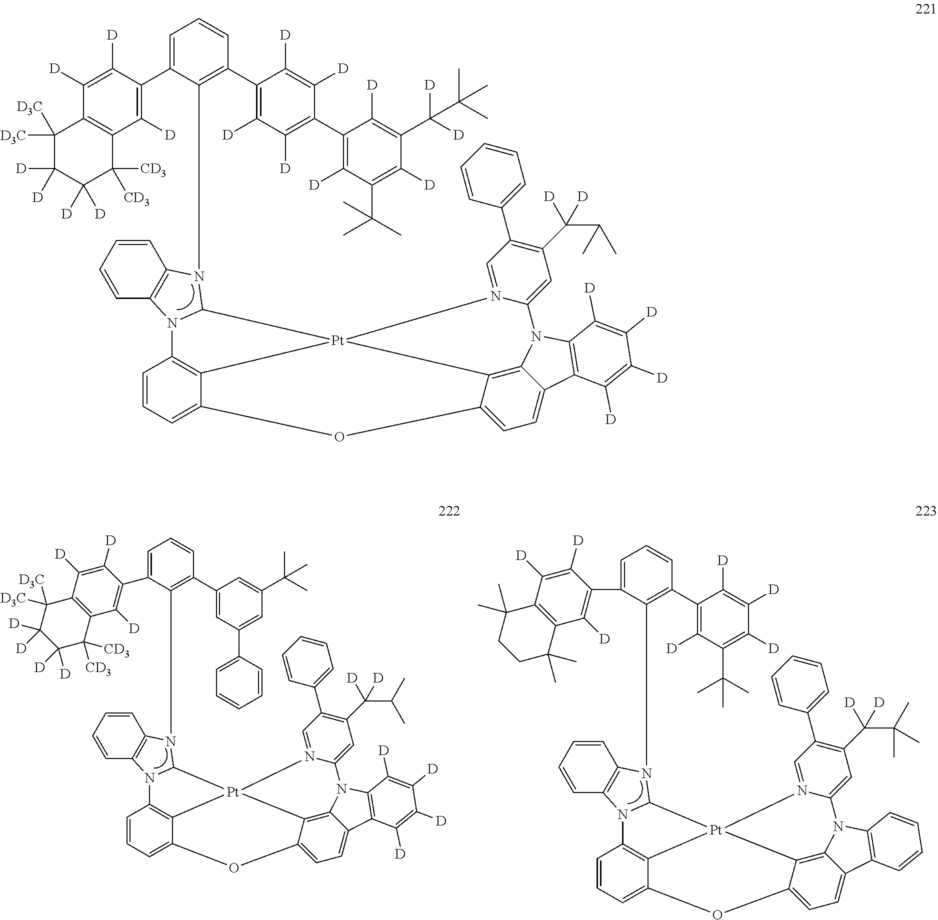

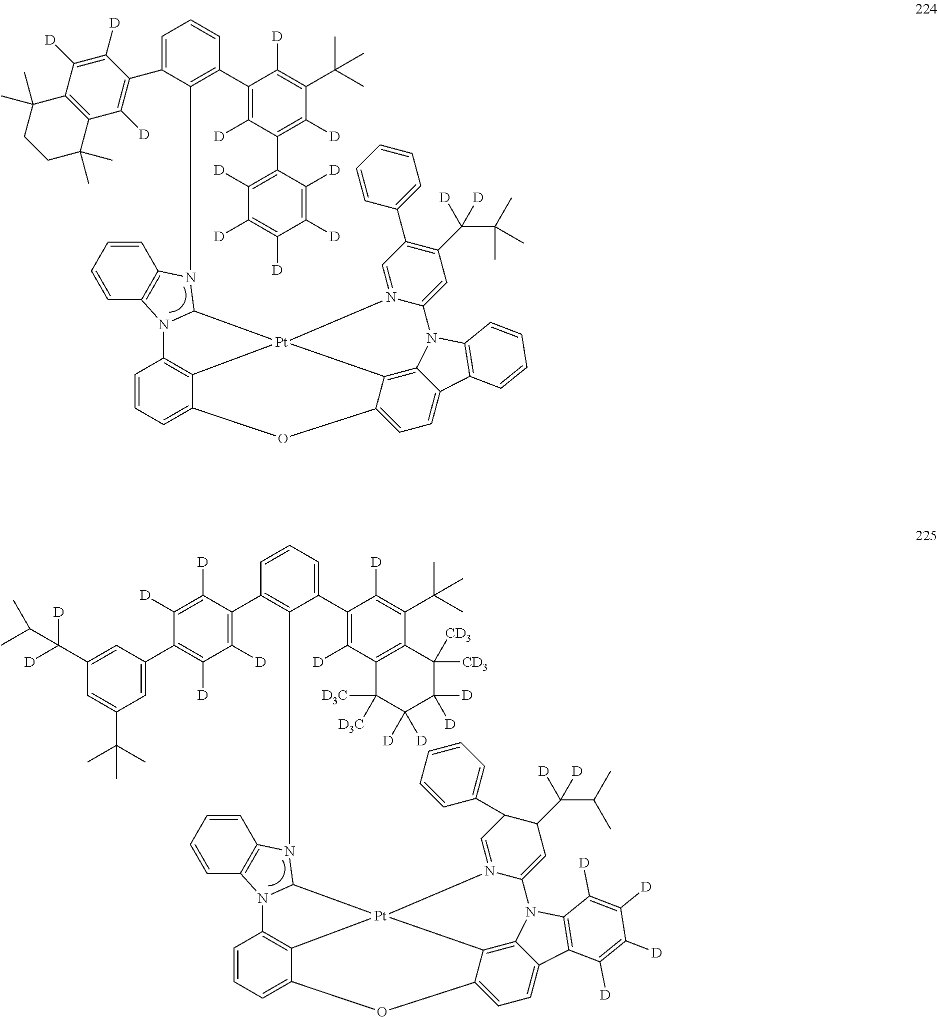

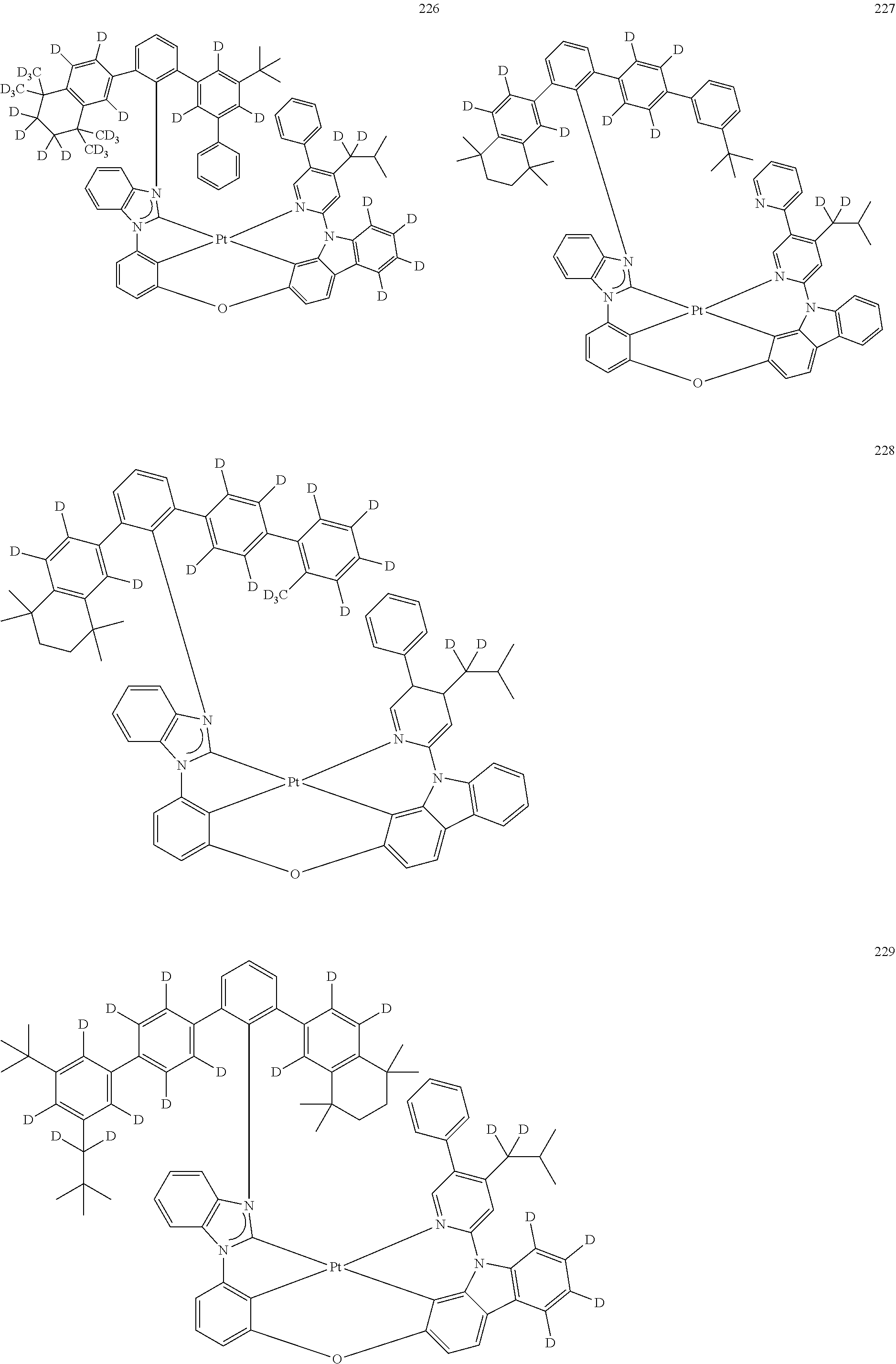

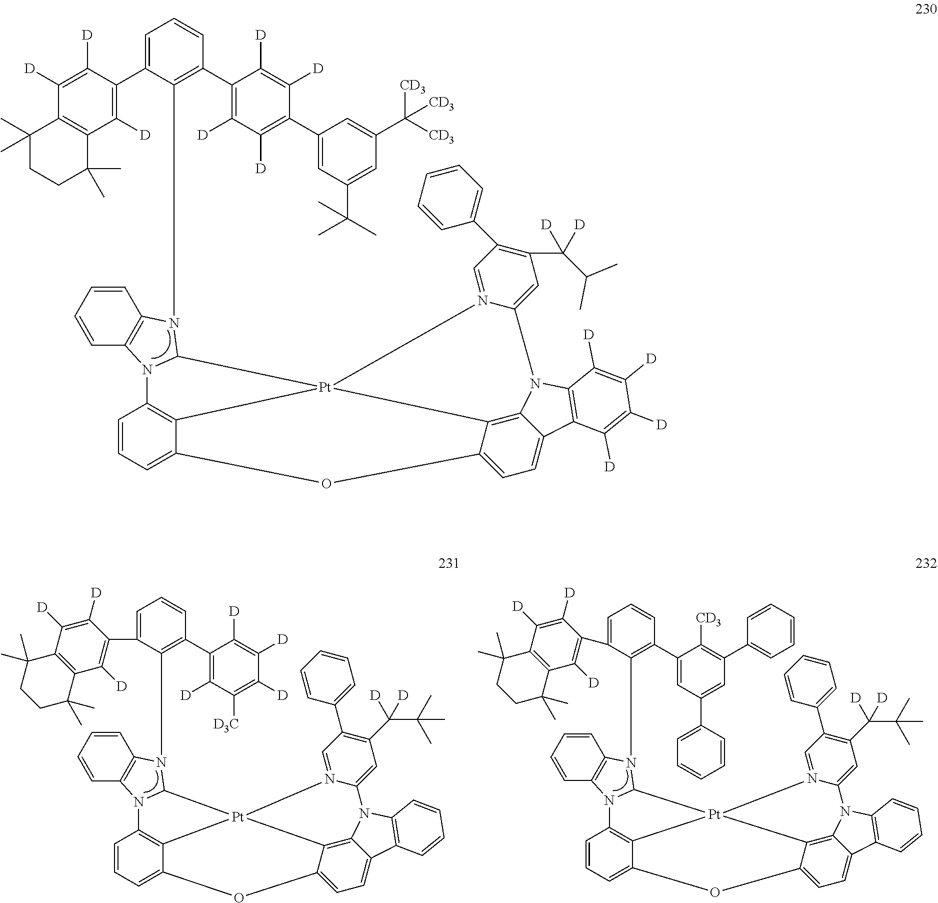

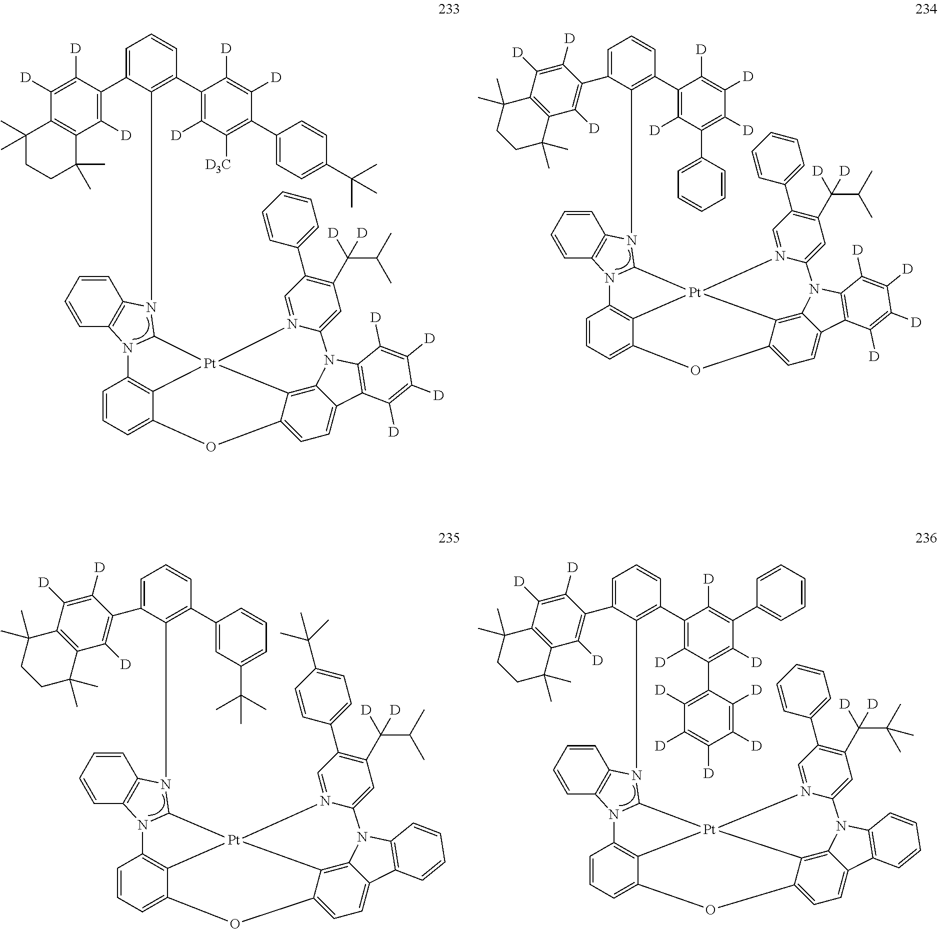

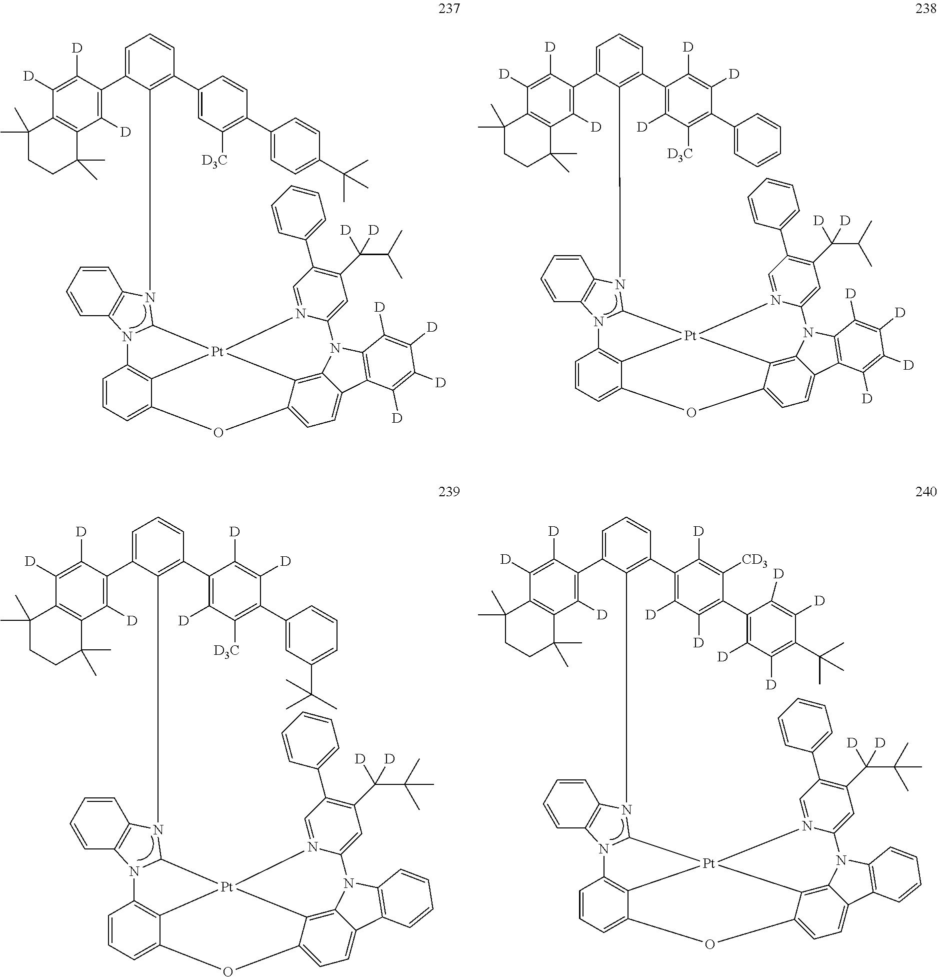

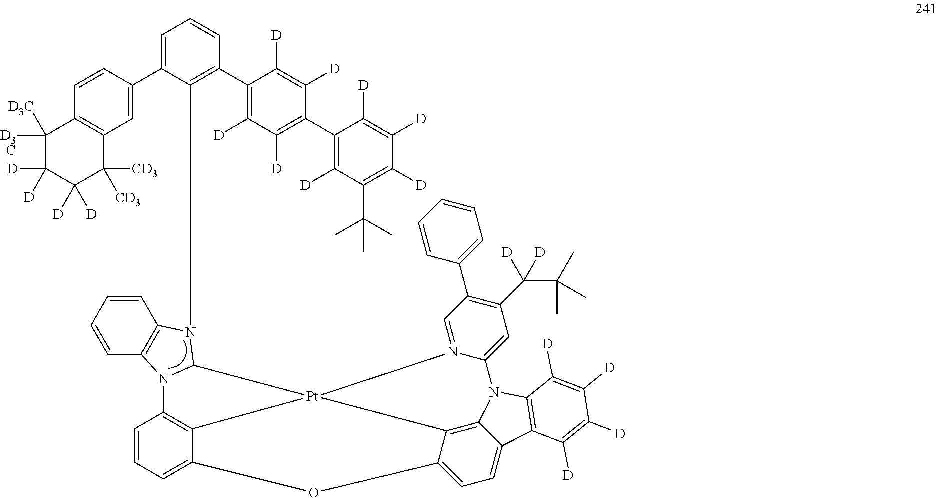

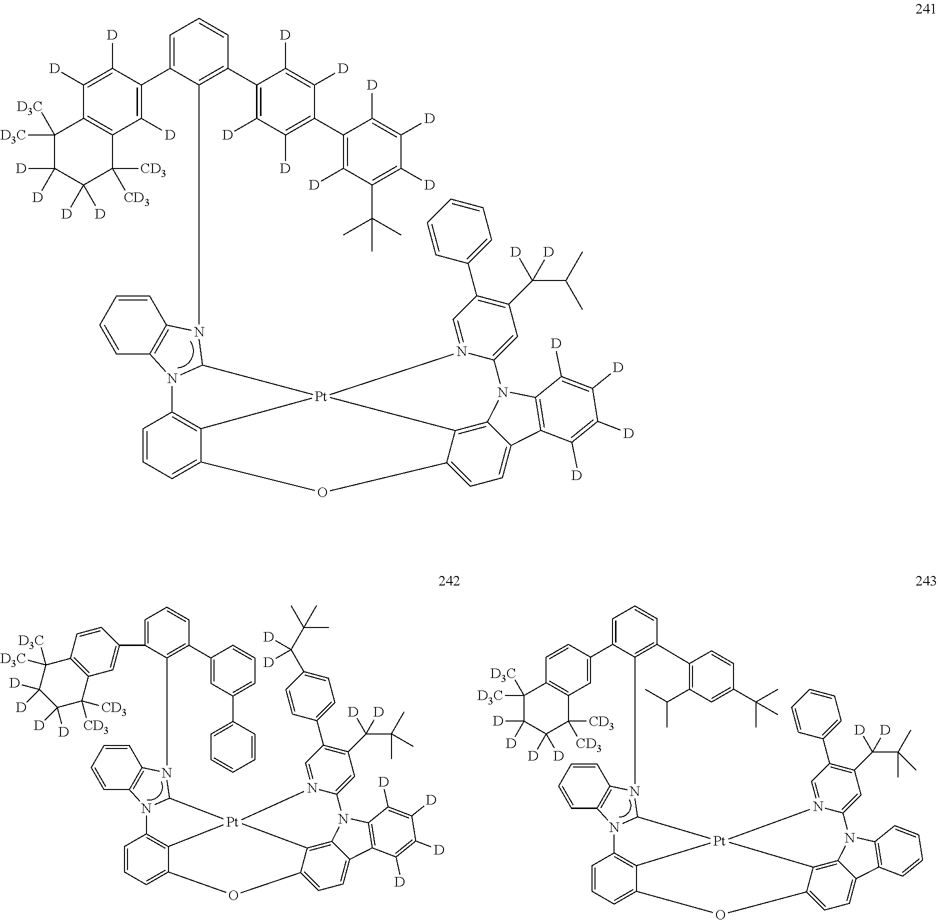

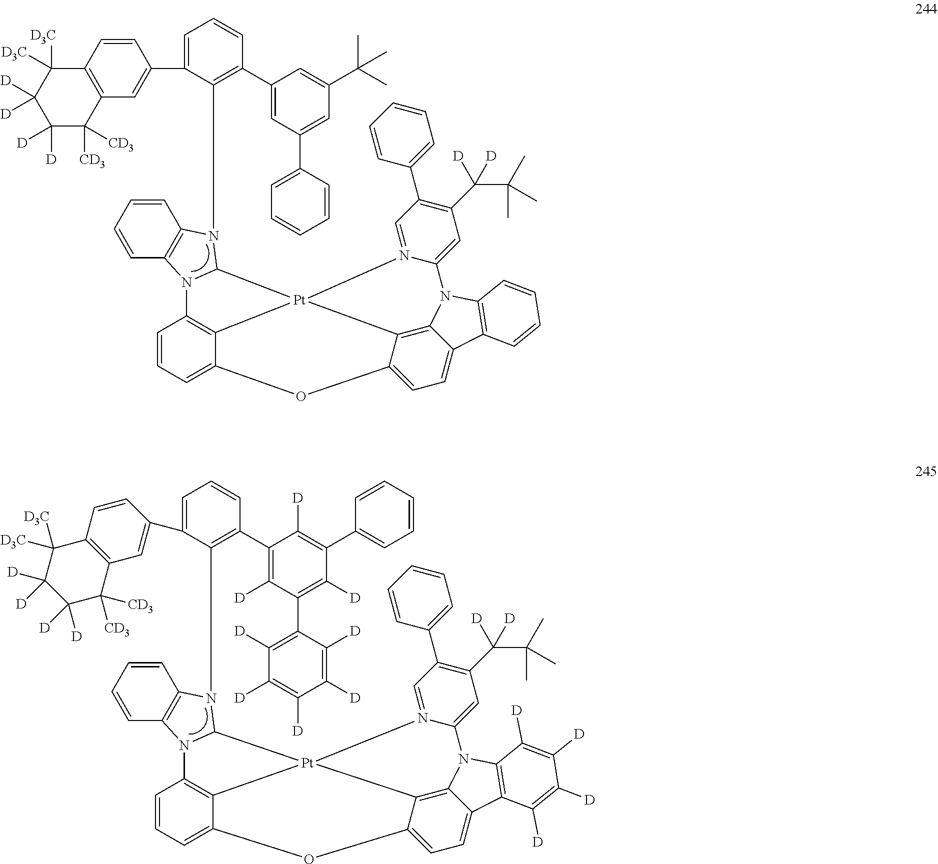

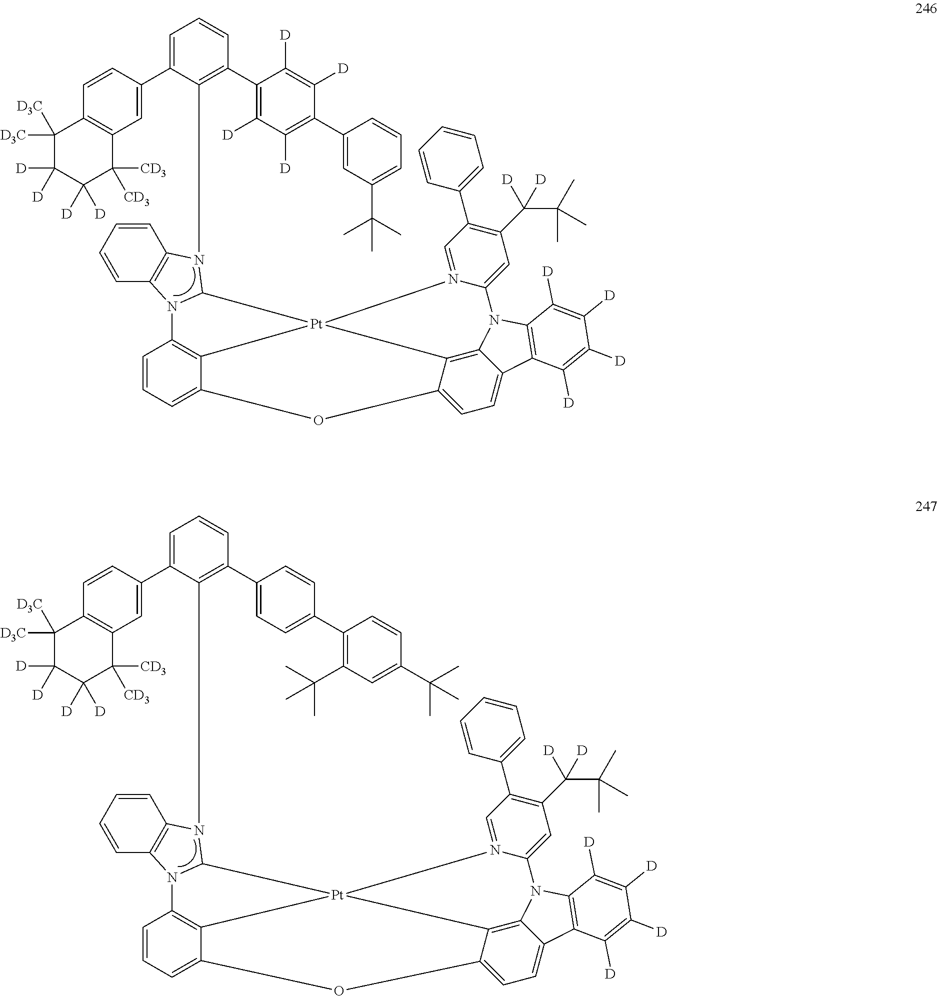

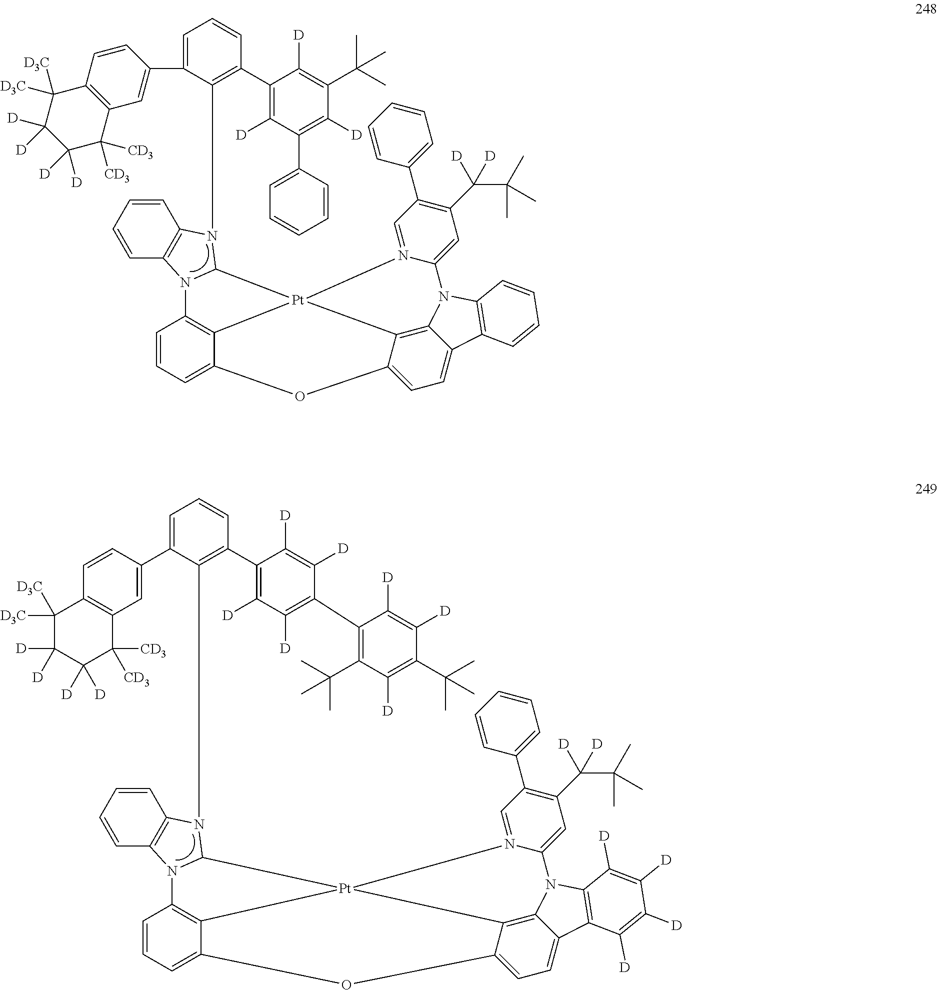

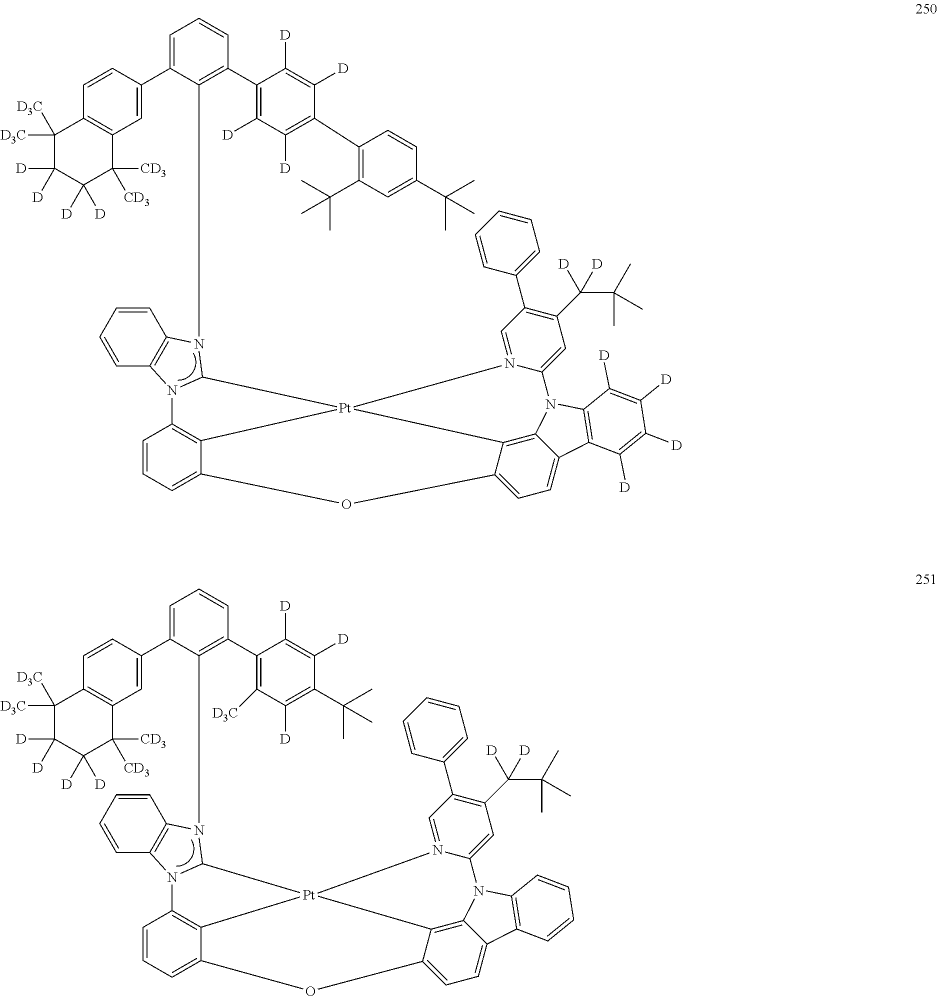

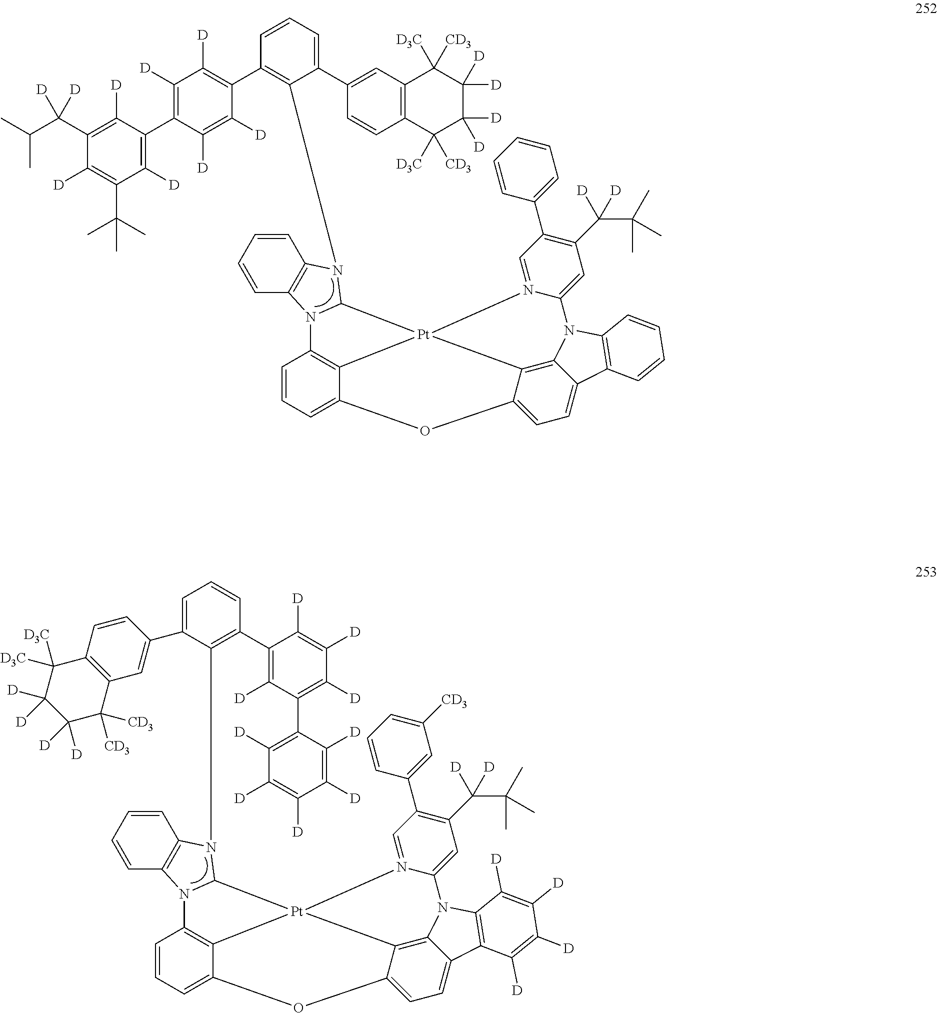

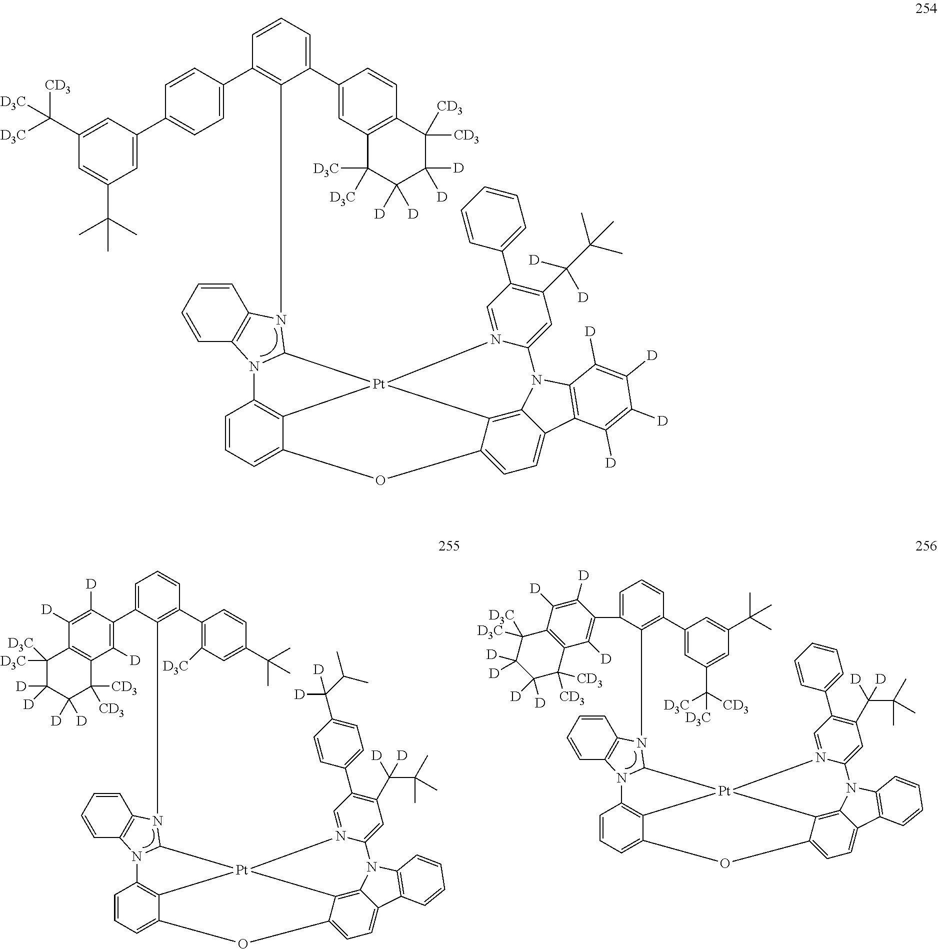

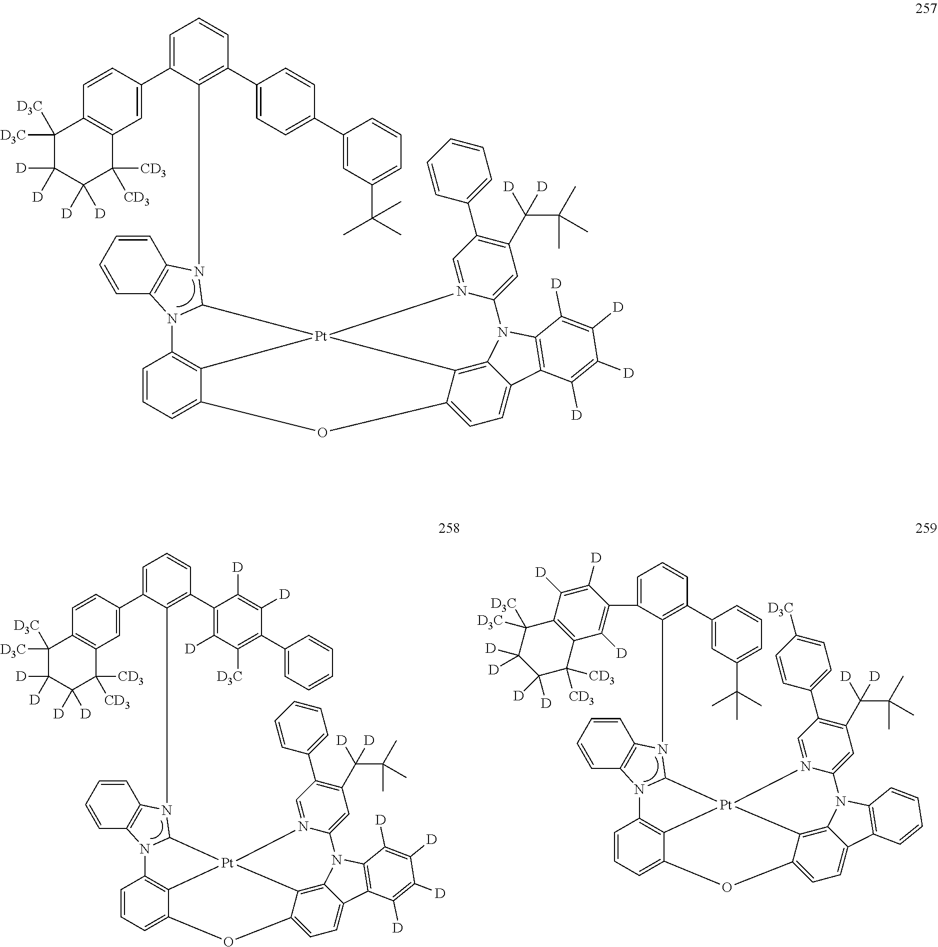

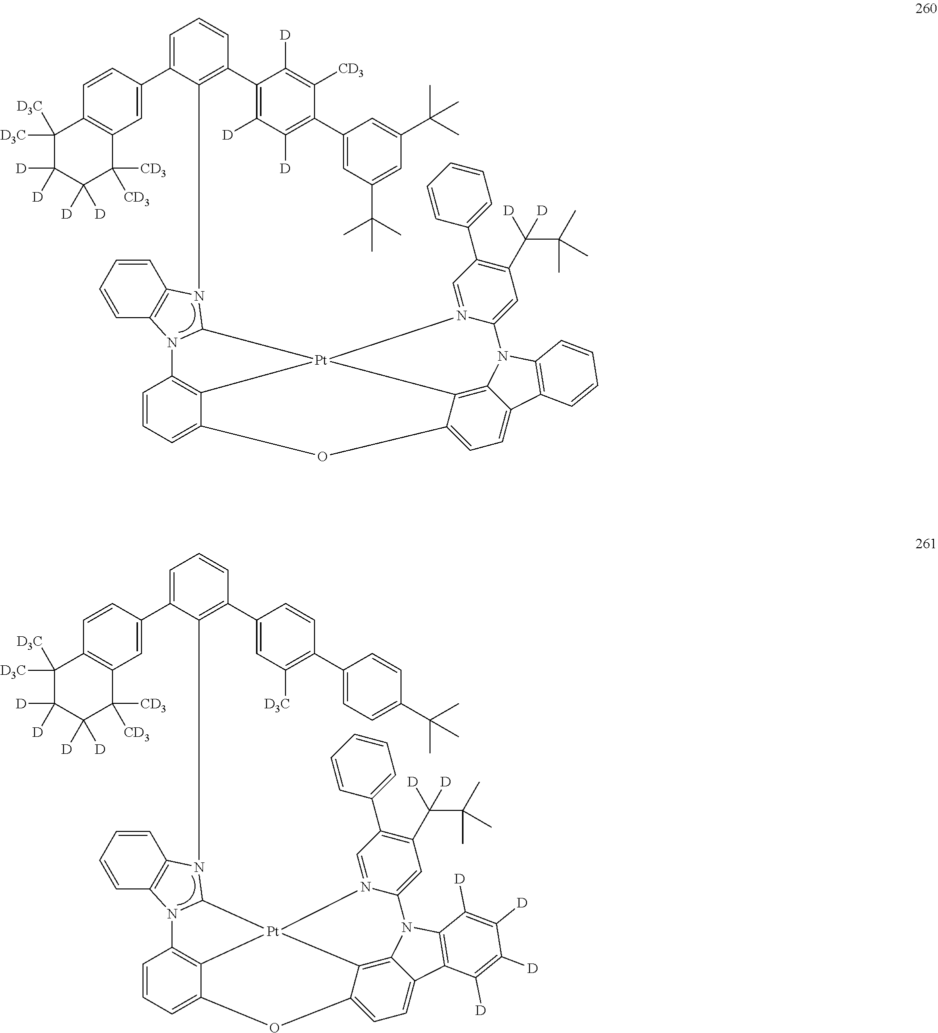

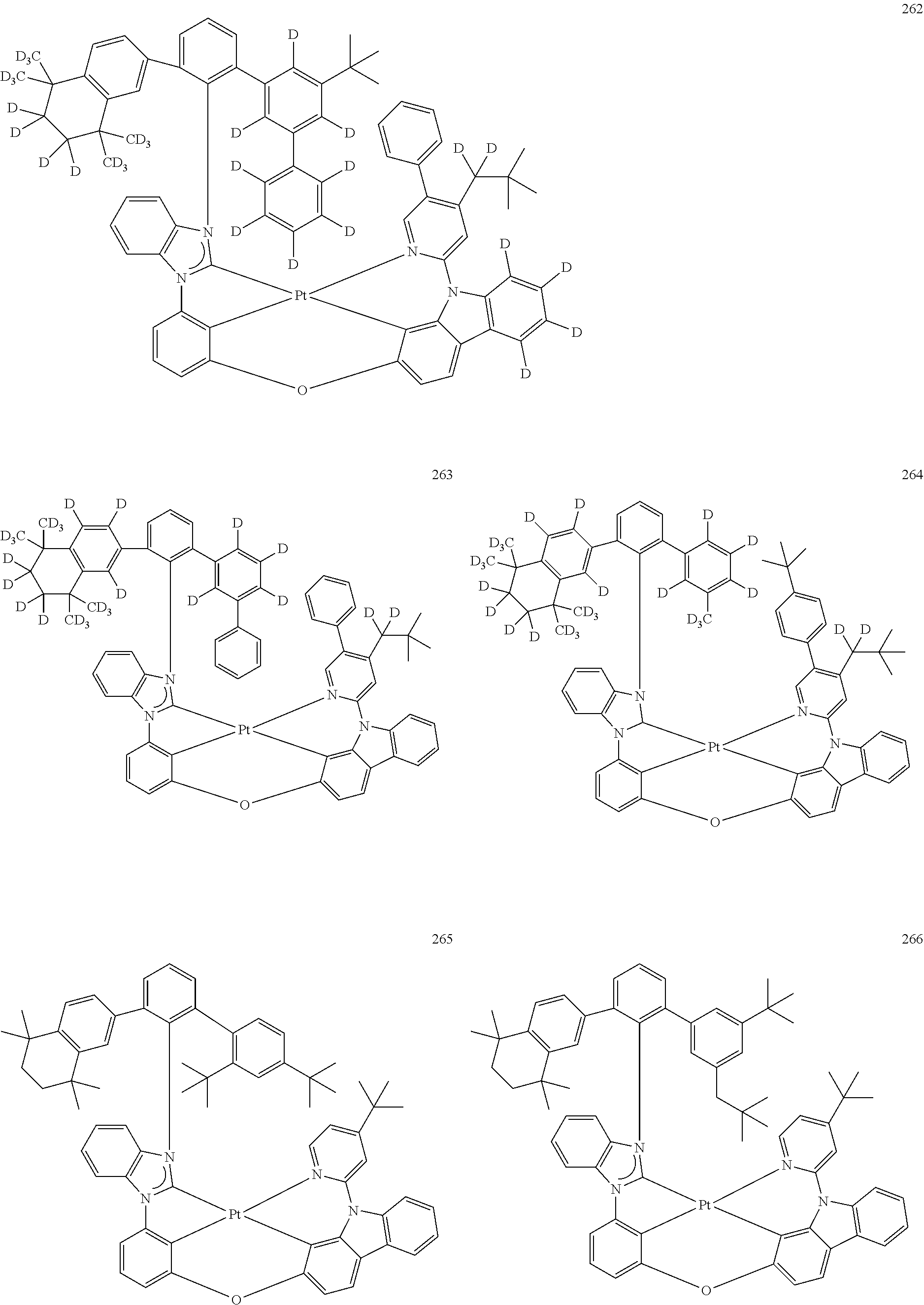

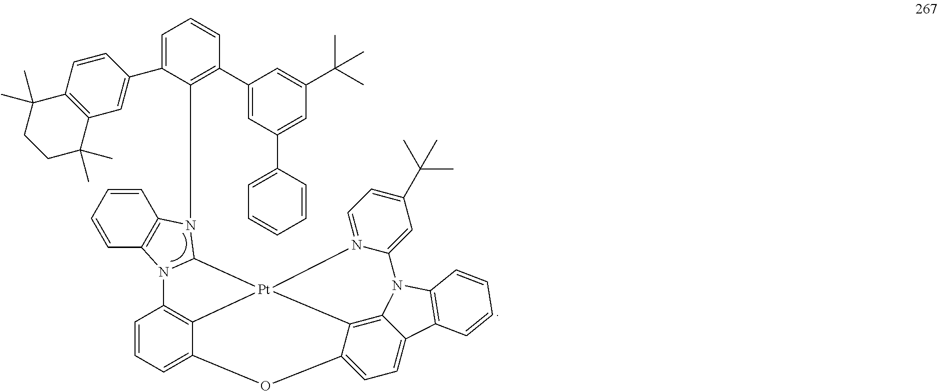

In one or more embodiments, the second compound may be one selected from among Compounds ETH1 to ETH101:

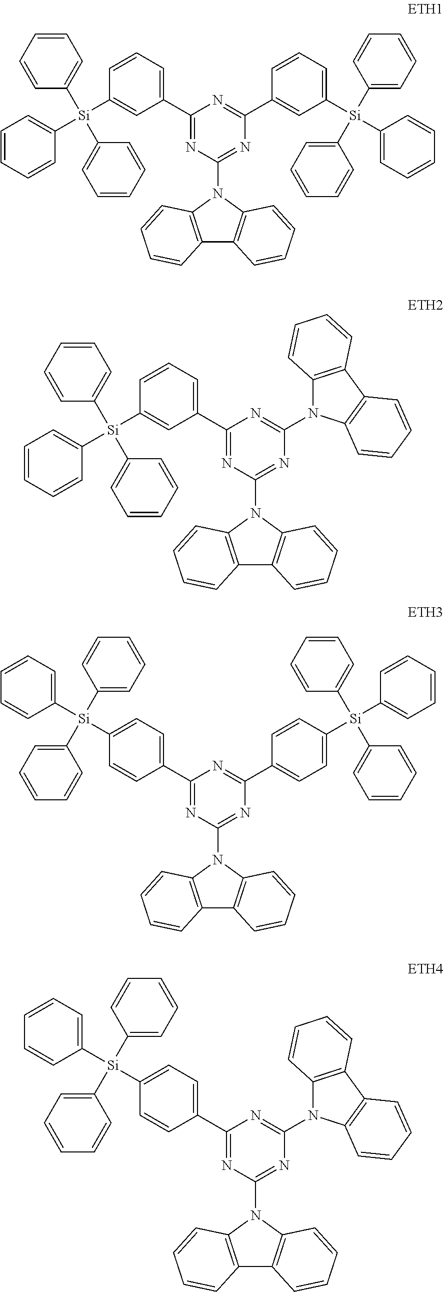 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

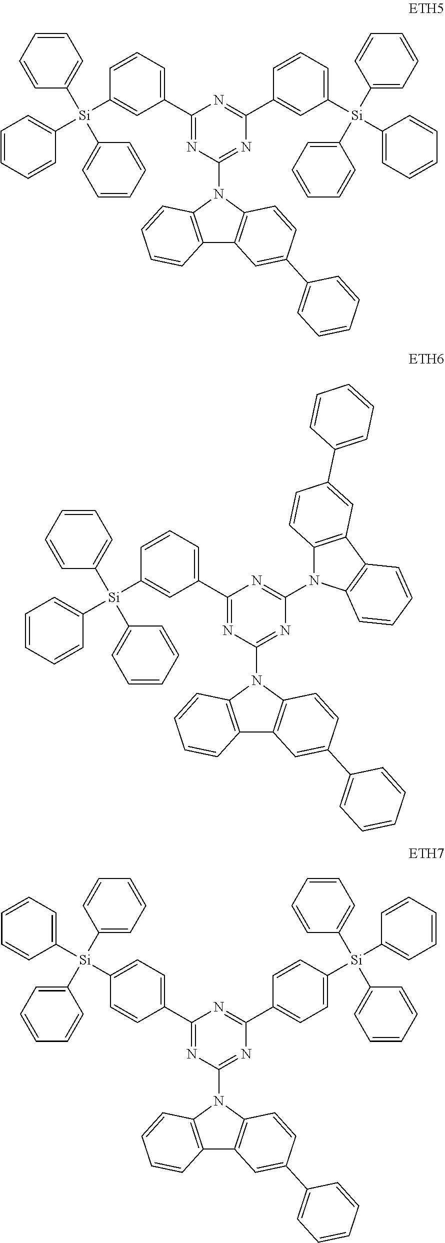 [SMILES: c1ccc(-c2ccc3c(c2)c2ccccc2n3-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4cc(-c5ccccc5)ccc43)n2)cc1 ; c1ccc(-c2ccc3c(c2)c2ccccc2n3-c2nc(-c3ccc([Si](c4ccccc4)(c4ccccc4)c4ccccc4)cc3)nc(-c3ccc([Si](c4ccccc4)(c4ccccc4)c4ccccc4)cc3)n2)cc1]

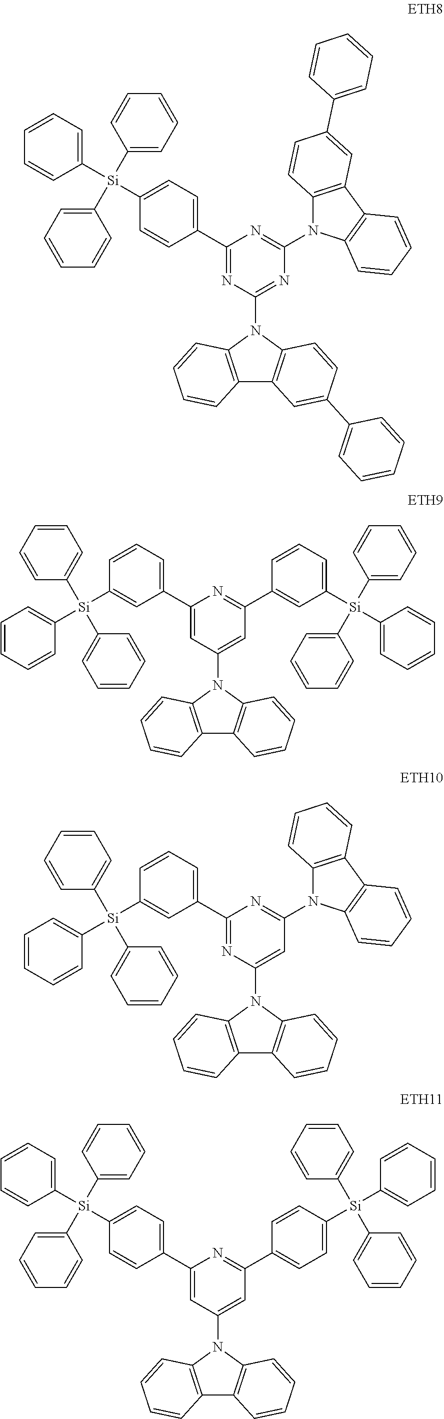 [SMILES: c1ccc(-c2ccc3c(c2)c2ccccc2n3-c2nc(-c3ccc([Si](c4ccccc4)(c4ccccc4)c4ccccc4)cc3)nc(-n3c4ccccc4c4cc(-c5ccccc5)ccc43)n2)cc1 ; c1ccc([Si](c2ccccc2)(c2ccccc2)c2cccc(-c3cc(-n4c5ccccc5c5ccccc54)cc(-c4cccc([Si](c5ccccc5)(c5ccccc5)c5ccccc5)c4)n3)c2)cc1 ; c1ccc([Si](c2ccccc2)(c2ccccc2)c2cccc(-c3nc(-n4c5ccccc5c5ccccc54)cc(-n4c5ccccc5c5ccccc54)n3)c2)cc1 ; c1ccc([Si](c2ccccc2)(c2ccccc2)c2ccc(-c3cc(-n4c5ccccc5c5ccccc54)cc(-c4ccc([Si](c5ccccc5)(c5ccccc5)c5ccccc5)cc4)n3)cc2)cc1]

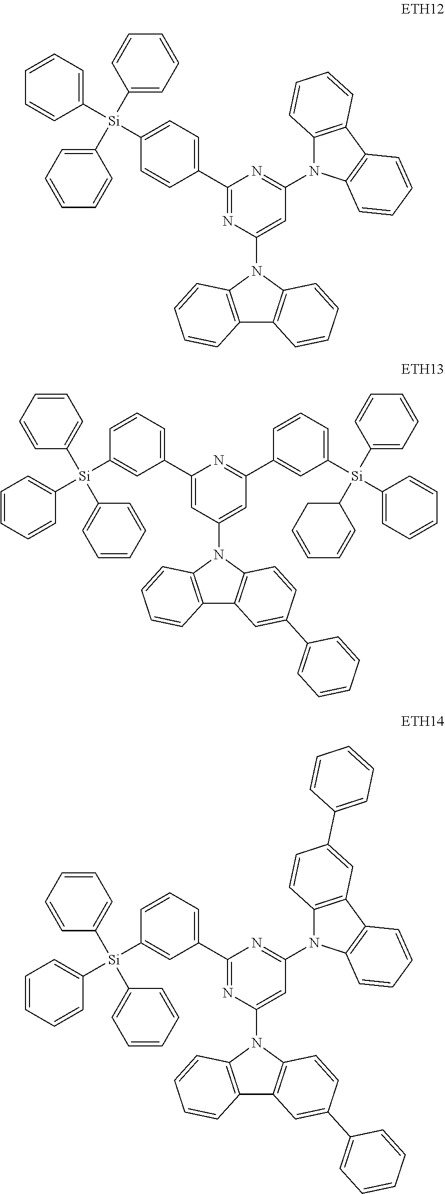 [SMILES: c1ccc([Si](c2ccccc2)(c2ccccc2)c2ccc(-c3nc(-n4c5ccccc5c5ccccc54)cc(-n4c5ccccc5c5ccccc54)n3)cc2)cc1 ; C1=CCC([Si](c2ccccc2)(c2ccccc2)c2cccc(-c3cc(-n4c5ccccc5c5cc(-c6ccccc6)ccc54)cc(-c4cccc([Si](c5ccccc5)(c5ccccc5)c5ccccc5)c4)n3)c2)C=C1 ; c1ccc(-c2ccc3c(c2)c2ccccc2n3-c2cc(-n3c4ccccc4c4cc(-c5ccccc5)ccc43)nc(-c3cccc([Si](c4ccccc4)(c4ccccc4)c4ccccc4)c3)n2)cc1]

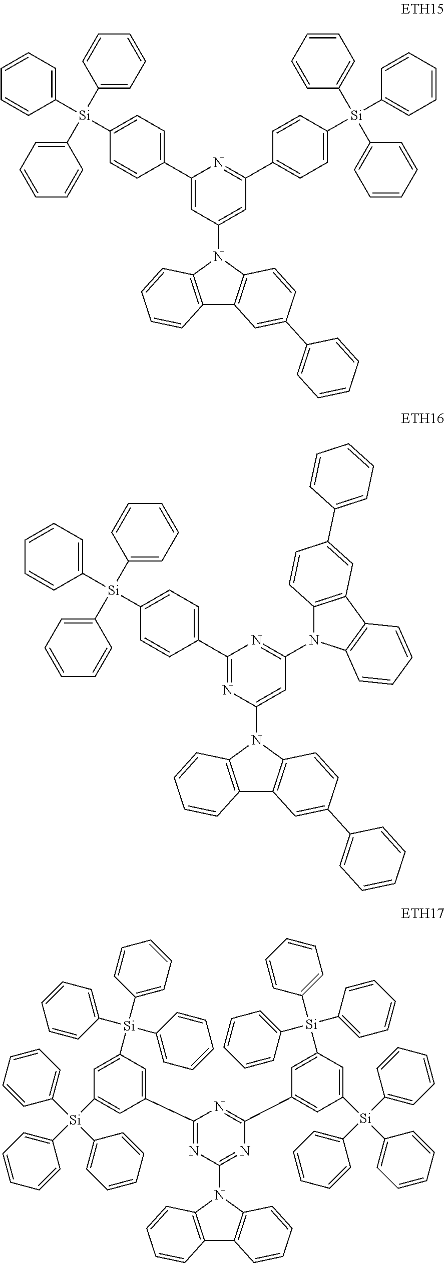 [SMILES: c1ccc(-c2ccc3c(c2)c2ccccc2n3-c2cc(-c3ccc([Si](c4ccccc4)(c4ccccc4)c4ccccc4)cc3)nc(-c3ccc([Si](c4ccccc4)(c4ccccc4)c4ccccc4)cc3)c2)cc1 ; c1ccc(-c2ccc3c(c2)c2ccccc2n3-c2cc(-n3c4ccccc4c4cc(-c5ccccc5)ccc43)nc(-c3ccc([Si](c4ccccc4)(c4ccccc4)c4ccccc4)cc3)n2)cc1 ; c1ccc([Si](c2ccccc2)(c2ccccc2)c2cc(-c3nc(-c4cc([Si](c5ccccc5)(c5ccccc5)c5ccccc5)cc([Si](c5ccccc5)(c5ccccc5)c5ccccc5)c4)nc(-n4c5ccccc5c5ccccc54)n3)cc([Si](c3ccccc3)(c3ccccc3)c3ccccc3)c2)cc1]

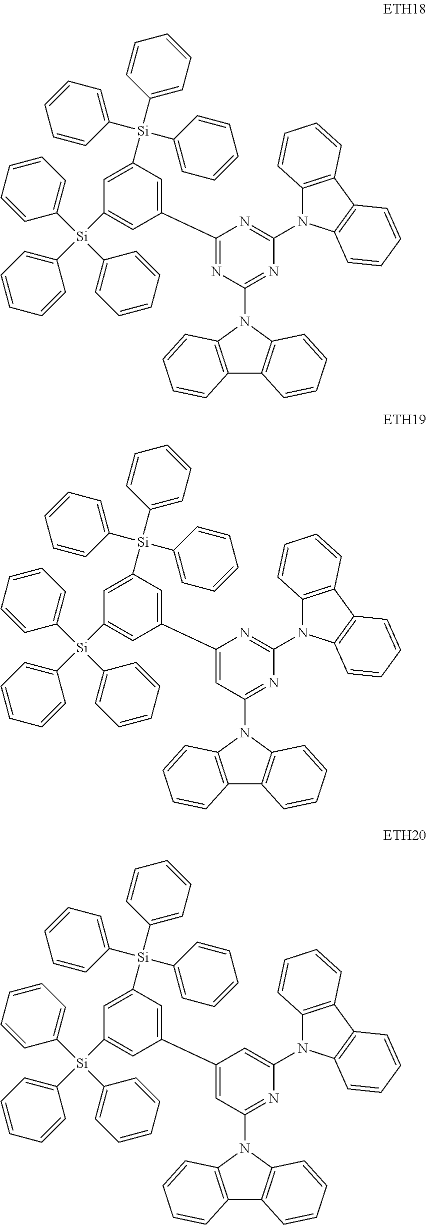 [SMILES: c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1 ; c1ccc([Si](c2ccccc2)(c2ccccc2)c2cc(-c3cc(-n4c5ccccc5c5ccccc54)nc(-n4c5ccccc5c5ccccc54)n3)cc([Si](c3ccccc3)(c3ccccc3)c3ccccc3)c2)cc1 ; c1ccc([Si](c2ccccc2)(c2ccccc2)c2cc(-c3cc(-n4c5ccccc5c5ccccc54)nc(-n4c5ccccc5c5ccccc54)c3)cc([Si](c3ccccc3)(c3ccccc3)c3ccccc3)c2)cc1]

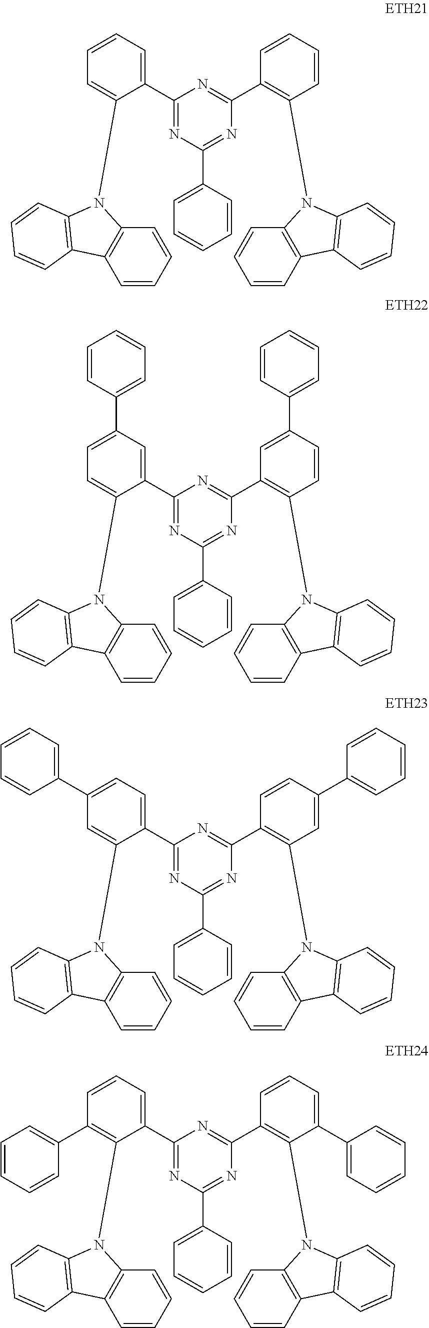

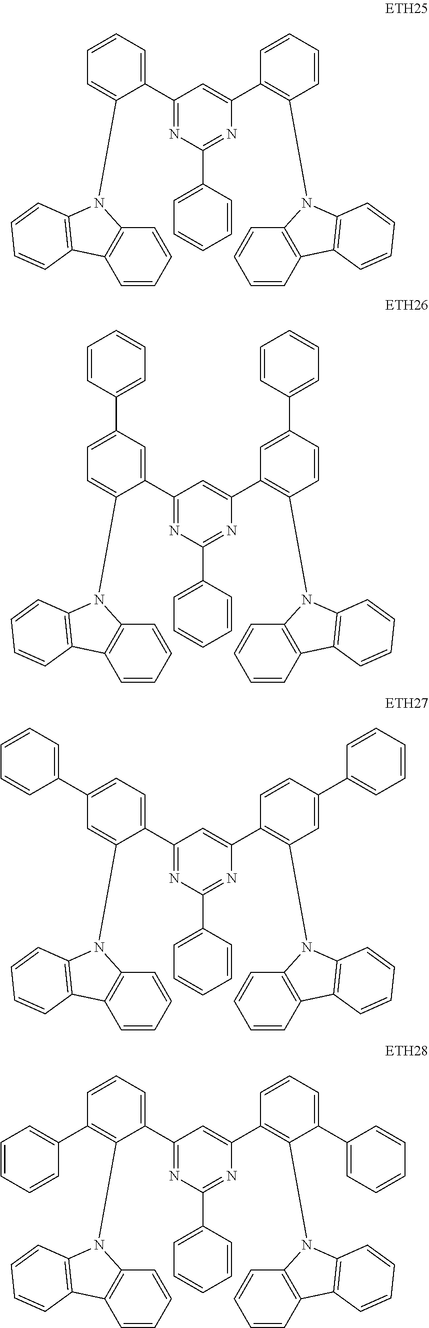

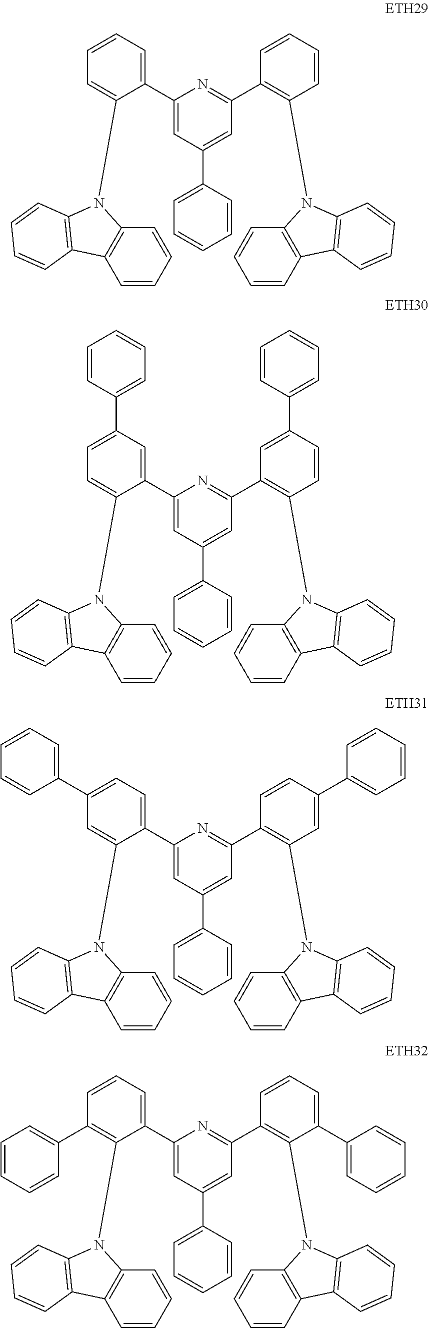

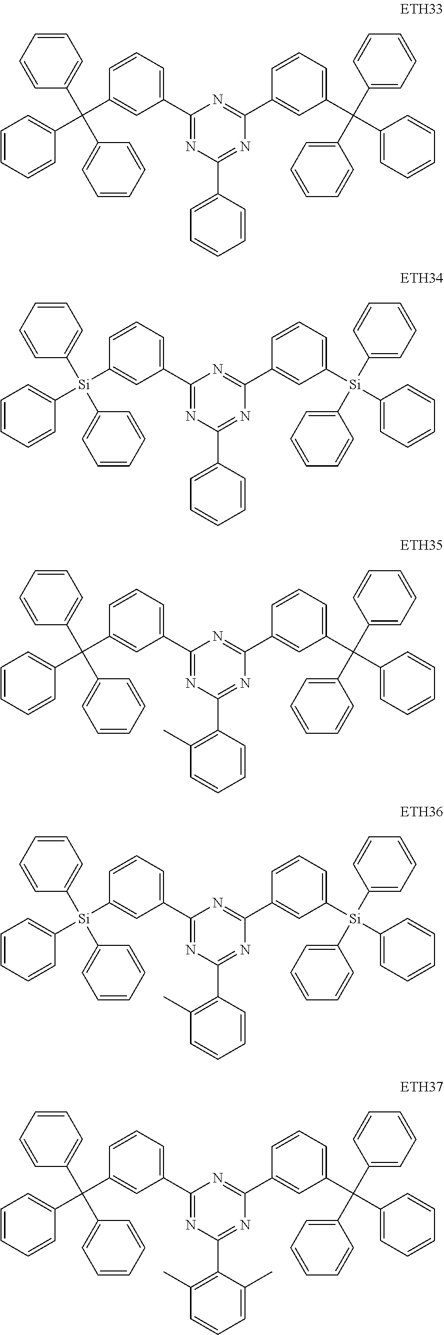

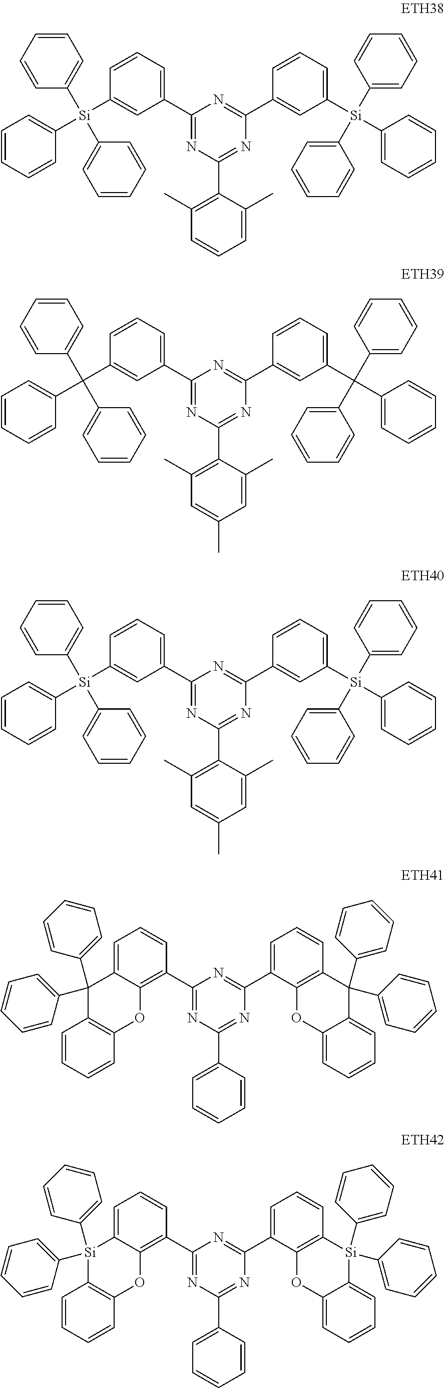

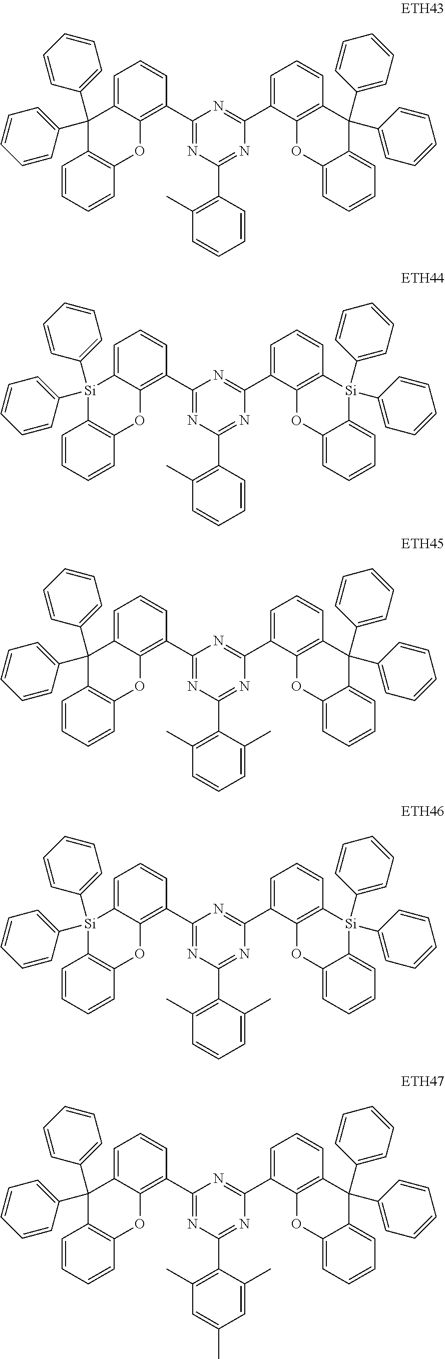

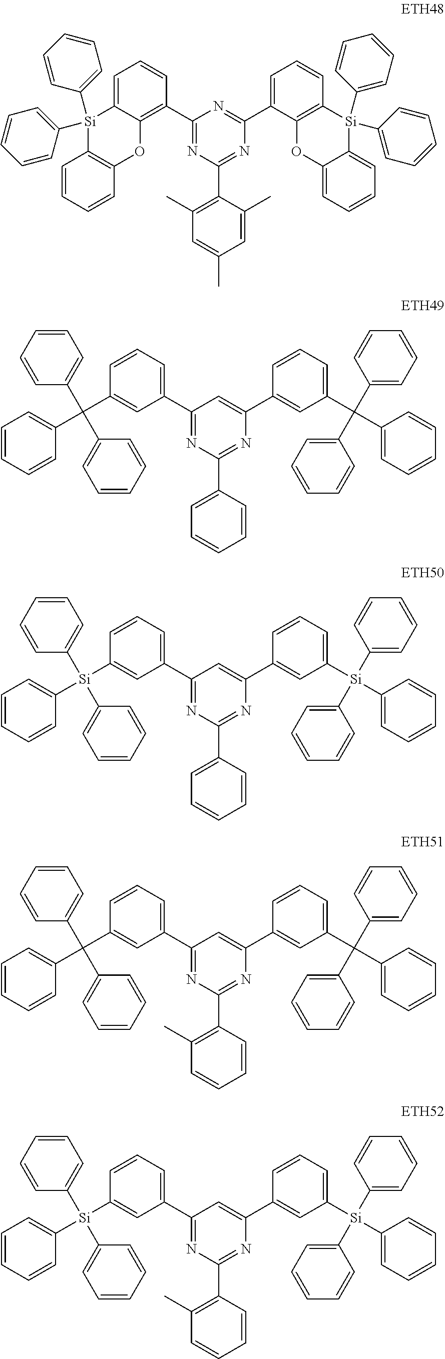

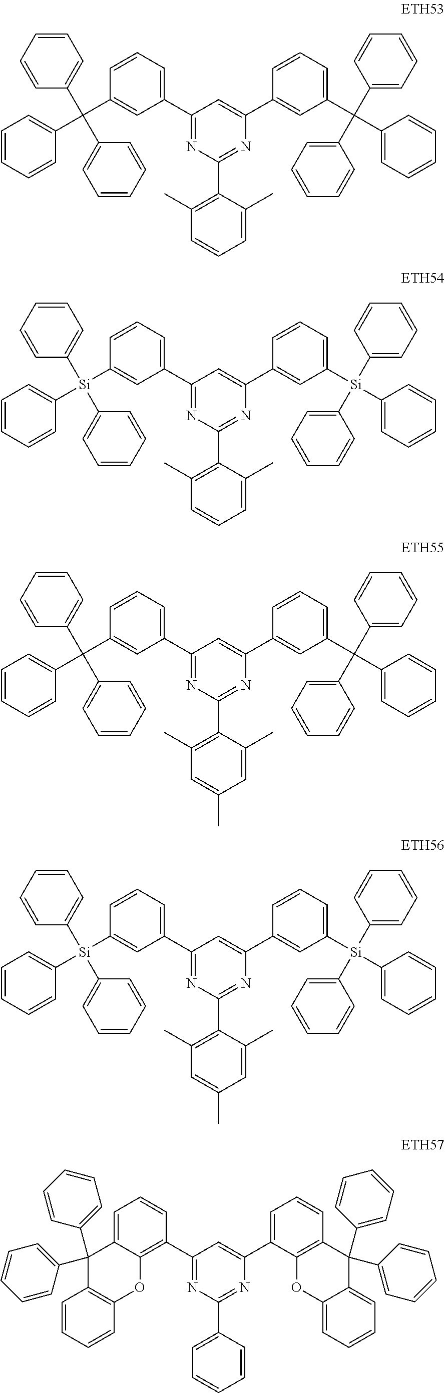

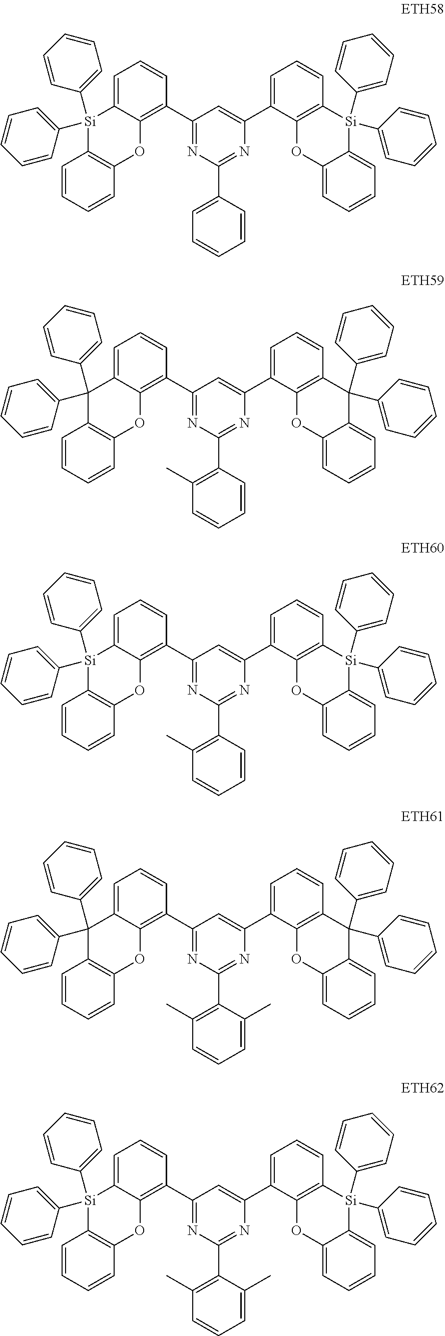

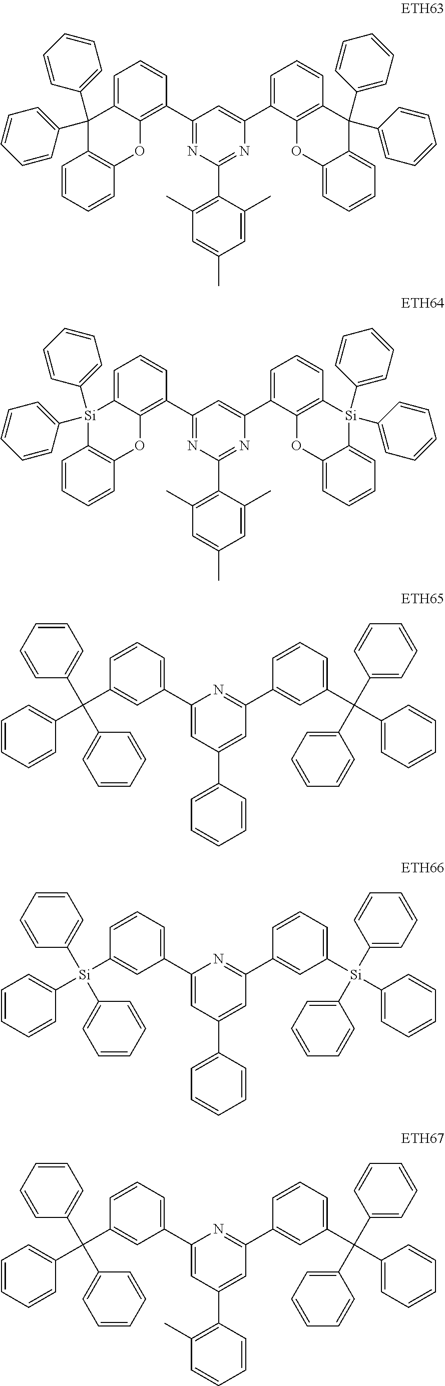

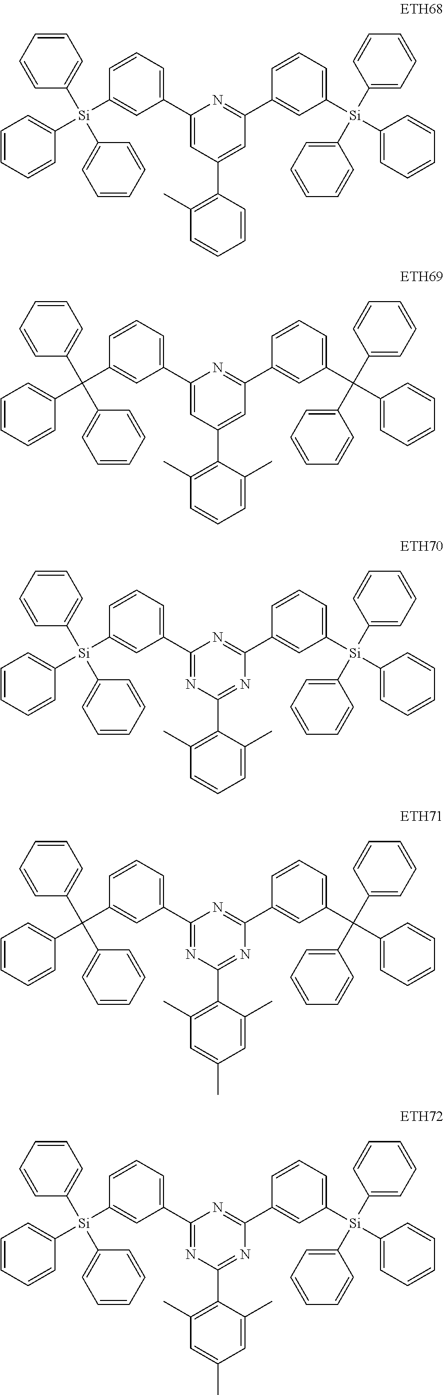

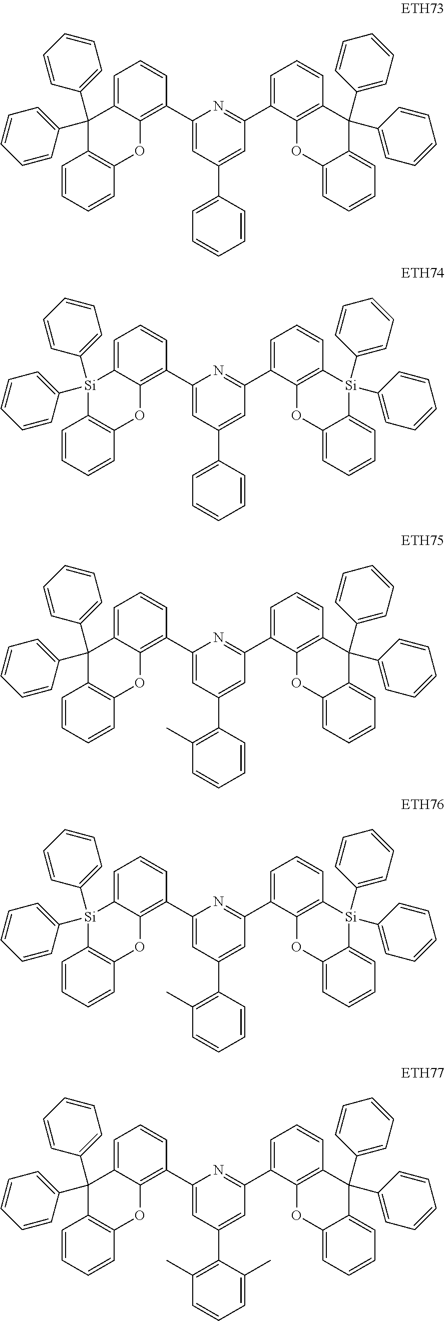

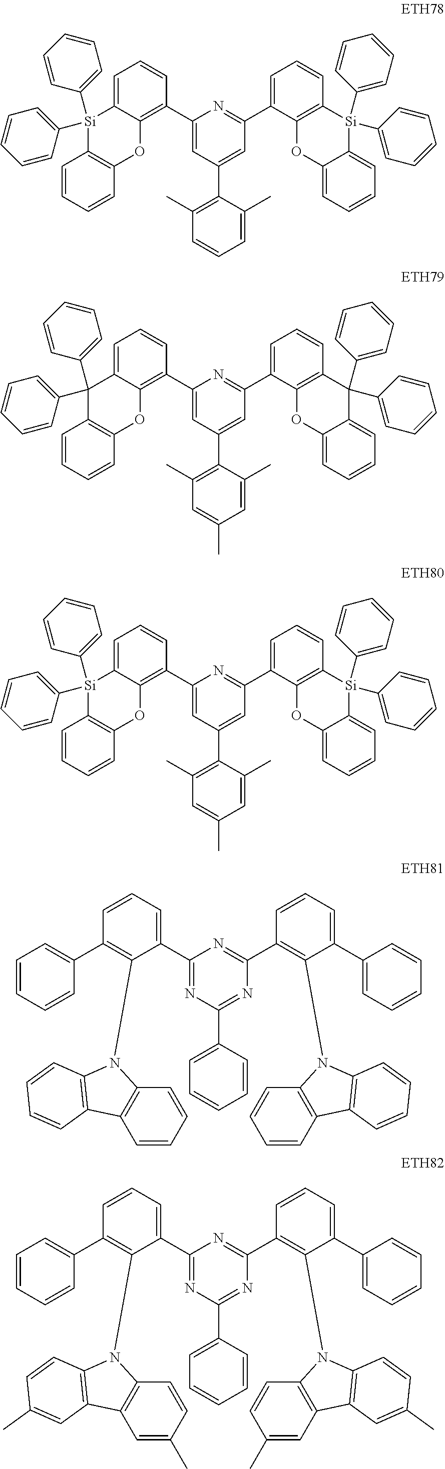

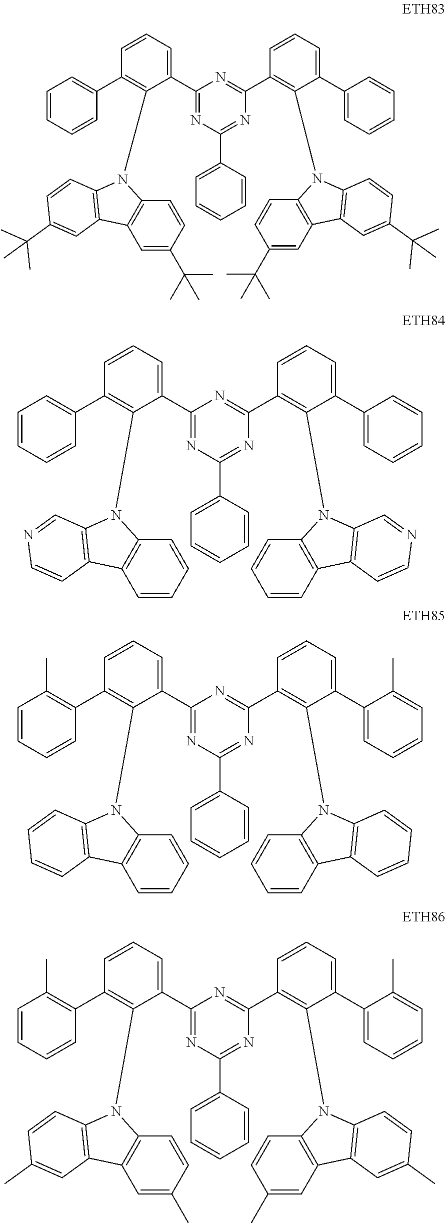

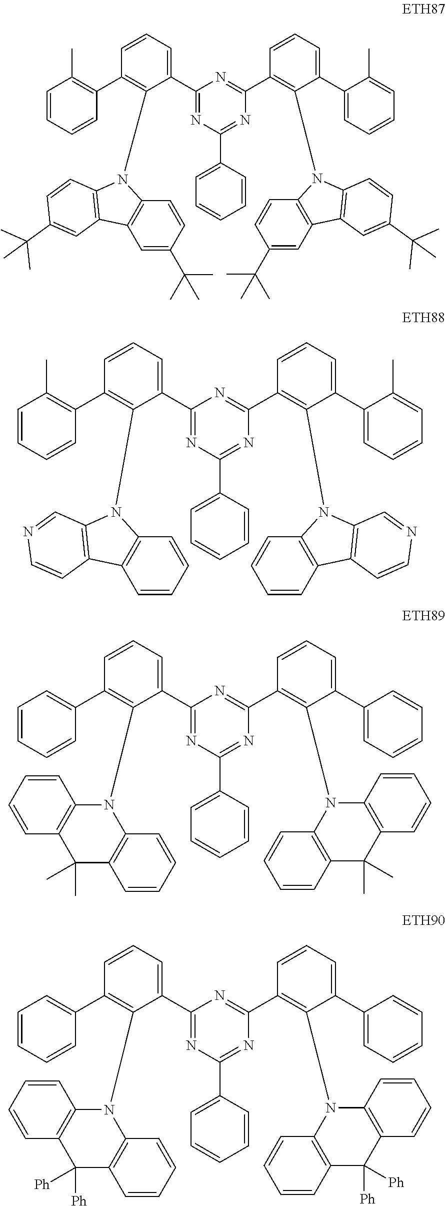

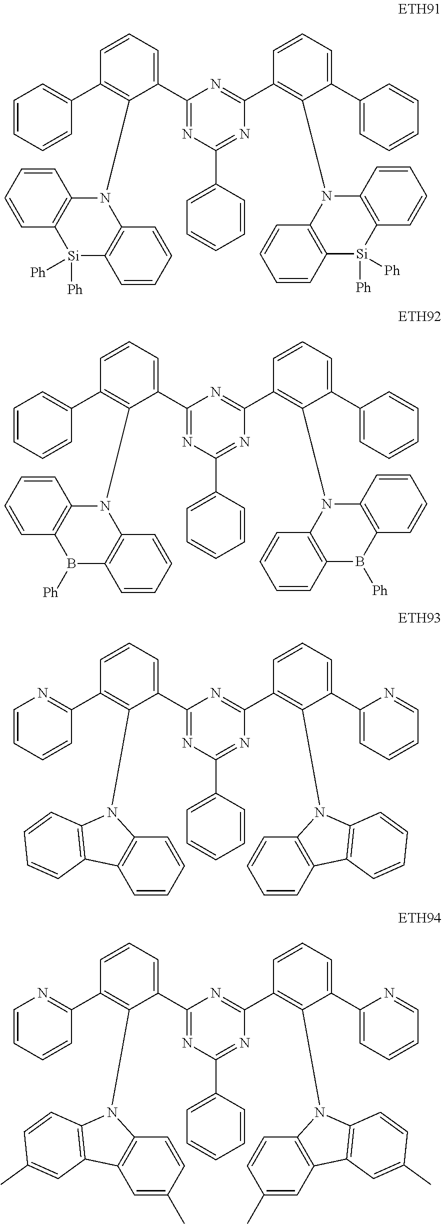

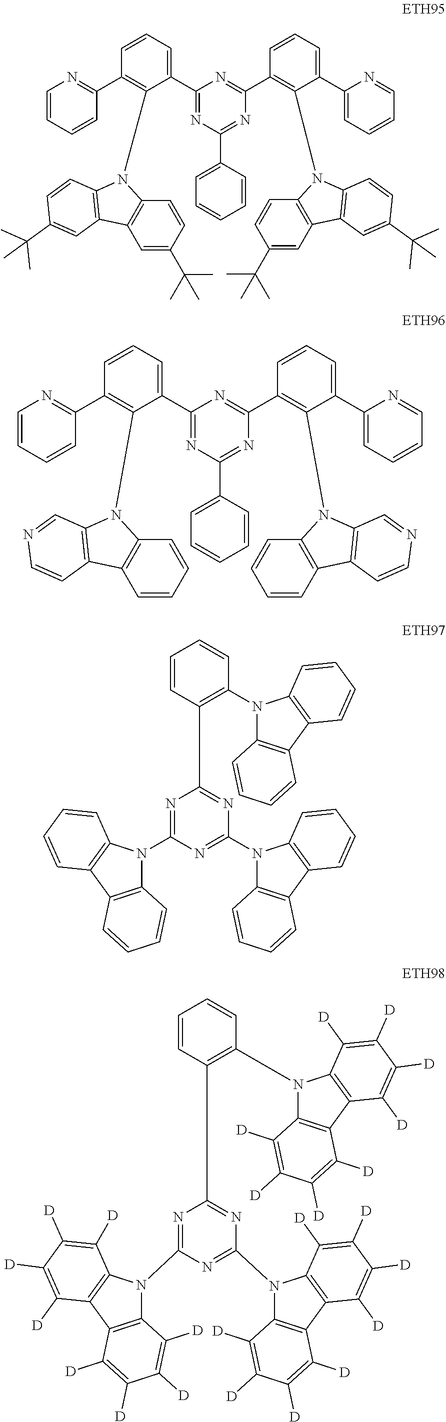

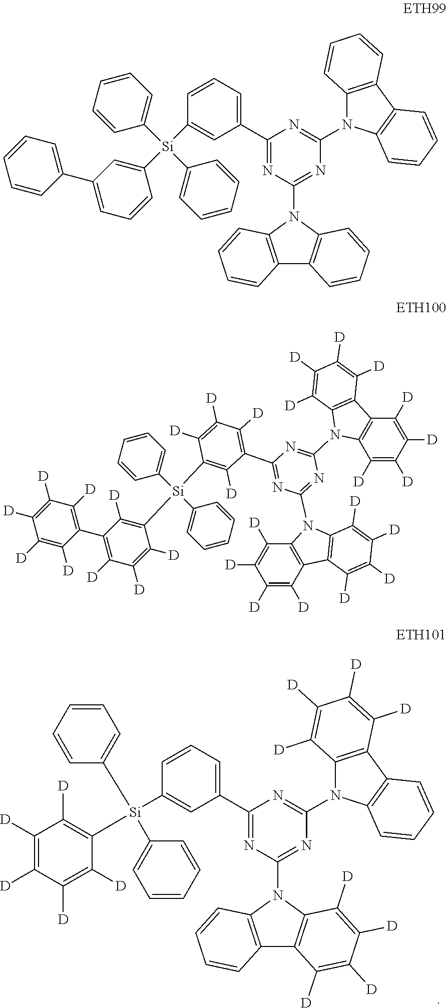

In one or more embodiments, the third compound may be one selected from among Compounds HTH1 to HTH47:

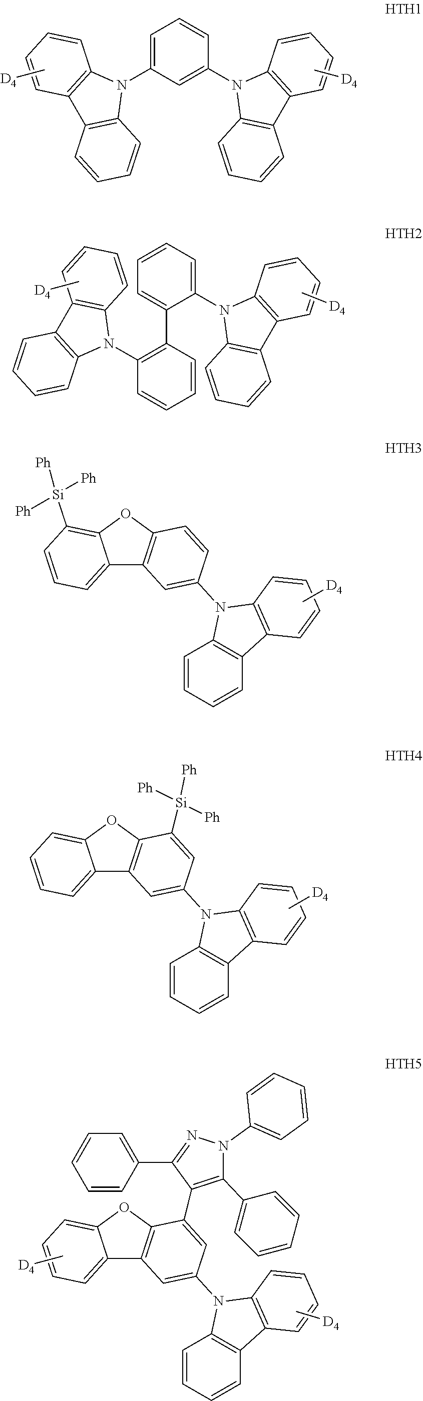

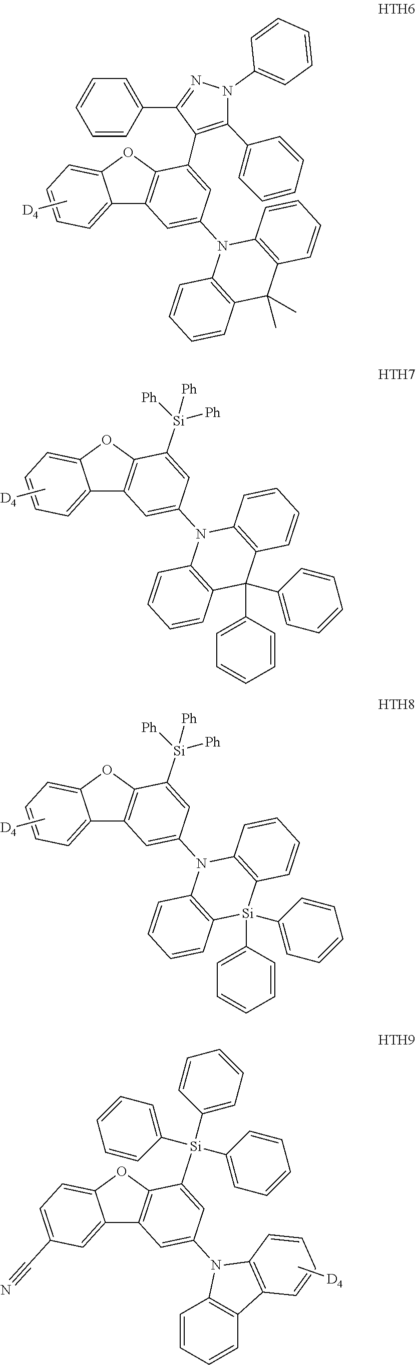

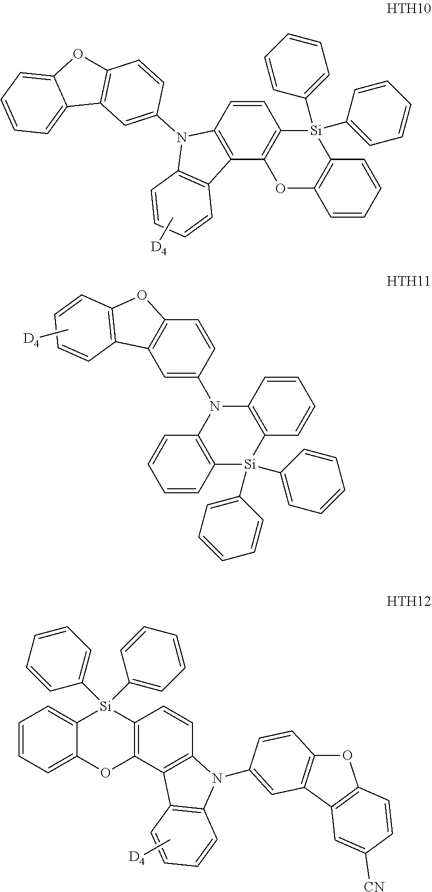

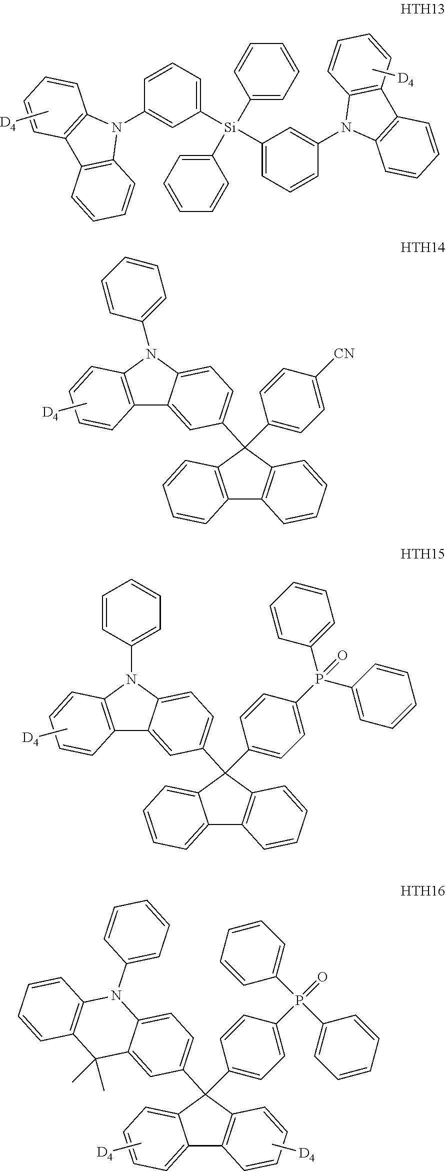

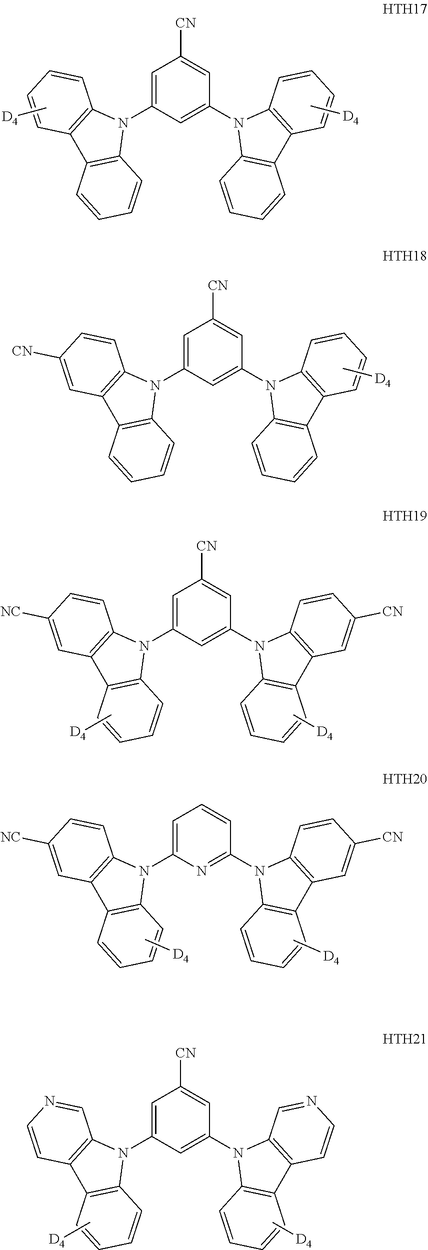

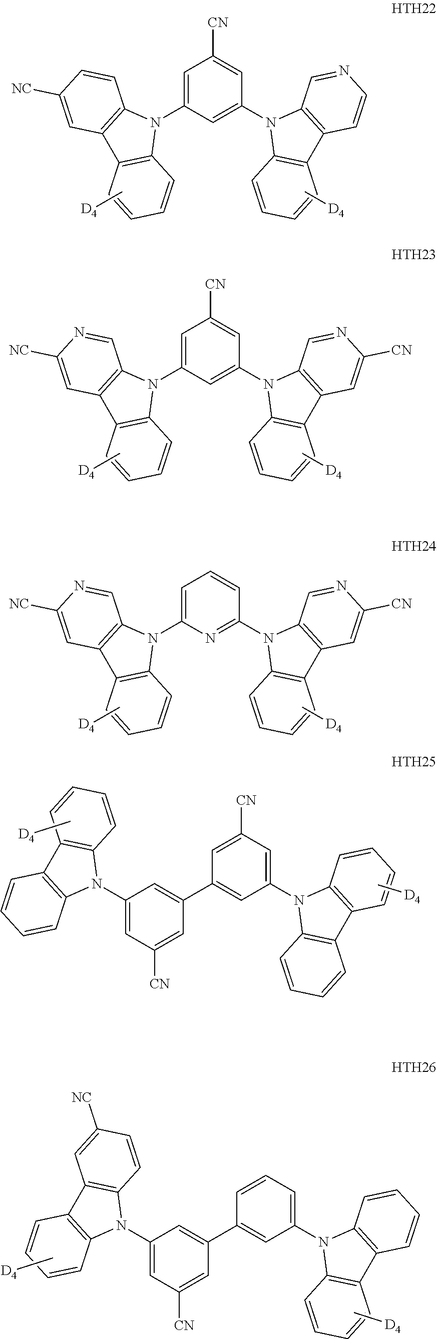

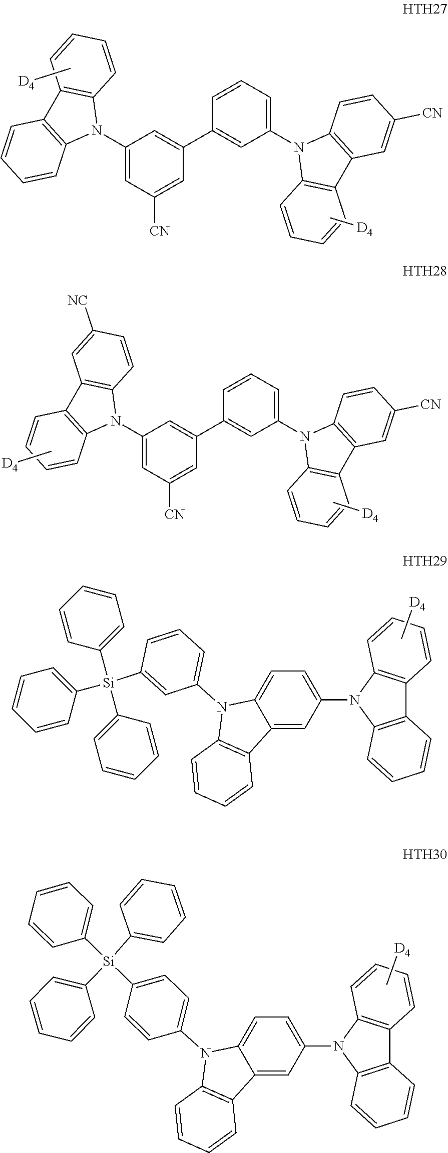

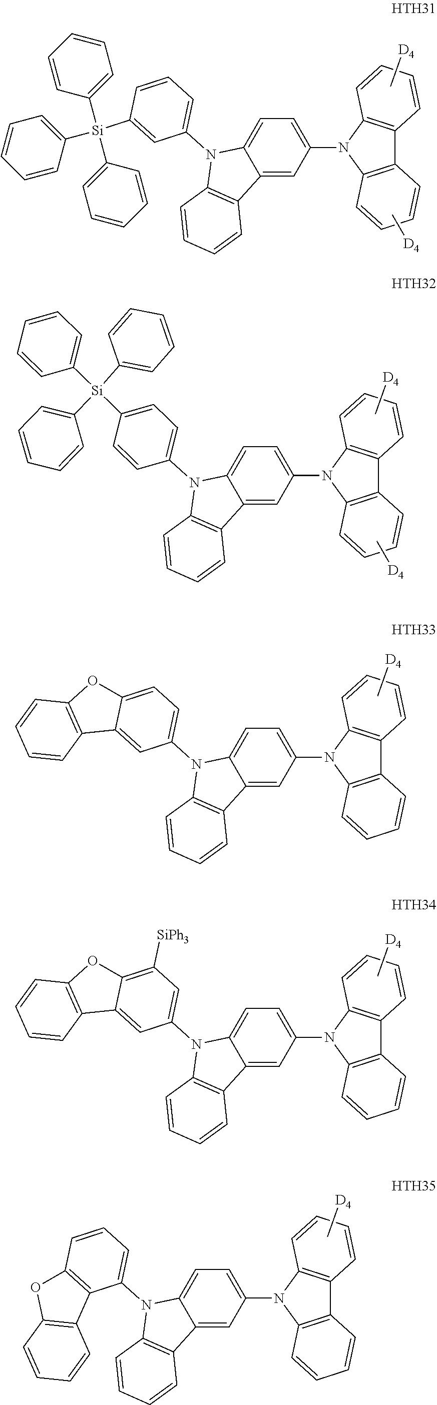

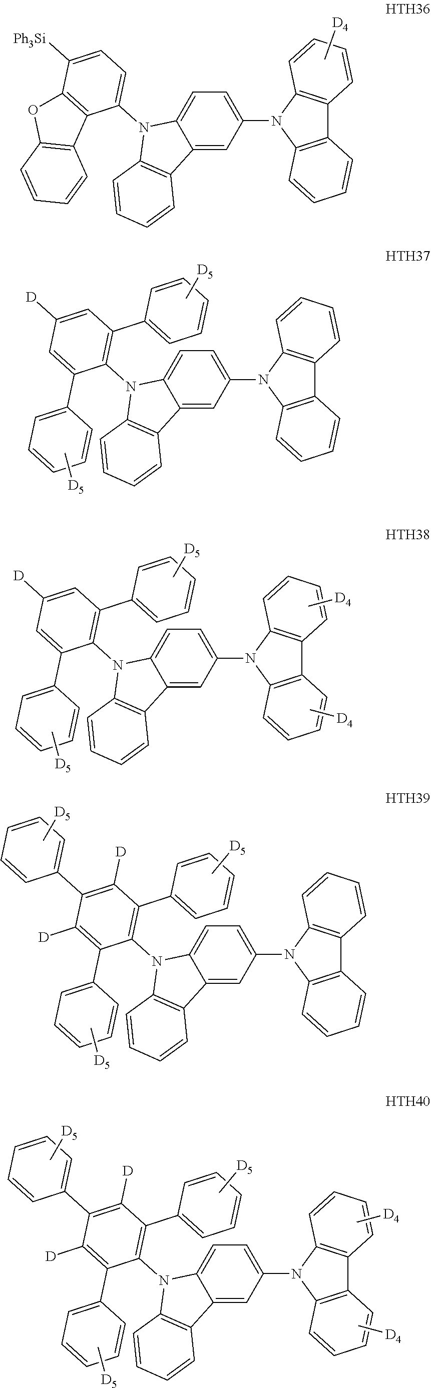

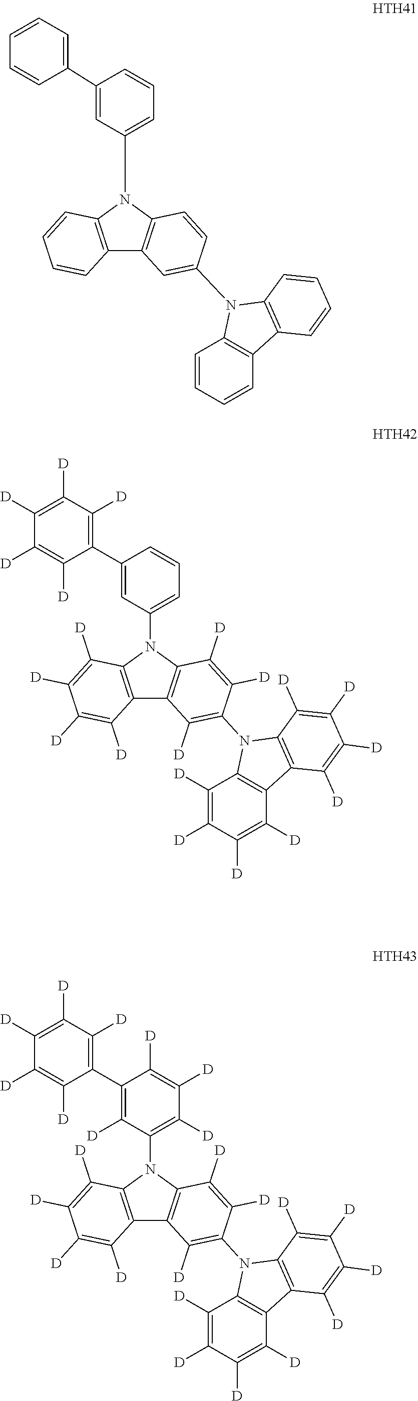 [SMILES: c1ccc(-c2cccc(-n3c4ccccc4c4cc(-n5c6ccccc6c6ccccc65)ccc43)c2)cc1 ; [2H]c1c([2H])c([2H])c(-c2cccc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2)c([2H])c1[2H] ; [2H]c1c([2H])c([2H])c(-c2c([2H])c([2H])c([2H])c(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2[2H])c([2H])c1[2H]]

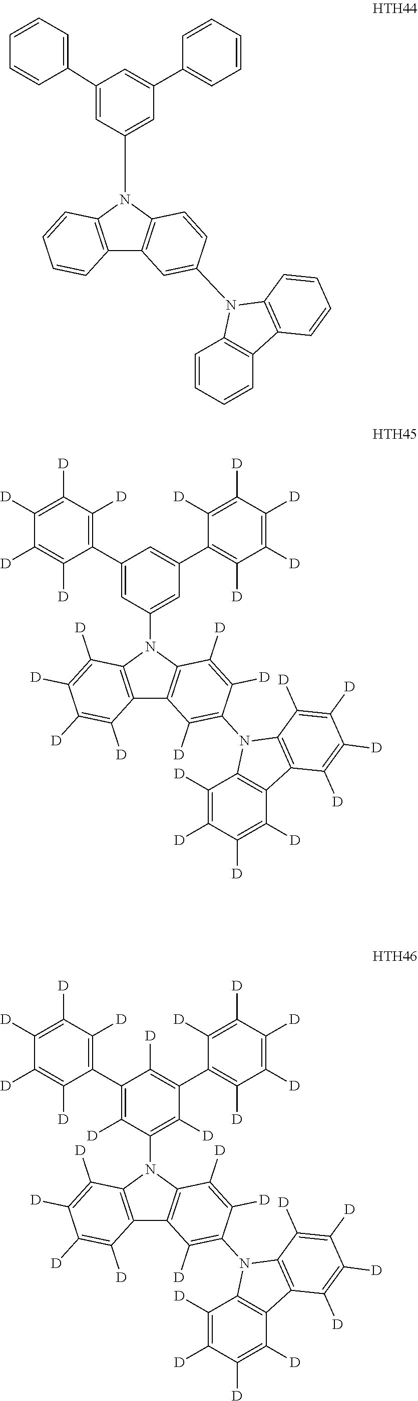

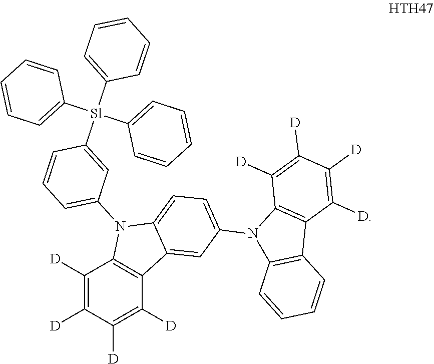

In one or more embodiments, the fourth compound may be one selected from among Compounds DFD1 to DFD31:

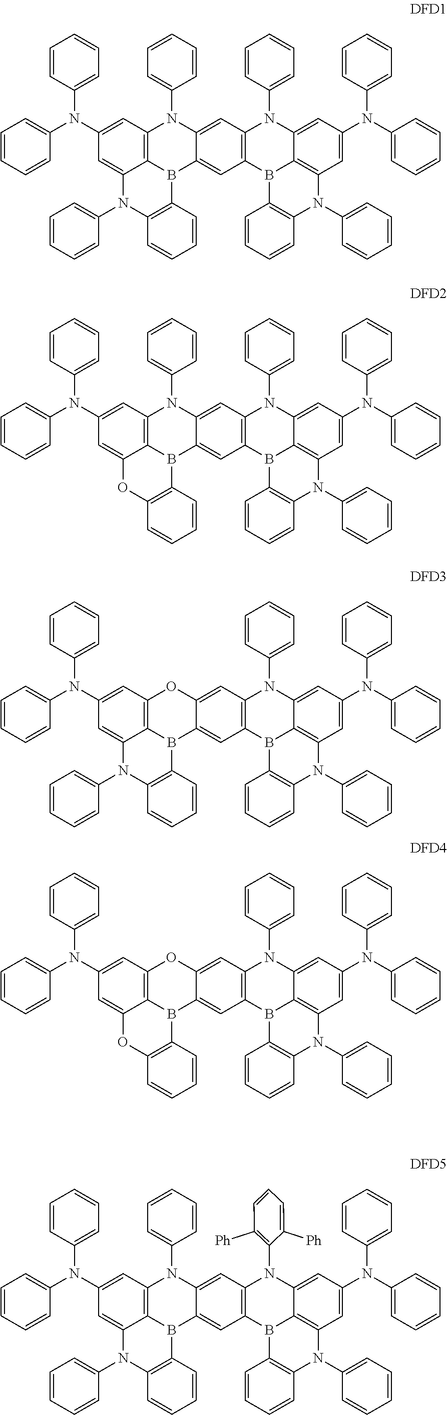

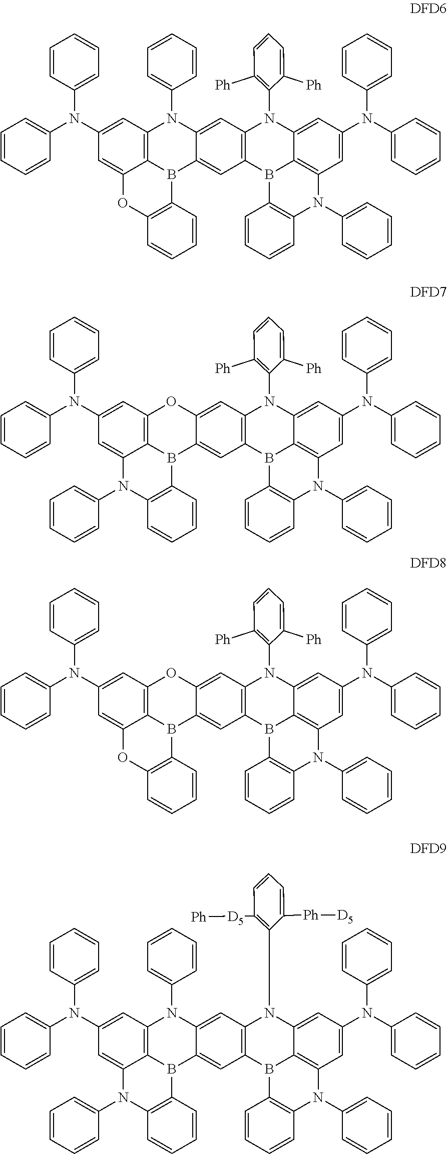

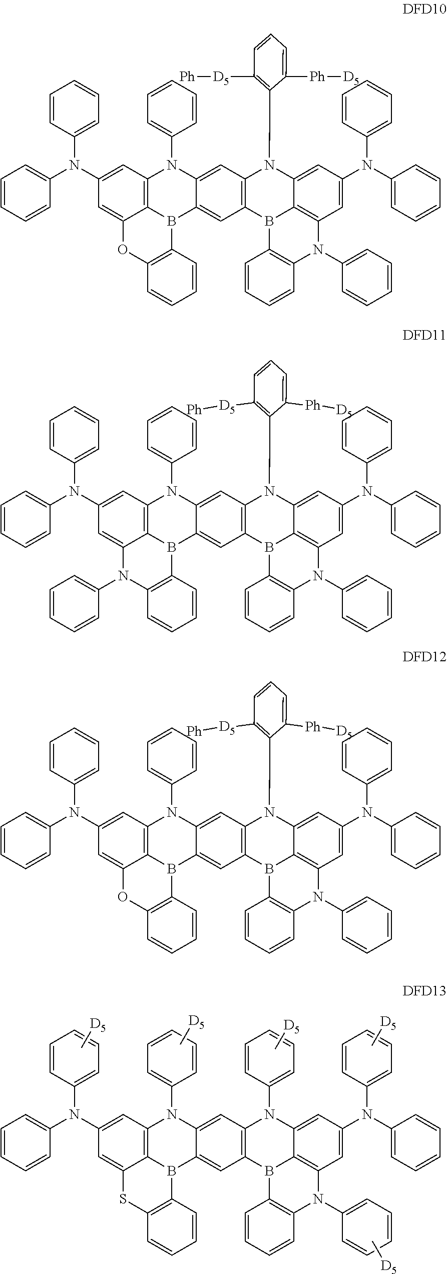

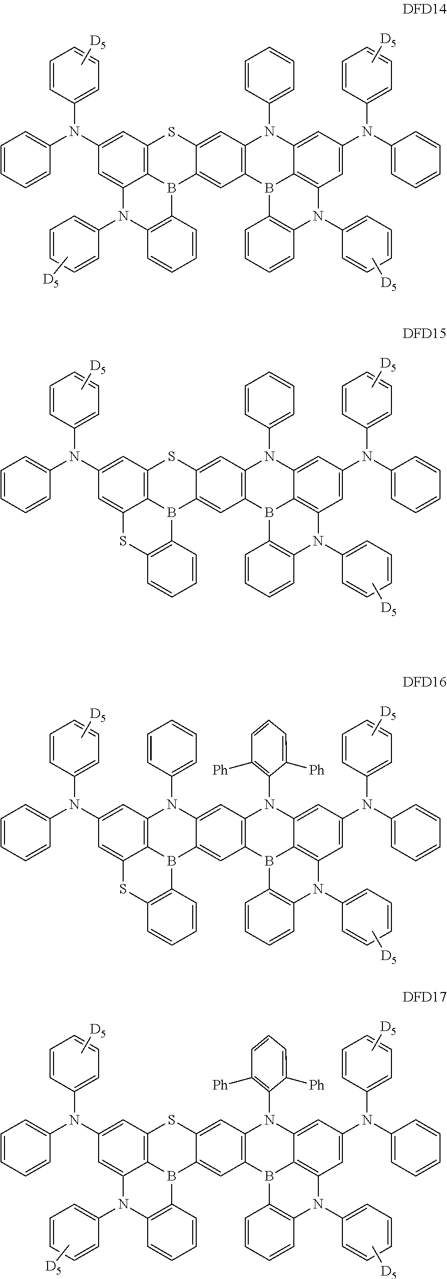

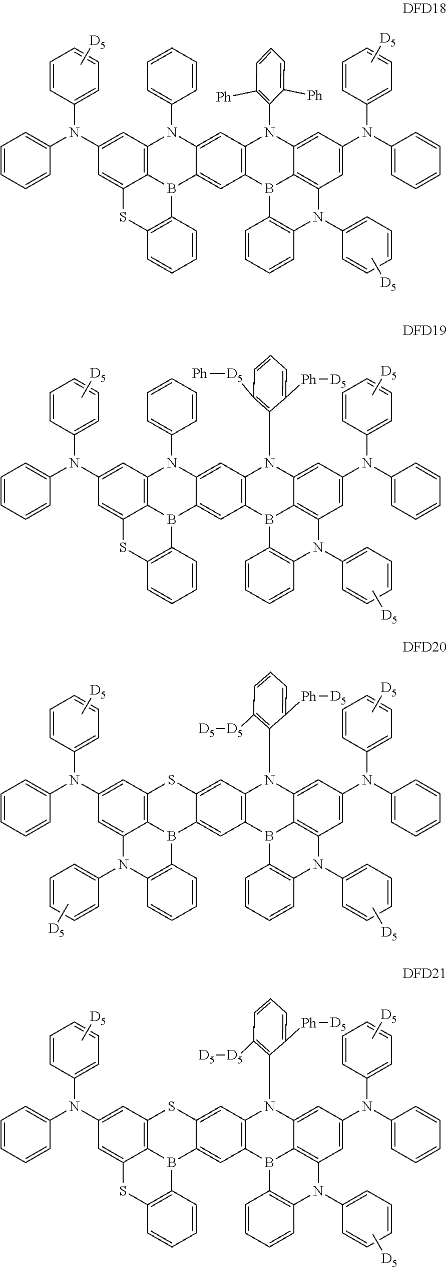

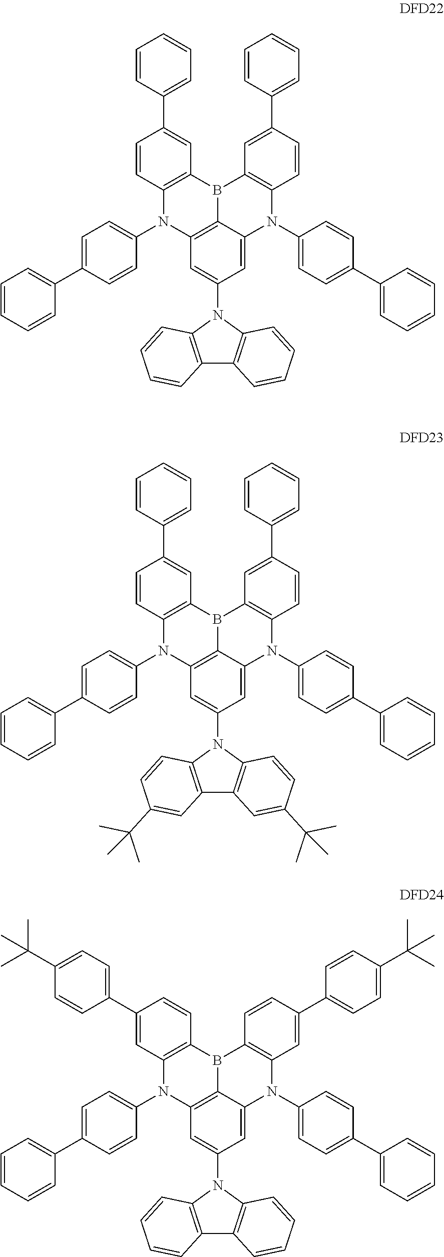 [SMILES: c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1 ; CC(C)(C)c1ccc2c(c1)c1cc(C(C)(C)C)ccc1n2-c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; CC(C)(C)c1ccc(-c2ccc3c(c2)N(c2ccc(-c4ccccc4)cc2)c2cc(-n4c5ccccc5c5ccccc54)cc4c2B3c2ccc(-c3ccc(C(C)(C)C)cc3)cc2N4c2ccc(-c3ccccc3)cc2)cc1]

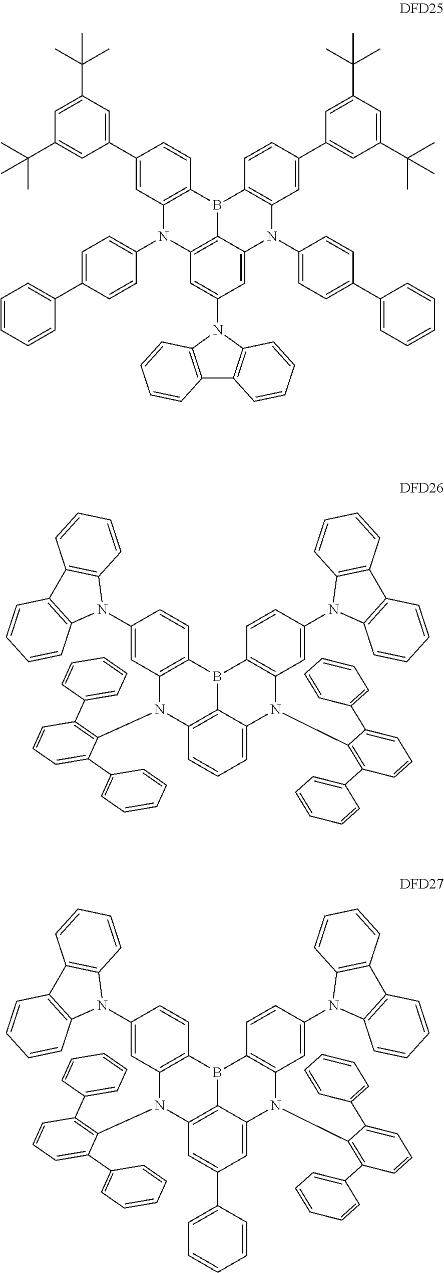 [SMILES: CC(C)(C)c1cc(-c2ccc3c(c2)N(c2ccc(-c4ccccc4)cc2)c2cc(-n4c5ccccc5c5ccccc54)cc4c2B3c2ccc(-c3cc(C(C)(C)C)cc(C(C)(C)C)c3)cc2N4c2ccc(-c3ccccc3)cc2)cc(C(C)(C)C)c1 ; c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cccc2c43)cc1 ; c1ccc(-c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)cc1]

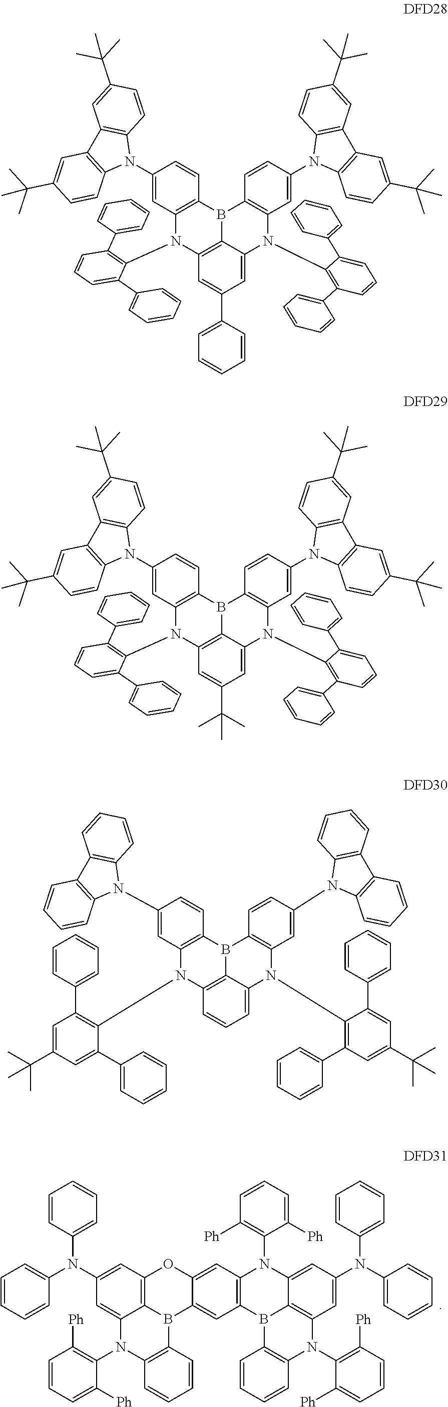

In the compounds above, Ph represents a phenyl group, D₅ represents substitution with five deuterium, and D₄ represents substitution with four deuterium. For example, a group represented by

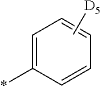

may be identical to a group represented by

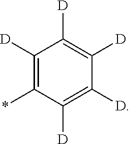

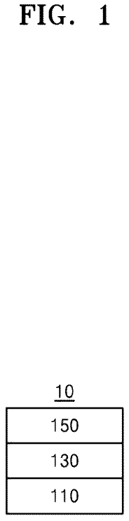

### Description of FIG. 1

FIG. 1 is a schematic cross-sectional view of a light-emitting device 10 according to one or more embodiments. The light-emitting device 10 may include a first electrode 110, an interlayer 130, and a second electrode 150.

Hereinafter, a structure of the light-emitting device 10 according to one or more embodiments and a method of manufacturing the light-emitting device 10 will be described with reference to FIG. 1.

### First Electrode 110

In FIG. 1, in one or more embodiments, a substrate may be additionally provided and arranged under the first electrode 110 and/or on the second electrode 150. In one or more embodiments, as the substrate, a glass substrate or a plastic substrate may be utilized. In one or more embodiments, the substrate may be a flexible substrate, and may include plastics with excellent or suitable heat resistance and durability, such as polyimide, polyethylene terephthalate (PET), polycarbonate, polyethylene naphthalate, polyarylate (PAR), polyetherimide, or a (e.g., any suitable) combination thereof.

The first electrode 110 may be formed by, for example, depositing or sputtering a material for forming (or providing) the first electrode 110 on the substrate. When the first electrode 110 is an anode, a material for forming (or providing) the first electrode 110 may be a high-work function material that facilitates injection of holes.

The first electrode 110 may be a reflective electrode, a transflective electrode, or a transmissive electrode. In one or more embodiments, when the first electrode 110 is a transmissive electrode, a material for forming (or providing) the first electrode 110 may include indium tin oxide (ITO), indium zinc oxide (IZO), tin oxide (SnO₂), zinc oxide (ZnO), or a (e.g., any suitable) combination thereof. In one or more embodiments, when the first electrode 110 is a transflective electrode or a reflective electrode, a material for forming (or providing) the first electrode 110 may include magnesium (Mg), silver (Ag), aluminum (Al), aluminum-lithium (Al—Li), calcium (Ca), magnesium-indium (Mg—In), magnesium-silver (Mg—Ag), or a (e.g., any suitable) combination thereof.

The first electrode 110 may have a single-layer structure including (e.g., consisting of) a single layer, or a multi-layer structure including multiple layers. For example, in some embodiments, the first electrode 110 may have a three-layer structure of ITO/Ag/ITO.

### Interlayer 130

The interlayer 130 may be arranged on the first electrode 110. The interlayer 130 may include an emission layer.

In one or more embodiments, the interlayer 130 may further include: a hole transport region between the first electrode 110 and the emission layer; and an electron transport region between the emission layer and the second electrode 150.

In one or more embodiments, the interlayer 130 may further include, in addition to one or more suitable organic materials, a metal-containing compound such as an organometallic compound, for example, the organometallic compound represented by Formula 1, an inorganic material such as quantum dots, and/or the like.

In one or more embodiments, the interlayer 130 may include i) two or more light-emitting units sequentially stacked between the first electrode 110 and the second electrode 150, and ii) a charge generation layer arranged between two neighboring light-emitting units. When the interlayer 130 includes the two or more light-emitting units and the charge generation layer, the light-emitting device 10 may be a tandem light-emitting device.

### Hole Transport Region in Interlayer 130

The hole transport region may have i) a single-layer structure including (e.g., consisting of) a single layer including (e.g., consisting of) a single material, ii) a single-layer structure including (e.g., consisting of) a single layer including (e.g., consisting of) multiple materials that are different from each other, or iii) a multi-layer structure including multiple layers including multiple materials that are different from each other.

The hole transport region may include a hole injection layer, a hole transport layer, an emission auxiliary layer, an electron blocking layer, or a (e.g., any suitable) combination thereof.

For example, in some embodiments, the hole transport region may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein constituent layers in each structure are sequentially stacked from the first electrode 110 in the stated order.

In one or more embodiments, the hole transport region may include a compound represented by Formula 201, a compound represented by Formula 202, or a (e.g., any suitable) combination thereof:

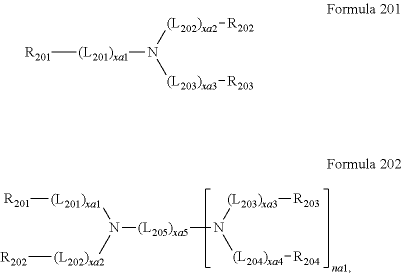

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form (or provide) a C₈-C₆₀ polycyclic group (e.g., a carbazole group and/or the like) unsubstituted or substituted with at least one R₁₀ₐ (e.g., see Compound HT16),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form (or provide) a C₈-C₆₀ polycyclic group unsubstituted or substituted with at least one R₁₀ₐ, and
na1 may be an integer from 1 to 4.

For example, in some embodiments, each of Formulae 201 and 202 may include at least one selected from among groups represented by Formulae CY201 to CY217:

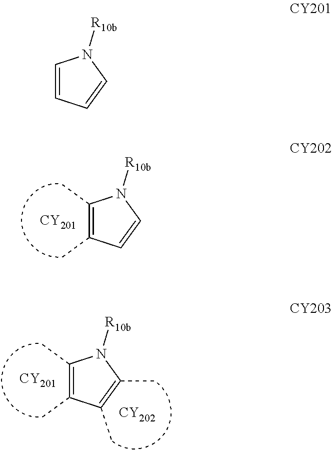

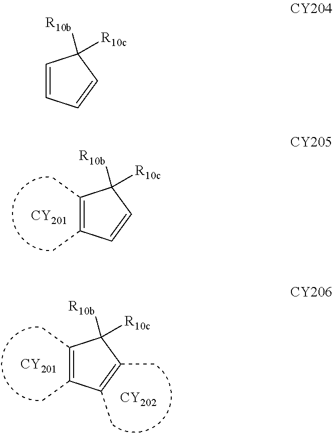

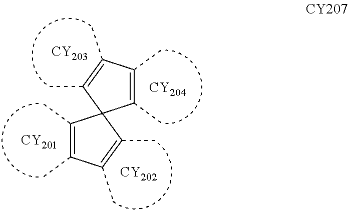

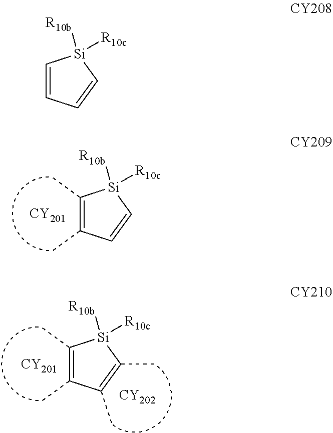

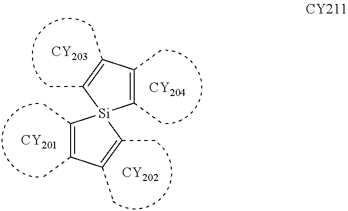

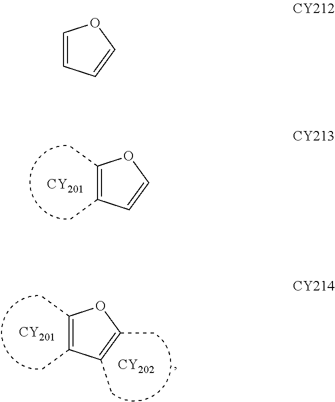

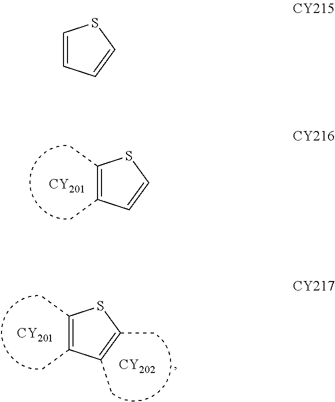

wherein, in Formulae CY201 to CY217, R_{10b} and R_{10c} may each be the same as described with respect to R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, ring CY₂₀₁ to ring CY₂₀₄ in Formulae CY201 to CY217 may each independently be a benzene group, a naphthalene group, a phenanthrene group, or an anthracene group.

In one or more embodiments, each of Formulae 201 and 202 may include at least one selected from among groups represented by Formulae CY201 to CY203.

In one or more embodiments, Formula 201 may include at least one selected from among groups represented by Formulae CY201 to CY203 and at least one selected from among groups represented by Formulae CY204 to CY217.

In one or more embodiments, in Formula 201, xa1 may be 1, R₂₀₁ may be one selected from among groups represented by Formulae CY201 to CY203, xa2 may be 0, and R₂₀₂ may be one selected from among groups represented by Formulae CY204 to CY207.

In one or more embodiments, each of Formulae 201 and 202 may not include (e.g., may exclude) any of groups represented by Formulae CY201 to CY203.

In one or more embodiments, each of Formulae 201 and 202 may not include (e.g., may exclude) any of groups represented by Formulae CY201 to CY203, and may include at least one selected from among groups represented by Formulae CY204 to CY217.

In one or more embodiments, each of Formulae 201 and 202 may not include (e.g., may exclude) any of groups represented by Formulae CY201 to CY217. In present disclosure, “not include a or any ‘component’” “exclude a or any ‘component’”, “‘component’-free”, and/or the like refers to that the “component” not being added, selected or utilized as a component in the composition/formula/structure, but, in some embodiments, the “component” of less than a suitable amount may still be included due to other impurities and/or external factors.

For example, in one or more embodiments, the hole transport region may include: at least one selected from among Compounds HT1 to HT46; 4,4′,4″-[tris(3-methylphenyl)phenylamino]triphenylamine (m-MTDATA); 4,4′,4″-tris(N,N-diphenylamino)triphenylamine (TDATA); 4,4′,4″-tris[N-(2-naphthyl)-N-phenylamino]triphenylamine (2-TNATA); N,N′-di(naphthalen-1-yl)-N,N′-diphenyl-benzidine (NPB(NPD)); β-NPB; N,N′-bis(3-methylphenyl)-N,N′-diphenyl-[1,1′-biphenyl]-4,4′-diamine (TPD); spiro-TPD; spiro-NPB; methylated NPB; 4,4′-cyclohexylidene-bis[N,N-bis(4-methylphenyl)benzenamine](TAPC); 4,4′-bis[N,N′-(3-tolyl)amino]-3,3′-dimethylbiphenyl (HMTPD); 4,4′,4″-tris(N-carbazolyl)triphenylamine (TCTA); polyaniline/dodecylbenzenesulfonic acid (PANI/DBSA); poly(3,4-ethylenedioxythiophene)/poly(4-styrenesulfonate) (PEDOT/PSS); polyaniline/camphor sulfonic acid (PANI/CSA); polyaniline/poly(4-styrenesulfonate) (PANI/PSS); or a (e.g., any suitable) combination thereof:

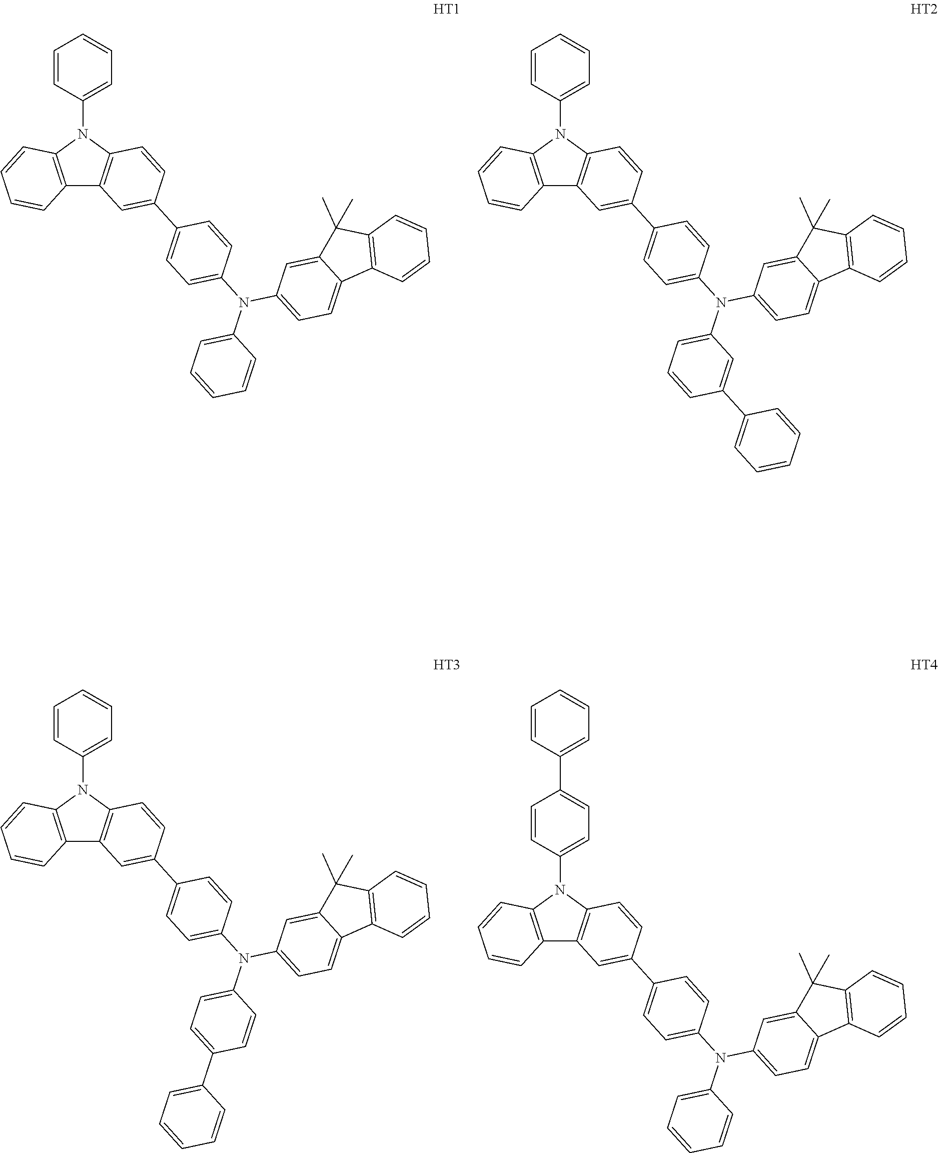 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

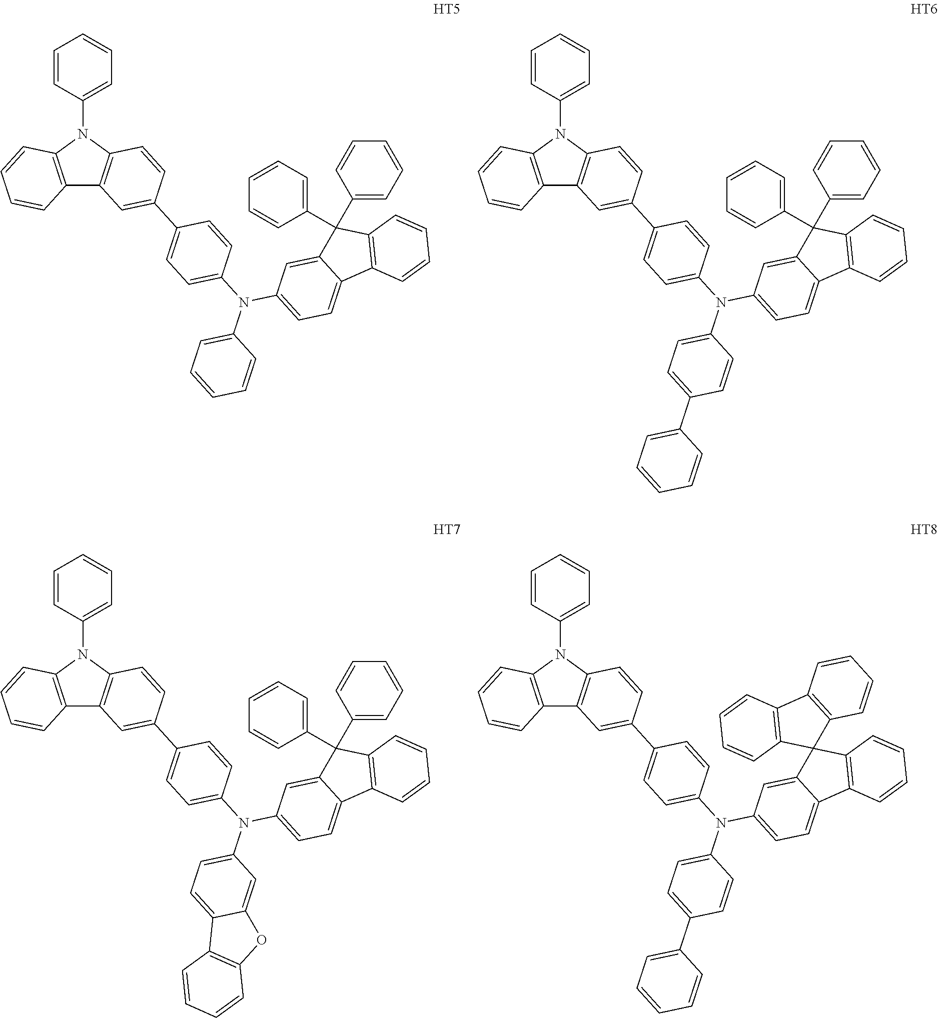 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

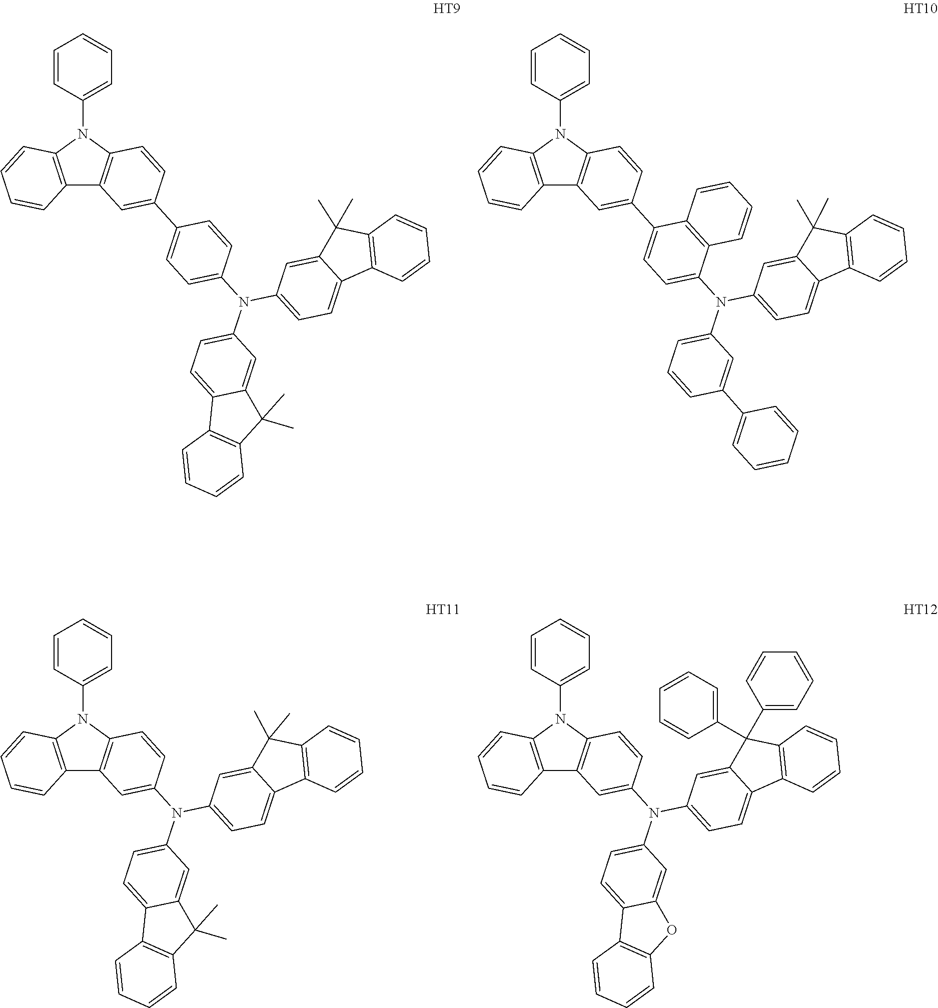 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

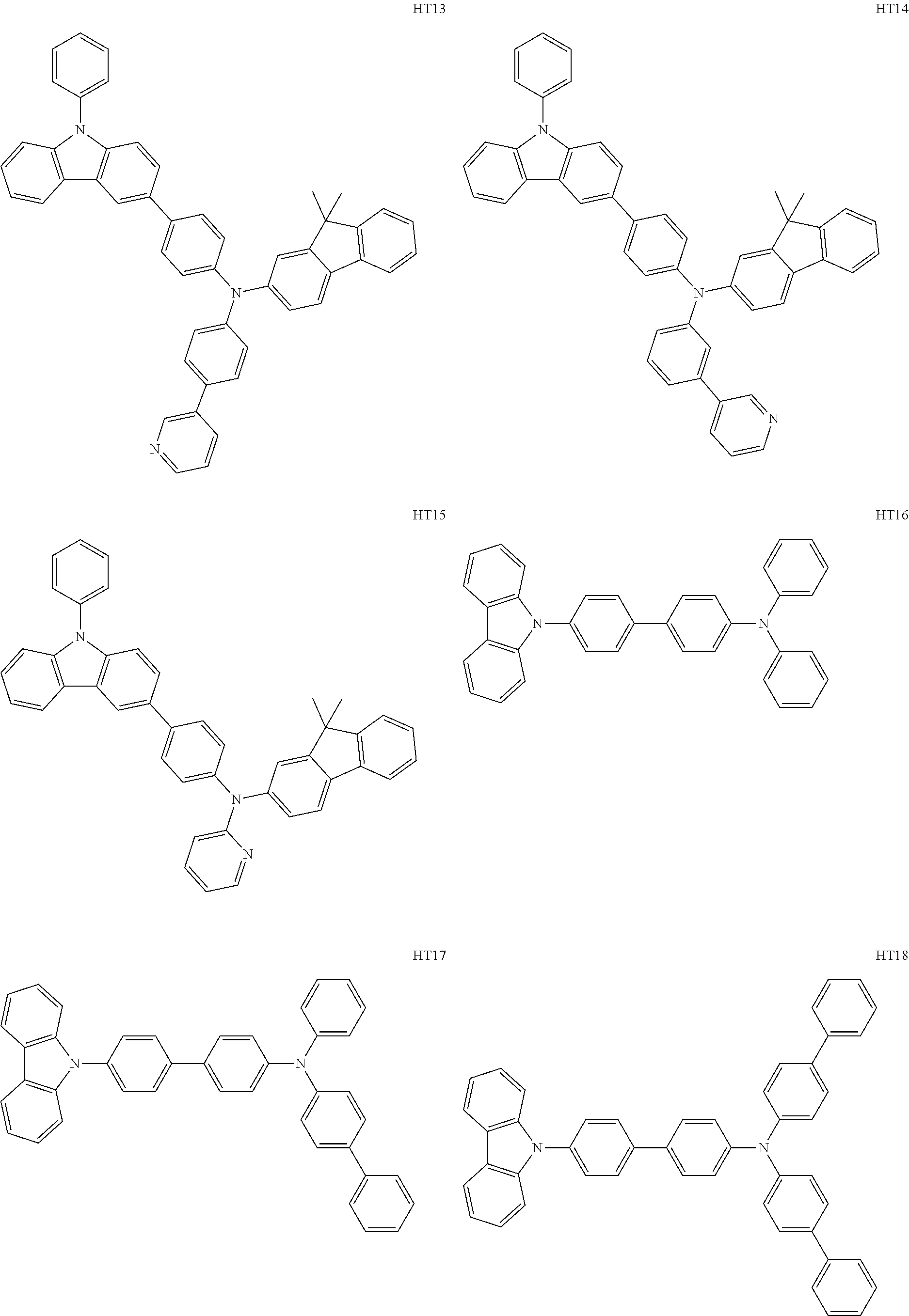 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

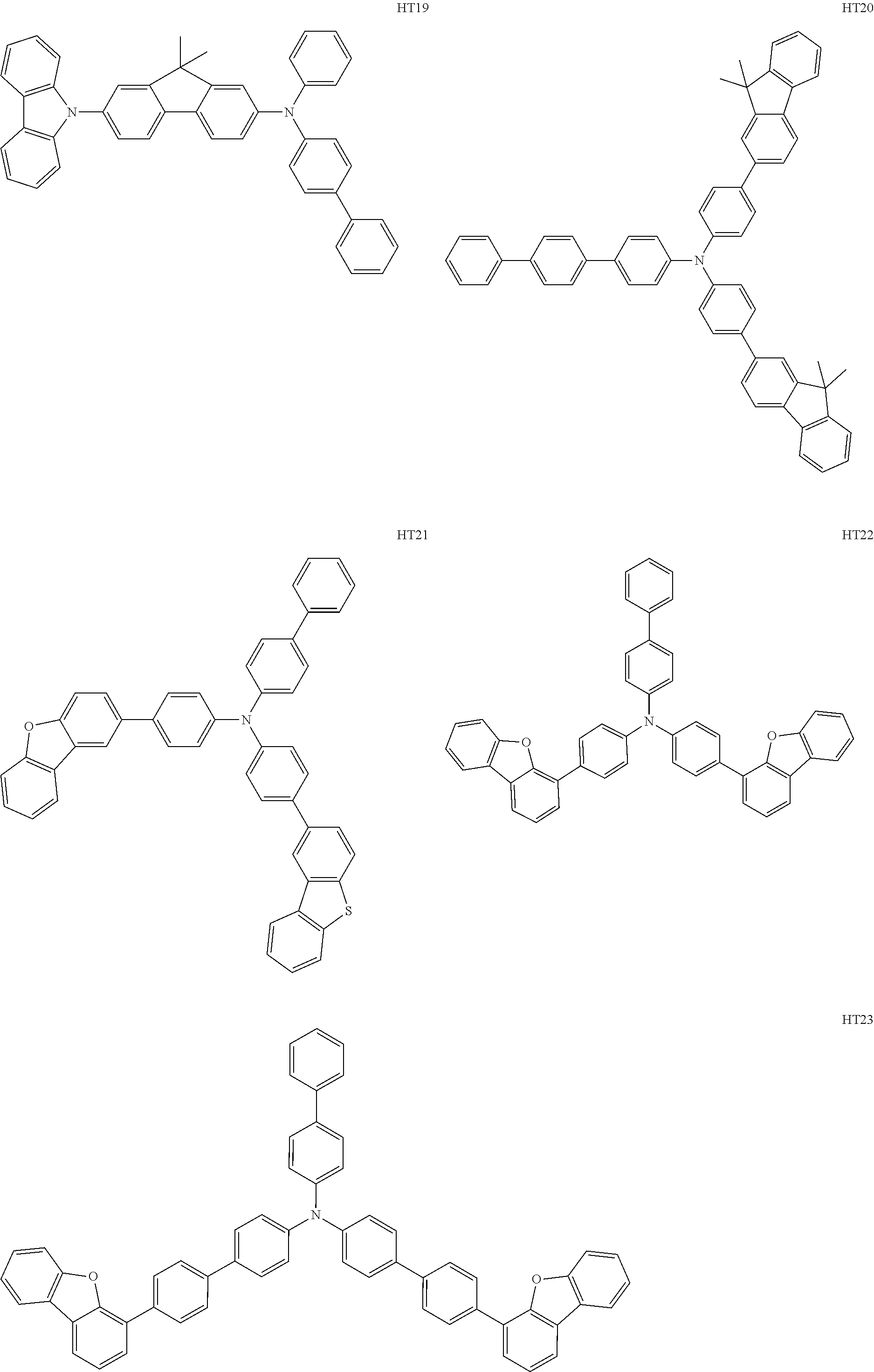 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

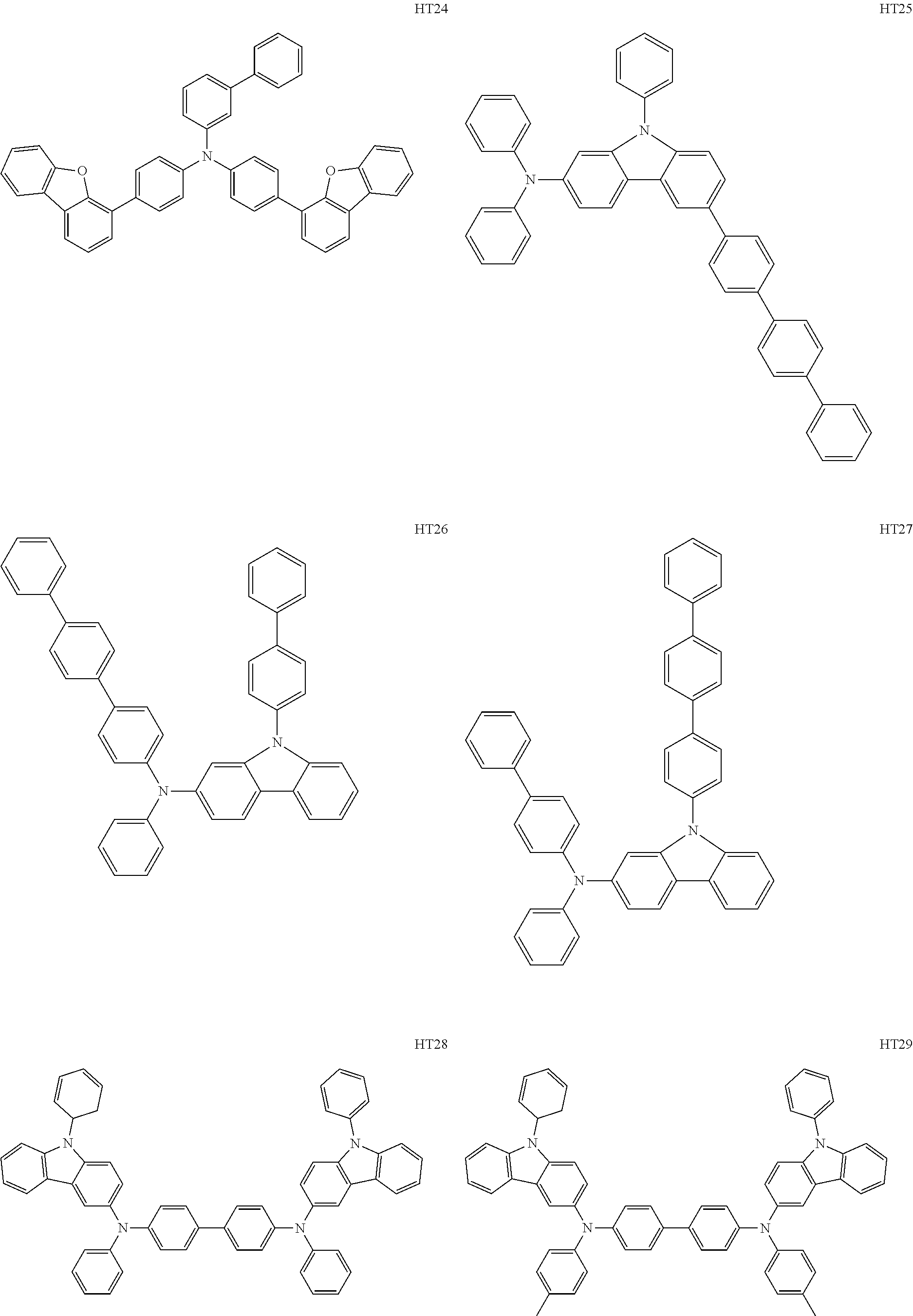

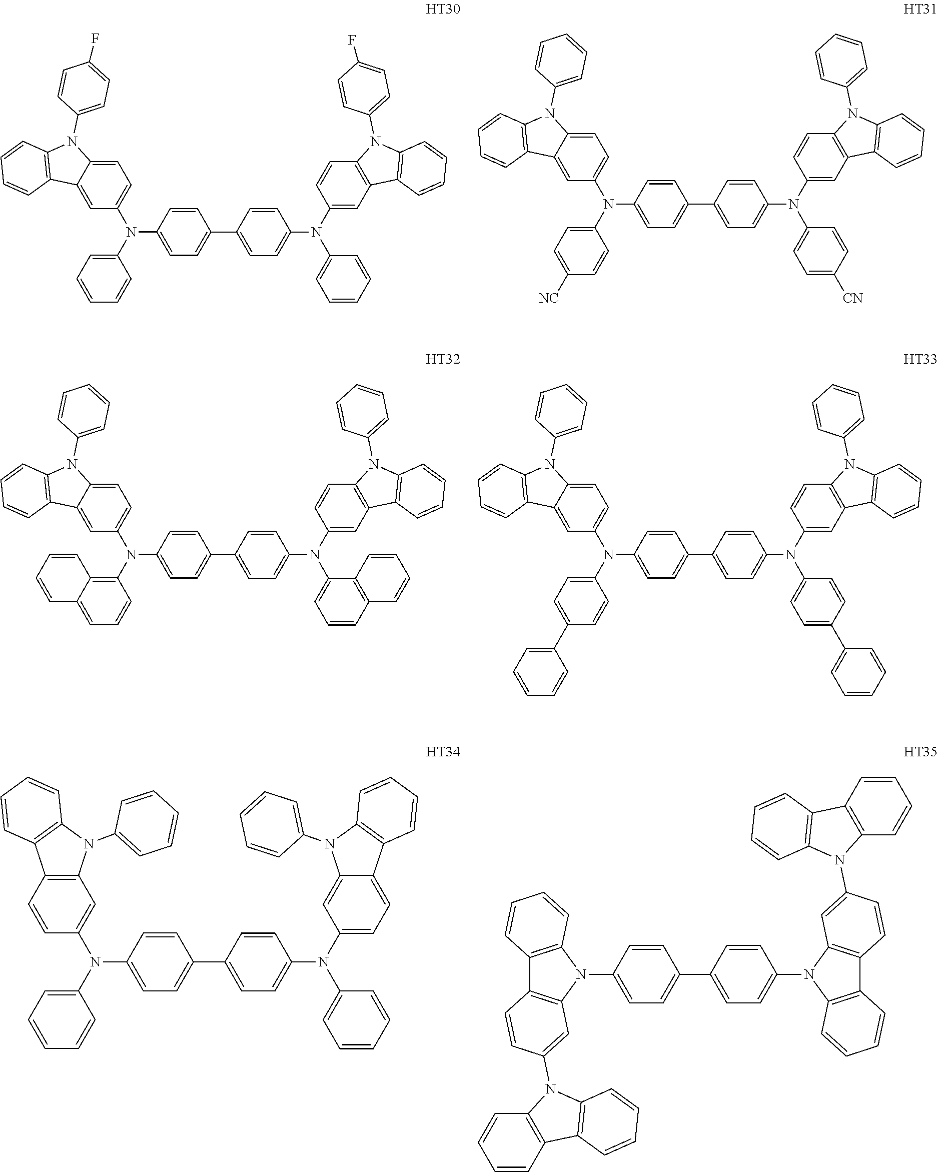

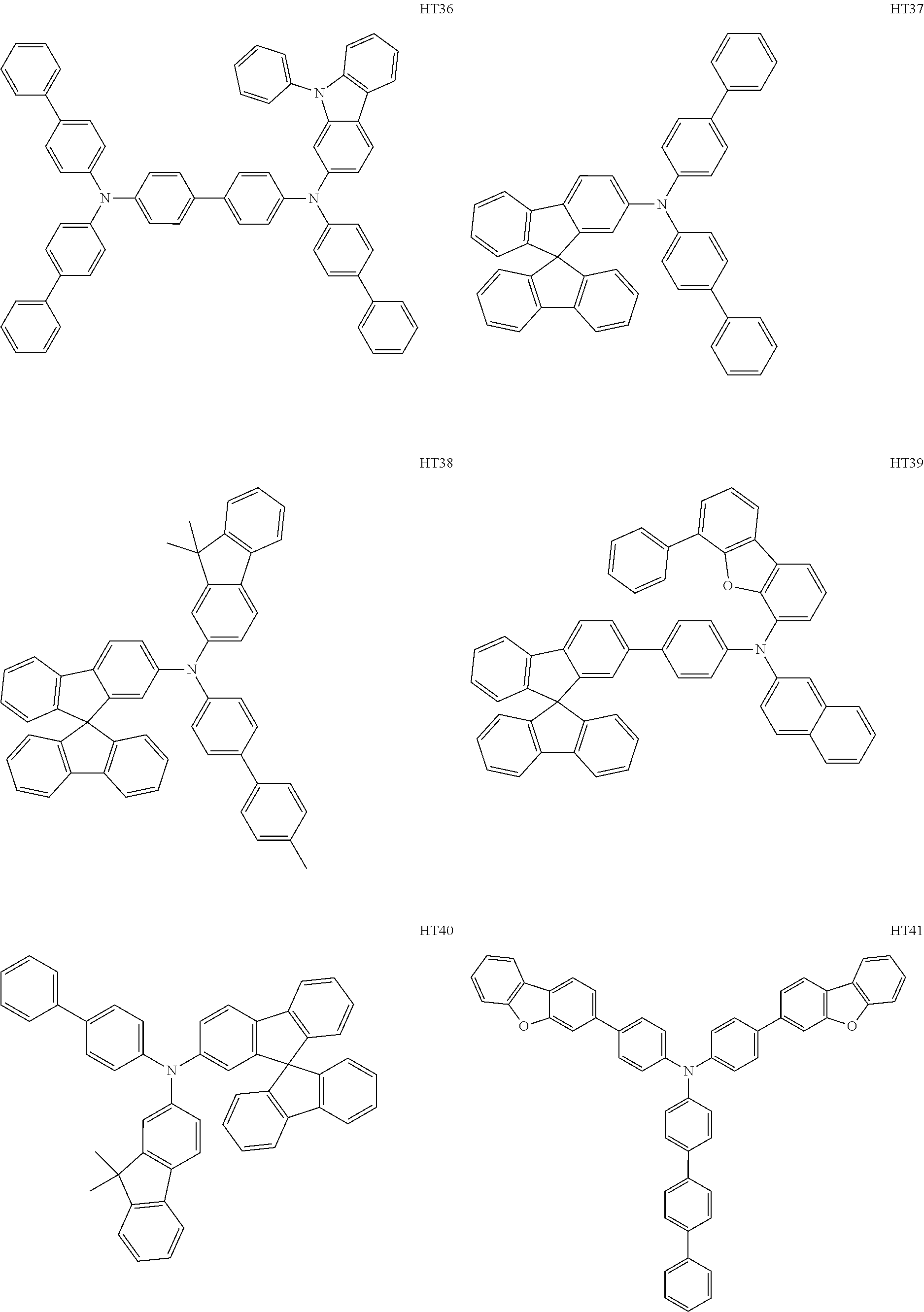

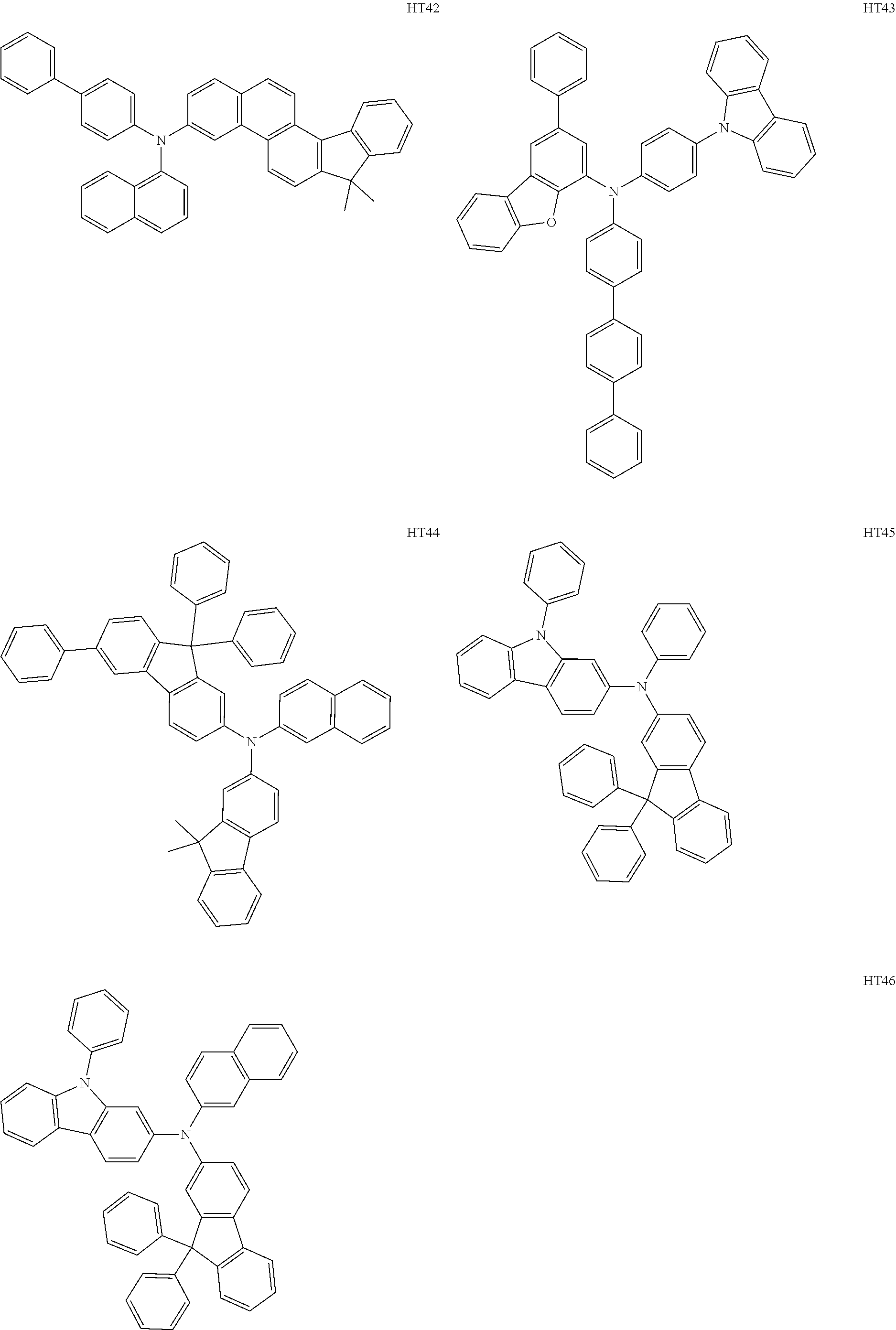 [SMILES: CC1(C)c2ccccc2-c2c1ccc1c2ccc2ccc(N(c3ccc(-c4ccccc4)cc3)c3cccc4ccccc34)cc21 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; c1ccc(-n2c3ccccc3c3ccc(N(c4ccc5c(c4)C(c4ccccc4)(c4ccccc4)c4ccccc4-5)c4ccc5ccccc5c4)cc32)cc1]

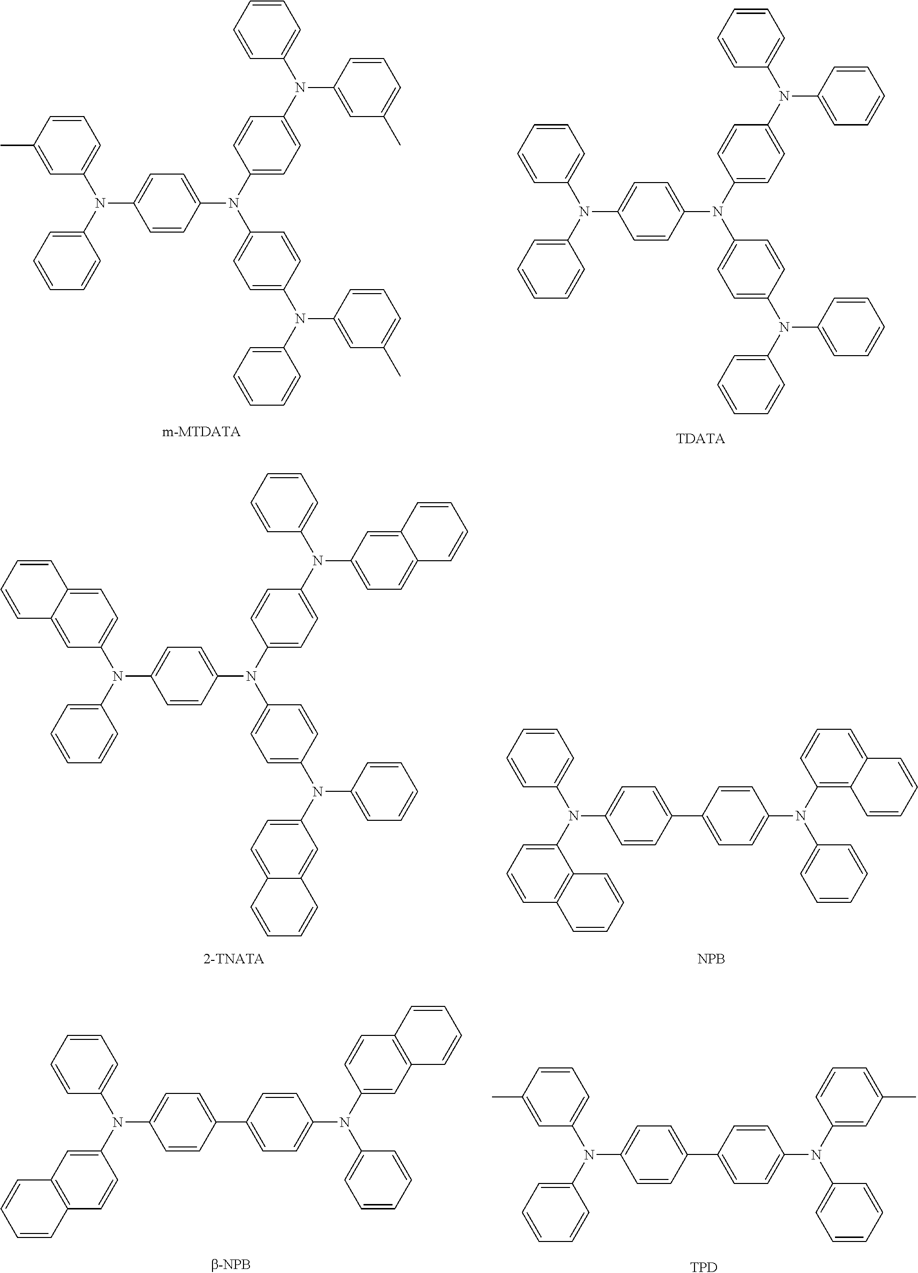

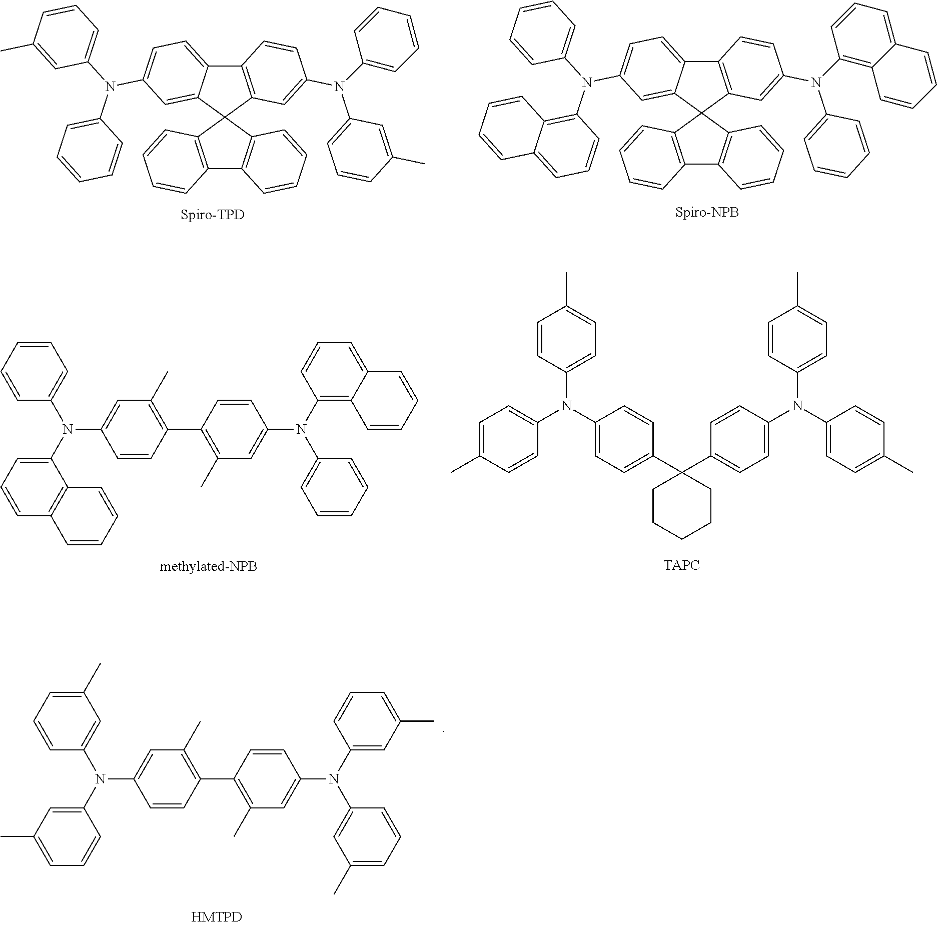

A thickness of the hole transport region may be in a range of about 50 Å to about 10,000 Å, for example, about 100 Å to about 4,000 Å. When the hole transport region includes a hole injection layer, a hole transport layer, or a (e.g., any suitable) combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light emission efficiency by compensating for an optical resonance distance according to the wavelength of light emitted by the emission layer, and the electron blocking layer may block or reduce the leakage of electrons from the emission layer to the hole transport region. Materials that may be included in the hole transport region may be included in the emission auxiliary layer and the electron blocking layer.

p-Dopant

In one or more embodiments, the hole transport region may further include, in addition to one or more of the aforementioned materials, a charge-generation material for the improvement of conductive properties. The charge-generation material may be uniformly (substantially uniformly) or non-uniformly (substantially non-uniformly) dispersed in the hole transport region (for example, in the form of a single layer consisting of the charge-generation material).

The charge-generation material may be, for example, a p-dopant.

For example, in one or more embodiments, the p-dopant may have a lowest unoccupied molecular orbital (LUMO) energy level of −3.5 eV or less.

In one or more embodiments, the p-dopant may include a quinone derivative, a cyano group-containing compound, a compound including element EL1 and element EL2, or a (e.g., any suitable) combination thereof.

Non-limiting examples of the quinone derivative may include tetracyanoquinodimethane (TCNQ), 2,3,5,6-tetrafluoro-7,7,8,8-tetracyanoquinodimethane (F4-TCNQ), and/or the like.

Non-limiting examples of the cyano group-containing compound may include dipyrazino[2,3-f:2′,3′-h]quinoxaline-2,3,6,7,10,11-hexacarbonitrile (HAT-CN), a compound represented by Formula 221, and/or the like:

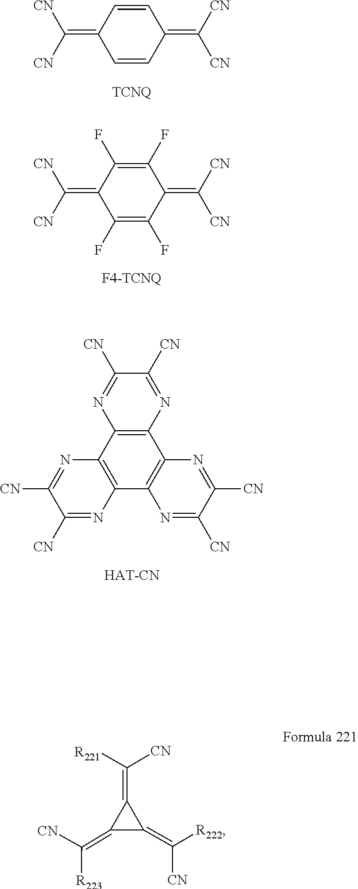

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or a (e.g., any suitable) combination thereof; or a (e.g., any suitable) combination thereof.

In the compound including element EL1 and element EL2, element EL1 may be a metal, a metalloid, or a (e.g., any suitable) combination thereof, and element EL2 may be a non-metal, a metalloid, or a (e.g., any suitable) combination thereof.

Non-limiting examples of the metal may include: alkali metals (e.g., lithium (Li), sodium (Na), potassium (K), rubidium (Rb), cesium (Cs), and/or the like); alkaline earth metals (e.g., beryllium (Be), magnesium (Mg), calcium (Ca), strontium (Sr), barium (Ba), and/or the like); transition metals (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); post-transition metal (e.g., zinc (Zn), indium (In), tin (Sn), and/or the like); lanthanide metals (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and/or the like.

Non-limiting examples of the metalloid may include silicon (Si), antimony (Sb), tellurium (Te), and/or the like.

Non-limiting examples of the non-metal may include oxygen (O), a halogen (for example, F, Cl, Br, I, and/or the like), and/or the like.

For example, the compound including element EL1 and element EL2 may include metal oxides, metal halides (e.g., metal fluorides, metal chlorides, metal bromides, metal iodides, and/or the like), metalloid halides (e.g., metalloid fluorides, metalloid chlorides, metalloid bromides, metalloid iodides, and/or the like), metal tellurides, or a (e.g., any suitable) combination thereof.

Non-limiting examples of the metal oxide may include tungsten oxides (e.g., WO, W₂O₃, WO₂, WO₃, W₂O₅, and/or the like), vanadium oxides (e.g., VO, V₂O₃, VO₂, V₂O₅, and/or the like), molybdenum oxides (e.g., MoO, Mo₂O₃, MoO₂, MoO₃, Mo₂O₅, and/or the like), rhenium oxides (e.g., ReO₃, and/or the like), and/or the like.

Non-limiting examples of the metal halide may include alkali metal halides, alkaline earth metal halides, transition metal halides, post-transition metal halides, lanthanide metal halides, and/or the like.

Non-limiting examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and/or the like.

Non-limiting examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and/or the like.

Non-limiting examples of the transition metal halide may include titanium halides (e.g., TiF₄, TiCl₄, TiBr₄, TiI₄, and/or the like), zirconium halides (e.g., ZrF₄, ZrCl₄, ZrBr₄, ZrI₄, and/or the like), hafnium halides (e.g., HfF₄, HfCl₄, HfBr₄, HfI₄, and/or the like), vanadium halides (e.g., VF₃, VCl₃, VBr₃, VI₃, and/or the like), niobium halides (e.g., NbF₃, NbCl₃, NbBr₃, NbI₃, and/or the like), tantalum halides (e.g., TaF₃, TaCl₃, TaBr₃, TaI₃, and/or the like), chromium halides (e.g., CrF₃, CrCl₃, CrBr₃, CrI₃, and/or the like), molybdenum halides (e.g., MoF₃, MoCl₃, MoBr₃, MoI₃, and/or the like), tungsten halides (e.g., WF₃, WCl₃, WBr₃, WI₃, and/or the like), manganese halides (e.g., MnF₂, MnCl₂, MnBr₂, MnI₂, and/or the like), technetium halides (e.g., TcF₂, TcCl₂, TcBr₂, TcI₂, and/or the like), rhenium halides (e.g., ReF₂, ReCl₂, ReBr₂, ReI₂, and/or the like), ferrous halides (e.g., FeF₂, FeCl₂, FeBr₂, FeI₂, and/or the like), ruthenium halides (e.g., RuF₂, RuCl₂, RuBr₂, RuI₂, and/or the like), osmium halides (e.g., OsF₂, OsCl₂, OsBr₂, OsI₂, and/or the like), cobalt halides (e.g., CoF₂, COCl₂, CoBr₂, CoI₂, and/or the like), rhodium halides (e.g., RhF₂, RhCl₂, RhBr₂, RhI₂, and/or the like), iridium halides (e.g., IrF₂, IrCl₂, IrBr₂, IrI₂, and/or the like), nickel halides (e.g., NiF₂, NiCl₂, NiBr₂, NiI₂, and/or the like), palladium halides (e.g., PdF₂, PdCl₂, PdBr₂, PdI₂, and/or the like), platinum halides (e.g., PtF₂, PtCl₂, PtBr₂, PtI₂, and/or the like), cuprous halides (e.g., CuF, CuCl, CuBr, CuI, and/or the like), silver halides (e.g., AgF, AgCl, AgBr, AgI, and/or the like), gold halides (e.g., AuF, AuCl, AuBr, AuI, and/or the like), and/or the like.

Non-limiting examples of the post-transition metal halide may include zinc halides (e.g., ZnF₂, ZnCl₂, ZnBr₂, ZnI₂, and/or the like), indium halides (e.g., InI₃, and/or the like), tin halides (e.g., SnI₂, and/or the like), and/or the like.

Non-limiting examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Non-limiting examples of the metalloid halide may include antimony halides (e.g., SbCl₅, and/or the like) and/or the like.

Non-limiting examples of the metal telluride may include alkali metal tellurides (e.g., Li₂Te, Na₂Te, K₂Te, Rb₂Te, Cs₂Te, and/or the like), alkaline earth metal tellurides (e.g., BeTe, MgTe, CaTe, SrTe, BaTe, and/or the like), transition metal tellurides (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), post-transition metal tellurides (e.g., ZnTe, and/or the like), lanthanide metal tellurides (e.g., LaTe, CeTe, PrTe, NdTe, PmTe, EuTe, GdTe, TbTe, DyTe, HoTe, ErTe, TmTe, YbTe, LuTe, and/or the like), and/or the like.

### Emission Layer in Interlayer 130

When the light-emitting device 10 is a full-color light-emitting device, the emission layer may be patterned into a red emission layer, a green emission layer, and/or a blue emission layer, according to a sub-pixel. In one or more embodiments, the emission layer may have a stacked structure of two or more layers selected from among a red emission layer, a green emission layer, and a blue emission layer, in which the two or more layers contact each other or are separated from each other, to emit white light (e.g., combined white light). In one or more embodiments, the emission layer may include two or more materials selected from among a red light-emitting material, a green light-emitting material, and a blue light-emitting material, in which the two or more materials are mixed with each other in a single layer, to emit white light (e.g., combined white light).

In one or more embodiments, the emission layer may include a host and a dopant (or an emitter). In some embodiments, the emission layer may further include an auxiliary dopant that promotes energy transfer to the dopant (or the emitter), in addition to the host and the dopant (or an emitter). When the emission layer includes the dopant (or an emitter) and the auxiliary dopant, the dopant (or an emitter) and the auxiliary dopant are different from each other.

The organometallic compound represented by Formula 1 in the present disclosure may serve as the dopant (or an emitter), or may serve as the auxiliary dopant.

An amount (weight) of the dopant (or an emitter) in the emission layer may be in a range of about 0.01 parts by weight to about 15 parts by weight based on 100 parts by weight of the host.

In one or more embodiments, the emission layer may include the organometallic compound represented by Formula 1. An amount of the organometallic compound in the emission layer may be, based on 100 parts by weight of the emission layer, in a range of about 0.01 parts by weight to about 30 parts by weight, about 0.1 parts by weight to about 20 parts by weight, or about 0.1 parts by weight to about 15 parts by weight.

A thickness of the emission layer may be in a range of about 100 Å to about 1,000 Å, for example, about 200 Å to about 600 Å. When the thickness of the emission layer is within these ranges, excellent or suitable luminescence characteristics may be obtained without a substantial increase in driving voltage.

### Host

In one or more embodiments, the host in the emission layer may include the second compound, the third compound, or a (e.g., any suitable) combination thereof.

In one or more embodiments, the host may include a compound represented by Formula 301:

[Ar₃₀₁]_{xb11}-[(L₃₀₁)_{xb1}-R₃₀₁]_{xb21}, Formula 301
wherein, in Formula 301,
Ar₃₀₁ and L₃₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described with respect to Q₁.

For example, in some embodiments, when xb11 in Formula 301 is 2 or more, two or more of Ar₃₀₁(s) may be linked to each other via a single bond.

In one or more embodiments, the host may include a compound represented by Formula 301-1, a compound represented by Formula 301-2, or a (e.g., any suitable) combination thereof:

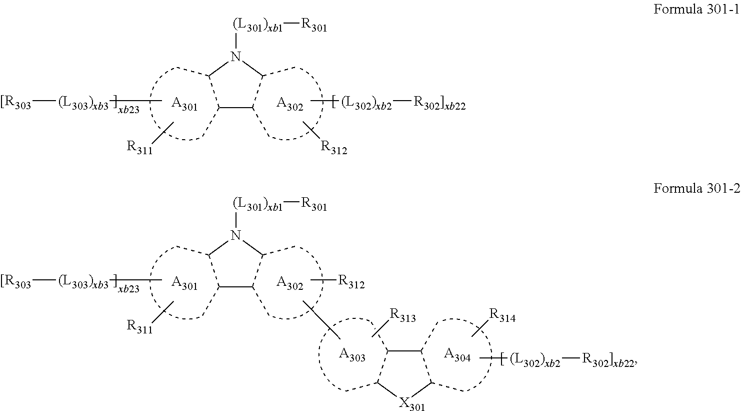

wherein, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described herein,
L₃₀₂ to L₃₀₄ may each independently be the same as described with respect to L₃₀₁,
xb2 to xb4 may each independently be the same as described with respect to xb1, and
R₃₀₂ to R₃₀₅ and R₃₁₁ to R₃₁₄ may each independently be the same as described herein with respect to R₃₀₁.

In one or more embodiments, the host may include an alkaline earth metal complex, a post-transition metal complex, or a (e.g., any suitable) combination thereof. In one or more embodiments, the hosts may each independently include a Be complex (e.g., Compound H55), an Mg complex, a Zn complex, or a (e.g., any suitable) combination thereof.

In one or more embodiments, the host may include at least one selected from among Compounds H1 to H130, 9,10-di(2-naphthyl)anthracene (ADN), 2-methyl-9,10-bis(naphthalen-2-yl)anthracene (MADN), 9,10-di(2-naphthyl)-2-t-butyl-anthracene (TBADN), 4,4′-bis(N-carbazolyl)-1,1′-biphenyl (CBP), 1,3-di(9H-carbazol-9-yl)benzene (mCP), 1,3,5-tri(carbazol-9-yl)benzene (TCP), or a (e.g., any suitable) combination thereof:

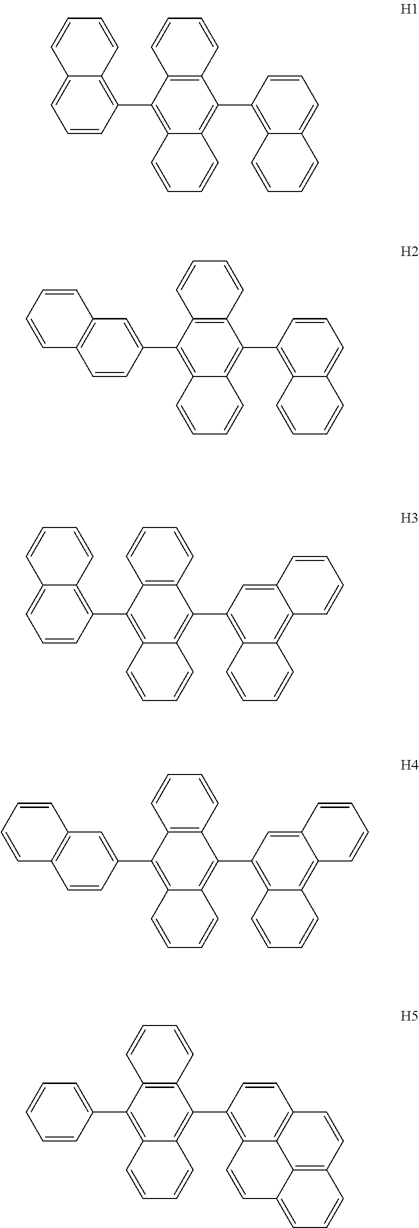

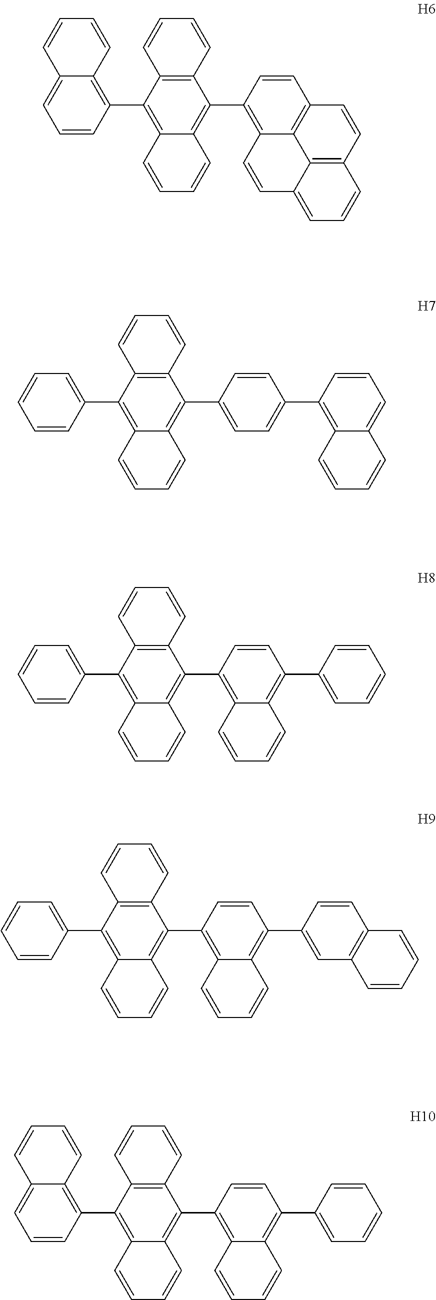

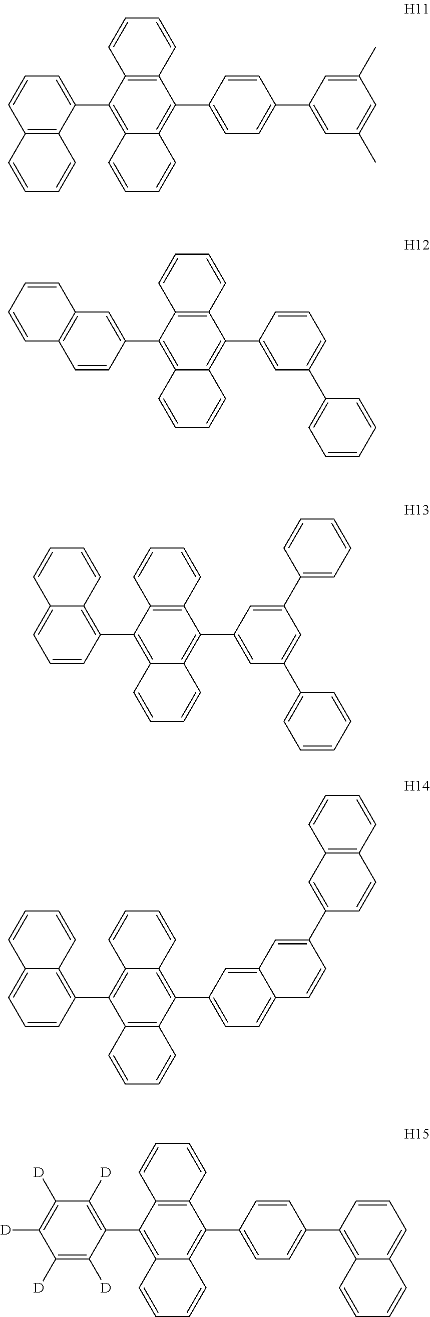

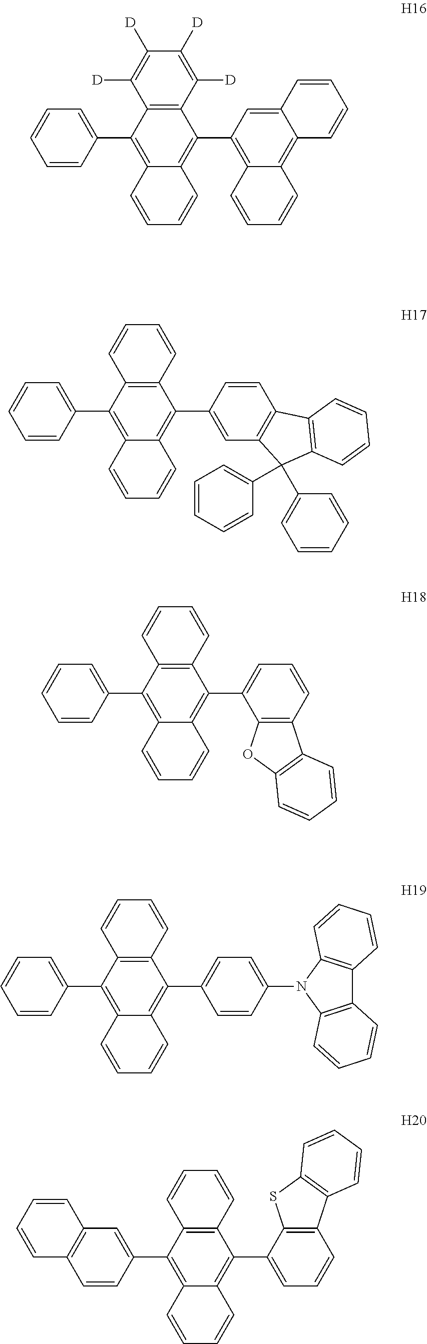

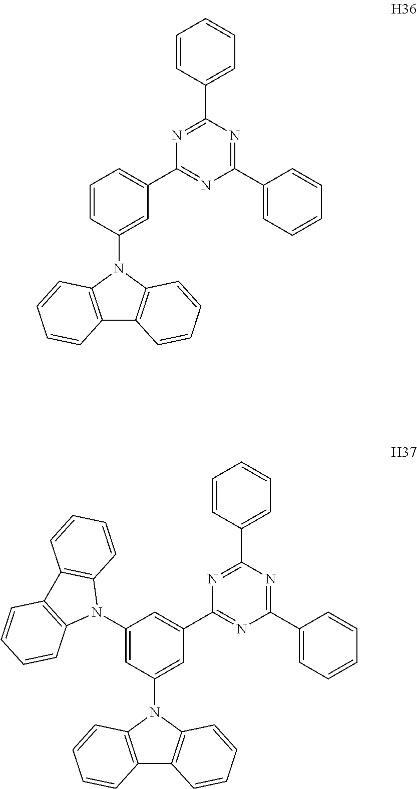 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

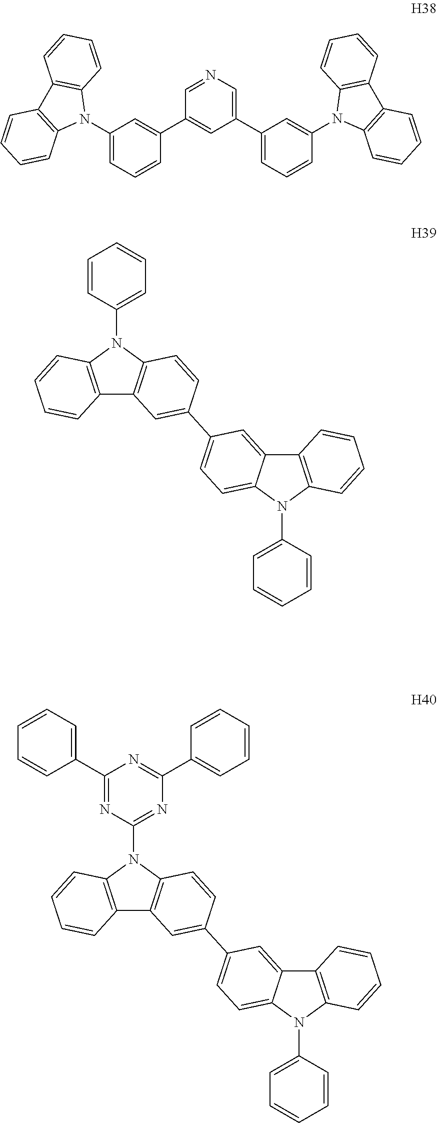 [SMILES: c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

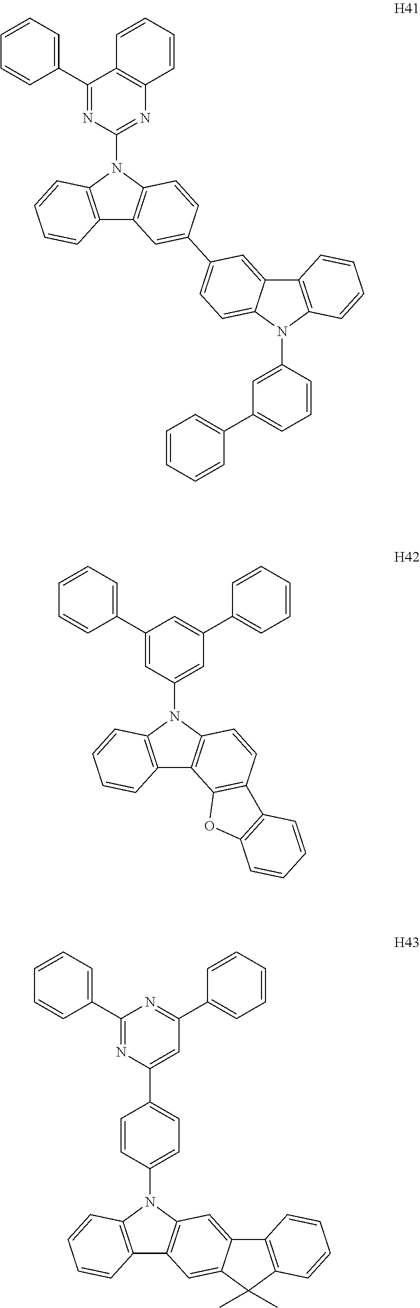 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

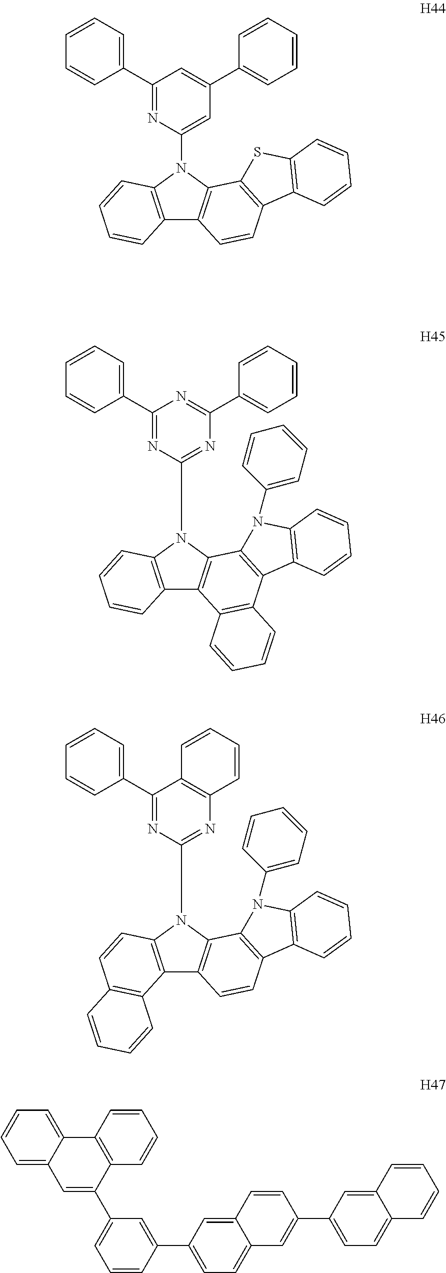

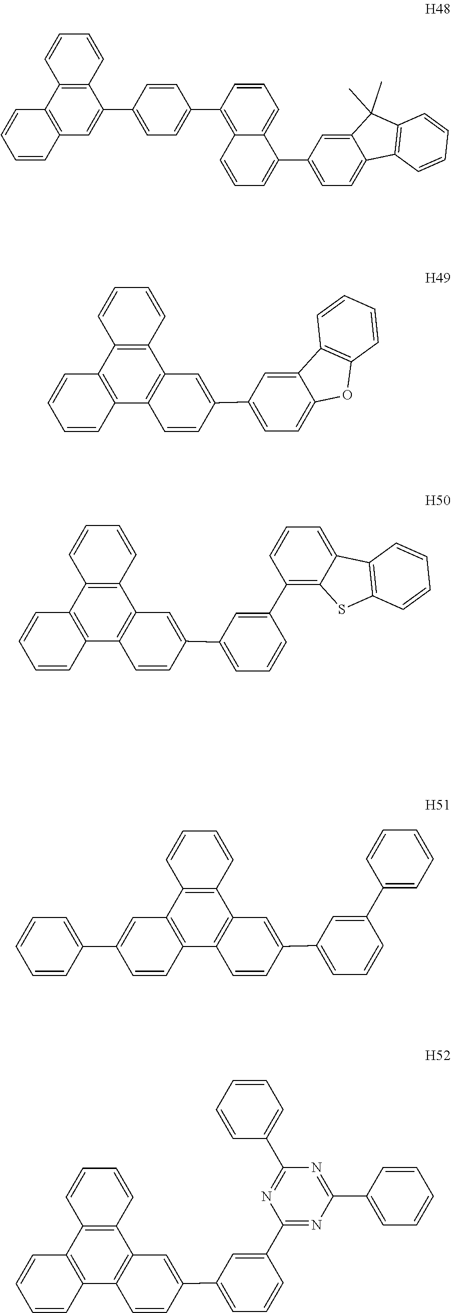

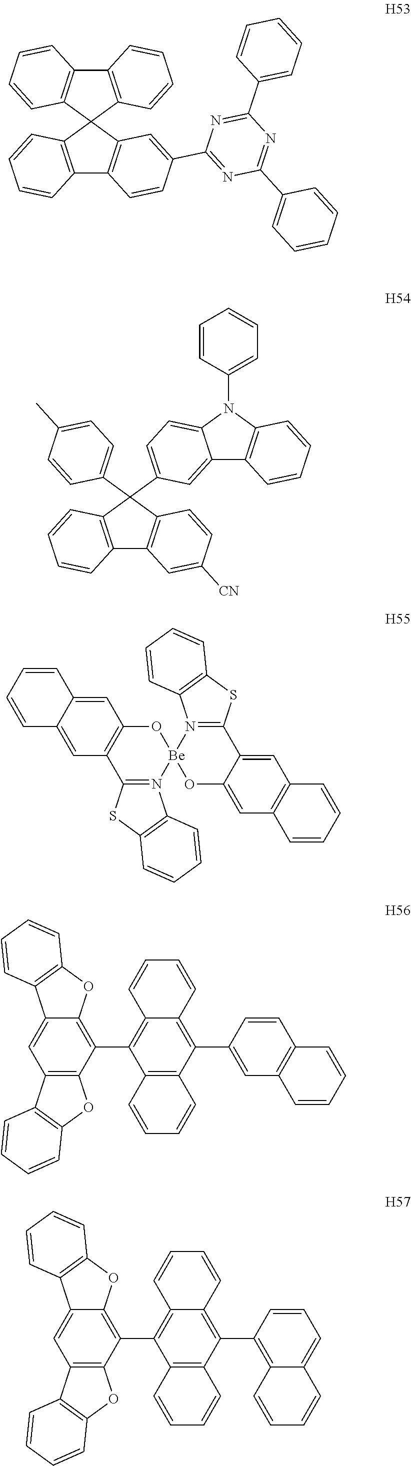

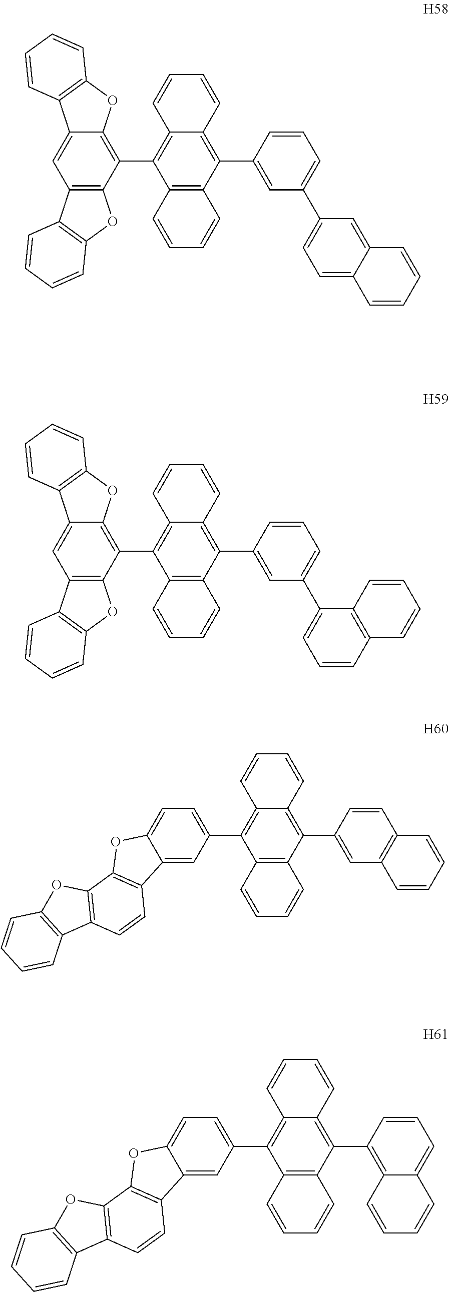 [SMILES: c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1]

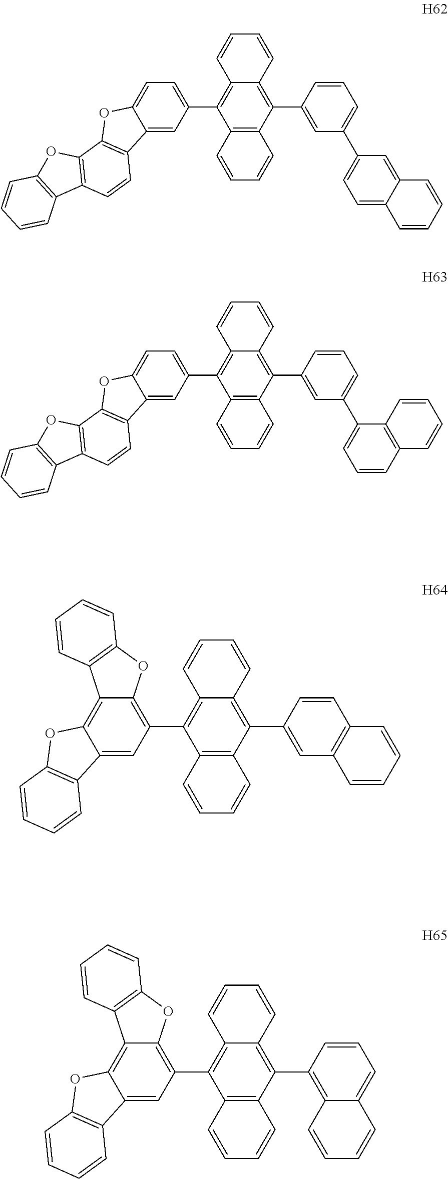 [SMILES: c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1 ; c1ccc2c(-c3c4ccccc4c(-c4cc5c6ccccc6oc5c5c4oc4ccccc45)c4ccccc34)cccc2c1]

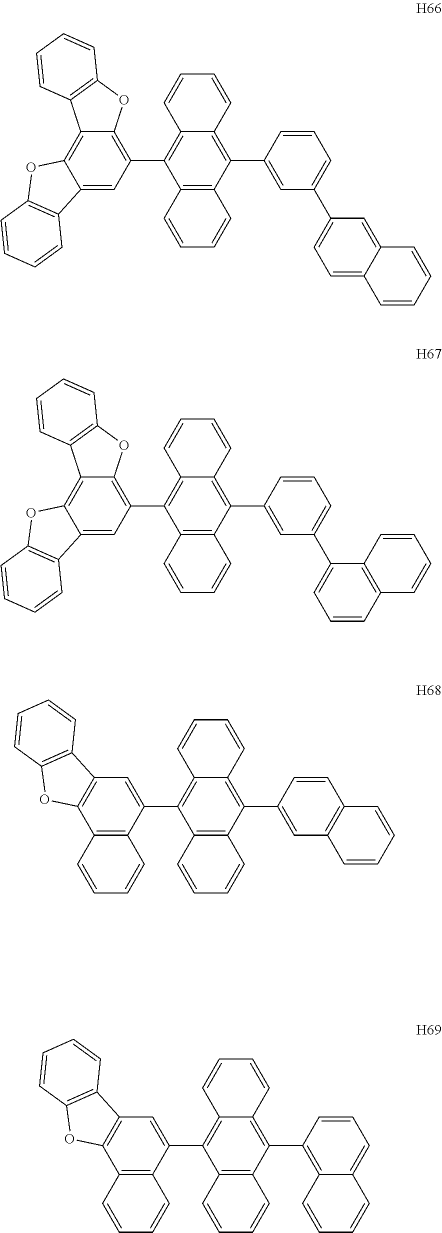 [SMILES: c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1]

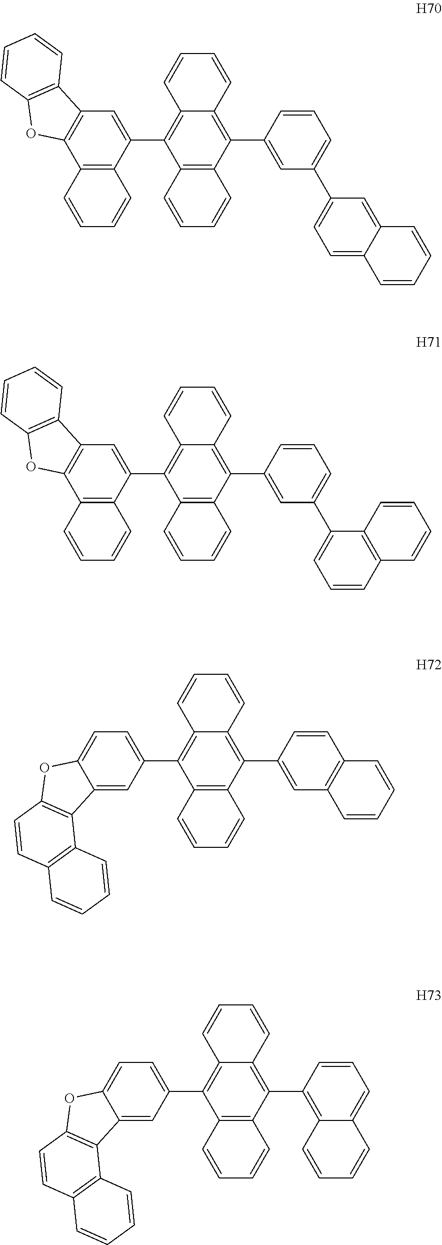 [SMILES: c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1]

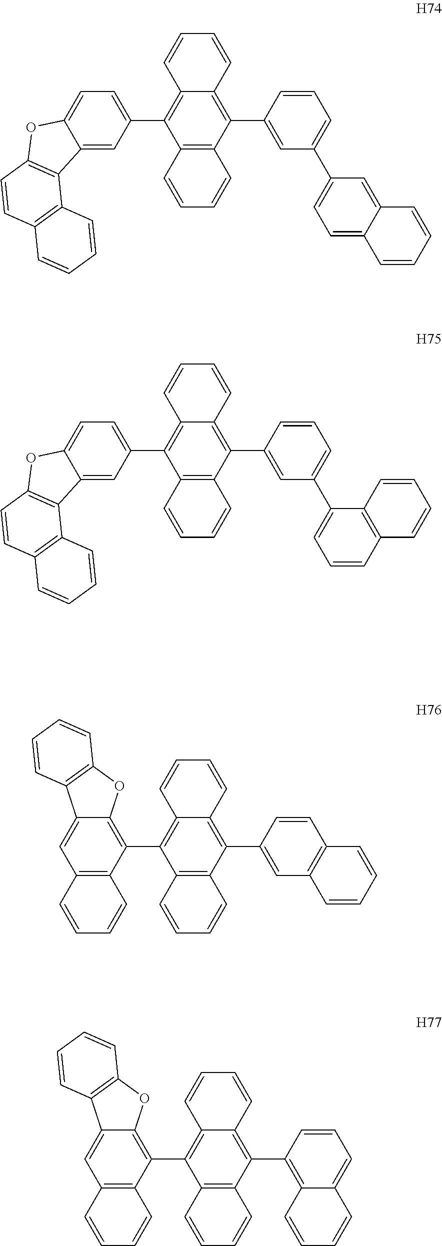 [SMILES: c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1]

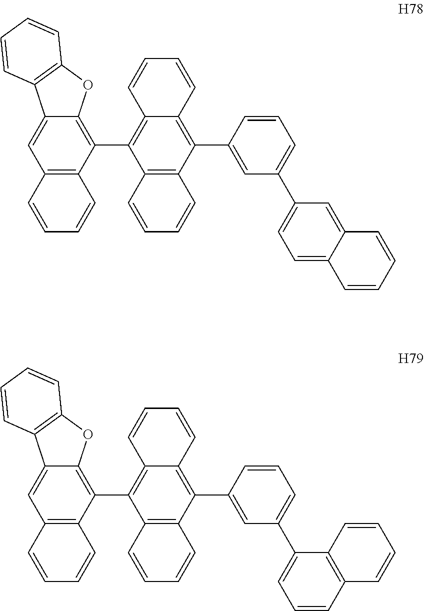 [SMILES: c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1]

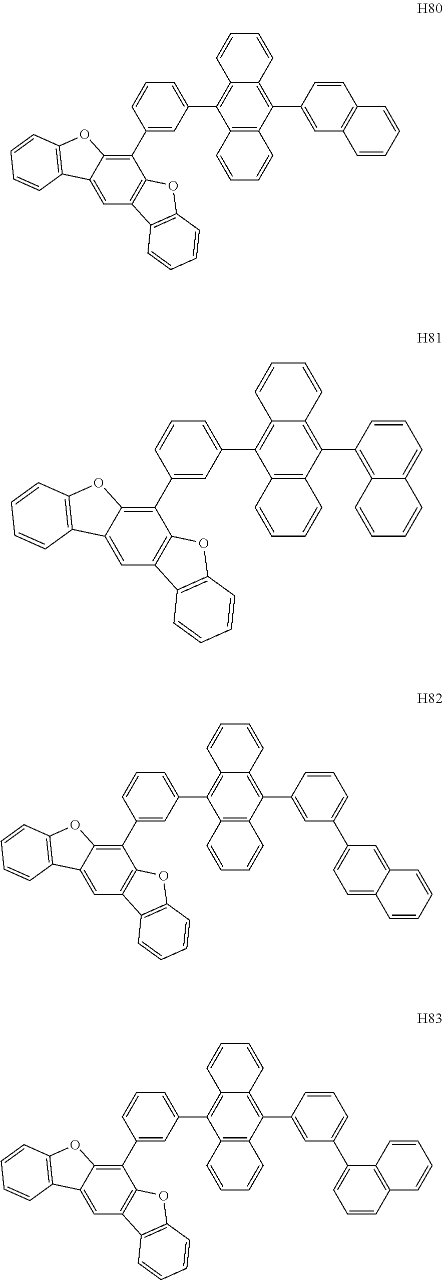 [SMILES: c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1]

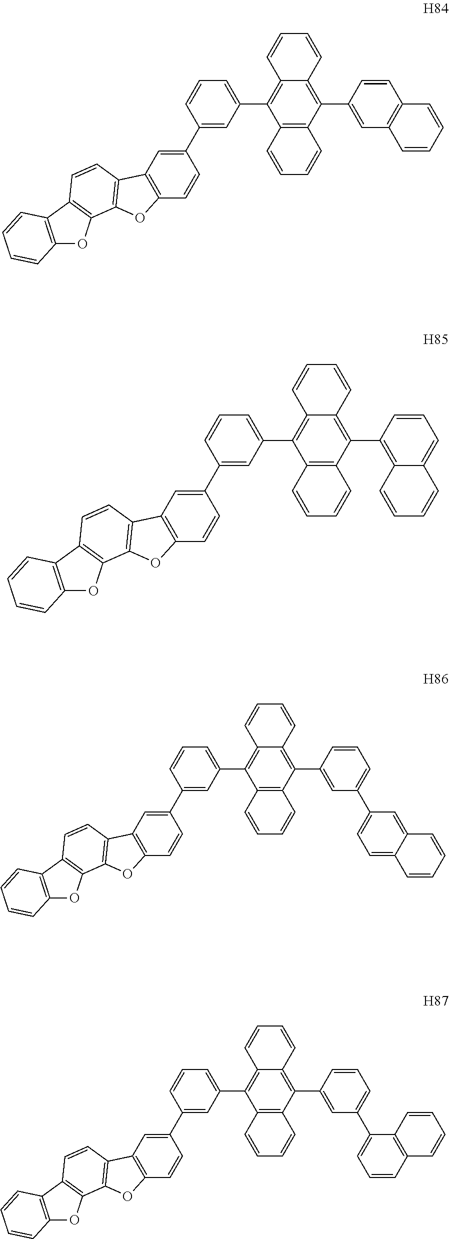 [SMILES: c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1]

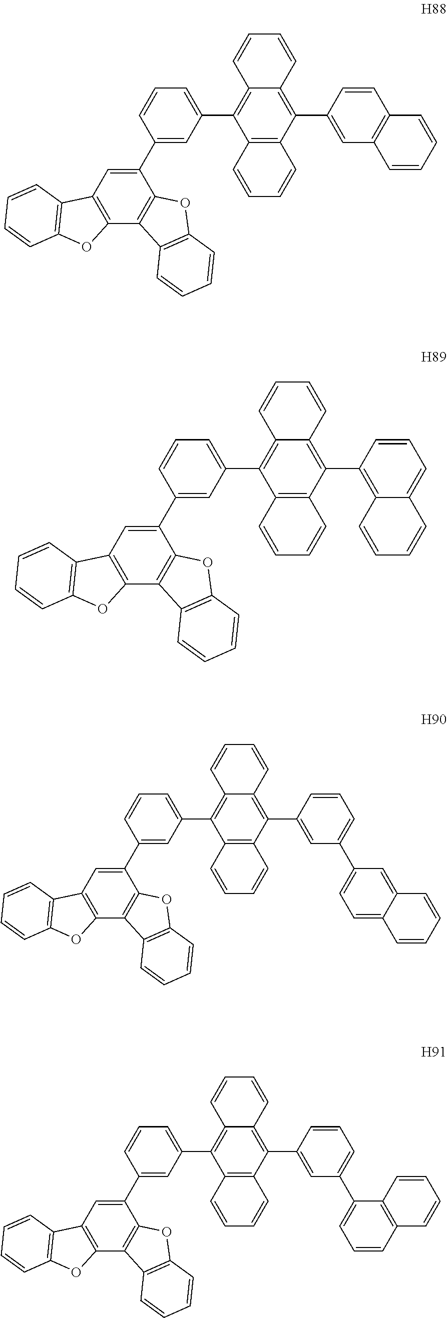 [SMILES: c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1]

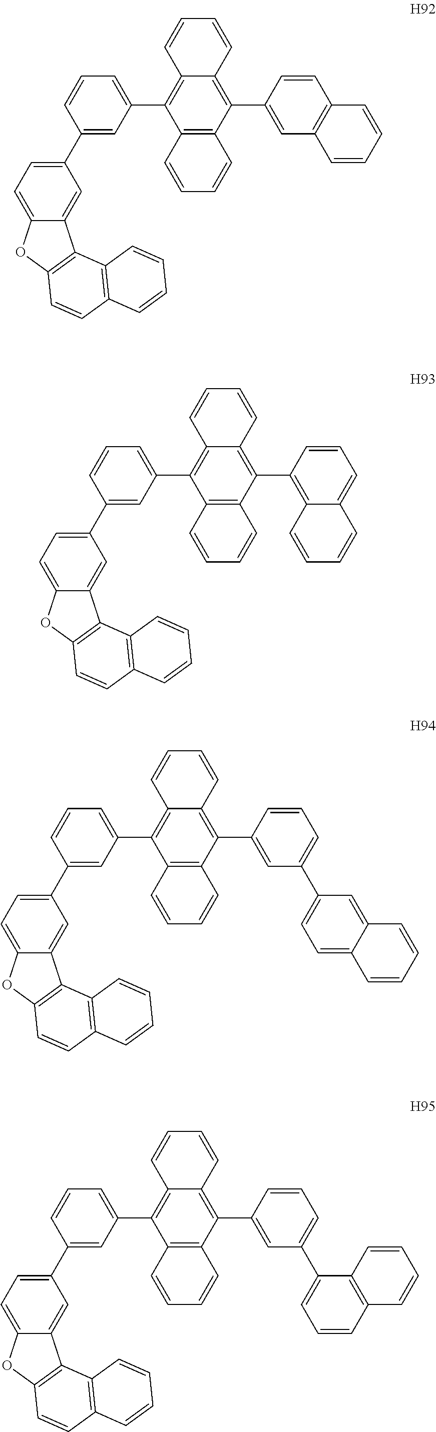 [SMILES: c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1]

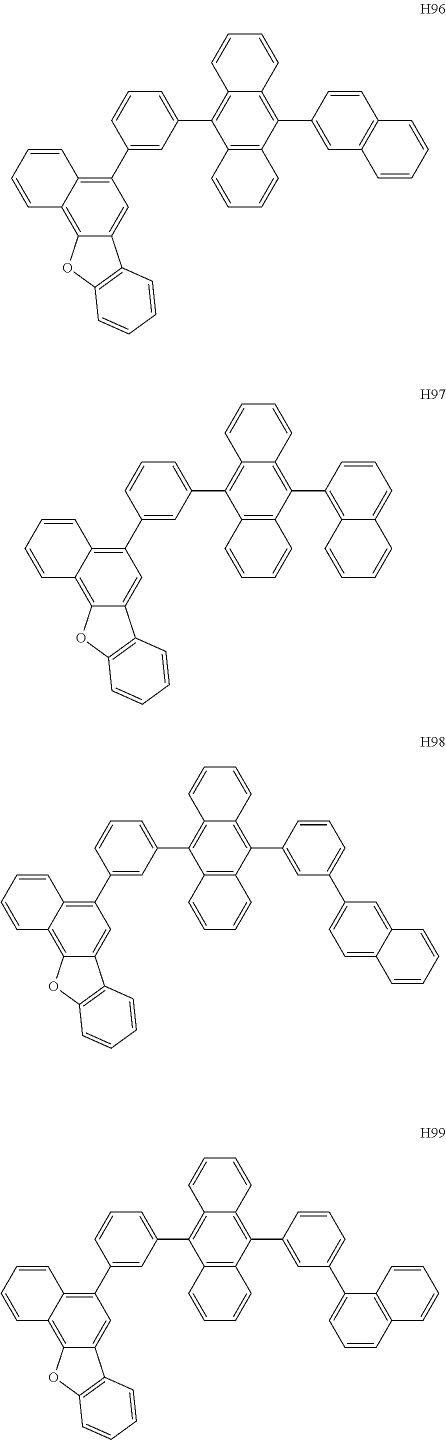 [SMILES: c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

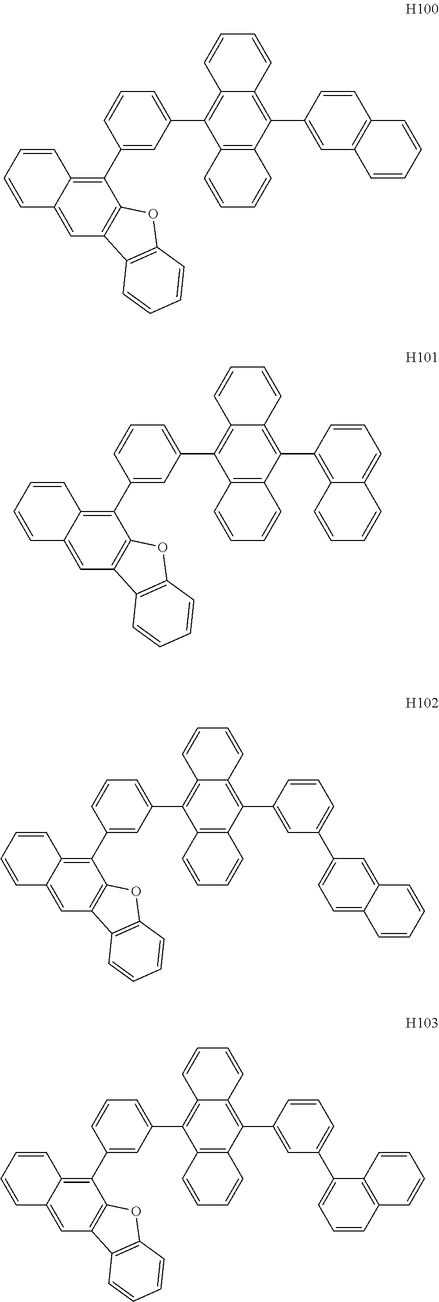 [SMILES: c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

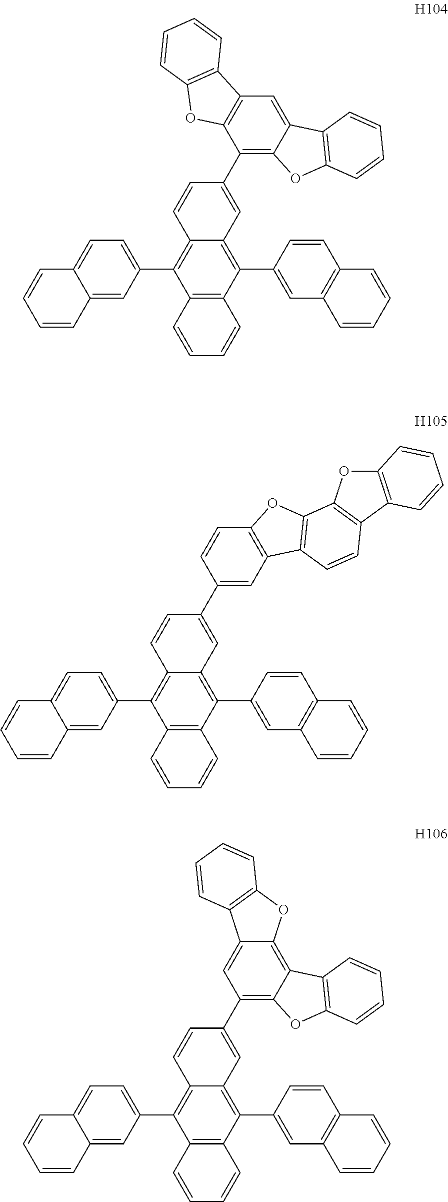 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

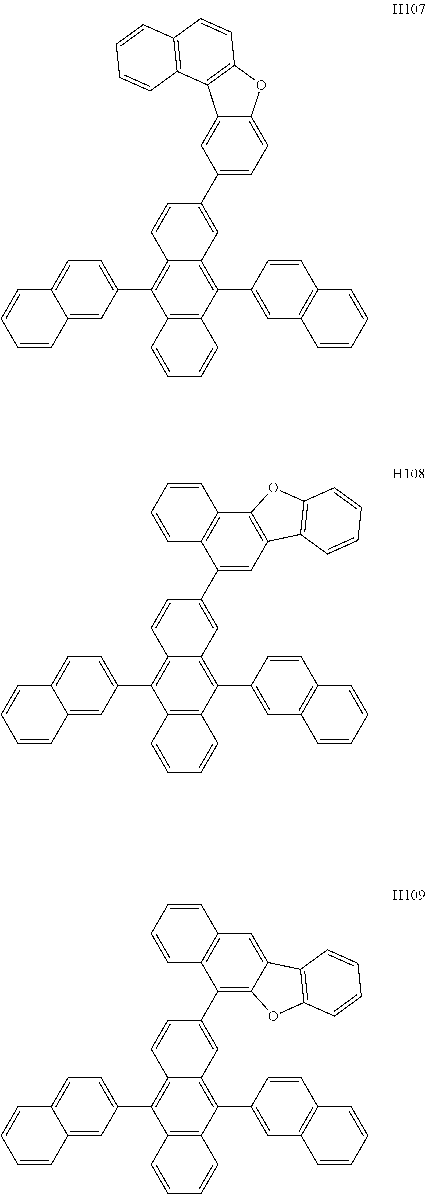 [SMILES: c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1]

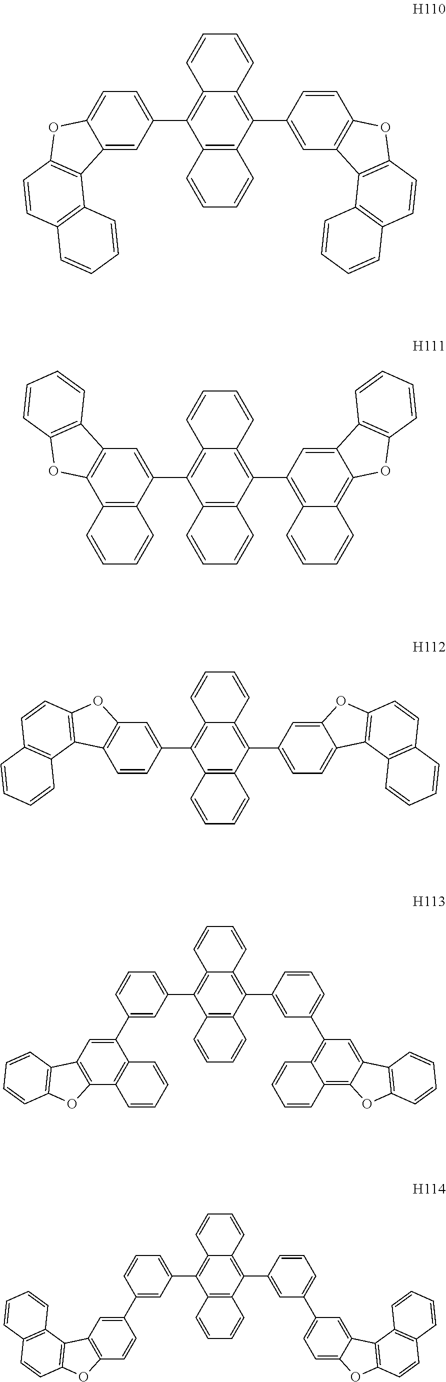 [SMILES: c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21 ; c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1]

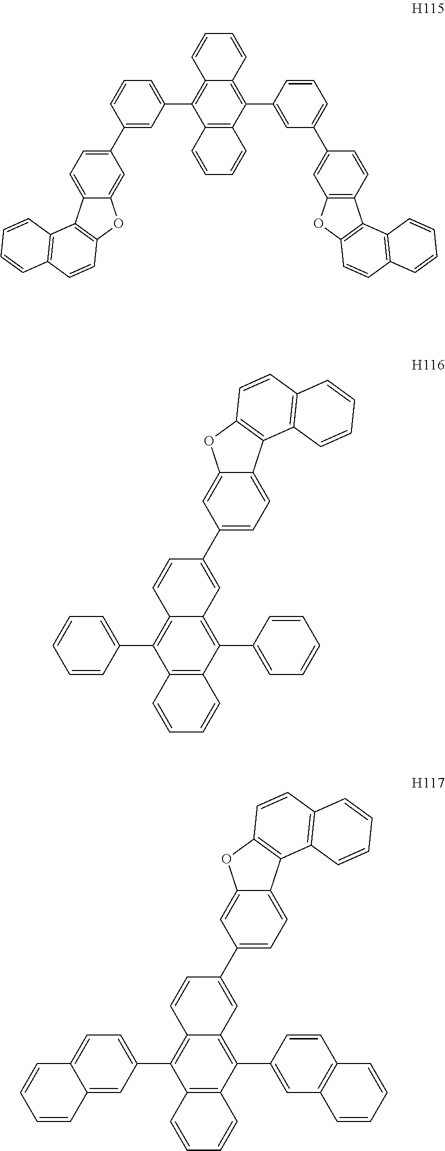 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

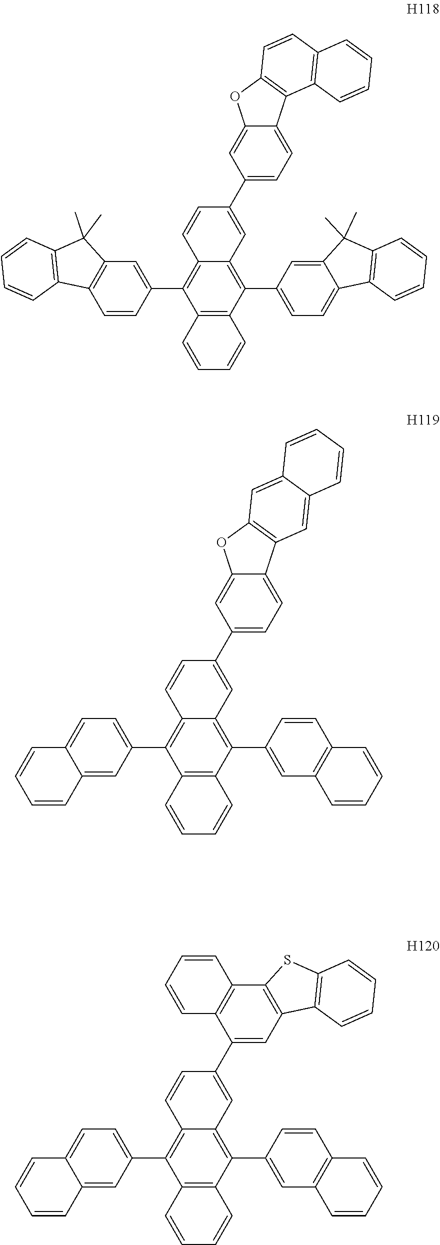 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

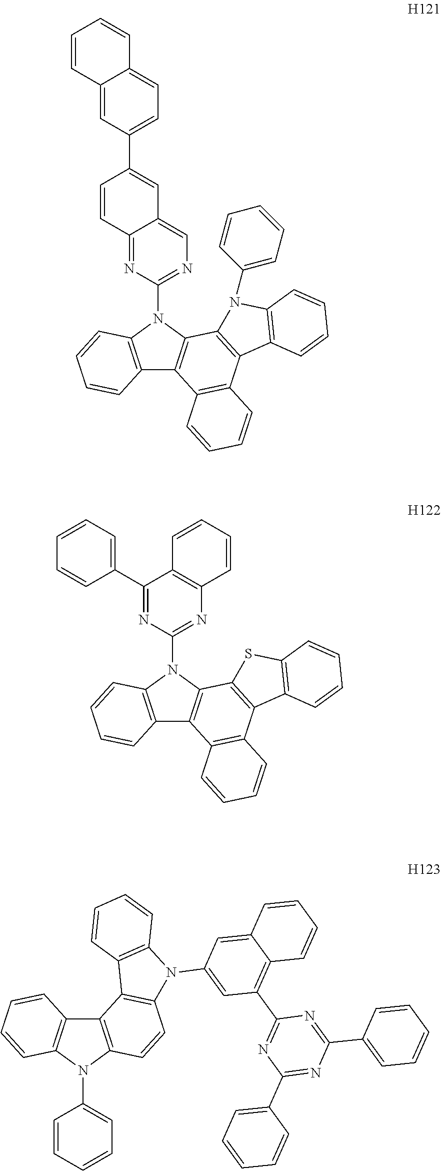 [SMILES: c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1 ; c1ccc(-c2nc(-c3ccccc3)nc(-c3cc(-n4c5ccccc5c5c6c7ccccc7n(-c7ccccc7)c6ccc54)cc4ccccc34)n2)cc1]

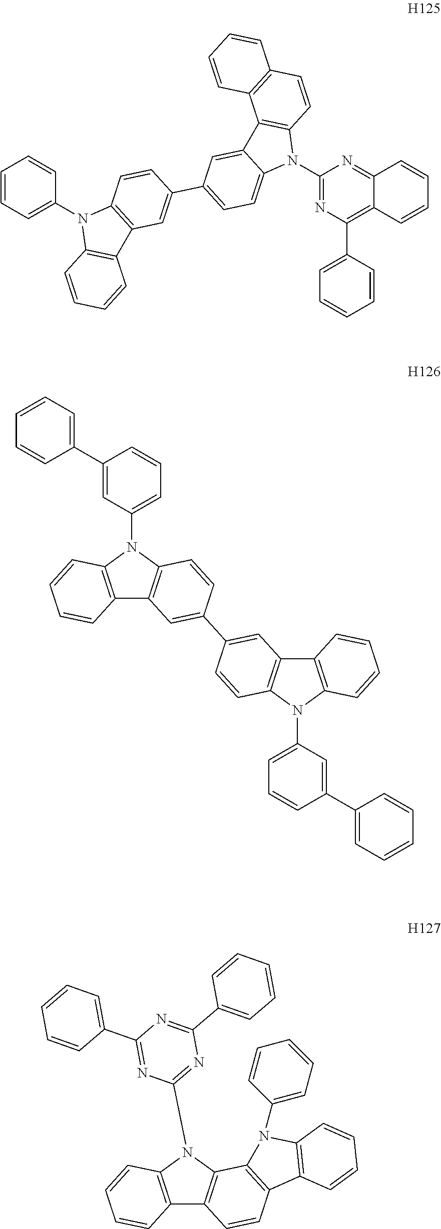 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2nc(-c3ccccc3)nc(-n3c4ccccc4c4ccc5c6ccccc6n(-c6ccccc6)c5c43)n2)cc1]

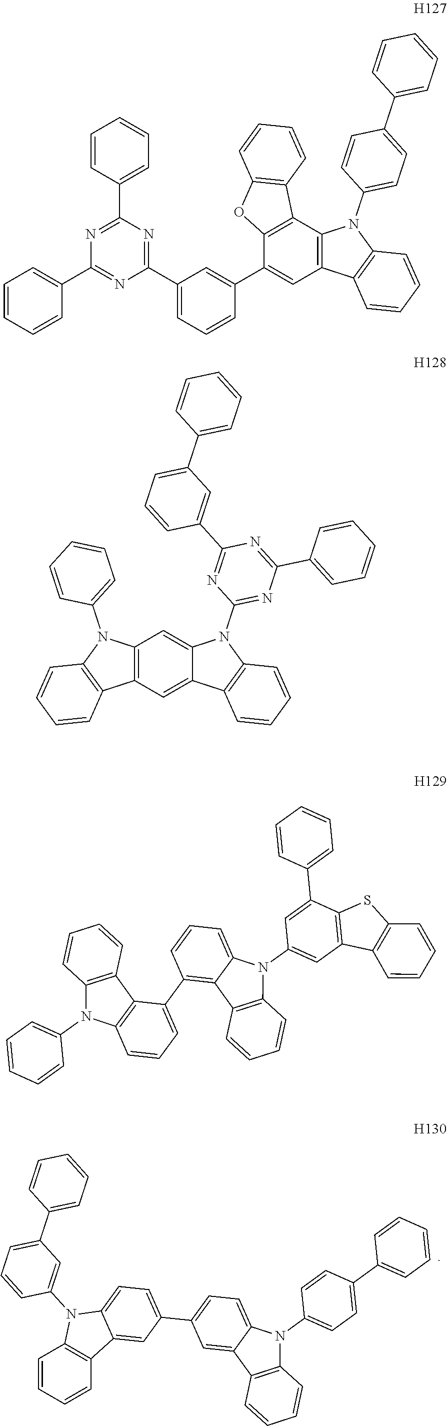

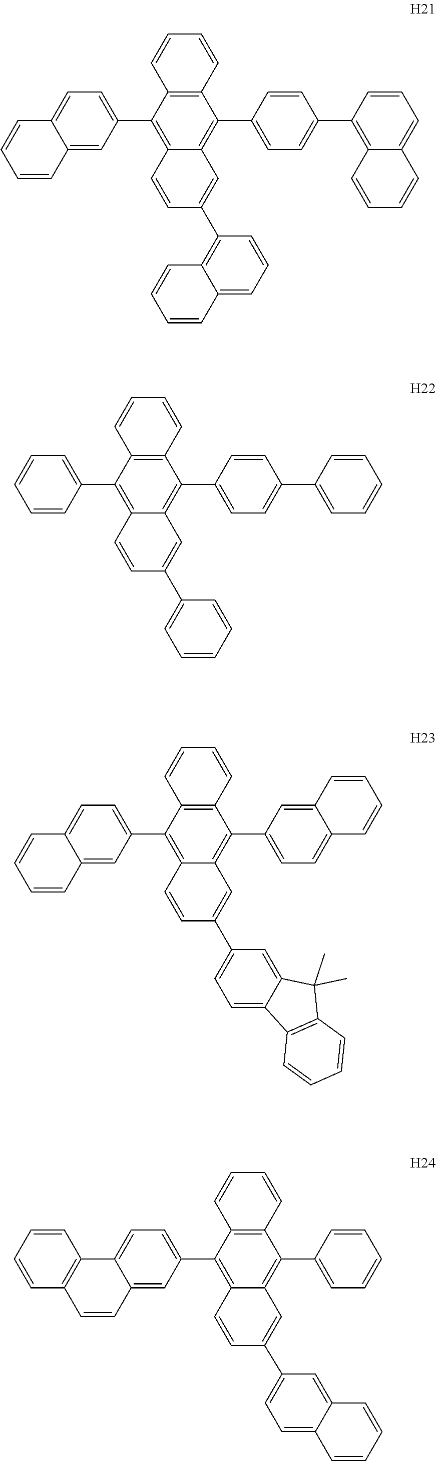

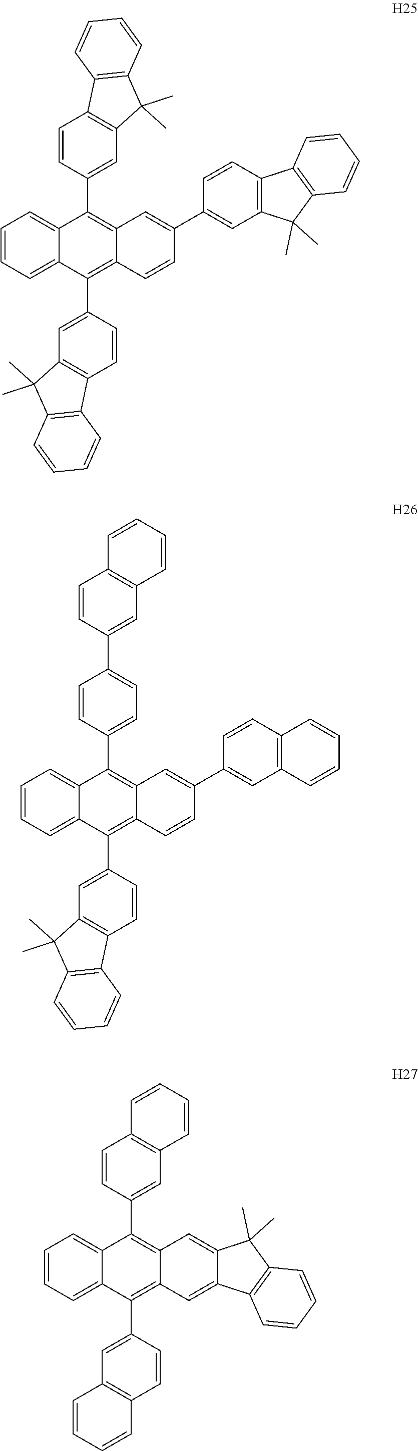

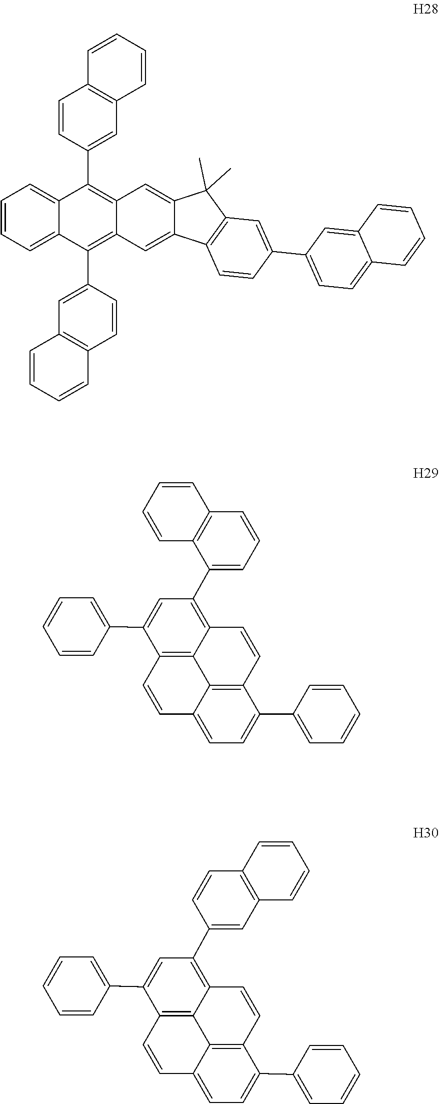

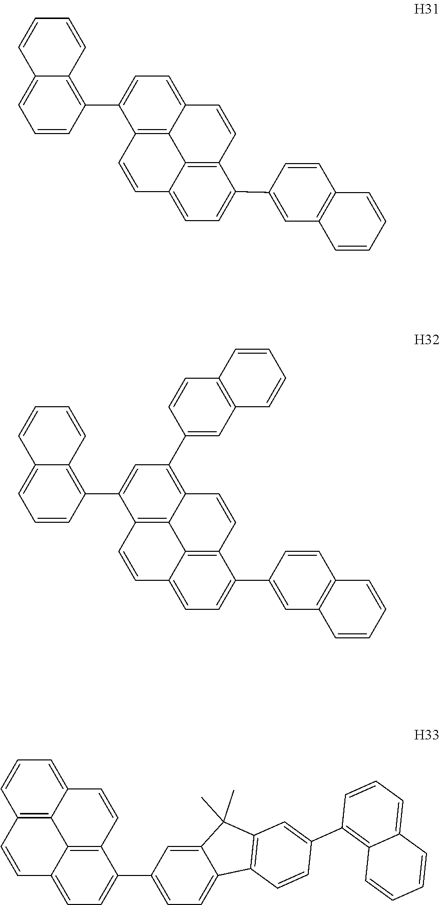

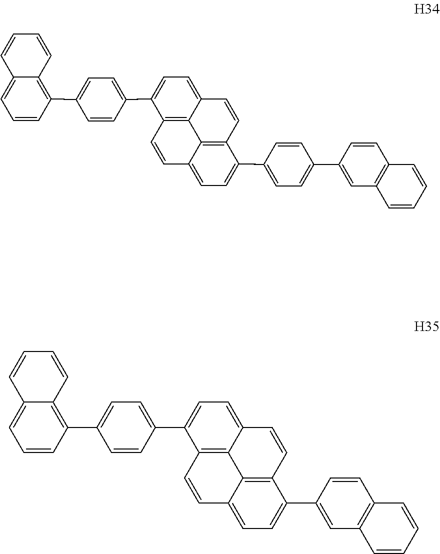

In one or more embodiments, the host may include a silicon-containing compound, a phosphine oxide-containing compound, or a (e.g., any suitable) combination thereof.

The host may have one or more suitable modifications. For example, the host may include only one kind of compound, or may include two or more kinds of different compounds.

### Phosphorescent Dopant

The emission layer may include, as a phosphorescent dopant, the organometallic compound represented by Formula 1.

In one or more embodiments, when the emission layer includes the organometallic compound represented by Formula 1 and the organometallic compound represented by Formula 1 serves as an auxiliary dopant, the emission layer may include a phosphorescent dopant.

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or a (e.g., any suitable) combination thereof.

The phosphorescent dopant may be electrically neutral.

For example, in some embodiments, the phosphorescent dopant may include an organometallic compound represented by Formula 401:

M(L₄₀₁)_{xc1}(L₄₀₂)_{xc2} Formula 401

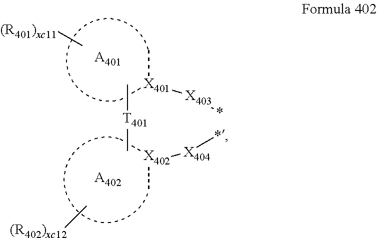

wherein, in Formulae 401 and 402,
M may be a transition metal (e.g., Ir, Pt, Pd, Os, Ti, Au, Hf, Eu, Tb, Rh, Re, or Tm),
L₄₀₁ may be a ligand represented by Formula 402, and xc1 may be 1, 2, or 3, wherein, when xc1 is 2 or more, two or more of L₄₀₁(s) may be identical to or different from each other,
L₄₀₂ may be an organic ligand, and xc2 may be 0, 1, 2, 3, or 4, wherein, when xc2 is 2 or more, two or more of L₄₀₂(s) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *═C(Q₄₁₁)-*′,
X₄₀₃ and X₄₀₄ may each independently be a chemical bond (e.g., a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be the same as described with respect to Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described with respect to Q₁,
xc11 and xc12 may each independently be an integer from 0 to 10, and
* and *′ in Formula 402 each indicate a binding site to M in Formula 401.

For example, in some embodiments, in Formula 402, i) X₄₀₁ may be nitrogen and X₄₀₂ may be carbon, or ii) each of X₄₀₁ and X₄₀₂ may be nitrogen.

In one or more embodiments, when xc1 in Formula 401 is 2 or more, two ring A₄₀₁(s) in two or more of L₄₀₁(s) may optionally be linked to each other via T₄₀₂, which is a linking group, and/or two ring A₄₀₂(s) may optionally be linked to each other via T₄₀₃, which is a linking group (see Compounds PD1 to PD4 and PD7). T₄₀₂ and T₄₀₃ may each be the same as described with respect to T₄₀₁.

In Formula 401, L₄₀₂ may be an organic ligand. For example, L₄₀₂ may include a halogen, a diketone group (e.g., an acetylacetonate group), a carboxylic acid group (e.g., a picolinate group), —C(═O), an isonitrile group, —CN group, a phosphorus-containing group (e.g., a phosphine group, a phosphite group, and/or the like), or a (e.g., any suitable) combination thereof.

In one or more embodiments, the phosphorescent dopant may include, for example, one selected from among compounds PD1 to PD25, or a (e.g., any suitable) combination thereof:

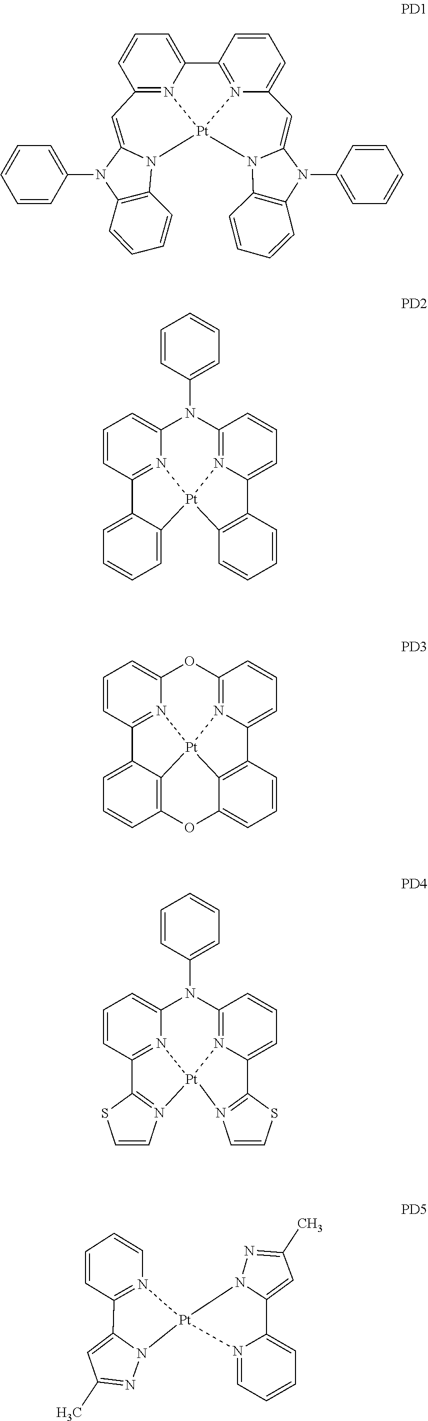

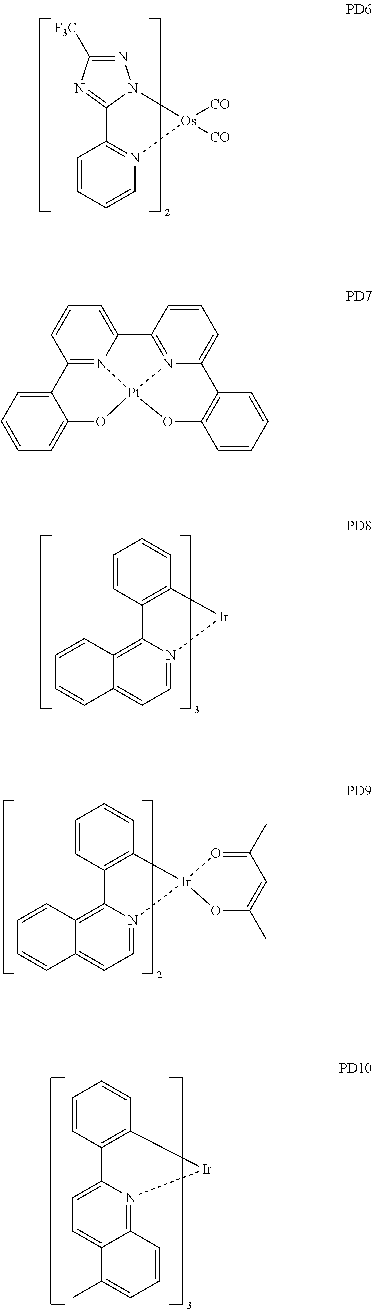

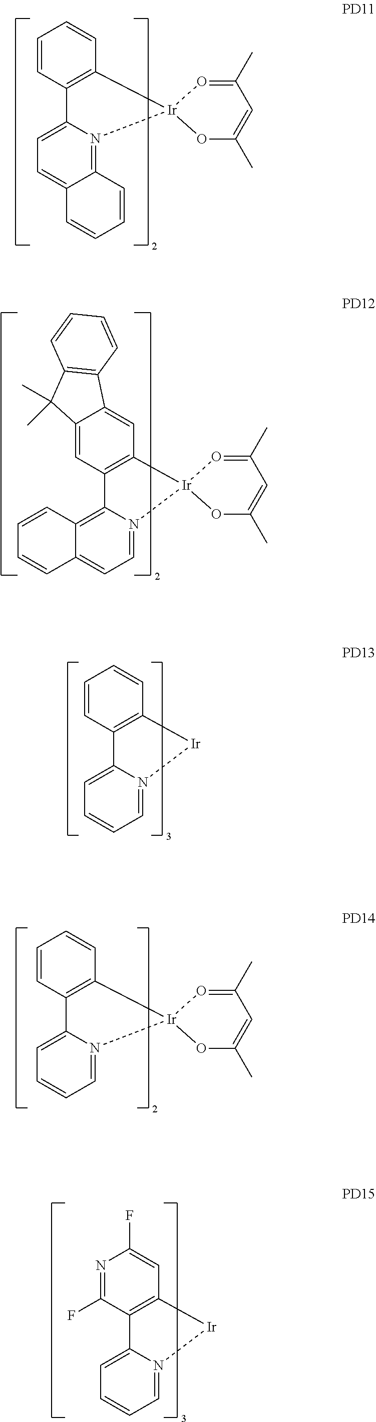

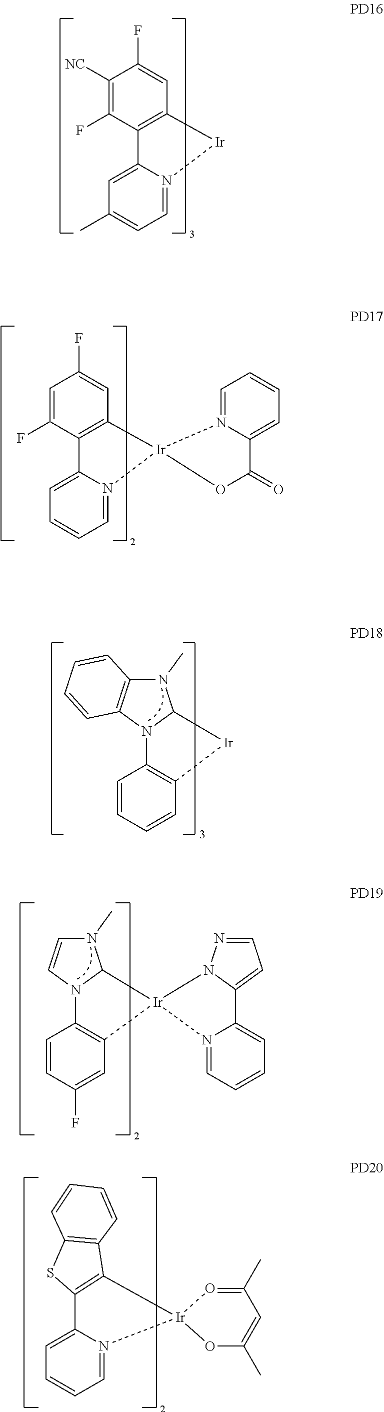

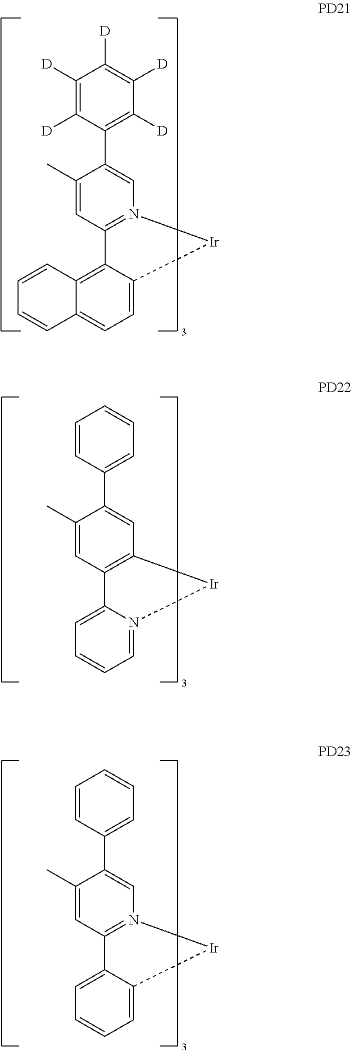

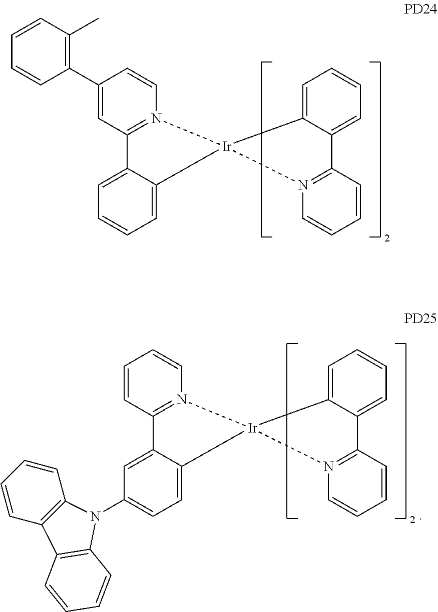

### Fluorescent Dopant

In one or more embodiments, when the emission layer includes the organometallic compound represented by Formula 1 and the organometallic compound represented by Formula 1 serves as an auxiliary dopant, the emission layer may further include a fluorescent dopant.

In one or more embodiments, when the emission layer includes the organometallic compound represented by Formula 1 and the organometallic compound represented by Formula 1 serves as a phosphorescent dopant, the emission layer may further include an auxiliary dopant.

The fluorescent dopant and the auxiliary dopant may each independently include an arylamine compound, a styrylamine compound, a boron-containing compound, or a (e.g., any suitable) combination thereof.

In one or more embodiments, the fluorescent dopant and the auxiliary dopant may each independently include a compound represented by Formula 501:

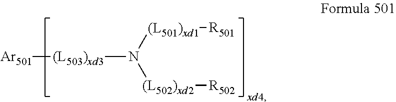

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

For example, in some embodiments, Ar₅₀₁ in Formula 501 may be a condensed cyclic group (e.g., an anthracene group, a chrysene group, a pyrene group, and/or the like) in which three or more monocyclic groups are condensed together.

For example, in some embodiments, xd4 in Formula 501 may be 2.

In one or more embodiments, the fluorescent dopant and the auxiliary dopant may each independently include: at least one selected from among Compounds FD1 to FD36; 4,4′-bis(2,2-diphenylvinyl)-1,1′-biphenyl (DPVBi); 4,4′-bis[4-(N,N-diphenylamino)styryl]biphenyl (DPAVBi); or a (e.g., any suitable) combination thereof:

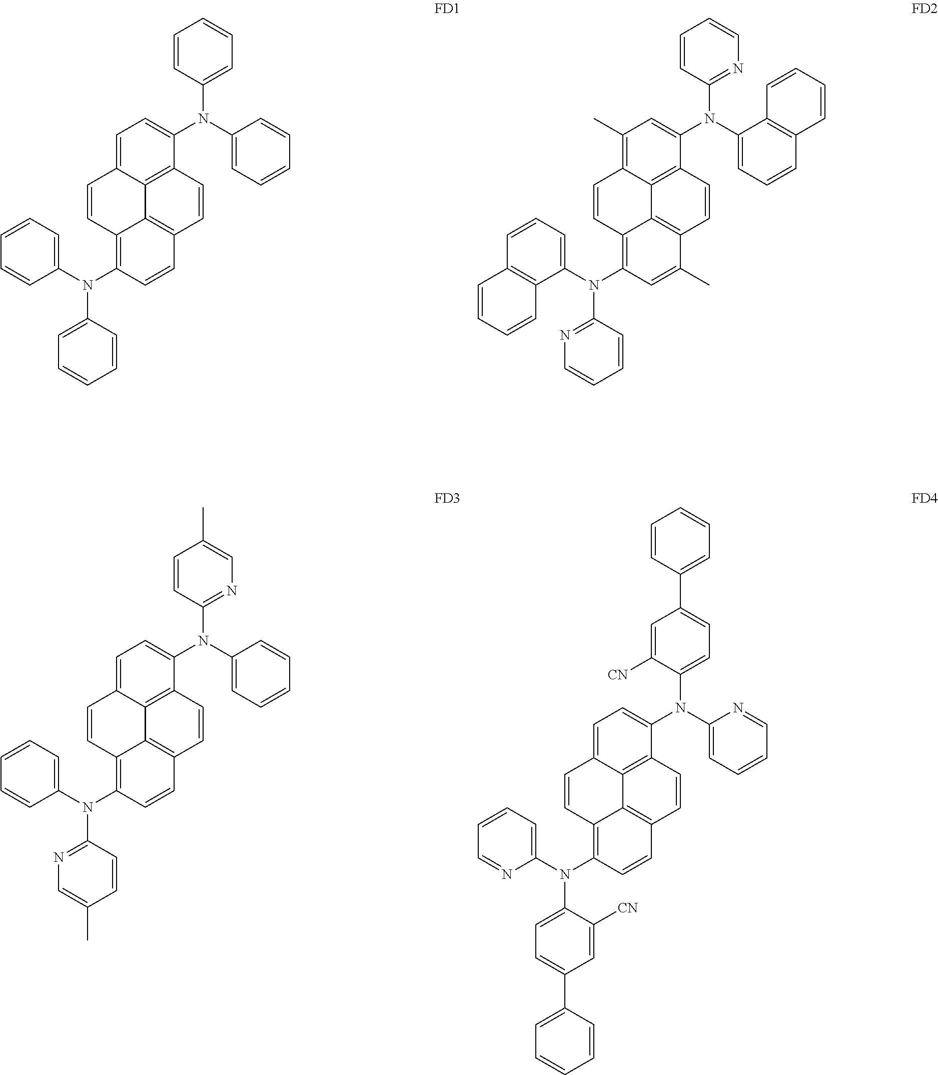

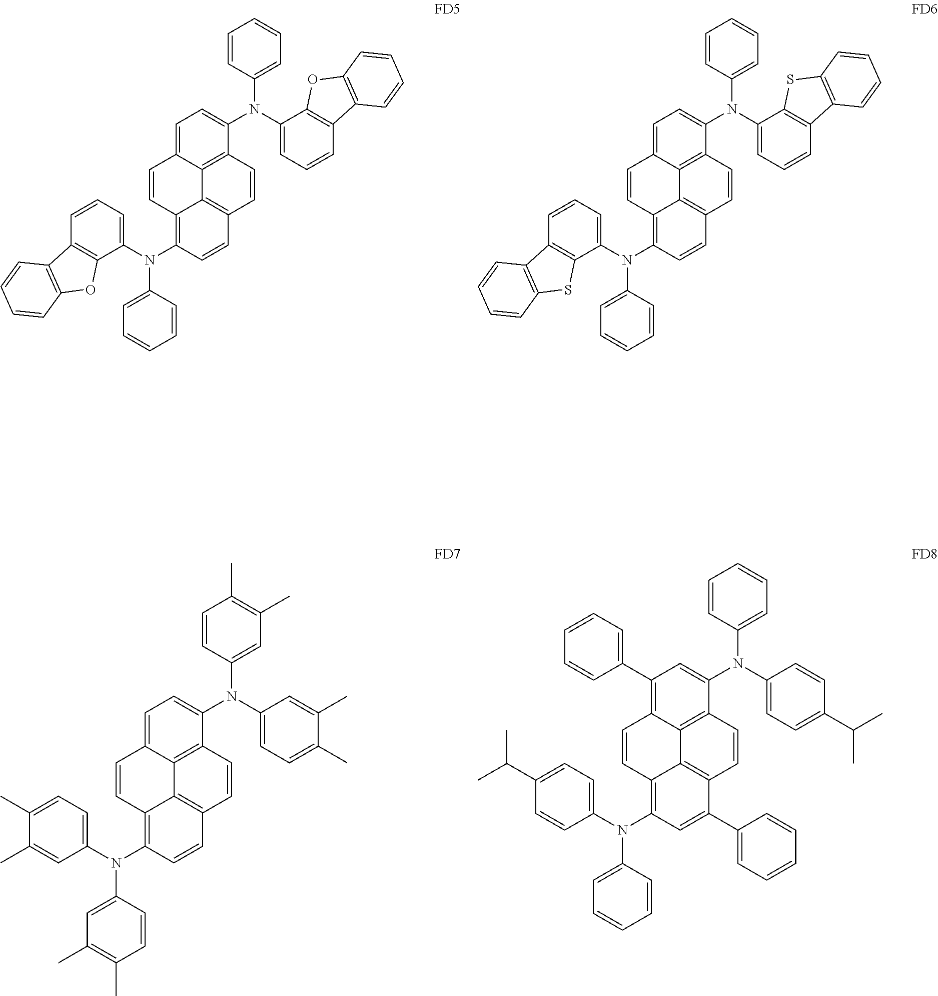

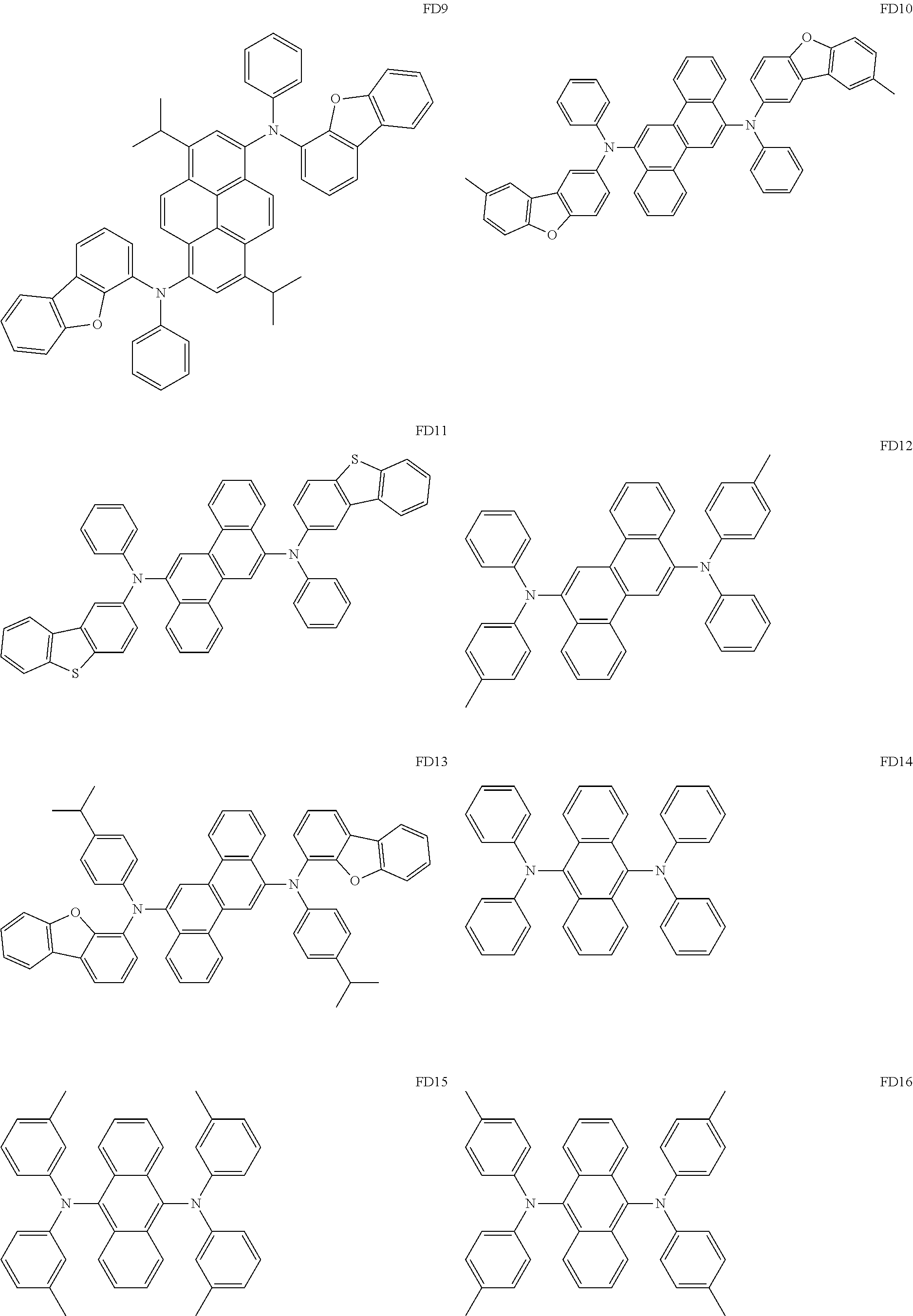

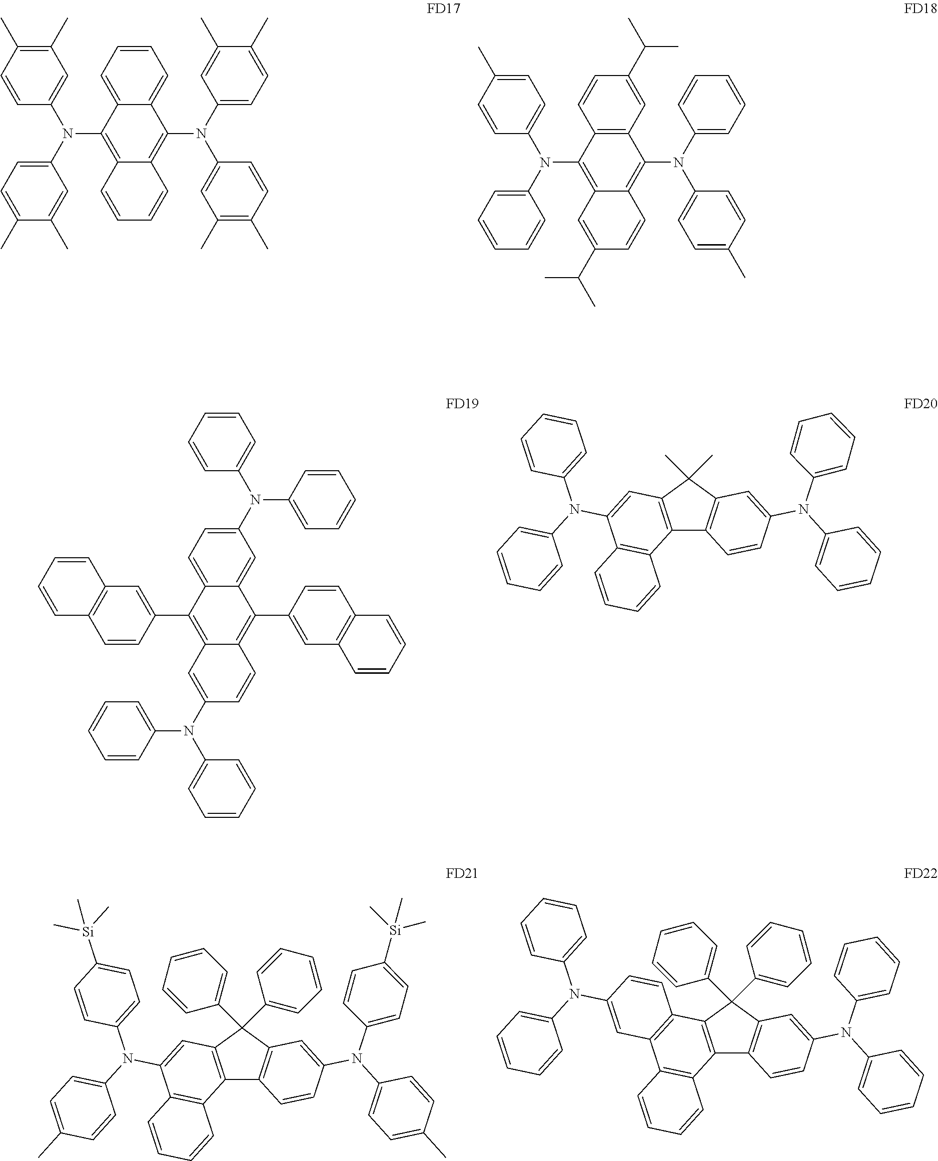

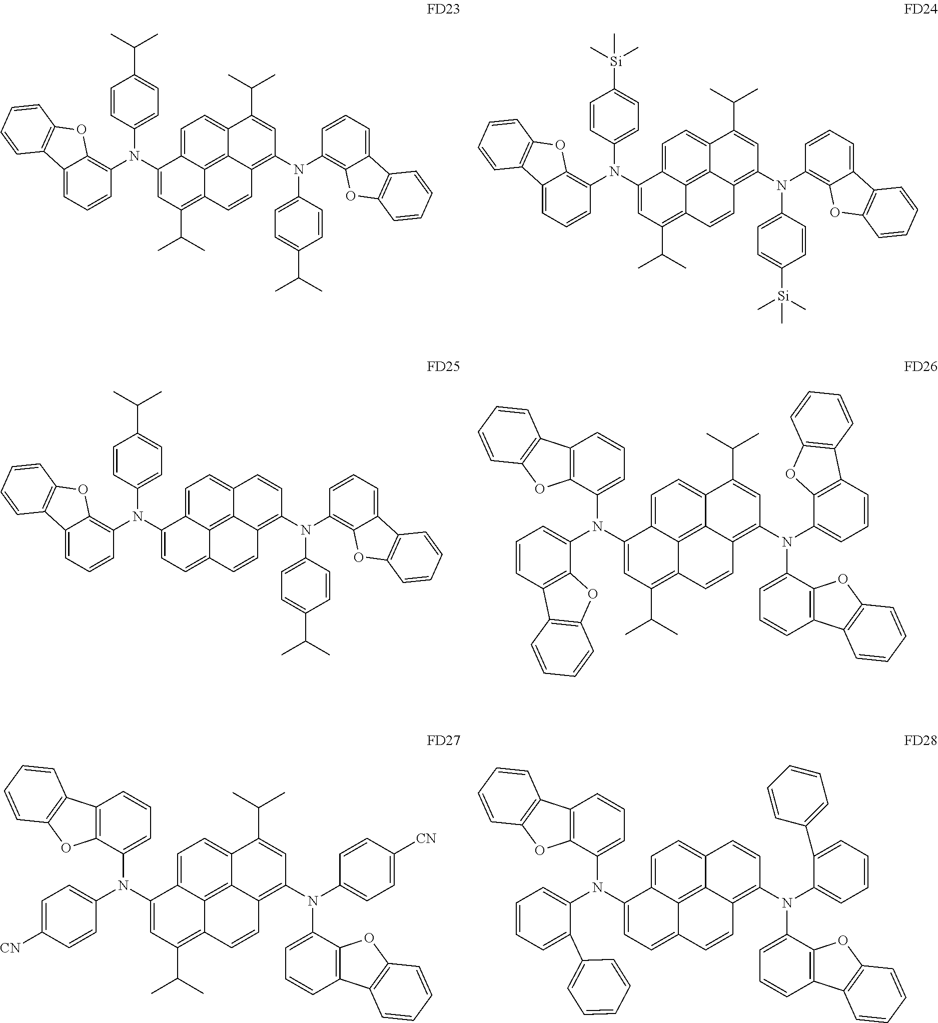

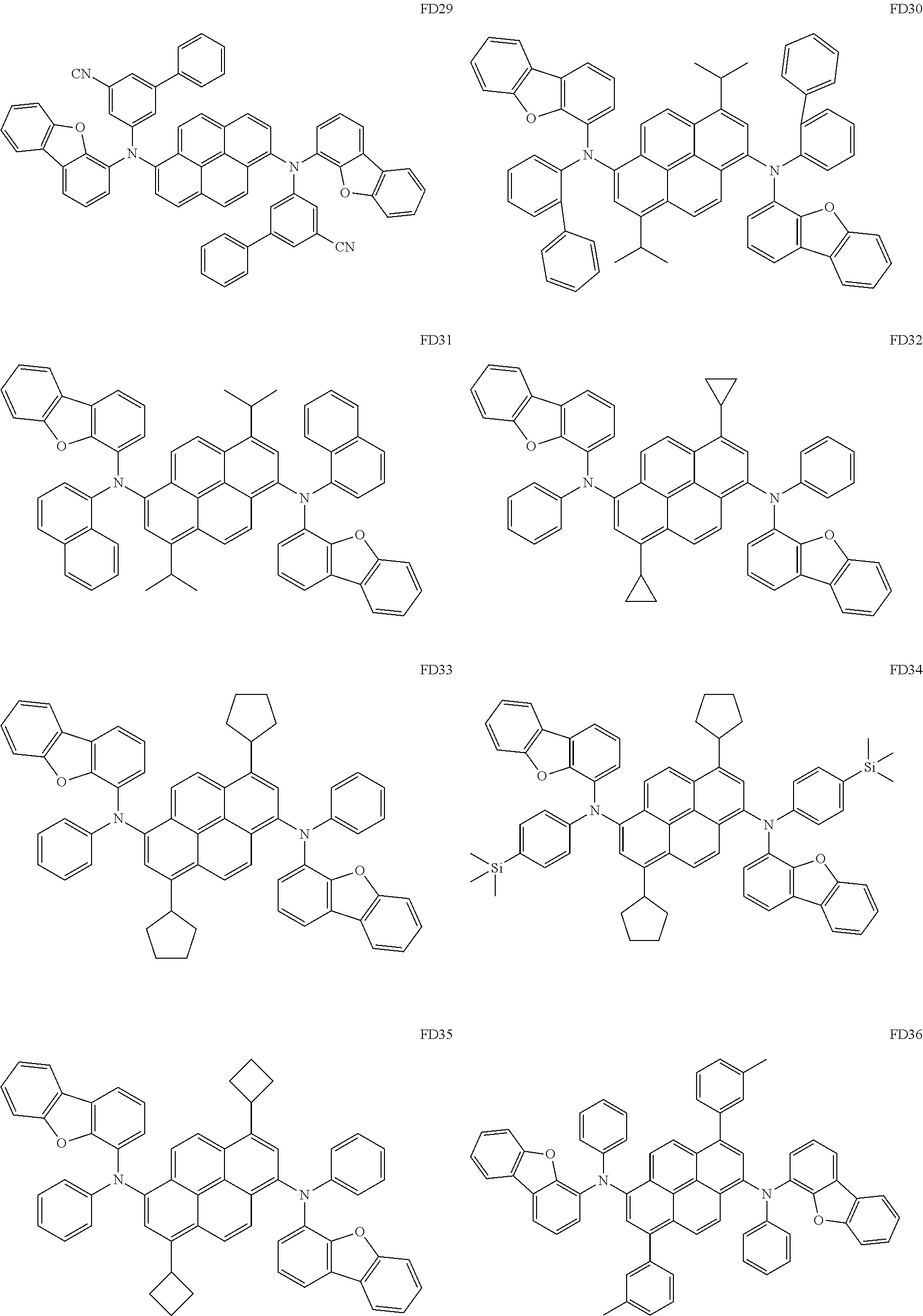

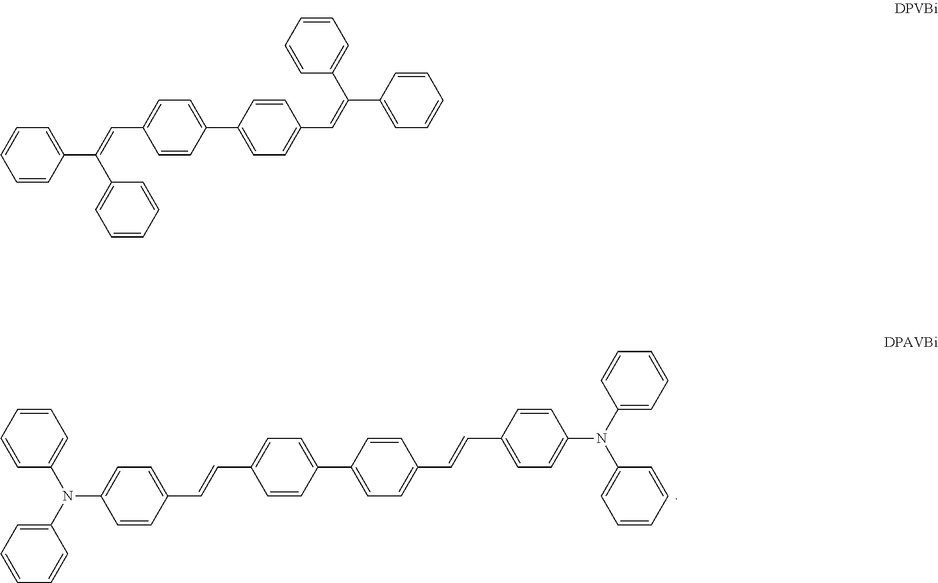

In one or more embodiments, the fluorescent dopant and the auxiliary dopant may each independently include the fourth compound represented by Formula 502 or 503.

### Electron Transport Region in Interlayer 130

The electron transport region may have: i) a single-layer structure including (e.g., consisting of) a single layer including (e.g., consisting of) a single material, ii) a single-layer structure including (e.g., consisting of) a single layer including (e.g., consisting of) multiple materials that are different from each other, or iii) a multi-layer structure including multiple layers including multiple materials that are different from each other.

The electron transport region may include a buffer layer, a hole blocking layer, an electron control layer, an electron transport layer, an electron injection layer, or a (e.g., any suitable) combination thereof.

For example, in one or more embodiments, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein constituent layers in each structure are sequentially stacked from the emission layer in the stated order.

In one or more embodiments, the electron transport region (e.g., a buffer layer, a hole blocking layer, an electron control layer, or an electron transport layer in the electron transport region) may include a metal-free compound including at least one π electron-deficient nitrogen-containing C₁-C₆₀ heterocyclic group.

For example, in some embodiments, the electron transport region may include a compound represented by Formula 601:

[Ar₆₀₁]ₓₑ₁₁-[(L₆₀₁)ₓₑ₁-R₆₀₁]ₓₑ₂₁, Formula 601
wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described with respect to Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ heterocyclic group that is unsubstituted or substituted with at least one R₁₀ₐ.

For example, in some embodiments, when xe11 in Formula 601 is 2 or more, two or more of Ar₆₀₁(s) may be linked to each other via a single bond.

In one or more embodiments, Ar₆₀₁ in Formula 601 may be an anthracene group unsubstituted or substituted with at least one R₁₀ₐ.

In one or more embodiments, the electron transport region may include a compound represented by Formula 601-1:

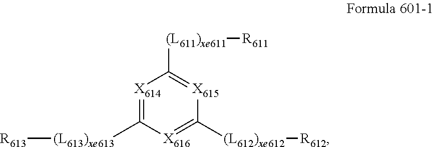

wherein, in Formula 601-1,
X₆₁₄ may be N or C(R₆₁₄), X₆₁₅ may be N or C(R₆₁₅), and X₆₁₆ may be N or C(R₆₁₆), wherein at least one selected from among X₆₁₄ to X₆₁₆ may be N,
L₆₁₁ to L₆₁₃ may each independently be the same as described with respect to L₆₀₁,
xe611 to xe613 may each independently be the same as described with respect to xe1,
R₆₁₁ to R₆₁₃ may each independently be the same as described with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, in some embodiments, xe1 and xe611 to xe613 in Formulae 601 and 601-1 may each independently be 0, 1, or 2.

In one or more embodiments, the electron transport region may include: at least one selected from among Compounds ET1 to ET46; 2,9-dimethyl-4,7-diphenyl-1,10-phenanthroline (BCP); 4,7-diphenyl-1,10-phenanthroline (Bphen); tris(8-hydroxyquinolinato)aluminum (Alq₃); bis(2-methyl-8-quinolinolato-N1,O8)-(1,1′-biphenyl-4-olato)aluminum (BAlq); 3-(4-biphenyl)-4-phenyl-5-tert-butylphenyl-1,2,4-triazole (TAZ); 4-(naphthalen-1-yl)-3,5-diphenyl-4H-1,2,4-triazole (NTAZ); or a (e.g., any suitable) combination thereof:

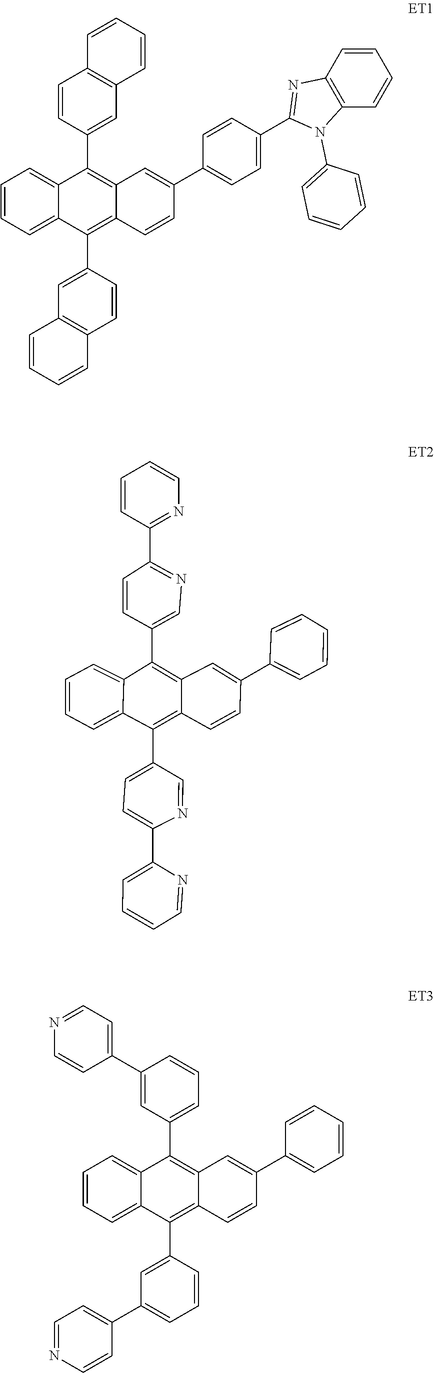 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

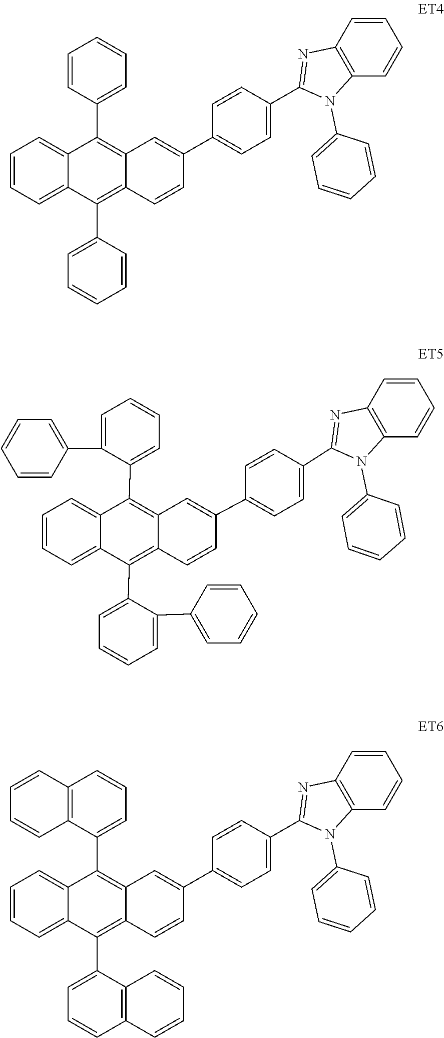 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

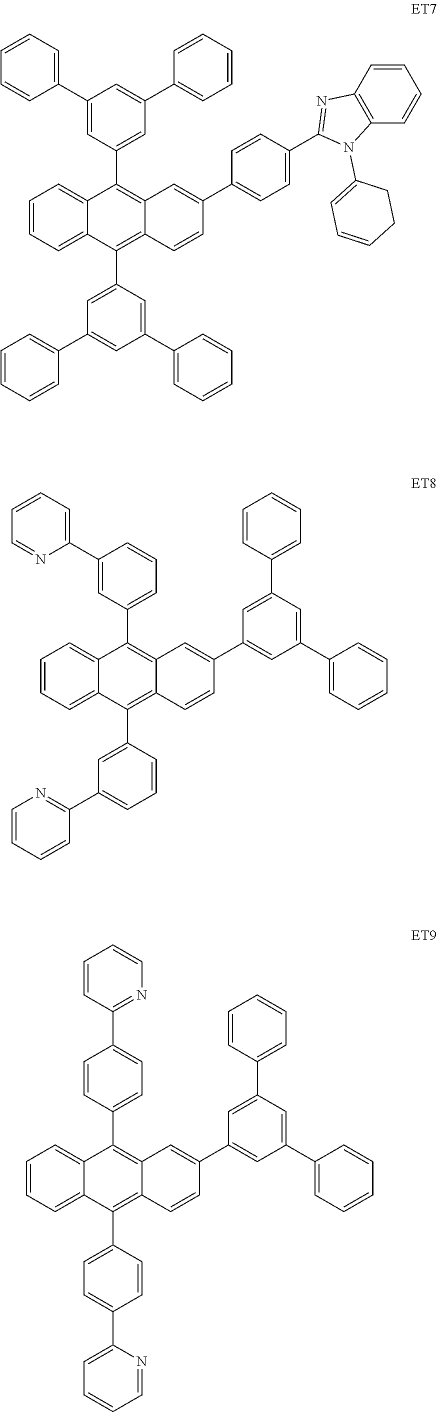 [SMILES: C1=CCCC(n2c(-c3ccc(-c4ccc5c(-c6cc(-c7ccccc7)cc(-c7ccccc7)c6)c6ccccc6c(-c6cc(-c7ccccc7)cc(-c7ccccc7)c6)c5c4)cc3)nc3ccccc32)=C1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

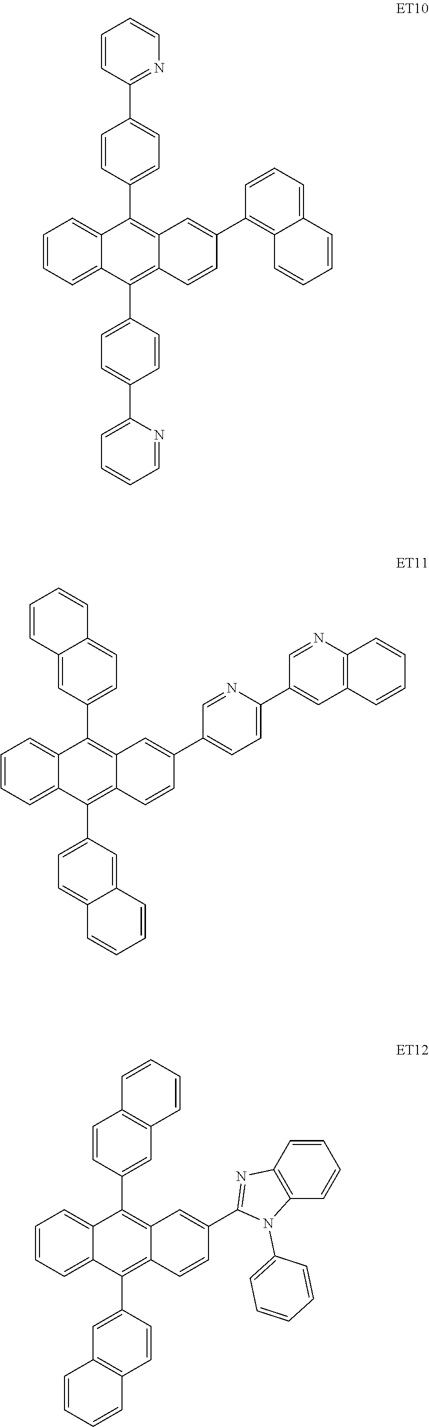 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

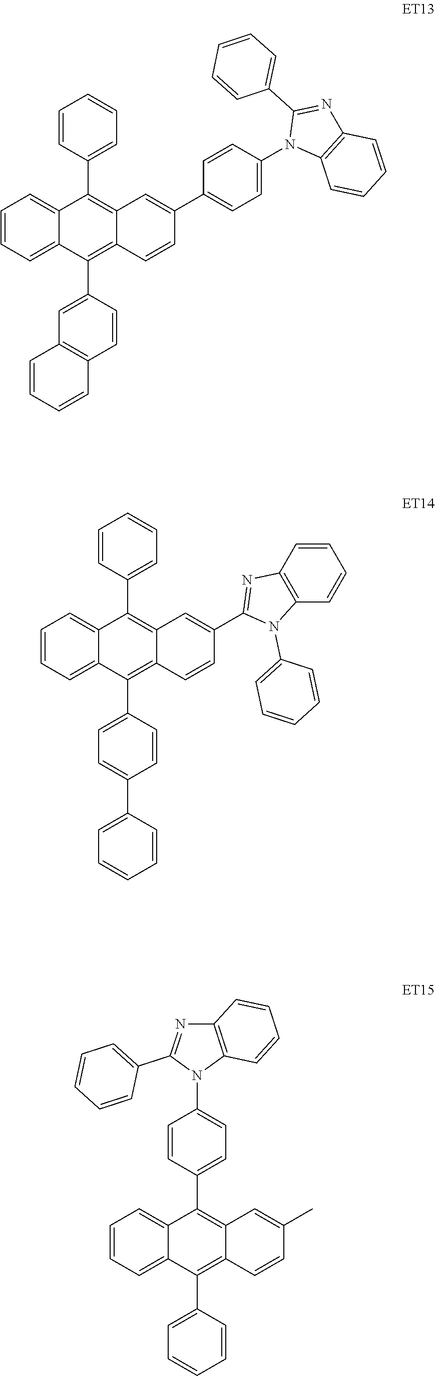 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

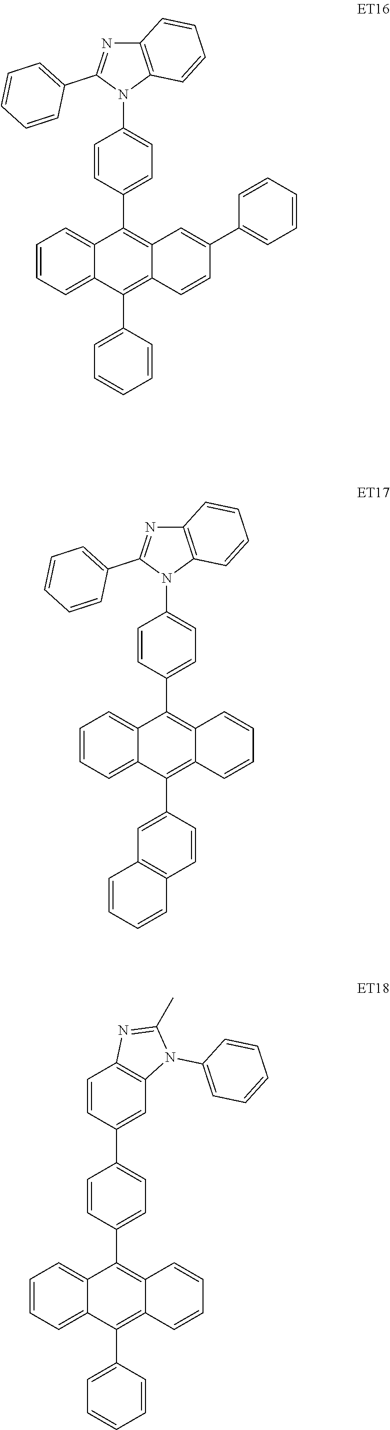 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

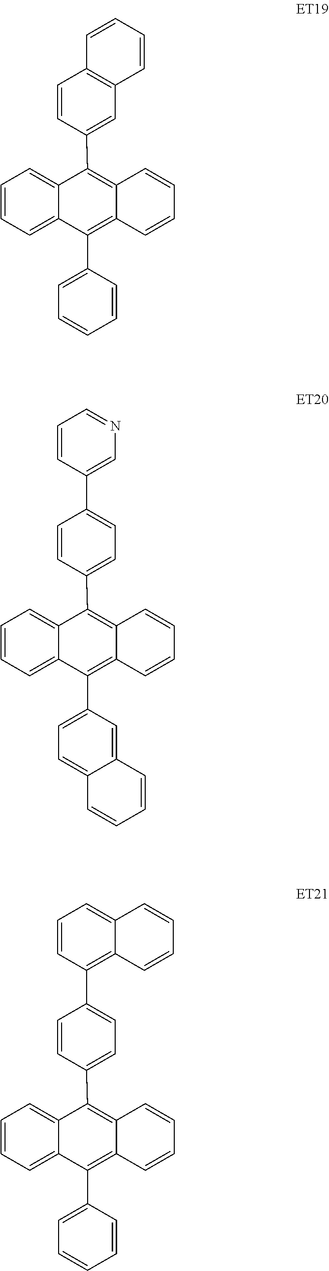

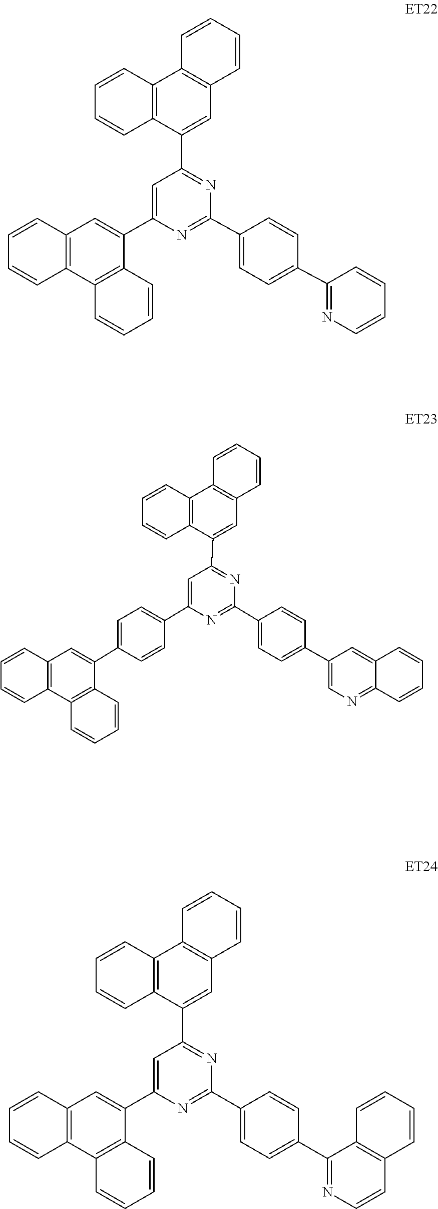 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

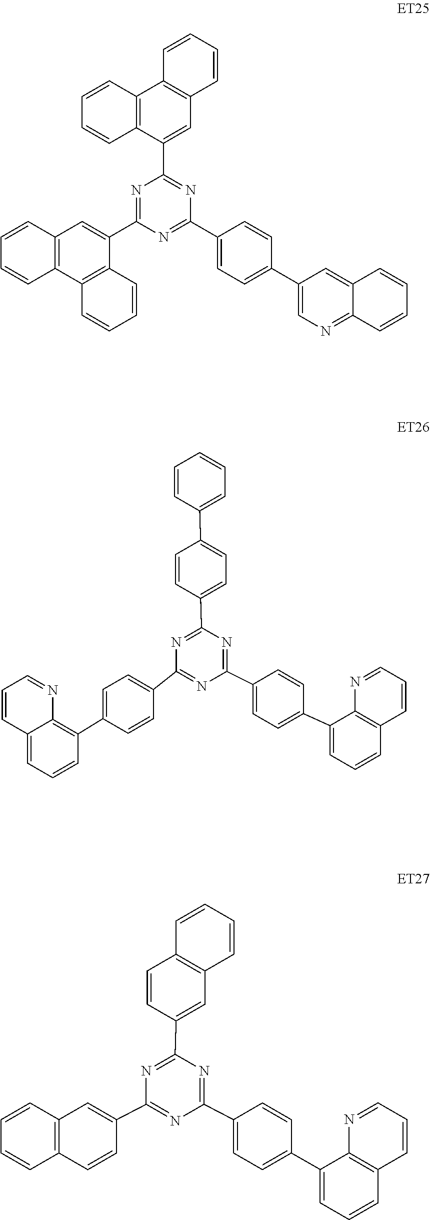 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

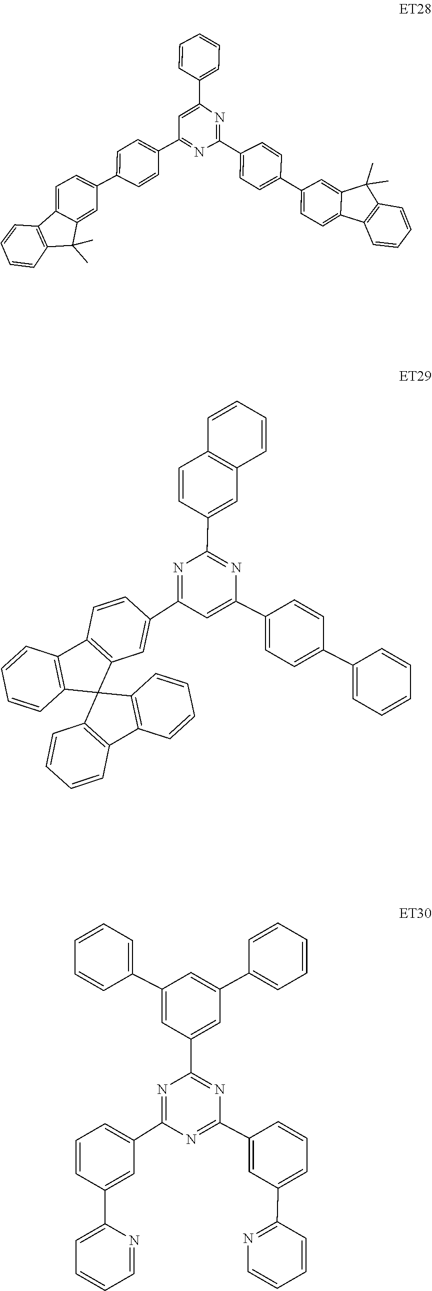 [SMILES: CC1(C)c2ccccc2-c2ccc(-c3ccc(-c4cc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

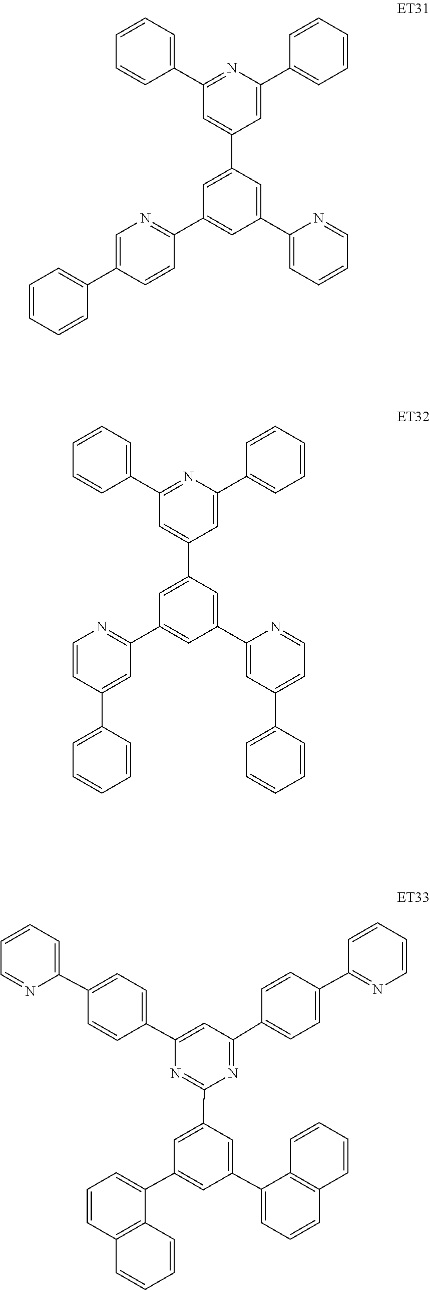 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

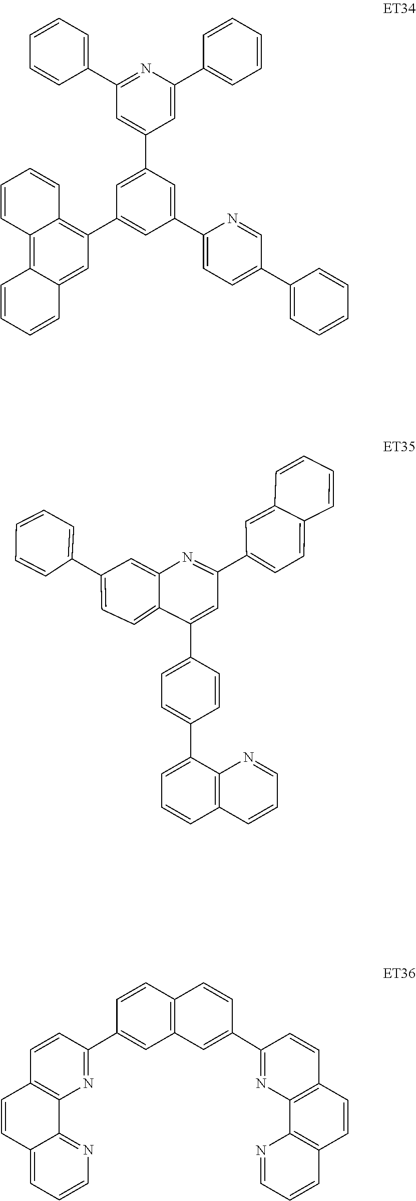 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

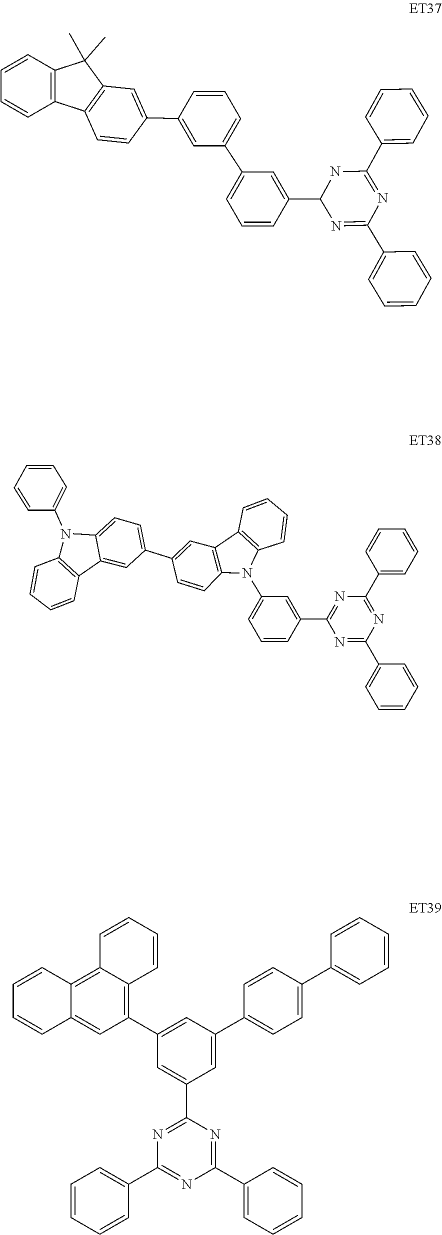

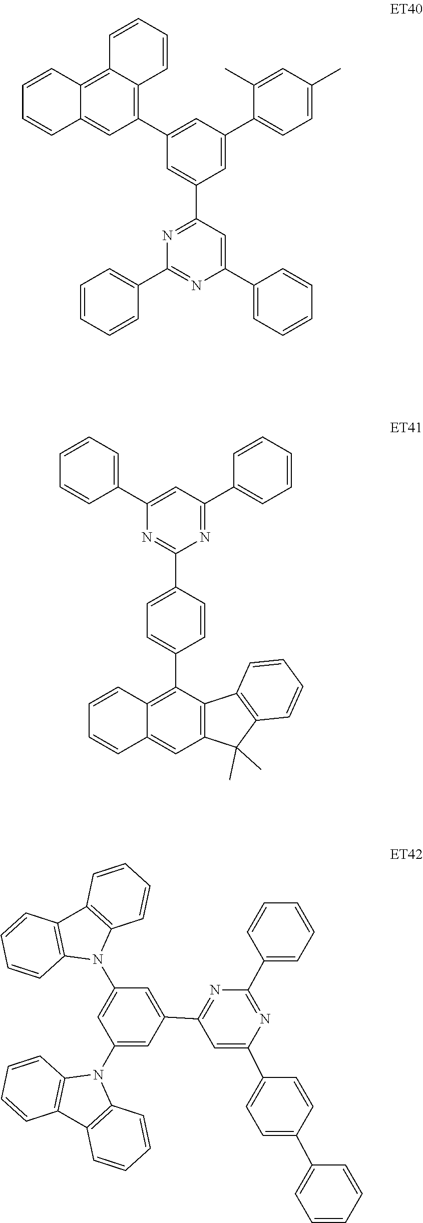 [SMILES: Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

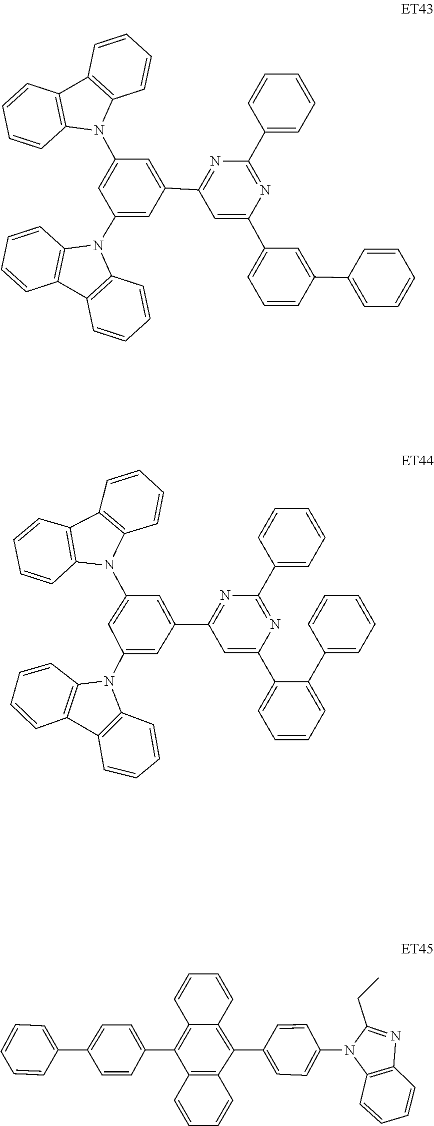 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

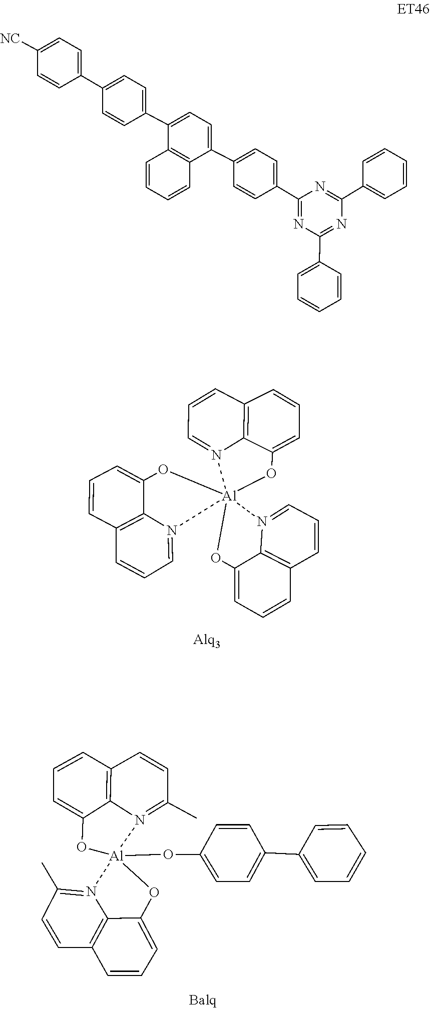

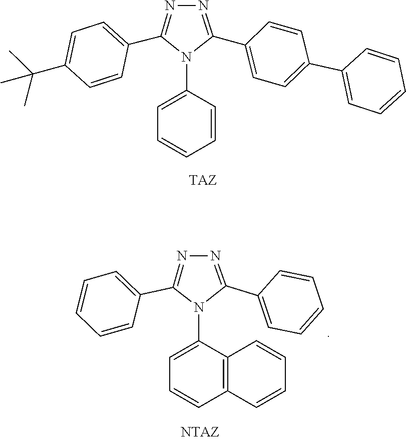 [SMILES: CC(C)(C)c1ccc(-c2nnc(-c3ccc(-c4ccccc4)cc3)n2-c2ccccc2)cc1 ; c1ccc(-c2nnc(-c3ccccc3)n2-c2cccc3ccccc23)cc1]

A thickness of the electron transport region may be in a range of about 100 Å to about 5,000 Å, for example, about 160 Å to about 4,000 Å. When the electron transport region includes a buffer layer, a hole blocking layer, an electron control layer, an electron transport layer, or a (e.g., any suitable) combination thereof, a thickness of the buffer layer, the hole blocking layer, or the electron control layer may each independently be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thickness of the buffer layer, the hole blocking layer, the electron control layer, the electron transport layer, and/or the electron transport region are within these ranges, satisfactory electron transporting characteristics may be obtained without a substantial increase in driving voltage.

In one or more embodiments, the electron transport region (e.g., an electron transport layer in the electron transport region) may further include, in addition to one or more of the aforementioned materials, a metal-containing material.

The metal-containing material may include an alkali metal complex, an alkaline earth metal complex, or a (e.g., any suitable) combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or a (e.g., any suitable) combination thereof.

For example, in some embodiments, the metal-containing material may include a Li complex. The Li complex may include, for example, Compound ET-D1 (Liq) or ET-D2:

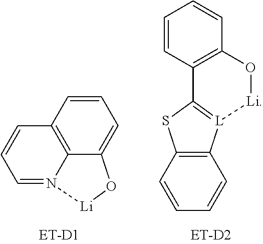

In one or more embodiments, the electron transport region may include an electron injection layer that facilitates the injection of electrons from the second electrode 150. The electron injection layer may directly contact the second electrode 150.

The electron injection layer may have: i) a single-layer structure including (e.g., consisting of) a single layer including (e.g., consisting of) a single material, ii) a single-layer structure including (e.g., consisting of) a single layer including (e.g., consisting of) multiple materials that are different from each other, or iii) a multi-layer structure including multiple layers including multiple materials that are different from each other.

In one or more embodiments, the electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a (e.g., any suitable) combination thereof.

The alkali metal may include Li, Na, K, Rb, Cs, or a (e.g., any suitable) combination thereof. The alkaline earth metal may include Mg, Ca, Sr, Ba, or a (e.g., any suitable) combination thereof. The rare earth metal may include Sc, Y, Ce, Tb, Yb, Gd, or a (e.g., any suitable) combination thereof.

The alkali metal-containing compound, the alkaline earth metal-containing compound, and the rare earth metal-containing compound may be oxides, halides (e.g., fluorides, chlorides, bromides, or iodides), or tellurides of the alkali metal, the alkaline earth metal, and the rare earth metal, respectively, or a (e.g., any suitable) combination thereof.

The alkali metal-containing compound may include: an alkali metal oxide, such as Li₂O, Cs₂O, K₂O, and/or the like; an alkali metal halide, such as LiF, NaF, CsF, KF, LiI, NaI, CsI, KI, and/or the like; or a (e.g., any suitable) combination thereof. The alkaline earth metal-containing compound may include an alkaline earth metal oxide, such as BaO, SrO, CaO, BaₓSr₁₋ₓO (wherein x is a real number satisfying 0<x<1), BaₓCa₁₋ₓO (wherein x is a real number satisfying 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or a (e.g., any suitable) combination thereof. In one or more embodiments, the rare earth metal-containing compound may include lanthanide metal tellurides. Non-limiting examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and/or the like.

The alkali metal complex, the alkaline earth-metal complex, and the rare earth metal complex may include i) one of metal ions of the alkali metal, one of metal ions of the alkaline earth metal, and one of metal ions of the rare earth metal, respectively, and ii) a ligand bonded to the metal ion (e.g., the respective metal ion), for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or a (e.g., any suitable) combination thereof.

In one or more embodiments, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a (e.g., any suitable) combination thereof, as described above. In one or more embodiments, the electron injection layer may further include an organic material (e.g., the compound represented by Formula 601).

In one or more embodiments, the electron injection layer may include (e.g., consist of) i) an alkali metal-containing compound (e.g., an alkali metal halide), or ii) a) an alkali metal-containing compound (e.g., an alkali metal halide), and b) an alkali metal, an alkaline earth metal, a rare earth metal, or a (e.g., any suitable) combination thereof. For example, in some embodiments, the electron injection layer may be a KI:Yb co-deposited layer, an RbI:Yb co-deposited layer, a LiF:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or a (e.g., any suitable) combination thereof may be uniformly (substantially uniformly) or non-uniformly (substantially non-uniformly) dispersed in a matrix including the organic material.

A thickness of the electron injection layer may be in a range of about 1 Å to about 100 Å, for example, about 3 Å to about 90 Å. When the thickness of the electron injection layer is within these ranges, satisfactory electron injection characteristics may be obtained without a substantial increase in driving voltage.

### Second Electrode 150

The second electrode 150 may be arranged on the interlayer 130 having the aforementioned structure. The second electrode 150 may be a cathode, which is an electron injection electrode, and as a material for forming (or providing) the second electrode 150, a metal, an alloy, an electrically conductive compound, or a (e.g., any suitable) combination thereof, each having a low-work function, may be utilized.

The second electrode 150 may include Li, Ag, Mg, Al, Al—Li, Ca, Mg—In, Mg—Ag, Yb, Ag—Yb, ITO, IZO, or a (e.g., any suitable) combination thereof. The second electrode 150 may be a transmissive electrode, a semi-transmissive electrode, or a reflective electrode.

The second electrode 150 may have a single-layer structure or a multi-layer structure including multiple layers.

### Capping Layer

A first capping layer may be arranged outside (e.g., on) the first electrode 110, and/or a second capping layer may be arranged outside (e.g., on) the second electrode 150. In one or more embodiments, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

In some embodiments, light generated in the emission layer of the interlayer 130 of the light-emitting device 10 may be extracted toward the outside through the first electrode 110, which is a semi-transmissive electrode or a transmissive electrode, and the first capping layer. In some embodiments, light generated in the emission layer of the interlayer 130 of the light-emitting device 10 may be extracted toward the outside through the second electrode 150, which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 may be increased, and accordingly, the luminescence efficiency of the light-emitting device 10 may be improved.

Each of the first capping layer and the second capping layer may include a material having a refractive index of 1.6 or more (e.g., at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer or the second capping layer may (e.g., the first capping layer and the second capping layer may each independently) include a carbocyclic compound, a heterocyclic compound, an amine group-containing compound, a porphine derivative, a phthalocyanine derivative, a naphthalocyanine derivative, an alkali metal complex, an alkaline earth metal complex, or a (e.g., any suitable) combination thereof. The carbocyclic compound, the heterocyclic compound, and the amine group-containing compound may each optionally be substituted with a substituent including O, N, S, Se, Si, F, Cl, Br, I, or a (e.g., any suitable) combination thereof. In one or more embodiments, at least one of the first capping layer or the second capping layer may (e.g., the first capping layer and the second capping layer may each independently) include an amine group-containing compound.

In one or more embodiments, at least one of the first capping layer or the second capping layer may (e.g., the first capping layer and the second capping layer may each independently) include a compound represented by Formula 201, a compound represented by Formula 202, or a (e.g., any suitable) combination thereof.

In one or more embodiments, at least one of the first capping layer or the second capping layer may (e.g., the first capping layer and the second capping layer may each independently) include: at least one selected from among Compounds HT28 to HT33; at least one selected from among Compounds CP1 to CP6; β-NPB; or a (e.g., any suitable) combination thereof:

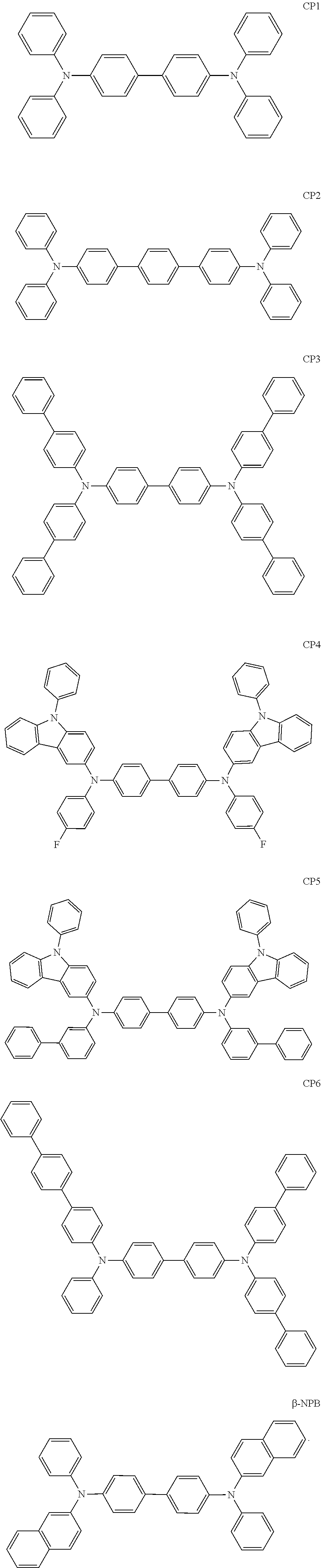

### Electronic Apparatus

The light-emitting device may be included in one or more suitable types (kinds) of electronic apparatuses. For example, the electronic apparatus including the light-emitting device may be a light-emitting apparatus, an authentication apparatus, and/or the like.

In one or more embodiments, the electronic apparatus (for example, light-emitting apparatus) may further include i) a color filter, ii) a color conversion layer, or iii) a color filter and a color conversion layer, in addition to the light-emitting device. The color filter and/or the color conversion layer may be arranged in at least one direction in which light emitted from the light-emitting device travels. For example, in some embodiments, light emitted from the light-emitting device may be blue light, green light, or white light (e.g., combined white light). Details on the light-emitting device may be referred to the descriptions provided herein. In some embodiments, the color conversion layer may include quantum dots.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining layer may be arranged among the subpixel areas to define each of the subpixel areas.

The color filter may further include a plurality of color filter areas and light-shielding patterns therebetween, and the color conversion layer may further include a plurality of color conversion areas and light-shielding patterns therebetween.

The plurality of color filter areas (or the plurality of color conversion areas) may include: a first area configured to emit first color light; a second area configured to emit second color light; and/or a third area configured to emit third color light, wherein the first color light, the second color light, and/or the third color light may have different maximum emission wavelengths from one another. For example, in one or more embodiments, the first color light may be red light, the second color light may be green light, and the third color light may be blue light. For example, in one or more embodiments, the plurality of color filter areas (or the plurality of color conversion areas) may include quantum dots. In some embodiments, the first area may include red quantum dots to emit red light, the second area may include green quantum dots to emit green light, and the third area may not include (e.g., may exclude) any quantum dots. Each of the first area, the second area, and/or the third area may further include a scatter.

For example, in the light-emitting device emitting first light, the first area may be to absorb the first light to emit first-first color light, the second area may be to absorb the first light to emit second-first color light, and the third area may be to absorb the first light to emit third-first color light. Here, the first-first color light, the second-first color light, and the third-first color light may have different maximum emission wavelengths from one another. In some embodiments, the first light may be blue light, the first-first color light may be red light, the second-first color light may be green light, and the third-first color light may be blue light.

In one or more embodiments, the electronic apparatus may further include a thin-film transistor, in addition to the aforementioned light-emitting device. The thin-film transistor may include a source electrode, a drain electrode, and an activation layer (e.g., a semiconductor layer), wherein one of the source electrode and the drain electrode may be electrically connected to the first electrode or the second electrode of the light-emitting device.

The thin-film transistor may further include a gate electrode, a gate insulating film, and/or the like.

The activation layer may include crystalline silicon, amorphous silicon, an organic semiconductor, an oxide semiconductor, and/or the like.

In one or more embodiments, the electronic equipment may further include a sealing portion for sealing the light-emitting device. The sealing portion may be arranged between the color filter and/or the color conversion layer and the light-emitting device. The sealing portion allows light from the light-emitting device to be extracted to the outside, and concurrently (e.g., simultaneously) prevents ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin-film encapsulation layer, the electronic equipment may be flexible.

In one or more embodiments, various functional layers may be additionally arranged on the sealing portion, in addition to the color filter and/or the color conversion layer, according to the utilization of the electronic apparatus. Non-limiting examples of the functional layers may include a touch screen layer, a polarizing layer, and/or the like. The touch screen layer may be a pressure-sensitive touch screen layer, a capacitive touch screen layer, or an infrared touch screen layer.

The authentication apparatus may be, for example, a biometric authentication apparatus that authenticates an individual by utilizing biometric information of a living body (e.g., fingertips, pupils, and/or the like). The authentication apparatus may further include, in addition to the light-emitting device as described above, a biometric information collector.

The electronic apparatus may be applied to one or more of displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (e.g., meters for a vehicle, an aircraft, and a vessel), projectors, and/or the like.

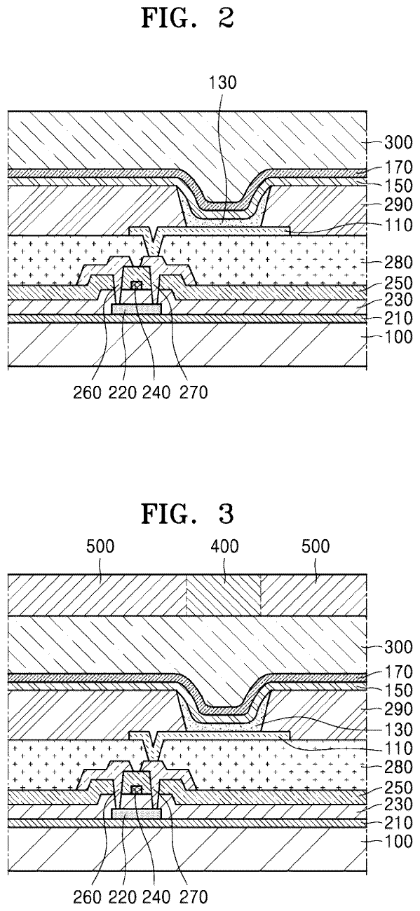

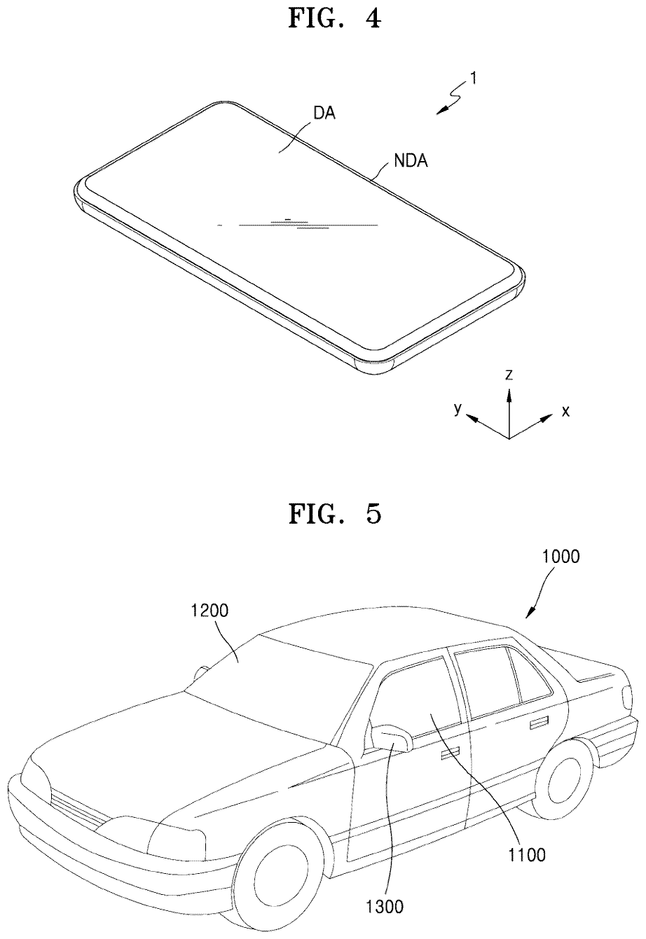

### Description of FIG. 2 and FIG. 3

FIG. 2 is a cross-sectional view showing a light-emitting apparatus as an example of an electronic apparatus according to one or more embodiments of the present disclosure.

The light-emitting apparatus of FIG. 2 may include a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be on the substrate 100. The buffer layer 210 may prevent or reduce penetration of impurities through the substrate 100, and provide a flat surface on the substrate 100.

The TFT may be on the buffer layer 210. The TFT may include an activation layer 220, a gate electrode 240, a source electrode 260, and a drain electrode 270.

The activation layer 220 may include an inorganic semiconductor, such as silicon or polysilicon, an organic semiconductor, or an oxide semiconductor, and may include a source region, a drain region, and a channel region.

A gate insulating film 230 for insulating the activation layer 220 from the gate electrode 240 may be on the activation layer 220, and the gate electrode 240 may be on the gate insulating film 230.

An interlayer insulating film 250 may be on the gate electrode 240. The interlayer insulating film 250 may be arranged between the gate electrode 240 and the source electrode 260 and between the gate electrode 240 and the drain electrode 270, to insulate these electrodes from one another.

The source electrode 260 and the drain electrode 270 may be on the interlayer insulating film 250. The interlayer insulating film 250 and the gate insulating film 230 may be formed to expose the source region and the drain region of the activation layer 220, and the source electrode 260 and the drain electrode 270 may be arranged in contact with the exposed portions of the source region and the drain region of the activation layer 220, respectively.

The TFT may be electrically connected to the light-emitting device to drive the light-emitting device, and may be covered and protected by a passivation layer 280. The passivation layer 280 may include an inorganic insulating film, an organic insulating film, or a (e.g., any suitable) combination thereof. The light-emitting device may be provided on the passivation layer 280. The light-emitting device may include a first electrode 110, an interlayer 130, and a second electrode 150.

The first electrode 110 (e.g., as an anode) may be on the passivation layer 280. The passivation layer 280 may be arranged to expose a portion of the drain electrode 270 without fully covering the drain electrode 270, and the first electrode 110 may be arranged to be connected to the exposed portion of the drain electrode 270.

A pixel defining layer 290 including an insulating material may be on the first electrode 110. The pixel defining layer 290 may expose a certain region of the first electrode 110, and the interlayer 130 may be formed in the exposed region of the first electrode 110. The pixel defining layer 290 may be a polyimide-based organic film or a polyacrylic-based organic film. In some embodiments, at least some layers of the interlayer 130 may extend beyond the upper portion of the pixel defining layer 290 to be arranged in the form (or provide) of a common layer.

The second electrode 150 may be on the interlayer 130, and a second capping layer 170 may be additionally formed on the second electrode 150. The second capping layer 170 may be formed to cover the second electrode 150.

The encapsulation portion 300 may be on the second capping layer 170. The encapsulation portion 300 may be arranged on the light-emitting device to protect the light-emitting device from moisture and/or oxygen. The encapsulation portion 300 may include: an inorganic film including silicon nitride (SiNₓ), silicon oxide (SiOₓ), indium tin oxide, indium zinc oxide, or a (e.g., any suitable) combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (e.g., polymethyl methacrylate, polyacrylic acid, and/or the like), an epoxy-based resin (e.g., aliphatic glycidyl ether (AGE), and/or the like), or a (e.g., any suitable) combination thereof; or any combination of the inorganic films and the organic films.

FIG. 3 is a cross-sectional view of a light-emitting apparatus as an example of an electronic apparatus according to one or more embodiments of the present disclosure.

The light-emitting apparatus of FIG. 3 is substantially the same as the light-emitting apparatus of FIG. 2, except that a light-shielding pattern 500 and a functional region 400 are additionally arranged on the encapsulation portion 300. The functional region 400 may be i) a color filter area, ii) a color conversion area, or iii) a combination of the color filter area and the color conversion area. In one or more embodiments, a light-emitting device included in the light-emitting apparatus of FIG. 3 may be a tandem light-emitting device.

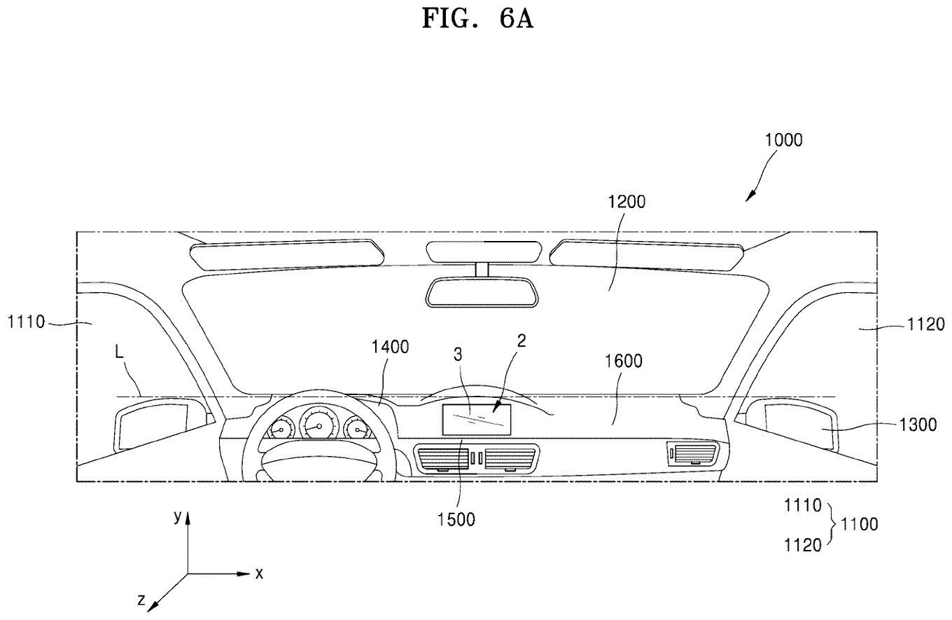

### Description of FIG. 4

FIG. 4 is a schematic perspective view of electronic equipment 1 including the light-emitting device according to one or more embodiments. The electronic equipment 1 may be a device that displays a moving image or still image, a portable electronic equipment, such as a mobile phone, a smart phone, a tablet personal computer (PC), a mobile communication terminal, an electronic notebook, an electronic book, a portable multimedia player (PMP), a navigation, a ultra-mobile PC (UMPC) and/or the like, as well as one or more suitable products, such as a television, a laptop, a monitor, a billboard, or an Internet of things (IOT) device, or a part of such one or more suitable products. In one or more embodiments, the electronic equipment 1 may be a wearable device, such as a smart watch, a watch phone, a glasses-type or kind display, or a head mounted display (HMD), or a part of such a wearable device. However, embodiments of the disclosure are not limited thereto. For example, the electron equipment 1 may include a dashboard of a vehicle, a center information display on a center fascia or dashboard of a vehicle, a room mirror display replacing a side mirror of a vehicle, an entertainment display arranged for the rear seat of a vehicle or arranged on the back of the front seat thereof, a head-up display (HUD) installed at the front of a vehicle or projected on a front window glass, and/or a computer generated hologram augmented reality head up display (CGH AR HUD). FIG. 4 illustrates an embodiment in which the electronic equipment 1 is a smart phone for convenience of explanation.

The electronic equipment 1 may include a display area DA and a non-display area NDA outside the display area DA. A display device of the electronic equipment 1 may implement an image through an array of a plurality of pixels that are two-dimensionally arranged in the display area DA.

The non-display area NDA is an area that does not display an image, and may entirely surround the display area DA. On the non-display area NDA, a driver for providing electrical signals or power to display devices arranged on the display area DA may be arranged. On the non-display area NDA, a pad, which is an area to which an electronic element or a printing circuit board, may be electrically connected may be arranged.

In the electronic equipment 1, a length in the x-axis direction and a length (e.g., a width) in the y-axis direction may be different from each other. In one or more embodiments, as shown in FIG. 4, the length in the x-axis direction may be shorter than the length (e.g., the width) in the y-axis direction. In one or more embodiments, the length in the x-axis direction may be substantially the same as the length (e.g., the width) in the y-axis direction. In one or more embodiments, the length in the x-axis direction may be longer than the length (e.g., the width) in the y-axis direction.

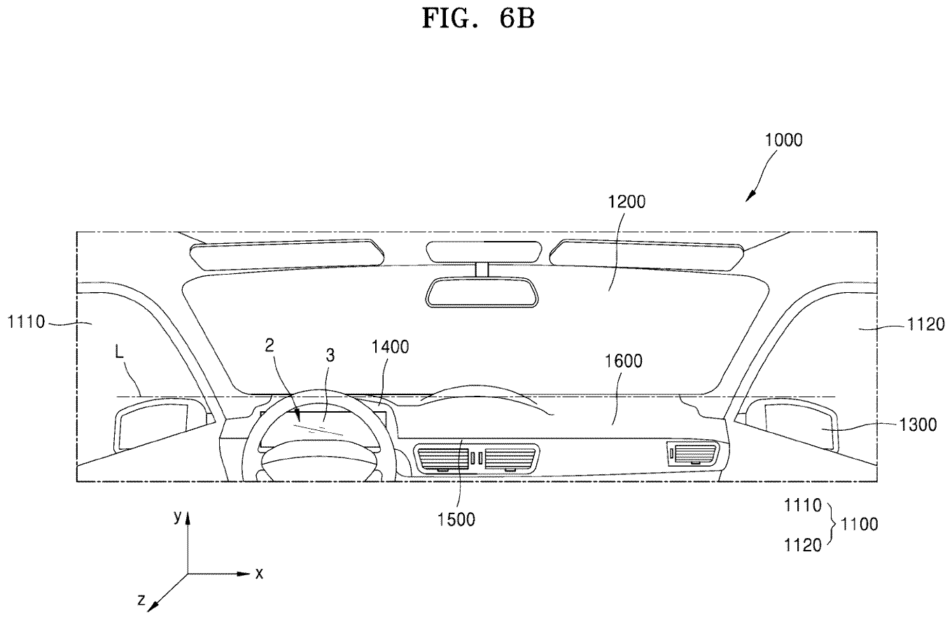

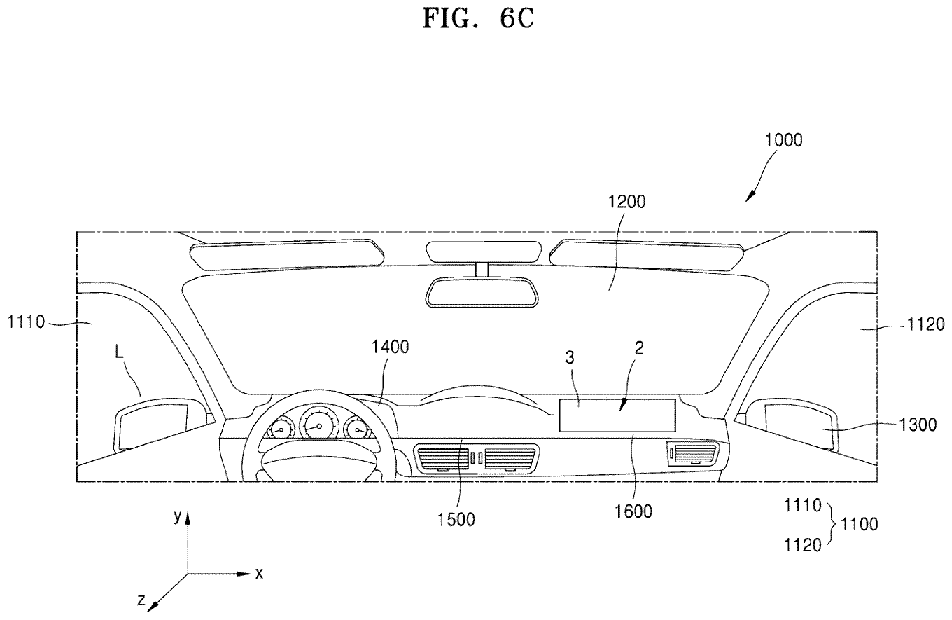

### Descriptions of FIGS. 5 and 6A to 6C

FIG. 5 is a schematic view of an exterior of a vehicle 1000 as an electronic equipment including the light-emitting device according to one or more embodiments of the present disclosure. FIGS. 6A to 6C are each a schematic view of an interior of the vehicle 1000 according to one or more embodiments of the present disclosure.

Referring to FIGS. 5, 6A, 6B, and 6C, the vehicle 1000 may refer to one or more suitable apparatuses for moving an object to be transported, such as a human, an object, or an animal, from a departure point to a destination point. The vehicle 1000 may include a vehicle traveling on a road or a track, a vessel moving over the sea or a river, an airplane flying in the sky utilizing the action of air, and/or the like.

In one or more embodiments, the vehicle 1000 may travel on a road or a track. The vehicle 1000 may move in a set or predetermined direction according to rotation of at least one wheel thereof. For example, the vehicle 1000 may include a three-wheeled or four-wheeled vehicle, a construction machine, a two-wheeled vehicle, a prime mover device, a bicycle, or a train running on a track.

The vehicle 1000 may include a body having an interior and an exterior, and a chassis in which mechanical apparatuses necessary for driving are installed as other parts except for the body. The exterior of the body may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear left and right wheels, and/or the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar arranged between the side window glass 1100 and the front window glass 1200.

The side window glass 1100 may be installed on a side of the vehicle 1000. In some embodiments, the side window glass 1100 may be installed on a door of the vehicle 1000. A plurality of side window glasses 1100 may be provided and may face each other. In some embodiments, the side window glass 1100 may include a first side window glass 1110 and a second side window glass 1120. In some embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced apart from each other in the x-axis direction or the −x-axis direction (the direction opposite the x-axis direction). For example, the first side window glass 1110 and the second side window glass 1120 may be spaced apart from each other in the x-axis direction or the x-axis direction. In other words, an imaginary straight line L connecting the side window glasses 1100 may extend in the x-axis direction or the x-axis direction. For example, an imaginary straight line L connecting the first side window glass 1110 and the second side window glass 1120 to each other may extend in the x direction or the x-axis direction.

The front window glass 1200 may be installed in the front of the vehicle 1000. The front window glass 1200 may be arranged between the side window glasses 1100 facing each other.

The side mirror 1300 may provide a rear view of the vehicle 1000. The side mirror 1300 may be installed on the exterior of the vehicle body. In one embodiment, a plurality of side mirrors 1300 may be provided. Any one of the plurality of side mirrors 1300 may be arranged outside the first side window glass 1110. The other one of the plurality of side mirrors 1300 may be arranged outside the second side window glass 1120.

The cluster 1400 may be arranged in front of the steering wheel. The cluster 1400 may include a tachometer, a speedometer, a coolant thermometer, a fuel gauge turn indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which a plurality of buttons for adjusting an audio device, an air conditioning device, and/or a heater of a seat are arranged. The center fascia 1500 may be arranged on one side of the cluster 1400.

The passenger seat dashboard 1600 may be spaced apart from the cluster 1400 with the center fascia 1500 arranged therebetween. In some embodiments, the cluster 1400 may be arranged to correspond to a driver seat, and the passenger seat dashboard 1600 may be arranged to correspond to a passenger seat. In some embodiments, the cluster 1400 may be adjacent to the first side window glass 1110, and the passenger seat dashboard 1600 may be adjacent to the second side window glass 1120.

In one or more embodiments, the display device 2 may include a display panel 3, and the display panel 3 may display an image. The display device 2 may be arranged inside the vehicle 1000. In some embodiments, the display device 2 may be arranged between the side window glasses 1100 facing each other. The display device 2 may be arranged on at least one of the cluster 1400, the center fascia 1500, or the passenger seat dashboard 1600.

The display device 2 may include an organic light-emitting display device, an inorganic electroluminescent display device, a quantum dot display device, and/or the like. Hereinafter, as the display device 2 according to one or more embodiments, an organic light-emitting display apparatus including the aforementioned light-emitting device will be described as an example, but one or more suitable types (kinds) of the aforementioned display apparatus may be utilized in embodiments of the present disclosure.

Referring to FIG. 6A, in one or more embodiments, the display device 2 may be arranged on the center fascia 1500. In some embodiments, the display device 2 may display navigation information. In some embodiments, the display device 2 may display audio, video, or information regarding vehicle settings.

Referring to FIG. 6B, in one or more embodiments, the display device 2 may be arranged on the cluster 1400. When the display device 2 is arranged on the cluster 1400, the cluster 1400 may display driving information and/or the like through the display device 2. For example, in some embodiments, the cluster 1400 may be implemented digitally. The digital cluster 1400 may display vehicle information and driving information as images. For example, a needle and a gauge of a tachometer and one or more suitable warning light icons may be displayed by a digital signal.

Referring to FIG. 6C, in one or more embodiments, the display device 2 may be arranged on the passenger seat dashboard 1600. The display device 2 may be embedded in the passenger seat dashboard 1600 or arranged on the passenger seat dashboard 1600. In some embodiments, the display device 2 arranged on the passenger seat dashboard 1600 may display an image related to information displayed on the cluster 1400 and/or information displayed on the center fascia 1500. In one or more embodiments, the display device 2 arranged on the passenger seat dashboard 1600 may display information different from information displayed on the cluster 1400 and/or information displayed on the center fascia 1500.

### Manufacturing Method

Layers constituting the hole transport region, the emission layer, and the layers constituting the electron transport region may each be formed in a certain region by utilizing one or more suitable methods such as vacuum deposition, spin coating, casting, Langmuir-Blodgett (LB) deposition, ink-jet printing, laser-printing, laser-induced thermal imaging, and/or the like.

When layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

### DEFINITION OF TERMS

The term “C₃-C₆₀ carbocyclic group” as utilized herein refers to a cyclic group including (e.g., consisting of) carbon only as a ring-forming atom and having three to sixty carbon atoms, and the term “C₁-C₆₀ heterocyclic group” as utilized herein refers to a cyclic group that has 1 to 60 carbon atoms and further has, in addition to carbon, a heteroatom as a ring-forming atom. The C₃-C₆₀ carbocyclic group and the C₁-C₆₀ heterocyclic group may each be: a monocyclic group including (e.g., consisting of) one (e.g., exactly one) ring; or a polycyclic group in which two or more rings are condensed with each other. For example, the number of ring-forming atoms of the C₁-C₆₀ heterocyclic group may be from 3 to 61.

The term “cyclic group” as utilized herein may include both (e.g., simultaneously) the C₃-C₆₀ carbocyclic group and the C₁-C₆₀ heterocyclic group.

The term “π electron-rich C₃-C₆₀ cyclic group” as utilized herein refers to a cyclic group that has 3 to 60 carbon atoms and does not include *—N═*′ as a ring-forming moiety, and the term “π electron-deficient nitrogen-containing C₁-C₆₀ heterocyclic group” as utilized herein refers to a heterocyclic group that has 1 to 60 carbon atoms and includes *—N=*′ as a ring-forming moiety.

For example,
the C₃-C₆₀ carbocyclic group may be i) Group T1 or ii) a condensed cyclic group in which two or more of Group T1 are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which at least two of Group T2 (e.g., at least two of the groups in Group T2) are condensed with each other, or iii) a condensed cyclic group in which at least one Group T2 and at least one Group T1 are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T3 and at least one Group T1 are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),
the π electron-deficient nitrogen-containing C₁-C₆₀ heterocyclic group may be i) Group T4, ii) a condensed cyclic group in which two or more of Group T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
Group T3 may be a furan group, a thiophene group, a 1H-pyrrole group, a silole group, or a borole group, and
Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.
The term “cyclic group,” “C₃-C₆₀ carbocyclic group,” “C₁-C₆₀ heterocyclic group,” “π electron-rich C₃-C₆₀ cyclic group,” or “π electron-deficient nitrogen-containing C₁-C₆₀ heterocyclic group” as utilized herein may refer to a group condensed to any cyclic group that is condensed with an another cyclic group (e.g., a benzo group, a naphtho group, and/or the like), a monovalent group, or a polyvalent group (e.g., a divalent group, a trivalent group, a tetravalent group, and/or the like) according to the structure of a formula for which the corresponding term is utilized. For example, the “benzene group” may be a benzo group, a phenyl group, a phenylene group, and/or the like, which may be easily understood by one of ordinary skill in the art according to the structure of a formula including the “benzene group.”

Depending on context, in the present disclosure, a divalent group may refer or be a polyvalent group (e.g., trivalent, tetravalent, etc., and not just divalent) per, e.g., the structure of a formula in connection with which of the terms are utilized.

Non-limiting examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Non-limiting examples of the divalent C₃-C₆₀ carbocyclic group and the divalent C₁-C₆₀ heterocyclic group are a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as utilized herein refers to a linear or branched aliphatic hydrocarbon monovalent group that has 1 to 60 carbon atoms, and non-limiting examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as utilized herein refers to a divalent group having substantially the same structure as the C₁-C₆₀ alkyl group.

The term “C₂-C₆₀ alkenyl group” as utilized herein refers to a monovalent hydrocarbon group having at least one carbon-carbon double bond in the middle or at the terminus of a C₂-C₆₀ alkyl group, and non-limiting examples thereof may include an ethenyl group, a propenyl group, a butenyl group, and/or the like. The term “C₂-C₆₀ alkenylene group” as utilized herein refers to a divalent group having substantially the same structure as the C₂-C₆₀ alkenyl group.

The term “C₂-C₆₀ alkynyl group” as utilized herein refers to a monovalent hydrocarbon group having at least one carbon-carbon triple bond in the middle or at the terminus of a C₂-C₆₀ alkyl group, and non-limiting examples thereof may include an ethynyl group, a propynyl group, and/or the like. The term “C₂-C₆₀ alkynylene group” as utilized herein refers to a divalent group having substantially the same structure as the C₂-C₆₀ alkynyl group.

The term “C₁-C₆₀ alkoxy group” as utilized herein refers to a monovalent group represented by —OA₁₀₁ (wherein A₁₀₁ is a C₁-C₆₀ alkyl group), and non-limiting examples thereof may include a methoxy group, an ethoxy group, an isopropyloxy group, and/or the like.

The term “C₃-C₁₀ cycloalkyl group” as utilized herein refers to a monovalent saturated hydrocarbon cyclic group having 3 to 10 carbon atoms, and non-limiting examples thereof may include a cyclopropyl group, a cyclobutyl group, a cyclopentyl group, a cyclohexyl group, a cycloheptyl group, a cyclooctyl group, an adamantanyl group, a norbornyl group (or bicyclo[2.2.1]heptyl group), a bicyclo[1.1.1]pentyl group, a bicyclo[2.1.1]hexyl group, a bicyclo[2.2.2]octyl group, and/or the like. The term “C₃-C₁₀ cycloalkylene group” as utilized herein refers to a divalent group having substantially the same structure as the C₃-C₁₀ cycloalkyl group.

The term “C₁-C₁₀ heterocycloalkyl group” as utilized herein refers to a monovalent cyclic group of 1 to 10 carbon atoms, further including, in addition to carbon atoms, at least one heteroatom as ring-forming atoms, and non-limiting examples thereof may include a 1,2,3,4-oxatriazolidinyl group, a tetrahydrofuranyl group, a tetrahydrothiophenyl group, and/or the like. The term “C₁-C₁₀ heterocycloalkylene group” as utilized herein refers to a divalent group having substantially the same structure as the C₁-C₁₀ heterocycloalkyl group.

The term “C₃-C₁₀ cycloalkenyl group” as utilized herein refers to a monovalent cyclic group that 3 to 10 carbon atoms, at least one carbon-carbon double bond in the ring thereof, and no aromaticity, and non-limiting examples thereof may include a cyclopentenyl group, a cyclohexenyl group, a cycloheptenyl group, and/or the like. The term “C₃-C₁₀ cycloalkenylene group” as utilized herein refers to a divalent group having substantially the same structure as the C₃-C₁₀ cycloalkenyl group.

The term “C₁-C₁₀ heterocycloalkenyl group” as utilized herein refers to a monovalent cyclic group of 1 to 10 carbon atoms, further including, in addition to carbon atoms, at least one heteroatom as ring-forming atoms and at least one double bond in the cyclic structure thereof. Non-limiting examples of the C₁-C₁₀ heterocycloalkenyl group may include a 4,5-dihydro-1,2,3,4-oxatriazolyl group, a 2,3-dihydrofuranyl group, a 2,3-dihydrothiophenyl group, and/or the like. The term “C₁-C₁₀ heterocycloalkenylene group” as utilized herein refers to a divalent group having substantially the same structure as the C₁-C₁₀ heterocycloalkenyl group.

The term “C₆-C₆₀ aryl group” as utilized herein refers to a monovalent group having a carbocyclic aromatic system of 6 to 60 carbon atoms, and the term “C₆-C₆₀ arylene group” as utilized herein refers to a divalent group having a carbocyclic aromatic system of 6 to 60 carbon atoms. Non-limiting examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and/or the like. When the C₆-C₆₀ aryl group and the C₆-C₆₀ arylene group each include two or more rings, the rings may be condensed with each other.

The term “C₁-C₆₀ heteroaryl group” as utilized herein refers to a monovalent group having a heterocyclic aromatic system of 1 to 60 carbon atoms, further including, in addition to carbon atoms, at least one heteroatom as ring-forming atoms. The term “C₁-C₆₀ heteroarylene group” as utilized herein refers to a divalent group having a heterocyclic aromatic system of 1 to 60 carbon atoms, further including, in addition to carbon atoms, at least one heteroatom as ring-forming atoms. Non-limiting examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and/or the like. When the C₁-C₆₀ heteroaryl group and the C₁-C₆₀ heteroarylene group each include two or more rings, the rings may be condensed with each other.

The term “monovalent non-aromatic condensed polycyclic group” as utilized herein refers to a monovalent group (for example, having 8 to 60 carbon atoms) having two or more rings condensed to each other, only carbon atoms as ring-forming atoms, and no aromaticity in the entire molecular structure when considered as a whole. Non-limiting examples of the monovalent non-aromatic condensed polycyclic group may include an indenyl group, a fluorenyl group, a spiro-bifluorenyl group, a benzofluorenyl group, an indenophenanthrenyl group, an indeno anthracenyl group, and/or the like. The term “divalent non-aromatic condensed polycyclic group” as utilized herein refers to a divalent group having substantially the same structure as the monovalent non-aromatic condensed polycyclic group described above.

The term “monovalent non-aromatic hetero-condensed polycyclic group” as utilized herein refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure when considered as a whole. Non-limiting examples of the monovalent non-aromatic hetero-condensed polycyclic group are a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as utilized herein refers to a divalent group having substantially the same structure as the monovalent non-aromatic condensed heteropolycyclic group.

The term “C₆-C₆₀ aryloxy group” as utilized herein indicates —OA₁₀₂ (wherein A₁₀₂ is a C₆-C₆₀ aryl group), and the term “C₆-C₆₀ arylthio group” as utilized herein indicates —SA₁₀₃ (wherein A₁₀₃ is a C₆-C₆₀ aryl group).

The term “C₇-C₆₀ arylalkyl group” as utilized herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as utilized herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as utilized herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a (e.g., any suitable) combination thereof;
a C₃-C₆₀carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a (e.g., any suitable) combination thereof;
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), or
a (e.g., any suitable) combination thereof.
Q₁ to Q₃, Q₁₁ to Q₁₃, Q₂₁ to Q₂₃, and Q₃₁ to Q₃₃ in the present disclosure may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or a (e.g., any suitable) combination thereof.

The term “heteroatom” as utilized herein refers to any atom other than a carbon atom. Non-limiting examples of the heteroatom may include O, S, N, P, Si, B, Ge, Se, and a (e.g., any suitable) combination thereof.

The term “transition metal” as utilized herein may include Hf, Ta, W, Re, Os, Ir, Pt, Au, and/or the like.

“Ph” as utilized herein refers to a phenyl group, “Me” as utilized herein refers to a methyl group, “Et” as utilized herein refers to an ethyl group, “tert-Bu” or “Bu^{t}” as utilized herein refers to a tert-butyl group, and “OMe” as utilized herein refers to a methoxy group.

The term “biphenyl group” as utilized herein refers to “a phenyl group substituted with a phenyl group.” In some embodiments, the “biphenyl group” may be a substituted phenyl group having a C₆-C₆₀ aryl group as a substituent.

The term “terphenyl group” as utilized herein refers to “a phenyl group substituted with a biphenyl group.” In some embodiments, the “terphenyl group” may be a substituted phenyl group having, as a substituent, a C₆-C₆₀ aryl group substituted with a C₆-C₆₀ aryl group.

Unless otherwise specified, *, *′, and *″ each indicate a binding site to a neighboring atom in the corresponding formula or moiety.

Hereinafter, compounds according to embodiments and light-emitting devices according to embodiments will be described in more detail with reference to the following Synthesis Examples and Examples. The wording “B was utilized instead of A” utilized in describing Synthesis Examples refers to that an identical molar equivalent of B was utilized in place of A.

### EXAMPLES

### Synthesis Example 1: Synthesis of Compound 26

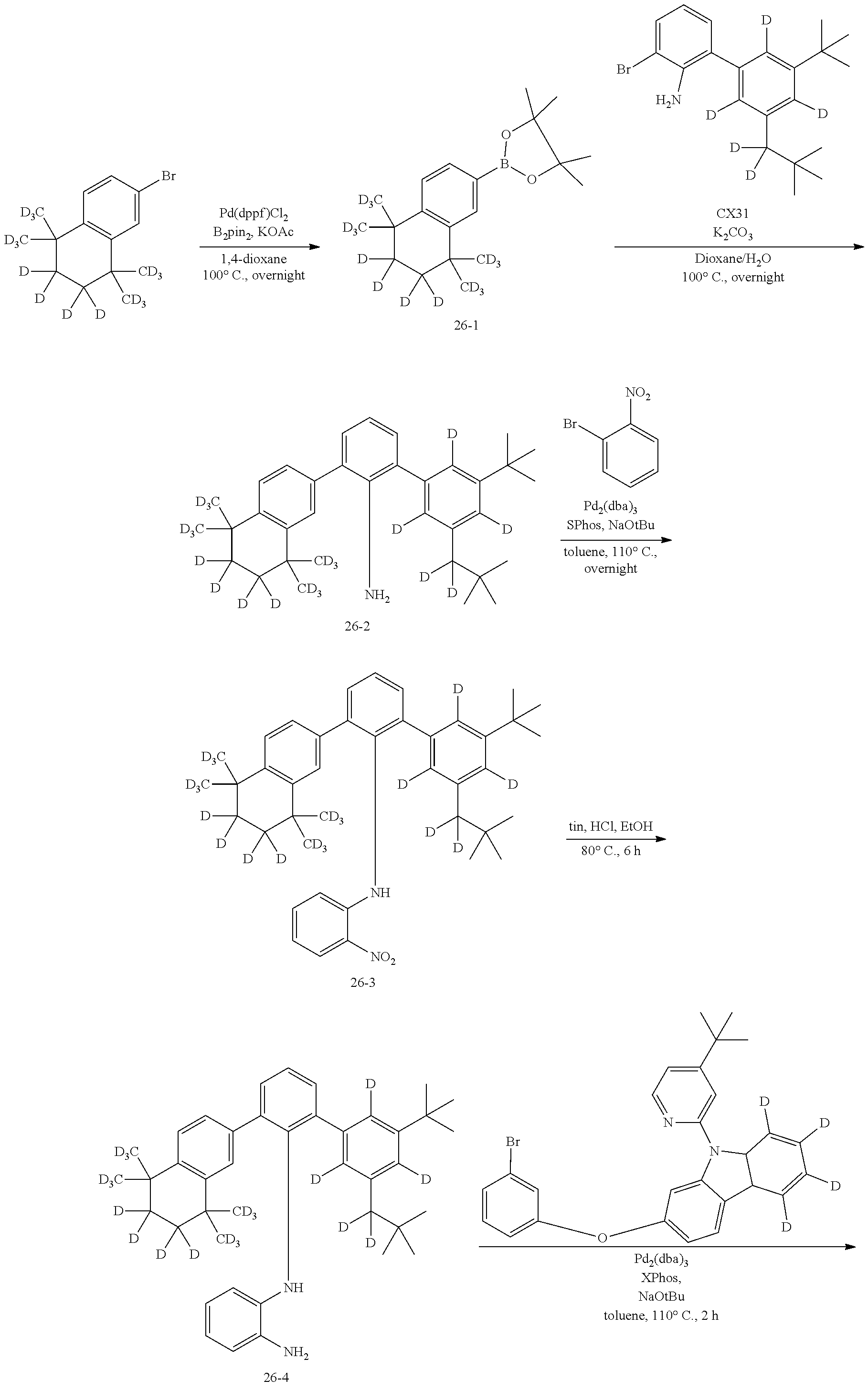

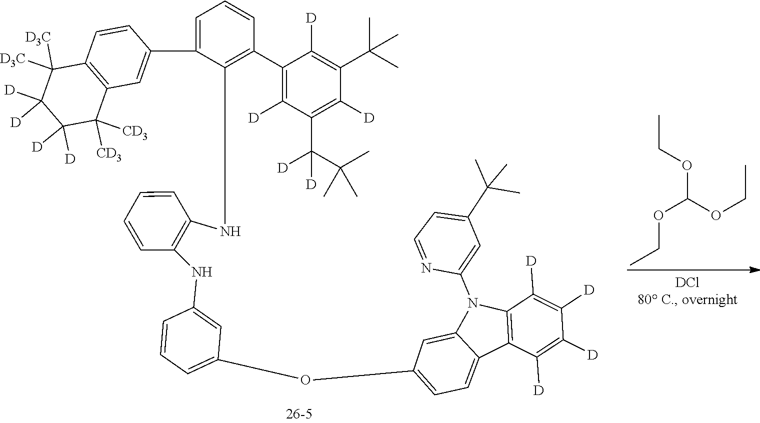

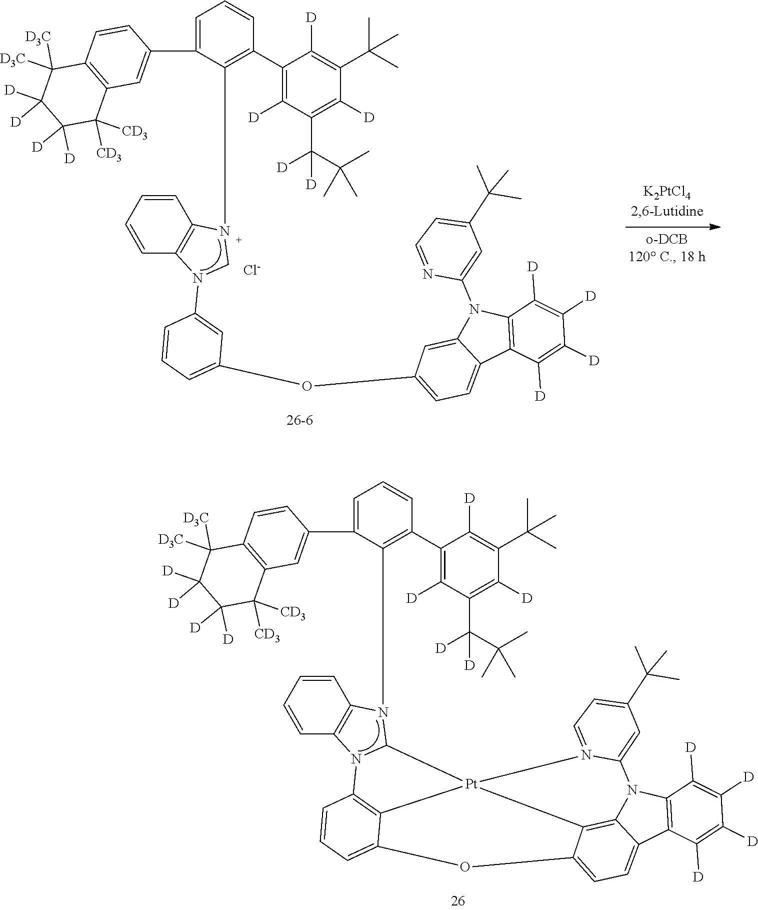

### Synthesis of Intermediate 26-1

6-bromo-1,1,4,4-tetrakis(methyl-d₃)-1,2,3,4-tetrahydronaphthalene-2,2,3,3-d₄ (1.0 eq), [1,1′-bis(diphenylphosphino)ferrocene]dichloropalladium(II) (Pd(dppf)Cl₂) (0.05 eq), bis(pinacolato)diboron (B₂pin₂) (1.5 eq), and potassium acetate (KOAc) (3 eq) were mixed with 1,4-dioxane, and then stirred at 100° C. for 24 hours. After cooling the resulting product to room temperature, the solvent was removed therefrom by distillation under reduced pressure at 8 mbar, and an extraction process was performed thereon three times by utilizing methylene chloride (MC) and water to obtain an organic layer. The organic layer thus obtained was dried over magnesium sulfate, concentrated, and then subjected to column chromatography (MC/hexane (Hex) as an eluent), so as to synthesize Intermediate 26-1 (yield of 78%).

### Synthesis of Intermediate 26-2

Intermediate 26-1 (1.0 eq), 3-bromo-3′-(tert-butyl)-5′-(2,2-dimethylpropyl-1,1-d₂)-[1,1′-biphenyl]-2′,4′,6′-d₃₋₂-amine (1.0 eq), chlorophenylallyl[1,3-bis(2,6-diisopropylphenyl)imidazol-2-ylidene]palladium (II) (CX31 Umicore) (0.05 eq), and potassium carbonate (3,0 eq), were mixed with a mixture containing 1,4-dioxane and H₂O at a volume ratio of 3:1, and then stirred at 100° C. for 24 hours. After cooling the resulting product to room temperature, the solvent was removed therefrom by distillation under reduced pressure at 8 mbar, and an extraction process was performed thereon three times by utilizing MC and water to obtain an organic layer. The organic layer thus obtained was dried over magnesium sulfate, concentrated, and then subjected to column chromatography (MC/Hex as an eluent), so as to synthesize Intermediate 26-2 (yield of 68%).

### Synthesis of Intermediate 26-3

Intermediate 26-2 (1.0 eq), 1-bromo-2-nitrobenzene (2 eq), 2-dicyclohexylphosphino-2′,6′-dimethoxybiphenyl (Sphos, 0.10 eq), tris(dibenzylideneacetone)dipalladium(0) (Pd₂(dba)₃, 0.05 eq), and sodium tert-butoxide (NaOtBu, 3 eq) were mixed with toluene, and then stirred at 110° C. for 24 hours to obtain a reaction product. After cooling the reaction product to room temperature, the solvent was removed therefrom by distillation under reduced pressure at 8 mbar, and an extraction process was performed thereon three times by utilizing MC and water to obtain an organic layer. The organic layer thus obtained was dried over magnesium sulfate, concentrated, and then subjected to column chromatography (MC/Hex as an eluent), so as to synthesize Intermediate 26-3 (yield of 83%).

### Synthesis of Intermediate 26-4

Intermediate 26-3 (1.0 eq) and tin (5 eq) were mixed and stirred with ethanol (EtOH), and hydrogen chloride (12 M) was injected thereto. The mixed solution was then stirred at 80° C. for 6 hours. After cooling the resulting product to room temperature, the solvent was removed therefrom by distillation under reduced pressure at 8 mbar, and an extraction process was performed thereon three times by utilizing MC and water to obtain an organic layer. The organic layer thus obtained was dried over magnesium sulfate, concentrated, and then subjected to column chromatography (MC/Hex as an eluent), so as to synthesize Intermediate 26-4 (yield of 85%).

### Synthesis of Intermediate 26-5

Intermediate 26-4 (1.0 eq), 2-(3-bromophenoxy)-9-(4-tert-butyl-pyridin-2-yl)-9H-carbazole-5,6,7,8-d₄ (1.0 eq), Pd₂(dba)₃ (tris(dibenzylideneacetone)dipalladium(0), 0.05 eq), Xphos (2-dicyclohexylphosphino-2′,4′,6′-triisopropylbiphenyl, 0.10 eq), and sodium tert-butoxide (2.0 eq) were dissolved in toluene (0.1 M), and then stirred at 110° C. for 2 hours. After cooling the resulting product to room temperature, the solvent was removed therefrom by distillation under reduced pressure at 8 mbar, and an extraction process was performed thereon three times by utilizing MC and water to obtain an organic layer. The organic layer thus obtained was dried over magnesium sulfate, concentrated, and then subjected to column chromatography (MC:Hex as an eluent), so as to synthesize Intermediate 26-5 (yield of 67%).

### Synthesis of Intermediate 26-6

Intermediate 26-5 (1.0 eq) was dissolved in triethyl orthoformate (30 eq), and 37% DCI (1.5 eq) was added thereto. The mixed solution was then stirred at 80° C. for 24 hours. After cooling the resulting product to room temperature, the triethyl orthoformate was concentrated and removed. Then, an extraction process was performed thereon three times by utilizing MC and water to obtain an organic layer. The organic layer thus obtained was dried over magnesium sulfate, concentrated, and then subjected to column chromatography (MC:methanol as an eluent), so as to synthesize Intermediate 26-6 (yield of 77%).

### Synthesis of Compound 26

Intermediate 26-6 (1.0 eq), potassium platinum(II) chloride (K₂PtCl₄) (1.1 eq), and 2,6-lutidine (4.0 eq) were dissolved in 1,2-dichlorobenzene (o-DCB, 0.05 M), and then stirred under nitrogen conditions at 120° C. for 18 days. After cooling the resulting product to room temperature, the 1,2-dichlorobenzene was concentrated and removed. Then, an extraction process was performed thereon three times by utilizing dichloromethane and water to obtain an organic layer. The organic layer thus obtained was dried over magnesium sulfate, concentrated, and then subjected to column chromatography (MC:Hex as an eluent), so as to synthesize Compound 26 (yield of 48%).

ESI-LCMS: [M]+: C₆₉H₄₅D₂₅N₄OPt, 1189.80

### Synthesis Example 2: Synthesis of Compound 70

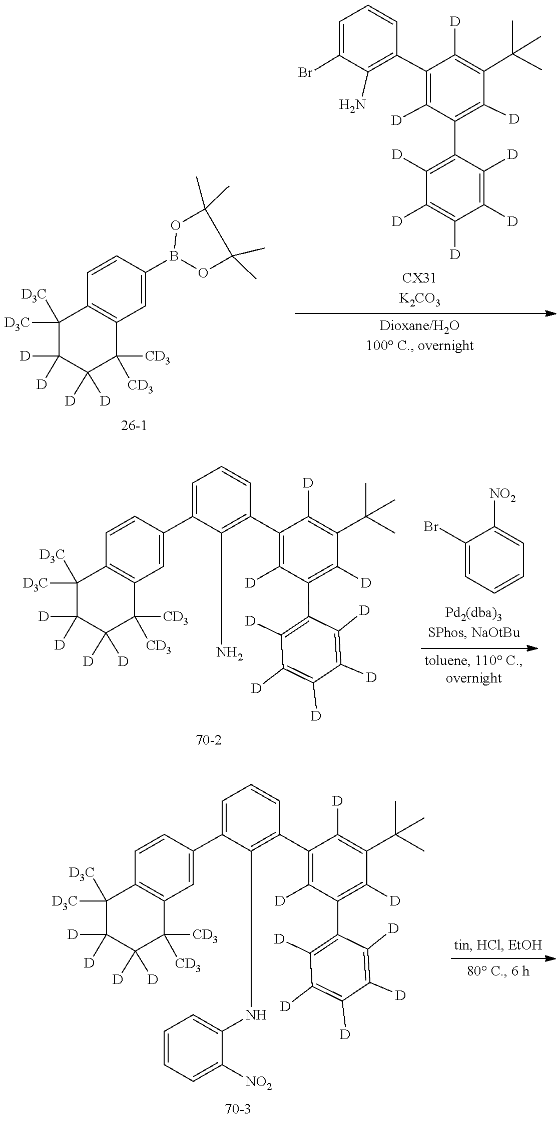

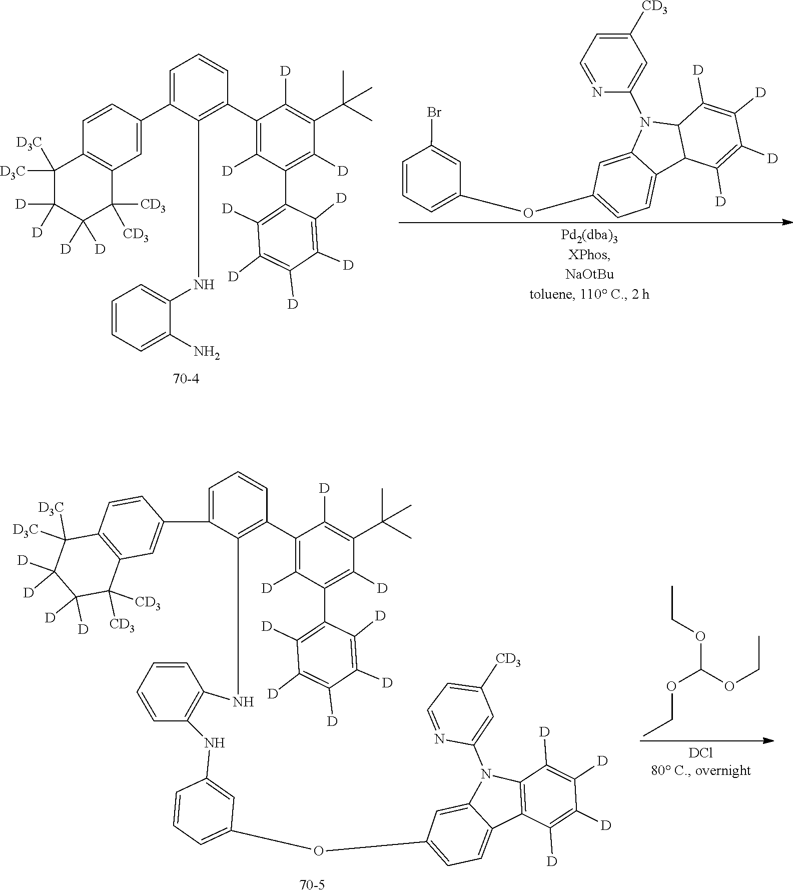

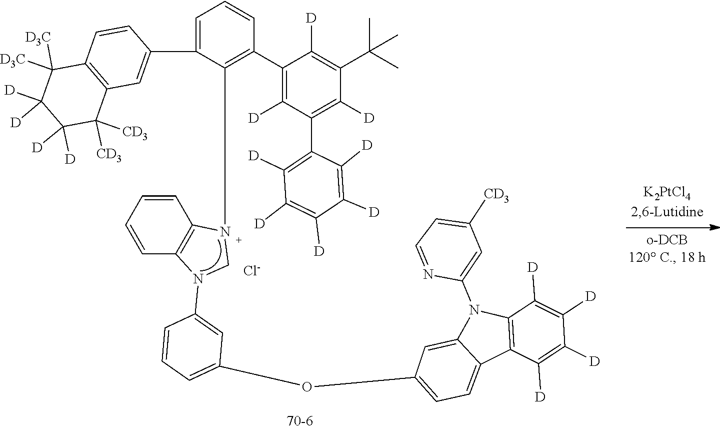 [SMILES: [2H]c1c([2H])c([2H])c(-c2c([2H])c(-c3cccc(-c4ccc5c(c4)C(C([2H])([2H])[2H])(C([2H])([2H])[2H])C([2H])([2H])C([2H])([2H])C5(C([2H])([2H])[2H])C([2H])([2H])[2H])c3N3CN(c4cccc(Oc5ccc6c7c([2H])c([2H])c([2H])c([2H])c7n(-c7cc(C([2H])([2H])[2H])ccn7)c6c5)c4)c4ccccc43)c([2H])c(C(C)(C)C)c2[2H])c([2H])c1[2H] ; [Cl-]]

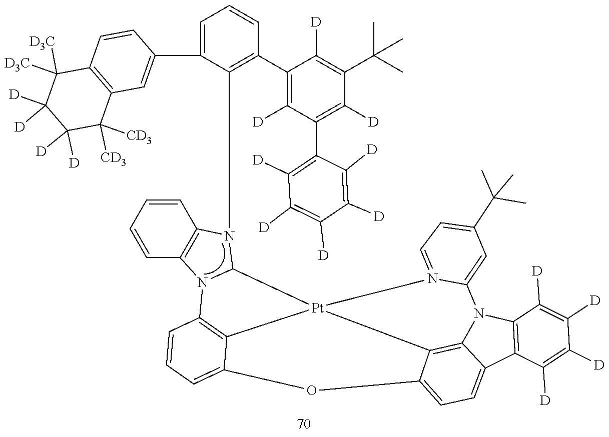

### Synthesis of Intermediate 70-2

Intermediate 70-2 was synthesized in substantially the same manner as in the synthesis of Intermediate 26-2 in Synthesis Example 1, except that 3-bromo-5′-(tert-butyl)-[1,1′:3′,1″-terphenyl]-2′,2″,3″,4′,4″,5″,6′,6″-de-2-amine was utilized instead of 3-bromo-3′-(tert-butyl)-5′-(2,2-dimethylpropyl-1,1-d₂)-[1,1′-biphenyl]-2′,4′,6′-d₃₋₂-amine.

### Synthesis of Intermediate 70-3

Intermediate 70-3 was synthesized in substantially the same manner as in the synthesis of Intermediate 26-3 in Synthesis Example 1, except that Intermediate 70-2 was utilized instead of Intermediate 26-2.

### Synthesis of Intermediate 70-4

Intermediate 70-4 (yield of 61%) was synthesized in substantially the same manner as in the synthesis of Intermediate 26-4 in Synthesis Example 1, except that Intermediate 70-3 was utilized instead of Intermediate 26-3.

### Synthesis of Intermediate 70-5

Intermediate 70-5 was synthesized in substantially the same manner as in the synthesis of Intermediate 26-5 in Synthesis Example 1, except that Intermediate 70-4 and 2-(3-bromophenoxy)-9-(4-(methyl-d3)pyridin-2-yl)-9H-carbazole-5,6,7,8-d₄ were utilized instead of Intermediate 26-4 and 2-(3-bromophenoxy)-9-(4-tert-butyl-pyridin-2-yl)-9H-carbazole-5,6,7,8-d₄, respectively.

### Synthesis of Intermediate 70-6

Intermediate 70-6 was synthesized in substantially the same manner as in the synthesis of Intermediate 26-6 in Synthesis Example 1, except that Intermediate 70-5 was utilized instead of Intermediate 26-5.

### Synthesis of Compound 70

Compound 70 (yield of 68%) was synthesized in substantially the same manner as in the synthesis of Compound 26 in Synthesis Example 1, except that Intermediate 70-6 was utilized instead of Intermediate 26-6.

ESI-LCMS: [M]+: C₆₇H₂₇D₃₁N₄₀Pt, 1159.40

### Synthesis Example 3: Synthesis of Compound 124

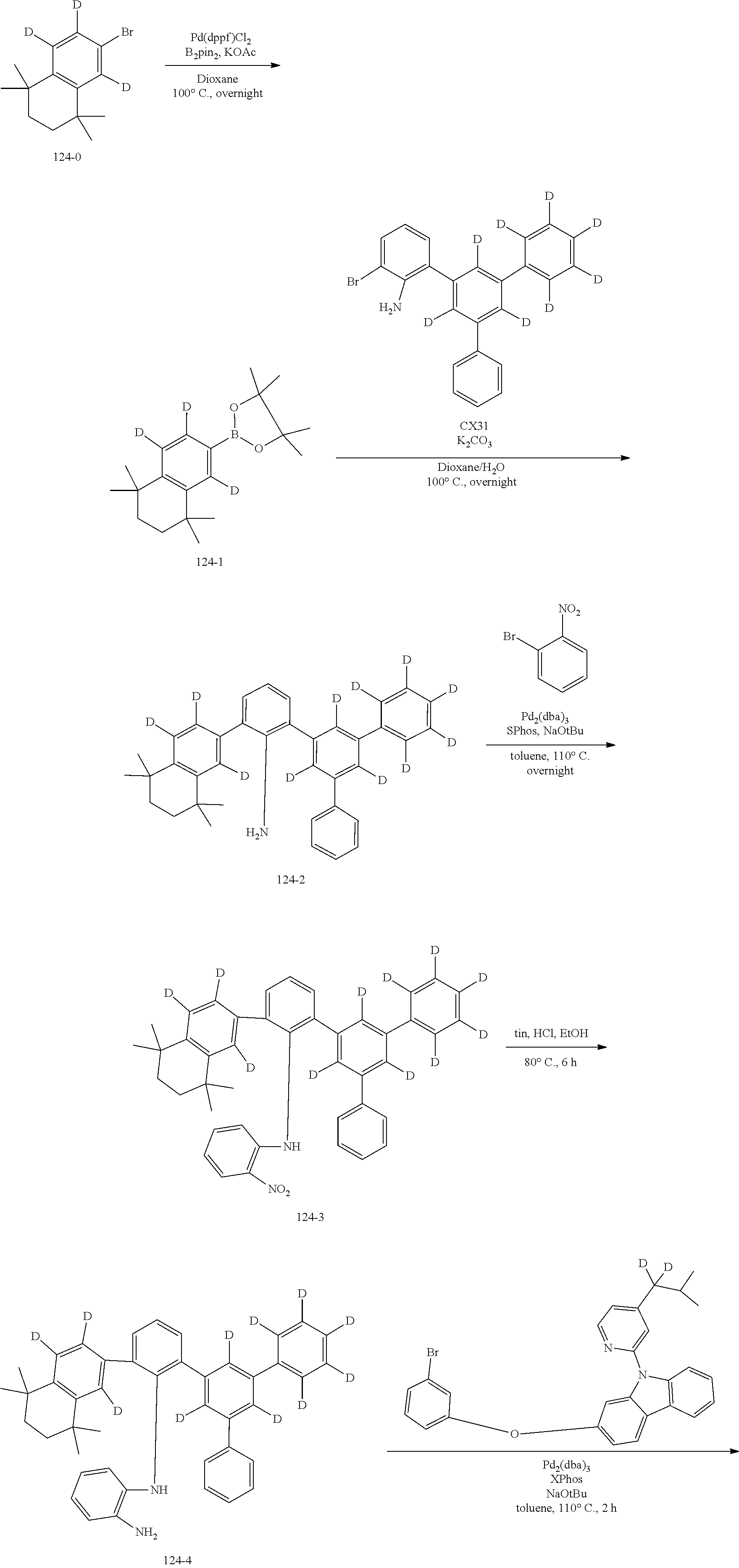

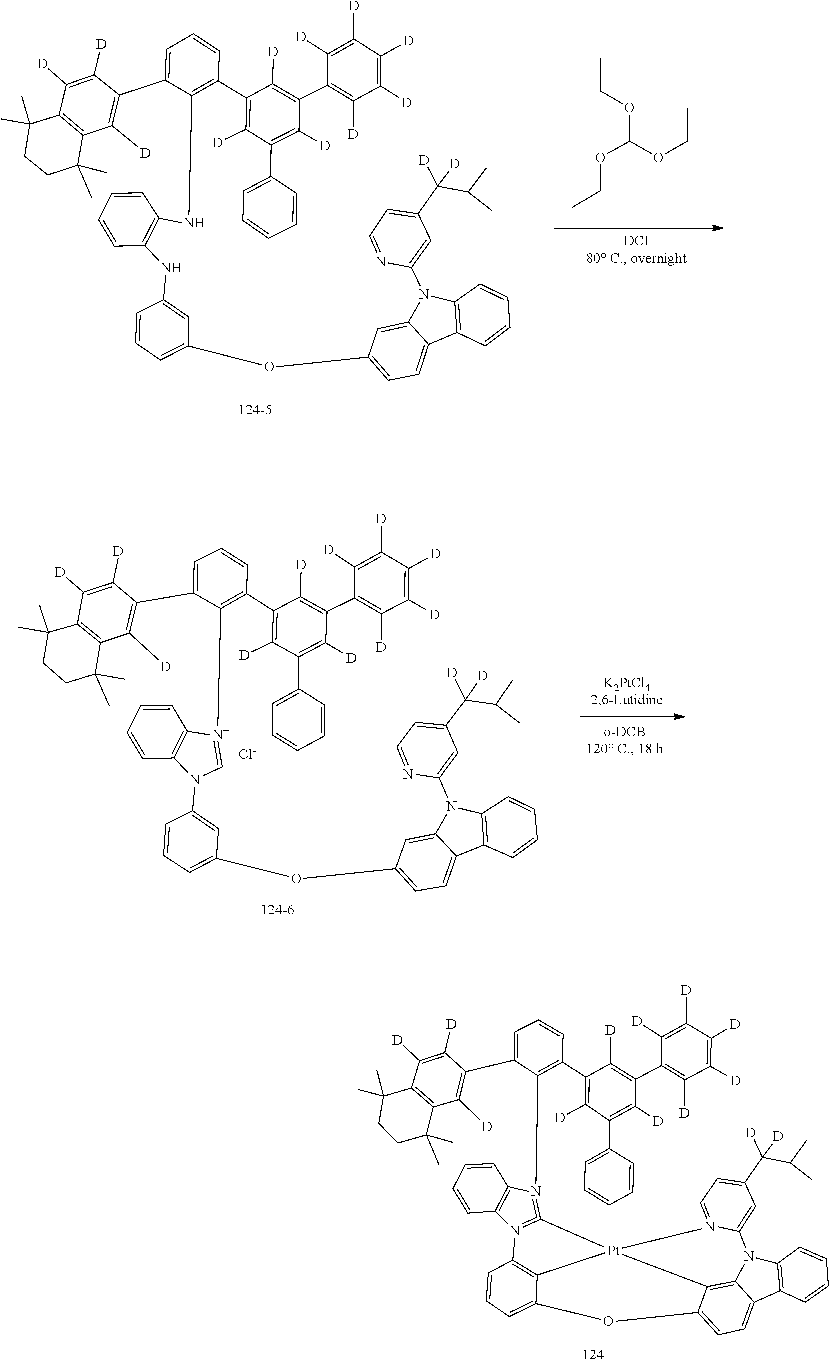

### Synthesis of Intermediate 124-1

Intermediate 124-1 was synthesized in substantially the same manner as in the synthesis of Intermediate 26-1 in Synthesis Example 1, except that Intermediate 124-0 was utilized instead of 6-bromo-1,1,4,4-tetrakis(methyl-d₃)-1,2,3,4-tetrahydronaphthalene-2,2,3,3-d₄.

### Synthesis of Intermediate 124-2

Intermediate 124-2 was synthesized in substantially the same manner as in the synthesis of Intermediate 26-2 in Synthesis Example 1, except that Intermediate 124-1 and 3-bromo-5′-phenyl-[1,1′:3′,1″-terphenyl]-2′,2″,3″,4′,4″,5″,6′,6″-d₈₋₂-amine were utilized instead of Intermediate 26-1 and 3-bromo-3′-(tert-butyl)-5′-(2,2-dimethylpropyl-1,1-d₂)-[1,1′-biphenyl]-2′,4′,6′-d₃-2-amine, respectively.

### Synthesis of Intermediate 124-3

Intermediate 124-3 was synthesized in substantially the same manner as in the synthesis of Intermediate 26-3 in Synthesis Example 1, except that Intermediate 124-2 was utilized instead of Intermediate 26-2.

### Synthesis of Intermediate 124-4

Intermediate 124-4 (yield of 68%) was synthesized in substantially the same manner as in the synthesis of Intermediate 26-4 in Synthesis Example 1, except that Intermediate 124-3 was utilized instead of Intermediate 26-3.

### Synthesis of Intermediate 124-5

Intermediate 124-5 was synthesized in substantially the same manner as in the synthesis of Intermediate 26-5 in Synthesis Example 1, except that Intermediate 124-4 and 2-(3-bromophenoxy)-9-(4-(2-methylpropyl-1,1-d₂)pyridin-2-yl)-9H-carbazole were utilized instead of Intermediate 26-4 and 2-(3-bromophenoxy)-9-(4-tert-butyl-pyridin-2-yl)-9H-carbazole-5,6,7,8-d₄, respectively.

### Synthesis of Intermediate 124-6

Intermediate 124-6 was synthesized in substantially the same manner as in the synthesis of Intermediate 26-6 in Synthesis Example 1, except that Intermediate 124-5 was utilized instead of Intermediate 26-5.

### Synthesis of Compound 124

Compound 124 (yield of 53%) was synthesized in substantially the same manner as in the synthesis of Compound 26 in Synthesis Example 1, except that Intermediate 124-6 was utilized instead of Intermediate 26-6.

ESI-LCMS: [M]+: C₇₂H₄₇D₁₃N₄OPt, 1203.30

### Synthesis Example 4: Synthesis of Compound 134

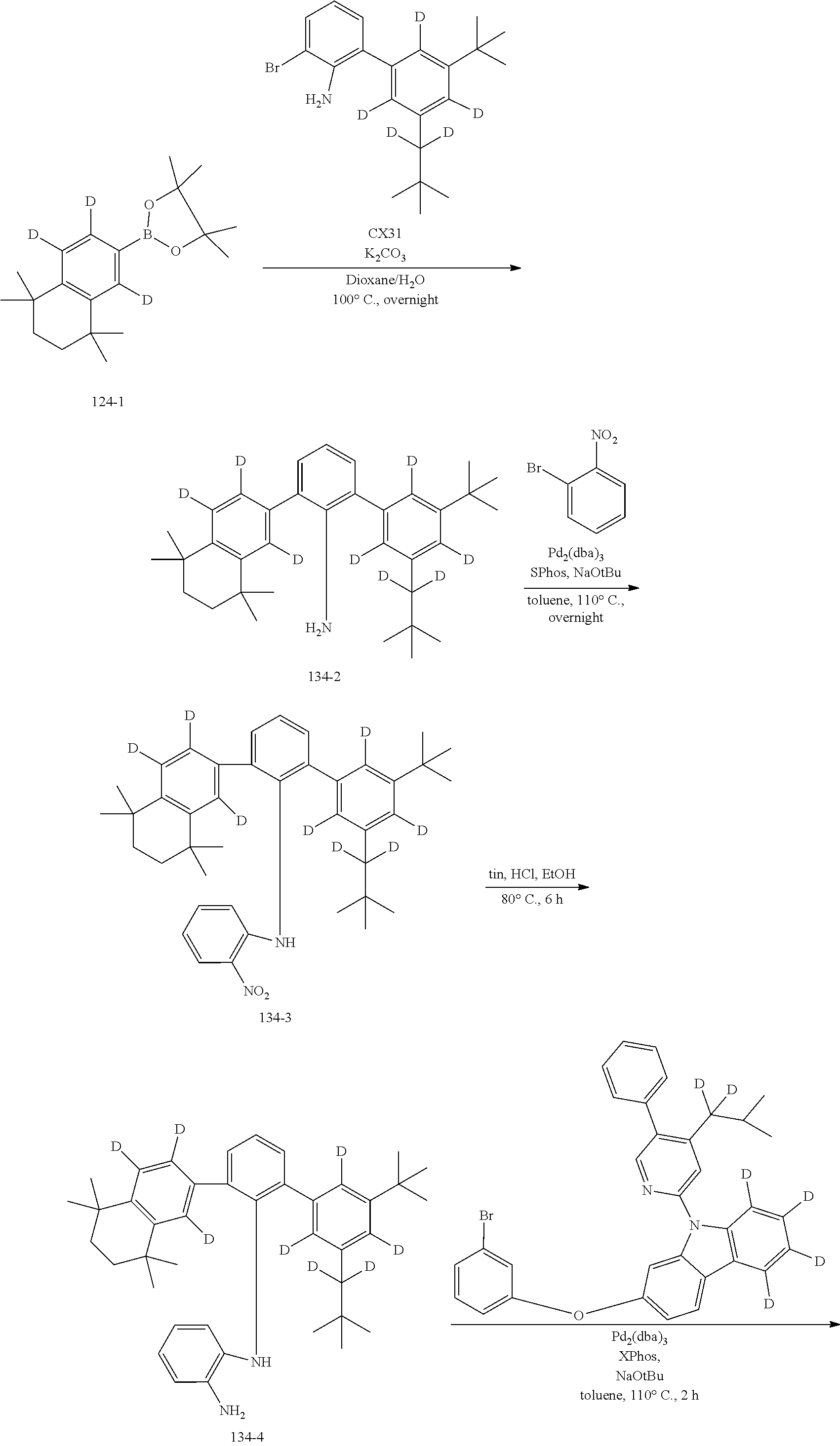

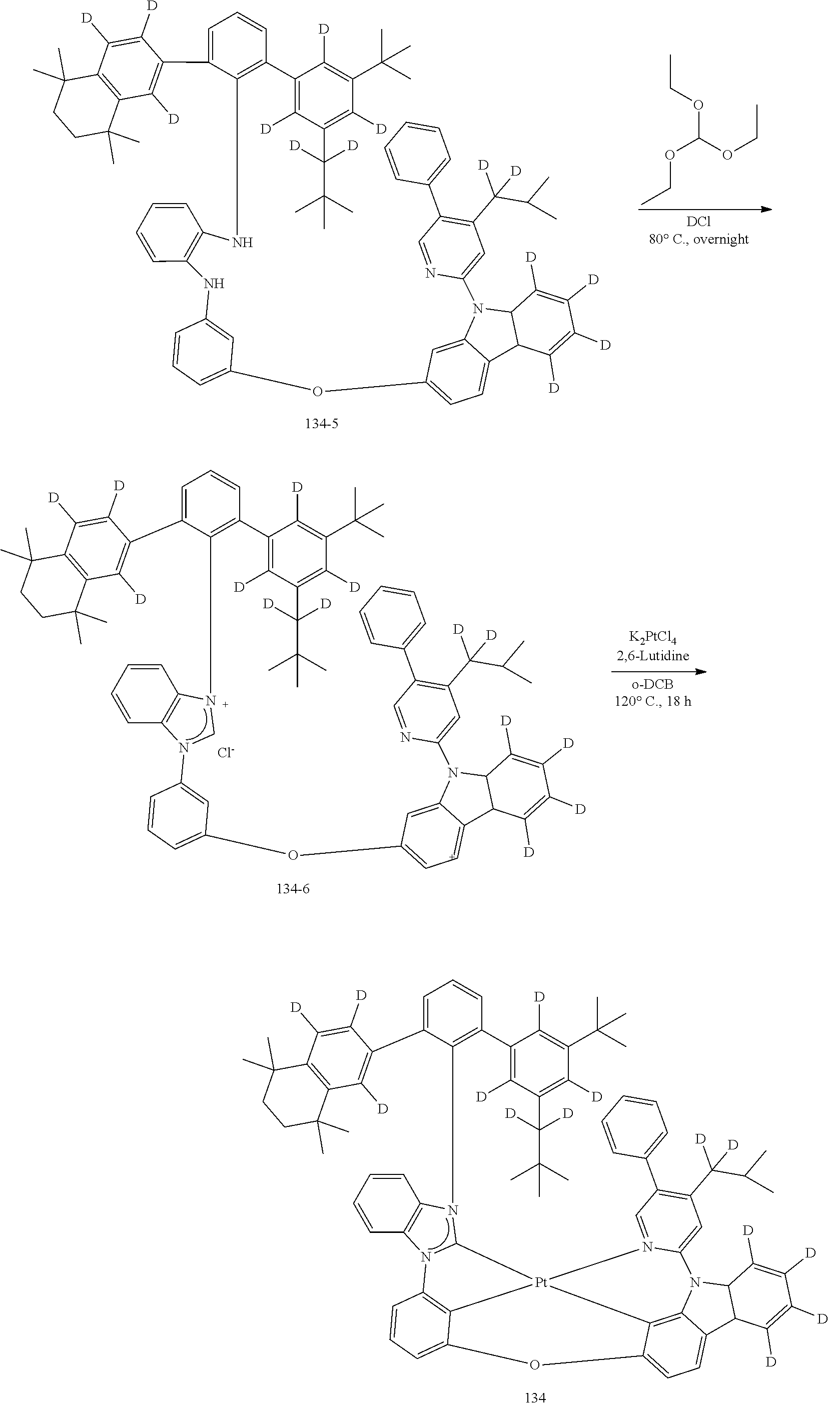

### Synthesis of Intermediate 134-2

Intermediate 134-2 was synthesized in substantially the same manner as in the synthesis of Intermediate 26-2 in Synthesis Example 1, except that Intermediate 124-1 and 3-bromo-3′-(tert-butyl)-5′-(2,2-dimethylpropyl-1,1-d₂)-[1,1′-biphenyl]-2′,4′,6′-d₃₋₂-amine were utilized instead of Intermediate 26-1 and 3-bromo-3′-(tert-butyl)-5′-(2,2-dimethylpropyl-1,1-d₂)-[1,1′-biphenyl]-2′,4′,6′-d₃-2-amine, respectively.

### Synthesis of Intermediate 134-3

Intermediate 134-3 was synthesized in substantially the same manner as in the synthesis of Intermediate 26-3 in Synthesis Example 1, except that Intermediate 134-2 was utilized instead of Intermediate 26-2.

### Synthesis of Intermediate 134-4

Intermediate 134-4 (yield of 70%) was synthesized in substantially the same manner as in the synthesis of Intermediate 26-4 in Synthesis Example 1, except that Intermediate 134-3 was utilized instead of Intermediate 26-3.

### Synthesis of Intermediate 134-5

Intermediate 134-5 was synthesized in substantially the same manner as in the synthesis of Intermediate 26-5 in Synthesis Example 1, except that Intermediate 134-4 and 2-(3-bromophenoxy)-9-(4-(2-methylpropyl-1,1-d₂)-5-phenylpyridin-2-yl)-9H-carbazole-5,6,7,8-d₄ were utilized instead of Intermediate 26-4 and 2-(3-bromophenoxy)-9-(4-tert-butyl-pyridin-2-yl)-9H-carbazole-5,6,7,8-d₄, respectively.

### Synthesis of Intermediate 134-6

Intermediate 134-6 was synthesized in substantially the same manner as in the synthesis of Intermediate 26-6 in Synthesis Example 1, except that Intermediate 134-5 was utilized instead of Intermediate 26-5.

### Synthesis of Compound 134

Compound 134 (yield of 55%) was synthesized in substantially the same manner as in the synthesis of Compound 26 in Synthesis Example 1, except that Intermediate 134-6 was utilized instead of Intermediate 26-6.

ESI-LCMS: [M]+: C₇₅H₆₀D₁₄N₄OPt, 1254.70

### Synthesis Example 5: Synthesis of Compound 185

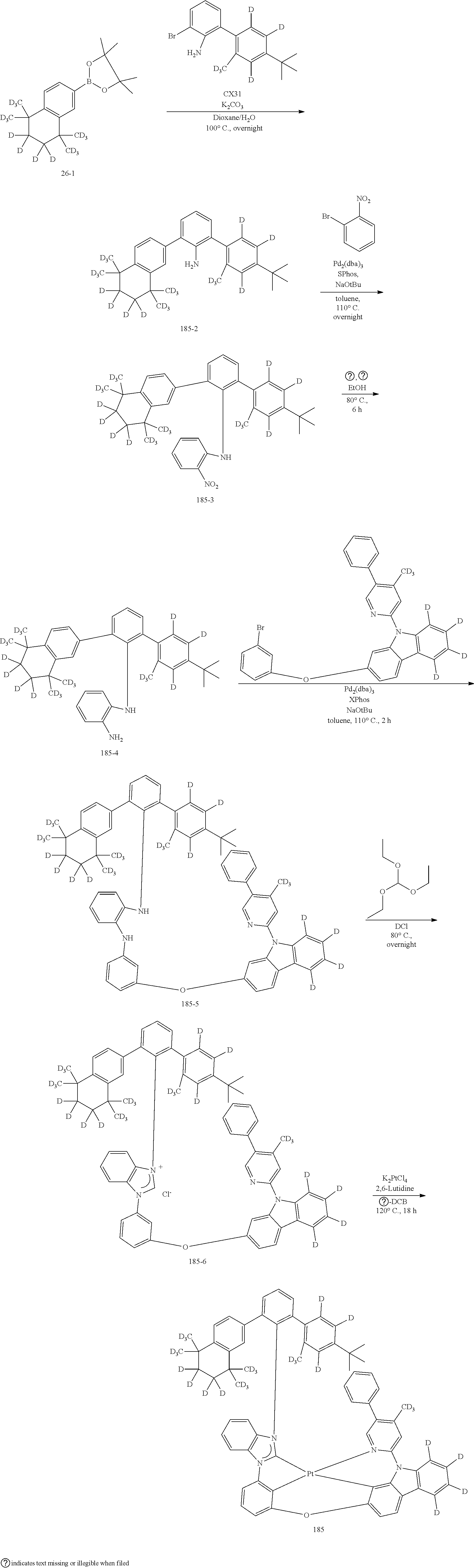

### Synthesis of Intermediate 185-2

Intermediate 185-2 was synthesized in substantially the same manner as in the synthesis of Intermediate 26-2 in Synthesis Example 1, except that 3-bromo-4′-(tert-butyl)-2′-(methyl-d₃)-[1,1′-biphenyl]-3′,5′,6′-d₃-2-amine was utilized instead of 3-bromo-3′-(tert-butyl)-5′-(2,2-dimethylpropyl-1,1-d₂)-[1,1′-biphenyl]-2′,4′,6′-d₃-2-amine.

### Synthesis of Intermediate 185-3

Intermediate 185-3 was synthesized in substantially the same manner as in the synthesis of Intermediate 26-3 in Synthesis Example 1, except that Intermediate 185-2 was utilized instead of Intermediate 26-2.

### Synthesis of Intermediate 185-4

Intermediate 185-4 (yield of 62%) was synthesized in substantially the same manner as in the synthesis of Intermediate 26-4 in Synthesis Example 1, except that Intermediate 185-3 was utilized instead of Intermediate 26-3.

### Synthesis of Intermediate 185-5

Intermediate 185-5 was synthesized in substantially the same manner as in the synthesis of Intermediate 26-5 in Synthesis Example 1, except that Intermediate 185-4 and 2-(3-bromophenoxy)-9-(4-(methyl-d₃)-5-phenylpyridin-2-yl)-9H-carbazole-5,6,7,8-d₄ were utilized instead of Intermediate 26-4 and 2-(3-bromophenoxy)-9-(4-tert-butyl-pyridin-2-yl)-9H-carbazole-5,6,7,8-d₄, respectively.

### Synthesis of Intermediate 185-6

Intermediate 185-6 was synthesized in substantially the same manner as in the synthesis of Intermediate 26-6 in Synthesis Example 1, except that Intermediate 185-5 was utilized instead of Intermediate 26-5.

### Synthesis of Compound 185

Compound 185 (yield of 51%) was synthesized in substantially the same manner as in the synthesis of Compound 26 in Synthesis Example 1, except that Intermediate 185-6 was utilized instead of Intermediate 26-6.

ESI-LCMS: [M]+: C₆₈H₃₁D₂₉N₄OPt, 1171.50

### Synthesis Example 6: Synthesis of Compound 213

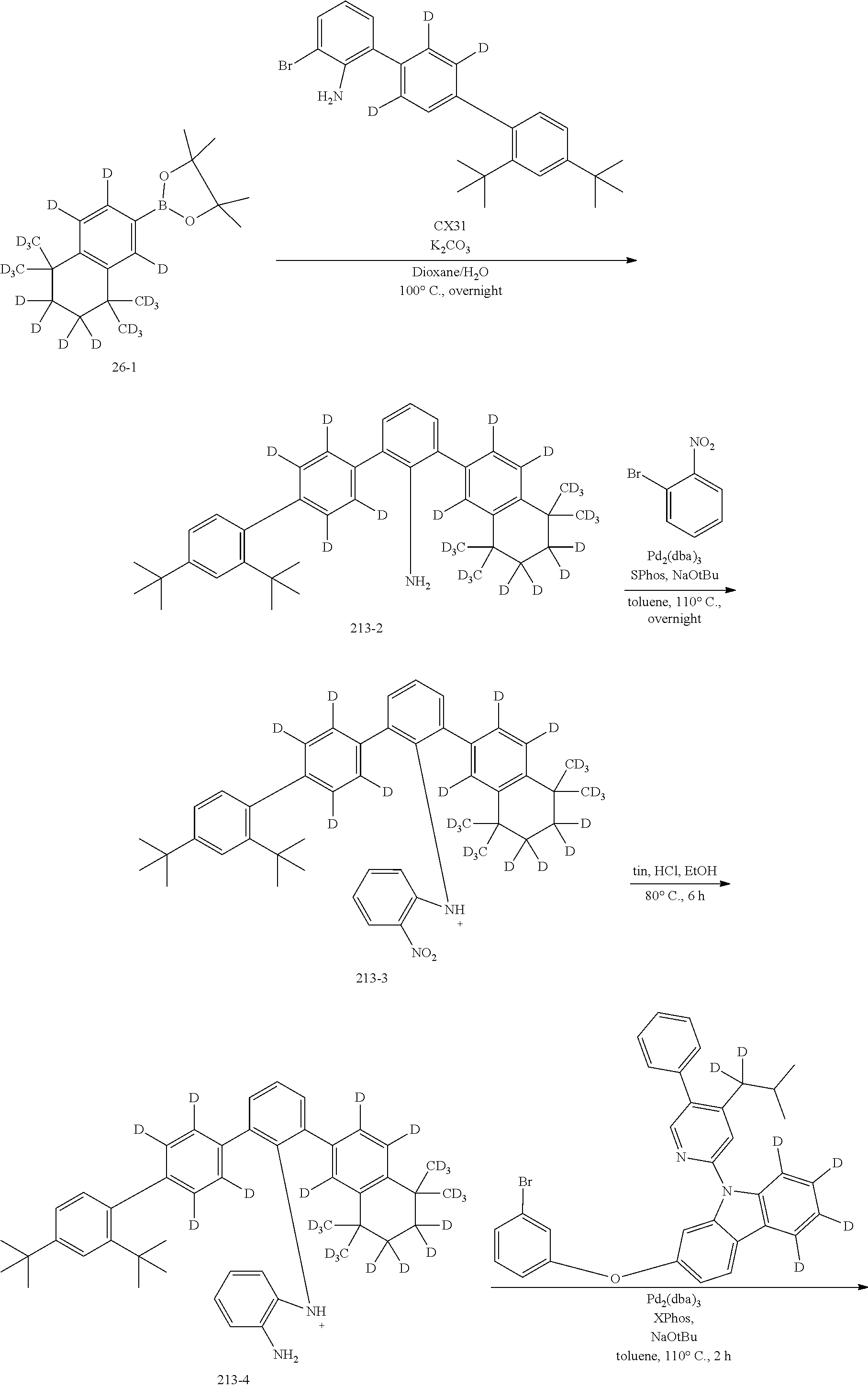

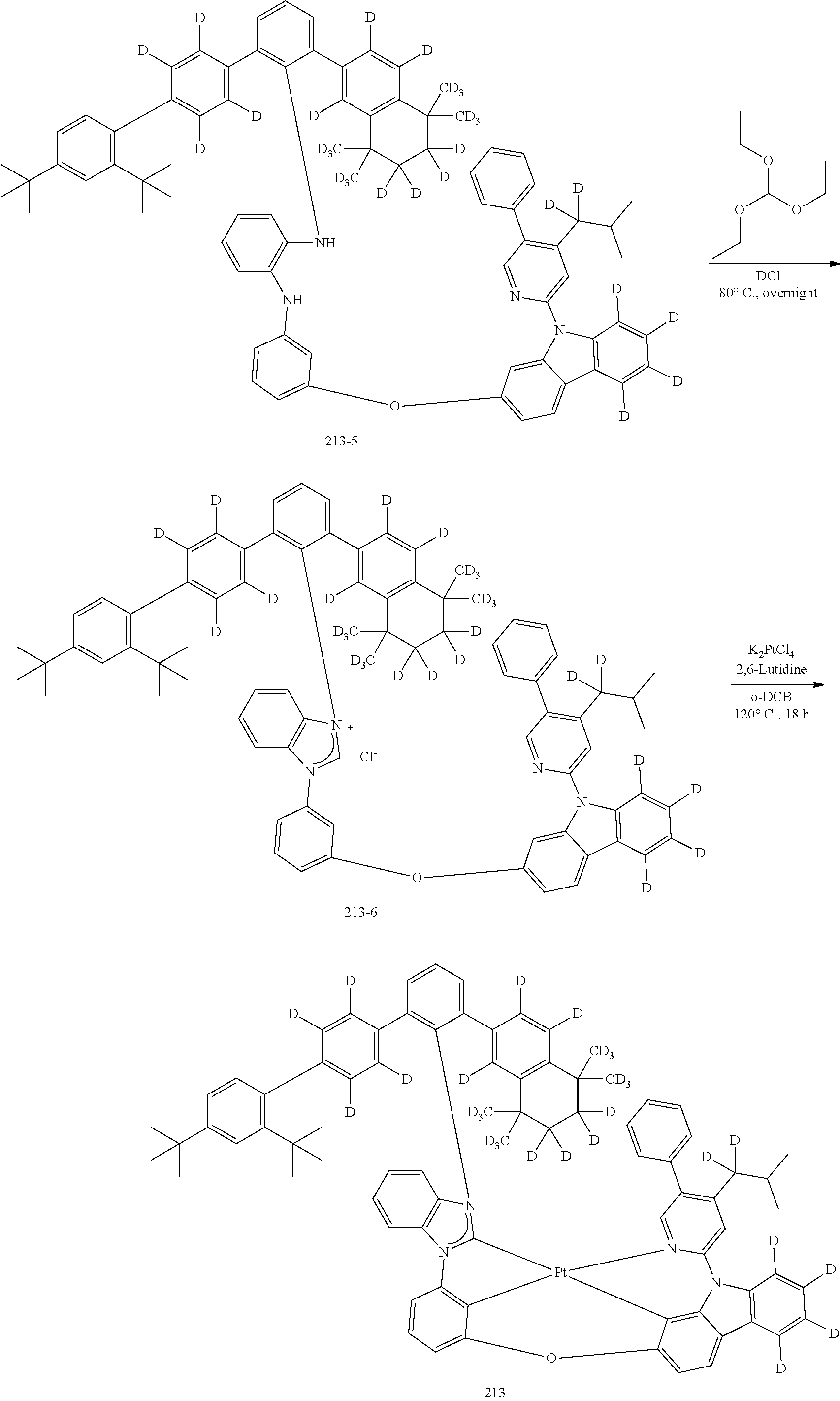

### Synthesis of Intermediate 213-2

Intermediate 213-2 was synthesized in substantially the same manner as in the synthesis of Intermediate 26-2 in Synthesis Example 1, except that 3-bromo-2″,4″-di-tert-butyl-[1,1′:4′,1″-terphenyl]-2′,3′,5′,6′-d₄-2-amine was utilized instead of 3-bromo-3′-(tert-butyl)-5′-(2,2-dimethylpropyl-1,1-d₂)-[1,1′-biphenyl]-2′,4′,6′-d₃-2-amine.

### Synthesis of Intermediate 213-3

Intermediate 213-3 was synthesized in substantially the same manner as in the synthesis of Intermediate 26-3 in Synthesis Example 1, except that Intermediate 213-2 was utilized instead of Intermediate 26-2.

### Synthesis of Intermediate 213-4

Intermediate 213-4 (yield of 66%) was synthesized in substantially the same manner as in the synthesis of Intermediate 26-4 in Synthesis Example 1, except that Intermediate 213-3 was utilized instead of Intermediate 26-3.

### Synthesis of Intermediate 213-5

Intermediate 213-5 was synthesized in substantially the same manner as in the synthesis of Intermediate 26-5 in Synthesis Example 1, except that Intermediate 213-4 and 2-(3-bromophenoxy)-9-(4-(2-methylpropyl-1,1-d₂)-5-phenylpyridin-2-yl)-9H-carbazole-5,6,7,8-d₄ were utilized instead of Intermediate 26-4 and 2-(3-bromophenoxy)-9-(4-tert-butyl-pyridin-2-yl)-9H-carbazole-5,6,7,8-d₄, respectively.

### Synthesis of Intermediate 213-6

Intermediate 213-6 was synthesized in substantially the same manner as in the synthesis of Intermediate 26-6 in Synthesis Example 1, except that Intermediate 213-5 was utilized instead of Intermediate 26-5.

### Synthesis of Compound 213

Compound 213 (yield of 53%) was synthesized in substantially the same manner as in the synthesis of Compound 26 in Synthesis Example 1, except that Intermediate 213-6 was utilized instead of Intermediate 26-6.

ESI-LCMS: [M]+: C₈₀H₄₇D₂₉N₄OPt, 1331.60

### Synthesis Example 7: Synthesis of Compound 267

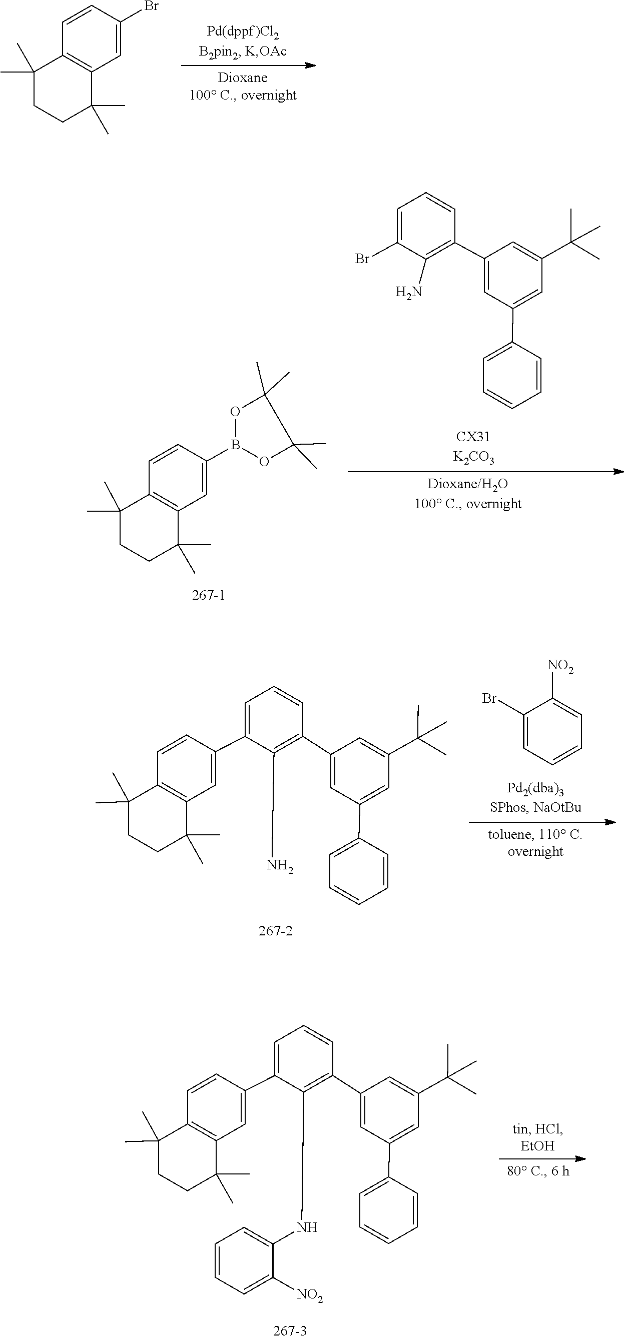

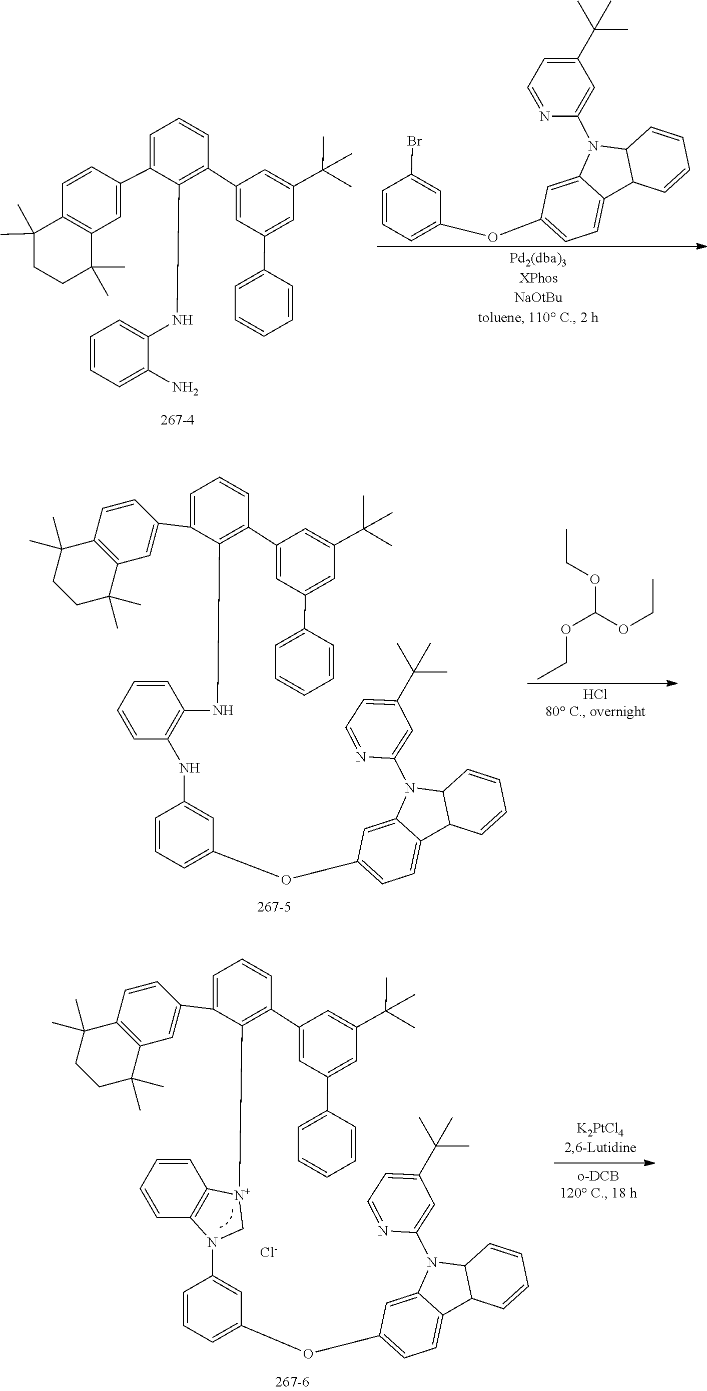

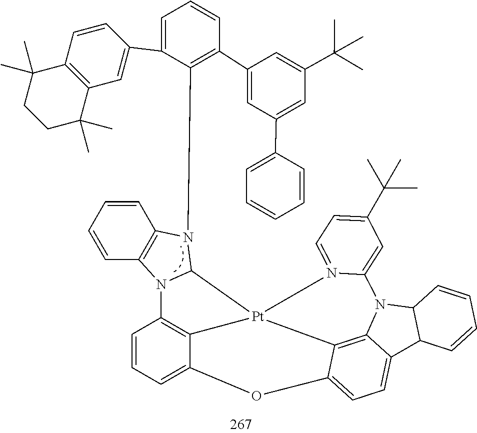

### Synthesis of Intermediate 267-1

Intermediate 267-1 was synthesized in substantially the same manner as in the synthesis of Intermediate 26-1 in Synthesis Example 1, except that 6-bromo-1,1,4,4-tetramethyl-1,2,3,4-tetrahydronaphthalene was utilized instead of 6-bromo-1,1,4,4-tetrakis(methyl-d₃)-1,2,3,4-tetrahydronaphthalene-2,2,3,3-d₄.

### Synthesis of Intermediate 267-2

Intermediate 267-2 was synthesized in substantially the same manner as in the synthesis of Intermediate 26-2 in Synthesis Example 1, except that Intermediate 267-1 and 3-bromo-5′-(tert-butyl)-[1,1′:3′,1″-terphenyl]-2-amine were utilized instead of Intermediate 26-1 and 3-bromo-3′-(tert-butyl)-5′-(2,2-dimethylpropyl-1,1-d₂)-[1,1′-biphenyl]-2′,4′,6′-d₃-2-amine, respectively.

### Synthesis of Intermediate 267-3

Intermediate 267-3 was synthesized in substantially the same manner as in the synthesis of Intermediate 26-3 in Synthesis Example 1, except that Intermediate 267-2 was utilized instead of Intermediate 26-2.

### Synthesis of Intermediate 267-4

Intermediate 267-4 (yield of 69%) was synthesized in substantially the same manner as in the synthesis of Intermediate 26-4 in Synthesis Example 1, except that Intermediate 267-3 was utilized instead of Intermediate 26-3.

### Synthesis of Intermediate 267-5

Intermediate 267-5 was synthesized in substantially the same manner as in the synthesis of Intermediate 26-5 in Synthesis Example 1, except that Intermediate 267-4 and 2-(3-bromophenoxy)-9-(4-(tert-butyl)pyridin-2-yl)-9H-carbazole were utilized instead of Intermediate 26-4 and 2-(3-bromophenoxy)-9-(4-tert-butyl-pyridin-2-yl)-9H-carbazole-5,6,7,8-d₄, respectively.

### Synthesis of Intermediate 267-6

Intermediate 267-6 was synthesized in substantially the same manner as in the synthesis of Intermediate 26-6 in Synthesis Example 1, except that Intermediate 267-5 and HCl were utilized instead of Intermediate 26-5 and DCI, respectively.

### Synthesis of Compound 267

Compound 267 (yield of 55%) was synthesized in substantially the same manner as in the synthesis of Compound 26 in Synthesis Example 1, except that Intermediate 267-6 was utilized instead of Intermediate 26-6.

ESI-LCMS: [M]+: C₇₀H₆₄N₄OPt, 1170.50

For each of the compounds synthesized in Synthesis Examples 1 to 7, high-resolution mass spectrum (HR-MS) was measured, and the results are shown in Table 1. Synthesis methods of compounds other than the compounds synthesized in Synthesis Examples 1 to 7 may be easily recognized by those skilled in the art by referring to the synthesis paths and source materials.

TABLE 1

HR-MS (m/z)
[M⁺]

| Compound | found | calc. |
|---|---|---|
| 26 | 1189.80 | 1190.68 |
| 70 | 1159.40 | 1160.62 |
| 124 | 1203.30 | 1204.52 |
| 134 | 1254.70 | 1255.64 |
| 185 | 1171.50 | 1172.62 |
| 213 | 1331.60 | 1332.75 |
| 267 | 1170.50 | 1171.47 |

### Evaluation Example 1

The HOMO and LUMO energy levels of each of Compounds 26, 70, 124, 134, 185, 213, and 267 were evaluated according to methods described in Table 2, and the results are shown in Table 3.

TABLE 2

| | |
|---|---|
| HOMO | By utilizing cyclic voltammetry (CV) (electrolyte: 0.1M |
| energy | Bu₄NPF₆/solvent: dimethylformamide (DMF)/electrode: |
| level | 3-electrode system (working electrode: glassy carbon (GC), |
| evaluation | reference electrode: Ag/AgCl, and auxiliary electrode: Pt)), |
| method | the potential (V)-current (A) graph of each compound was |
| | obtained, and then, from the oxidation onset of the graph, the |
| | HOMO energy level of each compound was calculated. |
| LUMO | By utilizing cyclic voltammetry (CV) (electrolyte: 0.1M |
| energy | Bu₄NPF₆/solvent: dimethylformamide (DMF)/electrode: |
| level | 3-electrode system (working electrode: GC, reference |
| evaluation | electrode: Ag/AgCl, and auxiliary electrode: Pt)), the |
| method | potential (V)-current (A) graph of each compound was |
| | obtained, and then, from the reduction onset of the graph, the |
| | LUMO energy level of each compound was calculated. |

TABLE 3

| Compound No. | HOMO energy level (eV) | LUMO energy level (eV) |
|---|---|---|
| 26 | −5.27 | −1.96 |
| 70 | −5.26 | −1.95 |
| 124 | −5.25 | −1.94 |
| 134 | −5.27 | −1.96 |
| 185 | −5.25 | −1.96 |
| 213 | −5.24 | −2.00 |
| 267 | −5.26 | −1.96 |

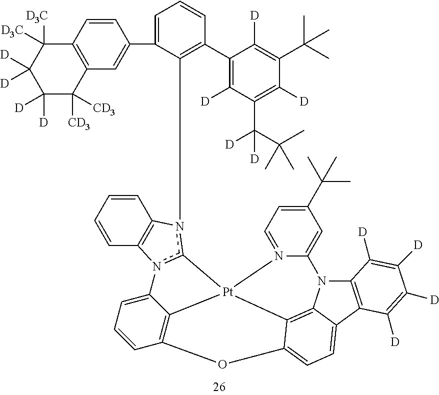

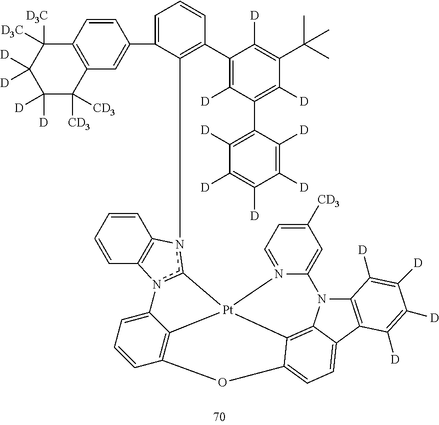

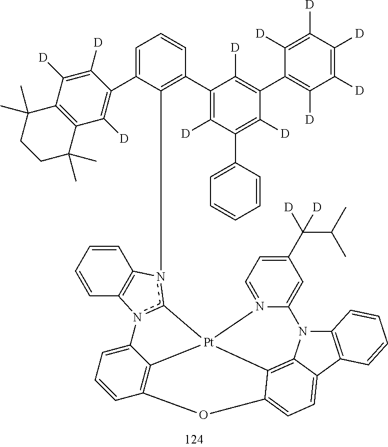

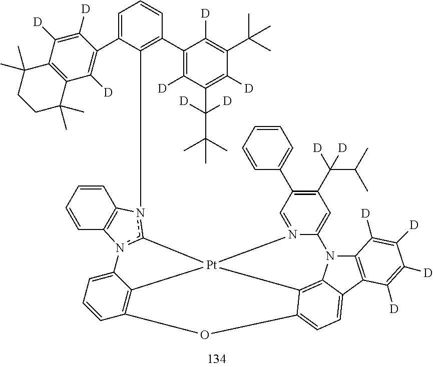

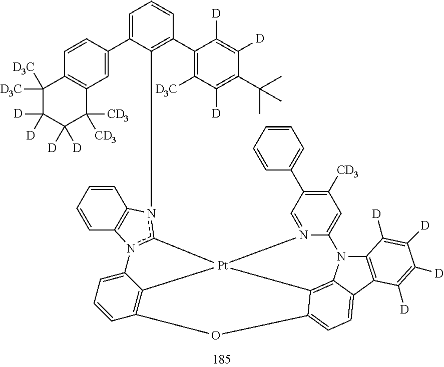

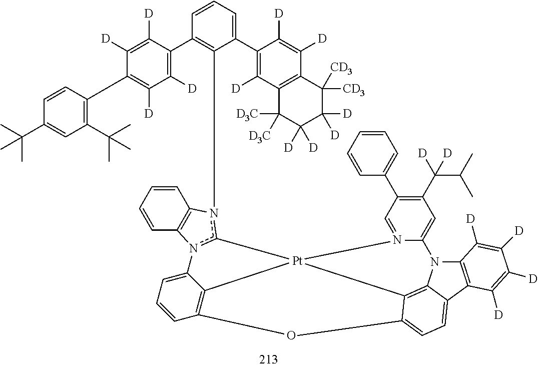

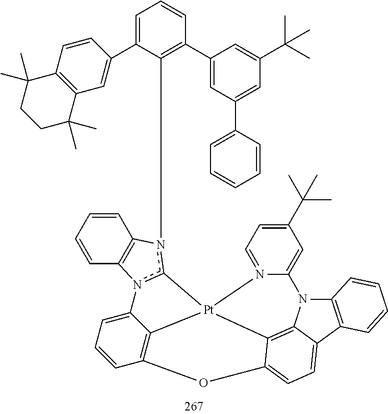

### Evaluation Example 2

Compound 26 (2 mg), Compound ETH2 (10 mg), Compound HTH29 (10 mg), and poly(methyl methacrylate) (PMMA) in CH₂Cl₂ (wherein the weight of PMMA was 50 mg) were mixed together, and the resulting product was applied to a quartz substrate by utilizing a spin coater. The quartz substrate was heat-treated in an oven at 80° C., and then cooled to room temperature, so as to prepare Film 26 having a thickness of 40 nm. Subsequently, Films 70, 124, 134, 185, 213, and 267 were each prepared in substantially the same manner as in the preparation of Film 26, except that Compounds 70, 124, 134, 185, 213, and 267 were each respectively utilized instead of Compound 26.

The emission spectrum for each of Films 26, 70, 124, 134, 185, 213, and 267 was measured by utilizing a Quantaurus-QY absolute PL quantum yield spectrometer (equipped with a xenon light source, a monochromator, a photonic multichannel analyzer, and an integrating sphere) manufactured by Hamamatsu Company and a PLQY measurement software (by Hamamatsu Photonics, Ltd., Shizuoka, Japan). During the measurement, an excitation wavelength was scanned from 320 nm to 380 nm at intervals of 10 nm, and a spectrum measured at the excitation wavelength of 340 nm was taken to obtain a maximum emission wavelength (emission peak wavelength) and full width at half maximum (FWHM) of an organometallic compound included in each film. The results are summarized in Table 4.

Next, PLQY for each of Films 26, 70, 124, 134, 185, 213, and 267 was measured by scanning an excitation wavelength from 300 nm to 380 nm at intervals of 10 nm with a Quantaurus-QY absolute PL quantum yield spectrometer manufactured by Hamamatsu Company, and the PLQY measured at the excitation wavelength of 330 nm was taken to obtain PLQY of an organometallic compound included in each film. The results are summarized in Table 4.

TABLE 4

| | Organometallic | Maximum | | |
|---|---|---|---|---|
| | compound No. | emission | FWHM | PLQY |
| Film No. | included in film | wavelength (nm) | (nm) | (%) |
| 26 | 26 | 456 | 38 | 72 |
| 70 | 70 | 457 | 39 | 70 |
| 124 | 124 | 458 | 39 | 71 |
| 134 | 134 | 457 | 38 | 74 |
| 185 | 185 | 456 | 39 | 73 |
| 213 | 213 | 457 | 39 | 73 |
| 267 | 267 | 456 | 38 | 72 |

Referring to Table 4, it was confirmed that Compounds 26, 70, 124, 134, 185, 213, and 267 had excellent or suitable PLQY, and emitted blue light with a relatively small FWHM.

### Evaluation Example 3

The PL spectrum for each of Films 26, 70, 124, 134, 185, 213, and 267 was measured at room temperature by utilizing FluoTime 300, which is a time-resolved photoluminescence (TRPL) measuring system by PicoQuant Company, and PLS340, which is a pumping source by PicoQuant Company (excitation wavelength=340 nm, spectral width=20 nm). Then, the wavelength of the main peak of the PL spectrum was determined, and the number of photons emitted at the wavelength of the main peak from each of the films measured according to the photon pulse (pulse width=500 ps) applied by the PLS340 to each of the films, and this measurement was repeated by hours based on time-correlated single photon counting (TCSPC), so as to obtain a TRPL curve with a sufficiently good or suitable fitting. The T_{decay}(Ex), i.e., decay time, for each of Films 26, 70, 124, 134, 185, 213, and 267 was obtained by fitting one or more exponential decay functions to the obtained results, and the results obtained by the fitting are shown in Table 5. A function utilized for the fitting is as shown in Equation 20, and the largest T_{decay} value from among the T_{decay} values obtained from each exponential decay function utilized for the fitting was obtained as T_{decay} (Ex). Here, the similar measurement was repeated one more time during the same amount of measurement time as that for obtaining the TRPL curve in dark state (i.e., a state in which pumping signals incident on the set or predetermined film are blocked) to obtain a baseline or a background signal curve for utilization as a baseline for the fitting.

$$f ( t ) = {\sum }_{i = 1}^{n} {A}_{i} exp ( - t / {T}_{decay , i} ) \qquad Equation 20$$

TABLE 5

| | Organometallic compound No. | |
|---|---|---|
| Film No. | included in film | T_{decay} (Ex)/τ (μs) |
| 26 | 26 | 1.90 |
| 70 | 70 | 2.02 |
| 124 | 124 | 2.06 |
| 134 | 134 | 1.87 |
| 185 | 185 | 1.95 |
| 213 | 213 | 2.08 |
| 267 | 267 | 2.09 |

Referring to Table 5, it was confirmed that Compounds 26, 70, 124, 134, 185, 213, and 267 had relatively short luminescence decay time.

### Example 1

A glass substrate (product of Corning Inc.) with a 15 Ω/cm² (1,200 Å) ITO formed thereon as an anode was cut to a size of 50 mm×50 mm×0.7 mm, sonicated with isopropyl alcohol and then pure water each for 5 minutes, cleaned by irradiation of ultraviolet rays and exposure of ozone thereto for 30 minutes, and then mounted on a vacuum deposition apparatus.

2-TNATA was vacuum-deposited on the anode to form (or provide) a hole injection layer having a thickness of 600 Å, and 4,4′-bis[N-(1-naphthyl)-N-phenylamino]biphenyl (hereinafter, referred as “NPB”) was vacuum-deposited on the hole injection layer to form (or provide) a hole transport layer having a thickness of 300 Å.

A first compound (Compound 26), a second compound (Compound ETH101), a third compound (Compound HTH47), and a fourth compound (Compound DFD30) were vacuum-deposited on the hole transport layer to form (or provide) an emission layer having a thickness of 350 Å. Here, the amount of the first compound was 14 wt % per a total weight (100 wt %) of the emission layer, the amount of the fourth compound was 1.3 wt % per a total weight (100 wt %) of the emission layer, and the weight ratio of the second compound to the third compound was adjusted to 3.3:6.7.

Compound ETH34 was vacuum-deposited on the emission layer to form (or provide) a hole blocking layer having a thickness of 50 Å, and ET46 and Liq were vacuum-deposited on the hole blocking layer at a weight ratio of 4:6 to form (or provide) an electron transport layer having a thickness of 310 Å. Next, Yb was vacuum-deposited on the electron transport layer to form (or provide) an electron injection layer having a thickness of 15 Å, and then Mg was vacuum-deposited thereon to form (or provide) a cathode having a thickness of 800 Å, thereby completing manufacture of an organic light-emitting device.

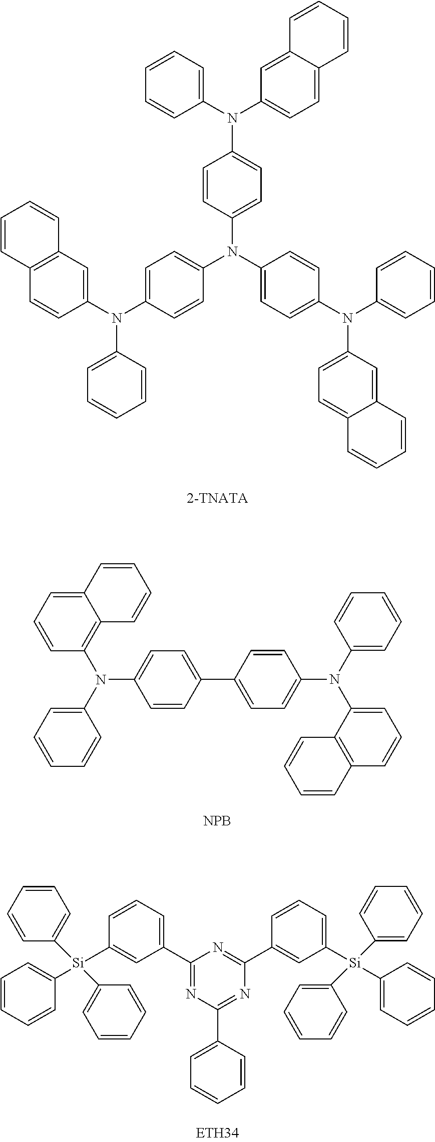 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; "NPB" ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

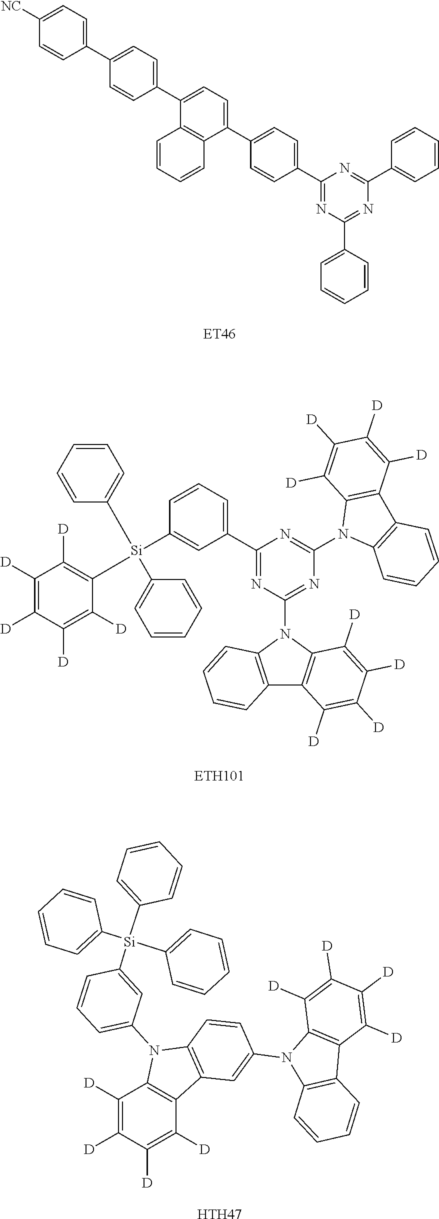 [SMILES: N#Cc1ccc(-c2ccc(-c3ccc(-c4ccc(-c5nc(-c6ccccc6)nc(-c6ccccc6)n5)cc4)c4ccccc34)cc2)cc1 ; [2H]c1c([2H])c([2H])c([Si](c2ccccc2)(c2ccccc2)c2cccc(-c3nc(-n4c5ccccc5c5c([2H])c([2H])c([2H])c([2H])c54)nc(-n4c5ccccc5c5c([2H])c([2H])c([2H])c([2H])c54)n3)c2)c([2H])c1[2H] ; [2H]c1c([2H])c([2H])c2c(c1[2H])c1ccccc1n2-c1ccc2c(c1)c1c([2H])c([2H])c([2H])c([2H])c1n2-c1cccc([Si](c2ccccc2)(c2ccccc2)c2ccccc2)c1 ; "HTH47"]

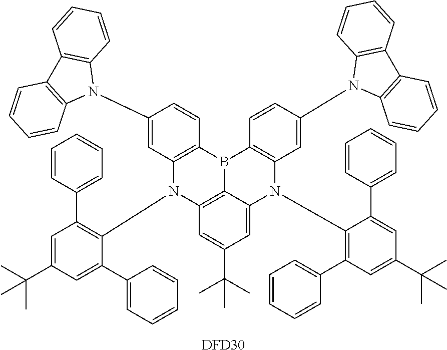 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; "DFD30"]

### Examples 2 to 7 and Comparative Examples A to D

Organic light-emitting devices were each manufactured in substantially the same manner as in Example 1, except that compounds shown in Table 6 were each respectively utilized instead of Compound 26 as the first compound in forming (or providing) an emission layer. In Table 6, the weight shown in parenthesis indicates the weight of the corresponding compound per 100 wt % of the emission layer.

### Evaluation Example 4

The driving voltage (V) at 1,000 cd/m², y color coordinates (CIE(y)), color conversion efficiency (cd/A/y), emission color, and lifespan (T₉₅) of the organic light-emitting devices of Examples 1 to 7 and Comparative Examples A to D were each measured by utilizing a Keithley SMU 236 meter and a luminance meter PR650, and the results are shown in Table 7. In Table 7, the lifespan (T₉₅) is a measure of the time (hr) expressed as a relative value (%) with respect to the lifespan (T₉₅) of Comparative Example D, taken for the luminance to reach 95% of the initial luminance.

TABLE 6

| | First | | | | |
|---|---|---|---|---|---|
| | compound | | | | |
| | (organometallic | | | | Weight ratio of |
| | compound | | | | second |
| | represented by | Second | Third | Fourth | compound to |
| No. | Formula 1) | compound | compound | compound | third compound |
| Example 1 | 26 | ETH101 | HTH47 | DFD30 | 3.3:6.7 |
| | (14 wt %) | | | (1.3 wt %) | |
| Example 2 | 70 | ETH101 | HTH47 | DFD30 | 3.3:6.7 |
| | (14 wt %) | | | (1.3 wt %) | |
| Example 3 | 124 | ETH101 | HTH47 | DFD30 | 3.3:6.7 |
| | (14 wt %) | | | (1.3 wt %) | |
| Example 4 | 134 | ETH101 | HTH47 | DFD30 | 3.3:6.7 |
| | (14 wt %) | | | (1.3 wt %) | |
| Example 5 | 185 | ETH101 | HTH47 | DFD30 | 3.3:6.7 |
| | (14 wt %) | | | (1.3 wt %) | |
| Example 6 | 213 | ETH101 | HTH47 | DFD30 | 3.3:6.7 |
| | (14 wt %) | | | (1.3 wt %) | |
| Example 7 | 267 | ETH101 | HTH47 | DFD30 | 3.3:6.7 |
| | (14 wt %) | | | (1.3 wt %) | |
| Comparative Example A | A | ETH101 | HTH47 | DFD30 | 3.3:6.7 |
| | (14 wt %) | | | (1.3 wt %) | |
| Comparative Example B | B | ETH101 | HTH47 | DFD30 | 3.3:6.7 |
| | (14 wt %) | | | (1.3 wt %) | |
| Comparative Example C | C | ETH101 | HTH47 | DFD30 | 3.3:6.7 |
| | (14 wt %) | | | (1.3 wt %) | |
| Comparative Example D | D | ETH101 | HTH47 | DFD30 | 3.3:6.7 |
| | (14 wt %) | | | (1.3 wt %) | |

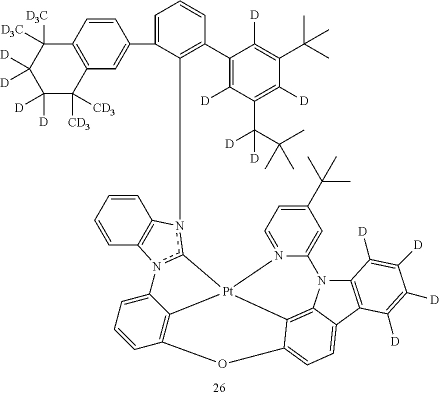

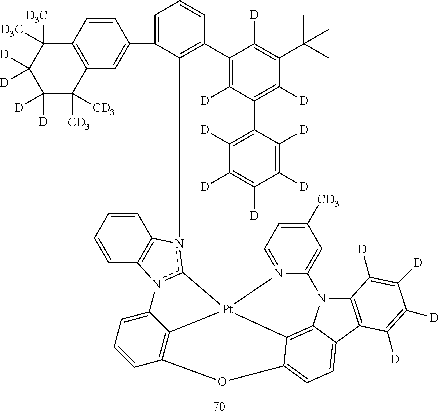

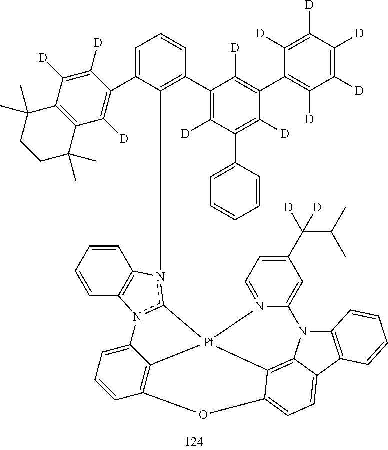

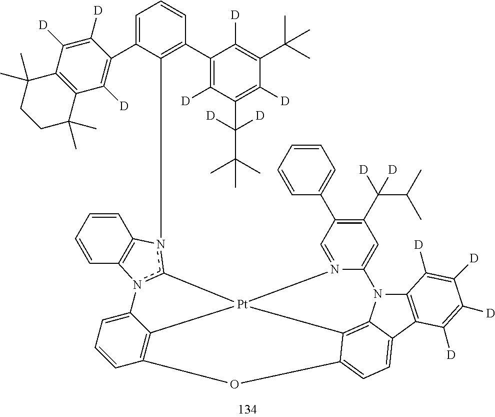

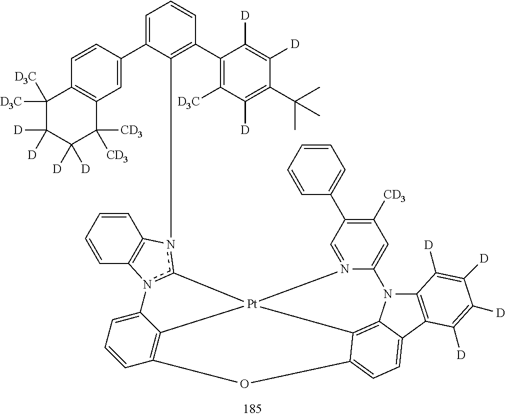

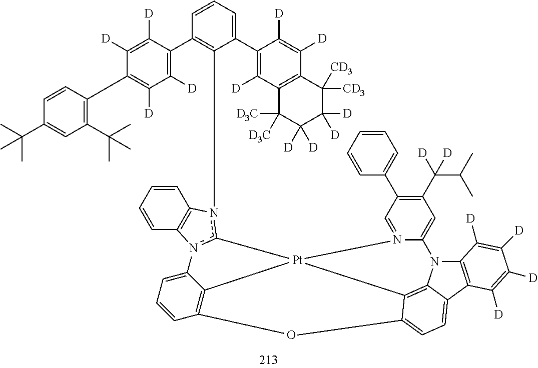

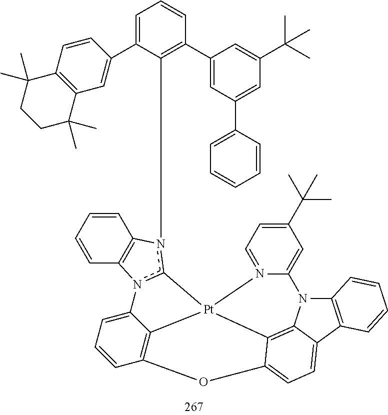

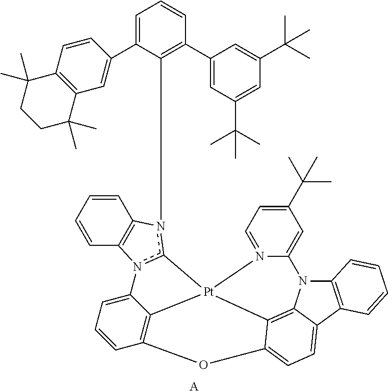

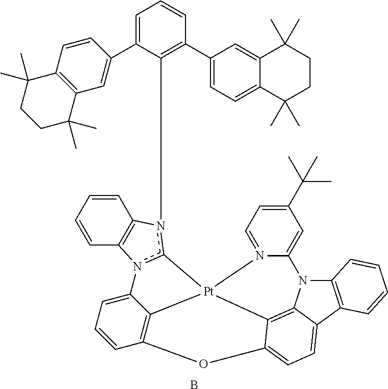

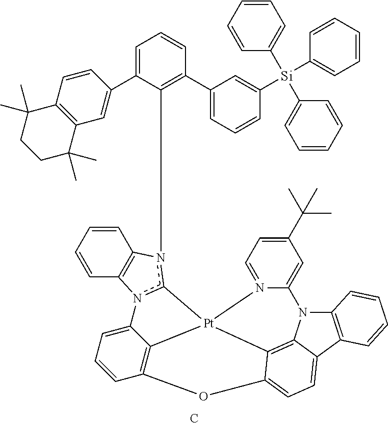

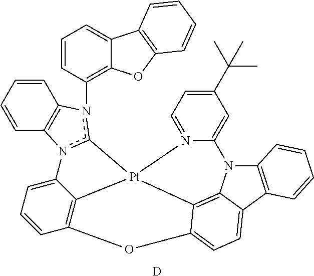

TABLE 7

| | First | | | | | | |
|---|---|---|---|---|---|---|---|
| | compound | | | | | | |
| | (organometallic | | | | Color | | Lifespan |
| | compound | | Driving | | conversion | | (T₉₅) |
| | represented by | Fourth | Voltage | | Efficiency | Emission | (relative |
| No. | Formula 1) | compound | (V) | CIE(y) | (cd/A/y) | color | value, %) |
| Example 1 | 26 | DFD30 | 4.18 | 0.112 | 158.3 | Blue | 526 |
| Example 2 | 70 | DFD30 | 4.12 | 0.110 | 153.4 | Blue | 540 |
| Example 3 | 124 | DFD30 | 4.10 | 0.109 | 156.1 | Blue | 474 |
| Example 4 | 134 | DFD30 | 4.20 | 0.115 | 150.7 | Blue | 516 |
| Example 5 | 185 | DFD30 | 4.22 | 0.114 | 151.4 | Blue | 498 |
| Example 6 | 213 | DFD30 | 4.19 | 0.118 | 152.2 | Blue | 510 |
| Example 7 | 267 | DFD30 | 4.14 | 0.111 | 150.8 | Blue | 466 |
| Comparative | A | DFD30 | 4.22 | 0.120 | 147.7 | Blue | 390 |
| Example A | | | | | | | |
| Comparative | B | DFD30 | 4.20 | 0.123 | 148.1 | Blue | 366 |
| Example B | | | | | | | |
| Comparative | C | DFD30 | 4.26 | 0.116 | 146.3 | Blue | 240 |
| Example C | | | | | | | |
| Comparative | D | DFD30 | 4.30 | 0.131 | 135.2 | Blue | 100 |
| Example D | | | | | | | |

Referring to Table 7, it was confirmed that the organic light-emitting devices of Examples 1 to 6 emitted blue light and had excellent or suitable driving voltage, excellent or suitable color purity, excellent or suitable color conversion efficiency, and excellent or suitable lifespan characteristics. It was also confirmed that the organic light-emitting device of Example 7 emitted relatively deep blue light and had the driving voltage, color purity, color conversion efficiency, lifespan characteristics improved compared to the organic light-emitting devices of Comparative Examples A to D.

### Examples 11 to 17 and Comparative Examples 1A to 1D

Organic light-emitting devices were each manufactured in substantially the same manner as in Example 1, except that the amounts of the first compound and the fourth compound and the weight ratio of the second compound to the third compound were changed as shown in Table 8 in forming (or providing) an emission layer. In Table 8, the weight shown in parenthesis indicates the weight of the corresponding compound per 100 wt % of the emission layer.

### Evaluation Example 5

The driving voltage V at 1,000 cd/m², y color coordinates (CIE(y)), color conversion efficiency (cd/A/y), emission color, and lifespan (T₉₅) of the organic light-emitting devices of Examples 11 to 17 and Comparative Examples 1A to 1D were each measured in substantially the same manner as in Evaluation Example 4, and the results are shown in Table 9. In Table 9, the lifespan (T₉₅) is a measure of the time (hr) expressed as a relative value (%) with respect to the lifespan (T₉₅) of Comparative Example 1 D, taken for the luminance to reach 95% of the initial luminance.

TABLE 8

| | First | | | | |
|---|---|---|---|---|---|
| | compound | | | | |
| | (organometallic | | | | Weight ratio of |
| | compound | | | | second |
| | represented by | Second | Third | Fourth | compound to |
| No. | Formula 1) | compound | compound | compound | third compound |
| Example | 26 | ETH101 | HTH47 | DFD31 | 4:6 |
| 11 | (15 wt %) | | | (1.3 wt %) | |
| Example | 70 | ETH101 | HTH47 | DFD31 | 4:6 |
| 12 | (15 wt %) | | | (1.3 wt %) | |
| Example | 124 | ETH101 | HTH47 | DFD31 | 4:6 |
| 13 | (15 wt %) | | | (1.3 wt %) | |
| Example | 134 | ETH101 | HTH47 | DFD31 | 4:6 |
| 14 | (15 wt %) | | | (1.3 wt %) | |
| Example | 185 | ETH101 | HTH47 | DFD31 | 4:6 |
| 15 | (15 wt %) | | | (1.3 wt %) | |
| Example | 213 | ETH101 | HTH47 | DFD31 | 4:6 |
| 16 | (15 wt %) | | | (1.3 wt %) | |
| Example | 267 | ETH101 | HTH47 | DFD31 | 4:6 |
| 17 | (15 wt %) | | | (1.3 wt %) | |
| Comparative Example 1A | A | ETH101 | HTH47 | DFD31 | 4:6 |
| | (15 wt %) | | | (1.3 wt %) | |
| Comparative Example 1B | B | ETH101 | HTH47 | DFD31 | 4:6 |
| | (15 wt %) | | | (1.3 wt %) | |
| Comparative Example 1C | C | ETH101 | HTH47 | DFD31 | 4:6 |
| | (15 wt %) | | | (1.3 wt %) | |
| Comparative Example 1D | D | ETH101 | HTH47 | DFD31 | 4:6 |
| | (15 wt %) | | | (1.3 wt %) | |

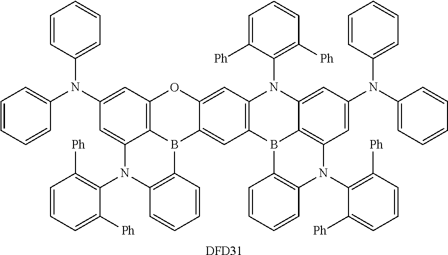

TABLE 9

| | First | | | | | | |
|---|---|---|---|---|---|---|---|
| | compound | | | | | | |
| | (organometallic | | | | Color | | Lifespan |
| | compound | | Driving | | conversion | | (T₉₅) |
| | represented by | Fourth | Voltage | | Efficiency | Emission | (relative |
| No. | Formula 1) | compound | (V) | CIE(y) | (cd/A/y) | color | value, %) |
| Example 11 | 26 | DFD31 | 4.25 | 0.120 | 149.5 | Blue | 717.5 |
| Example 12 | 70 | DFD31 | 4.27 | 0.117 | 151.3 | Blue | 712.5 |
| Example 13 | 124 | DFD31 | 4.21 | 0.121 | 146.7 | Blue | 697.5 |
| Example 14 | 134 | DFD31 | 4.24 | 0.114 | 149.5 | Blue | 662.5 |
| Example 15 | 185 | DFD31 | 4.29 | 0.119 | 148.9 | Blue | 727.5 |
| Example 16 | 213 | DFD31 | 4.20 | 0.122 | 150.8 | Blue | 700 |
| Example 17 | 267 | DFD31 | 4.28 | 0.118 | 150.7 | Blue | 655 |
| Comparative | A | DFD31 | 4.32 | 0.120 | 142.8 | Blue | 542.5 |
| Example 1A | | | | | | | |
| Comparative | B | DFD31 | 4.35 | 0.123 | 119.8 | Blue | 525 |
| Example 1B | | | | | | | |
| Comparative | C | DFD31 | 4.36 | 0.125 | 121.3 | Blue | 175 |
| Example 1C | | | | | | | |
| Comparative | D | DFD31 | 4.54 | 0.121 | 115.7 | Blue | 100 |
| Example 1D | | | | | | | |

Referring to Table 9, it was confirmed that each of the organic light-emitting devices of Examples 11 to 16 emitted blue light and had excellent or suitable driving voltage, excellent or suitable color purity, excellent or suitable color conversion efficiency, and excellent or suitable lifespan characteristics. It was also confirmed that the organic light-emitting device of Example 17 emitted relatively deep blue light and had the driving voltage, color purity, color conversion efficiency, lifespan characteristics improved compared to the organic light-emitting devices of Comparative Examples 1A to 1D.

According to the one or more embodiments, an organometallic compound may have excellent or suitable processability and electrical properties, and thus a light-emitting device including the organometallic compound may have improved color purity, improved luminescence efficiency, and improved lifespan.

In the present disclosure, it will be understood that the term “comprise(s),” “include(s),” or “have/has” specifies the presence of stated features, integers, steps, operations, elements, and/or components, but do not preclude the presence or addition of one or more other features, integers, steps, operations, elements, components, and/or groups thereof.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light-emitting device, the light-emitting apparatus, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the appended claims and equivalents thereof.

What is claimed is:

1. A composition comprising:
an organometallic compound represented by Formula 1; and
a second compound comprising at least one π electron-deficient nitrogen-containing C₁-C₆₀ heterocyclic group, a third compound comprising a group represented by Formula 3, a fourth compound capable of emitting delayed fluorescence, or a combination thereof,
wherein the organometallic compound, the second compound, the third compound, and the fourth compound are different from each other: 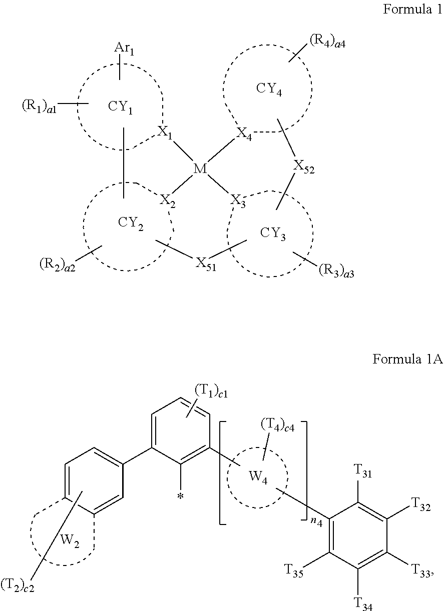
wherein, Ar₁ in Formula 1 is a group represented by Formula 1A,
* in Formula 1A indicates a binding site to ring CY₁ in Formula 1,
in Formulae 1 and 1A,
M is platinum, palladium, gold, nickel, silver, or copper,
X₁ to X₄ are each independently C or N,
i) a bond between X₁ and M is a coordinate bond, and ii) one selected from among a bond between X₂ and M, a bond between X₃ and M, and a bond between X₄ and M is a coordinate bond, and the other two are each a covalent bond,
ring CY₁ to ring CY₄ and ring W₄ are each independently a C₃-C₆₀ carbocyclic group or a C₁-C₆₀ heterocyclic group,
ring W₂ is a saturated C₃-C₈ carbocyclic group,
n4 is 0, 1, or 2, when n4 is 0, a group represented by 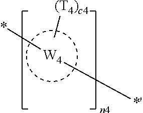
in Formula 1A is a single bond,
X₅₁ is a single bond, *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*, *—S—*′, *—Se—*′, *—O—*′, *—C(═O)—*′, *—S(═O)—*′, *—S(═O)₂—*′, *—C(Z₅₁ₐ)=*′, *═C(Z₅₁ₐ)—*′, *—C(Z₅₁ₐ)═C(Z_{51b})—*′, *—C(═S)—*′, or *—C≡C—*′,
X₅₂ is a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′, *—O—*′, *—C(═O)—*′, *—S(═O)—*′, *—S(═O)₂—*′, *—C(Z₅₂ₐ)=*′, *═C(Z₅₂ₐ)—*′, *—C(Z₅₂ₐ)═C(Z_{52b})—*′, *—C(═S)—*′, or *—C≡C—*′,
R₁ to R₄, Z₅₁ₐ, Z_{51b}, Z₅₂ₐ, and Z_{52b} are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
T₁, T₂, T₃₁ to T₃₅, and T₄ are each independently:
hydrogen, deuterium, —F, or a cyano group;
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁—C₂₀ alkyl)phenyl group, a biphenyl group, a deuterated biphenyl group, a fluorinated biphenyl group, a (C₁-C₂₀ alkyl)biphenyl group, or a combination thereof,
a1 to a4 are each independently an integer from 0 to 10,
c1 is an integer from 1 to 3,
c2 is an integer from 1 to 15,
c4 is an integer from 1 to 10,
Formula 1A satisfies at least one selected from among Conditions A and B:
Condition A
T₃₁ and T₃₅ are different from each other; and
Condition B
T₃₂ and T₃₄ are different from each other,
in Formula 1A, a group represented by 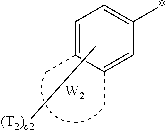
and a group represented by 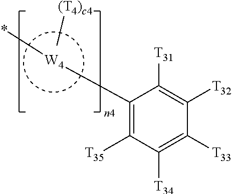
are different from each other,
two or more selected from among ring CY₁, ring CY₂, ring CY₃, ring CY₄, R₁, R₂, R₃, R₄, Z₅₁ₐ, Z_{51b}, Z₅₂ₐ, Z_{52b}, T₁, T₂, T₃₁, T₃₂, T₃₃, T₃₄, T₃₅, and T₄ are optionally bonded together to form a C₃-C₆₀ carbocyclic group or unsubstituted or substituted with at least one R₁₀ₐ or a C₁-C₆₀ heterocyclic group unsubstituted or substituted with at least one R₁₀ₐ,
* indicating a binding site to a neighboring atom,
R₁₀ₐ being:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof;
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂); or
a combination thereof,
Q₁ to Q₃, Q₁₁ to Q₁₃, Q₂₁ to Q₂₃, and Q₃₁ to Q₃₃ each being independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or a combination thereof,
Formula 3 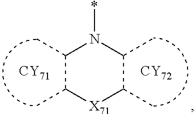
and
wherein, in Formula 3,
ring CY₇₁ and ring CY₇₂ are each independently a π electron-rich C₃-C₆₀ cyclic group or a pyridine group,
X₇₁ is a single bond, or a linking group comprising O, S, N, B, C, Si, or a combination thereof, and
* indicates a binding site to any atom included in the remaining part other than the group represented by Formula 3 in the third compound.

2. A light-emitting device comprising:
a first electrode;
a second electrode facing the first electrode;
an interlayer between the first electrode and the second electrode and comprising an emission layer; and
an organometallic compound represented by Formula 1: 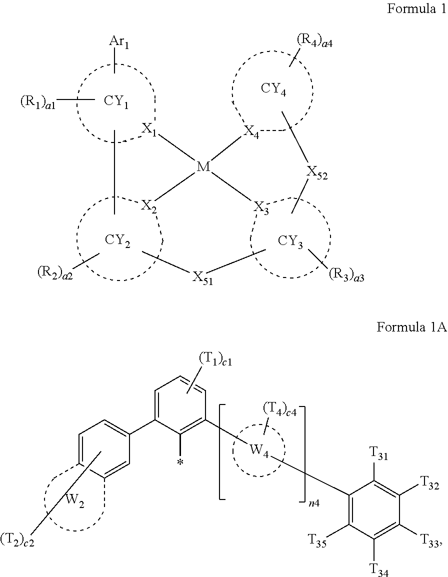
wherein, Ar₁ in Formula 1 is a group represented by Formula 1A,
* in Formula 1A indicates a binding site to ring CY₁ in Formula 1,
in Formulae 1 and 1A,
M is platinum, palladium, gold, nickel, silver, or copper,
X₁ to X₄ are each independently C or N,
i) a bond between X₁ and M is a coordinate bond, and ii) one selected from among a bond between X₂ and M, a bond between X₃ and M, and a bond between X₄ and M is a coordinate bond, and the other two are each a covalent bond,
ring CY₁ to ring CY₄ and ring W₄ are each independently a C₃-C₆₀ carbocyclic group or a C₁-C₆₀ heterocyclic group,
ring W₂ is a saturated C₃-C₈ carbocyclic group,
n4 is 0, 1, or 2, when n4 is 0, a group represented by 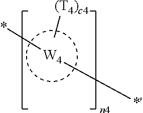
in Formula 1A is a single bond,
X₅₁ is a single bond, *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′, *—O—*, *—C(═O)—*′, *—S(═O)—*′, *—S(═O)₂—*′, *—C(Z₅₁ₐ)=*′, *═C(Z₅₁ₐ)—*′, *—C(Z₅₁ₐ)═C(Z_{51b})—*′, *—C(═S)—*′, or *—C≡C—*′,
X₅₂ is a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*, *—Ge(Z₅₂ₐ)(Z_{52b})—*, *—S—*′, *—Se—*′, *—O—*′, *—C(═O)—*′, *—S(═O)—*, *—S(═O)₂—*′, *—C(Z₅₂ₐ)=*′, *═C(Z₅₂ₐ)—*′, *—C(Z₅₂ₐ)═C(Z_{52b})—*′, *—C(═S)—*′, or *—C≡C—*′,
R₁ to R₄, Z₅₁ₐ, Z_{51b}, Z₅₂ₐ, and Z_{52b} are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
T₁, T₂, T₃₁ to T₃₅, and T₄ are each independently:
hydrogen, deuterium, —F, or a cyano group;
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof,
a1 to a4 are each independently an integer from 0 to 10,
c1 is an integer from 1 to 3,
c2 is an integer from 1 to 15,
c4 is an integer from 1 to 10,
Formula 1A satisfies at least one selected from among Conditions A and B:
Condition A
T₃₁ and T₃₅ are different from each other; and
Condition B
T₃₂ and T₃₄ are different from each other,
in Formula 1A, a group represented by 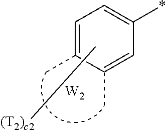
and a group represented by 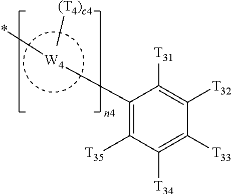
are different from each other,
two or more selected from among ring CY₁, ring CY₂, ring CY₃, ring CY₄, R₁, R₂, R₃, R₄, Z₅₁ₐ, Z_{51b}, Z₅₂ₐ, Z_{52b}, T₁, T₂, T₃₁, T₃₂, T₃₃, T₃₄, T₃₅, and T₄ are optionally bonded together to form a C₃-C₆₀ carbocyclic group or unsubstituted or substituted with at least one R₁₀ₐ or a C₁-C₆₀ heterocyclic group unsubstituted or substituted with at least one R₁₀ₐ,
* indicating a binding site to a neighboring atom,
R₁₀ₐ being:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂—C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof;
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), or
a combination thereof, and
Q₁ to Q₃, Q₁₁ to Q₁₃, Q₂₁ to Q₂₃, and Q₃₁ to Q₃₃ each being independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or a combination thereof.

3. The light-emitting device of claim 2, further comprising
a second compound comprising at least one π electron-deficient nitrogen-containing C₁-C₆₀ heterocyclic group, a third compound comprising a group represented by Formula 3, a fourth compound capable of emitting delayed fluorescence, or a combination thereof,
wherein the organometallic compound, the second compound, the third compound, and the fourth compound are different from each other: 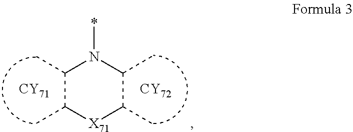
in Formula 3,
ring CY₇₁ and ring CY₇₂ being each independently a π electron-rich C₃-C₆₀ cyclic group or a pyridine group,
X₇₁ being a single bond, or a linking group comprising O, S, N, B, C, Si, or a combination thereof, and
* indicating a binding site to any atom included in the remaining part other than the group represented by Formula 3 in the third compound.

4. The light-emitting device of claim 3, wherein,
the second compound comprises a pyridine group, a pyrimidine group, a pyrazine group, a pyridazine group, a triazine group, or a combination thereof, and
the fourth compound is a compound comprising at least one cyclic group comprising both boron (B) and nitrogen (N) as ring-forming atoms.

5. The light-emitting device of claim 3, wherein,
the emission layer comprises:
i) the organometallic compound; and
ii) the second compound, the third compound, the fourth compound, or a combination thereof,
the emission layer configured to emit blue light.

6. The light-emitting device of claim 3, comprising
the second compound and the third compound,
wherein at least one of the second compound or the third compound comprises at least one deuterium, at least one silicon, or a combination thereof.

7. An electronic apparatus the light-emitting device of claim 2.

8. The electronic apparatus of claim 7, further comprising: a color filter, a color conversion layer, a touch screen layer, a polarizing layer, or a combination thereof.

9. An electronic equipment comprising the light-emitting device of claim 2.

10. The electronic equipment of claim 9, wherein the electronic equipment is at least one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, or a signboard.

11. An organometallic compound represented by Formula 1: 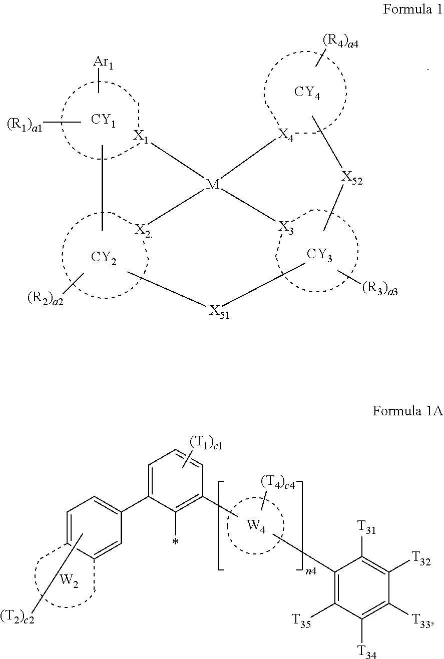
wherein, Ar₁ in Formula 1 is a group represented by Formula 1A,
* in Formula 1A indicates a binding site to ring CY₁ in Formula 1,
in Formulae 1 and 1A,
M is platinum, palladium, gold, nickel, silver, or copper,
X₁ to X₄ are each independently C or N,
i) a bond between X₁ and M is a coordinate bond, and ii) one selected from among a bond between X₂ and M, a bond between X₃ and M, and a bond between X₄ and M is a coordinate bond, and the other two are each a covalent bond,
ring CY₁ to ring CY₄ and ring W₄ are each independently a C₃-C₆₀ carbocyclic group or a C₁-C₆₀ heterocyclic group,
ring W₂ is a saturated C₃-C₈ carbocyclic group,
n4 is 0, 1, or 2, when n4 is 0, a group represented by 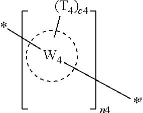
in Formula 1A is a single bond,
X₅₁ is a single bond, *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′, *—O—*, *—C(═O)—*′, *—S(═O)—*′, *—S(═O)₂—*′, *—C(Z₅₁ₐ)=*′, *═C(Z₅₁ₐ)—*′, *—C(Z₅₁ₐ)═C(Z_{51b})—*′, *—C(═S)—*′, or *—C≡C—*′,
X₅₂ is a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*, *S—*, *—Se—*, *—O—*′, *—C(═O)—*′, *—S(═O)—*′, *—S(═O)₂—*′, *—C(Z₅₂ₐ)=*′, *═C(Z₅₂ₐ)—*′, *—C(Z₅₂ₐ)═C(Z_{52b})—*′, *—C(═S)—*′, or *—C≡C—*′,
R₁ to R₄, Z₅₁ₐ, Z_{51b}, Z₅₂ₐ, and Z_{52b} are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
T₁, T₂, T₃₁ to T₃₅, and T₄ are each independently:
hydrogen, deuterium, —F, or a cyano group;
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof,
a1 to a4 are each independently an integer from 0 to 10,
c1 is an integer from 1 to 3,
c2 is an integer from 1 to 15,
c4 is an integer from 1 to 10,
Formula 1A satisfies at least one selected from among Conditions A and B:
Condition A
T₃₁ and T₃₅ are different from each other; and
Condition B
T₃₂ and T₃₄ are different from each other,
in Formula 1A, a group represented by 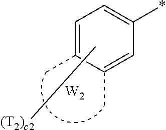
and a group represented by 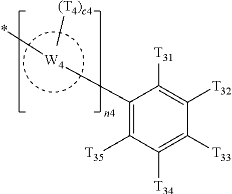
are different from each other, two or more selected from among ring CY₁, ring CY₂, ring CY₃, ring CY₄, R₁, R₂, R₃, R₄, Z₅₁ₐ, Z_{51b}, Z₅₂ₐ, Z_{52b}, T₁, T₂, T₃₁, T₃₂, T₃₃, T₃₄, T₃₅, and T₄ are optionally bonded together to form a C₃-C₆₀ carbocyclic group or unsubstituted or substituted with at least one R₁₀ₐ or a C₁-C₆₀ heterocyclic group unsubstituted or substituted with at least one R₁₀ₐ,
* indicating a binding site to a neighboring atom,
R₁₀ₐ being:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof;
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂); or
a combination thereof, and
Q₁ to Q₃, Q₁₁ to Q₁₃, Q₂₁ to Q₂₃, and Q₃₁ to Q₃₃ each being independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or a combination thereof.

12. The organometallic compound of claim 11, wherein,
X₁ is C, and
ring CY₁ is an imidazole group, a triazole group, a benzimidazole group, a naphthoimidazole group, or an imidazopyridine group.

13. The organometallic compound of claim 11, wherein ring W₂ is a cyclopentane group, a cyclohexane group, a cycloheptane group, or a cyclooctane group.

14. The organometallic compound of claim 11, wherein,
R₁ to R₄, Z₅₁ₐ, Z_{51b}, Z₅₂ₐ, and Z_{52b} are each independently:
hydrogen, deuterium, —F, or a cyano group;
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof; or
a C₃-C₁₀ cycloalkyl group, a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof.

15. The organometallic compound of claim 11, wherein,
Formula 1A satisfies one selected from among Conditions A-1 to A-3:
Condition A-1
T₃₁ is hydrogen, deuterium, or —F,
T₃₅ is:
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof;
Condition A-2
T₃₁ and T₃₅ are different from each other, and
T₃₁ and T₃₅ are each independently a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof; and
Condition A-3
T₃₁ is a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof, and
T₃₅ is a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof.

16. The organometallic compound of claim 11, wherein,
Formula 1A satisfies one selected from among Conditions B-1 to B-3:
Condition B-1
T₃₂ is hydrogen, deuterium, or —F,
T₃₄ is:
a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof;
Condition B-2
T₃₂ and T₃₄ are different from each other, and
T₃₂ and T₃₄ are each independently a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof; and
Condition B-3
T₃₂ is a C₁-C₂₀ alkyl group unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof, and
T₃₄ is a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof.

17. The organometallic compound of claim 11, wherein the group represented by Formula 1A is one selected from among groups represented by Formulae 1A(1) to 1A(4): 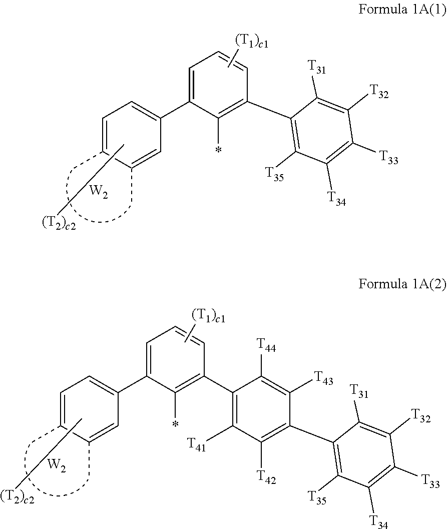 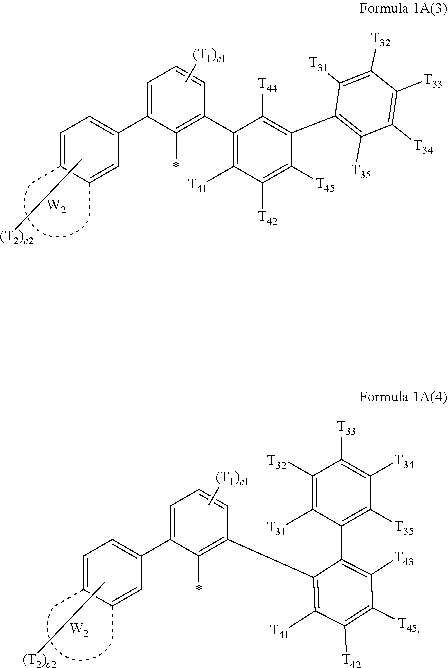
in Formulae 1A(1) to 1A(4),
* indicating a binding site to ring CY₁ in Formula 1,
ring W₂, T₁, T₂, T₃₁ to T₃₅, c1, and c2 each independently being the same as defined in Formula 1, and
T₄₁ to T₄₅ each independently being the same as defined with respect to T₄ in Formula 1.

18. The organometallic compound of claim 11, wherein the organometallic compound comprises at least one deuterium.

19. The organometallic compound of claim 11, wherein the organometallic compound is represented by Formula 1-1 or 1-2: 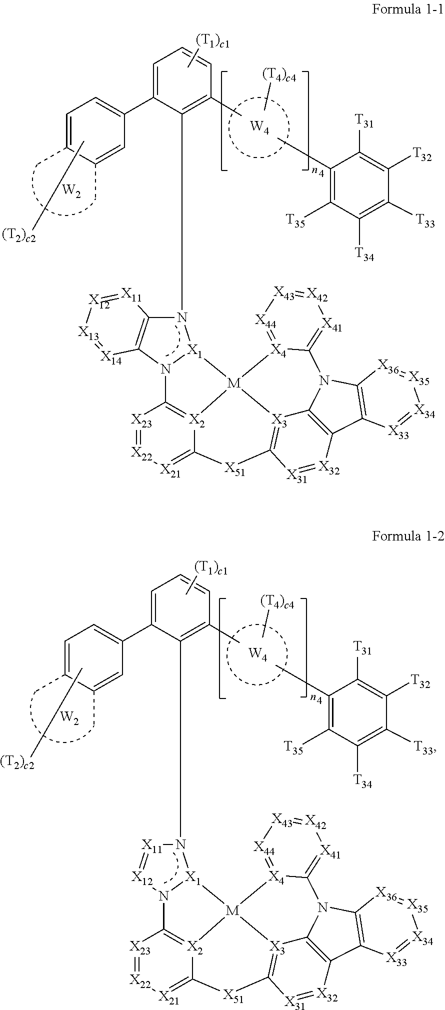
in Formulae 1-1 and 1-2,
M, X₁ to X₄, ring W₄, ring W₂, n4, X₅₁, T₁, T₂, T₃₁ to T₃₅, T₄, c1, c2, and c4 each being independently the same as defined in Formula 1,
X₁₁ being C(R₁₁) or N, X₁₂ being C(R₁₂) or N, X₁₃ being C(R₁₃) or N, and X₁₄ being C(R₁₄) or N,
R₁₁ to R₁₄ each being independently the same as defined with respect to R₁ in Formula 1, and two or more selected from among R₁₁ to R₁₄ being optionally bonded together to form a C₃-C₆₀ carbocyclic group unsubstituted or substituted with at least one R₁₀ₐ or a C₁-C₆₀ heterocyclic group unsubstituted or substituted with at least one R₁₀ₐ,
X₂₁ being C(R₂₁) or N, X₂₂ being C(R₂₂) or N, and X₂₃ being C(R₂₃) or N,
R₂₁ to R₂₃ each being independently the same as defined with respect to R₂ in Formula 1, and two or more selected from among R₂₁ to R₂₃ being optionally bonded together to form a C₃-C₆₀ carbocyclic group unsubstituted or substituted with at least one R₁₀ₐ or a C₁-C₆₀ heterocyclic group unsubstituted or substituted with at least one R₁₀ₐ,
X₃₁ being C(R₃₁) or N, X₃₂ being C(R₃₂) or N, X₃₃ being C(R₃₃) or N, X₃₄ being C(R₃₄) or N, X₃₅ being C(R₃₅) or N, and X₃₆ being C(R₃₆) or N,
R₃₁ to R₃₆ each being independent the same as defined with respect to R₃ in Formula 1, and two or more selected from among R₃₁ to R₃₆ being optionally bonded together to form a C₃-C₆₀ carbocyclic group unsubstituted or substituted with at least one R₁₀ₐ or a C₁-C₆₀ heterocyclic group unsubstituted or substituted with at least one R₁₀ₐ,
X₄₁ being C(R₄₁) or N, X₄₂ being C(R₄₂) or N, X₄₃ being C(R₄₃) or N, and X₄₄ being C(R₄₄) or N,
R₄₁ to R₄₄ each being independently the same as defined with respect to R₄ in Formula 1, and two or more selected from among R₄₁ to R₄₄ being optionally bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, and
Formulae 1-1 and 1-2 satisfying at least one selected from among Conditions A and B:
Condition A
T₃₁ and T₃₅ are different from each other; and
Condition B
T₃₂ and T₃₄ are different from each other,
in Formulae 1-1 and 1-2, a group represented by 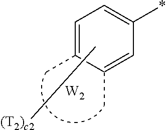
and a group represented by 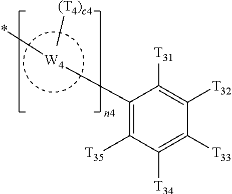
being different from each other, and
* indicating a binding site to a neighboring atom.

20. The organometallic compound of claim 19, wherein
X₄₂ is C(R₄₂), X₄₃ is C(R₄₃), and at least one of R₄₂ or R₄₃ is not hydrogen.
